(19) United States
(12) Patent Application Publication
(10) Pub. No.: US 2025/0122233 A1
(43) Pub. Date: Apr. 17, 2025

(54) ORGANIC ELECTROLUMINESCENT MATERIALS AND DEVICES

(71) Applicant: Universal Display Corporation, Ewing, NJ (US)

(72) Inventors: Zhiqiang JI, Chalfont, PA (US); Derek Ian WOZNIAK, Bensalem, PA (US); Pierre-Luc T. BOUDREAULT, Pennington, NJ (US); Tongxiang LU, Lawrenceville, NJ (US); Alexey Borisovich DYATKIN, Ambler, PA (US); Jerald FELDMAN, Cherry Hill, NJ (US)

(73) Assignee: Universal Display Corporation, Ewing, NJ (US)

(21) Appl. No.: 18/765,912

(22) Filed: Jul. 8, 2024

Related U.S. Application Data
(60) Provisional application No. 63/514,698, filed on Jul. 20, 2023.
(60) Provisional application No. 63/585,614, filed on Sep. 27, 2023.
(60) Provisional application No. 63/600,843, filed on Nov. 20, 2023.

(51) Int. Cl. C07F 15/00; C07B 59/00; H10K 85/30; H10K 85/40; H10K 85/60

(52) U.S. Cl. CPC C07F 15/0033; C07B 59/004; H10K 85/342; H10K 85/40; H10K 85/622; H10K 85/623; H10K 85/624; H10K 85/654; H10K 85/6572; H10K 85/6574; H10K 85/6576; C07B 2200/05

(57) ABSTRACT

A compound comprising a first ligand L_{A} of Formula I′,

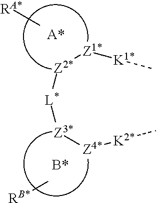

or Formula I*:
In Formula I′ or Formula I*, all the variables are defined herein; and L_{A} is coordinated to a metal M. Formulations, OLEDs, and consumer products containing the compound are also provided.

### CROSS-REFERENCE TO RELATED APPLICATIONS

This application claims priority under 35 U.S.C. § 119(e) to U.S. Provisional Applications No. 63/600,843, filed on Nov. 20, 2023, No. 63/585,614, filed on Sep. 27, 2023, and No. 63/514,698, filed on Jul. 20, 2023, the entire contents of which are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound comprising a first ligand L_{A} of Formula I′,

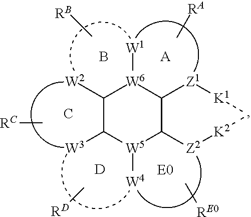

wherein moieties A, B, C, D, and E0 are each independently a monocyclic ring or a polycyclic fused ring system, wherein the monocyclic ring or each ring of the polycyclic fused ring system is independently a 5-membered or 6-membered carbocyclic or heterocyclic ring;
wherein W¹, W², W³, and W⁴ are each independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
wherein W⁵ and W⁶ are each independently selected from the group consisting of BR, N, CR, SiR, and GeR;
wherein each of K¹ and K² is independently selected from the group consisting of a direct bond, O, S, N(R^{α}), P(R^{α}), B(R^{α}), C(R^{α})(R^{β}), and Si(R^{α})(R^{β});
at least one of K¹ and K² is a direct bond;
each of R^{A}, R^{B}, R^{C}, R^{D}, and R^{E0} independently represents mono to a maximum allowable substitution, or no substitution;
each R, R′, R^{α}, R^{β}, R^{A}, R^{B}, R^{C}, R^{D}, and R^{E0} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M;
M may be coordinate to other ligands;
L_{A} may join with other ligands to form a tridentate, tetradentate, pentadentate, or hexadentate ligand;
wherein any two substituents may be joined or fused to form a ring; and
wherein compound is not

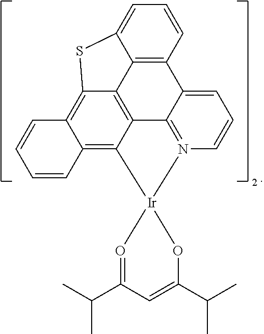

In another aspect, the present disclosure also provides a compound comprising a first ligand L_{A*} of Formula I*:

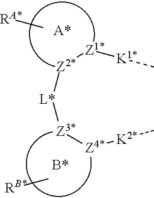

wherein each moiety A* and moiety B* is independently a monocyclic ring or a polycyclic fused ring system, wherein the monocyclic ring or each ring of the polycyclic fused ring system is independently a 5-membered to 10-membered carbocyclic or heterocyclic ring;
wherein Z^{1*}-Z^{4*} are each independently C or N;
wherein each R^{A*} and R^{B*} independently represents mono to the maximum allowable substitution, or no substitution;
wherein K^{1*} and K^{2*} are each independently selected from the group consisting of a direct bond, O, S, N(R^{α}), P(R^{α}), B(R^{α}), C(R^{α})(R^{β}), and Si(R^{α})(R^{β});
wherein L* is selected from the group consisting of a direct bond, BR, BRR′, NR, PR, P(O)R, O, S, Se, C═O, C═S, C═Se, C═NR′, C═CR′R″, S═O, SO₂, CRR′, SiRR′, and GeRR′;
wherein each of R^{α}, R^{β}, R, R′, R^{A*}, and R^{B*} is independently a hydrogen or a substituent selected from the group consisting a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
   wherein any two substituents may be joined or fused to form a ring;
   wherein L_{A*} comprises a structure of Formula II*

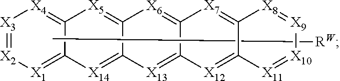

wherein each of X₁ to X₁₄ is independently C or N; each R^{W} represents mono to the maximum allowable substitution, or no substitution; and each R^{W} is independently a hydrogen or a substituent selected from the group consisting a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and any two R^{W} may be optionally joined or fused to form a ring;
wherein L_{A*} is coordinated to a metal M having an atomic mass of at least 40;
wherein the compound is a monometallic compound;
wherein the metal M may be coordinated to other ligands; and
wherein L_{A*} may be joined with other ligands to form a tridentate, tetradentate, pentadentate, or hexadentate ligand;

In yet another aspect, the present disclosure provides a formulation comprising a compound comprising a first ligand L_{A} of Formula I′ or Formula I* as defined herein.

In yet another aspect, the present disclosure provides an OLED having an organic layer comprising a compound comprising a first ligand L_{A} of Formula I′ or Formula I* as defined herein.

In yet another aspect, the present disclosure provides a consumer product comprising an OLED with an organic layer comprising a compound comprising a first ligand L_{A} of Formula I′ or Formula I* as defined herein.

### BRIEF DESCRIPTION OF THE DRAWINGS

FIG. 1 shows an organic light emitting device.

FIG. 2 shows an inverted organic light emitting device that does not have a separate electron transport layer.

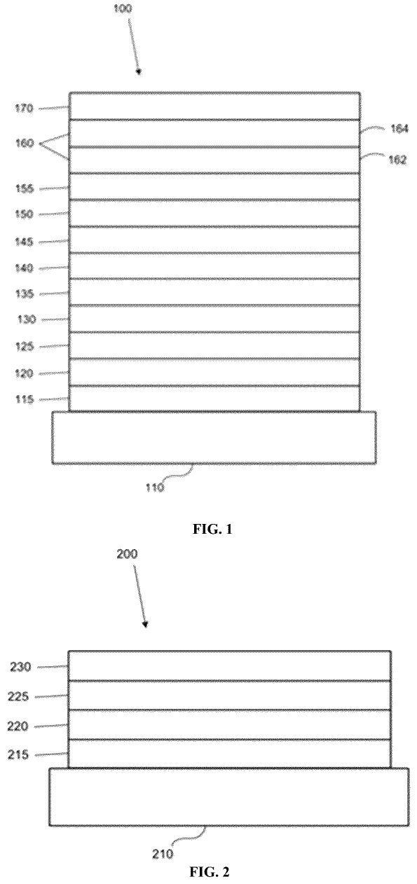

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.3731, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —ORₛ group.

The terms “sulfanyl” or “thio-ether” are used interchangeably and refer to a —SRₛ group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure. Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen or a substituent selected from the group consisting of the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5λ²,9λ²-diaza-13b-boranaphtho[2,3,4-de]anthracene, 5λ²-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of

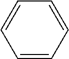

implies to include C₆H₆, C₆D₆, C₆H₃D₃, and any other partially deuterated variants thereof. Some common basic partially or fully deuterated groups include, without limitation, CD₃, CD₂C(CH₃)₃, C(CD₃)₃, and C₆D₅.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, includes both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

Complexes with unique ligand structures and substitution features are described herein. The substitution patterns described herein improve materials properties including emission color, emission spectrum lineshape, alignment in the emissive film layer and to improve OLED performance when the compound is used as emissive dopant.

In one aspect, the present disclosure provides a compound comprising a first ligand L_{A} of Formula I′,

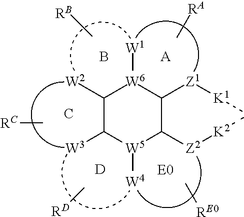

wherein moieties A, B, C, D, and E0 are each independently a monocyclic ring or a polycyclic fused ring system, wherein the monocyclic ring or each ring of the polycyclic fused ring system is independently a 5-membered or 6-membered carbocyclic or heterocyclic ring;
wherein W¹, W², W³, and W⁴ are each independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
wherein W⁵ and W⁶ are each independently selected from the group consisting of BR, N, CR, SiR, and GeR;
wherein each of K¹ and K² is independently selected from the group consisting of a direct bond, O, S, N(R^{α}), P(R^{α}), B(R^{α}), C(R^{α})(R^{β}), and Si(R^{α})(R^{β});
at least one of K¹ and K² is a direct bond;
each of R^{A}, R^{B}, R^{C}, R^{D}, and R^{E0} independently represents mono to a maximum allowable substitution, or no substitution;
each R, R′, R^{α}, R^{β}, R^{A}, R^{B}, R^{C}, R^{D}, and R^{E0} is independently hydrogen or a substituent selected from the group consisting of the General Substituents defined herein;
L_{A} is coordinated to a metal M;
M may be coordinate to other ligands;
L_{A} may join with other ligands to form a tridentate, tetradentate, pentadentate, or hexadentate ligand;
wherein any two substituents may be joined or fused to form a ring; and
wherein compound is not

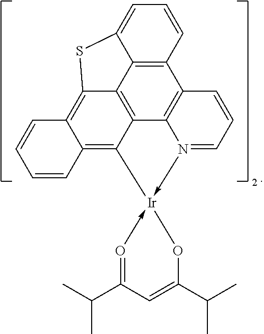

In some embodiments, when moiety C is a 5 membered aromatic ring, and moiety A is 6 member or polycyclic, then two R^{C} are not joined to form a ring. In some of these embodiments, moiety B and/or moiety D may be present or absent.

In some embodiments, when moiety C is a 5 membered non-aromatic ring, then moiety E0 is a polycyclic fused ring system.

In some embodiments, when moiety C is a 6-membered ring, then at least one of moiety A or moiety E0 is a polycyclic fused ring system; and at least one of moiety B or D is present.

In some embodiments, the compound comprises a ligand L_{A} of Formula I′A:

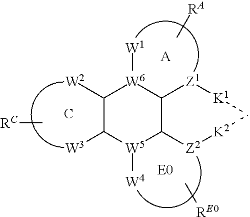

In some embodiments, the compound comprises a ligand L_{A} of Formula I′B:

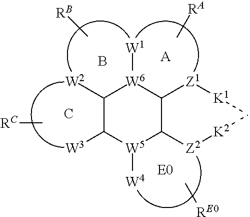

In some embodiments, the compound comprises a ligand L_{A} of Formula I′C:

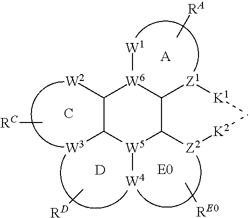

In some embodiments, the compound comprises a ligand L_{A} of Formula I′D:

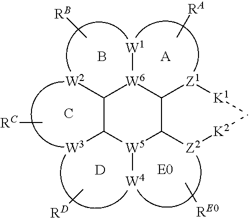

In some embodiments of Formula I′, each of moieties A, B when present, C, D when present, and E0 is independently selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, benzoxazole, benzothiophene, benzothiazole, benzoselenophene, indene, indole, benzimidazole, carbazole, dibenzofuran, dibenzothiophene, quinoxaline, phthalazine, phenanthrene, phenanthridine, and fluorene.

In some embodiments, moiety C is pyrrole, furan, thiophene, selenophene, pyrazole, oxazole, thioazole, or imidazole. In some embodiments, moiety A is pyridine, pyrimidine, quinoline, isoquinoline, furanopyridine, or thienopyridine.

In some embodiments of Formula I′, Z¹ is N and Z² is C. In some embodiments, Z¹ is C and Z² is N.

In some embodiments of Formula I′, each of W¹ to X⁶ is C, In some embodiments, at least one of W¹ to X⁶ is N. In some embodiments, at least one of W¹ to W⁴ is O, S, or Se. In some embodiments, at least one of W⁵ or W⁶ is N.

In one aspect, the present disclosure provides a compound comprising a first ligand L_{A} of Formula I,

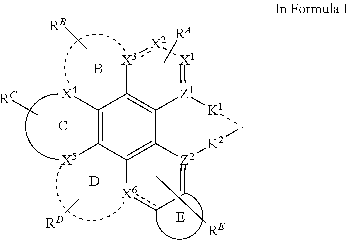

### In Formula I:

each of moiety C, moiety E, and, when present, moieties B and D is independently a monocyclic ring or a polycyclic fused ring system, wherein the monocyclic ring or each ring of the polycyclic fused ring system is independently a 5-membered or 6-membered carbocyclic or heterocyclic ring;
the dashed arcs indicate that moiety B and moiety D are optionally present;
each of X¹, X², Z¹, and Z² is independently C or N;
each of X³ to X⁶ is independently selected from the group consisting of C, O, S, Se, N, P, Si, and Ge;
each of K¹ and K² is independently selected from the group consisting of a direct bond, O, S, N(R^{α}), P(R^{α}), B(R^{α}), C(R^{α})(R^{β}), and Si(R^{α})(R^{β});
at least one of K¹ and K² is a direct bond;
each [symbol] is independently a single bond or a double bond;
each of R^{A}, R^{B}, R^{C}, R^{D}, and R^{E} independently represents mono to the maximum allowable substitution, or no substitution;
each R^{α}, R^{β}, R^{A}, R^{B}, R^{C}, R^{D}, and R^{E} is independently hydrogen or a substituent selected from the group consisting of the General Substituents defined herein;
L_{A} is coordinated to a metal M;
M may be coordinate to other ligands;
L_{A} may join with other ligands to comprise a tridentate, tetradentate, pentadentate, or hexadentate ligand;
any two substituents may be joined or fused to form a ring; and
with the proviso that the compound is not

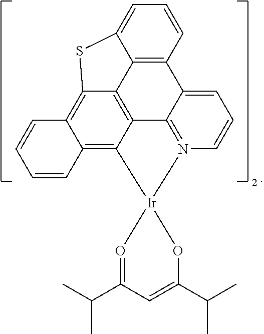

In some embodiments of Formula I, if each of X³ to X⁶ is carbon, then at least one of moiety B and moiety D is present.

In some embodiments of Formula I, at least one of R^{A}, R^{B} if present, R^{C}, R^{D} if present, or R^{E} is partially or fully deuterated. In some embodiments, at least one R^{A} is partially or fully deuterated. In some embodiments, at least one R^{B} if present is partially or fully deuterated. In some embodiments, at least one R^{C} is partially or fully deuterated. In some embodiments, at least one R^{D} if present is partially or fully deuterated. In some embodiments, at least one R^{E} is partially or fully deuterated.

In some embodiments, each R^{α}, R^{β}, R^{A}, R^{B} if present, R^{C}, R^{D} if present, and R^{E} is independently hydrogen or a substituent selected from the group consisting of the Preferred General Substituents defined herein. In some embodiments, each R^{α}, R^{β}, R^{A}, R^{B} if present, R^{C}, R^{D} if present, and R^{E} is independently hydrogen or a substituent selected from the group consisting of the More Preferred General Substituents defined herein. In some embodiments, each R^{α}, R^{β}, R^{A}, R^{B} if present, R^{C}, R^{D} if present, and R^{E} is independently hydrogen or a substituent selected from the group consisting of the Most Preferred General Substituents defined herein.

In some embodiments, metal M is selected from the group consisting of Ir, Rh, Re, Ru, Os, Pt, Pd, Ag, Au, and Cu. In some embodiments, metal M is Ir. In some embodiments, metal M is Pt or Pd. In some embodiments, metal M is Pt. In some embodiments, metal M is Pd.

In some embodiments, Z¹ is N and Z² is C. In some embodiments, Z¹ is C and Z² is N.

In some embodiments, the [symbol] between X² and X³ is a double bond. In some embodiments, the [symbol] between X² and X³ is a single bond. In some embodiments, the [symbol] that includes X⁶ is a double bond. In some embodiments, the [symbol] that includes X⁶ is a single bond.

In some embodiments, X¹ and X² are both C. In some embodiments, at least one of X¹ or X² is N.

In some embodiments, each of X³ to X⁶ is C.

In some embodiments, at least one of X³ to X⁶ is not C. In some embodiments, at least one of X³ to X⁶ is selected from the group consisting of O, S, Se, and N. In some embodiments, X³ is selected from the group consisting of O, S, Se, and N. In some embodiments, X⁴ is selected from the group consisting of O, S, Se, and N. In some embodiments, X⁵ is selected from the group consisting of O, S, Se, and N. In some embodiments, X⁶ is selected from the group consisting of O, S, Se, and N.

In some embodiments, at least one of X⁴ or X⁵ is selected from the group consisting of O, S, Se, and N. In some embodiments, at least one of X⁴ or X⁵ is O or S. In some embodiments, at least one of X⁴ or X⁵ is O. In some embodiments, at least one of X⁴ or X⁵ is S. In some embodiments, moiety C is a 5-membered ring.

In some embodiments, X⁴ is selected from the group consisting of O, S, Se, and N, and moiety B is not present. In some embodiments, X⁴ is N, and moiety B is present. In some such embodiments, moiety C is a 5-membered ring.

In some embodiments, X⁵ is selected from the group consisting of O, S, Se, and N, and moiety D is not present. In some embodiments, X⁵ is N, and moiety D is present. In some such embodiments, moiety C is a 5-membered ring.

In some embodiments, each of moiety C, moiety E, and, when present, moieties B and D is independently selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-anthracene, phenanthridine, fluorene, and aza-fluorene.

In some embodiments, moiety B is not present.

In some embodiments, moiety B is present. In some embodiments, B is a monocyclic ring. In some embodiments, moiety B is a polycyclic fused ring system. In some embodiments, the ring including X³ and X⁴ is a 5-membered ring. In some embodiments, the ring including X³ and X⁴ is a 6-membered ring.

In some embodiments, moiety B is selected from the group consisting of benzene, pyridine, naphthalene, quinoline, and isoquinoline. In some embodiments, moiety B is benzene. In some embodiments, moiety B is naphthalene. In some embodiments, moiety B is pyridine. In some embodiments, moiety B is pyridine. In some embodiments, X⁴ is N.

In some embodiments, moiety C is a monocyclic ring. In some embodiments, moiety C is a polycyclic fused ring system. In some embodiments, the ring including X⁴ and X⁵ is a 5-membered ring. In some embodiments, the ring including X⁴ and X⁵ is a 6-membered ring.

In some embodiments, moiety C is selected from the group consisting of benzene, pyrrole, and furan. In some embodiments, moiety C is benzene. In some embodiments, moiety C is pyrrole. In some embodiments, moiety C is furan. In some embodiments, X⁴ is N or O. In some embodiments, X⁵ is N or O.

In some embodiments, moiety D is not present. In some embodiments, X⁵ is O. In some embodiments, X⁵ is N.

In some embodiments, moiety D is present. In some embodiments, moiety D is a monocyclic ring. In some embodiments, moiety D is a polycyclic fused ring system. In some embodiments, the ring including X⁵ and X⁶ is a 5-membered ring. In some embodiments, the ring including X⁵ and X⁶ is a 6-membered ring.

In some embodiments, moiety D is selected from the group consisting of benzene, pyridine, naphthalene, quinoline, and isoquinoline. In some embodiments, moiety D is benzene. In some embodiments, moiety D is naphthalene. In some embodiments, moiety D is pyridine. In some embodiments, moiety D is X⁵ is N.

In some embodiments, moiety E is a monocyclic ring. In some embodiments, moiety E is a polycyclic fused ring system. In some embodiments, the ring of moiety E fused to the ring containing X⁶ is a 5-membered ring. In some embodiments, the ring of moiety E fused to the ring containing X⁶ is a 6-membered ring.

In some embodiments, moiety E is selected from the group consisting of benzene, naphthalene, and thiophene. In some embodiments, moiety E is benzene. In some embodiments, moiety E is naphthalene. In some embodiments, moiety E is thiophene.

In some embodiments, each of moiety B, moiety C, moiety D, and moiety E can independently be a polycyclic fused ring structure. In some embodiments, each of moiety B, moiety C, moiety D, and moiety E can independently be a polycyclic fused ring structure comprising at least three fused rings. In some embodiments, the polycyclic fused ring structure has two 6-membered rings and one 5-membered ring. In some embodiments, each of moiety B, moiety C, moiety D, and moiety E can independently be selected from the group consisting of dibenzofuran, dibenzothiophene, dibenzoselenophene, and aza-variants thereof. In some such embodiments, each of moiety B, moiety C, moiety D, and moiety E can independently be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, each of moiety B, moiety C, moiety D, and moiety E can independently be a polycyclic fused ring structure comprising at least four fused rings. In some embodiments, the polycyclic fused ring structure comprises three 6-membered rings and one 5-membered ring.

In some embodiments, each of moiety B, moiety C, moiety D, and moiety E can independently be a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring.

In some embodiments, each of moiety B, moiety C, moiety D, and moiety E can independently be an aza version of the polycyclic fused rings described above. In some such embodiments, each of moiety B, moiety C, moiety D, and moiety E can independently contain exactly one aza N atom. In some such embodiments, each of moiety B, moiety C, moiety D, and moiety E contains exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho positions of the aza N atom is substituted.

In some embodiments, at least one R^{A} is not hydrogen. In some embodiments, at least one R^{A} comprises at least one C atom. In some embodiments, moiety B is not present and the R^{A} at X³ comprises at least one C atom.

In some embodiments, two R^{A} are joined or fused to form a ring. In some embodiments, the R^{A} at X¹ and X² are joined or fused to form a ring. In some embodiments, the R^{A} at X² and X³ are joined or fused to form a ring. In some embodiments, the ring formed by the joining or fusing of two R^{A} is a benzene ring.

In some embodiments, at least one R^{B} is not hydrogen. In some embodiments, at least one R^{B} comprises at least one C atom.

In some embodiments, two R^{B} are joined or fused to form a ring. In some embodiments, two R^{B} are joined or fused to form a benzene ring.

In some embodiments, at least one R^{C} is not hydrogen. In some embodiments, at least one R^{C} comprises at least one C atom. In some embodiments, moiety B is not present and the R^{C} at X⁴ comprises at least one C atom. In some embodiments, moiety D is not present and the R^{C} at X⁵ comprises at least one C atom.

In some embodiments, two R^{C} are joined or fused to form a ring. In some embodiments, two R^{C} are joined or fused to form a benzene ring.

In some embodiments, at least one R^{D} is not hydrogen. In some embodiments, at least one R^{D} comprises at least one C atom.

In some embodiments, two R^{D} are joined or fused to form a ring. In some embodiments, two R^{D} are joined or fused to form a benzene ring.

In some embodiments, at least one R^{E} is not hydrogen. In some embodiments, at least one R^{E} comprises at least one C atom. In some embodiments, moiety D is not present and the R^{E} at X⁶ comprises at least one C atom.

In some embodiments, two R^{E} are joined or fused to form a ring. In some embodiments, two R^{E} are joined or fused to form a benzene ring.

It should be understood that all the Formula I related embodiments can be equally applied to Formula I′, Formula I′A, Formula I′B, Formula I′C or Formula I′D. For example, all R^{A} related embodiments can be equally applied to Formula I, Formula I′, Formula I′A, Formula I′B, Formula I′C or Formula I′D. Likewise, all R^{B}, R^{C}, R^{D}, R^{E0}, or R^{E} related embodiments of Formula I can be equally applied to Formula I′, Formula I′A, Formula I′B, Formula I′C or Formula I′D. The same is true for all the moieties B, C, D, E, or E0 related embodiments among Formula I, Formula I′, Formula I′A, Formula I′B, Formula I′C and Formula I′D.

In some embodiments, the compound comprises an electron-withdrawing group. In some embodiments, the compound comprises an electron-withdrawing group having a Hammett constant of at least 0.1.

In some embodiments, the compound comprises an electron-withdrawn group selected from the group consisting of the structures of the following EWG1 LIST: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

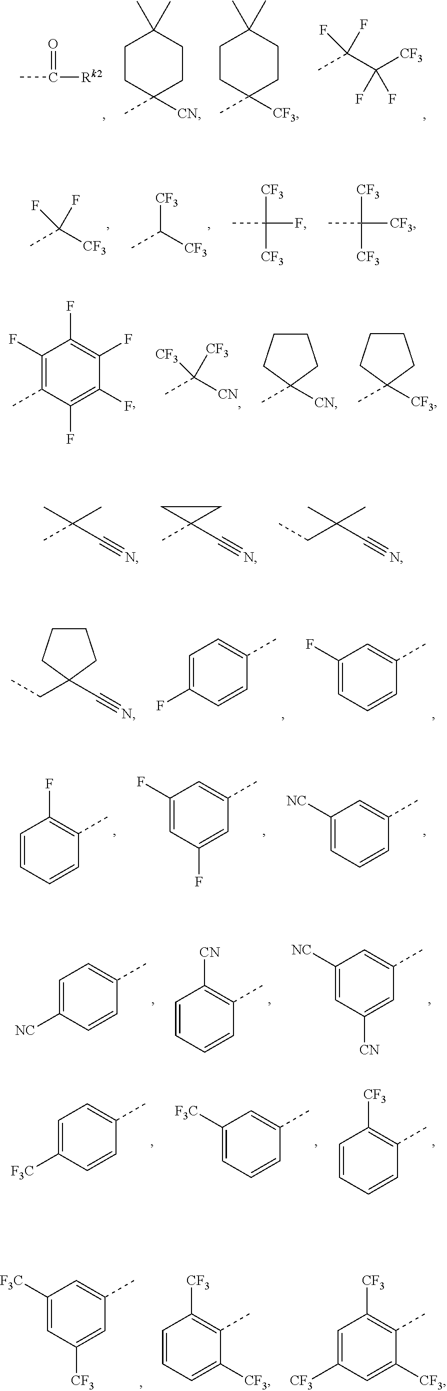

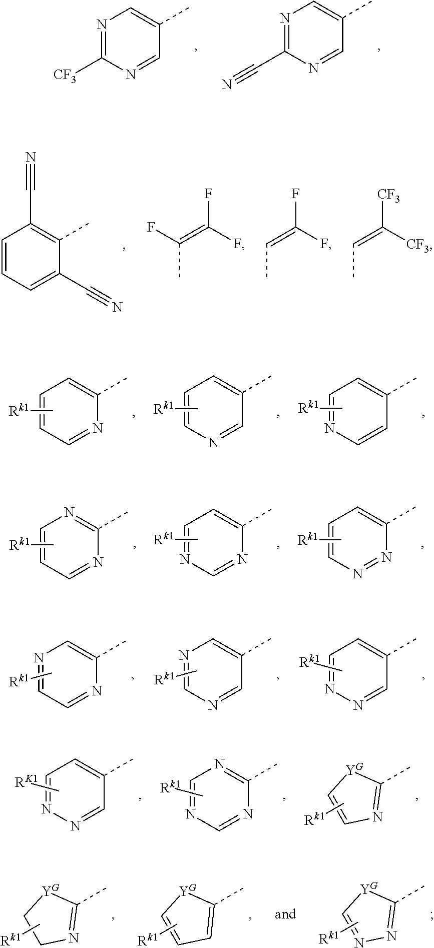

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen or a substituent selected from the group consisting of the General Substituents defined herein.

In some embodiments, the compound comprises an electron-withdrawing group selected from the group consisting of the structures of the following EWG2 List:

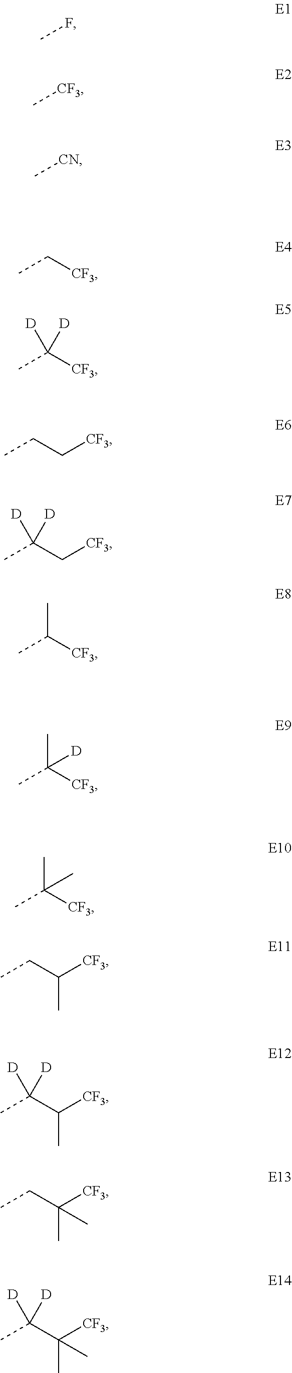

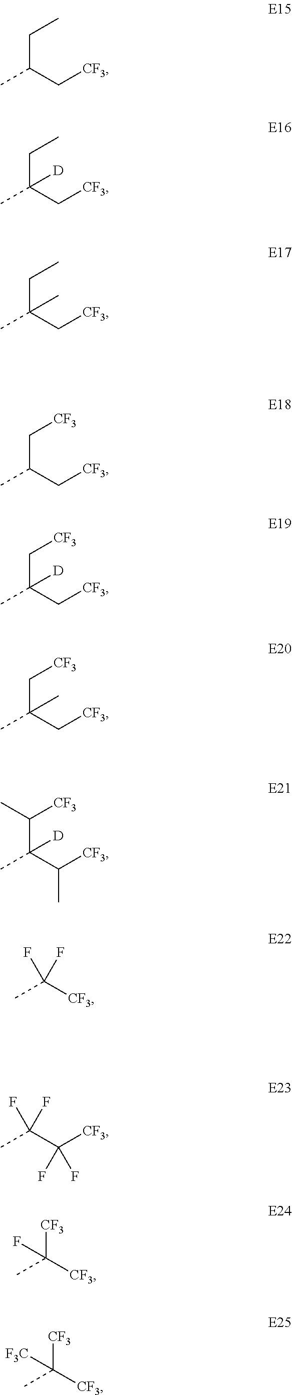

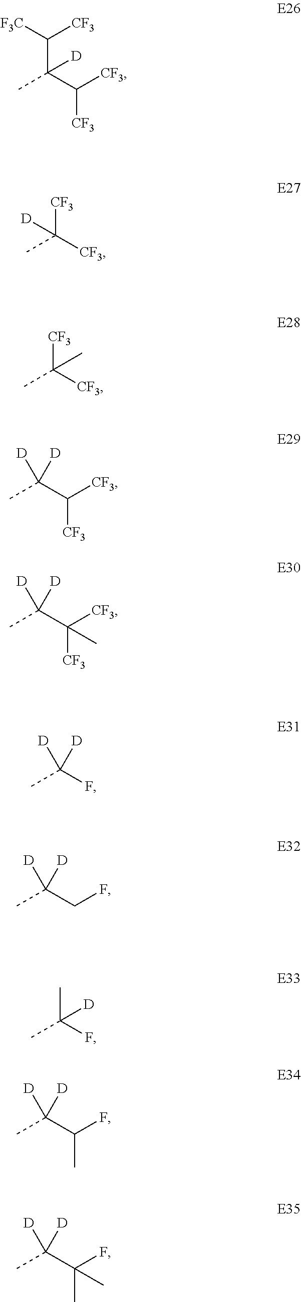

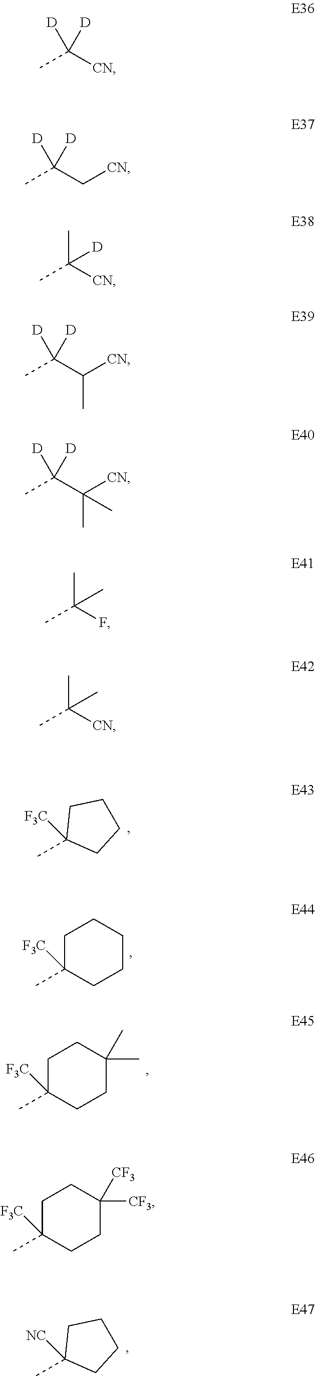

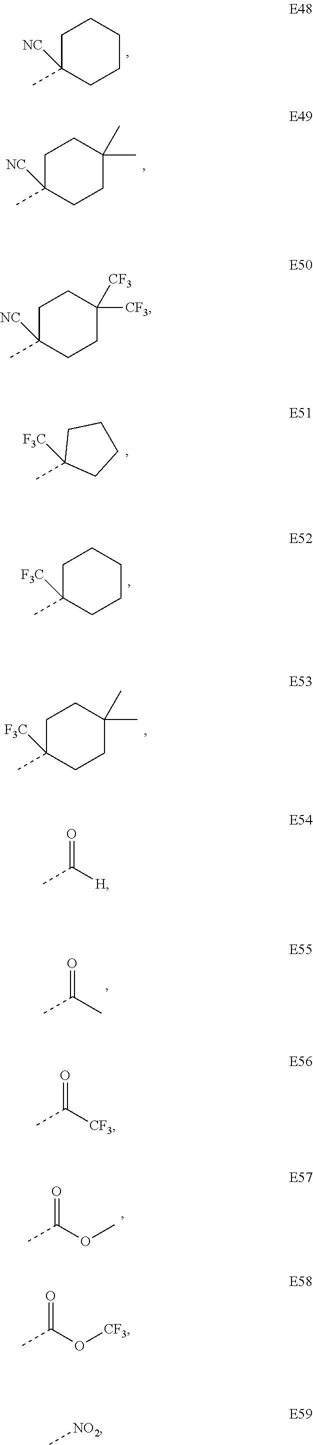

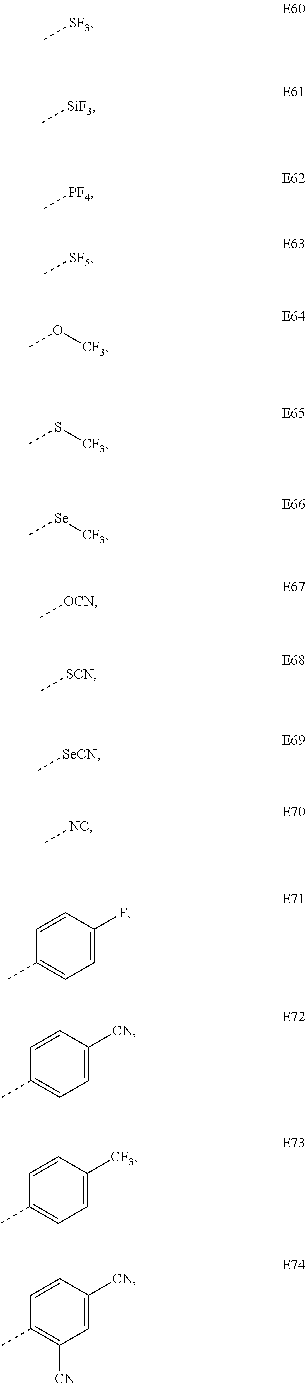

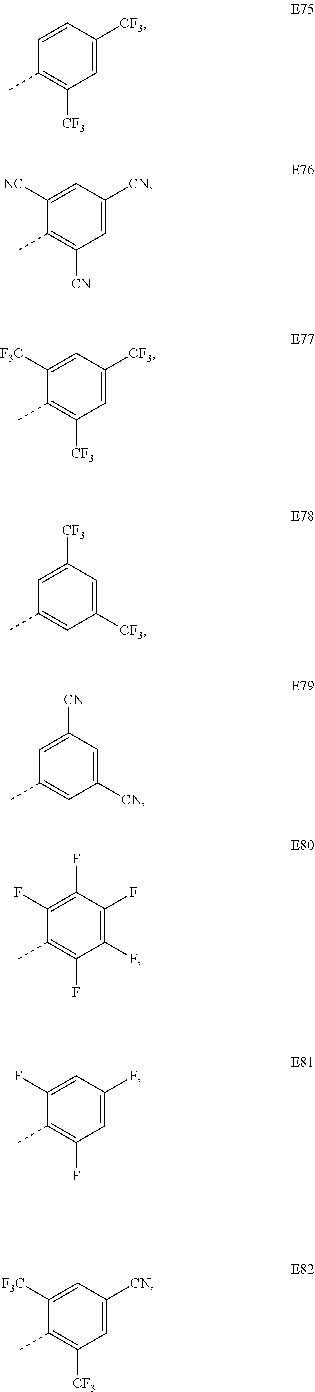

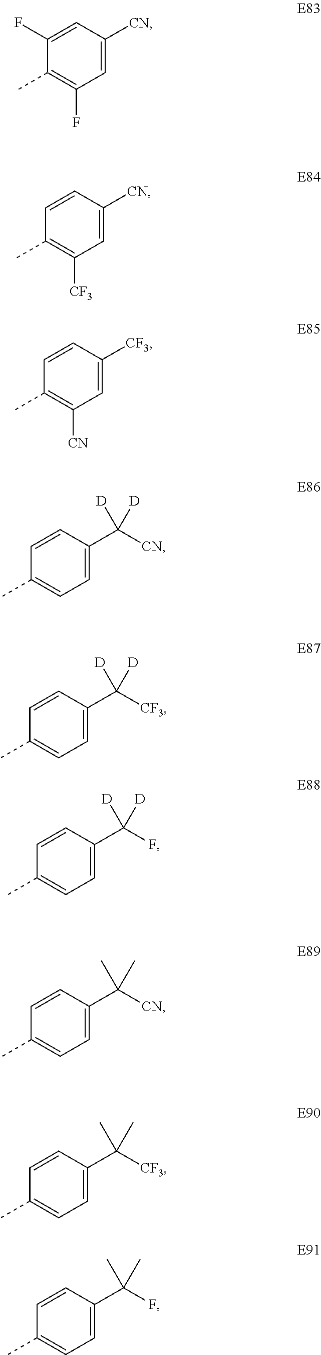

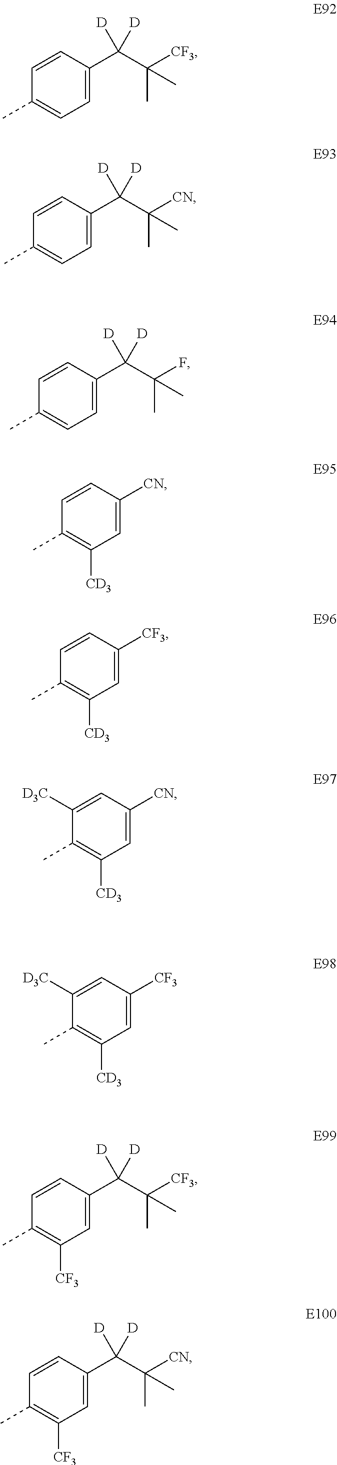

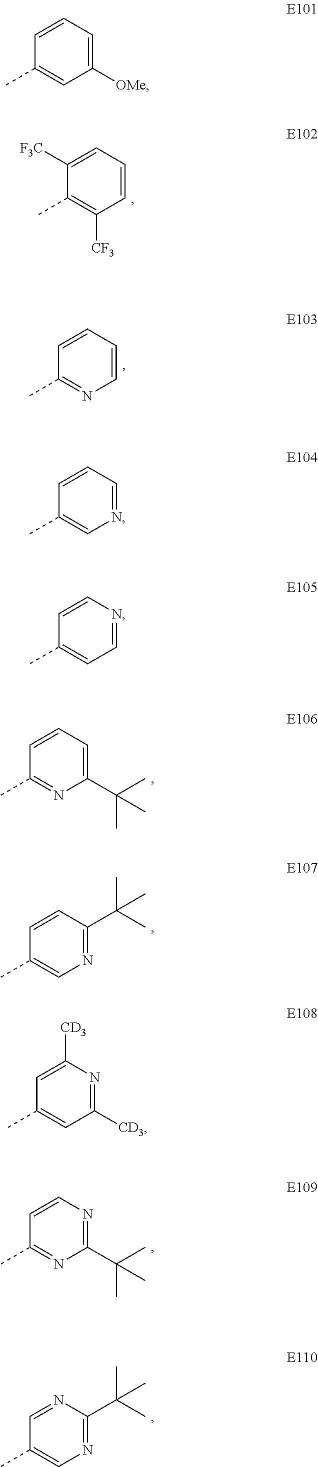

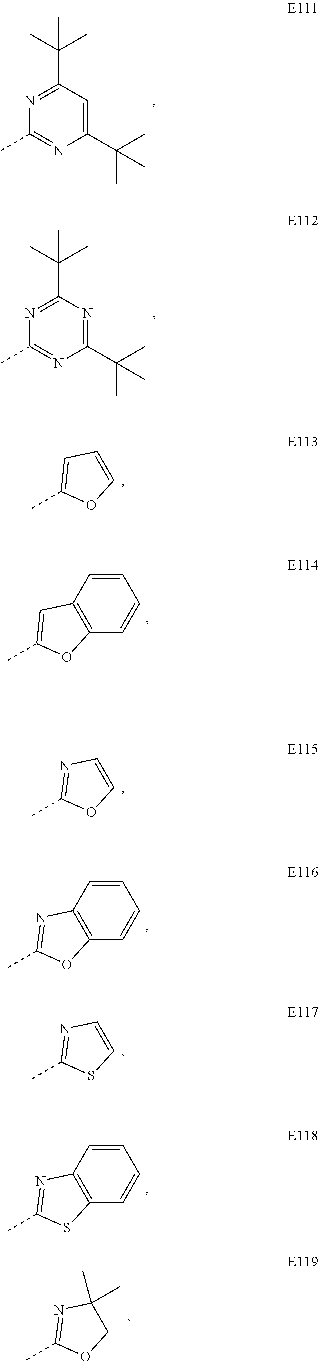

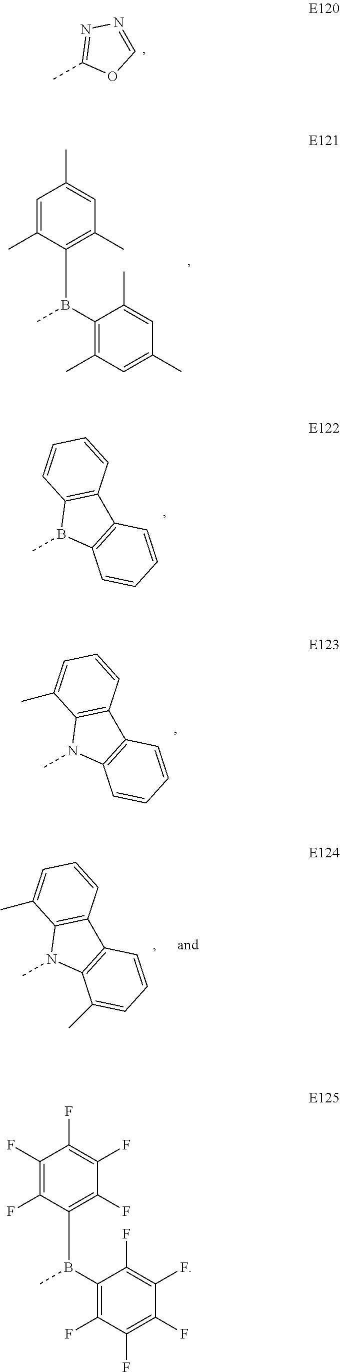

In some embodiments, the compound comprises an electron-withdrawing group selected from the group consisting of the structures of the following EWG3 LIST:

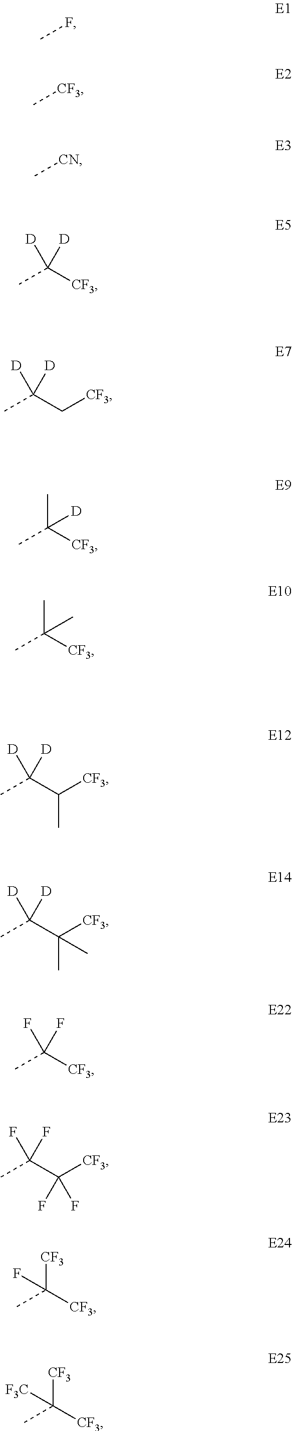

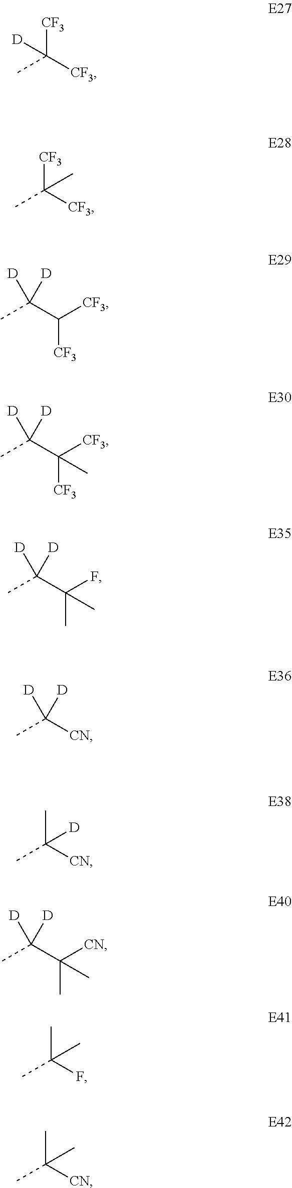

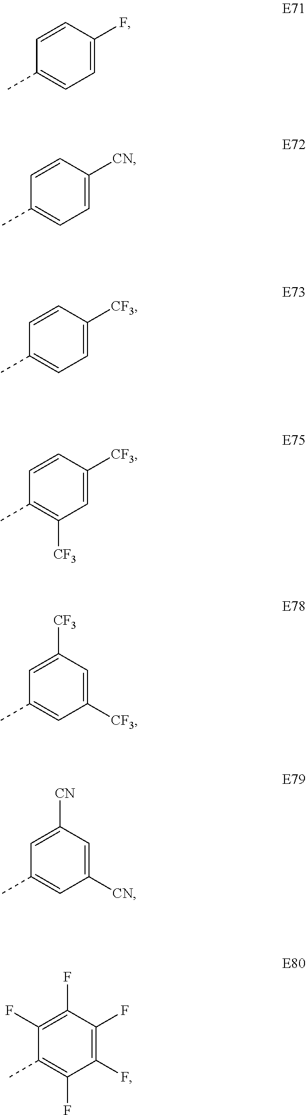

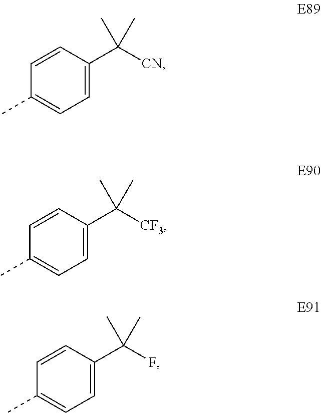

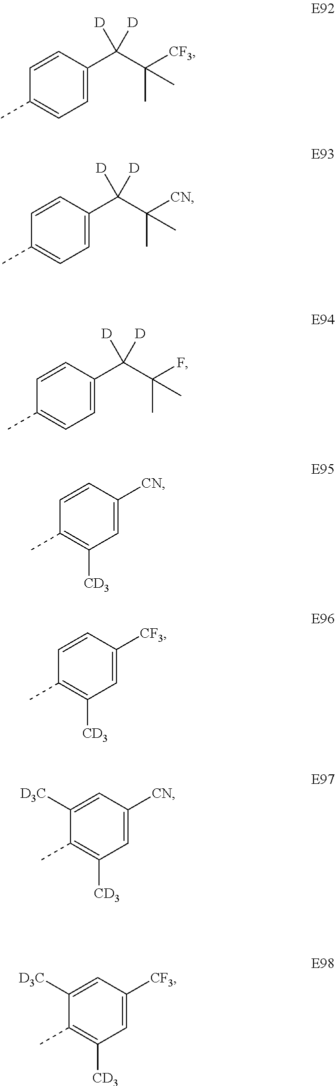

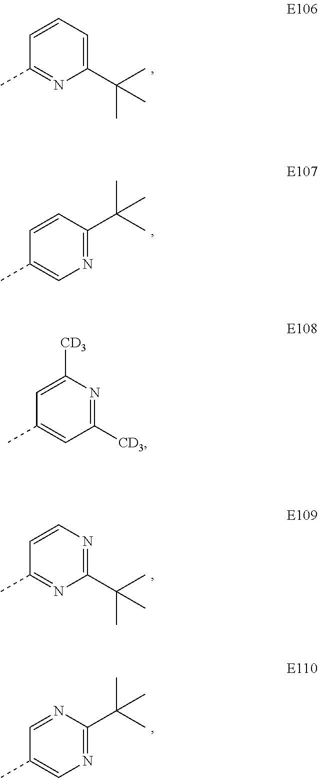

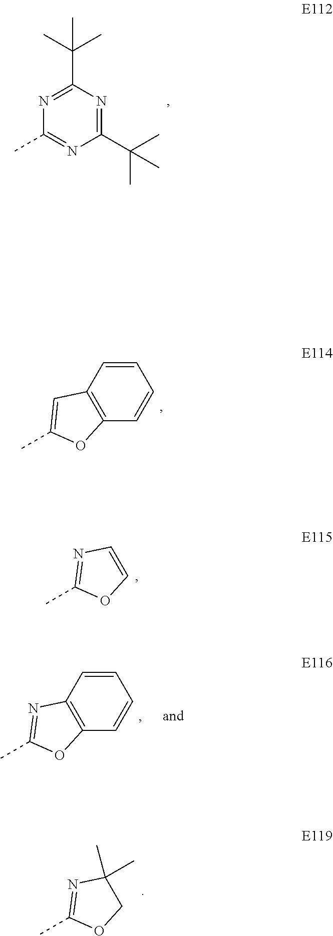

In some embodiments, the compound comprises an electron-withdrawing group selected from the group consisting of the structures of the following EWG4 LIST:

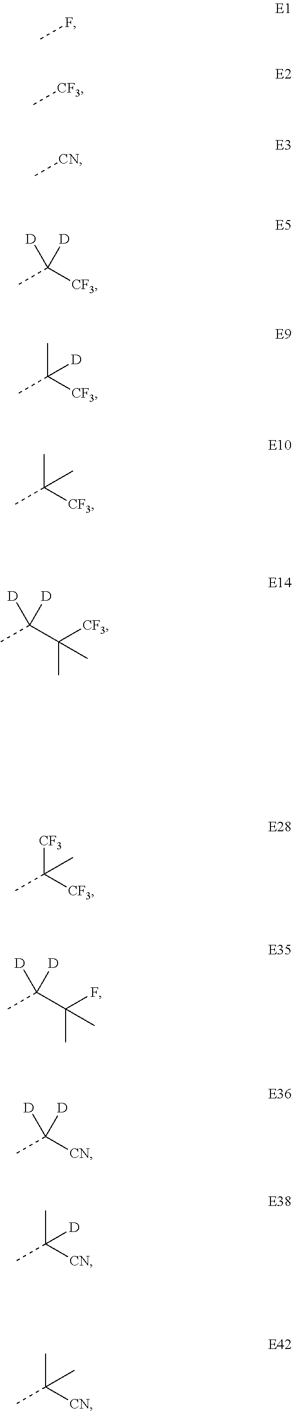

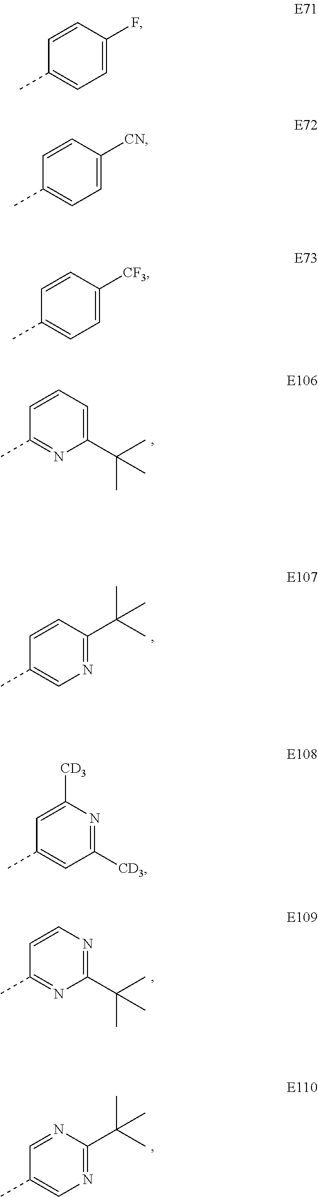

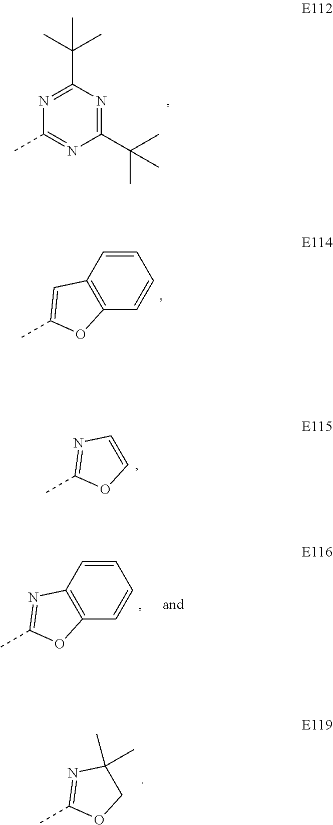

In some embodiments, the compound comprises an electron-withdrawing group that is a π-electron deficient electron-withdrawing group. In some embodiments, the π-electron deficient electron-withdrawing group is selected from the group consisting of the structures of the following Pi-EWG LIST: CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

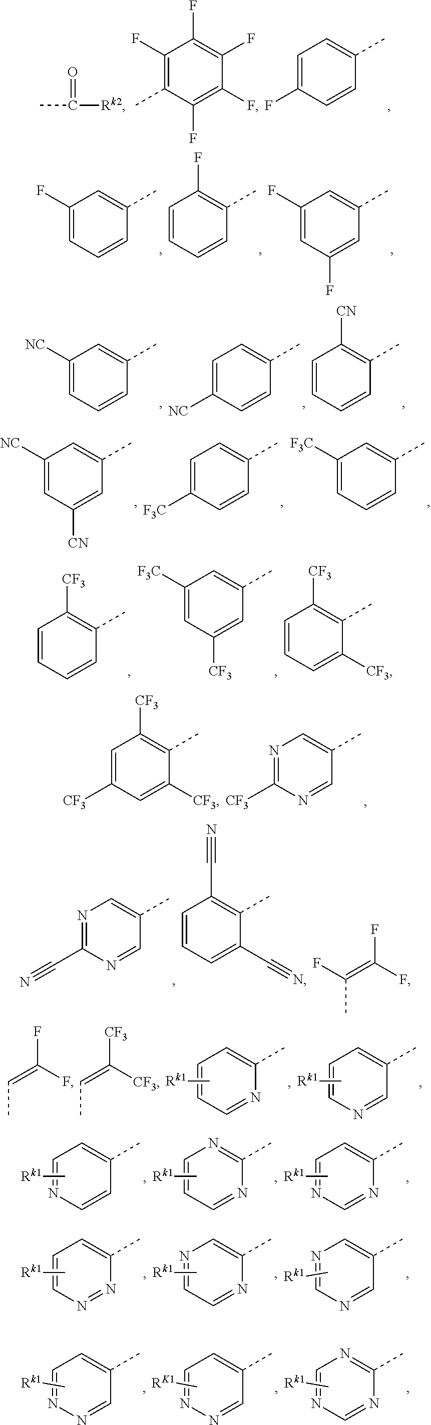

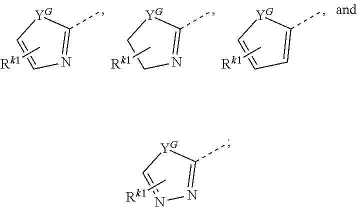

wherein the variables are the same as previously defined.

In some embodiments, at least one R^{A}, R^{B}, R^{C}, R^{D}, or R^{E} is or comprises an electron-withdrawing group selected from the EWG1 LIST as defined herein. In some embodiments, at least one R^{A} or R^{B} is or comprises an electron-withdrawing group selected from the EWG2 LIST as defined herein. In some embodiments, at least one R^{A} or R^{B} is or comprises an electron-withdrawing group selected from the EWG3 LIST as defined herein. In some embodiments, at least one R^{A} or R^{B} is or comprises an electron-withdrawing group selected from the EWG4 LIST as defined herein. In some embodiments, at least one R^{A} or R^{B} is or comprises an electron-withdrawing group selected from the Pi-EWG LIST as defined herein.

In some embodiments, at least one R^{A} is or comprises an electron-withdrawing group selected from the EWG1 LIST as defined herein. In some embodiments, at least one R^{A} is or comprises an electron-withdrawing group selected from the EWG2 LIST as defined herein. In some embodiments, at least one R^{A} is or comprises an electron-withdrawing group selected from the EWG3 LIST as defined herein. In some embodiments, at least one R^{A} is or comprises an electron-withdrawing group selected from the EWG4 LIST as defined herein. In some embodiments, at least one R^{A} is or comprises an electron-withdrawing group selected from the Pi-EWG LIST as defined herein.

In some embodiments, at least one R^{B} is or comprises an electron-withdrawing group selected from the EWG1 LIST as defined herein. In some embodiments, at least one R^{B} is or comprises an electron-withdrawing group selected from the EWG2 LIST as defined herein. In some embodiments, at least one R^{B} is or comprises an electron-withdrawing group selected from the EWG3 LIST as defined herein. In some embodiments, at least one R^{B} is or comprises an electron-withdrawing group selected from the EWG4 LIST as defined herein. In some embodiments, at least one R^{B} is or comprises an electron-withdrawing group selected from the Pi-EWG LIST as defined herein.

In some embodiments, at least one R^{C} is or comprises an electron-withdrawing group selected from the EWG1 LIST as defined herein. In some embodiments, at least one R^{C} is or comprises an electron-withdrawing group selected from the EWG2 LIST as defined herein. In some embodiments, at least one R^{C} is or comprises an electron-withdrawing group selected from the EWG3 LIST as defined herein. In some embodiments, at least one R^{C} is or comprises an electron-withdrawing group selected from the EWG4 LIST as defined herein. In some embodiments, at least one R^{C} is or comprises an electron-withdrawing group selected from the Pi-EWG LIST as defined herein.

In some embodiments, at least one R^{D} is or comprises an electron-withdrawing group selected from the EWG1 LIST as defined herein. In some embodiments, at least one R^{D} is or comprises an electron-withdrawing group selected from the EWG2 LIST as defined herein. In some embodiments, at least one R^{D} is or comprises an electron-withdrawing group selected from the EWG3 LIST as defined herein. In some embodiments, at least one R^{D} is or comprises an electron-withdrawing group selected from the EWG4 LIST as defined herein. In some embodiments, at least one R^{D} is or comprises an electron-withdrawing group selected from the Pi-EWG LIST as defined herein.

In some embodiments, at least one R^{E} is or comprises an electron-withdrawing group selected from the EWG1 LIST as defined herein. In some embodiments, at least one R^{E} is or comprises an electron-withdrawing group selected from the EWG2 LIST as defined herein. In some embodiments, at least one R^{E} is or comprises an electron-withdrawing group selected from the EWG3 LIST as defined herein. In some embodiments, at least one R^{E} is or comprises an electron-withdrawing group selected from the EWG4 LIST as defined herein. In some embodiments, at least one R^{E} is or comprises an electron-withdrawing group selected from the Pi-EWG LIST as defined herein.

In some embodiments, moiety D is not thiophene. In some embodiments, if moiety D is thiophene, then at least one of the following is true: (i) moiety B is present, (ii) moiety C is not benzene; (iii) moiety E is not benzene; (iv) at least one of X¹ to X⁶ is not C; or (v) at least one of R^{A}, R^{B}, R^{C}, R^{D}, or R^{E} comprises at least one C.

In some embodiments, the ligand L_{A} is selected from the group consisting of the structures of the following LIST 1:

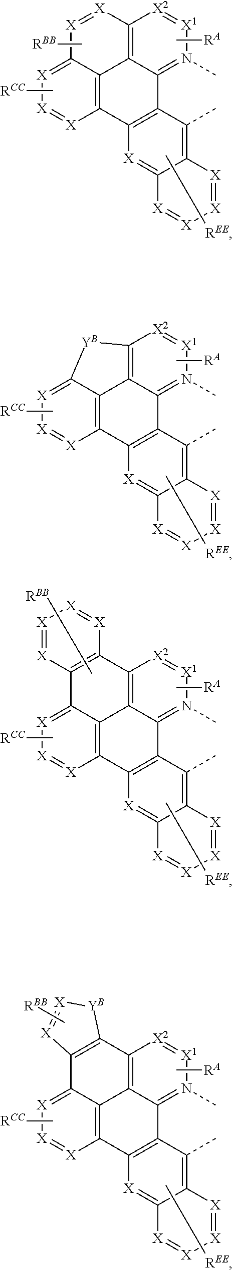

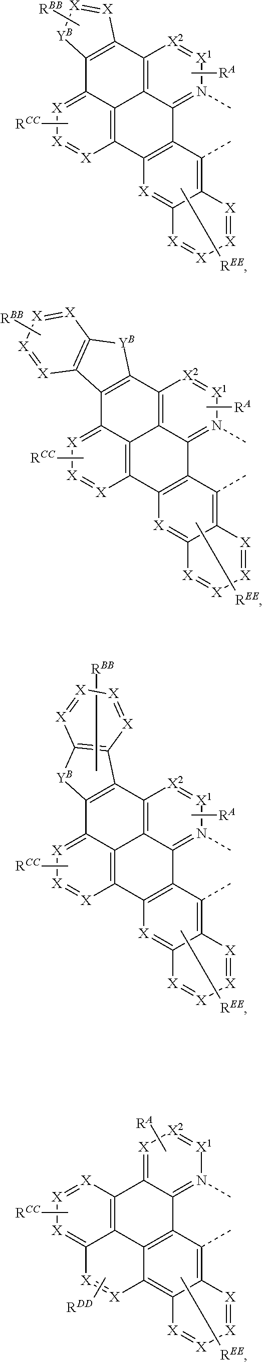

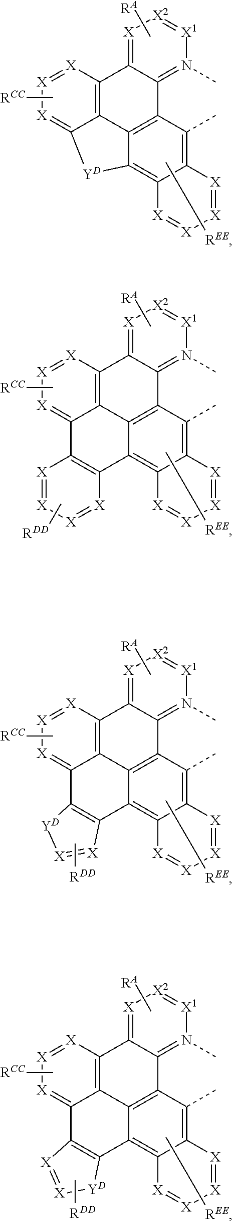

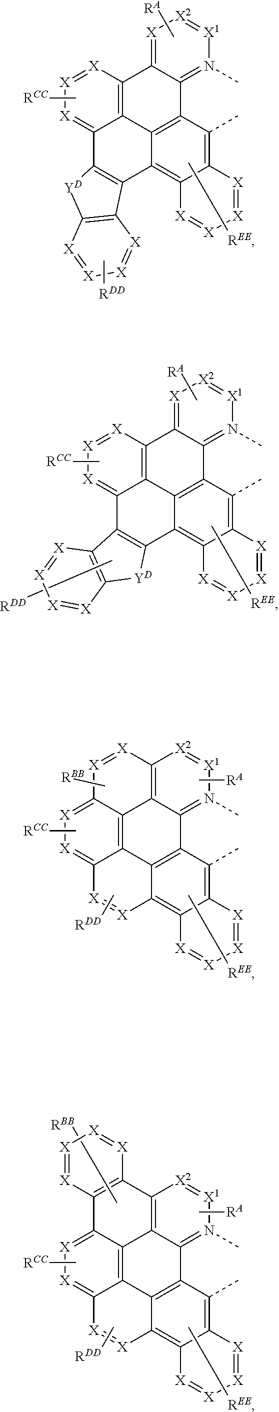

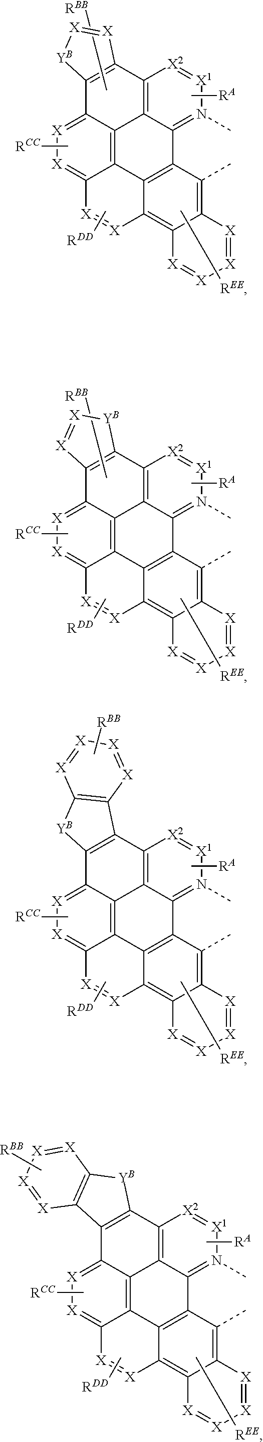

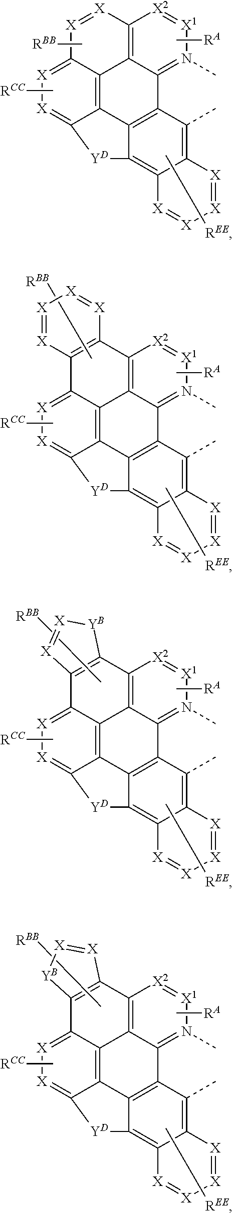

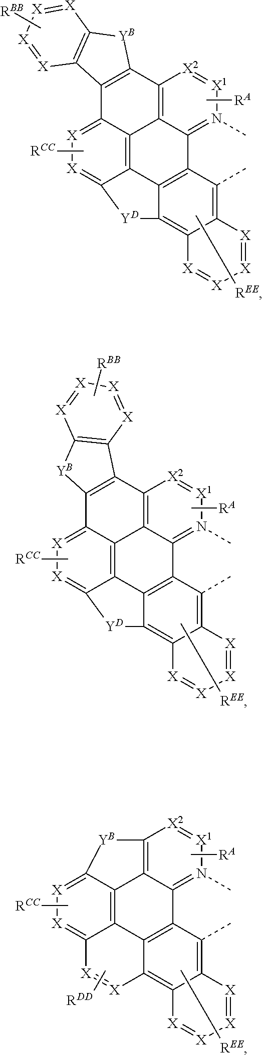

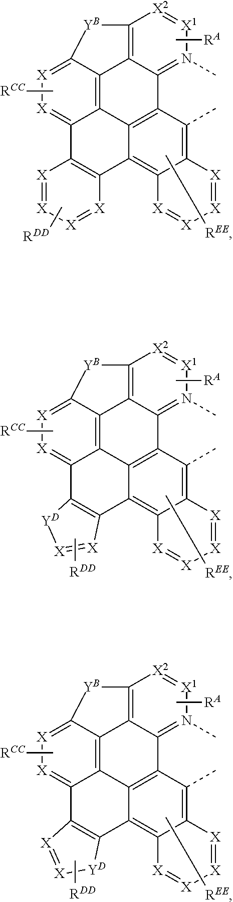

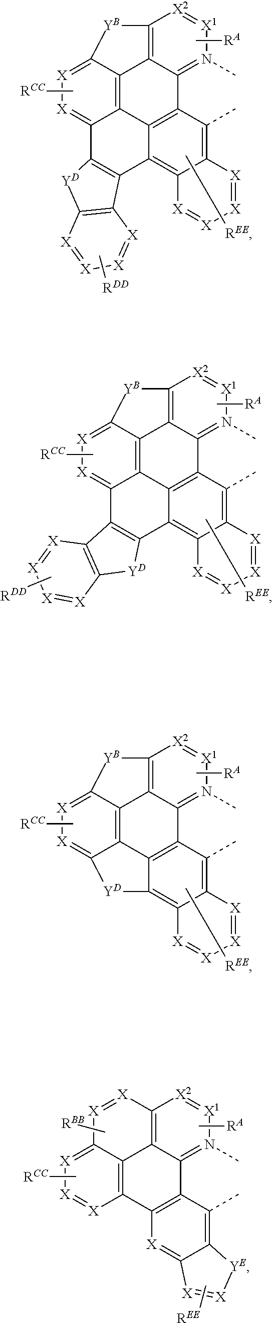

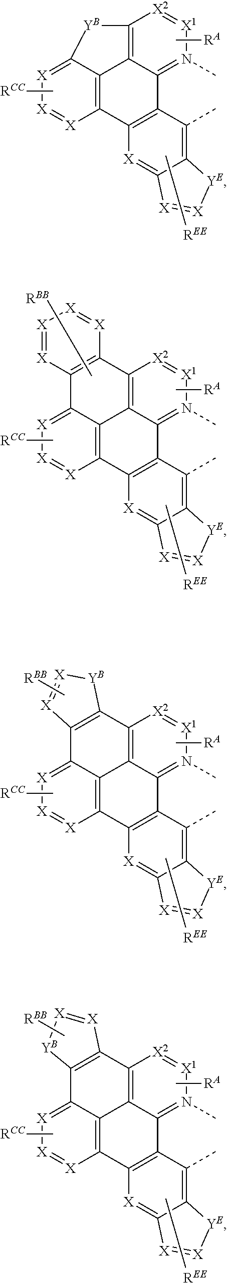

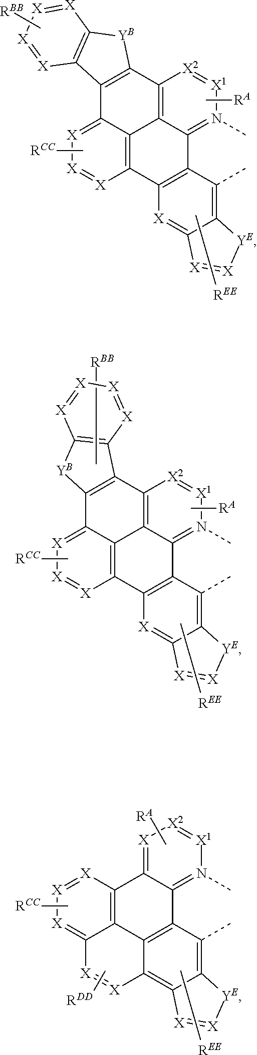

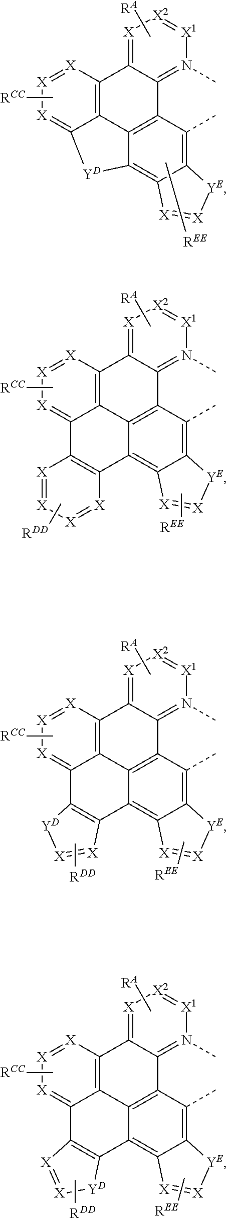

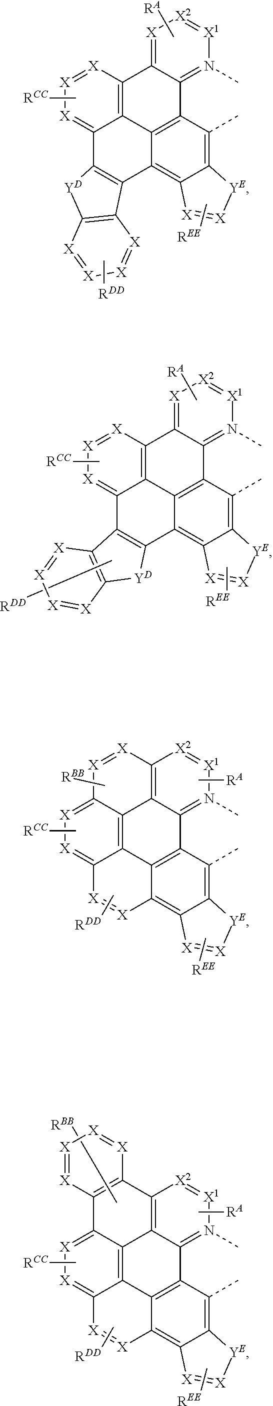

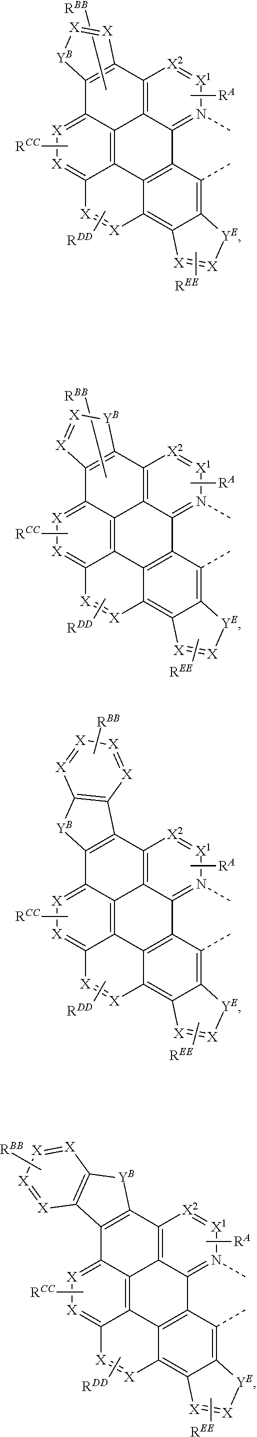

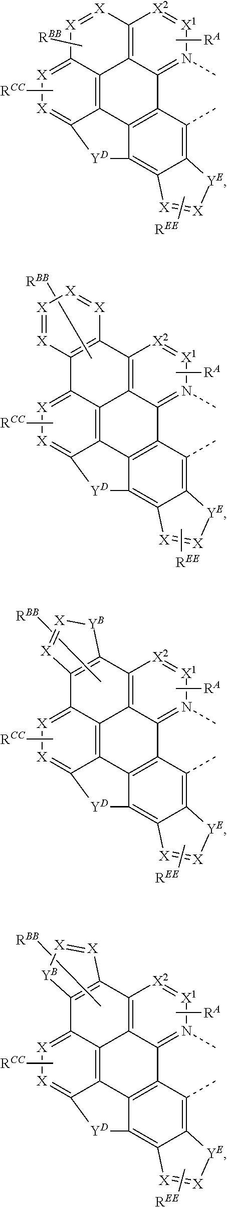

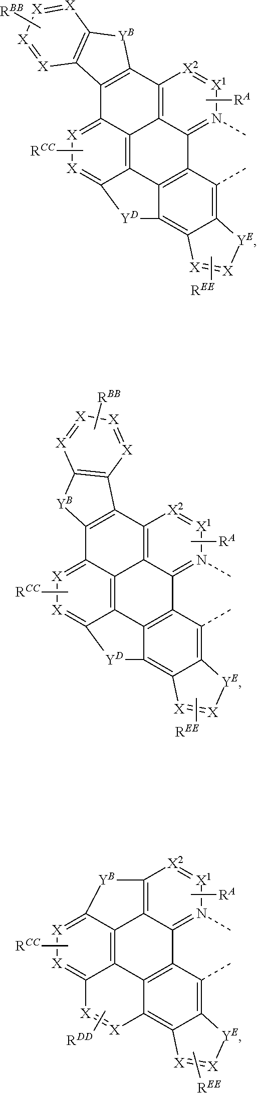

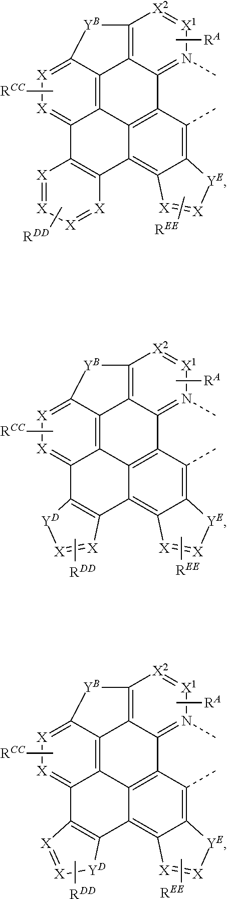

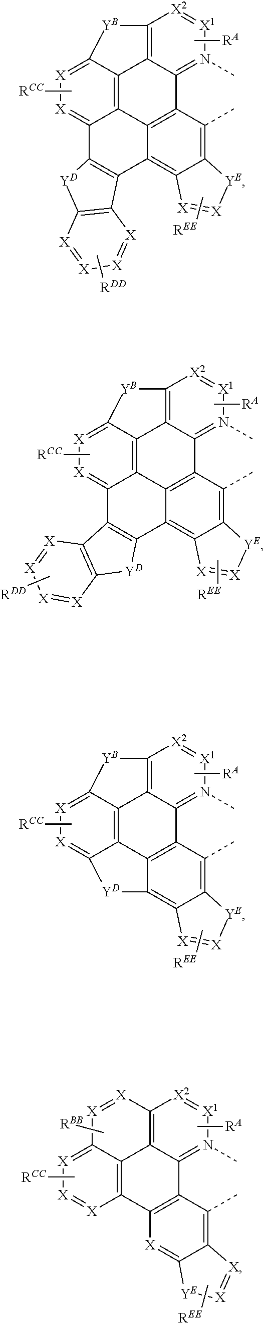

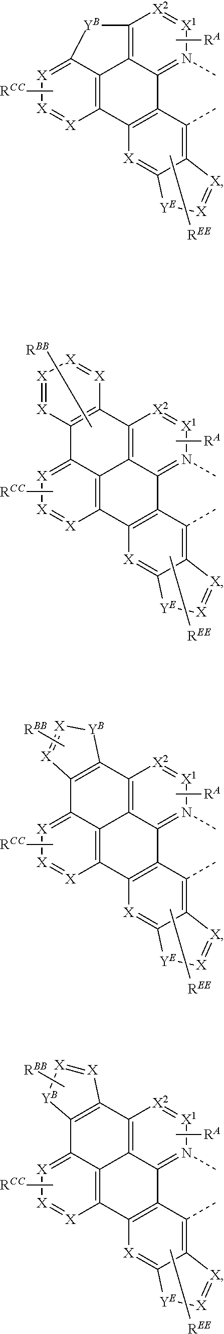

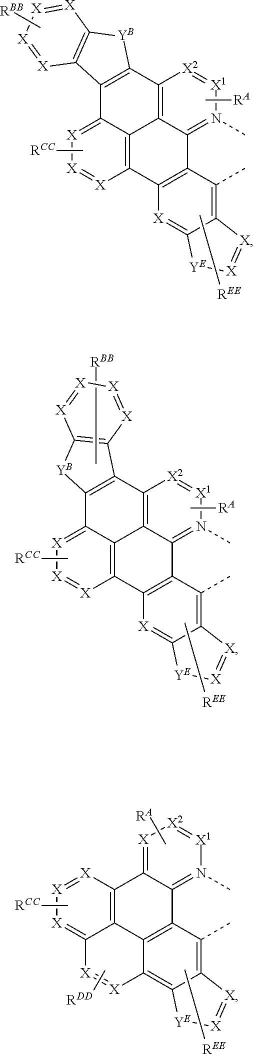

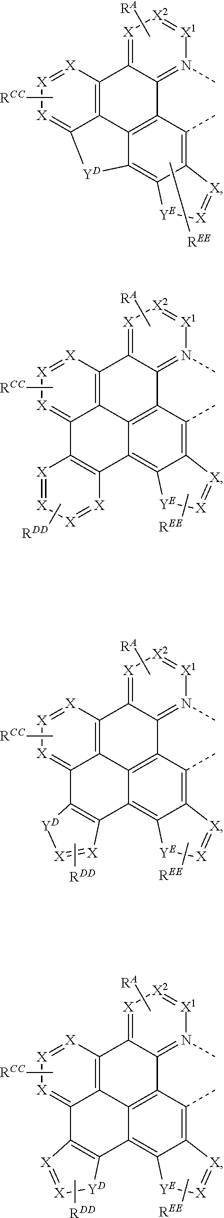

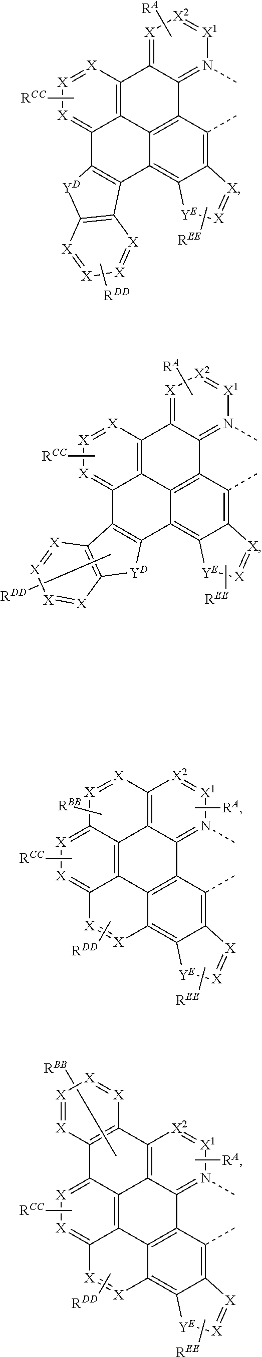

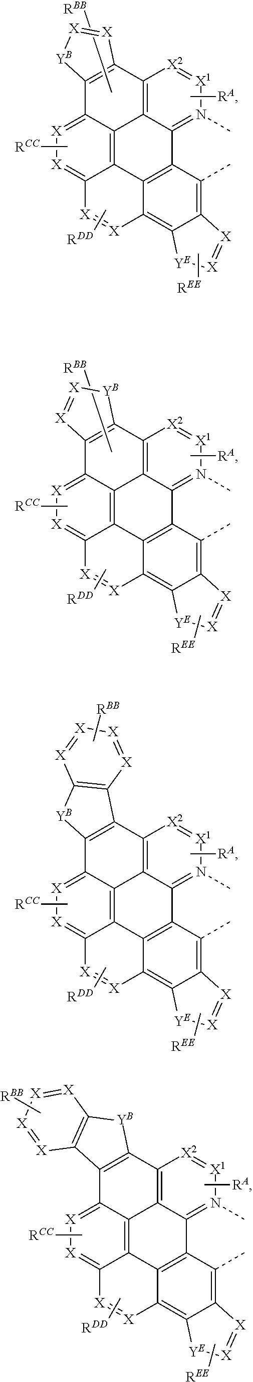

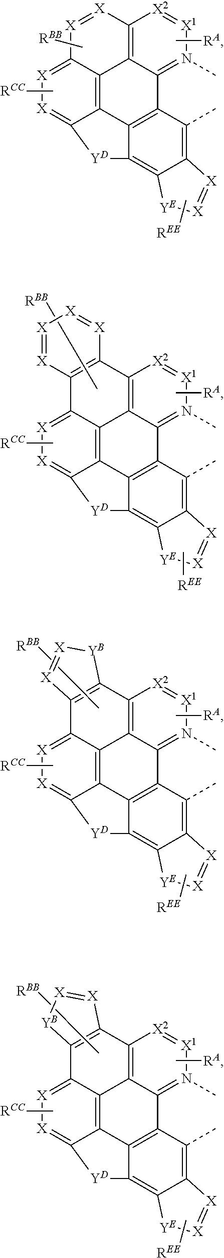

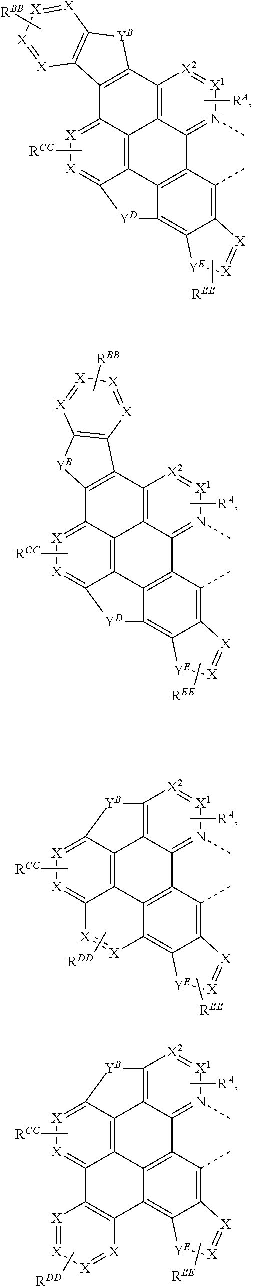

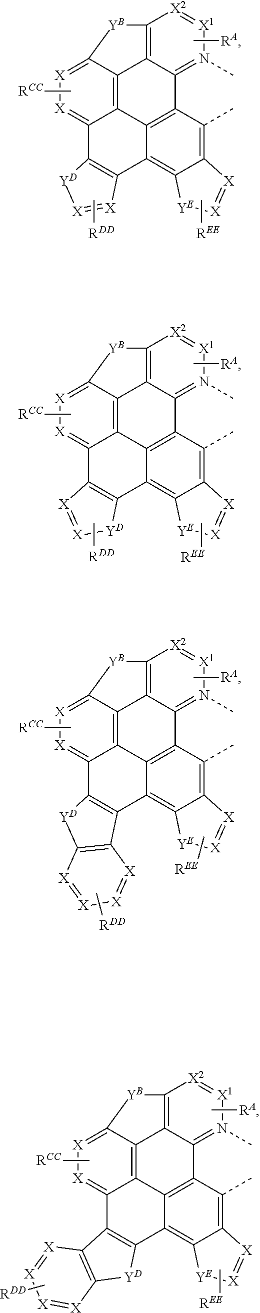

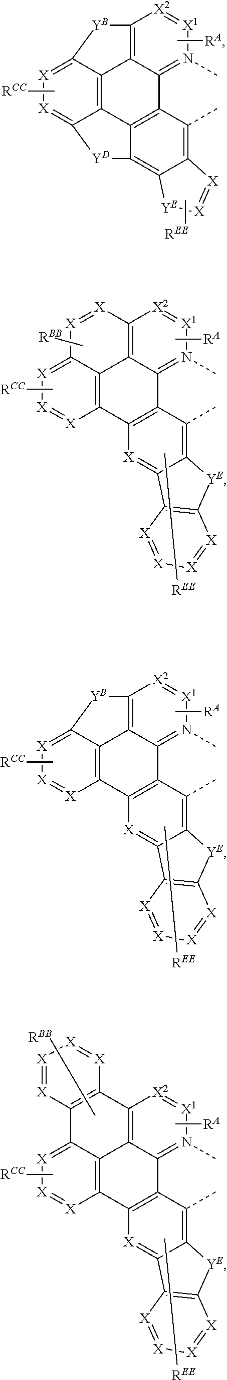

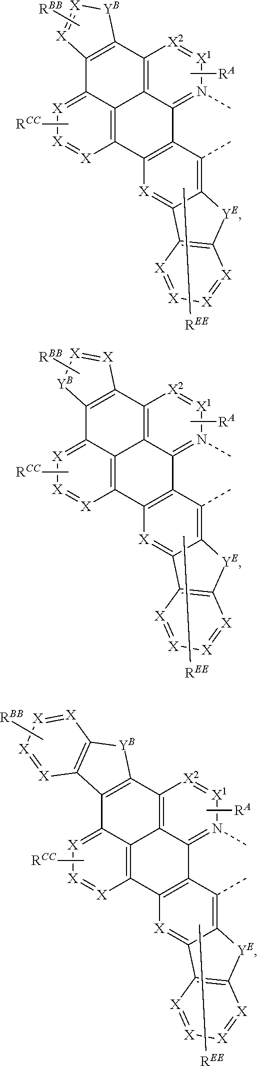

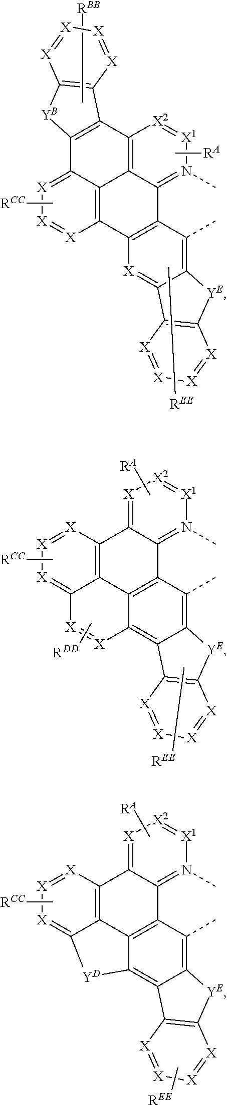

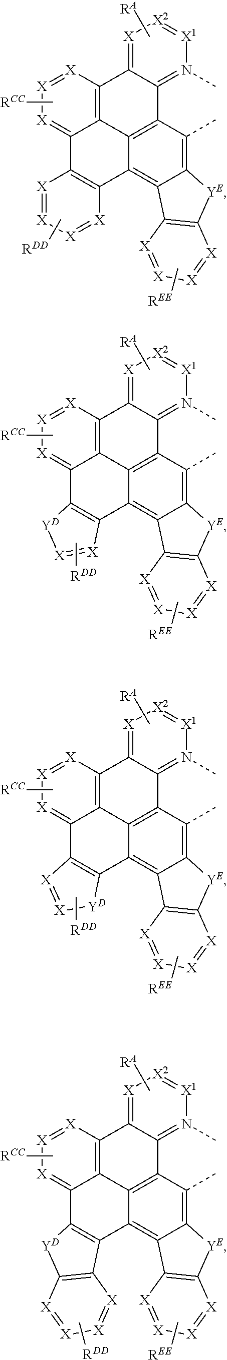

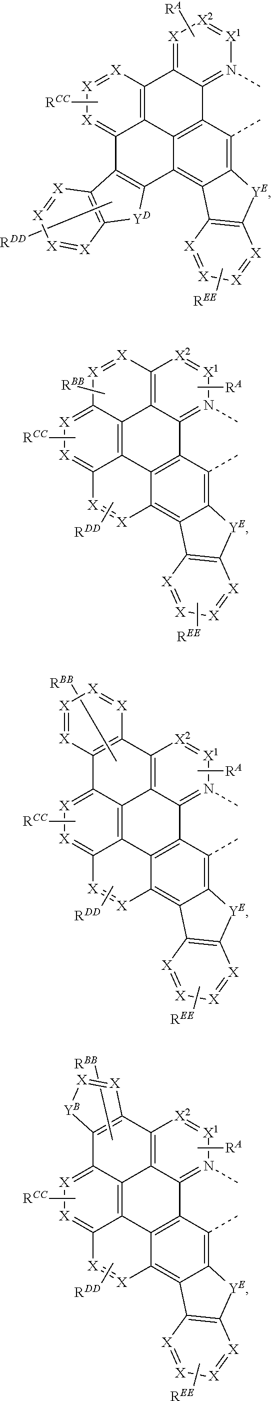

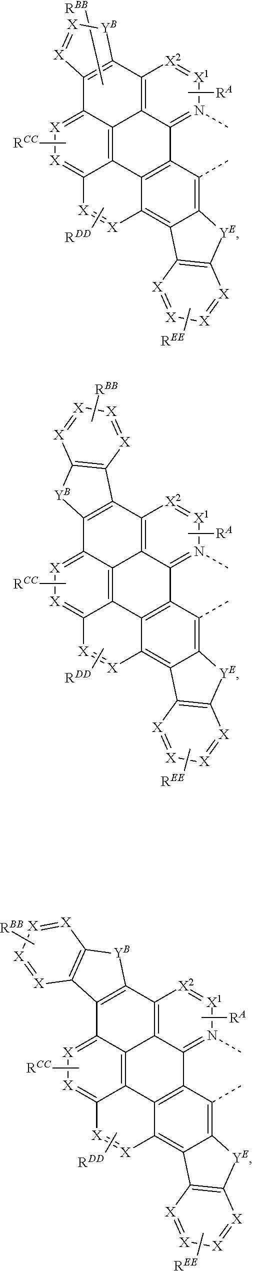

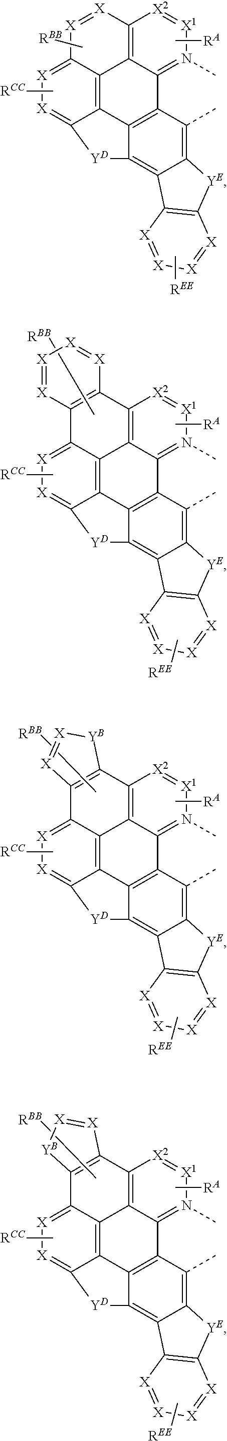

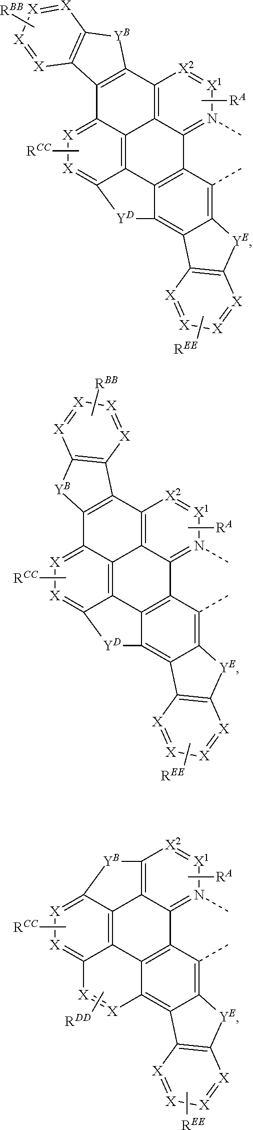

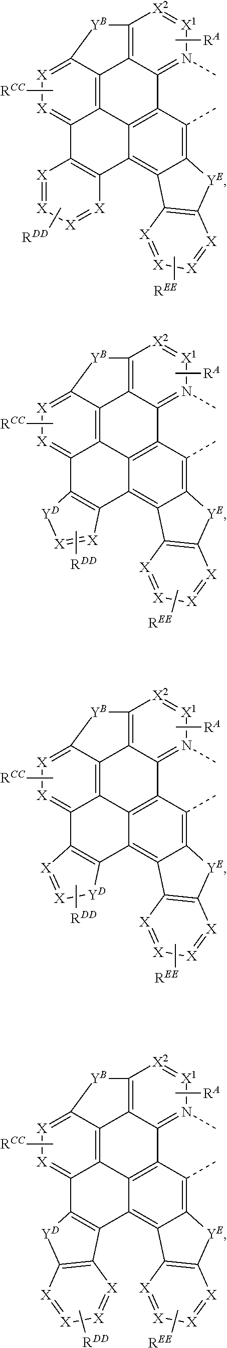

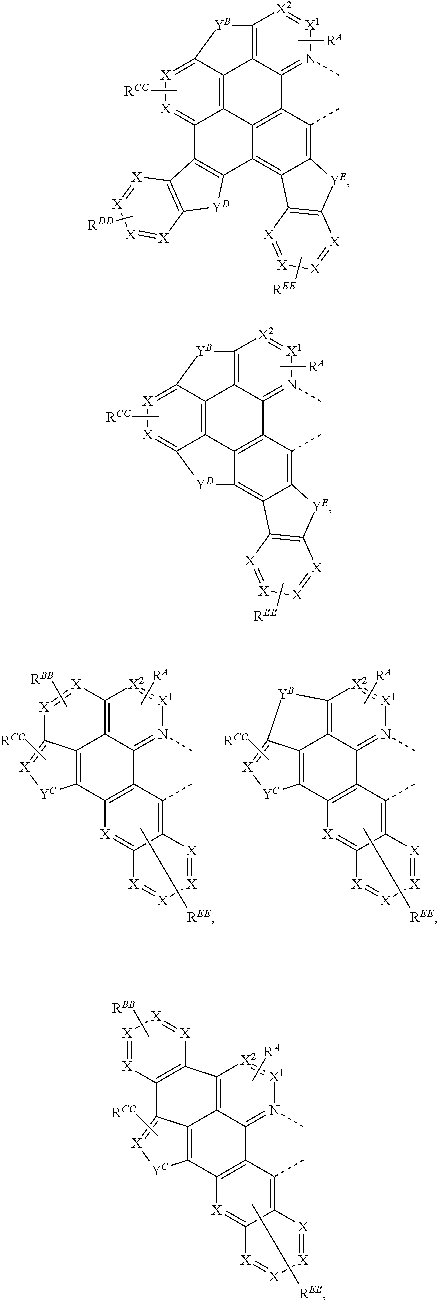

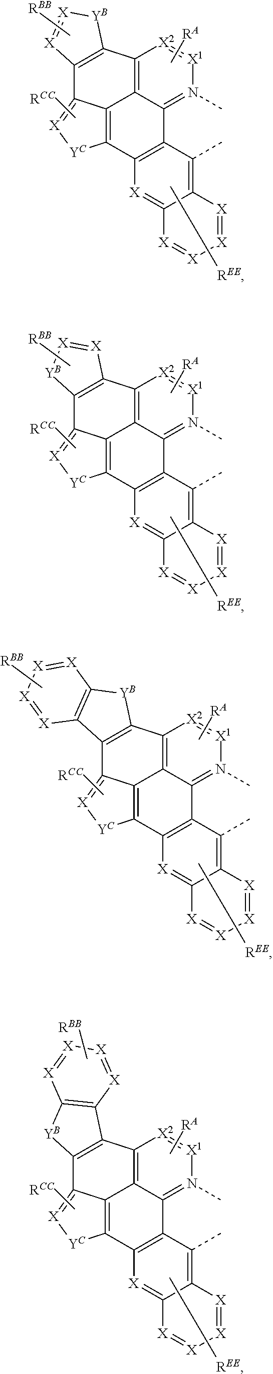

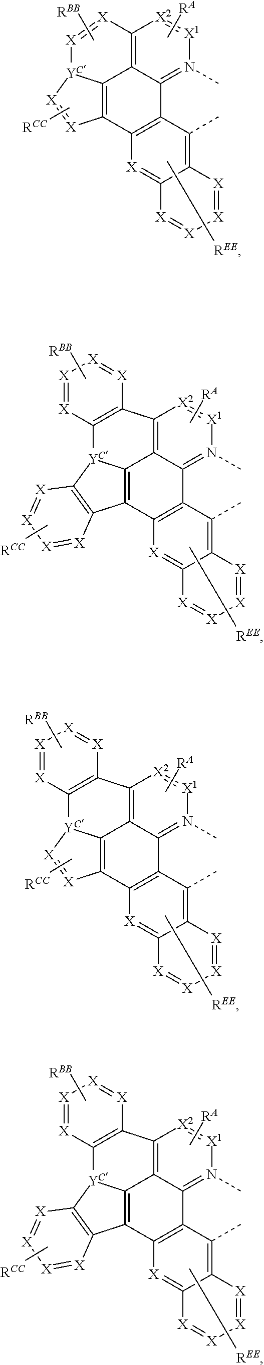

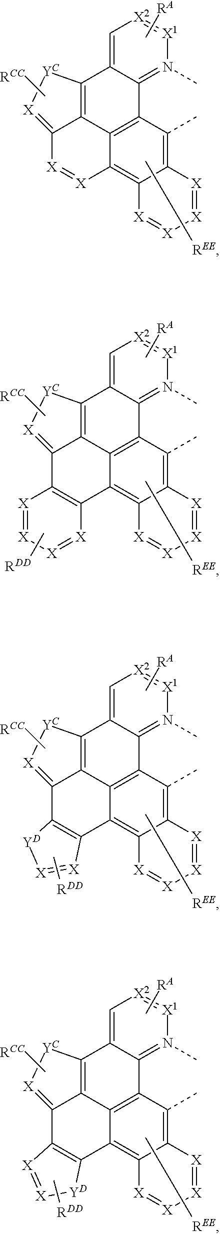

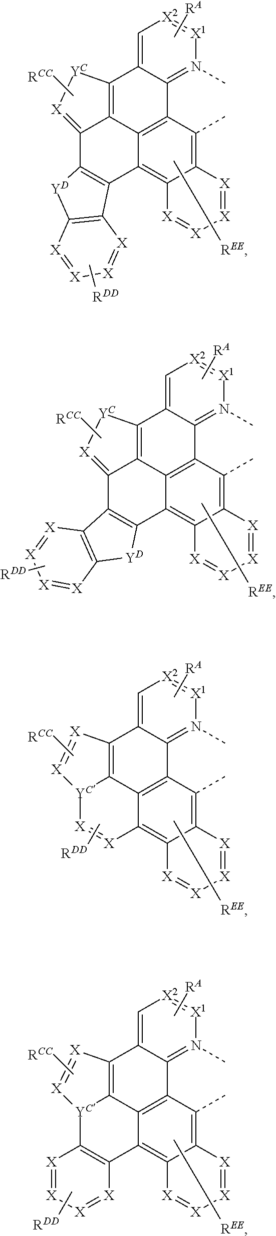

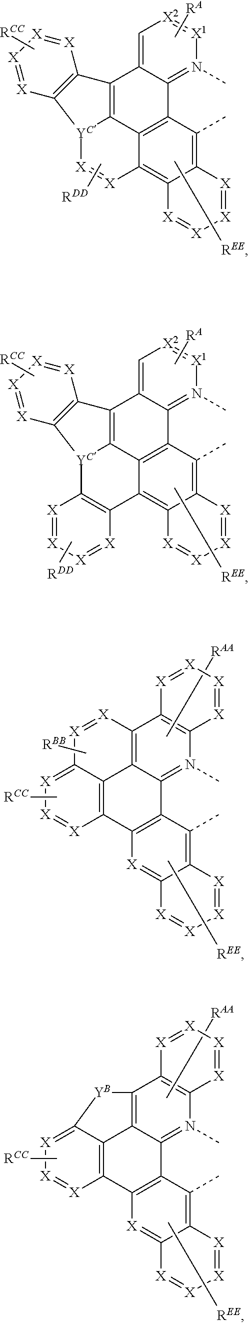

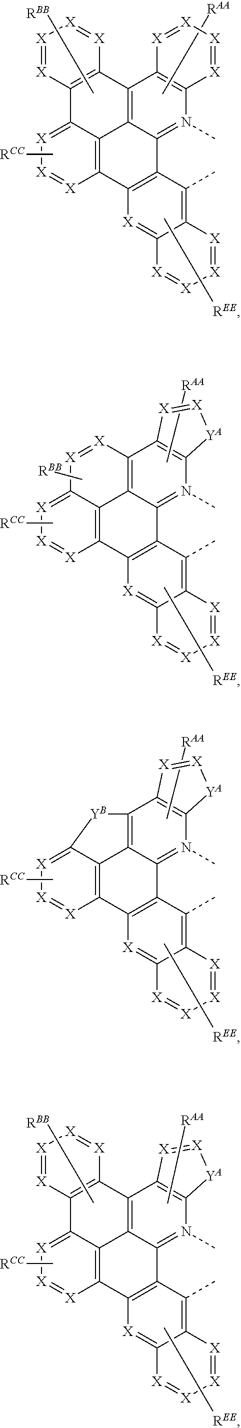

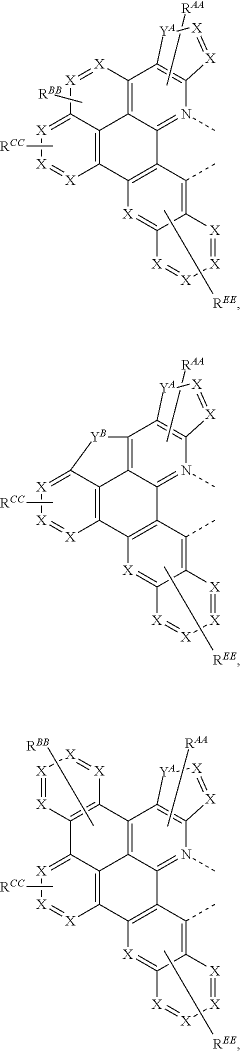

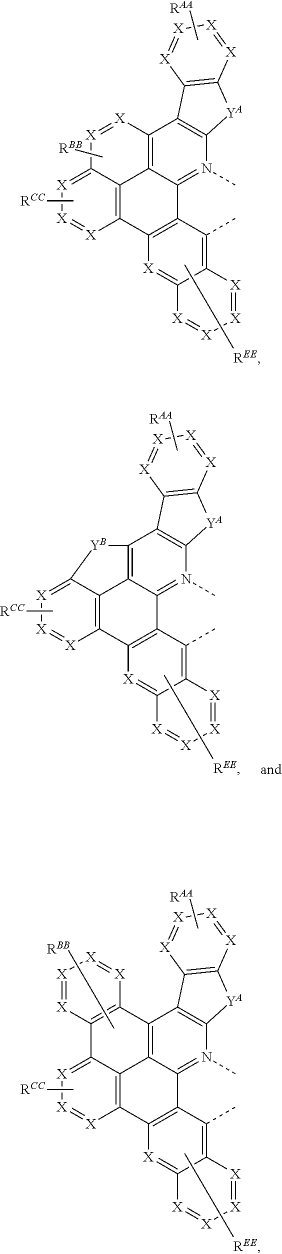

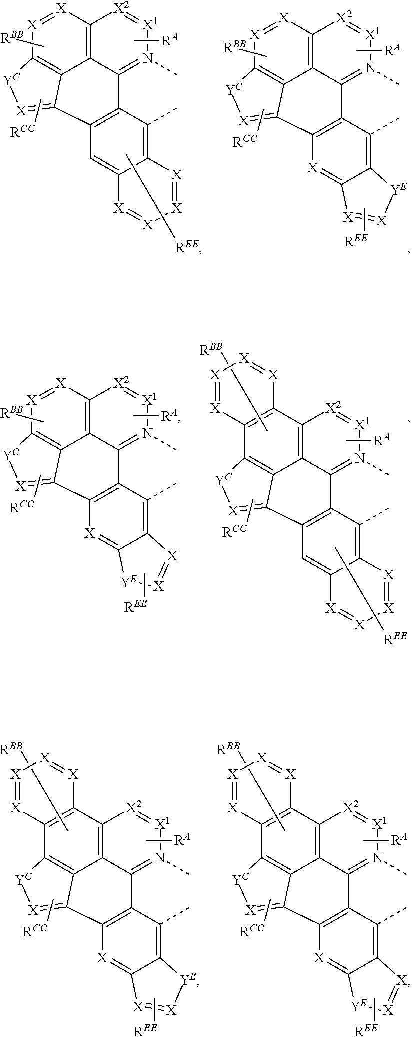

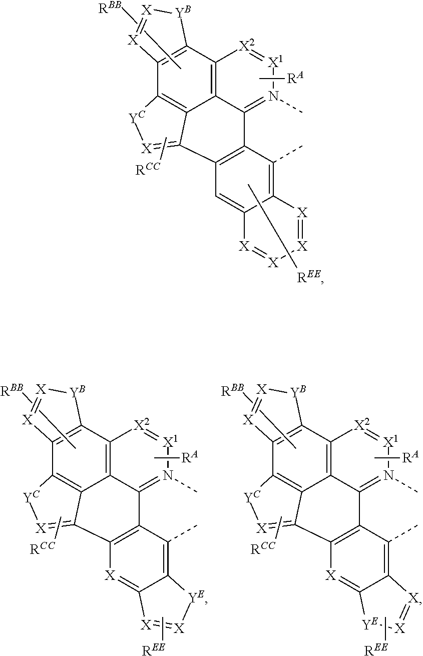

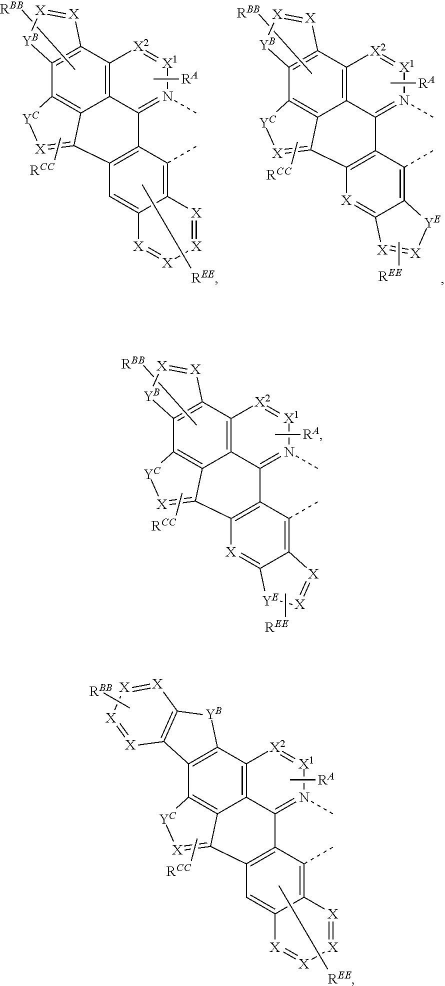

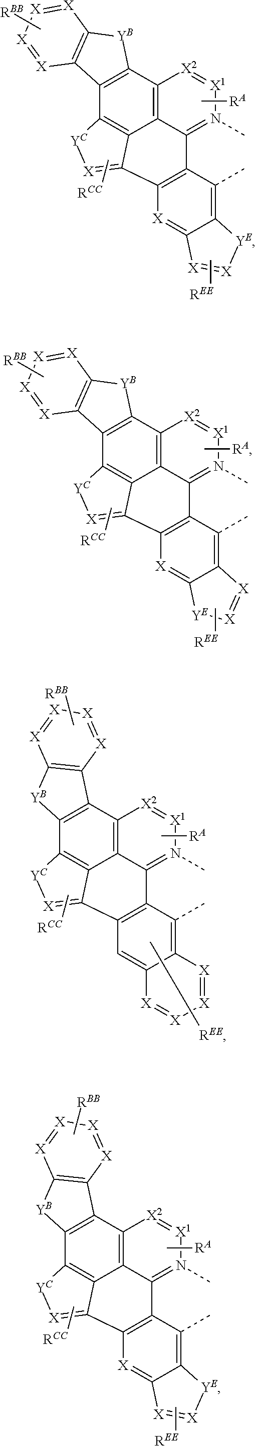

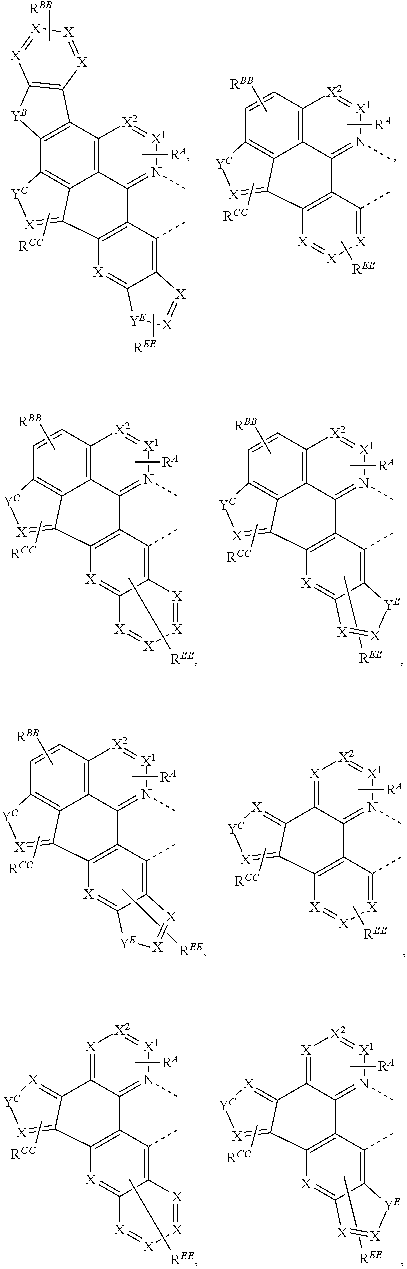

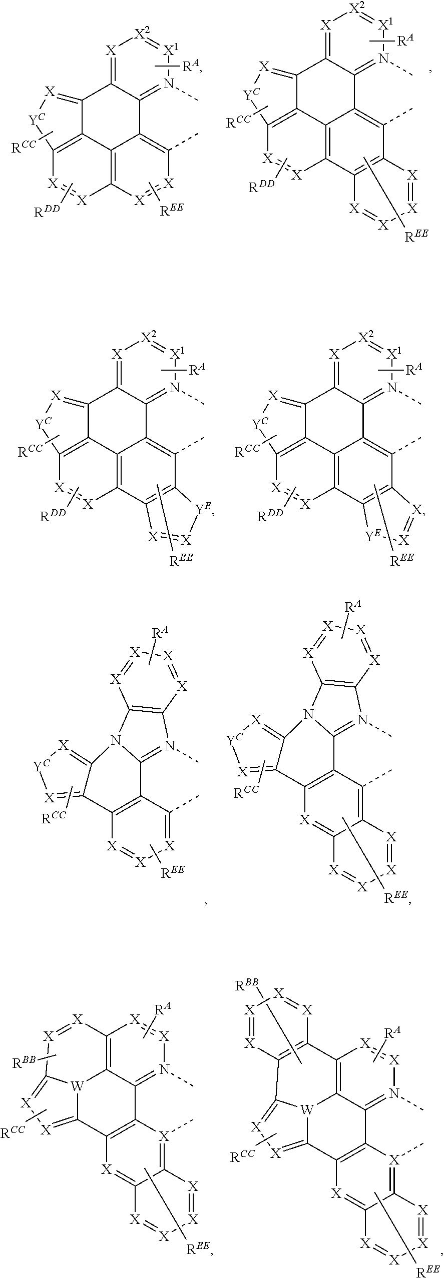

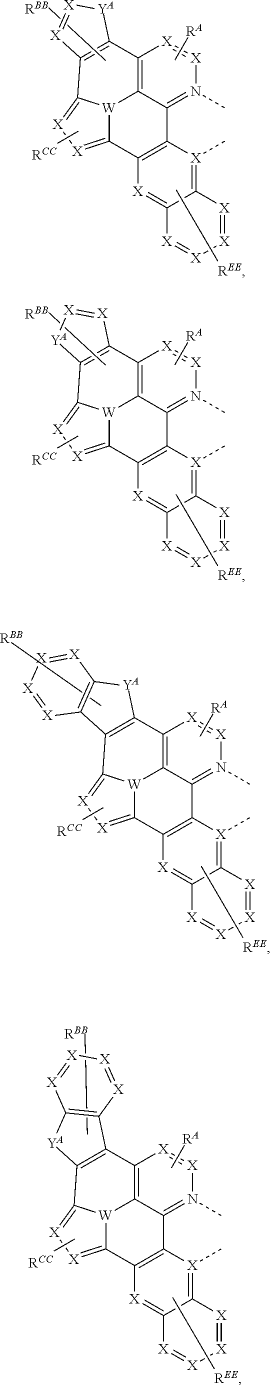

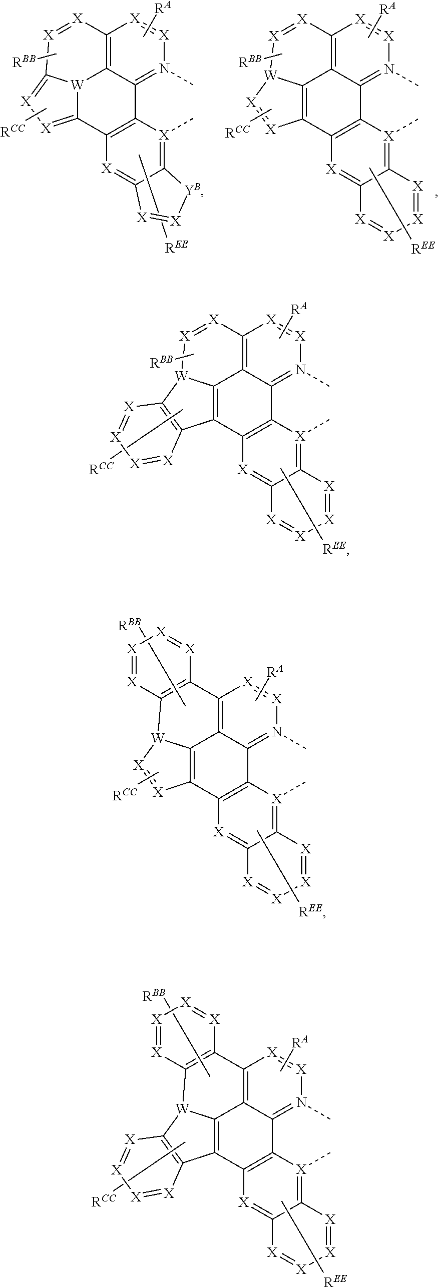

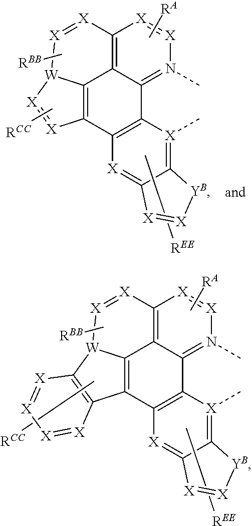

wherein:
for each occurrence, X is independently C or N;
each of Y^{A}, Y^{B}, Y^{C}, Y^{D}, and Y^{E} is independently selected from the group consisting of BR, BRR′, NR, PR, P(O)R, O, S, Se, C═O, C═S, C═Se, C═NR, C═CRR′, S═O, SO₂, CR, CRR′, SiRR′ and GeRR′;
Y^{C′} is selected from the group consisting of B, BR, CR, N, P, SiR, and GeR;
each of R^{AA}, R^{BB}, R^{CC}, R^{DD}, and R^{EE} independently represents mono to the maximum allowable substitution, or no substitution;
each R, R′, R^{AA}, R^{BB}, R^{CC}, R^{DD}, and R^{EE} is independently hydrogen or a substituent selected from the group consisting of the General Substituents defined herein;
W is B, P, or N; and
any two substituents may be optionally joined or fused to form a ring.

In some embodiments for the structures of LIST 1, at least one of R^{A}, R^{AA}, R^{BB}, R^{CC}, R^{DD}, or R^{EE} is partially or fully deuterated. In some embodiments, at least one R^{A} is partially or fully deuterated. In some embodiments, at least one R^{AA} is partially or fully deuterated. In some embodiments, at least one R^{BB} is partially or fully deuterated. In some embodiments, at least one R^{CC} is partially or fully deuterated. In some embodiments, at least one R^{DD} is partially or fully deuterated. In some embodiments, at least one R^{EE} is partially or fully deuterated.

In some embodiment for the structures of LIST 1, at least one R^{A}, R^{AA}, R^{BB}, R^{CC}, R^{DD}, or R^{EE} is or comprises an electron-withdrawing group selected from the EWG1 LIST as defined herein. In some embodiment for the structures of LIST 1, at least one R^{A}, R^{AA}, R^{BB}, R^{CC}, R^{DD}, or R^{EE} is or comprises an electron-withdrawing group selected from the EWG2 LIST as defined herein. In some embodiment for the structures of LIST 1, at least one R^{A}, R^{AA}, R^{BB}, R^{CC}, R^{DD}, or R^{EE} is or comprises an electron-withdrawing group selected from the EWG3 LIST as defined herein. In some embodiment for the structures of LIST 1, at least one R^{A}, R^{AA}, R^{BB}, R^{CC}, R^{DD}, or R^{EE} is or comprises an electron-withdrawing group selected from the EWG4 LIST as defined herein. In some embodiment for the structures of LIST 1, at least one R^{A}, R^{AA}, R^{BB}, R^{CC}, R^{DD}, or R^{EE} is or comprises an electron-withdrawing group selected from the Pi-EWG LIST as defined herein.

In some embodiment for the structures of LIST 1, at least one R^{A} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 1, at least one R^{AA} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 1, at least one R^{BB} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 1, at least one R^{CC} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 1, at least one R^{DD} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 1, at least one R^{EE} is or comprises an electron-withdrawing group selected from the EWG1 LIST, the EWG2 LIST, the EWG3 LIST, the EWG4 LIST, or the Pi-EWG LIST defined herein.

In some embodiments, the ligand L_{A} is selected from the group consisting of the structures of the following LIST 2:

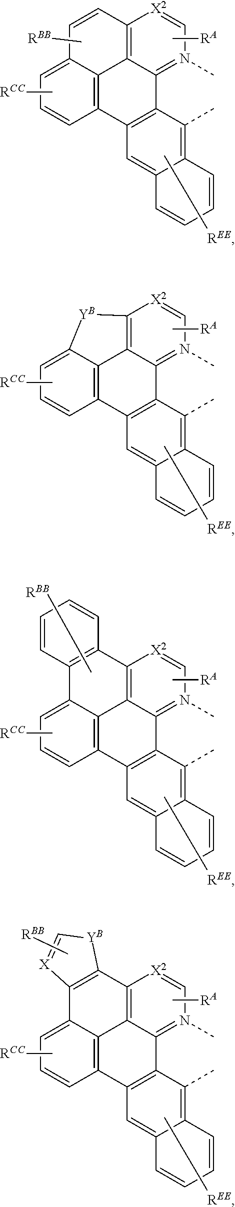

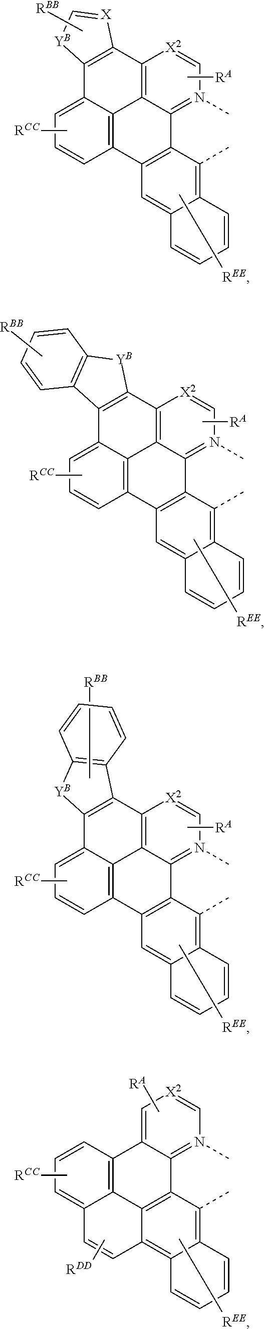

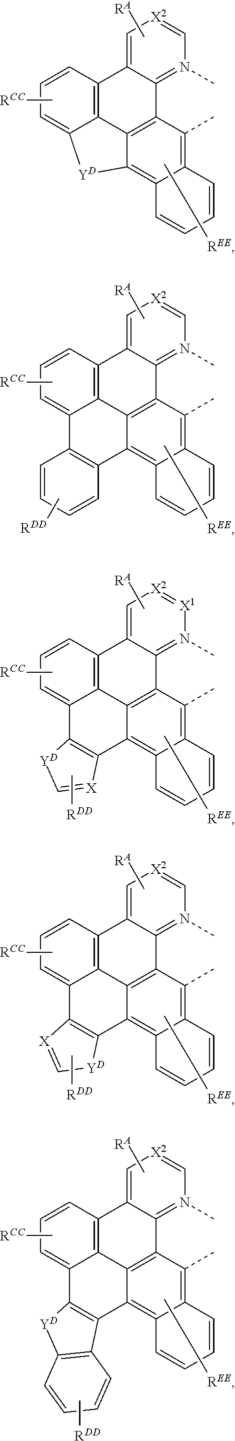

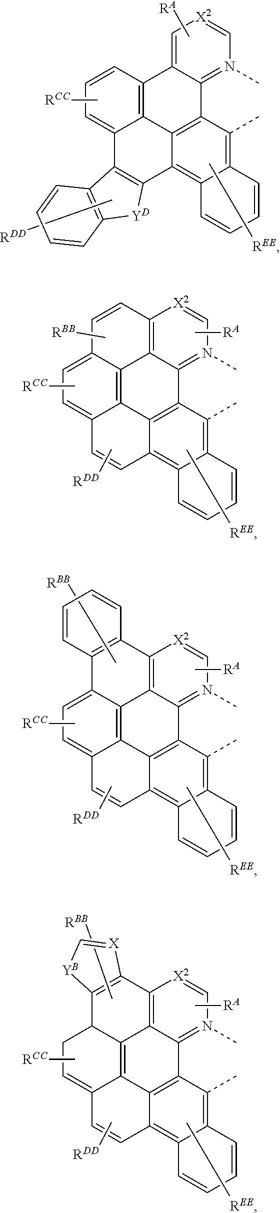

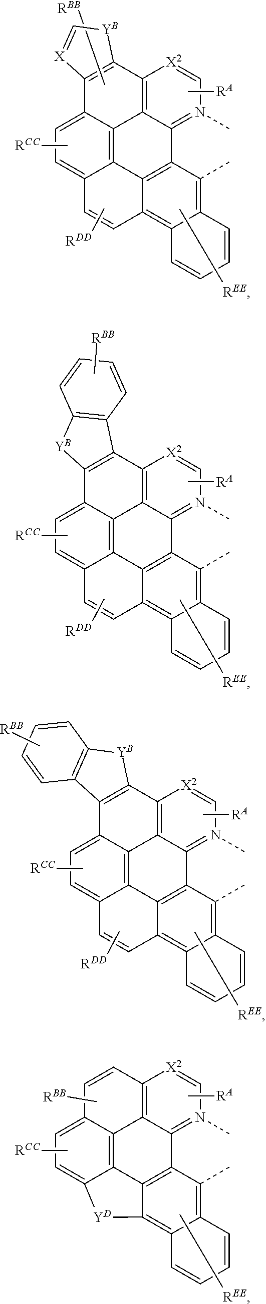

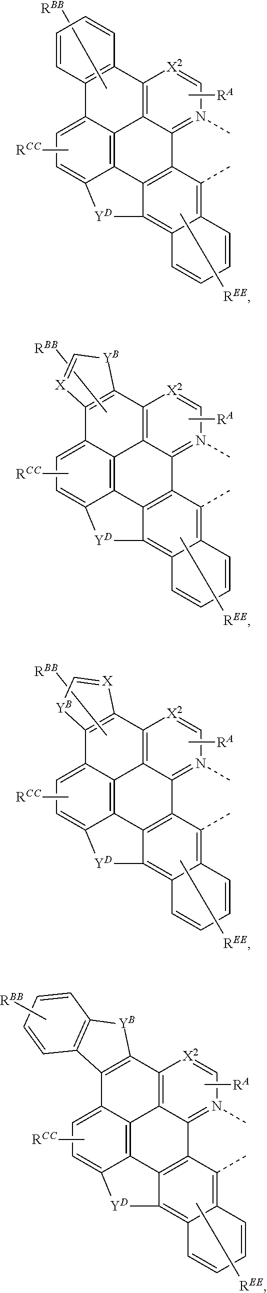

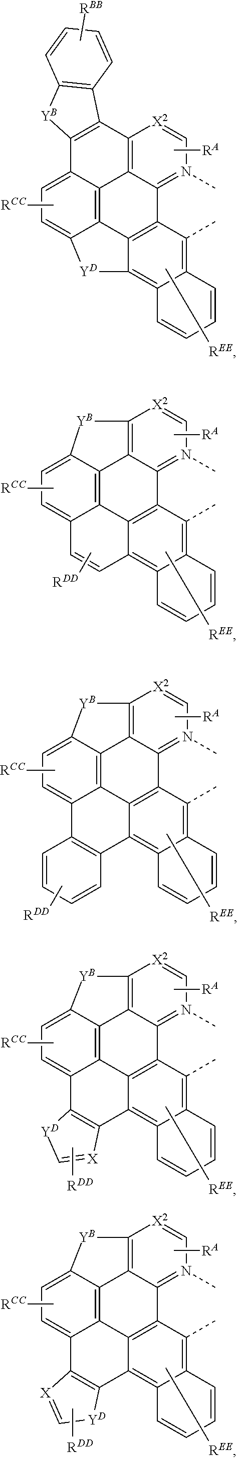

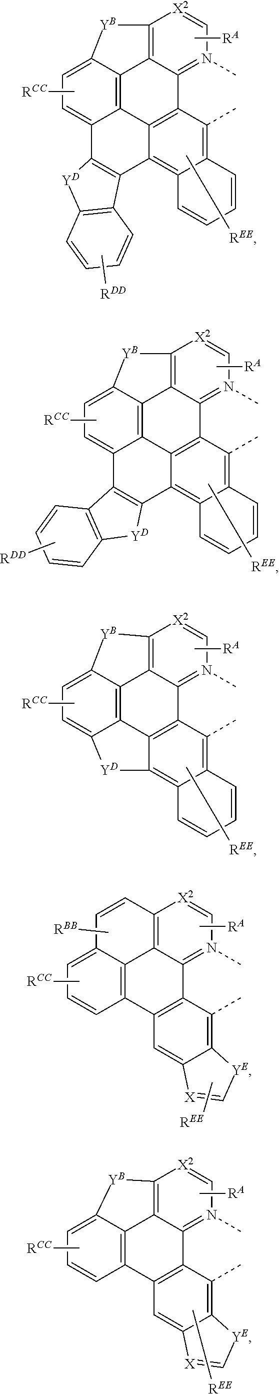

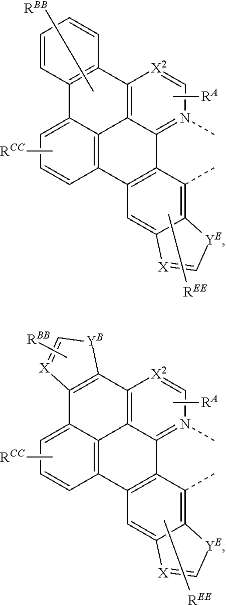

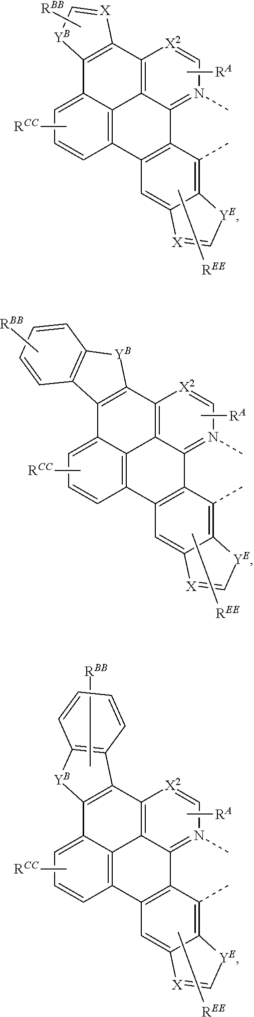

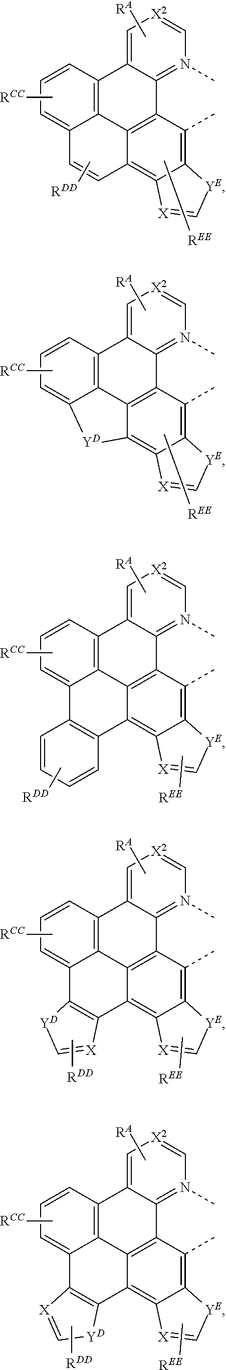

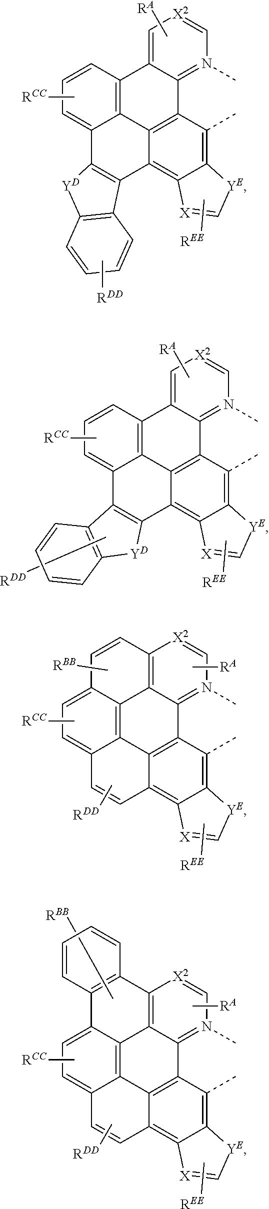

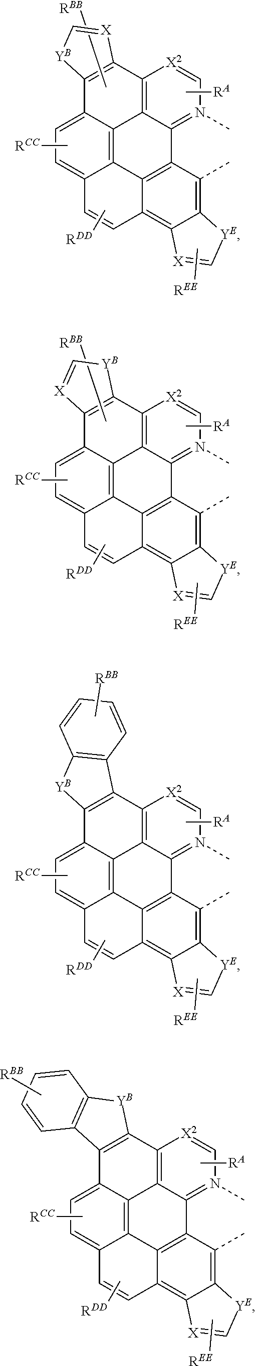

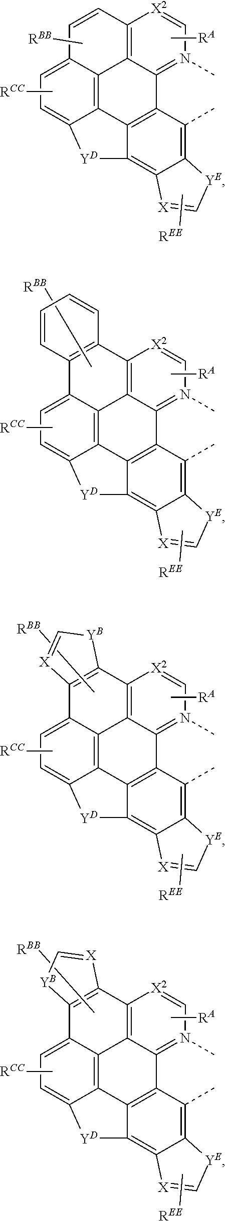

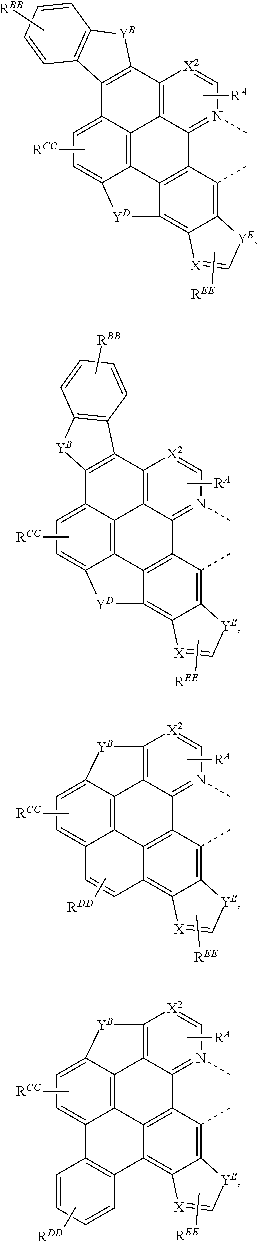

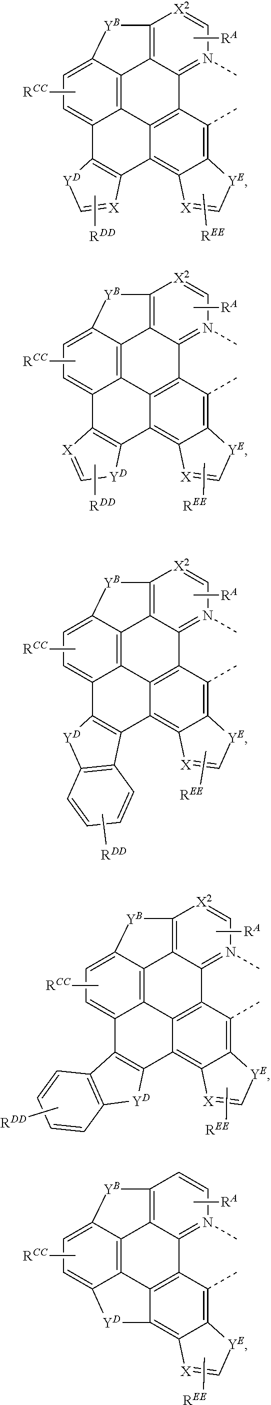

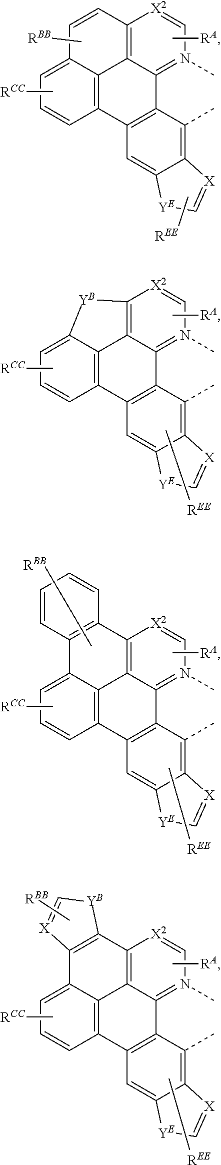

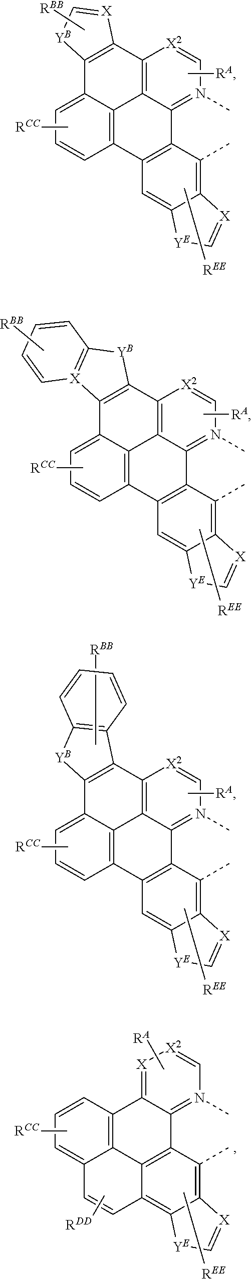

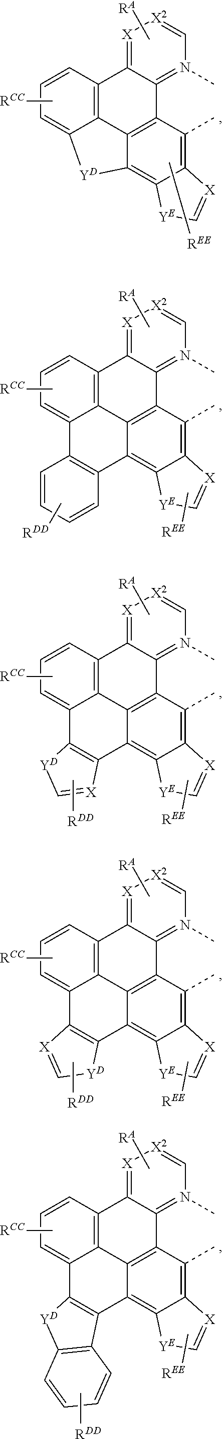

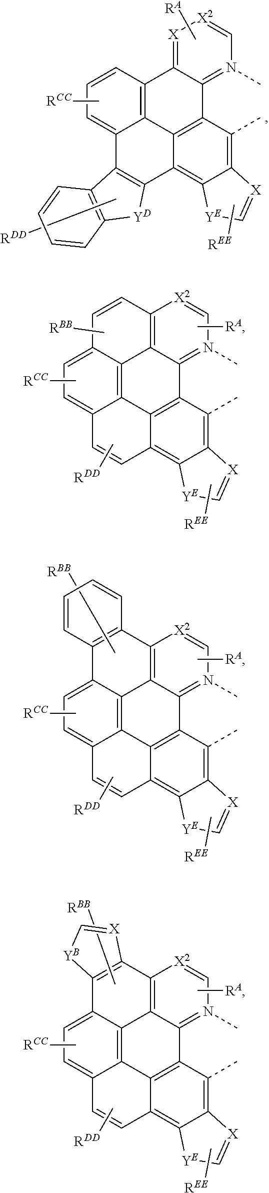

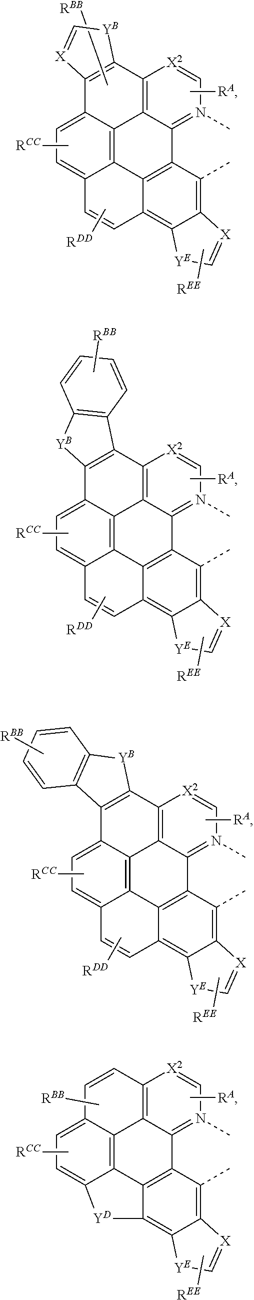

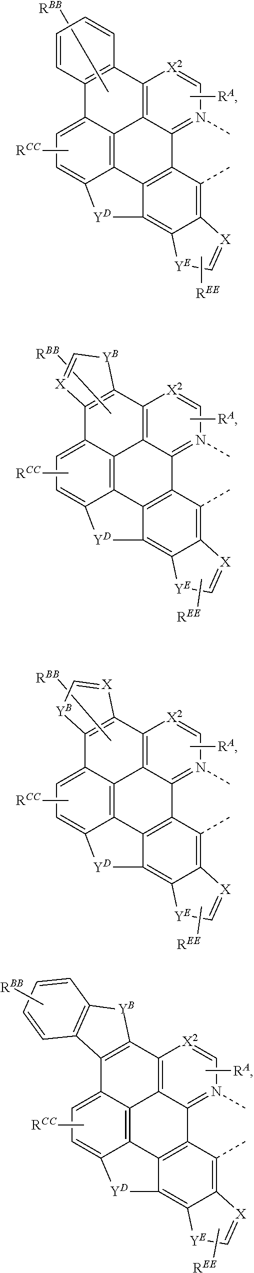

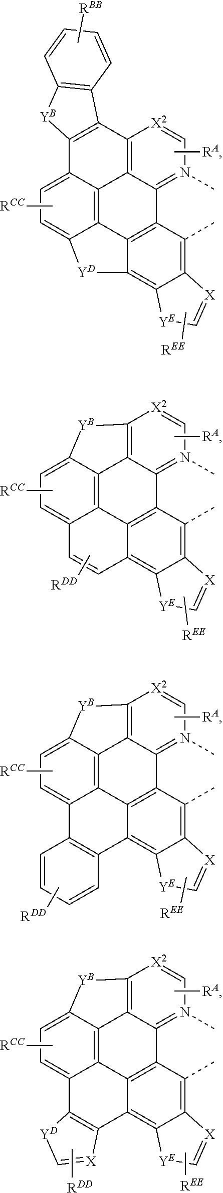

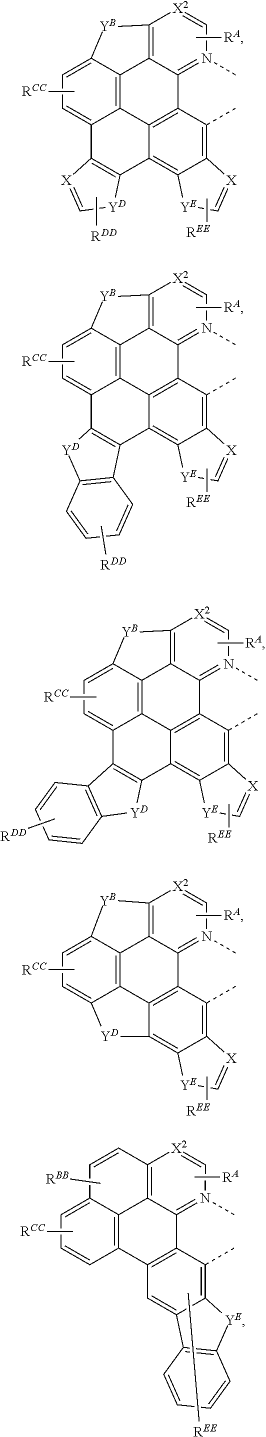

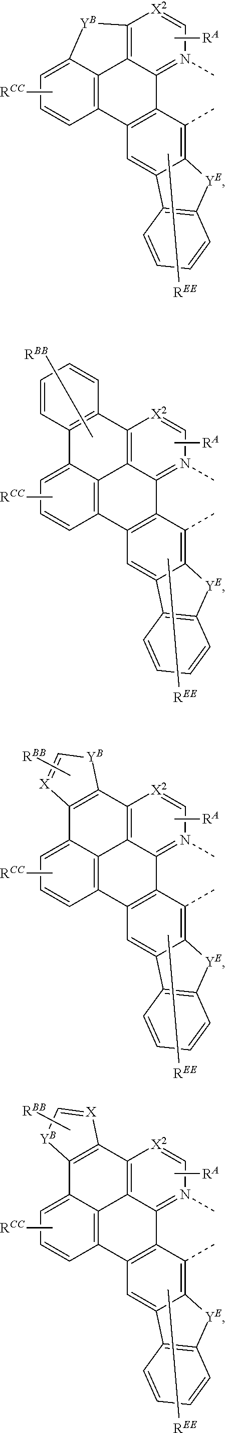

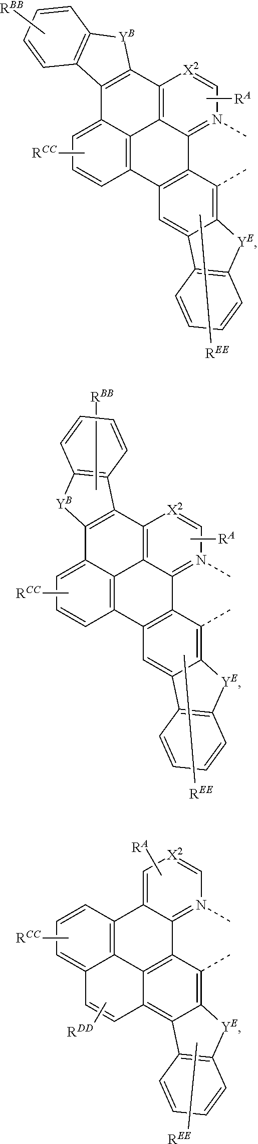

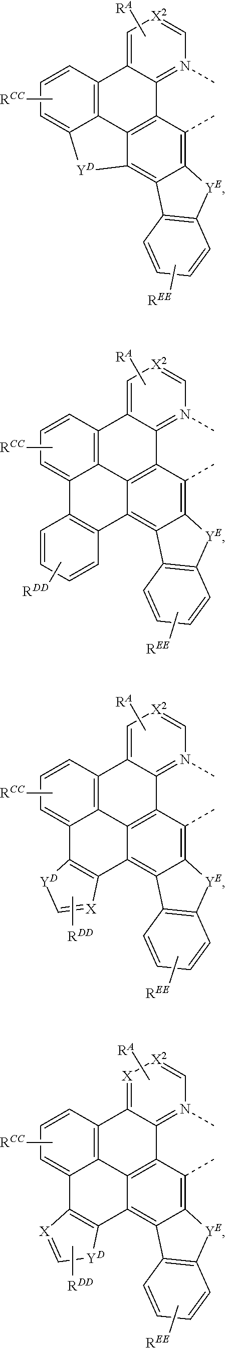

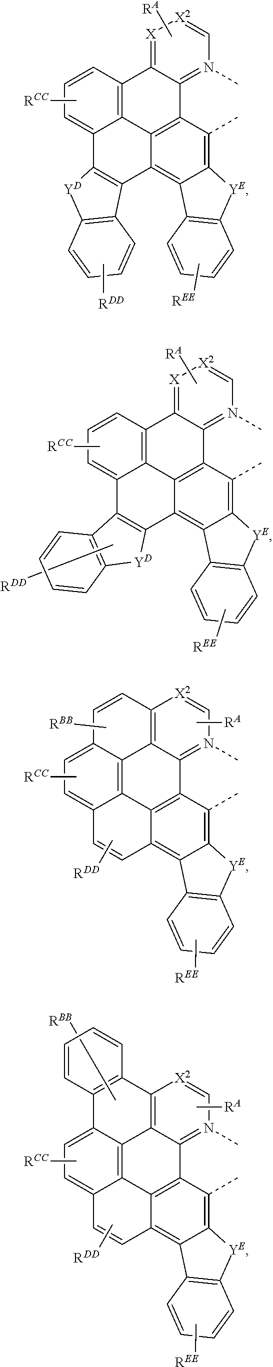

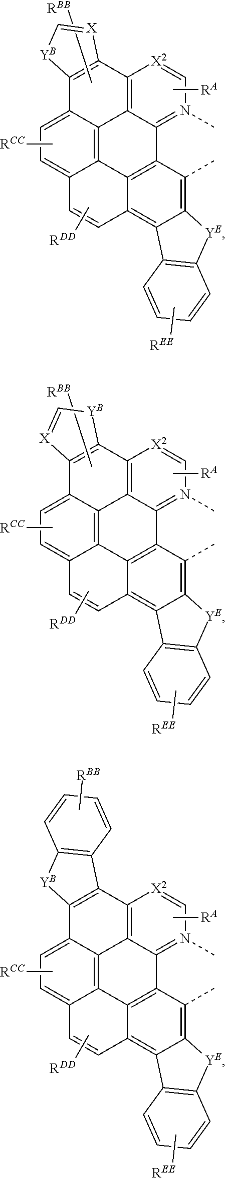

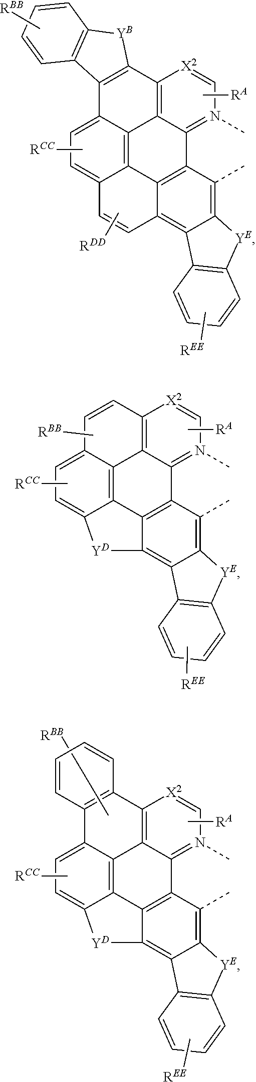

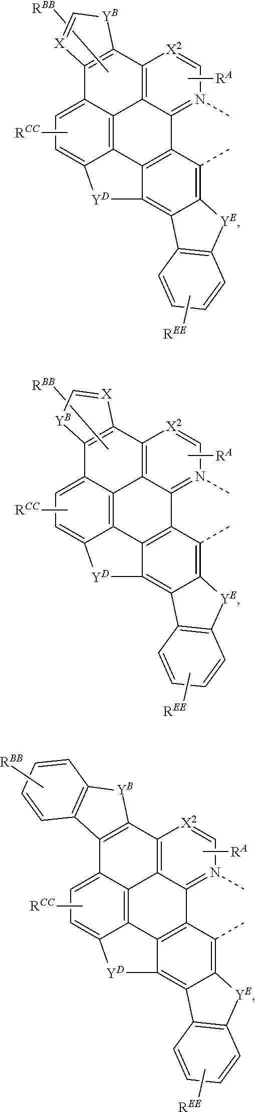

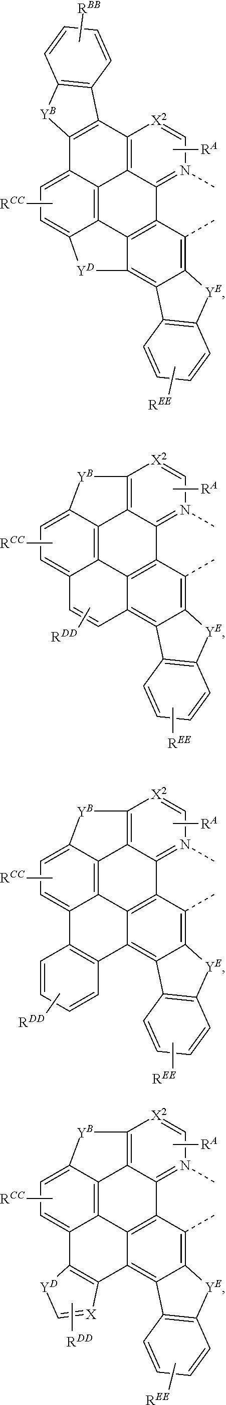

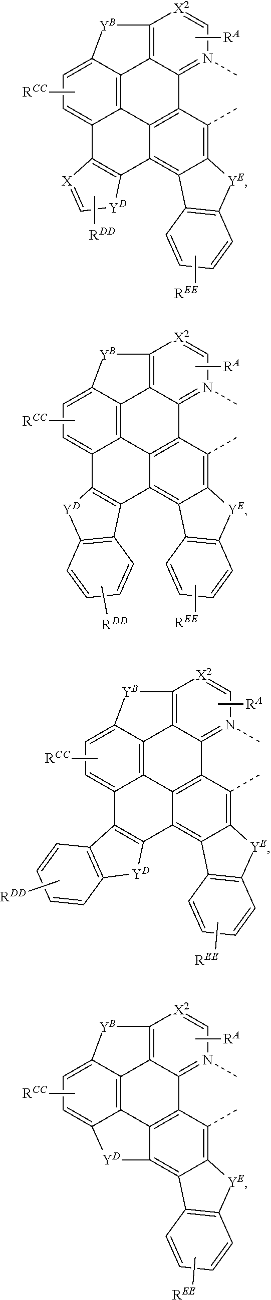

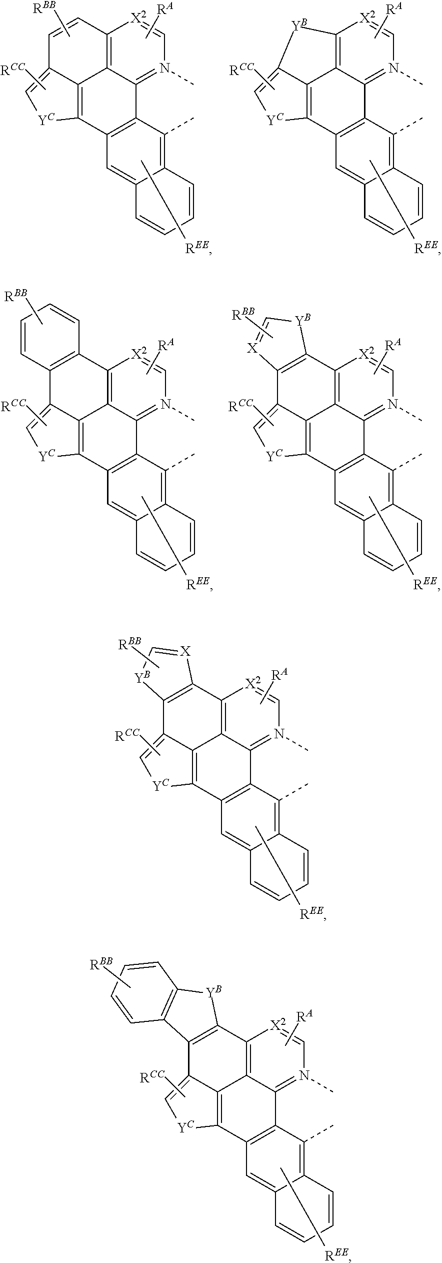

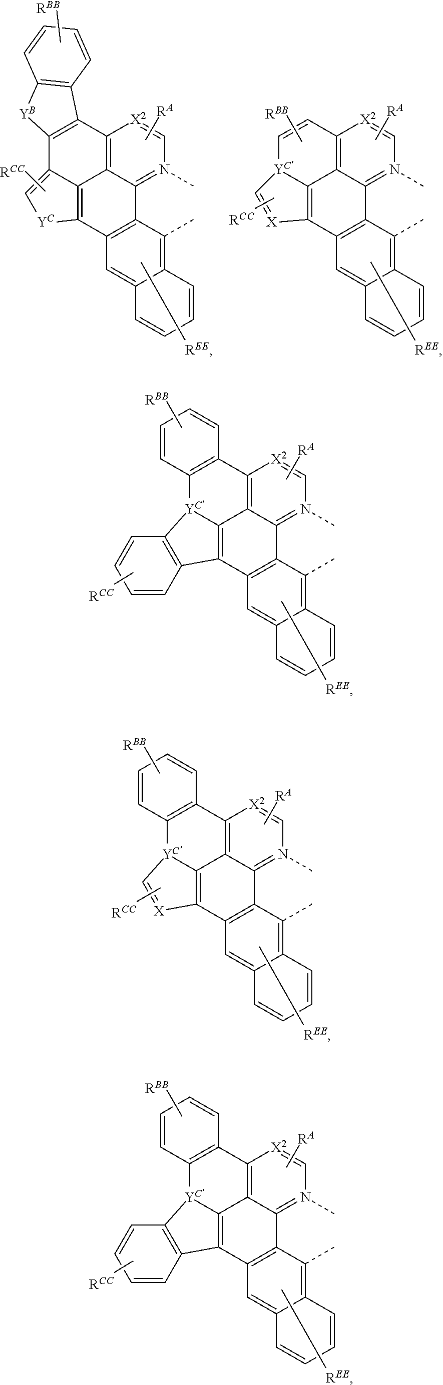

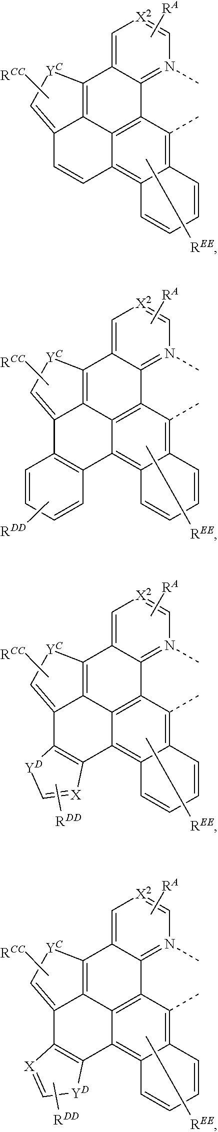

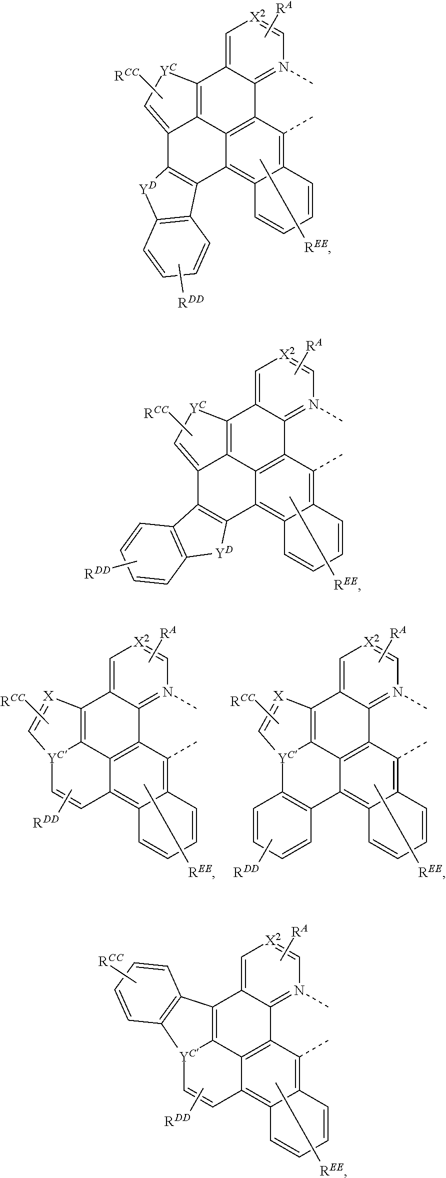

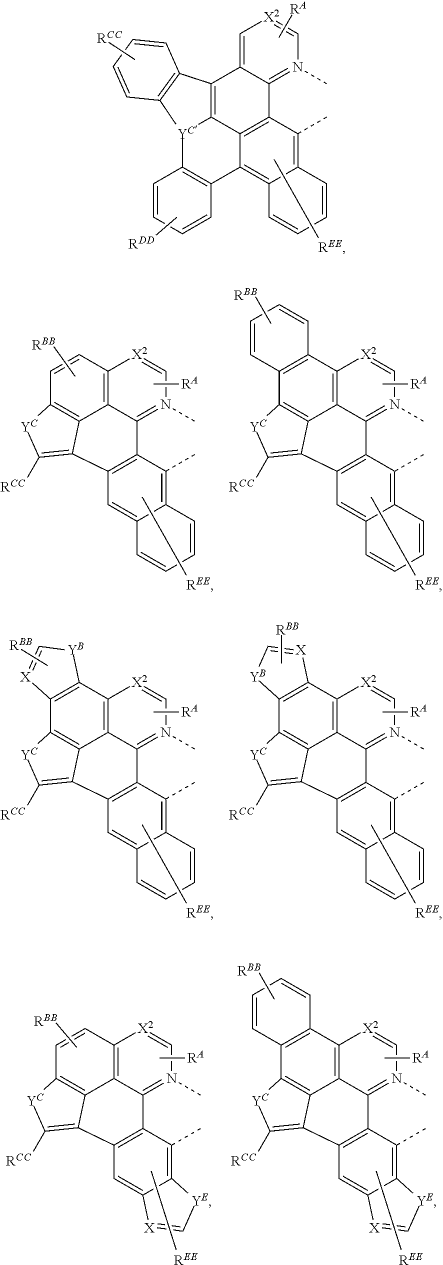

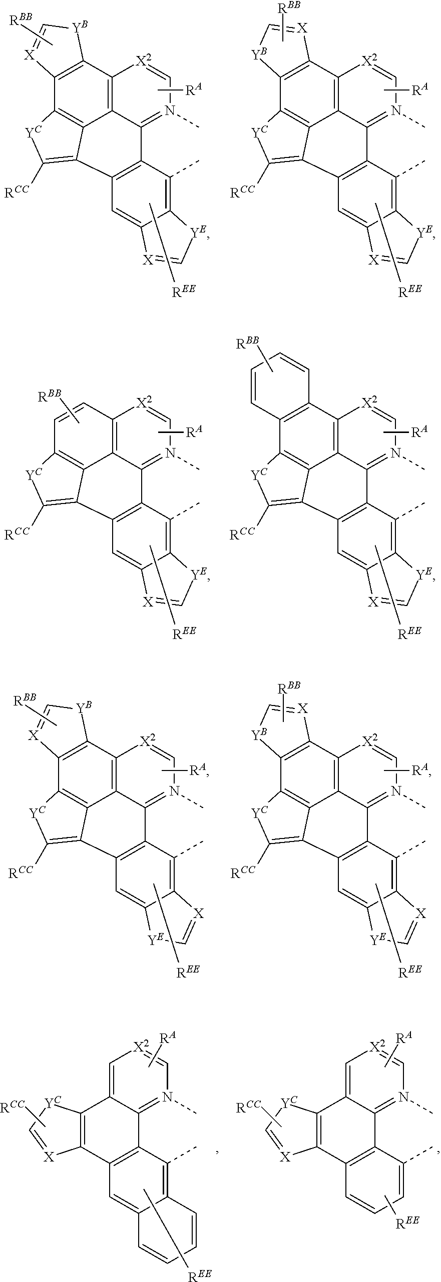

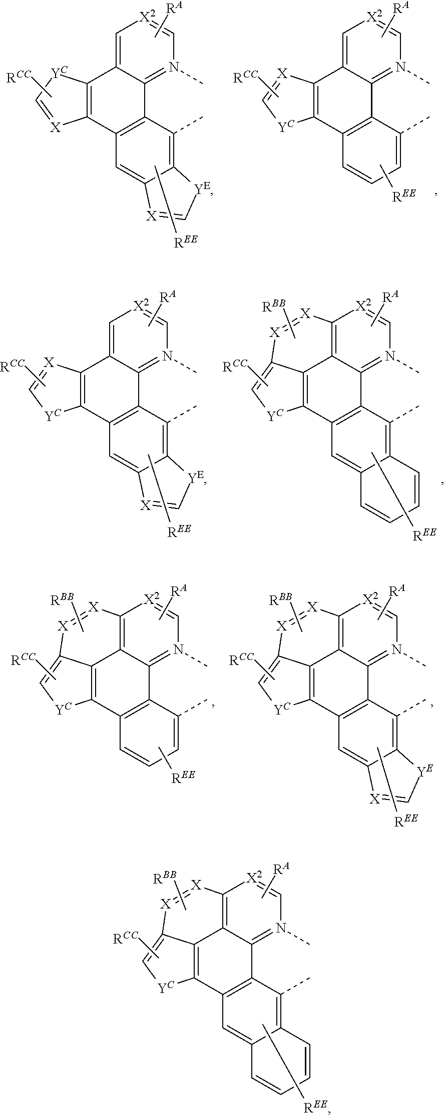

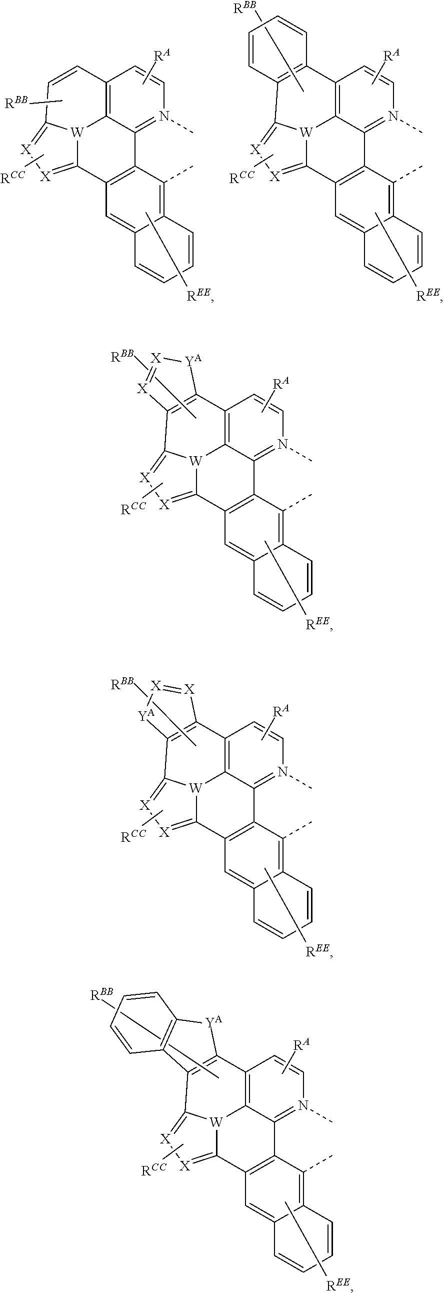

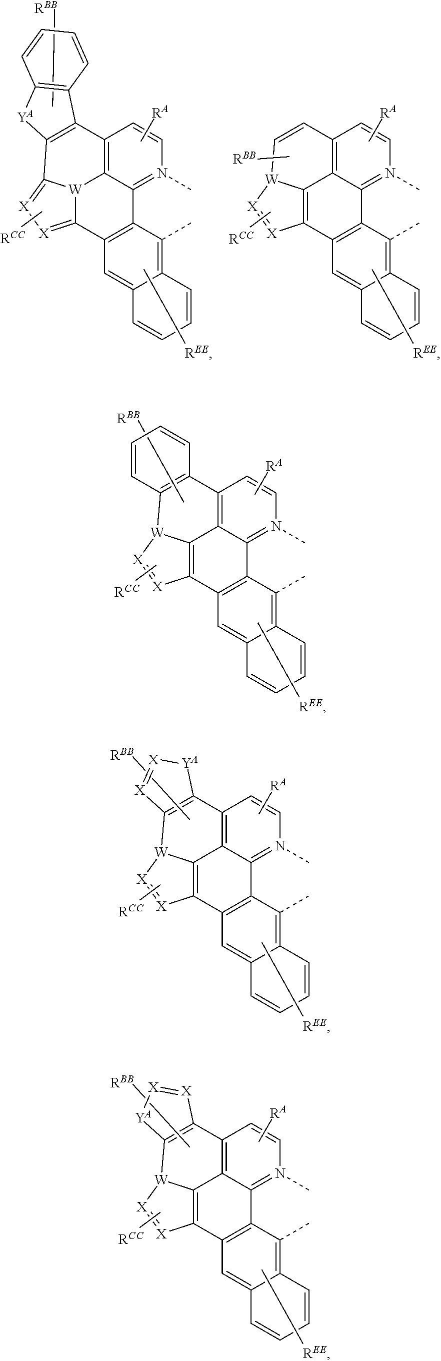

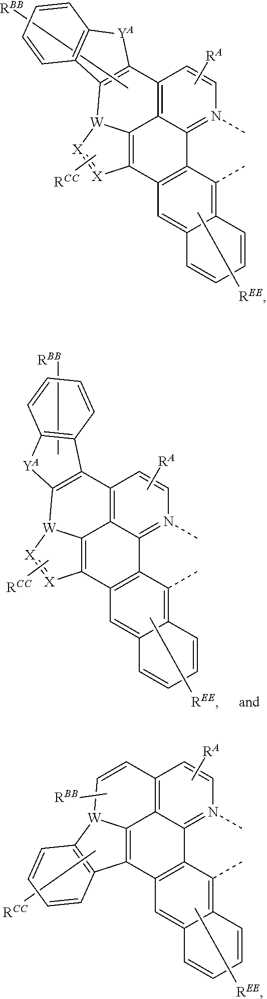

wherein:
   each of Y^{B}, Y^{C}, Y^{D}, and Y^{E} is independently selected from the group consisting of BR, BRR′, NR, PR, P(O)R, O, S, Se, C═O, C═S, C═Se, C═NR, C═CRR′, S═O, SO₂, CR, CRR′, SiRR′ and GeRR′;
   Y^{C′} is selected from the group consisting of B, BR, CR, N, P, SiR, and GeR;
   each of R^{BB}, R^{CC}, R^{DD}, and R^{EE} independently represents mono to the maximum allowable substitution, or no substitution;
   each R, R′, R^{BB}, R^{CC}, R^{DD}, and R^{EE} is independently hydrogen or a substituent selected from the group consisting of the General Substituents defined herein;
   the remaining variables are the same as previously defined; and
   any two substituents may be optionally fused or joined to form a ring.

In some embodiments for the structures of LIST 2, at least one of R^{A}, R^{AA}, R^{BB}, R^{CC}, R^{DD}, or R^{EE} is partially or fully deuterated. In some embodiments, at least one R^{A} is partially or fully deuterated. In some embodiments, at least one R^{AA} is partially or fully deuterated. In some embodiments, at least one R^{BB} is partially or fully deuterated. In some embodiments, at least one R^{CC} is partially or fully deuterated. In some embodiments, at least one R^{DD} is partially or fully deuterated. In some embodiments, at least one R^{EE} is partially or fully deuterated.

In some embodiment for the structures of LIST 2, at least one R^{A}, R^{AA}, R^{BB}, R^{CC}, R^{DD}, or R^{EE} is or comprises an electron-withdrawing group selected from the EWG1 LIST as defined herein. In some embodiment for the structures of LIST 2, at least one R^{A}, R^{AA}, R^{BB}, R^{CC}, R^{DD}, or R^{EE} is or comprises an electron-withdrawing group selected from the EWG2 LIST as defined herein. In some embodiment for the structures of LIST 2, at least one R^{A}, R^{AA}, R^{BB}, R^{CC}, R^{DD}, or R^{EE} is or comprises an electron-withdrawing group selected from the EWG3 LIST as defined herein. In some embodiment for the structures of LIST 2, at least one R^{A}, R^{AA}, R^{BB}, R^{CC}, R^{DD}, or R^{EE} is or comprises an electron-withdrawing group selected from the EWG4 LIST as defined herein. In some embodiment for the structures of LIST 2, at least one R^{A}, R^{AA}, R^{BB}, R^{CC}, R^{DD}, or R^{EE} is or comprises an electron-withdrawing group selected from the Pi-EWG LIST as defined herein.

In some embodiment for the structures of LIST 2, at least one R^{A} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 2, at least one R^{AA} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 2, at least one R^{BB} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 2, at least one R^{CC} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 2, at least one R^{DD} is or comprises an electron-withdrawing group selected from the EWG1 LIST, the EWG2 LIST, the EWG3 LIST, the EWG4 LIST, or the Pi-EWG LIST defined herein. In some embodiment for the structures of LIST 2, at least one R^{EE} is or comprises an electron-withdrawing group selected from the EWG1 LIST, the EWG2 LIST, the EWG3 LIST, the EWG4 LIST, or the Pi-EWG LIST defined herein.

In some embodiments, the ligand L_{A} is selected from L_{Ai}(R^{EA})(R^{EB})(R^{EC}) (R^{ED})(R^{EE})(R^{EF})(R^{EG}), wherein i is an integer from 1 to 161, and each of R^{EA}, R^{EB}, R^{EC}, R^{ED}, R^{EE}, R^{EF}, and R^{EG} is independently selected from the group consisting of R₁ to R₂₁₁; wherein each of L_{A1}(R₁)(R₁)(R₁)(R₁)(R₁)(R₁)(R₁) to L_{A161}(R₂₁₁)(R₂₁₁)(R₂₁₁)(R₂₁₁)(R₂₁₁)(R₂₁₁)(R₂₁₁) is defined in the following LIST 3:

| L_{A} | Structure of L_{A} |
|---|---|
| L_{A1}(R^{EA})(R^{EB})(R^{EC})(R^{ED})(R^{EE}) (R^{EF})(R^{EG}), wherein L_{A1}(R₁)(R₁)(R₁)(R₁)(R₁)(R₁) (R₁) to L_{A1}(R₂₁₁)(R₂₁₁)(R₂₁₁)(R₂₁₁)(R₂₁₁) (R₂₁₁)(R₂₁₁) have the structure | 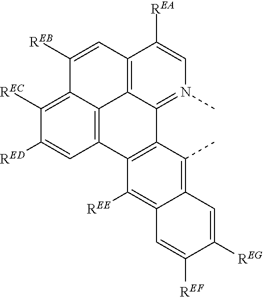 |
| L_{A2}(R^{EA})(R^{EB})(R^{EC})(R^{ED)}(R^{EE}) (R^{EF})(R^{EG}), wherein L_{A2}(R₁)(R₁)(R₁)(R₁)(R₁)(R₁) (R₁) to L_{A2}(R₂₁₁)(R₂₁₁)(R₂₁₁)(R₂₁₁)(R₂₁₁) (R₂₁₁)(R₂₁₁) have the structure | 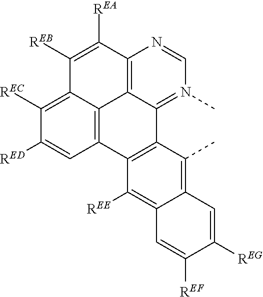 |
| L_{A3}(R^{EA})(R^{EB})(R^{EC})(R^{ED})(R^{EE}) (R^{EF})(R^{EG}), wherein L_{A3}(R₁)(R₁)(R₁)(R₁)(R₁)(R₁) (R₁) to L_{A3}(R₂₁₁)(R₂₁₁)(R₂₁₁)(R₂₁₁)(R₂₁₁) (R₂₁₁)(R₂₁₁) have the structure | 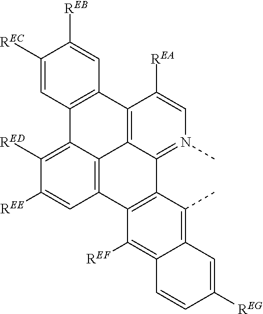 |
| L_{A4}(R^{EA})(R^{EB})(R^{EC})(R^{ED})(R^{EE}) (R^{EF})(R^{EG}), wherein L_{A4}(R₁)(R₁)(R₁)(R₁)(R₁)(R₁) (R₁) to L_{A4}(R₂₁₁)(R₂₁₁)(R₂₁₁)(R₂₁₁)(R₂₁₁) (R₂₁₁)(R₂₁₁) have the structure | 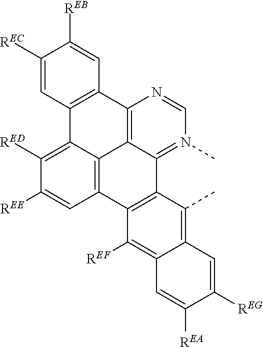 |
| L_{A5}(R^{EA})(R^{EB})(R^{EC})(R^{ED}) (R^{EE})(R^{EF})(R^{EG}), wherein L_{A5}(R₁)(R₁)(R₁)(R₁)(R₁)(R₁) (R₁) to L_{A5}(R₂₁₁)(R₂₁₁)(R₂₁₁)(R₂₁₁)(R₂₁₁) (R₂₁₁)(R₂₁₁) have the structure | 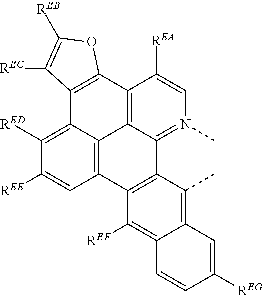 |
| L_{A6}(R^{EA})(R^{EB})(R^{EC})(R^{ED}) (R^{EE})(R^{EF})(R^{EG}), wherein L_{A6}(R₁)(R₁)(R₁)(R₁)(R₁)(R₁) (R₁) to L_{A6}(R₂₁₁)(R₂₁₁)(R₂₁₁)(R₂₁₁)(R₂₁₁) (R₂₁₁)(R₂₁₁) have the structure | 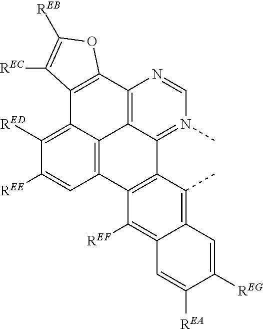 |
| L_{A7}(R^{EA})(R^{EB})(R^{EC})(R^{ED}) (R^{EE})(R^{EF})(R^{EG}), wherein L_{A7}(R₁)(R₁)(R₁)(R₁)(R₁)(R₁) (R₁) to L_{A7}(R₂₁₁)(R₂₁₁)(R₂₁₁)(R₂₁₁)(R₂₁₁) (R₂₁₁)(R₂₁₁) have the structure | 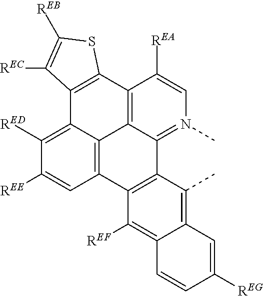 |
| L_{A8}(R^{EA})(R^{EB})(R^{EC})(R^{ED}) (R^{EE})(R^{EF})(R^{EG}), wherein L_{A8}(R₁)(R₁)(R₁)(R₁)(R1)(R₁) (R₁) to L_{A8}(R₂₁₁)(R₂₁₁)(R₂₁₁)(R₂₁₁)(R₂₁₁) (R₂₁₁)(R₂₁₁) have the structure | 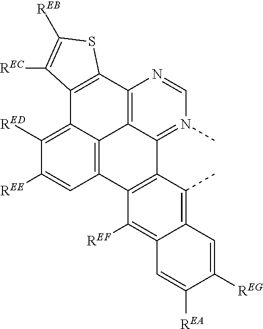 |
| L_{A9}(R^{EA})(R^{EB})(R^{EC})(R^{ED}) (R^{EE})(R^{EF})(R^{EG}), wherein L_{A9}(R₁)(R₁)(R₁)(R₁)(R₁)(R₁) (R₁) to L_{A9}(R₂₁₁)(R₂₁₁)(R₂₁₁)(R₂₁₁)(R₂₁₁) (R₂₁₁)(R₂₁₁) have the structure | 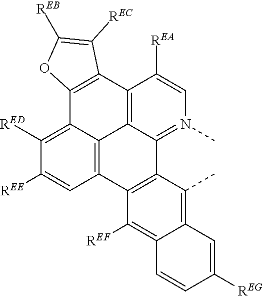 |
| L_{A10}(R^{EA})(R^{EB})(R^{EC})(R^{ED}) (R^{EE})(R^{EF})(R^{EG}), wherein L_{A10}(R₁)(R₁)(R₁)(R₁)(R₁)(R₁) (R₁) to L_{A10}(R₂₁₁)(R₂₁₁)(R₂₁₁)(R₂₁₁) (R₂₁₁)(R₂₁₁)(R₂₁₁) have the stucture | 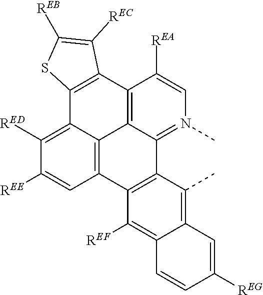 |
| L_{A11}(R^{EA})(R^{EB})(R^{EC})(R^{ED}) (R^{EE})(R^{EF})(R^{EG}), wherein L_{A11}(R₁)(R₁)(R₁)(R₁)(R₁)(R₁) (R₁) to L_{A11}(R₂₁₁)(R₂₁₁)(R₂₁₁)(R₂₁₁)(R₂₁₁) (R₂₁₁)(R₂₁₁) have the strucutre | 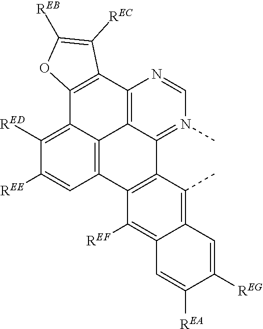 |
| L_{A12}(R^{EA})(R^{EB})(R^{EC})(R^{ED}) (R^{EE})(R^{EF})(R^{EG}), wherein L_{A12}(R₁)(R₁)(R₁)(R₁)(R₁)(R₁) (R₁) to L_{A12}(R₂₁₁)(R₂₁₁)(R₂₁₁)(R₂₁₁) (R₂₁₁)(R₂₁₁)(R₂₁₁) have the structure | 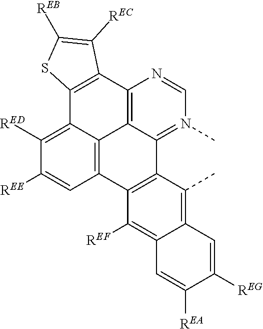 |
| L_{A13}(R^{EA})(R^{EB})(R^{EC})(R^{ED}) (R^{EE})(R^{EF})(R^{EG}), wherein L_{A13}(R₁)(R₁)(R₁)(R₁)(R₁(R₁) (R₁) to L_{A13}(R₂₁₁)(R₂₁₁)(R₂₁₁)(R₂₁₁)(R₂₁₁) (R₂₁₁)(R₂₁₁) have the structure | 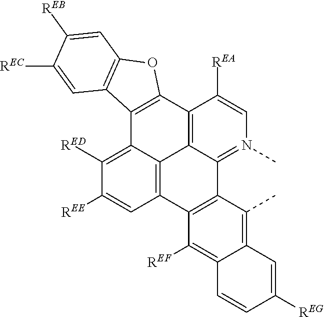 |
| L_{A14}(R^{EA})(R^{EB})(R^{EC})(R^{ED}) (R^{EE})(R^{EF})(R^{EG}), wherein L_{A14}(R₁)(R₁)(R₁)(R₁)(R₁)(R₁) (R₁) to L_{A14}(R₂₁₁)(R₂₁₁)(R₂₁₁)(R₂₁₁) (R₂₁₁)(R₂₁₁)(R₂₁₁) have the structure | 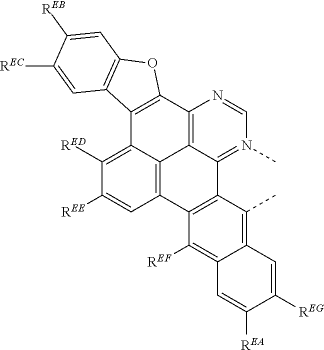 |
| L_{A15}(R^{EA})(R^{EB})(R^{EC})(R^{ED}) (R^{EE})(R^{EF})(R^{EG}), wherein L_{A15}(R₁)(R₁)(R₁)(R₁)(R₁)(R₁) (R₁) to L_{A15}(R₂₁₁)(R₂₁₁)(R₂₁₁)(R₂₁₁)(R₂₁₁) (R₂₁₁)(R₂₁₁) have the structure | 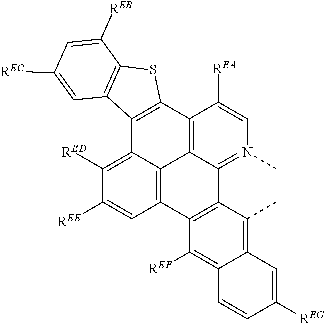 |
| L_{A16}(R^{EA})(R^{EB})(R^{EC})(R^{ED}) (R^{EE})(R^{EF})(R^{EG}), wherein L_{A16}(R₁)(R₁)(R₁)(R1)(R₁)(R₁) (R₁) to L_{A16}(R₂₁₁)(R₂₁₁)(R₂₁₁)(R₂₁₁) (R₂₁₁)(R₂₁₁)(R₂₁₁) have the structure | 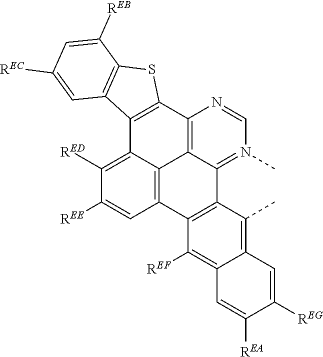 |
| L_{A17}(R^{EA})(R^{EB})(R^{EC})(R^{ED}) (R^{EE})(R^{EF})(R^{EG}), wherein L_{A17}(R₁)(R₁)(R₁)(R₁)(R₁)(R₁) (R₁) to L_{A17}(R₂₁₁)(R₂₁₁)(R₂₁₁)(R₂₁₁)(R₂₁₁) (R₂₁₁)(R₂₁₁) have the structure | 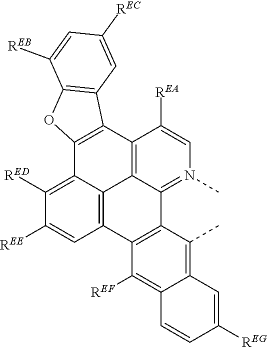 |
| L_{A18}(R^{EA})(R^{EB})(R^{EC})(R^{ED}) (R^{EE})(R^{EF})(R^{EG}), wherein L_{A18}(R₁)(R₁)(R₁)(R₁)(R₁)(R₁) (R₁) to L_{A18}(R₂₁₁)(R₂₁₁)(R₂₁₁)(R₂₁₁) (R₂₁₁)(R₂₁₁)(R₂₁₁) have the structure | 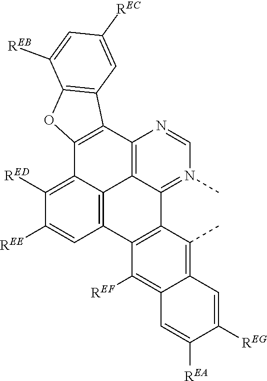 |
| L_{A19}(R^{EA})(R^{EB})(R^{EC})(R^{ED}) (R^{EE})(R^{EF})(R^{EG}), wherein L_{A19}(R₁)(R₁)(R₁)(R₁)(R₁)(R₁) (R₁) to L_{A19}(R₂₁₁)(R₂₁₁)(R₂₁₁)(R₂₁₁)(R₂₁₁) (R₂₁₁)(R₂₁₁) have the structure | 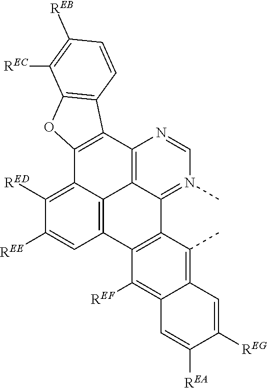 |
| L_{A20}(R^{EA})(R^{EB})(R^{EC})(R^{ED}) (R^{EE})(R^{EF})(R^{EG}), wherein L_{A20}(R₁)(R₁)(R₁)(R₁)(R₁)(R₁) (R₁) to L_{A20}(R₂₁₁)(R₂₁₁)(R₂₁₁)(R₂₁₁) (R₂₁₁)(R₂₁₁)(R₂₁₁) have the structure | 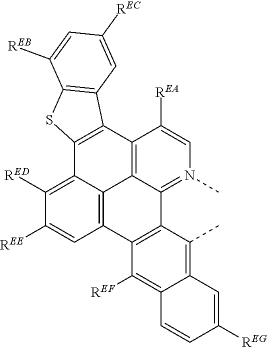 |
| L_{A21}(R^{EA})(R^{EB})(R^{EC})(R^{ED}) (R^{EE})(R^{EF})(R^{EG}), wherein L_{A21}(R₁)(R₁)(R₁)(R₁)(R₁)(R₁) (R₁) to L_{A21}(R₂₁₁)(R₂₁₁)(R₂₁₁)(R₂₁₁)(R₂₁₁) (R₂₁₁)(R₂₁₁) have the structure | 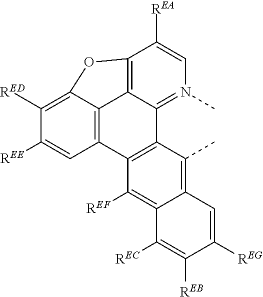 |
| L_{A22}(R^{EA})(R^{EB})(R^{EC})(R^{ED})(R^{EE}) (R^{EF})(R^{EG}), wherein L_{A22}(R₁)(R₁)(R₁)(R₁)(R₁)(R₁) (R₁) to L_{A22}(R₂₁₁)(R₂₁₁)(R₂₁₁)(R₂₁₁) (R₂₁₁)(R₂₁₁)(R₂₁₁) have the structure | 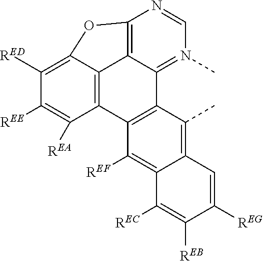 |
| L_{A23}(R^{EA})(R^{EB})(R^{EC})(R^{ED}) (R^{EE})(R^{EF})(R^{EG}), wherein L_{A23}(R₁)(R₁)(R₁)(R₁)(R₁)(R₁) (R₁) to L_{A23}(R₂₁₁)(R₂₁₁)(R₂₁₁)(R₂₁₁)(R₂₁₁) (R₂₁₁)(R₂₁₁) have the structure | 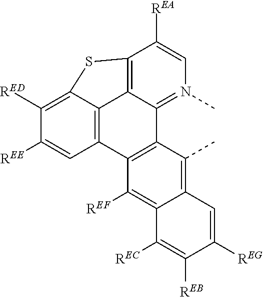 |
| L_{A24}(R^{EA})(R^{EB})(R^{EC})(R^{ED}) (R^{EE})(R^{EF})(R^{EG}), wherein L_{A24}(R₁)(R₁)(R₁)(R₁)(R₁)R₁) (R₁) to L_{A24}(R₂₁₁)(R₂₁₁)(R₂₁₁)(R₂₁₁) (R₂₁₁)(R₂₁₁)(R₂₁₁) have the structure | 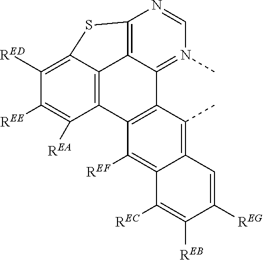 |
| L_{A25}(R^{EA})(R^{EB})(R^{EC})(R^{ED}) (R^{EE})(R^{EF})(R^{EG}), wherein L_{A25}(R₁)(R₁)(R₁(R₁)(R₁)(R₁) (R₁) to L_{A25}(R₂₁₁)(R₂₁₁)(R₂₁₁)(R₂₁₁)(R₂₁₁) (R₂₁₁)(R₂₁₁) have the structure | 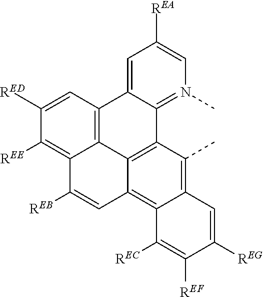 |
| L_{A26}(R^{EA})(R^{EB})(R^{EC})(R^{ED}) (R^{EE})(R^{EF})(R^{EG}), wherein L_{A26}(R₁)(R₁)(R₁)(R₁)(R₁)(R₁) (R₁) to L_{A26}(R₂₁₁)(R₂₁₁)(R₂₁₁)(R₂₁₁) (R₂₁₁)(R₂₁₁)(R₂₁₁) have the structure | 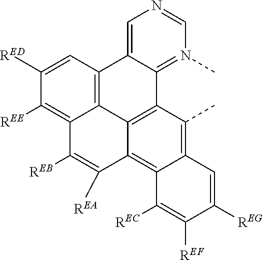 |
| L_{A27}(R^{EA})(R^{EB})(R^{EC})(R^{ED}) (R^{EE})(R^{EF})(R^{EG}), wherein L_{A27}(R₁)(R₁)(R₁)(R₁)(R₁)(R₁) (R₁) to L_{A27}(R₂₁₁)(R₂₁₁)(R₂₁₁)(R₂₁₁)(R₂₁₁) (R₂₁₁)(R₂₁₁) have the structure | 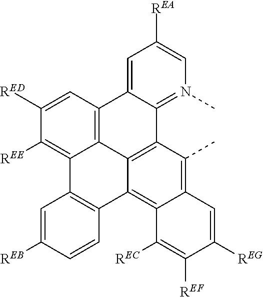 |
| L_{A28}(R^{EA})(R^{EB})(R^{EC})(R^{ED}) (R^{EE})(R^{EF})(R^{EG}), wherein L_{A28}(R₁)(R₁)(R₁)(R₁)(R₁)(R₁) (R₁) to L_{A28}(R₂₁₁)(R₂₁₁)(R₂₁₁)(R₂₁₁) (R₂₁₁)(R₂₁₁)(R₂₁₁) have the structure | 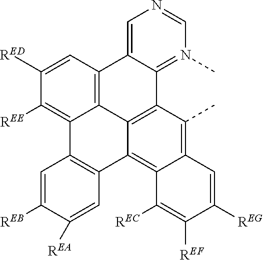 |
| L_{A29}(R^{EA})(R^{EB})(R^{EC})(R^{ED}) (R^{EE})(R^{EF})(R^{EG}), wherein L_{A29}(R₁)(R₁)(R₁)(R₁)(R₁)(R₁) (R₁) to L_{A29}(R₂₁₁)(R₂₁₁)(R₂₁₁)(R₂₁₁)(R₂₁₁) (R₂₁₁)(R₂₁₁) have the structure | 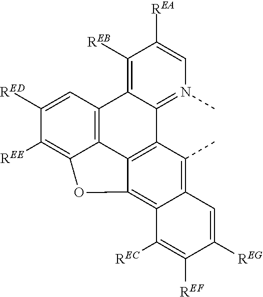 |
| L_{A30}(R^{EA})(R^{EB})(R^{EC})(R^{ED}) (R^{EE})(R^{EF})(R^{EG}), wherein L_{A30}(R₁)(R₁)(R₁)(R₁)(R₁)(R₁) (R₁) to L_{A30}(R₂₁₁)(R₂₁₁)(R₂₁₁)(R₂₁₁) (R₂₁₁)(R₂₁₁)(R₂₁₁) have the structure | 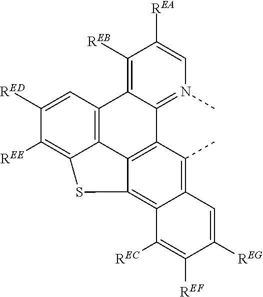 |
| L_{A31}(R^{EA})(R^{EB})(R^{EC})(R^{ED}) (R^{EE})(R^{EF})(R^{EG}), wherein L_{A31}(R₁)(R₁)(R₁)(R₁)(R₁)(R₁) (R₁) to L_{A31}(R₂₁₁)(R₂₁₁)(R₂₁₁)(R₂₁₁)(R₂₁₁) (R₂₁₁)(R₂₁₁) have the structure | 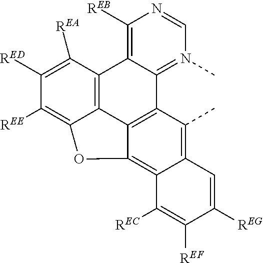 |
| L_{A32}(R^{EA})(R^{EB})(R^{EC})(R^{ED}) (R^{EE})(R^{EF})(R^{EG}), wherein L_{A32}(R₁)(R₁)(R₁)(R₁)(R₁)(R₁) (R₁) to L_{A32}(R₂₁₁)(R₂₁₁)(R₂₁₁)(R₂₁₁) (R₂₁₁)(R₂₁₁)(R₂₁₁) have the structure | 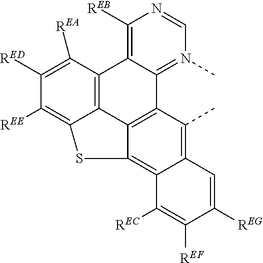 |
| L_{A33}(R^{EA})(R^{EB})(R^{EC})(R^{ED}) (R^{EE})(R^{EF})(R^{EG}), wherein L_{A33}(R₁)(R₁)(R₁)(R₁)(R₁)(R₁) (R₁) to L_{A33}(R₂₁₁)(R₂₁₁)(R₂₁₁)(R₂₁₁)(R₂₁₁) (R₂₁₁)(R₂₁₁) have the structure | 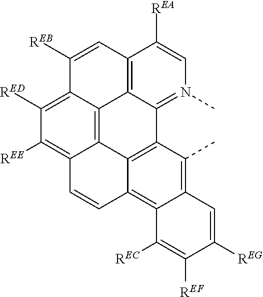 |
| L_{A34}(R^{EA})(R^{EB})(R^{EC})(R^{ED}) (R^{EE})(R^{EF})(R^{EG}), wherein L_{A34}(R₁)(R₁)(R₁)(R₁)(R₁)(R₁) (R₁) to L₃₄(R₂₁₁)(R₂₁₁)(R₂₁₁)(R₁₁) (R₂₁₁)(R₂₁₁)(R₂₁₁) have the structure | 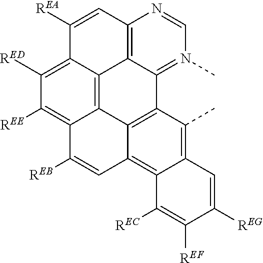 |
| L_{A35}(R^{EA})(R^{EB})(R^{EC})(R^{ED}) (R^{EE})(R^{EF})(R^{EG}), wherein L_{A35}(R₁)(R₁)(R₁)(R₁)(R₁)(R₁) (R₁) to L_{A35}(R₂₁₁)(R₂₁₁)(R₂₁₁)(R₂₁₁)(R₂₁₁) (R₂₁₁)(R₂₁₁) have the structure | 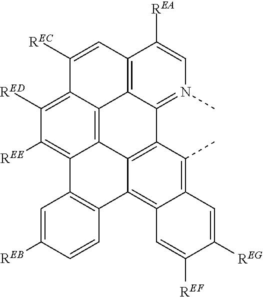 |
| L_{A36}(R^{EA})(R^{EB})(R^{EC})(R^{ED}) (R^{EE})(R^{EF})(R^{EG}), wherein L_{A36}(R₁)(R₁)(R₁)(R₁)(R₁)(R₁) (R₁) to L_{A36}(R₂₁₁)(R₂₁₁)(R₂₁₁)(R₂₁₁) (R₂₁₁)(R₂₁₁)(R₂₁₁) have the structure | 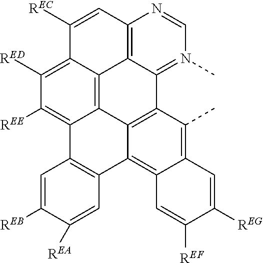 |
| L_{A37}(R^{EA})(R^{EB})(R^{EC})(R^{ED}) (R^{EE})(R^{EF})(R^{EG}), wherein L_{A37}(R₁)(R₁)(R₁)(R₁)(R₁)(R₁) (R₁) to L_{A37}(R₂₁₁)(R₂₁₁)(R₂₁₁)(R₂₁₁)(R₂₁₁) (R₂₁₁)(R₂₁₁) have the structure | 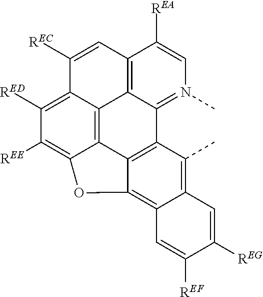 |
| L_{A38}(R^{EA})(R^{EB})(R^{EC})(R^{ED}) (R^{EE})(R^{EF})(R^{EG}), wherein L_{A38}(R₁ )(R₁)(R₁)(R₁)(R₁)(R₁) (R₁) to L_{A38}(R₂₁₁)(R₂₁₁)(R₂₁₁)(R₂₁₁) (R₂₁₁)(R₂₁₁)(R₂₁₁) have the structure | 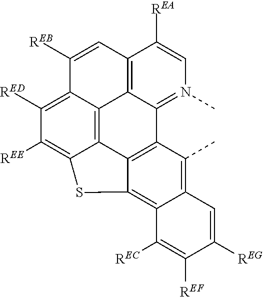 |
| L_{A39}(R^{EA})(R^{EB})(R^{EC})(R^{ED}) (R^{EE})(R^{EF})(R^{EG}), wherein L_{A39}(R₁)(R₁)(R₁)(R₁)(R₁)(R₁) (R₁) to L_{A39}(R₂₁₁)(R₂₁₁)(R₂₁₁)(R₂₁₁)(R₂₁₁) (R₂₁₁)(R₂₁₁) have the structure | 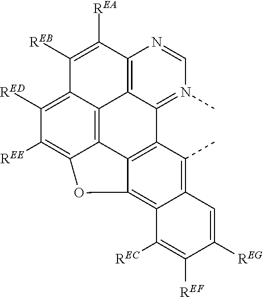 |
| L_{A40}(R^{EA})(R^{EB})(R^{EC})(R^{ED}) (R^{EE})(R^{EF})(R^{EG}), wherein L_{A40}(R₁)(R₁)(R₁)(R₁)(R₁)(R₁) (R₁) to L_{A40}(R₂₁₁)(R₂₁₁)(R₂₁₁)(R₂₁₁) (R₂₁₁)(R₂₁₁)(R₂₁₁) have the structure | 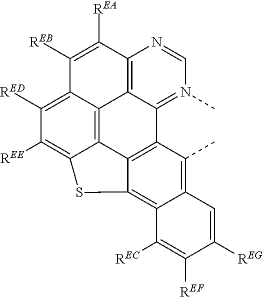 |
| L_{A41}(R^{EA})(R^{EB})(R^{EC})(R^{ED}) (R^{EE})(R^{EF})(R^{EG}), wherein L_{A41}(R₁)(R₁)(R₁)(R₁)(R₁)(R₁) (R₁) to L_{A41}(R₂₁₁)(R₂₁₁)(R₂₁₁)(R₂₁₁)(R₂₁₁) (R₂₁₁)(R₂₁₁) have the structure | 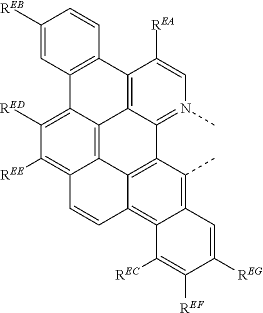 |
| L_{A42}(R^{EA})(R^{EB})(R^{EC})(R^{ED}) (R^{EE})(R^{EF})(R^{EG}), wherein L_{A42}(R₁)(R₁)(R₁)(R₁)(R₁)(R₁) (R₁) to L_{A42}(R₂₁₁)(R₂₁₁)(R₂₁₁)(R₂₁₁) (R₂₁₁)(R₂₁₁)(R₂₁₁) have the structure | 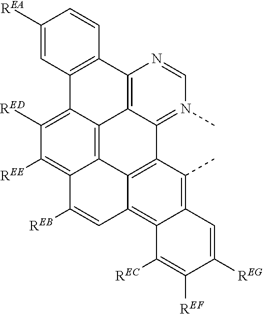 |
| L_{A43}(R^{EA})(R^{EB})(R^{EC})(R^{ED}) (R^{EE})(R^{EF})(R^{EG}), wherein L_{A43}(R₁)(R₁)(R₁)(R₁)(R₁)(R₁) (R₁) to L_{A43}(R₂₁₁)(R₂₁₁)(R₂₁₁)(R₂₁₁)(R₂₁₁) (R₂₁₁)(R₂₁₁) have the structure | 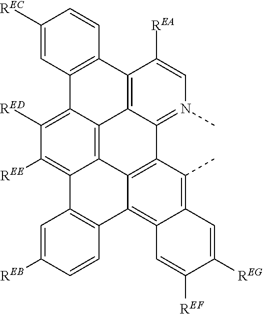 |
| L_{A44}(R^{EA})(R^{EB})(R^{EC})(R^{ED}) (R^{EE})(R^{EF})(R^{EG}), wherein L_{A44}(R₁)(R₁)(R₁)(R₁)(R₁)(R₁) (R₁) to L_{A44}(R₂₁₁)(R₂₁₁)(R₂₁₁)(R₂₁₁) (R₂₁₁)(R₂₁₁)(R₂₁₁) have the structure | 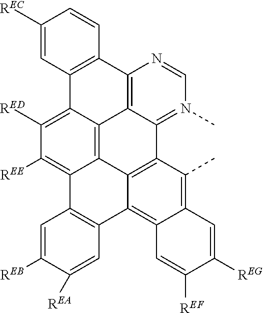 |
| L_{A45}(R^{EA})(R^{EB})(R^{EC})(R^{ED}) (R^{EE})(R^{EF})(R^{EG}), wherein L_{A45}(R₁)(R₁)(R₁)(R₁)(R₁)(R₁) (R₁) to L_{A45}(R₂₁₁)(R₂₁₁)(R₂₁₁)(R₂₁₁)(R₂₁₁) (R₂₁₁)(R₂₁₁) have the structure | 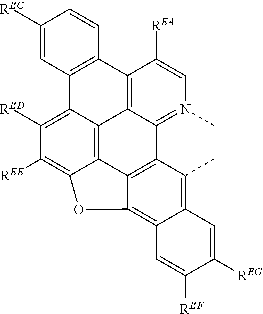 |
| L_{A46}(R^{EA})(R^{EB})(R^{EC})(R^{ED}) (R^{EE})(R^{EF})(R^{EG}), wherein L_{A46}(R₁)(R₁)(R₁)(R₁)(R₁)(R₁) (R₁) to L_{A6}(R₂₁₁)(R₂₁₁)(R₂₁₁)(R₂₁₁)(R₂₁₁) (R₂₁₁)(R₂₁₁) have the structure | 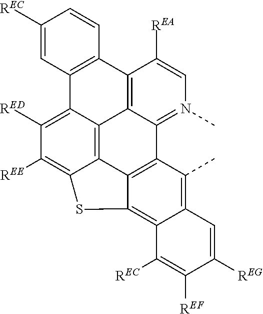 |
| L_{A47}(R^{EA})(R^{EB})(R^{EC})(R^{ED}) (R^{EE})(R^{EF})(R^{EG}), wherein L_{A47}(R₁)(R₁)(R₁)(R₁)(R₁)(R₁) (R₁) to L_{A47}(R₂₁₁)(R₂₁₁)(R₂₁₁)(R₂₁₁)(R₂₁₁) (R₂₁₁)(R₂₁₁) have the structure | 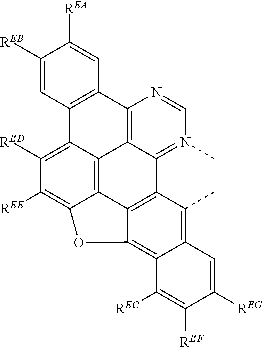 |
| L_{A48}(R^{EA})(R^{EB})(R^{EC})(R^{ED}) (R^{EE})(R^{EF})(R^{EG}), wherein L_{A48}(R₁)(R₁)(R₁)(R₁)(R₁)(R₁) (R₁) to L_{A48}(R₂₁₁)(R₂₁₁)(R₂₁₁)(R₂₁₁) (R₂₁₁)(R₂₁₁)(R₂₁₁) have the structure | 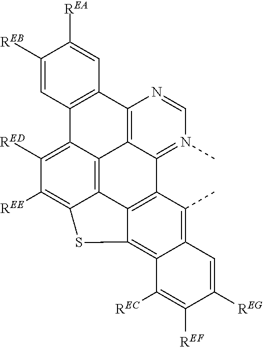 |
| L_{A49}(R^{EA})(R^{EB})(R^{EC})(R^{ED}) (R^{EE})(R^{EF})(R^{EG}), wherein L_{A49}(R₁)(R₁)(R₁)(R₁)(R₁)(R₁) (R₁) to L_{A49}(R₂₁₁)(R₂₁₁)(R₂₁₁)(R₂₁₁)(R₂₁₁) (R₂₁₁)(R₂₁₁) have the structure | 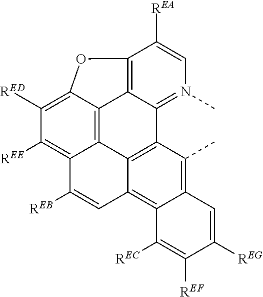 |
| L_{A50}(R^{EA})(R^{EB})(R^{EC})(R^{ED}) (R^{EE})(R^{EF})(R^{EG}), wherein L_{A50}(R₁)(R₁)(R₁)(R₁)(R₁)(R₁) (R₁) to L_{A50}(R₂₁₁)(R₂₁₁)(R₂₁₁)(R₂₁₁) (R₂₁₁)(R₂₁₁)(R₂₁₁) have the structure | 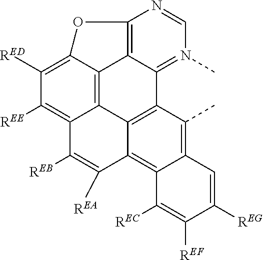 |
| L_{A51}(R^{EA})(R^{EB})(R^{EC})(R^{ED}) (R^{EE})(R^{EF})(R^{EG}), wherein L_{A51}(R₁)(R₁)(R₁)(R₁)(R₁)(R₁) (R₁) to L_{A51}(R₂₁₁)(R₂₁₁)(R₂₁₁)(R₂₁₁)(R₂₁₁) (R₂₁₁)(R₂₁₁) have the structure | 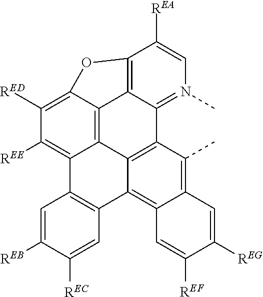 |
| L_{A52}(R^{EA})(R^{EB})(R^{EC})(R^{ED}) (R^{EE})(R^{EF})(R^{EG}), wherein L_{A52}(R₁)(R₁)(R₁)(R₁)(R₁)(R₁) (R₁) to L_{A52}(R₂₁₁)(R₂₁₁)(R₂₁₁)(R₂₁₁) (R₂₁₁)(R₂₁₁)(R₂₁₁) have the structure | 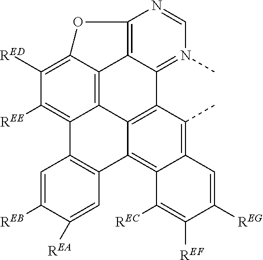 |
| L_{A53}(R^{EA})(R^{EB})(R^{EC})(R^{ED}) (R^{EE})(R^{EF})(R^{EG}), wherein L_{A53}(R₁)(R₁)(R₁)(R₁)(R₁)(R₁) (R₁) to L_{A53}(R₂₁₁)(R₂₁₁)(R₂₁₁)(R₂₁₁)(R₂₁₁) (R₂₁₁)(R₂₁₁) have the structure | 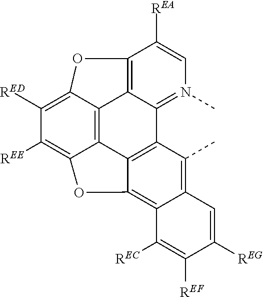 |
| L_{A54}(R^{EA})(R^{EB})(R^{EC})(R^{ED}) (R^{EE})(R^{EF})(R^{EG}), wherein L_{A54}(R₁)(R₁)(R₁)(R₁)(R₁)(R₁) (R₁) to L_{A54}(R₂₁₁)(R₂₁₁)(R₂₁₁)(R₂₁₁) (R₂₁₁)(R₂₁₁)(R₂₁₁) have the structure | 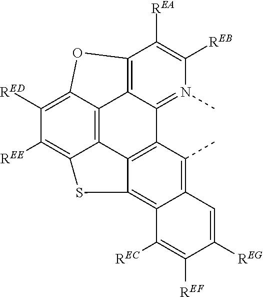 |
| L_{A55}(R^{EA})(R^{EB})(R^{EC})(R^{ED}) (R^{EE})(R^{EF})(R^{EG}), wherein L_{A55}(R₁)(R₁)(R₁)(R₁)(R₁)(R₁) (R₁) to L_{A55}(R₂₁₁)(R₂₁₁)(R₂₁₁)(R₂₁₁)(R₂₁₁) (R₂₁₁)(R₂₁₁) have the structure | 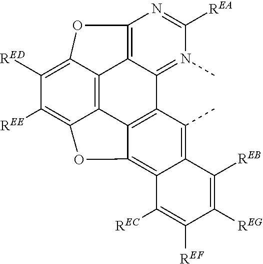 |
| L_{A56}(R^{EA})(R^{EB})(R^{EC})(R^{ED}) (R^{EE})(R^{EF})(R^{EG}), wherein L_{A56}(R₁)(R₁)(R₁)(R₁)(R₁)(R₁) (R₁) to L_{A56}(R₂₁₁)(R₂₁₁)(R₂₁₁)(R₂₁₁) (R₂₁₁)(R₂₁₁)(R₂₁₁) have the structure | 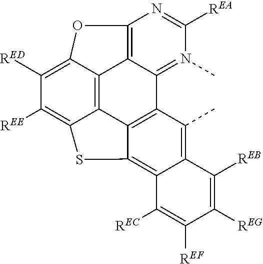 |
| L_{A57}(R^{EA})(R^{EB})(R^{EC})(R^{ED}) (R^{EE})(R^{EF})(R^{EG}), wherein L_{A57}(R₁)(R₁)(R₁)(R₁)(R₁)(R₁) (R₁) to L_{A57}(R₂₁₁)(R₂₁₁)(R₂₁₁)(R₂₁₁)(R₂₁₁) (R₂₁₁)(R₂₁₁) have the structure | 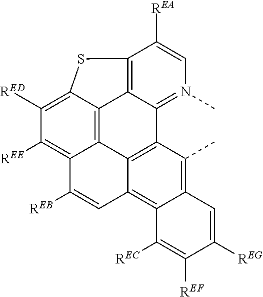 |
| L_{A58}(R^{EA})(R^{EB})(R^{EC})(R^{ED}) (R^{EE})(R^{EF})(R^{EG}), wherein L_{A58}(R₁)(R₁)(R₁)(R₁)(R₁)(R₁) (R₁) to L_{A58}(R₂₁₁)(R₂₁₁)(R₂₁₁)(R₂₁₁) (R₂₁₁)(R₂₁₁)(R₂₁₁) have the structure | 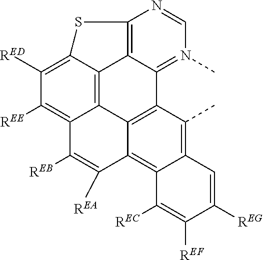 |
| L_{A59}(R^{EA})(R^{EB})(R^{EC})(R^{ED}) (R^{EE})(R^{EF})(R^{EG}), wherein L_{A59}(R₁)(R₁)(R₁)(R₁)(R₁)(R₁) (R₁) to L_{A59}(R₂₁₁)(R₂₁₁)(R₂₁₁)(R₂₁₁)(R₂₁₁) (R₂₁₁)(R₂₁₁) have the structure | 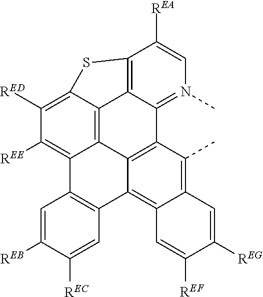 |
| L_{A60}(R^{EA})(R^{EB})(R^{EC})(R^{ED}) (R^{EE})(R^{EF})(R^{EG}), wherein L_{A60}(R₁)(R₁)(R₁)(R₁)(R₁(R₁) (R₁) to L_{A60}(R₂₁₁)(R₂₁₁)(R₂₁₁)(R₂₁₁) (R₂₁₁)(R₂₁₁)(R₂₁₁) have the structure | 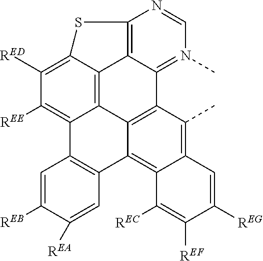 |
| L_{A61}(R^{EA})(R^{EB})(R^{EC})(R^{ED}) (R^{EE})(R^{EF})(R^{EG}), wherein L_{A61}(R₁)(R₁)(R₁)(R₁)(R₁)(R₁) (R₁) to L_{A61}(R₂₁₁)(R₂₁₁)(R₂₁₁)(R₂₁₁)(R₂₁₁) (R₂₁₁)(R₂₁₁) have the structure | 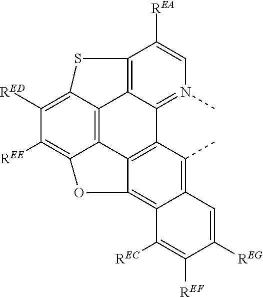 |
| L_{A62}(R^{EA})(R^{EB})(R^{EC})(R^{ED}) (R^{EE})(R^{EF})(R^{EG}), wherein L_{A62}(R₁)(R₁)(R₁)(R₁)(R₁)(R₁) (R₁) to L_{A62}(R₂₁₁)(R₂₁₁)(R₂₁₁)(R₂₁₁) (R₂₁₁)(R₂₁₁)(R₂₁₁) have the structure | 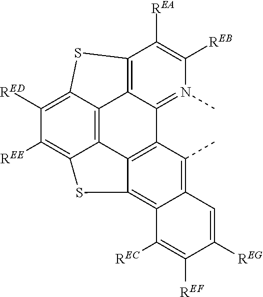 |
| L_{A63}(R^{EA})(R^{EB})(R^{EC})(R^{ED}) (R^{EE})(R^{REF})(R^{EG}), wherein L_{A63}(R₁)(R₁)(R₁)(R₁)(R₁)(R₁) (R₁) to L_{A63}(R₂₁₁)(R₂₁₁)(R₂₁₁)(R₂₁₁)(R₂₁₁) (R₂₁₁)(R₂₁₁) have the structure | 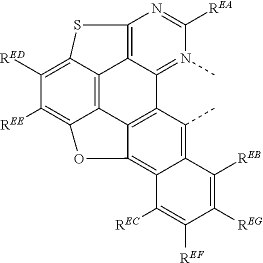 |
| L_{A64}(R^{EA})(R^{EB})(R^{EC})(R^{ED}) (R^{EE})(R^{EF})(R^{EG}), wherein L_{A64}(R₁)(R₁)(R₁)(R₁)(R₁)(R₁) (R₁) to L_{A64}(R₂₁₁)(R₂₁₁)(R₂₁₁)(R₂₁₁) (R₂₁₁)(R₂₁₁)(R₂₁₁) have the structure | 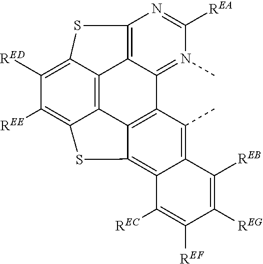 |
| L_{A65}(R^{EA})(R^{EB})(R^{EC})(R^{ED}) (R^{EE})(R^{EF})(R^{EG}), wherein L_{A65}(R₁)(R₁)(R₁)(R₁)(R₁)(R₁) (R₁) to L_{A65}(R₂₁₁)(R₂₁₁)(R₂₁₁)(R₂₁₁)(R₂₁₁) (R₂₁₁)(R₂₁₁) have the structure | 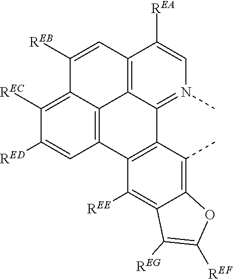 |
| L_{A66}(R^{EA})(R^{EB})(R^{EC})(R^{ED}) (R^{EE})(R^{EF})(R^{EG}), wherein L_{A66}(R₁)(R₁)(R₁)(R₁)(R₁)(R₁) (R₁) to L_{A66}(R₂₁₁)(R₂₁₁)(R₂₁₁)(R₂₁₁) (R₂₁₁)(R₂₁₁)(R₂₁₁) have the structure | 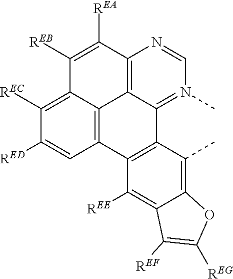 |
| L_{A67}(R^{EA})(R^{EB})(R^{EC})(R^{ED}) (R^{EE})(R^{EF})(R^{EG}), wherein L_{A67}(R₁)(R₁)(R₁)(R₁)(R₁)(R₁) (R₁) to L_{A67}(R₂₁₁)(R₂₁₁)(R₂₁₁)(R₂₁₁)(R₂₁₁) (R₂₁₁)(R₂₁₁) have the structure | 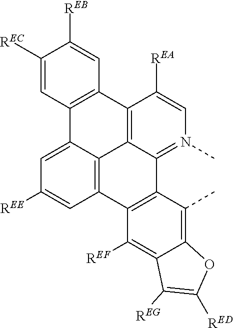 |
| L_{A68}(R^{EA})(R^{EB})(R^{EC})(R^{ED}) (R^{EE})(R^{EF})(R^{EG}), wherein L_{A68}(R₁)(R₁)(R₁)(R₁)(R₁)(R₁) (R₁) to L₆₈(R₂₁₁)(R₂₁₁)(R₂₁₁)(R₂₁₁) (R₂₁₁)(R₂₁₁)(R₂₁₁) have the structure | 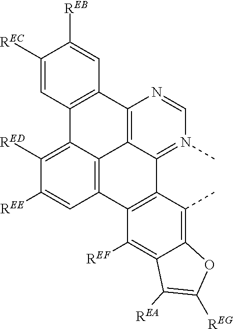 |
| L_{A69}(R^{EA})(R^{EB})(R^{EC})(R^{ED}) (R^{EE})(R^{EF})(R^{EG}), wherein L_{A69}(R₁)(R₁)(R₁)(R₁)(R₁)(R₁) (R₁) to L_{A69}(R₂₁₁)(R₂₁₁)(R₂₁₁)(R₂₁₁)(R₂₁₁) (R₂₁₁)(R₂₁₁) have the structure | 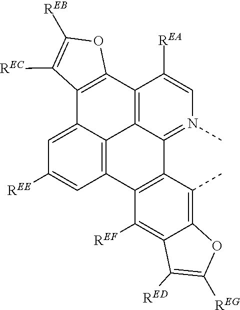 |
| L_{A70}(R^{EA})(R^{EB})(R^{EC})(R^{ED}) (R^{EE})(R^{EF})(R^{EG}), wherein L_{A70}(R₁)(R₁)(R₁)(R₁)(R₁)(R₁) (R₁) to L_{A70}(R₂₁₁)(R₂₁₁)(R₂₁₁)(R₂₁₁) (R₂₁₁)(R₂₁₁)(R₂₁₁) have the structure | 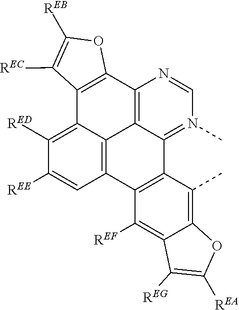 |
| L_{A71}(R^{EA})(R^{EB})(R^{EC})(R^{ED}) (R^{EE})(R^{EF})(R^{EG}), wherein L_{A71}(R₁)(R₁)(R₁)(R₁)(R₁)(R₁) (R₁) to L_{A71}(R₂₁₁)(R₂₁₁)(R₂₁₁)(R₂₁₁)(R₂₁₁) (R₂₁₁)(R₂₁₁) have the structure | 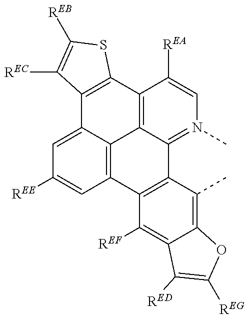 |
| L_{A72}(R^{EA})(R^{EB})(R^{EC})(R^{ED}) (R^{EE})(R^{EF})(R^{EG}), wherein L_{A72}(R₁)(R₁)(R1)(R₁)(R₁)(R₁) (R₁) to L_{A72}(R₂₁₁)(R₂₁₁)(R₂₁₁)(R₂₁₁) (R₂₁₁)(R₂₁₁)(R₂₁₁) have the structure | 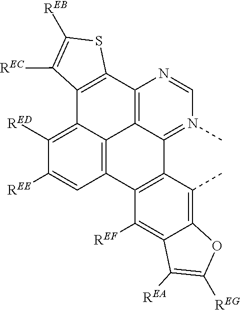 |
| L_{A73}(R^{EA})(R^{EB})(R^{EC})(R^{ED}) (R^{EE})(R^{EF})(R^{EG}), wherein L_{A73}(R₁)(R₁)(R₁)(R₁)(R₁)(R₁) (R₁) to L_{A73}(R₂₁₁)(R₂₁₁)(R₂₁₁)(R₂₁₁)(R₂₁₁) (R₂₁₁)(R₂₁₁) have the structure | 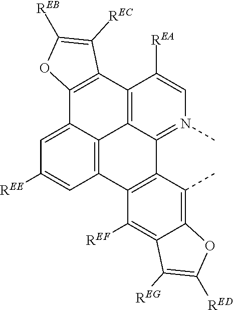 |
| L_{A74}(R^{EA})(R^{EB})(R^{EC})(R^{ED}) (R^{EE})(R^{EF})(R^{EG}), wherein L_{A74}(R₁)(R₁)(R₁)(R₁)(R₁)(R₁) (R₁) to L_{A74}(R₂₁₁)(R₂₁₁)(R₂₁₁)(R₂₁₁) (R₂₁₁)(R₂₁₁)(R₂₁₁) have the structure | 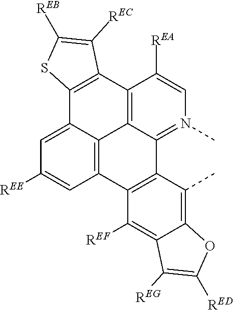 |
| L_{A75}(R^{EA})(R^{EB})(R^{EC})(R^{ED}) (R^{EE})(R^{EF})(R^{EG}), wherein L_{A75}(R₁)(R₁)(R₁)(R₁)(R₁)(R₁) (R₁) to L_{A75}(R₂₁₁)(R₂₁₁)(R₂₁₁)(R₂₁₁)(R₂₁₁) (R₂₁₁)(R₂₁₁) have the structure | 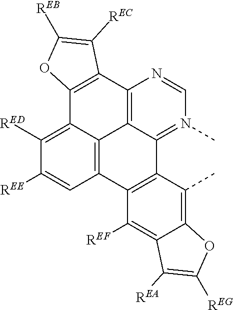 |
| L_{A76}(R^{EA})(R^{EB})(R^{EC})(R^{ED}) (R^{EE})(R^{EF})(R^{EG}), wherein L_{A76}(R₁)(R₁)(R₁)(R₁)(R₁)(R₁) (R₁) to L_{A76}(R₂₁₁)(R₂₁₁)(R₂₁₁)(R₂₁₁) (R₂₁₁)(R₂₁₁)(R₂₁₁) have the structure | 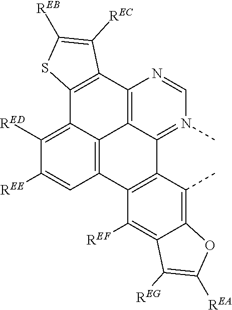 |
| L_{A77}(R^{EA})(R^{EB})(R^{EC})(R^{ED}) (R^{EE})(R^{EF})(R^{EG}), wherein L_{A77}(R₁)(R₁)(R₁)(R₁)(R₁)(R₁) (R₁) to L_{A77}(R₂₁₁)(R₂₁₁)(R₂₁₁)(R₂₁₁)(R₂₁₁) (R₂₁₁)(R₂₁₁) have the structure | 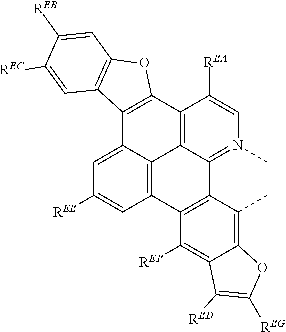 |
| L_{A78}(R^{EA})(R^{EB})(R^{EC})(R^{ED}) (R^{EE})(R^{EF})(R^{EG}), wherein L_{A78}(R₁)(R₁)(R₁)(R₁)(R₁)(R₁) (R₁) to L_{A78}(R₂₁₁)(R₂₁₁)(R₂₁₁)(R₂₁₁) (R₂₁₁)(R₂₁₁)(R₂₁₁) have the structure | 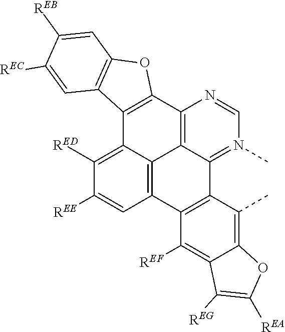 |
| L_{A79}(R^{EA})(R^{EB})(R^{EC})(R^{ED}) (R^{EE})(R^{EF})(R^{EG}), wherein L_{A79}(R₁)(R₁)(R₁)(R₁)(R₁)(R₁) (R₁) to L_{A79}(R₂₁₁)(R₂₁₁)(R₂₁₁)(R₂₁₁)(R₂₁₁) (R₂₁₁)(R₂₁₁) have the structure | 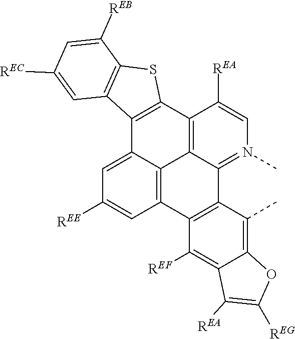 |
| L_{A80}(R^{EA})(R^{EB})(R^{EC})(R^{ED}) (R^{EE})(R^{EF}(R^{EG}), wherein L_{A80}(R₁)(R₁)(R₁)(R₁)(R₁)(R₁) (R₁) to L_{A80}(R₂₁₁)(R₂₁₁)(R₂₁₁)(R₂₁₁) (R₂₁₁)(R₂₁₁)(R₂₁₁) have the structure | 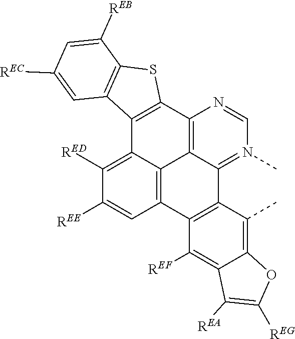 |
| L_{A81}(R^{EA})(R^{EB})(R^{EC})(R^{ED}) (R^{EE})(R^{EF})(R^{EG}), wherein L_{A81}(R₁)(R₁)(R₁)(R₁)(R₁)(R₁) (R₁) to L_{A81}(R₂₁₁)(R₂₁₁)(R₂₁₁)(R₂₁₁)(R₂₁₁) (R₂₁₁)(R₂₁₁) have the structure | 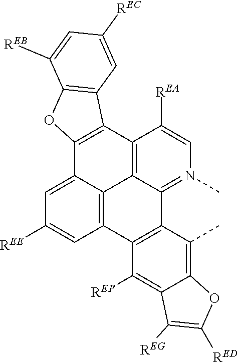 |
| L_{A82}(R^{EA})(R^{EB})(R^{EC})(R^{ED}) (R^{EE})(R^{EF})(R^{EG}), wherein L_{A82}(R₁)(R₁)(R₁)(R₁)(R₁)(R₁) (R₁) to L_{A82}(R₂₁₁)(R₂₁₁)(R₂₁₁)(R₂₁₁) (R₂₁₁)(R₂₁₁)(R₂₁₁) have the structure | 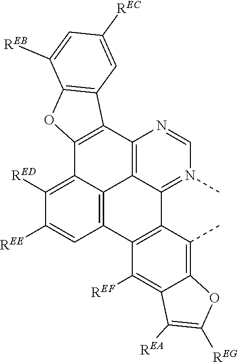 |
| L_{A83}(R^{EA})(R^{EB})(R^{EC})(R^{ED}) (R^{EE})(R^{EF})(R^{EG}), wherein L_{A83}(R₁)(R₁)(R₁)(R₁)(R₁)(R₁) (R₁) to L_{A83}(R₂₁₁)(R₂₁₁)(R₂₁₁)(R₂₁₁)(R₂₁₁) (R₂₁₁)(R₂₁₁) have the structure | 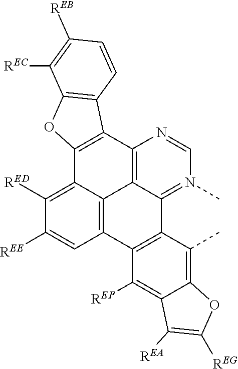 |
| L_{A84}(R^{EA})(R^{EB})(R^{EC})(R^{ED}) (R^{EE})(R^{EF})(R^{EG}), wherein L_{A84}(R₁)(R₁)(R₁)(R₁)(R₁)(R₁) (R₁) to L_{A84}(R₂₁₁)(R₂₁₁)(R₂₁₁)(R₂₁₁) (R₂₁₁)(R₂₁₁)(R₂₁₁) have the structure | 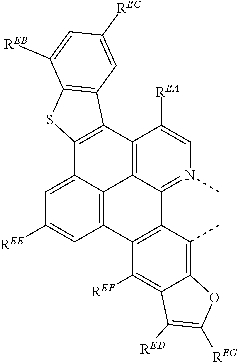 |
| L_{A85}(R^{EA})(R^{EB})(R^{EC})(R^{ED}) (R^{EE})(R^{EF})(R^{EG}), wherein L_{A85}(R₁)(R₁)(R₁)(R₁)(R₁)(R₁) (R₁) to L₈₅(R₂₁₁)(R₂₁₁)(R₂₁₁)(R₂₁₁)(R₂₁₁) (R₂₁₁)(R₂₁₁) have the structure | 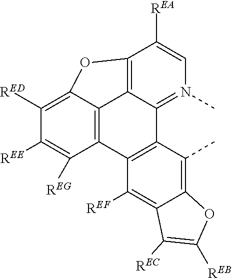 |
| L_{A86}(R^{EA})(R^{EB})(R^{EC})(R^{ED}) (R^{EE})(R^{EF})(R^{EG}), wherein L_{A86}(R₁)(R₁)(R₁)(R₁)(R₁)(R₁) (R₁) to L_{A86}(R₂₁₁)(R₂₁₁)(R₂₁₁)(R₂₁₁) (R₂₁₁)(R₂₁₁)(R₂₁₁) have the structure | 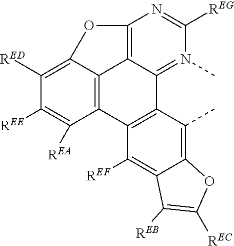 |
| L_{A87}(R^{EA})(R^{EB})(R^{EC})(R^{ED}) (R^{EE})(R^{EF})(R^{EG}), wherein L_{A87}(R₁)(R₁)(R₁)(R₁)(R₁)(R₁) (R₁) to L_{A87}(R₂₁₁)(R₂₁₁)(R₂₁₁)(R₂₁₁)(R₂₁₁) (R₂₁₁)(R₂₁₁) have the structure | 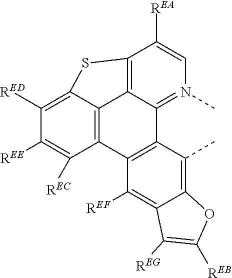 |
| L_{A88}(R^{EA})(R^{EB})(R^{EC})(R^{ED}) (R^{EE})(R^{EF})(R^{EG}), wherein L_{A88}(R₁)(R₁)(R₁)(R₁)(R₁)(R₁) (R₁) to L_{A88}(R₂₁₁)(R₂₁₁)(R₂₁₁)(R₂₁₁) (R₂₁₁)(R₂₁₁)(R₂₁₁) have the structure | 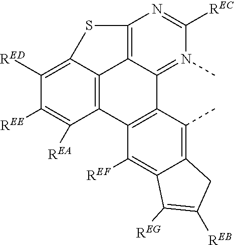 |
| L_{A89}(R^{EA})(R^{EB})(R^{EC})(R^{ED}) (R^{EE})(R^{EF})(R^{EG}), wherein L_{A89}(R₁)(R₁)(R₁)(R₁)(R₁)(R₁) (R₁) to L_{A89}(R₂₁₁)(R₂₁₁)(R₂₁₁)(R₂₁₁) (R₂₁₁)(R₂₁₁)(R₂₁₁) have the structure | 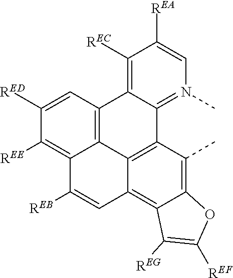 |
| L_{A90}(R^{EA})(R^{EB})(R^{EC})(R^{ED}) (R^{EE})(R^{EF})(R^{EG}), wherein L_{A90}(R₁)(R₁)(R₁)(R₁)(R₁)(R₁) (R₁) to L_{A90}(R₂₁₁)(R₂₁₁)(R₂₁₁)(R₂₁₁) (R₂₁₁)(R₂₁₁)(R₂₁₁) have the structure | 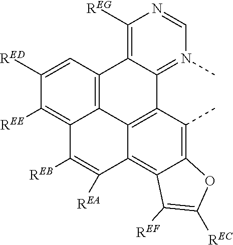 |
| L_{A91}(R^{EA})(R^{EB})(R^{EC})(R^{ED}) (R^{EE})(R^{EF})(R^{EG}), wherein L_{A91}(R₁)(R₁)(R₁)(R₁)(R₁)(R₁) (R₁) to L_{A91}(R₂₁₁)(R₂₁₁)(R₂₁₁)(R₂₁₁)(R₂₁₁) (R₂₁₁)(R₂₁₁) have the structure | 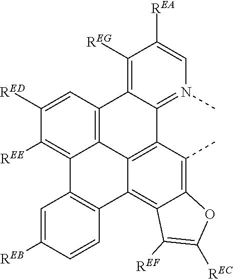 |
| L_{A92}(R^{EA})(R^{EB})(R^{EC})R^{ED}) (R^{EE})(R^{EF})(R^{EG}), wherein L_{A92}(R₁)(R₁)(R₁)(R₁)(R₁)(R₁) (R₁) to L_{A92}(R₂₁₁)(R₂₁₁)(R₂₁₁)(R₂₁₁) (R₂₁₁)(R₂₁₁)(R₂₁₁) have the structure | 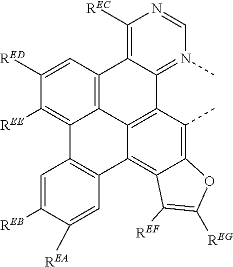 |
| L_{A93}(R^{EA})(R^{EB})(R^{EC})(R^{ED)} (R^{EE})(R^{EF})(R^{EG}), wherein L_{A93}(R₁)(R₁)(R₁)(R₁)(R₁)(R₁) (R₁) to L_{A93}(R₂₁₁)(R₂₁₁)(R₂₁₁)(R₂₁₁)(R₂₁₁) (R₂₁₁)(R₂₁₁) have the structure | 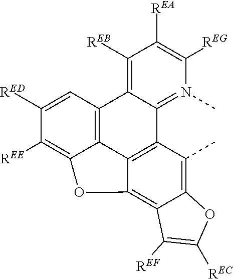 |
| L_{A94}(R^{EA})(R^{EB})(R^{EC})(R^{ED}) (R^{EE})(R^{EF})(R^{EG}), wherein L_{A94}(R₁)(R₁)(R₁)(R₁)(R₁)(R₁) (R₁) to L_{A94}(R₂₁₁)(R₂₁₁)(R₂₁₁)(R₂₁₁) (R₂₁₁)(R₂₁₁)(R₂₁₁) have the structure | 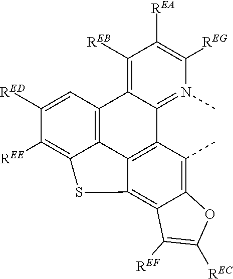 |
| L_{A95}(R^{EA})(R^{EB})(R^{EC})(R^{ED}) (R^{EE})(R^{EF})(R^{EG}), wherein L_{A95}(R₁)(R₁)(R₁)(R₁)(R₁)(R₁) (R₁) to L_{A95}(R₂₁₁)(R₂₁₁)(R₂₁₁)(R₂₁₁)(R₂₁₁) (R₂₁₁)(R₂₁₁) have the structure | 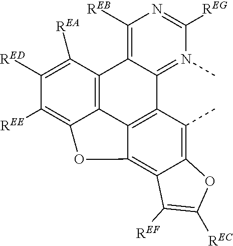 |
| L_{A96}(R^{EA})(R^{EB})(R^{EC})(R^{ED}) (R^{EE})(R^{EF})(R^{EG}), wherein L_{A96}(R₁)(R₁)(R₁)(R₁)(R₁)(R₁) (R₁) to L_{A96}(R₂₁₁)(R₂₁₁)(R₂₁₁)(R₂₁₁) (R₂₁₁)(R₂₁₁)(R2₁₁) have the structure | 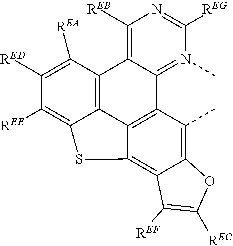 |
| l_{A97}(R^{EA})(R^{EB})(R^{EC})(R^{ED}) (R^{EE})(R^{EF})(R^{EG}), wherein L_{A97}(R₁)(R₁)(R₁)(R₁)(R₁)(R₁) (R₁) to L_{A97}(R₂₁₁)(R₂₁₁)(R₂₁₁)(R₂₁₁)(R₂₁₁) (R₂₁₁)(R₂₁₁) have the structure | 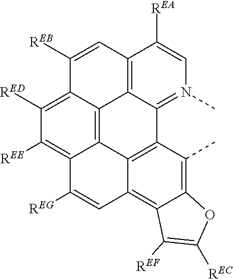 |
| L_{A98}(R^{EA})(R^{EB})(R^{EC})(R^{ED}) (R^{EE})(R^{EF})(R^{EG}), wherein L_{A98}(R₁)(R₁)(R₁)(R₁)(R₁)(R₁) (R₁) to L_{A98}(R₂₁₁)(R₂₁₁)(R₂₁₁)(R₂₁₁) (R₂₁₁)(R₂₁₁)(R₂₁₁) have the structure | 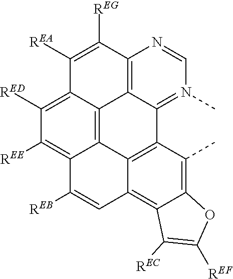 |
| L_{A99}(R^{EA})(R^{EB})(R^{EC})(R^{ED}) (R^{EE})(R^{EF})(R^{EG}), wherein L_{A99}(R₁)(R₁)(R₁)(R₁)(R₁)(R₁) (R₁) to L_{A99}(R₂₁₁)(R₂₁₁)(R₂₁₁)(R₂₁₁)(R₂₁₁) (R₂₁₁)(R₂₁₁) have the structure | 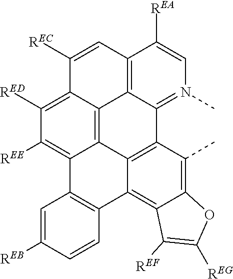 |
| L_{A100}(R^{EA})(R^{EB})(R^{EC})(R^{ED}) (R^{EE})(R^{EF})(R^{EG}), wherein L_{A100}(R₁)(R₁)(R₁)(R₁)(R₁)(R₁) (R₁) to L_{A100}(R₂₁₁)(R₂₁₁)(R₂₁₁)(R₂₁₁) (R₂₁₁)(R₂₁₁)(R₂₁₁) have the structure | 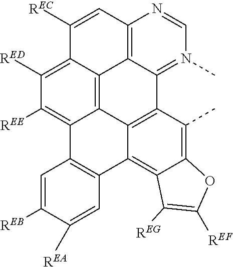 |
| L₁₀₁(R^{EA})(R^{EB})(R^{EC})(R^{ED}) (R^{EE})(R^{EF})(R^{EG}), wherein L_{A101}(R₁)(R₁)(R₁)(R₁)(R₁)(R₁) (R₁) to L_{A101}(R₂₁₁)(R₂₁₁)(R₂₁₁)(R₂₁₁) (R₂₁₁)(R₂₁₁)(R₂₁₁) have the structure | 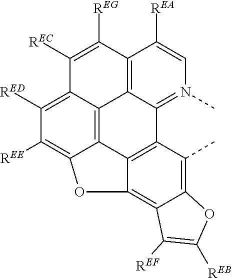 |
| L_{A102}(R^{EA})(R^{EB})(R^{EC})(R^{ED}) (R^{EE})(R^{EF})(R^{EG}), wherein L_{A102}(R₁)(R₁)(R₁)(R₁)(R₁)(R₁) (R₁) to L_{A102}(R₂₁₁)(R₂₁₁)(R₂₁₁)(R₂₁₁) (R₂₁₁)(R₂₁₁)(R₂₁₁) have the structure | 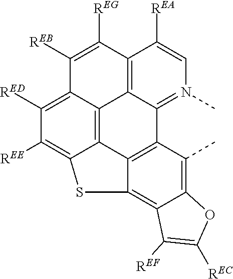 |
| L_{A103}(R^{EA})(R^{EB})(R^{EC})(R^{ED}) (R^{EE})(R^{EF})(R^{EG}), wherein L_{A103}(R₁)(R₁)(R₁)(R₁)(R₁)(R₁) (R₁) to L_{A103}(R₂₁₁)(R₂₁₁)(R₂₁₁)(R₂₁₁) (R₂₁₁)(R₂₁₁)(R₂₁₁) have the structure | 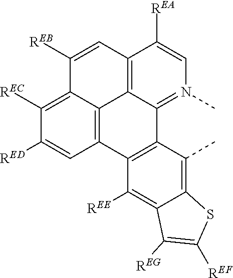 |
| L_{A104}(R^{EA})(R^{EB})(R^{EC})(R^{ED}) (R^{EE})(R^{EF})(R^{EG}), wherein L_{A104}(R₁(R₁)(R₁)(R₁)(R₁)(R₁) (R₁) to L_{A104}(R₂₁₁)(R₂₁₁)(R₂₁₁)(R₂₁₁) (R₂₁₁)(R₂₁₁)(R₂₁₁) have the structure | 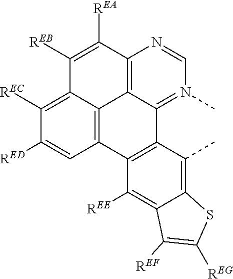 |
| L_{A105}(R^{EA})(R^{EB})(R^{EC})(R^{ED}) (R^{EE})(R^{EF})(R^{EG}), wherein L_{A105}(R₁)(R₁)(R₁)(R₁)(R₁)(R₁) (R₁) to L_{A105}(R₂₁₁)(R₂₁₁)(R₂₁₁)(R₂₁₁) (R₂₁₁)(R₂₁₁)(R₂₁₁) have the structure | 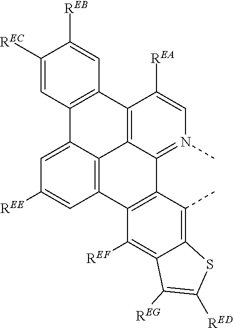 |
| L_{A106}(R^{EA})(R^{EB})(R^{EC})(R^{ED}) (R^{EE})(R^{EF})(R^{EG}), wherein L_{A106}(R₁)(R₁)(R₁)(R₁)(R₁)(R₁) (R₁) to L_{A106}(R₂₁₁)(R₂₁₁)(R₂₁₁)(R₂₁₁) (R₂₁₁)(R₂₁₁)(R₂₁₁) have the structure | 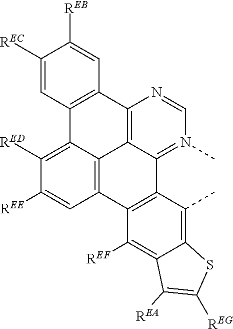 |
| L_{A107}(R^{EA})(R^{EB})(R^{EC})(R^{ED}) (R^{EE})(R^{EF})(R^{EG}), wherein L_{A107}(R₁)(R₁)(R₁)(R₁)(R₁)(R₁) (R₁) to L_{A107}(R₂₁₁)(R₂₁₁)(R₂₁₁)(R₂₁₁) (R₂₁₁)(R₂₁₁)(R₂₁₁) have the structure | 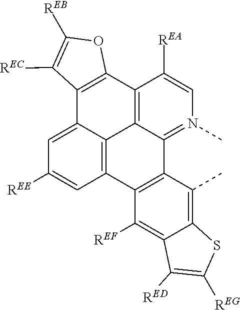 |
| L_{A108}(R^{EA})(R^{EB})(R^{EC})(R^{ED}) (R^{EE})(R^{EF})(R^{EG}), wherein L_{A108}(R₁)(R₁)(R₁)(R₁)(R₁)(R₁) (R₁) to L_{A108}(R₂₁₁)(R₂₁₁)(R₂₁₁)(R₂₁₁) (R₂₁₁)(R₂₁₁)(R₂₁₁) have the structure | 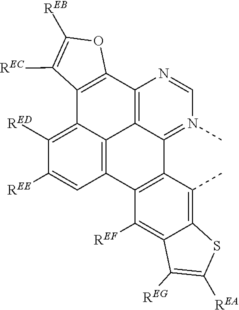 |
| L_{A109}(R^{EA})(R^{EB})(R^{EC})(R^{ED}) (R^{EE})(R^{EF})(R^{EG}), wherein L_{A109}(R₁)(R₁)(R₁)(R₁)(R₁)(R₁) (R₁) to L_{A109}(R₂₁₁)(R₂₁₁)(R₂₁₁)(R₂₁₁) (R₂₁₁)(R₂₁₁)(R₂₁₁) have the structure | 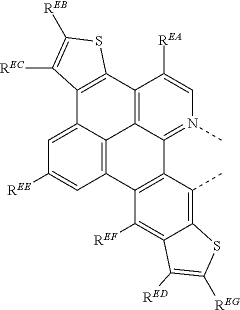 |
| L_{A110}(R^{EA})(R^{EB})(R^{EC})(R^{ED}) (R^{EE})(R^{EF})(R^{EG}), wherein L_{A110}(R₁)(R₁)(R₁)(R₁)(R₁)(R₁) (R₁) to L_{A110}(R₂₁₁)(R₂₁₁)(R₂₁₁)(R₂₁₁) (R₂₁₁)(R₂₁₁)(R₂₁₁) have the structure | 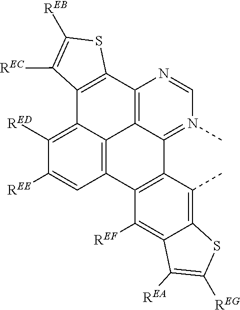 |
| L_{A111}(R^{EA})(R^{EB})(R^{EC})(R^{ED}) (R^{EE})(R^{EF})(R^{EG}), wherein L_{A111}(R₁)(R₁)(R₁)(R₁)(R₁)(R₁) (R₁) to L_{A111}(R₂₁₁)(R₂₁₁)(R₂₁₁)(R₂₁₁) (R₂₁₁)(R₂₁₁)(R₂₁₁) have the structure | 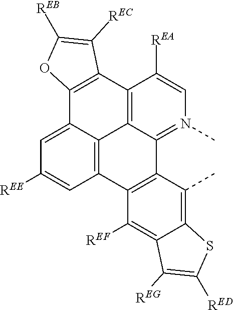 |
| L_{A112}(R^{EA})(R^{EB})(R^{EC})(R^{ED}) (R^{EE})(R^{EF})(R^{EG}), wherein L_{A112}(R₁)(R₁)(R₁)(R₁)(R₁)(R₁) (R₁) to L_{A112}(R₂₁₁)(R₂₁₁)(R₂₁₁)(R₂₁₁) (R₂₁₁)(R₂₁₁)(R₂₁₁) have the structure | 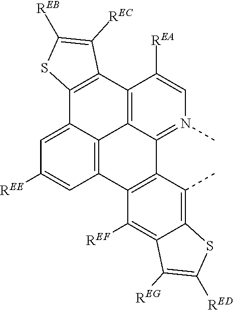 |
| L_{A113}(R^{EA})(R^{EB})(R^{EC})(R^{ED}) (R^{EE})(R^{EF})(R^{EG}), wherein L_{A113}(R₁)(R₁)(R₁)(R₁)(R₁)(R₁) (R₁) to L_{A113}(R₂₁₁)(R₂₁₁)(R₂₁₁)(R₂₁₁) (R₂₁₁)(R₂₁₁)(R₂₁₁) have the structure | 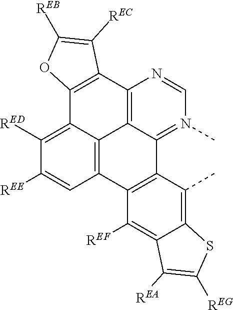 |
| L_{A114}(R^{EA})(R^{EB})(R^{EC})(R^{ED}) (R^{EE})(R^{EF})(R^{EG}), wherein L_{A114}(R₁)(R₁)(R₁)(R₁)(R₁)(R₁) (R₁) to L_{A114}(R₂₁₁)(R₂₁₁)(R₂₁₁)(R₂₁₁) (R₂₁₁)(R₂₁₁)(R₂₁₁) have the structure | 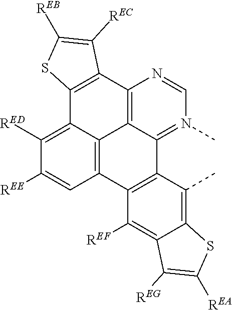 |
| L_{A115}(R^{EA})(R^{EB})(R^{EC})(R^{ED}) (R^{EE})(R^{EF})(R^{EG}), wherein L_{A115}(R₁)(R₁)(R₁)(R₁)(R₁)(R₁) (R₁) to L_{A115}(R₂₁₁)(R₂₁₁)(R₂₁₁)(R₂₁₁) (R₂₁₁)(R₂₁₁)(R₂₁₁) have the structure | 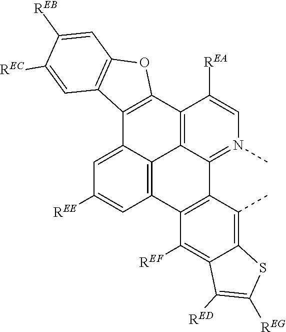 |
| L_{A116}(R^{EA})(R^{EB})(R^{EC})(R^{ED}) (R^{EE})(R^{EF})(R^{EG}), wherein L_{A116}(R₁)(R₁)(R₁)(R₁)(R₁)(R₁) (R₁) to L_{A116}(R₂₁₁)(R₂₁₁)(R₂₁₁)(R₂₁₁) (R₂₁₁)(R₂₁₁)(R₂₁₁) have the structure | 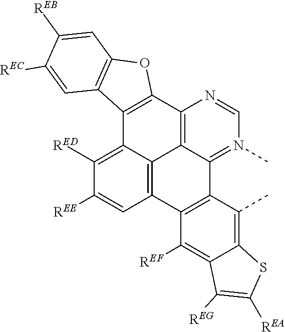 |
| L_{A117}(R^{EA})(R^{EB})(R^{EC})(R^{ED}) (R^{EE})(R^{EF})(R^{EG}), wherein L_{A117}(R₁)(R₁)(R₁)(R₁)(R₁)(R₁) (R₁) to L_{A117}(R₂₁₁)(R₂₁₁)(R₂₁₁)(R₂₁₁) (R₂₁₁)(R₂₁₁)(R₂₁₁) have the structure | 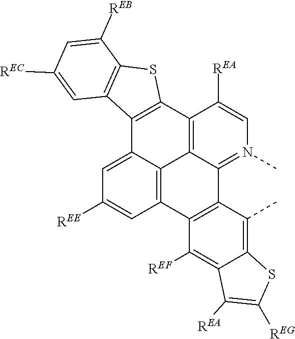 |
| L_{A118}(R^{EA})(R^{EB})(R^{EC})(R^{ED}) (R^{EE})(R^{EF})(R^{EG}), wherein L_{A118}(R₁)(R₁)(R₁)(R₁)(R₁)(R₁) (R₁) to L_{A118}(R₂₁₁)(R₂₁₁)(R₂₁₁)(R₂₁₁) (R₂₁₁)(R₂₁₁)(R₂₁₁) have the structure | 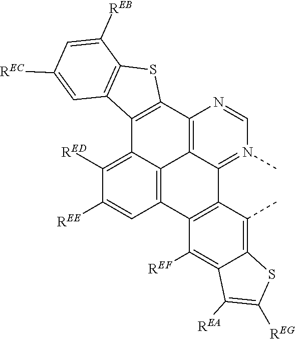 |
| L_{A119}(R^{EA})(R^{EB})(R^{EC})(R^{ED}) (R^{EE})(R^{EF})(R^{EG}), wherein L_{A119}(R₁)(R₁)(R₁)(R₁)(R₁)(R₁) (R₁) to L_{A119}(R₂₁₁)(R₂₁₁)(R₂₁₁)(R₂₁₁) (R₂₁₁)(R₂₁₁)(R₂₁₁) have the structure | 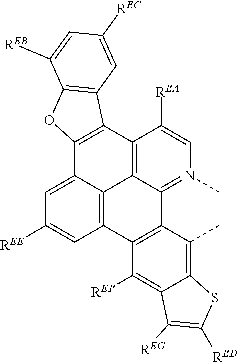 |
| L_{A120}(R^{EA})(R^{EB})(R^{EC})(R^{ED}) (R^{EE})(R^{EF})(R^{EG}), wherein L_{A120}(R₁)(R₁)(R₁)(R₁)(R₁)(R₁) (R₁) to L_{A120}(R₂₁₁)(R₂₁₁)(R₂₁₁)(R₂₁₁) (R₂₁₁)(R₂₁₁)(R₂₁₁) have the structure | 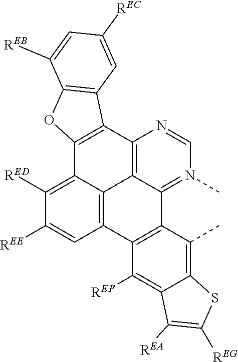 |
| L_{A121}(R^{EA})(R^{EB})(R^{EC})(R^{ED}) (R^{EE})(R^{EF})(R^{EG}), wherein L_{A121}(R₁)(R₁)(R₁)(R₁)(R₁)(R₁) (R₁) to L_{A121}(R₂₁₁)(R₂₁₁)(R₂₁₁)(R₂₁₁) (R₂₁₁)(R₂₁₁)(R₂₁₁) have the structure | 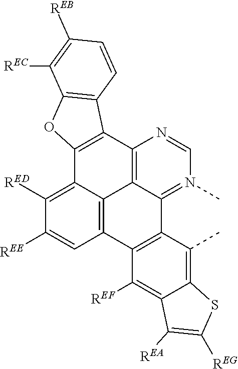 |
| L_{A122}(R^{EA})(R^{EB})(R^{EC})(R^{ED}) (R^{EE})(R^{EF})(R^{EG}), wherein L_{A122}(R₁)(R₁)(R₁)(R₁)(R₁)(R₁) (R₁) to L_{A122}(R₂₁₁)(R₂₁₁)(R₂₁₁)(R₂₁₁) (R₂₁₁)(R₂₁₁)(R₂₁₁) have the structure | 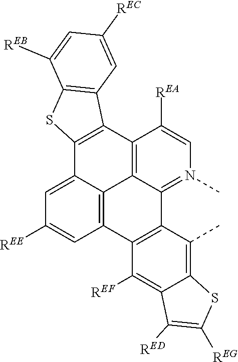 |
| L_{A123}(R^{EA})(R^{EB})(R^{EC})(R^{ED}) (R^{EE})(R^{EF})(R^{EG}), wherein L_{A123}(R₁)(R₁)(R₁)(R₁)(R₁)(R₁) (R₁) to L_{A123}(R₂₁₁)(R₂₁₁)(R₂₁₁)(R₂₁₁) (R₂₁₁)(R₂₁₁)(R₂₁₁) have the structure | 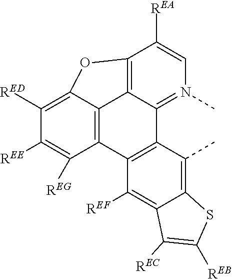 |
| L_{A124}(R^{EA})(R^{EB})(R^{EC})(R^{ED}) (R^{EE})(R^{EF})(R^{EG}), wherein L_{A124}(R₁)(R₁)(R₁)(R₁)(R₁)(R₁) (R₁) to L_{A124}(R₂₁₁)(R₂₁₁)(R₂₁₁)(R₂₁₁) (R₂₁₁)(R₁₁)(R₂₁₁) have the structure | 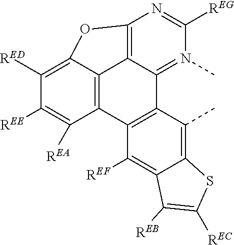 |
| L_{A125}(R^{EA})(R^{EB})(R^{EC})(R^{ED}) (R^{EE})(R^{EF})(R^{EG}), wherein L_{A125}(R₁)(R₁)(R₁)(R₁)(R₁)(R₁) (R₁) to L_{A125}(R₂₁₁)(R₂₁₁)(R₂₁₁)(R₂₁₁) (R₂₁₁)(R₂₁₁)(R₂₁₁) have the structure | 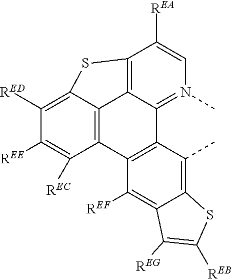 |
| L_{A126}(R^{EA})(R^{EB})(R^{EC})(R^{ED}) (R^{EE})(R^{EF})(R^{EG}), wherein L_{A126}(R₁)(R₁)(R₁)(R₁)(R₁)(R₁) (R₁) to L_{A126}(R₂₁₁)(R₂₁₁)(R₂₁₁)(R₂₁₁) (R₂₁₁)(R₂₁₁)(R₂₁₁) have the structure | 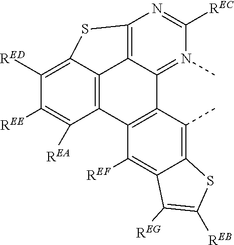 |
| L_{A127}(R^{EA})(R^{EB})(R^{EC})(R^{ED}) (R^{EE})(R^{EF})(R^{EG}), wherein L_{A127}(R₁)(R₁)(R₁)(R₁)(R₁)(R₁) (R₁) to L_{A127}(R₂₁₁)(R₂₁₁)(R₂₁₁)(R₂₁₁) (R₂₁₁)(R₂₁₁)(R₂₁₁) have the structure | 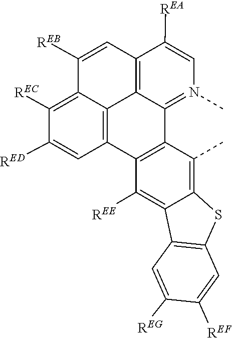 |
| L_{A128}(R^{EA})(R^{EB})(R^{EC})(R^{ED}) (R^{EE})(R^{EF})(R^{EG}), wherein L_{A128}(R₁)(R₁)(R₁)(R₁)(R₁)(R₁) (R₁) to L_{A128}(R₂₁₁)(R₂₁₁)(R₂₁₁)(R₂₁₁) (R₂₁₁)(R₂₁₁)(R₂₁₁) have the structure | 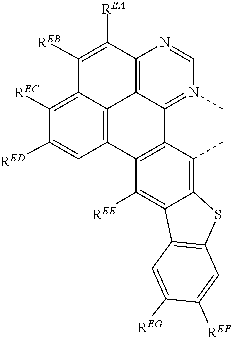 |
| L_{A129}(R^{EA})(R^{EB})(R^{EC})(R^{ED}) (R^{EE})(R^{EF})(R^{EG}), wherein L_{A129}(R₁)(R₁)(R₁)(R₁)(R₁)(R₁) (R₁) to L_{A129}(R₂₁₁)(R₂₁₁)(R₂₁₁)(R₂₁₁) (R₂₁₁)(R₂₁₁)(R₂₁₁) have the structure | 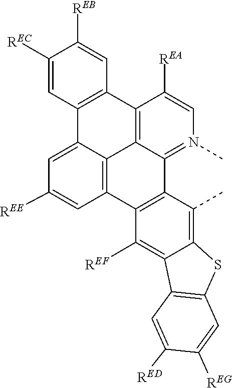 |
| L_{A130}(R^{EA})(R^{EB})(R^{EC})(R^{ED}) (R^{EE})(R^{EF})(R^{EG}), wherein L_{A130}(R₁)(R₁)(R₁)(R₁)(R₁)(R₁) (R₁) to L_{A130}(R₂₁₁)(R₂₁₁)(R₂₁₁)(R₂₁₁) (R₂₁₁)(R₂₁₁)(R₂₁₁) have the structure | 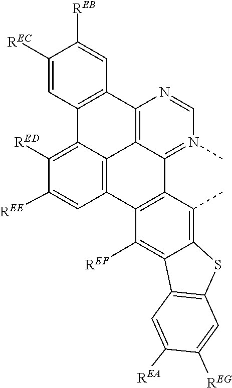 |
| L_{A131}(R^{EA})(R^{EB})(R^{EC})(R^{ED}) (R^{EE})(R^{EF})(R^{EG}), wherein L_{A131}(R₁)(R₁)(R₁)(R₁)(R₁)(R₁) (R₁) to L_{A131}(R₂₁₁)(R₂₁₁)(R₂₁₁)(R₂₁₁) (R₂₁₁)(R₂₁₁)(R₂₁₁) have the structure | 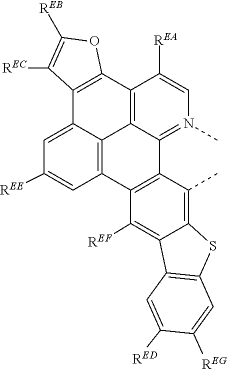 |
| L_{A132} (R^{EA})(R^{EB})(R^{EC})(R^{ED})(R^{EE}) (R^{EF})(R^{EG}), wherein L_{A132}(R₁)(R₁)(R₁)(R₁)(R₁)(R₁) (R₁) to L_{A132}(R₂₁₁)(R₂₁₁)(R₂₁₁)(R₂₁₁) (R₂₁₁)(R₂₁₁)(R₂₁₁) have the structure | 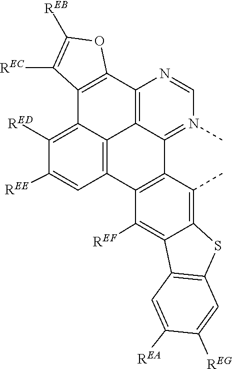 |
| L_{A133}(R^{EA})(R^{EB})(R^{EC})(R^{ED}) (R^{EE})(R^{EF})(R^{EG}), wherein L_{A133}(R₁)(R₁)(R₁)(R₁)(R₁)(R₁) (R₁) to L_{A133}(R₂₁₁)(R₂₁₁)(R₂₁₁)(R₂₁₁) (R₂₁₁)(R₂₁₁)(R₂₁₁) have the structure | 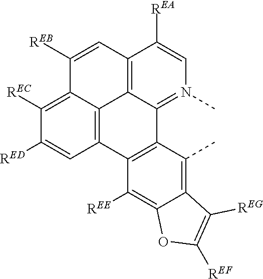 |
| L_{A134}(R^{EA})(R^{EB})(R^{EC})(R^{ED}) (R^{EE})(R^{EF})(R^{EG}), wherein L_{A134}(R₁)(R₁)(R₁)(R₁)(R₁)(R₁) (R₁) to L₁₃₄(R₂₁₁)(R₂₁₁)(R₂₁₁)(R₂₁₁) (R₂₁₁)(R₂₁₁)(R₂₁₁) have the structure | 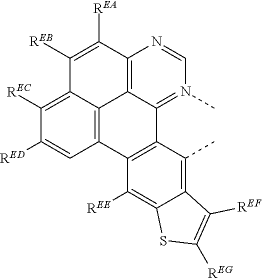 |
| L_{A135}(R^{EA})(R^{EB})(R^{EC})(R^{ED}) (R^{EE})(R^{EF})(R^{EG}), wherein L_{A135}(R₁(R₁)(R₁)(R₁)(R₁)(R₁) (R₁) to L_{A135}(R₂₁₁)(R₂₁₁)(R₂₁₁)(R₂₁₁) (R₂₁₁)(R₂₁₁)(R₂₁₁) have the structure | 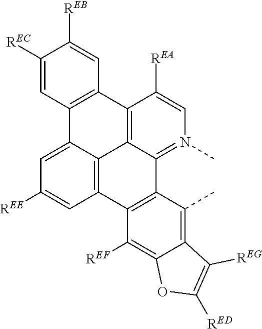 |
| L_{A136}(R^{EA})(R^{EB})(R^{EC})(R^{ED}) (R^{EE})(R^{EF})(R^{EG}), wherein L_{A136}(R₁)(R₁)(R₁)(R₁)(R₁)(R₁) (R₁) to L_{A136}(R₂₁₁)(R₂₁₁)(R₂₁₁)(R₂₁₁) (R₂₁₁)(R₂₁₁)(R₂₁₁) have the structure | 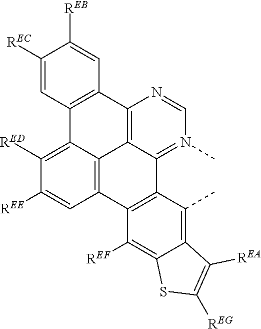 |
| L_{A137}(R^{EA})(R^{EB})(R^{EC})(R^{ED}) (R^{EE})(R^{EF})(R^{EG}), wherein L_{A137}(R₁)(R₁)(R₁)(R₁)(R₁)(R₁) (R₁) to L_{A137}(R₂₁₁)(R₂₁₁)(R₂₁₁)(R₂₁₁) (R₂₁₁)(R₂₁₁)(R₂₁₁) have the structure | 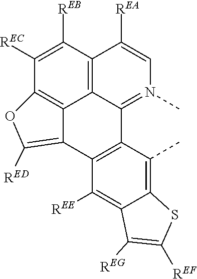 |
| L_{A138}(R^{EA})(R^{EB})(R^{EC})(R^{ED}) (R^{EE})(R^{EF})(R^{EG}), wherein L_{A138}(R₁)(R₁)(R₁)(R₁)(R₁)(R₁) (R₁) to L_{A138}(R₂₁₁)(R₂₁₁)(R₂₁₁)(R₂₁₁) (R₂₁₁)(R₂₁₁)(R₂₁₁) have the structure | 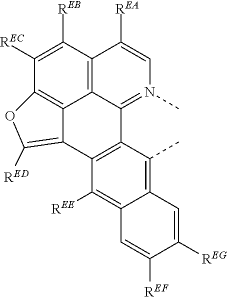 |
| L_{A139}(R^{EA})(R^{EB})(R^{EC})(R^{ED}) (R^{EE})(R^{EF})(R^{EG}), wherein L_{A139}(R₁)(R₁)(R₁)(R₁)(R₁)(R₁) (R₁) to L_{A139}(R₂₁₁)(R₂₁₁)(R₂₁₁)(R₂₁₁) (R₂₁₁)(R₂₁₁)(R₂₁₁) have the structure | 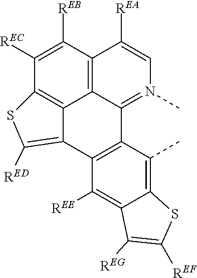 |
| L_{A140}(R^{EA})(R^{EB})(R^{EC})(R^{ED}) (R^{EE})(R^{EF})(R^{EG}), wherein L_{A140}(R₁)(R₁)(R₁)(R₁)(R₁)(R₁) (R₁) to L_{A140}(R₂₁₁)(R₂₁₁)(R₂₁₁)(R₂₁₁) (R₂₁₁)(R₂₁₁)(R₂₁₁) have the structure | 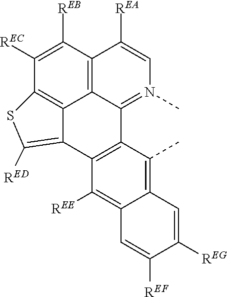 |
| L_{A141}(R^{EA})(R^{EB})(R^{EC})(R^{ED}) (R^{EE})(R^{EF})(R^{EG}), wherein L_{A141}(R₁)(R₁)(R₁)(R₁)(R₁)(R₁) (R₁) to L_{A141}(R₂₁₁)(R₂₁₁)(R₂₁₁)(R₂₁₁) (R₂₁₁)(R₂₁₁)(R₂₁₁) have the structure | 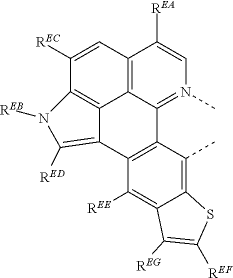 |
| L_{A142}(R^{EA})(R^{EB})(R^{EC})(R^{ED}) (R^{EE})(R^{EF})(R^{EG}), wherein L_{A142}(R₁)(R₁)(R₁)(R₁)(R₁)(R₁) (R₁) to L_{A142}(R₂₁₁)(R₂₁₁)(R₂₁₁)(R₂₁₁) (R₂₁₁)(R₂₁₁)(R₂₁₁) have the structure | 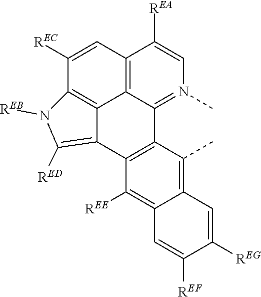 |
| L_{A143}(R^{EA})(R^{EB})(R^{EC})(R^{ED}) (R^{EE})(R^{EF})(R^{EG}), wherein L_{A143}(R₁)(R₁)(R₁)(R₁)(R₁)(R₁) (R₁) to L₁₄₃(R₂₁₁)(R₂₁₁)(R₂₁₁)(R₂₁₁) (R₂₁₁)(R₂₁₁)(R₂₁₁) have the structure | 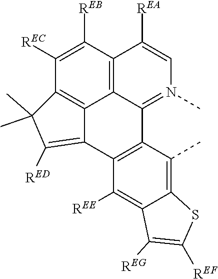 |
| L_{A144}(R^{EA})(R^{EB})(R^{EC})(R^{ED}) (R^{EE})(R^{EF})(R^{EG}), wherein L_{A144}(R₁)(R₁)(R₁)(R₁)(R₁)(R₁) (R₁) to L_{A144}(R₂₁₁)(R₂₁₁)(R₂₁₁)(R₂₁₁) (R₂₁₁)(R₂₁₁)(R₂₁₁) have the structure | 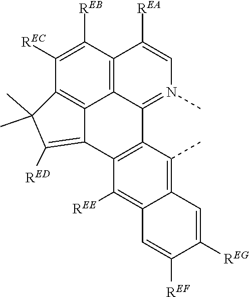 |
| L_{A145}(R^{EA})(R^{EB})(R^{EC})(R^{ED}) (R^{EE})(R^{EF})(R^{EG}), wherein L_{A145}(R₁)(R₁)(R₁)(R₁)(R₁)(R₁) (R₁) to L_{A145}(R₂₁₁)(R₂₁₁)(R₂₁₁)(R₂₁₁) (R₂₁₁)(R₂₁₁)(R₂₁₁) have the structure | 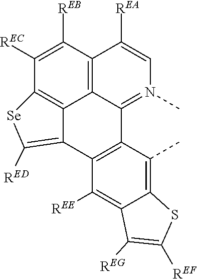 |
| L_{A146}(R^{EA})(R^{EB})(R^{EC})(R^{ED}) (R^{EE})(R^{EF})(R^{EG}), wherein L_{A146}(R₁)(R₁)(R₁)(R₁)(R₁)(R₁) (R₁) to L_{A146}(R₂₁₁)(R₂₁₁)(R₂₁₁)(R₂₁₁) (R₂₁₁)(R₂₁₁)(R₂₁₁) have the structure | 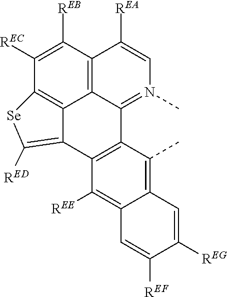 |
| L_{A147}(R^{EA})(R^{EB})(R^{EC})(R^{ED}) (R^{EE})(R^{EF})(R^{EG}), wherein L_{A147}(R₁)(R₁)(R₁)(R₁)(R₁)(R₁) (R₁) to L_{A147}(R₂₁₁)(R₂₁₁)(R₂₁₁)(R₂₁₁) (R₂₁₁)(R₂₁₁)(R₂₁₁) have the structure | 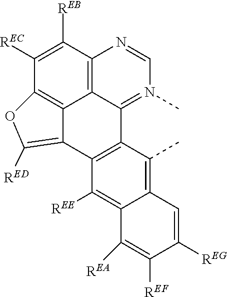 |
| L_{A148}(R^{EA})(R^{EB})(R^{EC})(R^{ED}) (R^{EE})(R^{EF})(R^{EG}), wherein L_{A148}(R₁)(R₁)(R₁)(R₁)(R₁)(R₁) (R₁) to L_{A148}(R₂₁₁)(R₂₁₁)(R₂₁₁)(R₂₁₁) (R₂₁₁)(R₂₁₁)(R₂₁₁) have the structure | 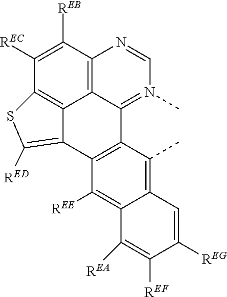 |
| L_{A149}(R^{EA})(R^{EB})(R^{EC})(R^{ED}) (R^{EE})(R^{EF})(R^{EG}), wherein L_{A149}(R₁)(R₁)(R₁)(R₁)(R₁)(R₁) (R₁) to L_{A149}(R₂₁₁)(R₂₁₁)(R₂₁₁)(R₂₁₁) (R₂₁₁)(R₂₁₁)(R₂₁₁) have the structure | 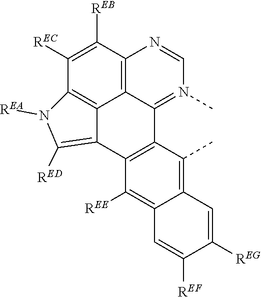 |
| L_{A150}(R^{EA})(R^{EB})(R^{EC})(R^{ED}) (R^{EE})(R^{EF})(R^{EG}), wherein L_{A150}(R₁)(R₁)(R₁)(R₁)(R₁)(R₁) (R₁) to L_{A150}(R₂₁₁)(R₂₁₁)(R₂₁₁)(R₂₁₁) (R₂₁₁)(R₂₁₁)(R₂₁₁) have the structure | 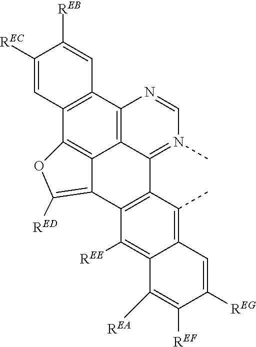 |
| L_{A151}(R^{EA})(R^{EB})(R^{EC})(R^{ED}) (R^{EE})(R^{EF})(R^{EG}), wherein L_{A151}(R₁)(R₁)(R₁)(R₁)(R₁)(R₁) (R₁) to L_{A151}(R₂₁₁)(R₂₁₁)(R₂₁₁)(R₂₁₁) (R₂₁₁)(R₂₁₁)(R₂₁₁) have the structure | 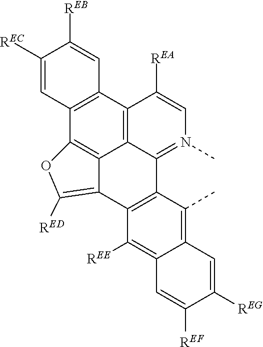 |
| L_{A152}(R^{EA})(R^{EB})(R^{EC})(R^{ED}) (R^{EE})(R^{EF})(R^{EG}), wherein L_{A152}(R₁)(R₁)(R₁)(R₁)(R₁)(R₁) (R₁) to L_{A152}(R₂₁₁)(R₂₁₁)(R₂₁₁)(R₂₁₁) (R₂₁₁)(R₂₁₁)(R₂₁₁) have the structure | 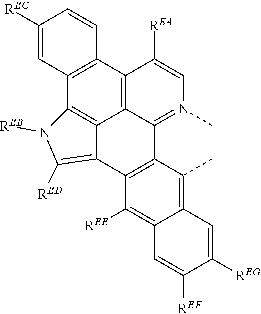 |
| L_{A153}(R^{EA})(R^{EB})(R^{EC})(R^{ED}) (R^{EE})(R^{EF})(R^{EG}), wherein L_{A153}(R₁)(R₁)(R₁)(R₁)(R₁)(R₁) (R₁) to L_{A153}(R₂₁₁)(R₂₁₁)(R₂₁₁)(R₂₁₁) (R₂₁₁)(R₂₁₁)(R₂₁₁) have the structure | 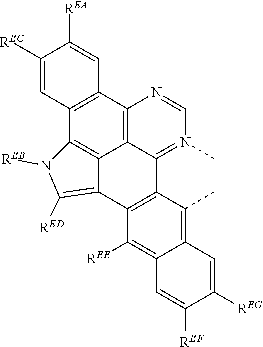 |
| L_{A154}(R^{EA})(R^{EB})(R^{EC})(R^{ED}) (R^{EE})(R^{EF})(R^{EG}), wherein L_{A154}(R₁)(R₁)(R₁)(R₁)(R₁)(R₁) (R₁) to L_{A154}(R₂₁₁)(R₂₁₁)(R₂₁₁)(R₂₁₁) (R₂₁₁)(R₂₁₁)(R₂₁₁) have the structure | 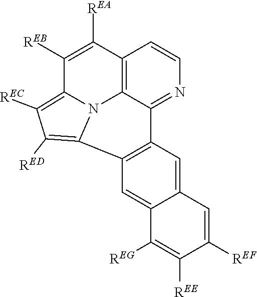 |
| L_{A155}(R^{EA})(R^{EB})(R^{EC})(R^{ED}) (R^{EE})(R^{EF})(R^{EG}), wherein L_{A155}(R₁)(R₁)(R₁)(R₁)(R₁)(R₁) (R₁) to L_{A155}(R₂₁₁)(R₂₁₁)(R₂₁₁)(R₂₁₁) (R₂₁₁)(R₂₁₁)(R₂₁₁) have the structure | 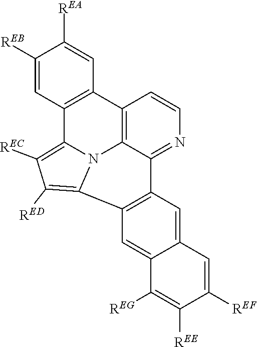 |
| L_{A156}(R^{EA})(R^{EB})(R^{EC})(R^{ED}) (R^{EE})(R^{EF})(R^{EG}), wherein L_{A156}(R₁)(R₁)(R₁)(R₁)(R₁)(R₁) (R₁) to L_{A156}(R₂₁₁)(R₂₁₁)(R₂₁₁)(R₂₁₁) (R₂₁₁)(R₂₁₁)(R₂₁₁) have the structure | 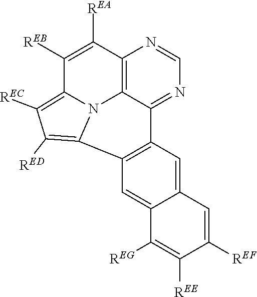 |
| L_{A157}(R^{EA})(R^{EB})(R^{EC})(R^{ED}) (R^{EE})(R^{EF})(R^{EG}), wherein L_{A157}(R₁)(R₁)(R₁)(R₁)(R₁)(R₁) (R₁) to L_{A157}(R₂₁₁)(R₂₁₁)(R₂₁₁)(R₂₁₁) (R₂₁₁)(R₂₁₁)(R₂₁₁) have the structure | 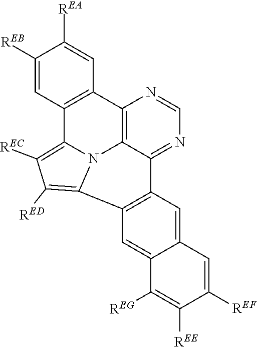 |
| L_{A158}(R^{EA})(R^{EB})(R^{EC})(R^{ED}) (R^{EE})(R^{EF})(R^{EG}), wherein L_{A158}(R₁)(R₁)(R₁)(R₁)(R₁)(R₁) (R₁) to L_{A158}(R₂₁₁)(R₂₁₁)(R₂₁₁)(R₂₁₁) (R₂₁₁)(R₂₁₁)(R₂₁₁) have the structure | 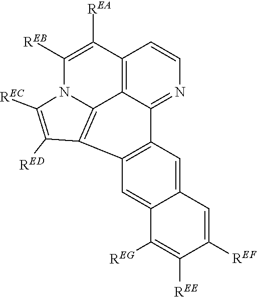 |
| L_{A159}(R^{EA})(R^{EB})(R^{EC})(R^{ED}) (R^{EE})(R^{EF})(R^{EG}), wherein L_{A159}(R₁)(R₁)(R₁)(R₁)(R₁)(R₁) (R₁) to L_{A159}(R₂₁₁)(R₂₁₁)(R₂₁₁)(R₂₁₁) (R₂₁₁)(R₂₁₁)(R₂₁₁) have the structure | 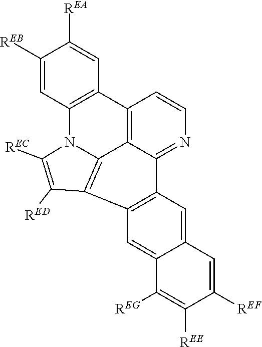 |
| L_{A160}(R^{EA})(R^{EB})(R^{EC})(R^{ED}) (R^{EE})(R^{EF})(R^{EG}), wherein L_{A160}(R₁)(R₁)(R₁)(R₁)(R₁)(R₁) (R₁) to L_{A160}(R₂₁₁)(R₂₁₁)(R₂₁₁)(R₂₁₁) (R₂₁₁)(R₂₁₁)(R₂₁₁) have the structure | 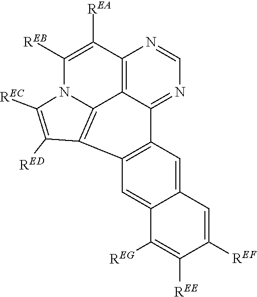 |
| L_{A161}(R^{EA})(R^{EB})(R^{EC})(R^{ED}) (R^{EE})(R^{EF})(R^{EG}), wherein L_{A161}(R₁)(R₁)(R₁)(R₁)(R₁)(R₁) (R₁) to L_{A161}(R₂₁₁)(R₂₁₁)(R₂₁₁)(R₂₁₁) (R₂₁₁)(R₂₁₁)(R₂₁₁) have the structure | 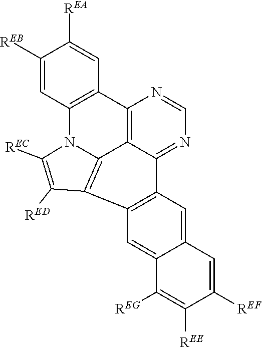 |

wherein R₁ to R₂₁₁ have the structures in the following LIST 4:

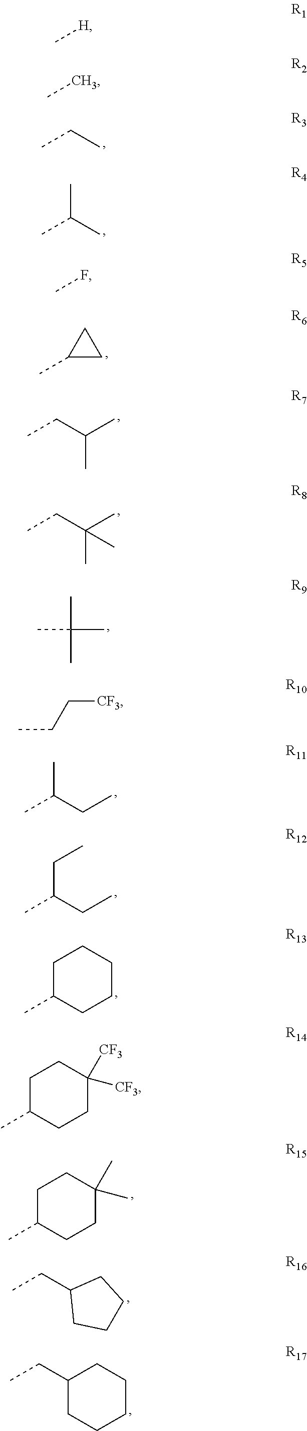

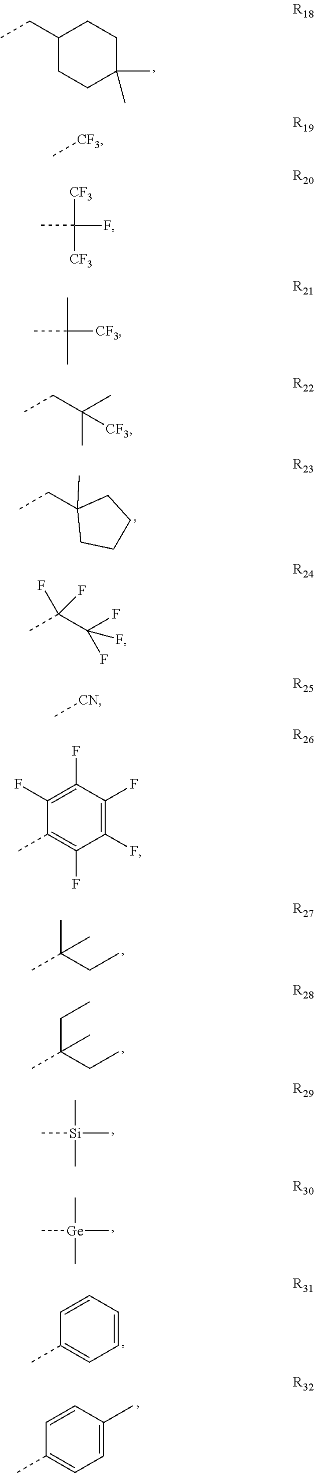

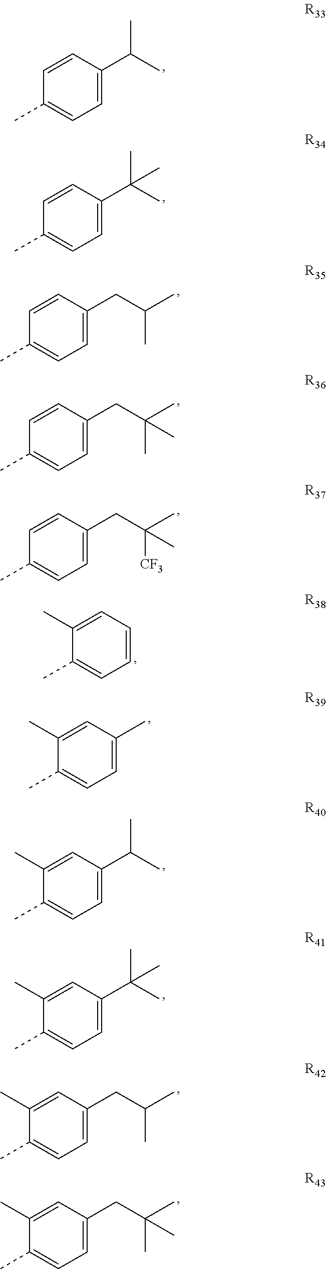

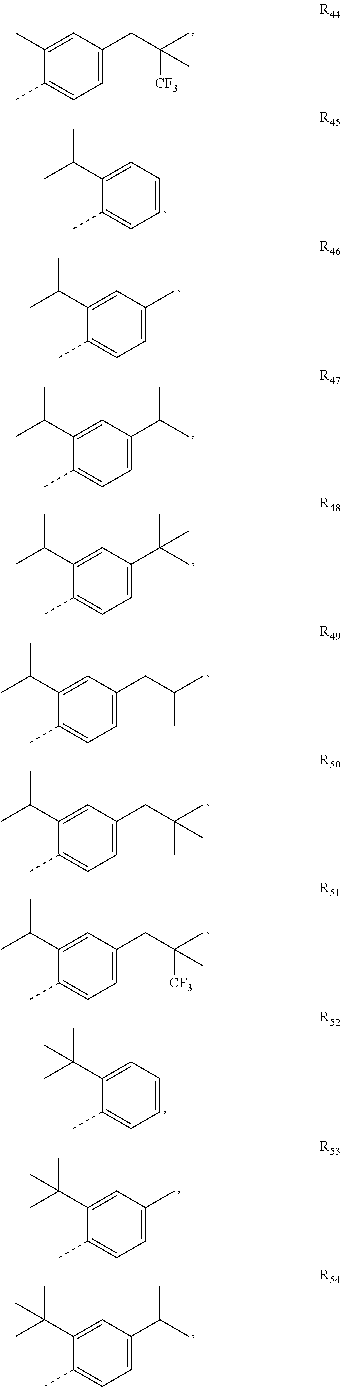

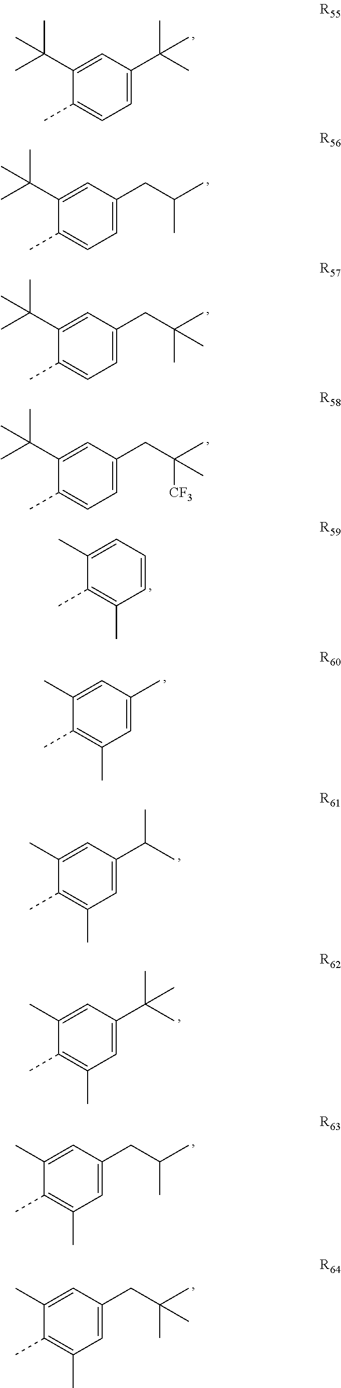

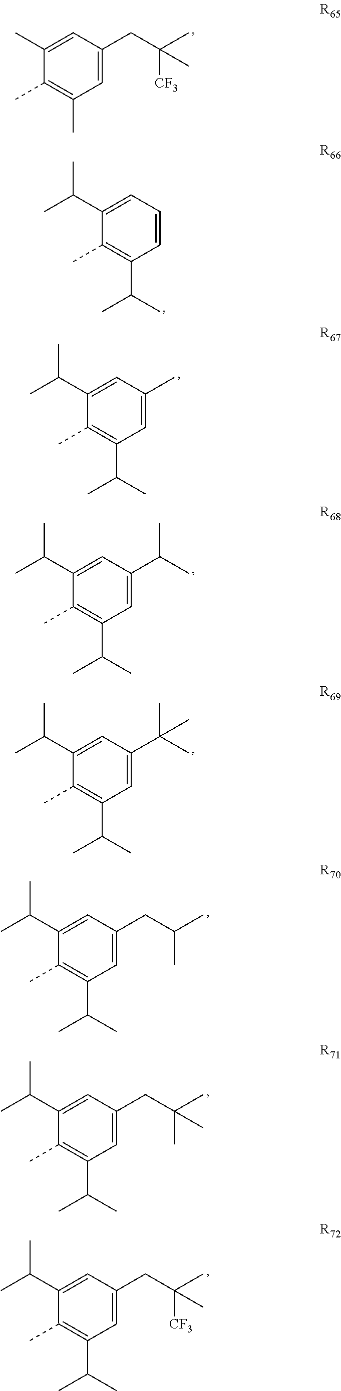

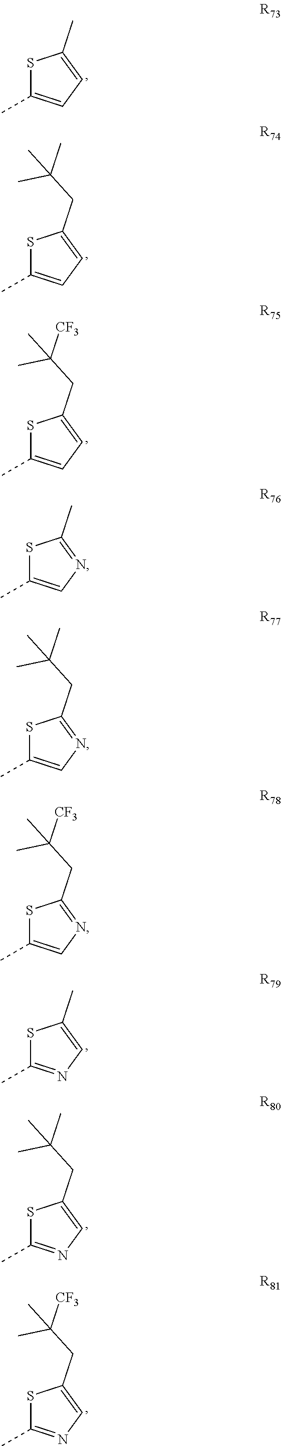

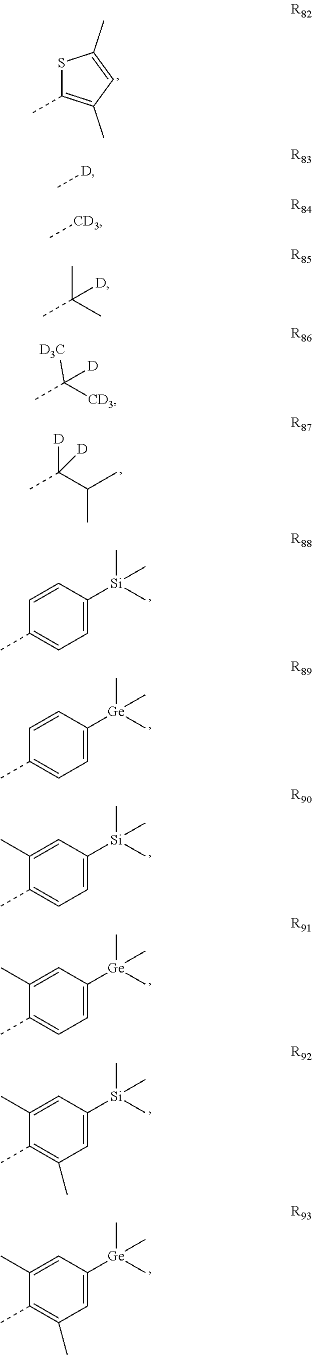

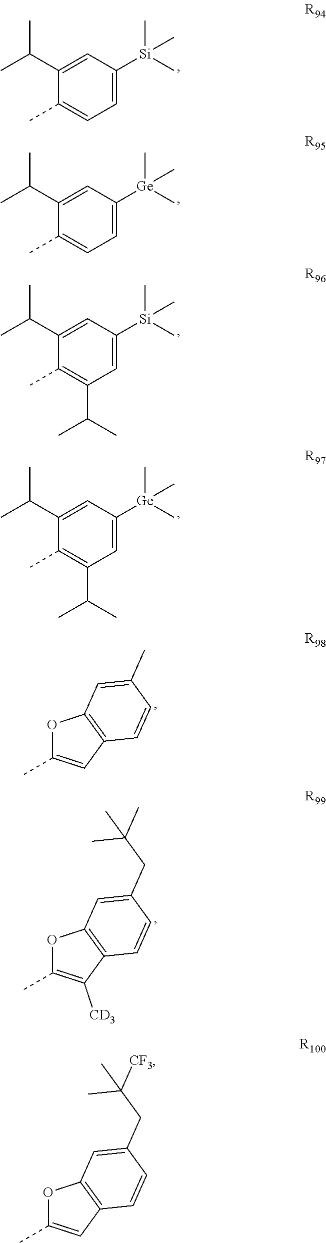

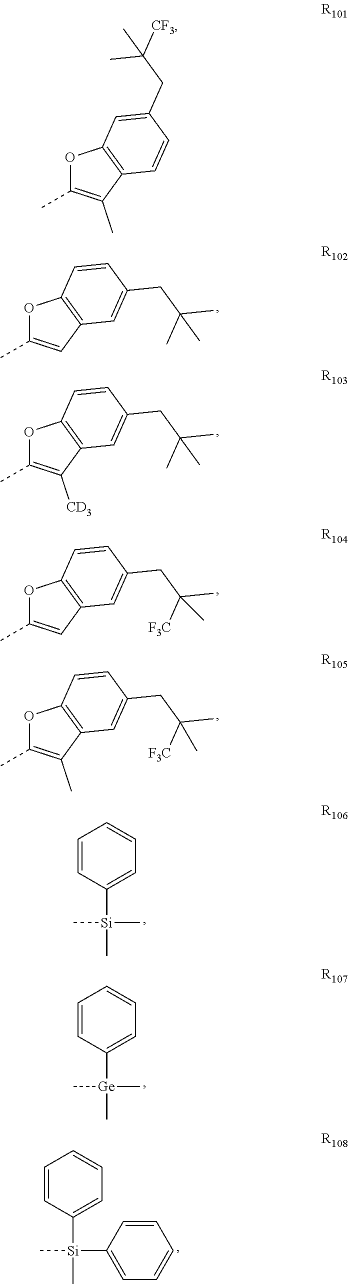

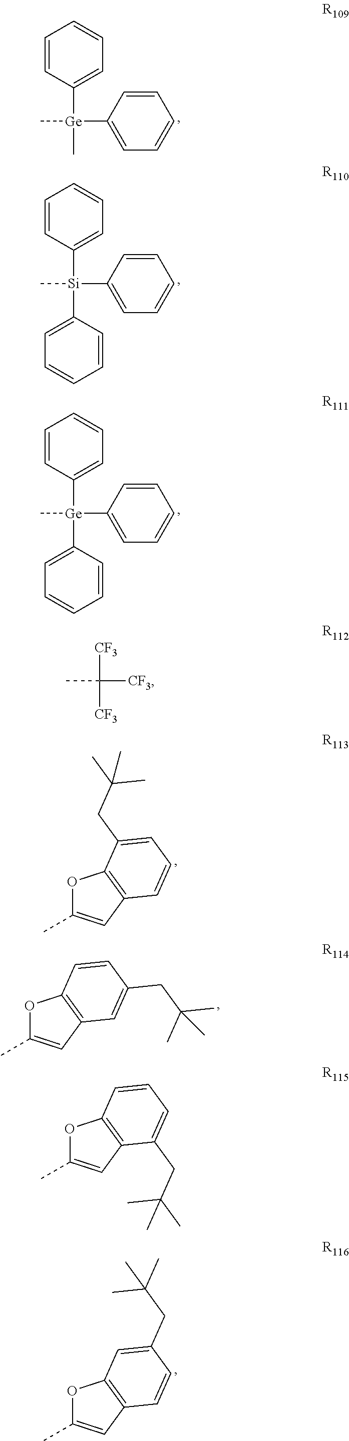

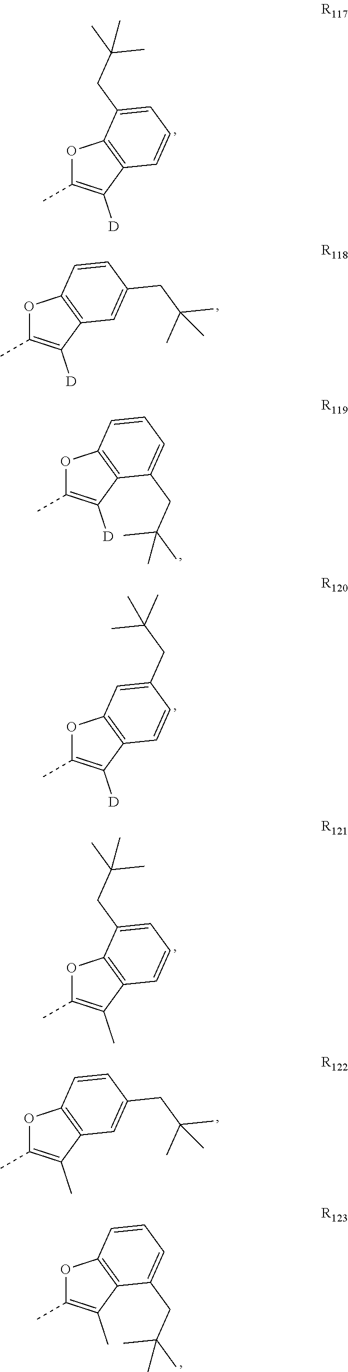

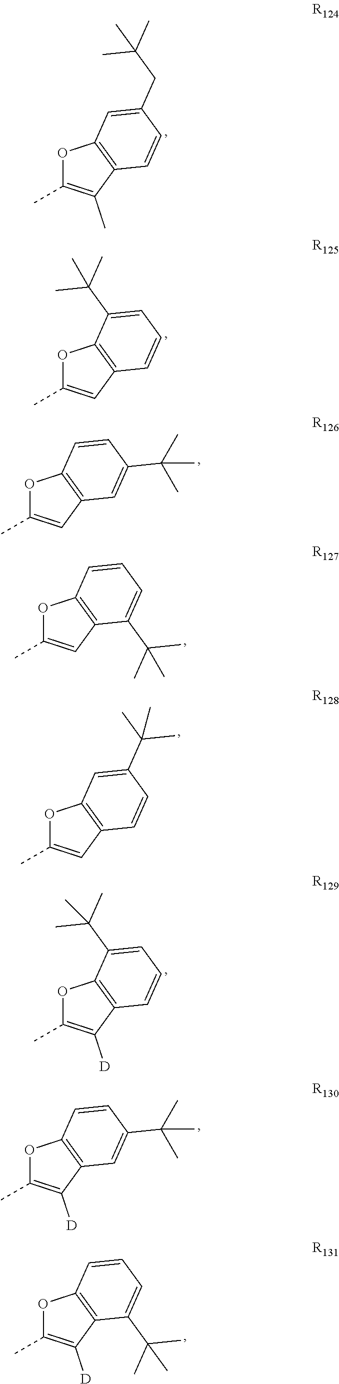

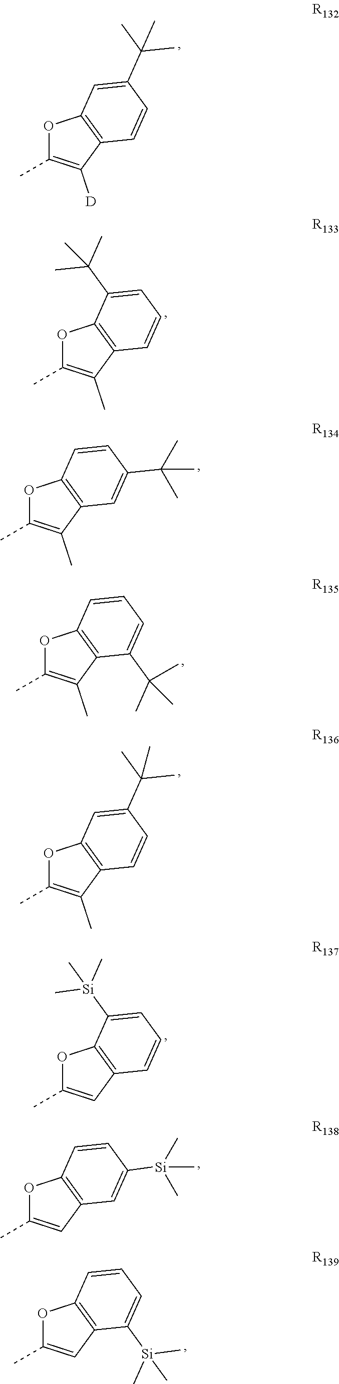

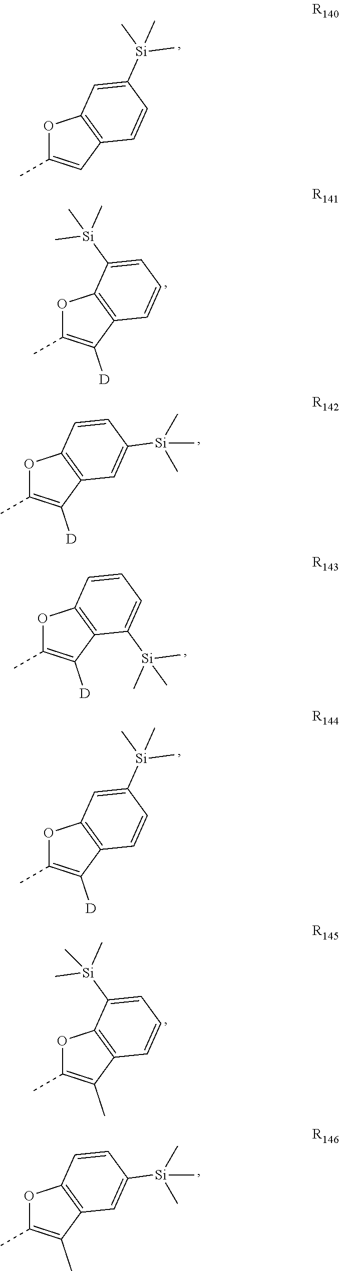

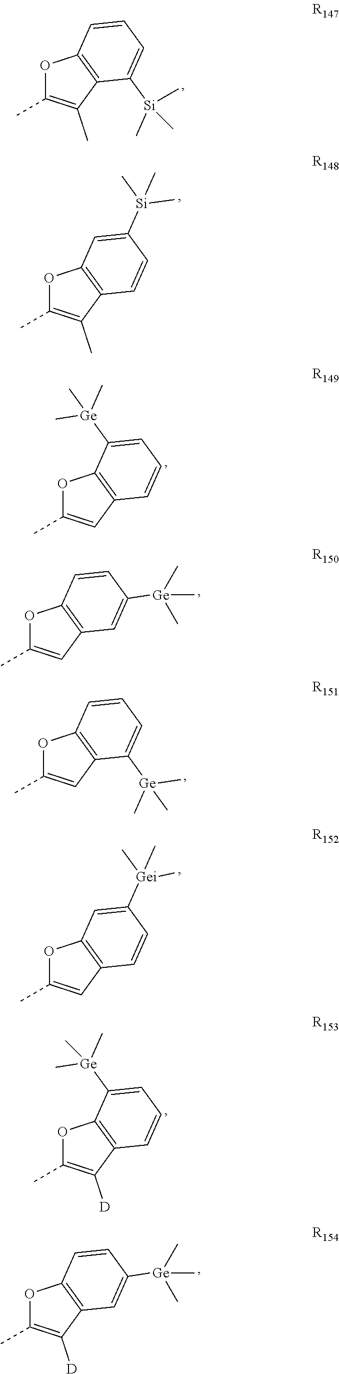

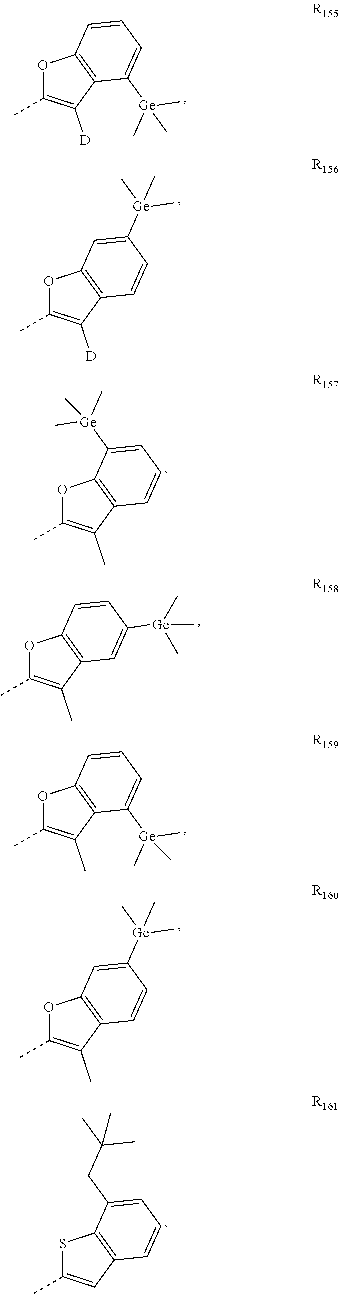

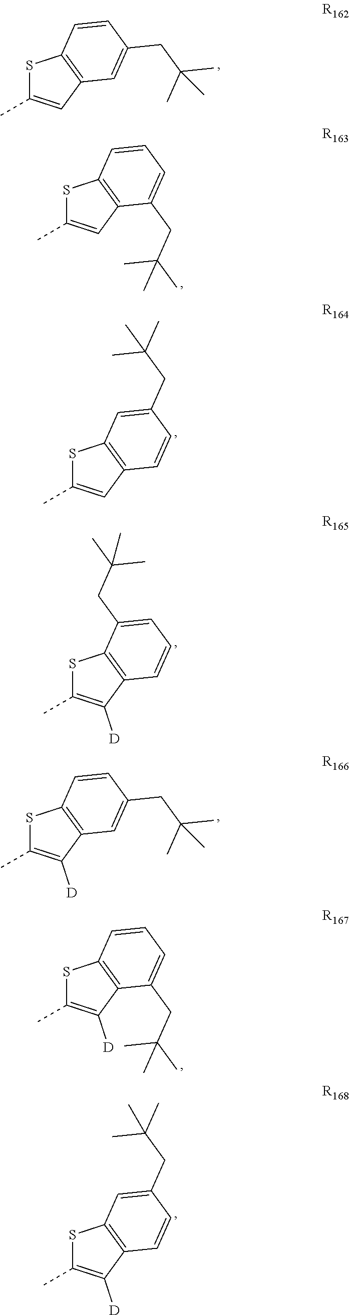

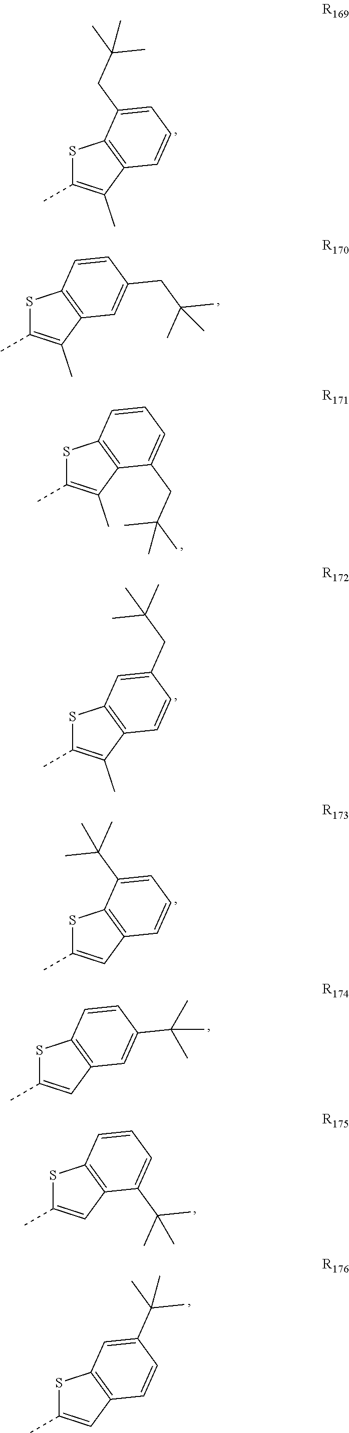

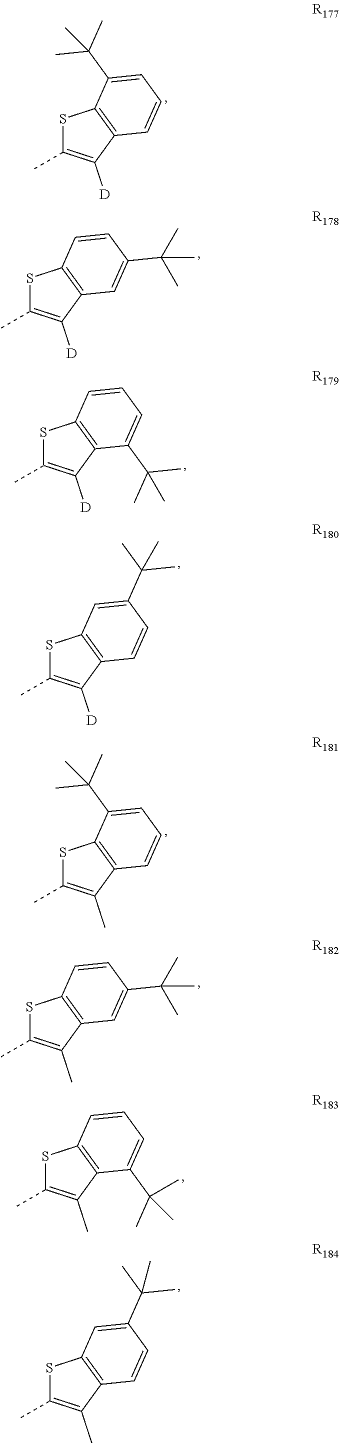

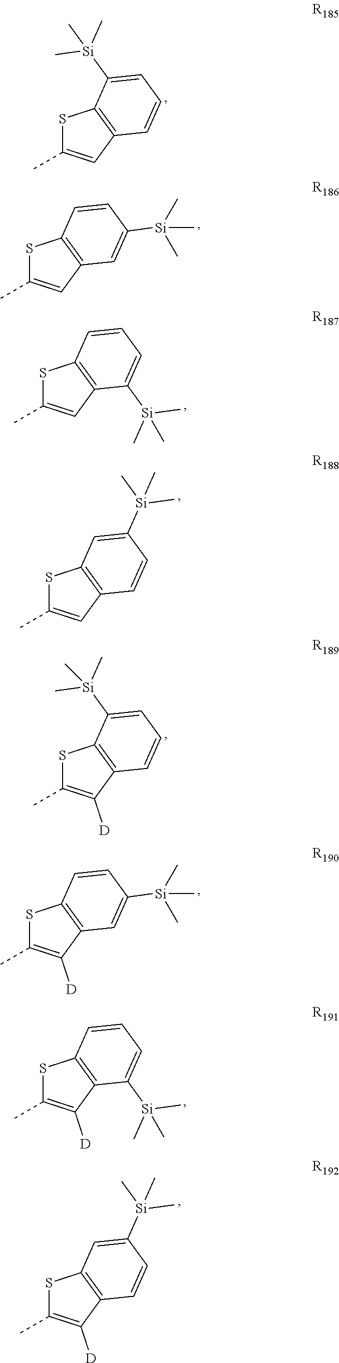

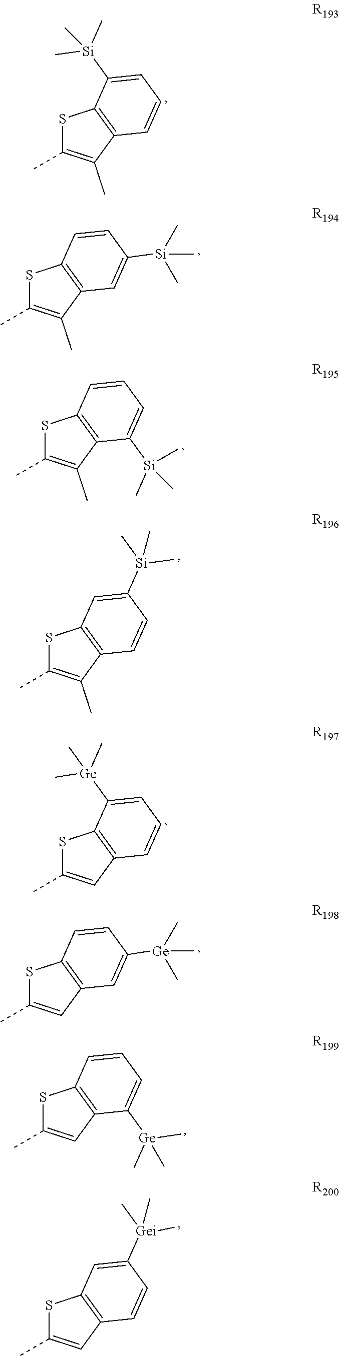

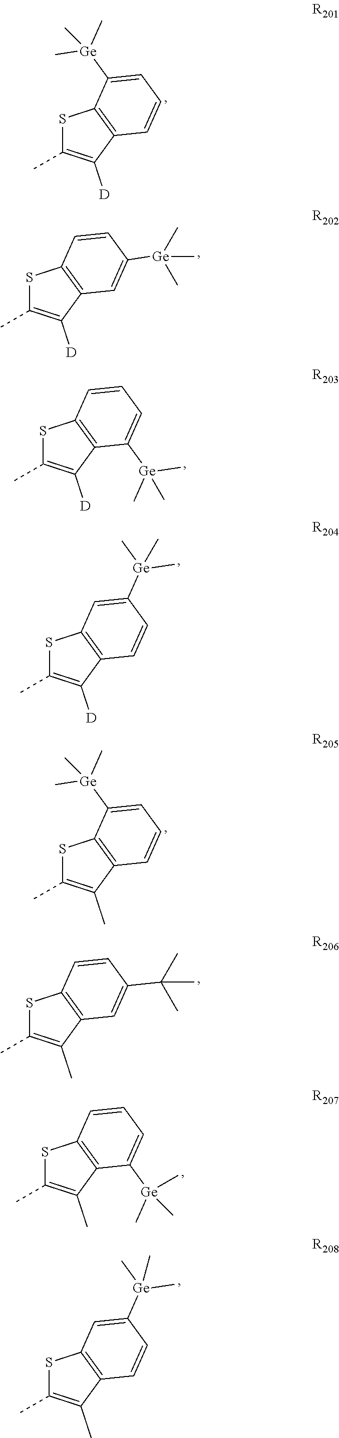

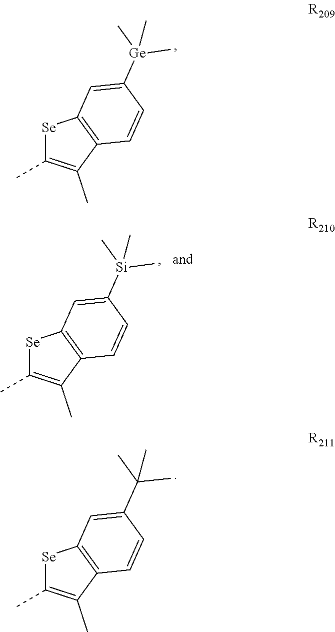

In some embodiments, the compound has a formula of M(L_{A})ₚ(L_{B})_{q}(L_{C})ᵣ, wherein L_{B} and L_{C} are each a bidentate ligand; and wherein p is 1, 2, or 3; q is 0, 1, or 2; r is 0, 1, or 2; and p+q+r is the oxidation state of the metal M.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, L_{B} is a substituted or unsubstituted phenylpyridine, and L_{C} is a substituted or unsubstituted acetylacetonate.

In some embodiments, the compound has a formula of Pt(L_{A})(L_{B}); and wherein L_{A} and L_{B} can be same or different. In some embodiments, L_{A} and L_{B} are connected to form a tetradentate ligand.

In some embodiments, L_{B} comprises an electron-withdrawing group selected from the EWG1 LIST as defined herein. In some embodiments, L_{B} comprises an electron-withdrawing group selected from the EWG2 LIST as defined herein. In some embodiments, L_{B} comprises an electron-withdrawing group selected from the EWG3 LIST as defined herein. In some embodiments, L_{B} comprises an electron-withdrawing group selected from the EWG4 LIST as defined herein. In some embodiments, L_{B} comprises an electron-withdrawing group selected from the Pi-EWG LIST as defined herein.

In some embodiments, L_{C} comprises an electron-withdrawing group selected from the EWG1 LIST as defined herein. In some embodiments, L_{C} comprises an electron-withdrawing group selected from the EWG2 LIST as defined herein. In some embodiments, L_{C} comprises an electron-withdrawing group selected from the EWG3 LIST as defined herein. In some embodiments, L_{C} comprises an electron-withdrawing group selected from the EWG4 LIST as defined herein. In some embodiments, L_{C} comprises an electron-withdrawing group selected from the Pi-EWG LIST as defined herein.

In some embodiments, L_{B} and L_{C} are each independently selected from the group consisting of the structures of the following LIST 5:

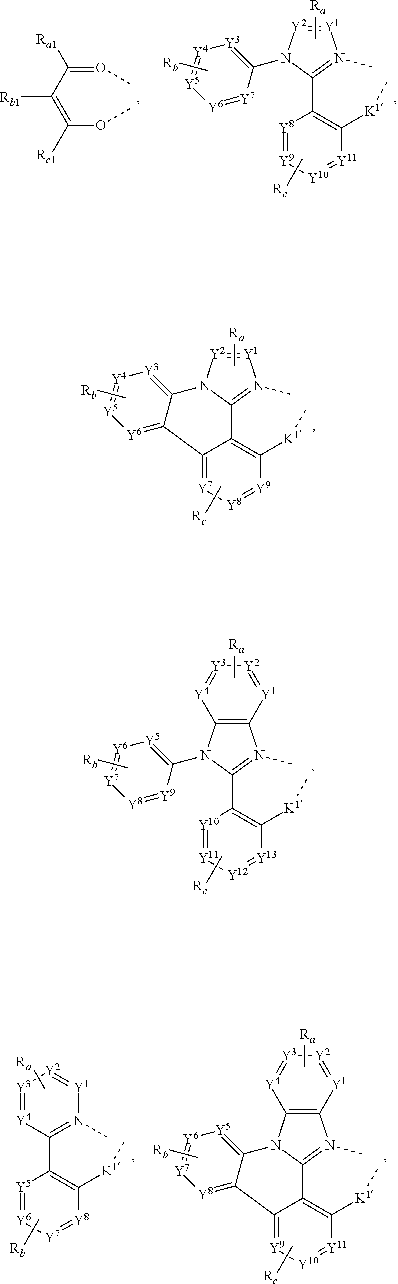

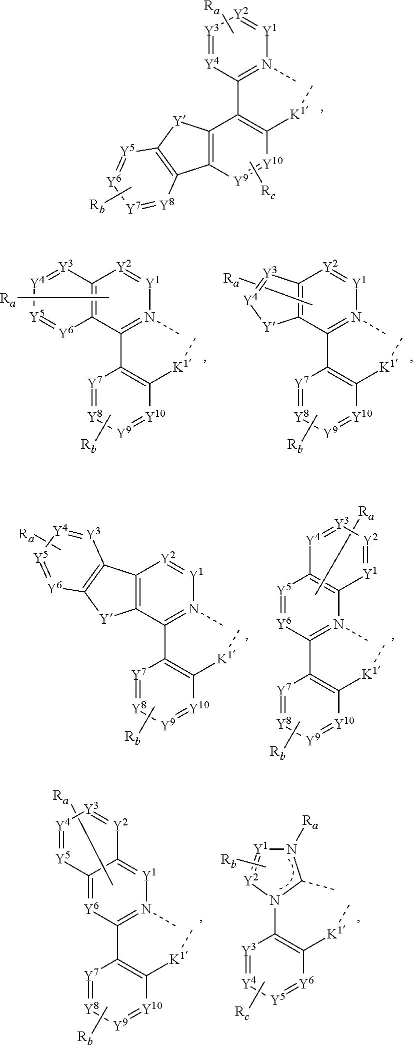

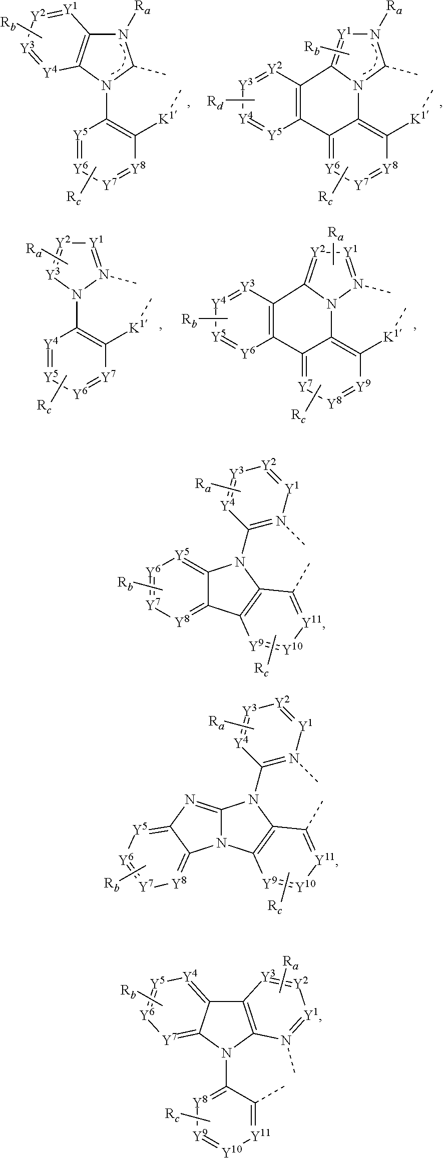

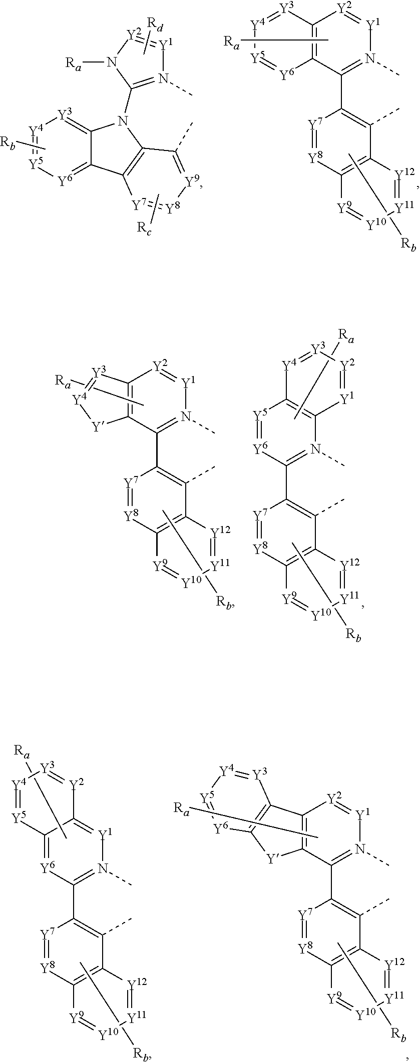

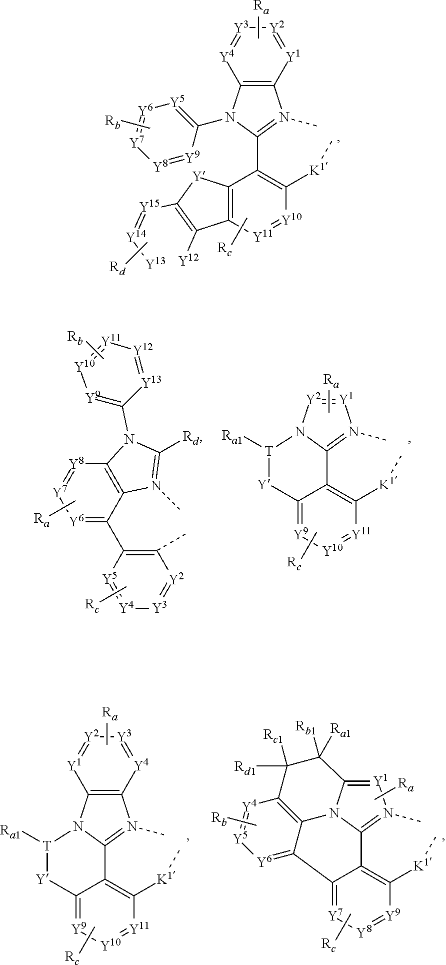

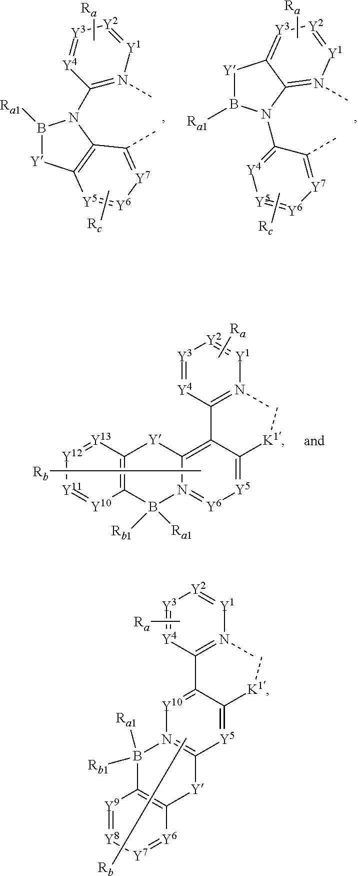

wherein:
   T is selected from the group consisting of B, Al, Ga, and In;
      K^{1′} is selected from the group consisting of a single bond, O, S, NRₑ, PRₑ, BRₑ, CRₑR_{f}, and SiRₑR_{f};
   each of Y¹ to Y¹³ is independently selected from the group consisting of C and N;
   Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
   Rₑ and R_{f} can be fused or joined to form a ring;
   each Rₐ, R_{b}, R_{c}, and R_{d} independently represents from mono to the maximum allowed number of substitutions, or no substitution;
   each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of the General Substituents defined herein; and
   any two substituents of Rₐ₁, R_{b1}, R_{c1}, R_{d1}, Rₐ, R_{b}, R_{c}, and R_{d} can be fused or joined to form a ring or form a multidentate ligand.

In some embodiments, L_{B} and L_{C} are each independently selected from the group consisting of the structures of the following LIST 6:

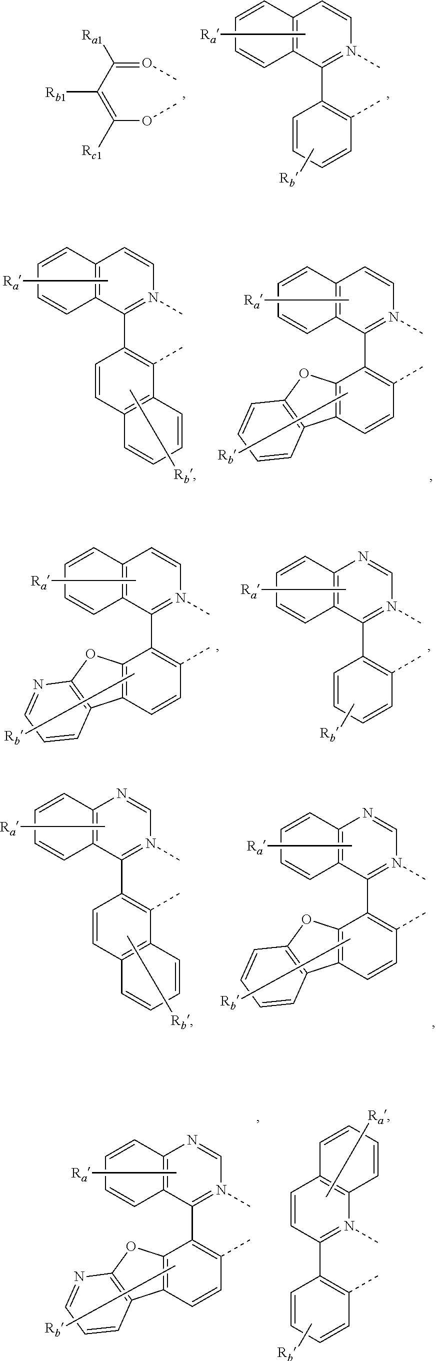

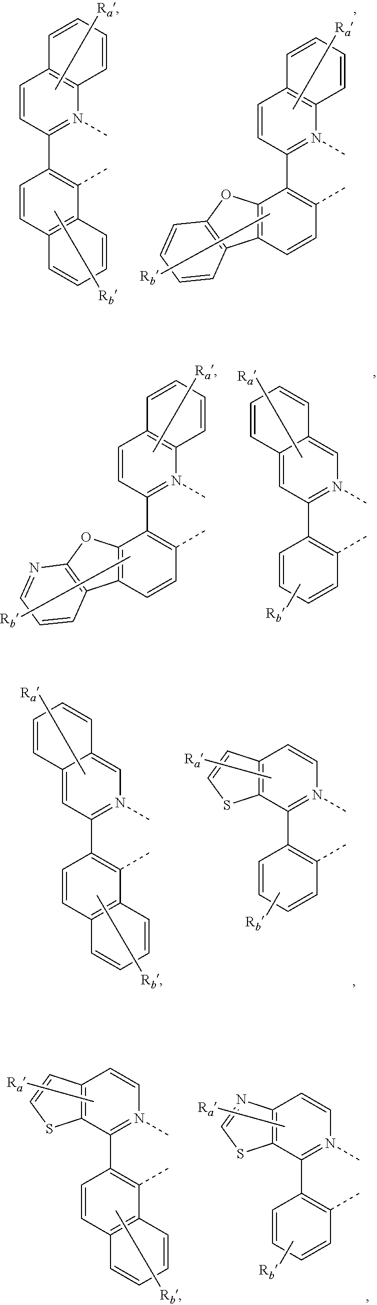

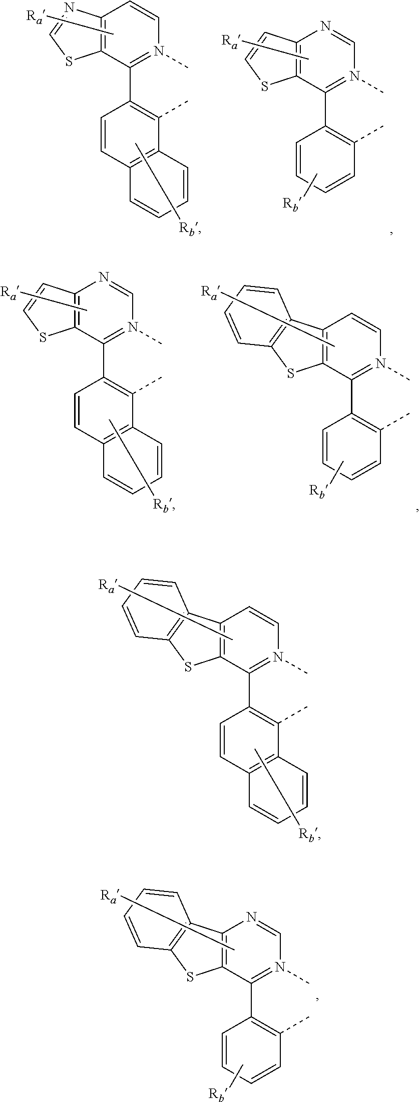

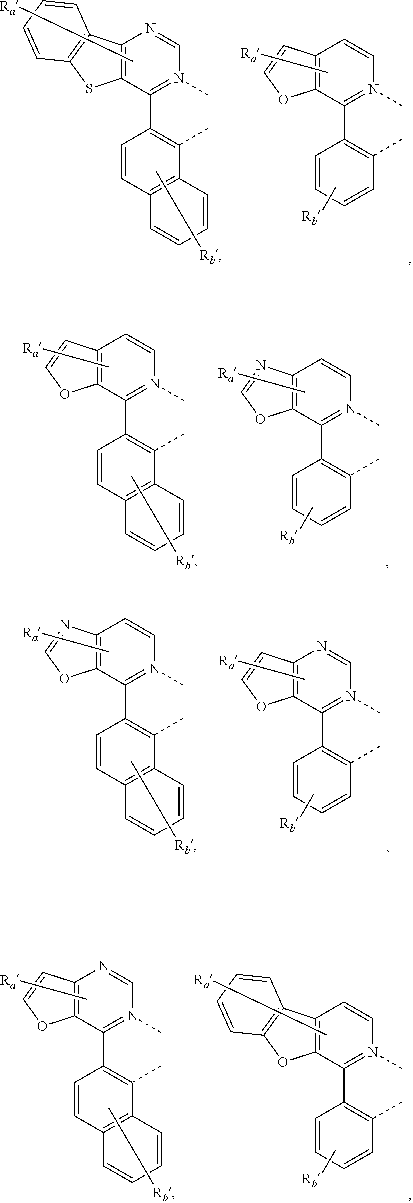

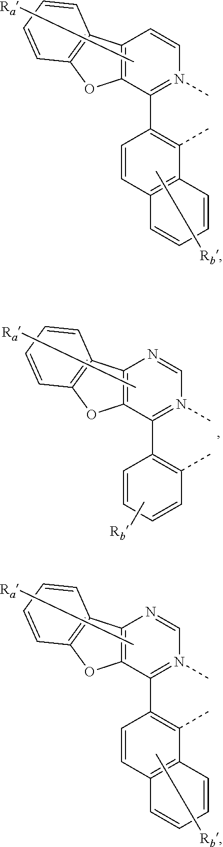

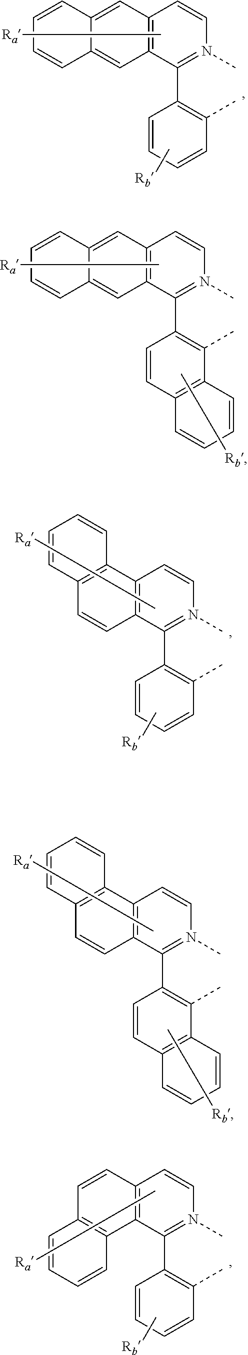

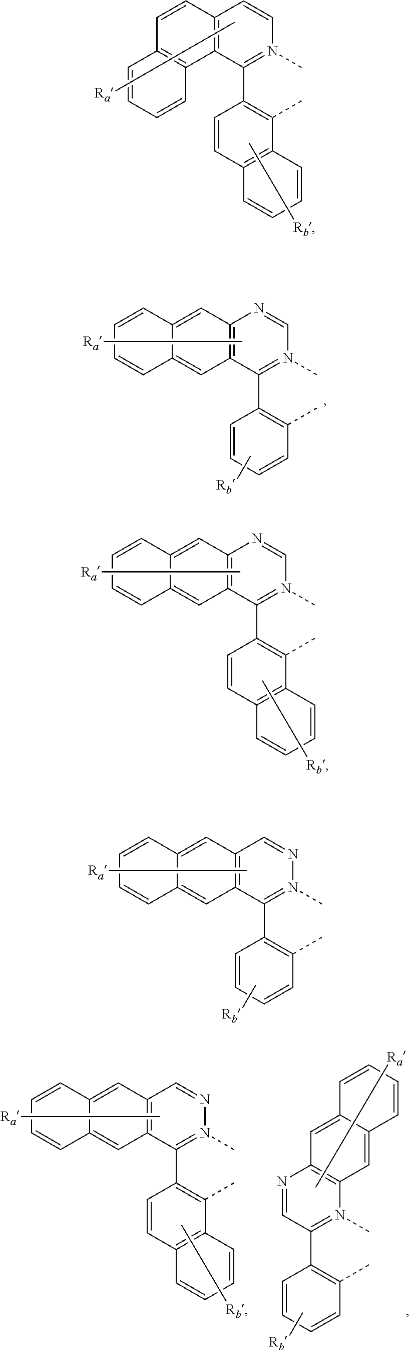

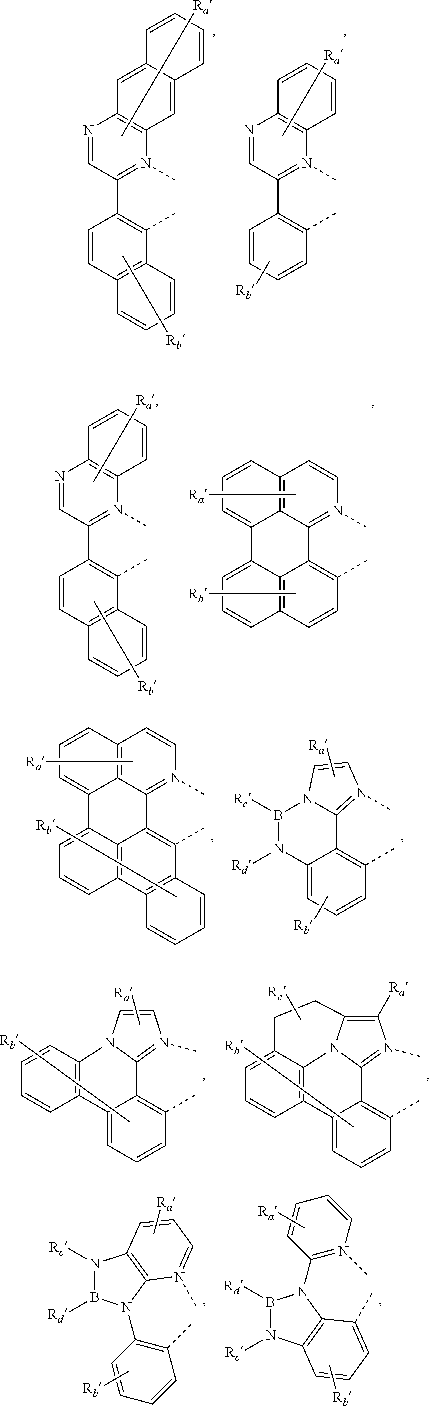

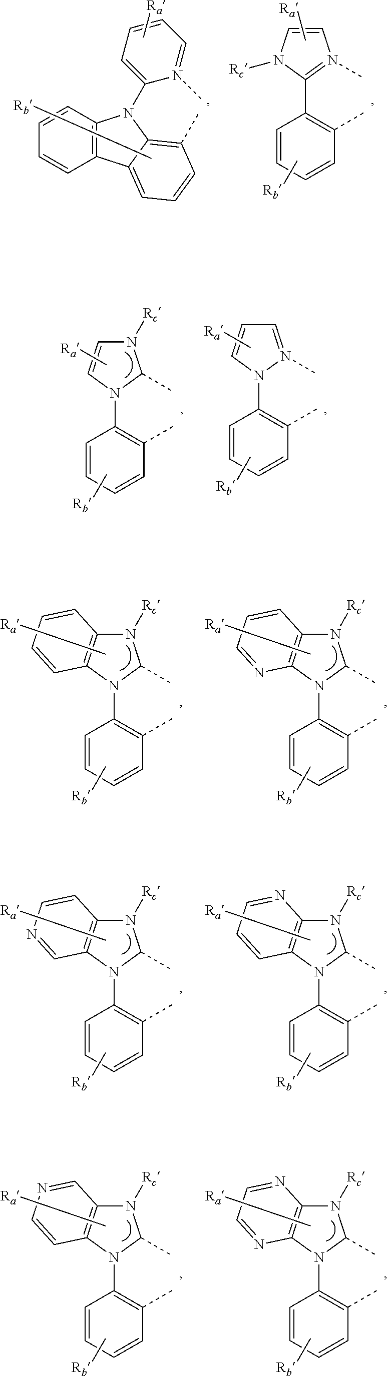

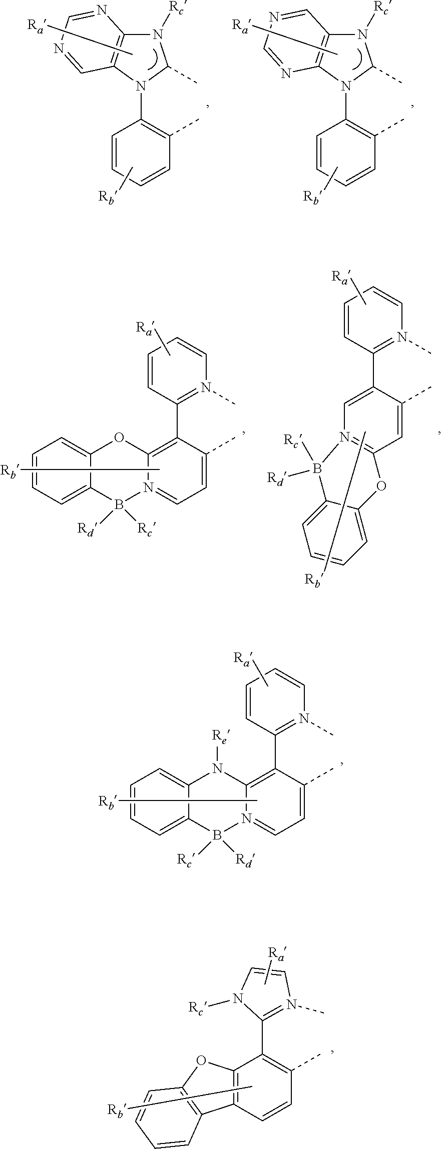

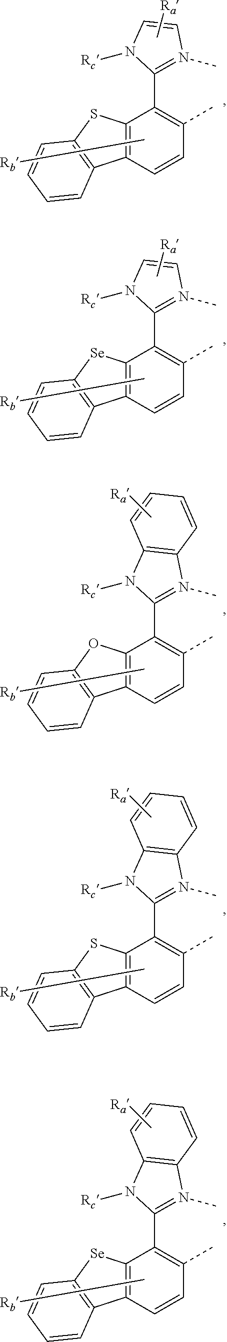

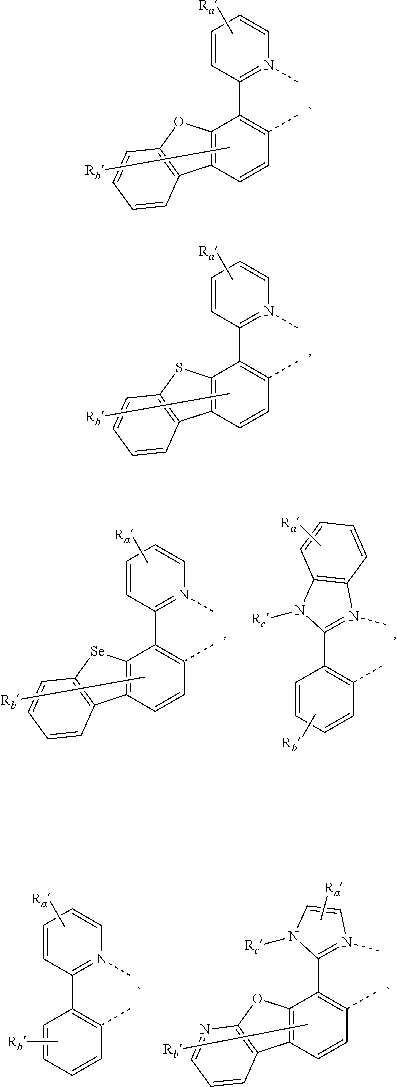

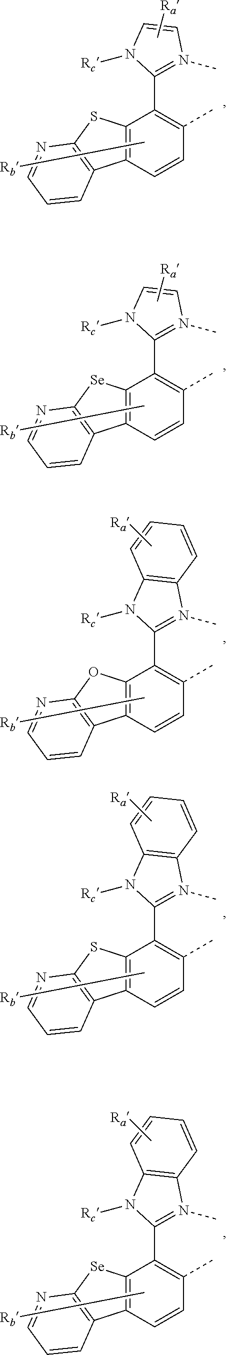

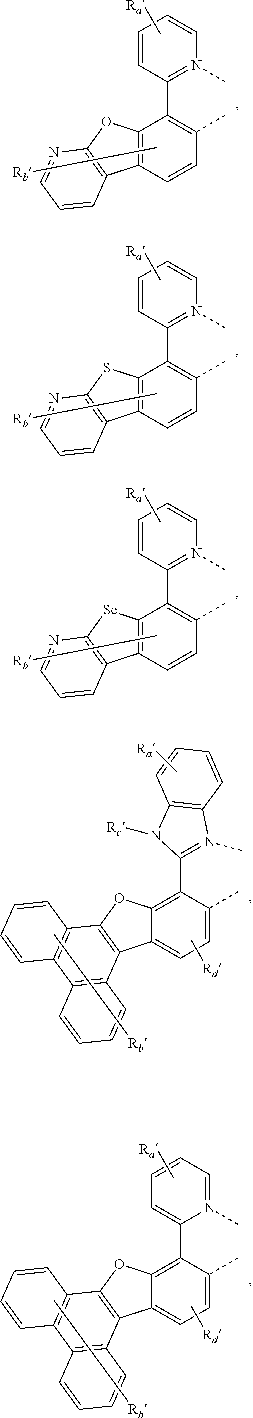

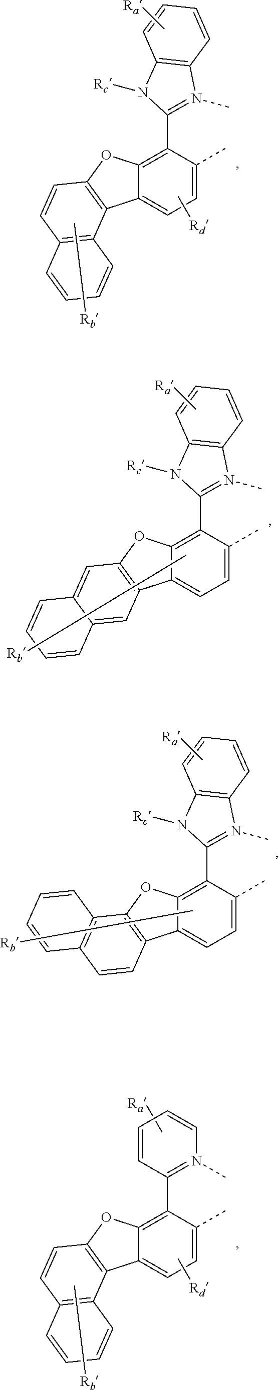

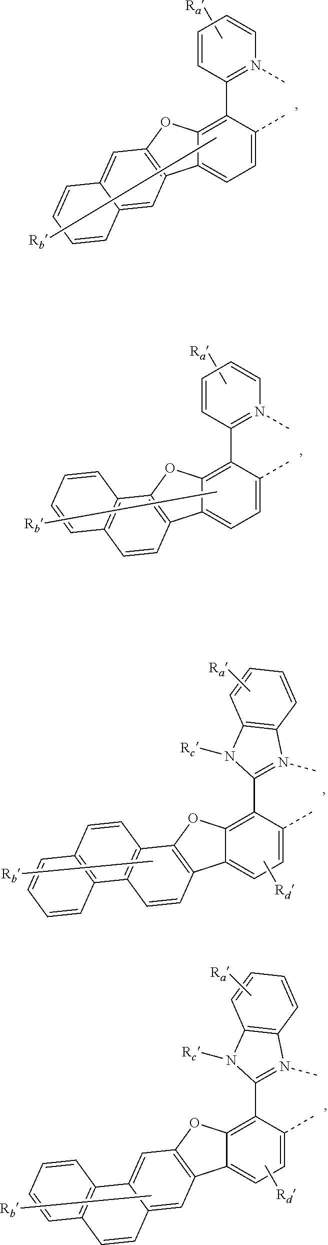

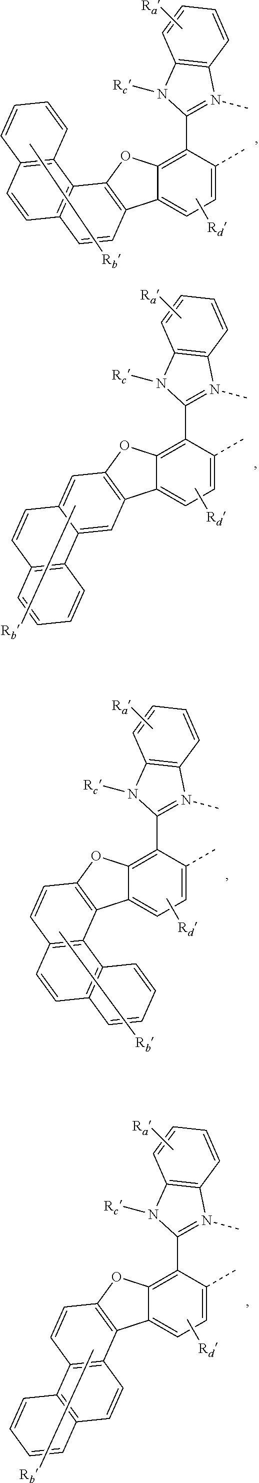

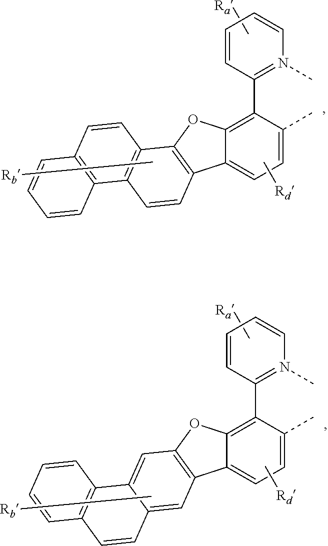

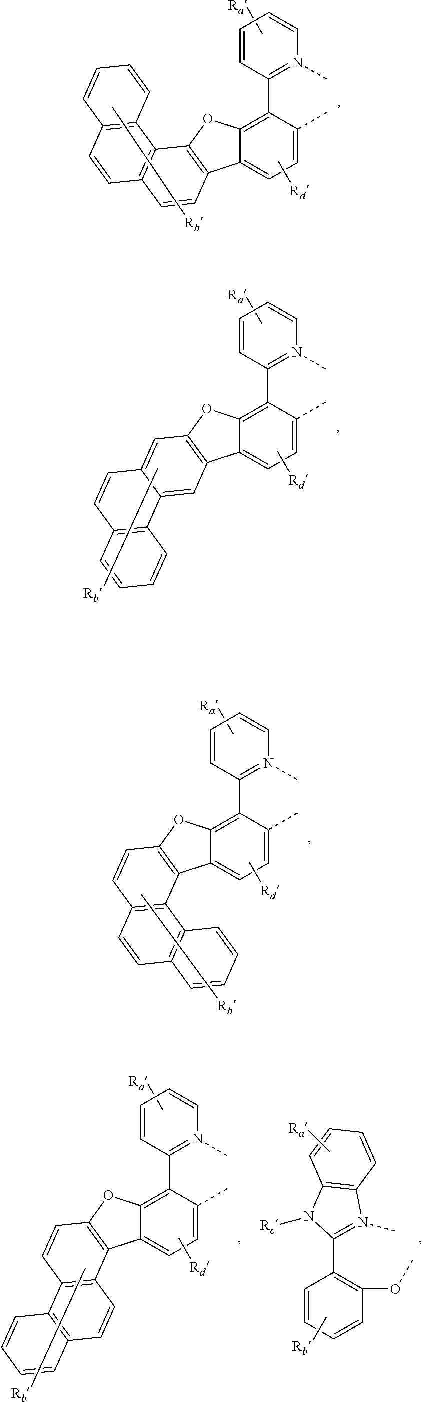

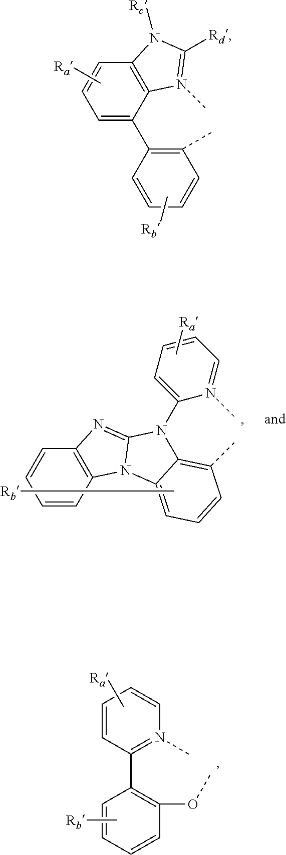

wherein:
   Rₐ′, R_{b}′, R_{c}′, R_{d}′, and Rₑ′ each independently represents zero, mono, or up to a maximum allowed number of substitution to its associated ring;
   Rₐ′, R_{b}′, R_{c}′, R_{d}′, and Rₑ′ each independently hydrogen or a substituent selected from the group consisting of the General Substituents defined herein; and
   two substituents of Rₐ′, R_{b}′, R_{c}′, R_{d}′, and Rₑ′ can be fused or joined to form a ring or form a multidentate ligand.

In some embodiments, L_{B} comprises a structure of

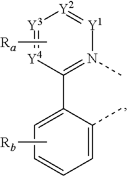

wherein the variables are the same as previously defined. In some embodiments, each of Y¹ to Y⁴ is independently carbon. In some embodiments, at least one of Y¹ to Y⁴ is N. In some embodiments, exactly one of Y¹ to Y⁴ is N. In some embodiments, Y¹ is N. In some embodiments, Y² is N. In some embodiments, Y³ is N. In some embodiments, Y⁴ is N. In some embodiments, at least one of Rₐ is a tertiary alkyl, silyl or germyl. In some embodiments, at least one of Rₐ is a tertiary alkyl. In some embodiments, Y³ is C and the Rₐ attached thereto is a tertiary alkyl, silyl or germyl. In some embodiments, Y¹ to Y³ is C, Y⁴ is N, and the Rₐ attached to Y³ is a tertiary alkyl, silyl or germyl. In some embodiments, Y¹ to Y³ is C, Y⁴ is N, and the Rₐ attached to Y² is a tertiary alkyl, silyl or germyl. In some embodiments, at least one of R_{b} is a tertiary alkyl, silyl, or germyl. In some embodiments, the tertiary alkyl is tert-butyl. In some embodiments, at least one pair of Rₐ, one pair of R_{b}, or one pair of Rₐ and R_{b} are joined or fused into a ring.

In some embodiments, the compound has formula Ir(L_{A})₃, formula Ir(L_{A})(L_{Bk})₂, formula Ir(L_{A})₂(L_{Bk}), formula Ir(L_{A})₂(L_{Cj-I}), or formula Ir(L_{A})₂(L_{Cj-II}),
wherein L_{A} is according to any embodiments described herein, including L_{A1}(R₁)(R₁)(R₁)(R₁)(R₁)(R₁)(R₁) to L_{A161}(R₂₁₁)(R₂₁₁)(R₂₁₁)(R₂₁₁)(R₂₁₁)(R₂₁₁)(R₂₁₁);
   wherein k is an integer from 1 to 522, and each L_{Bk} has the structure defined in the following LIST 7:

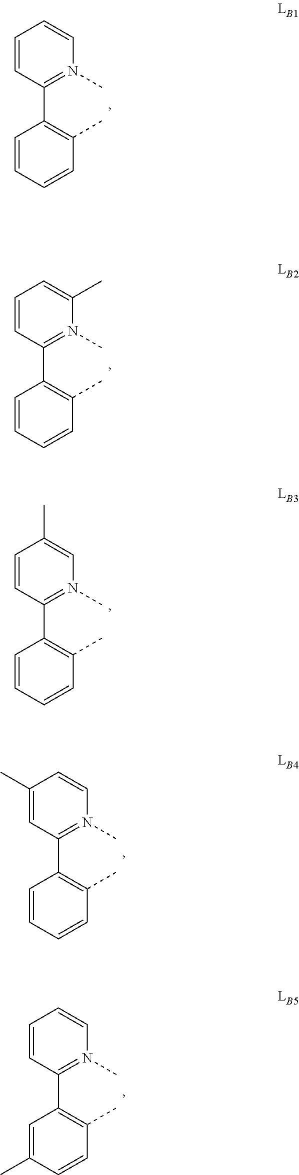

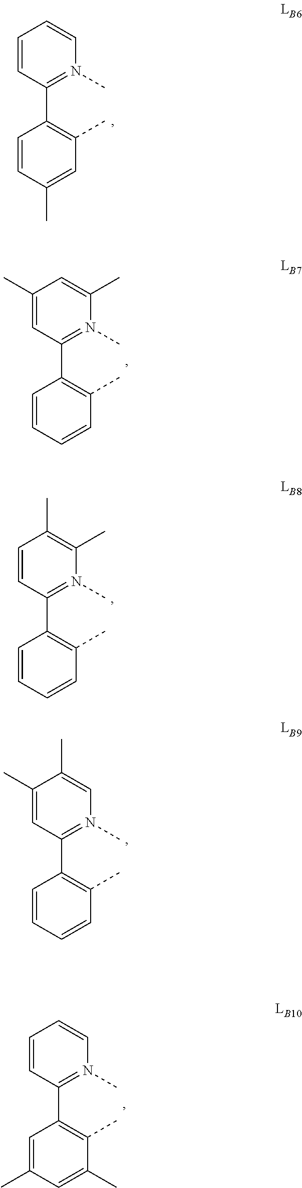

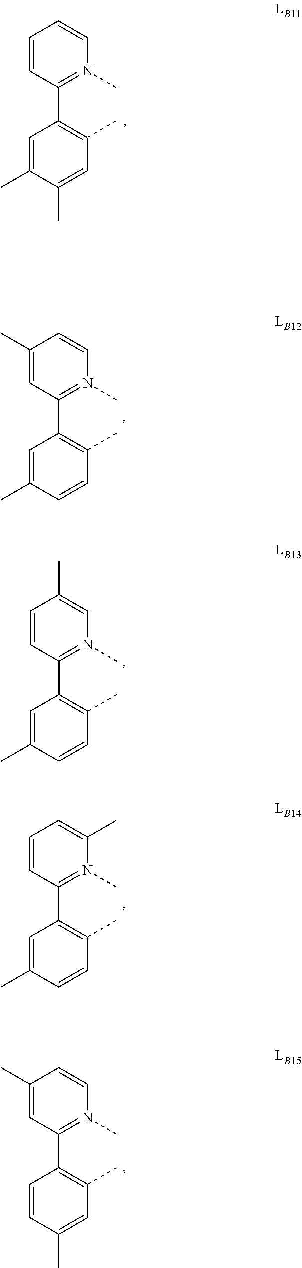

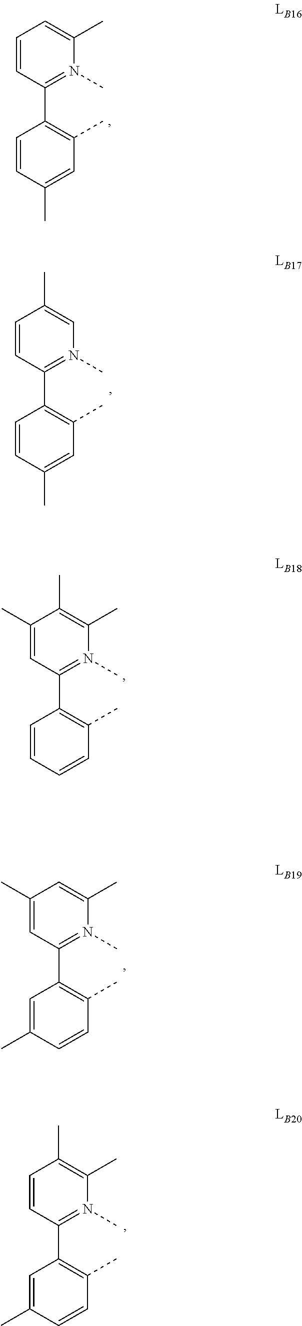

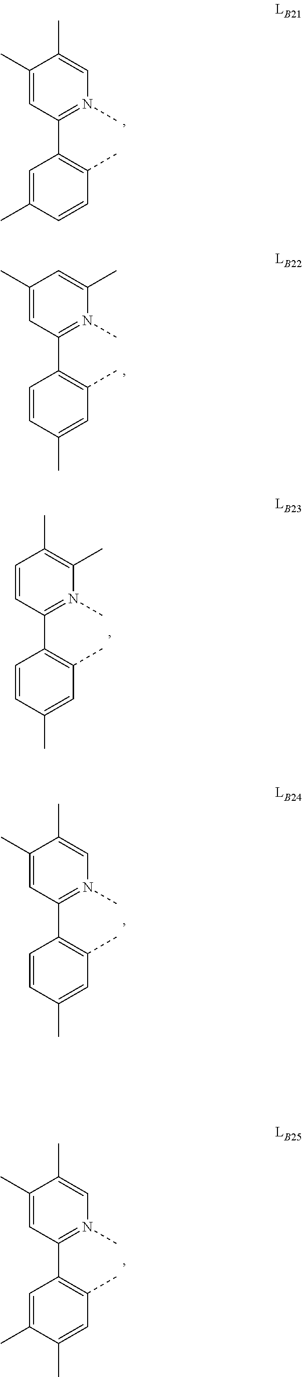

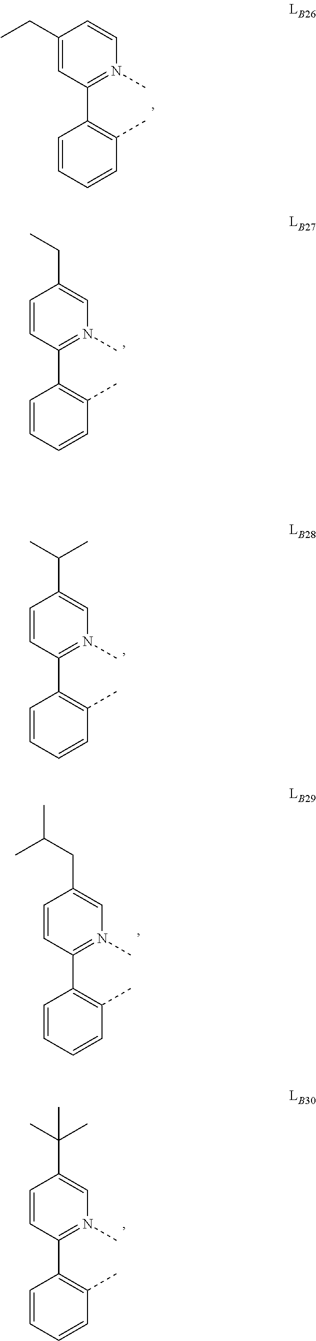

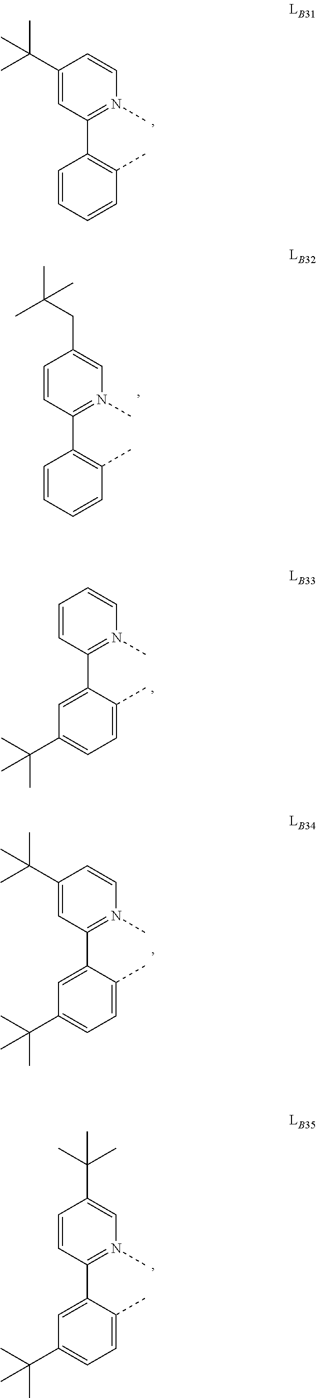

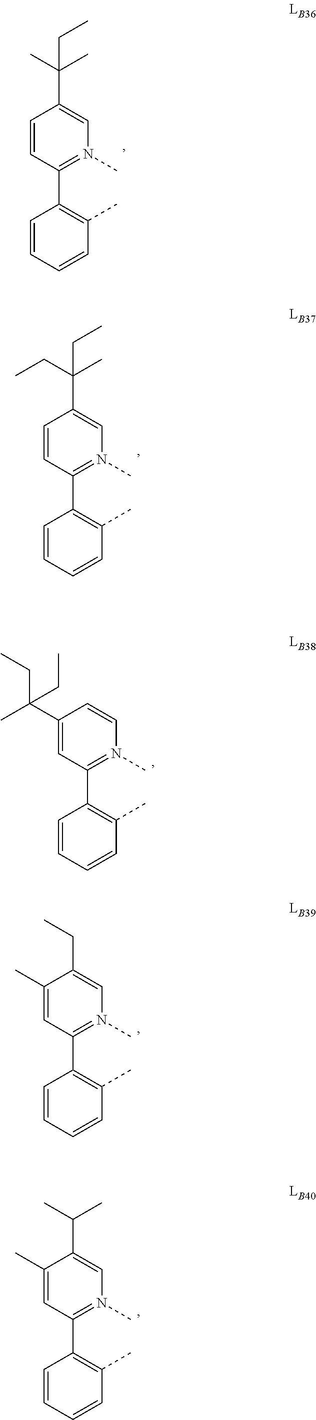

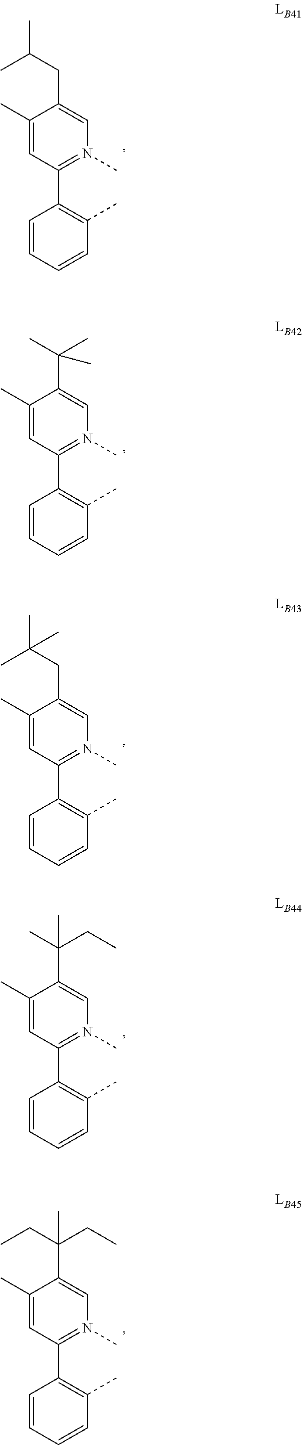

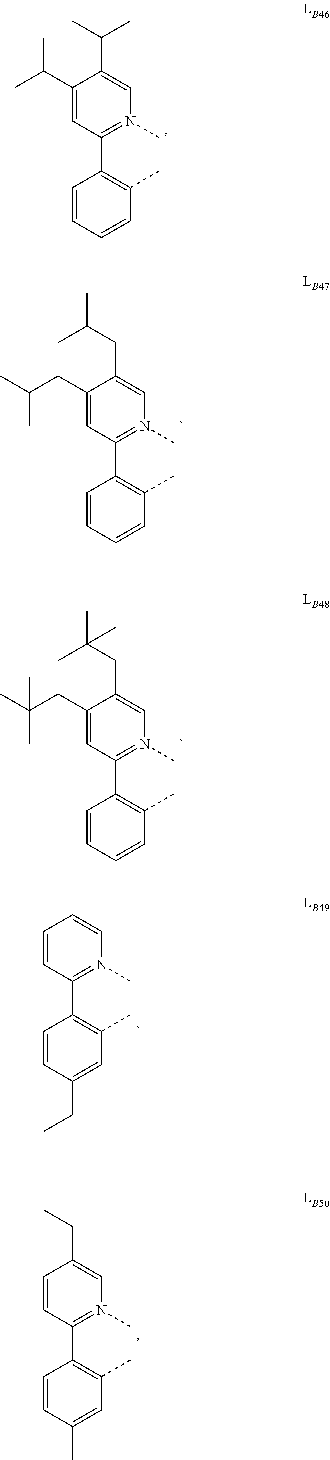

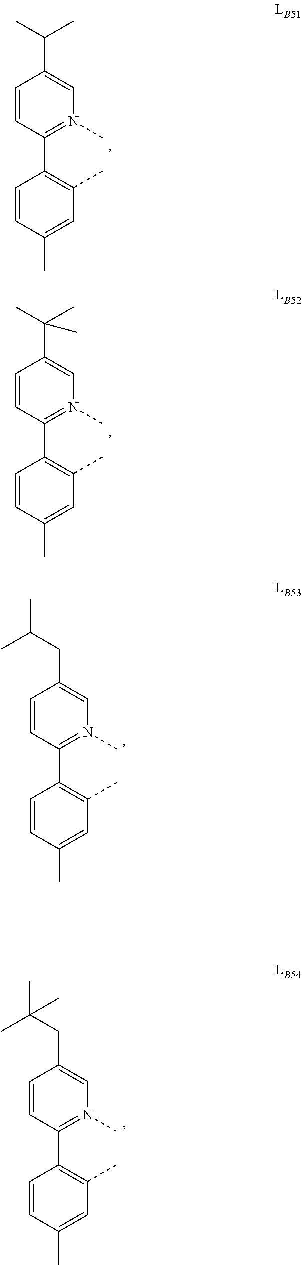

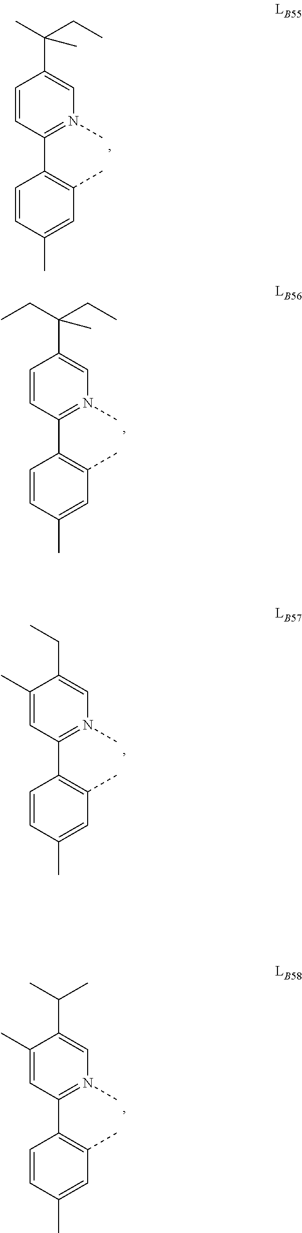

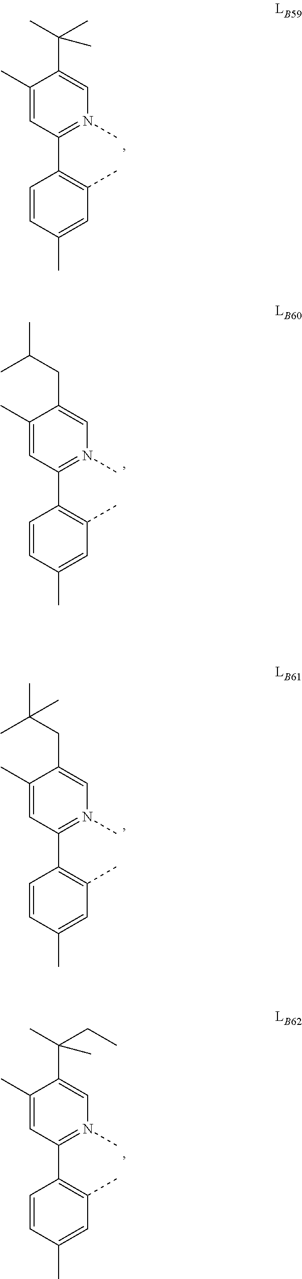

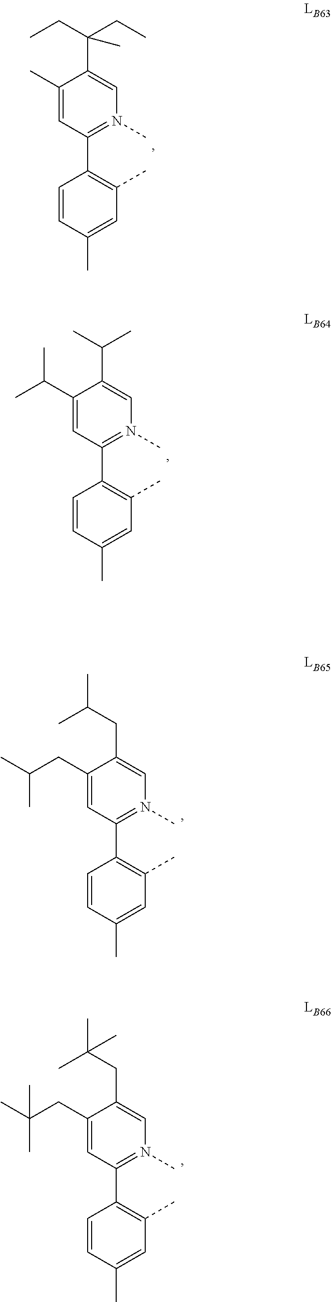

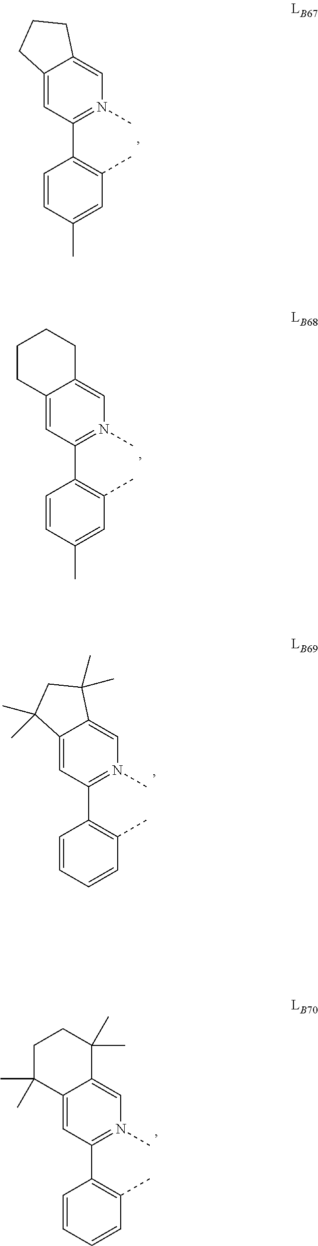

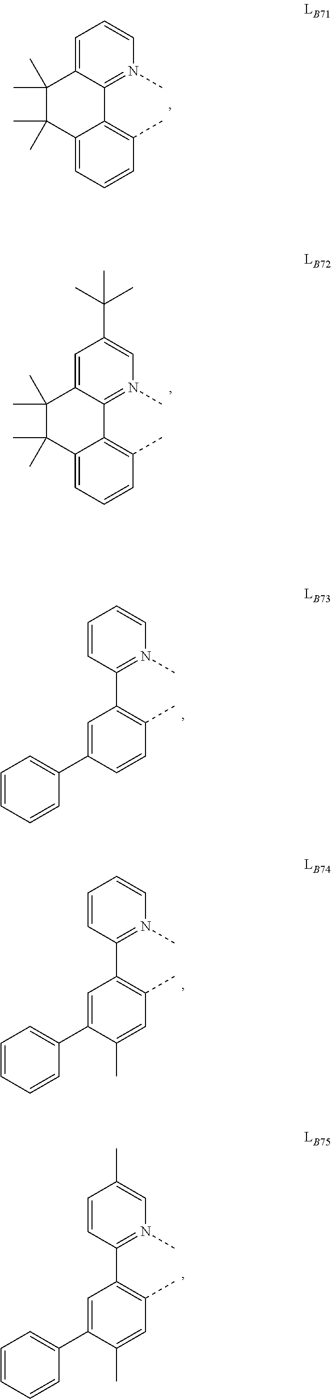

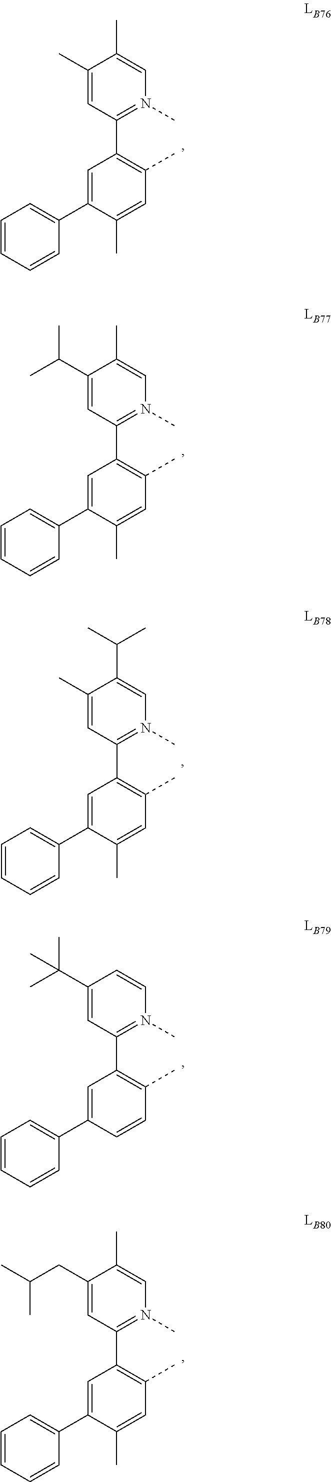

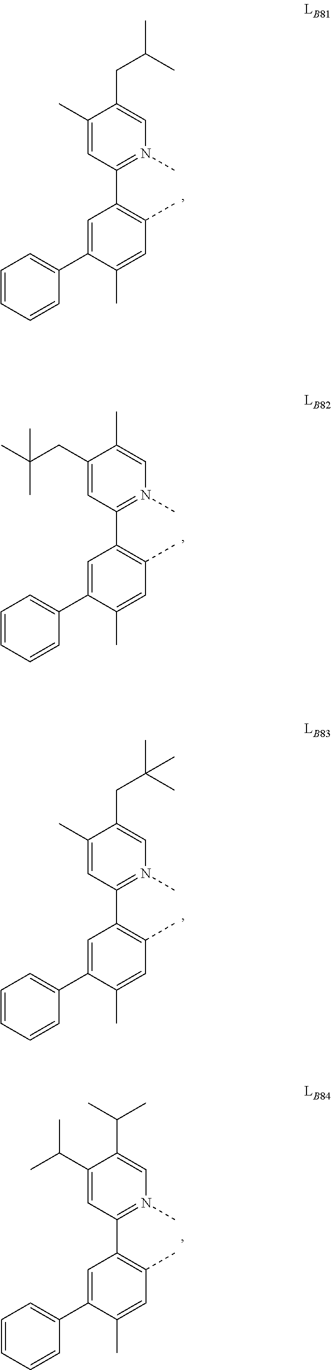

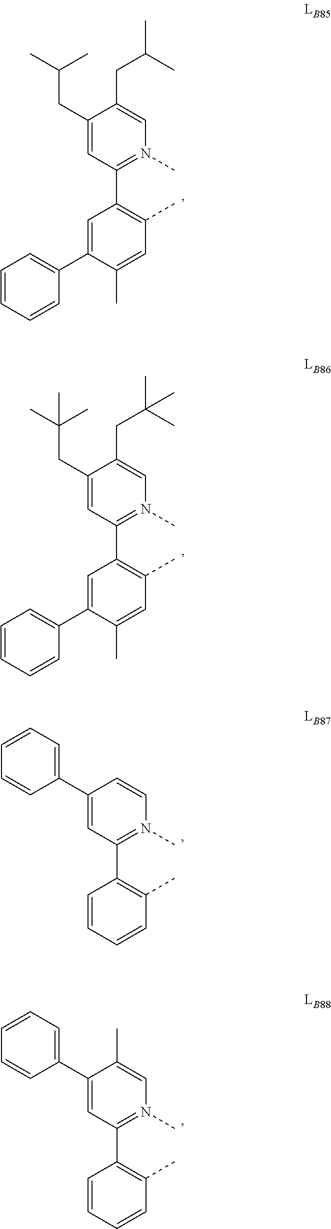

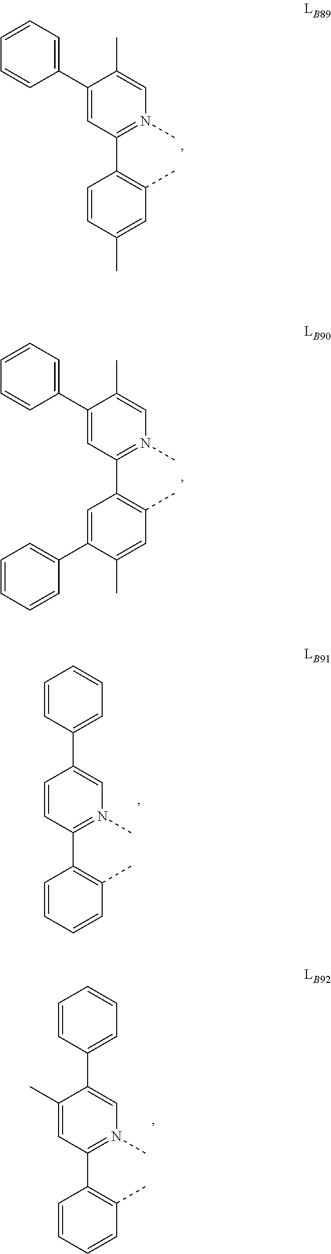

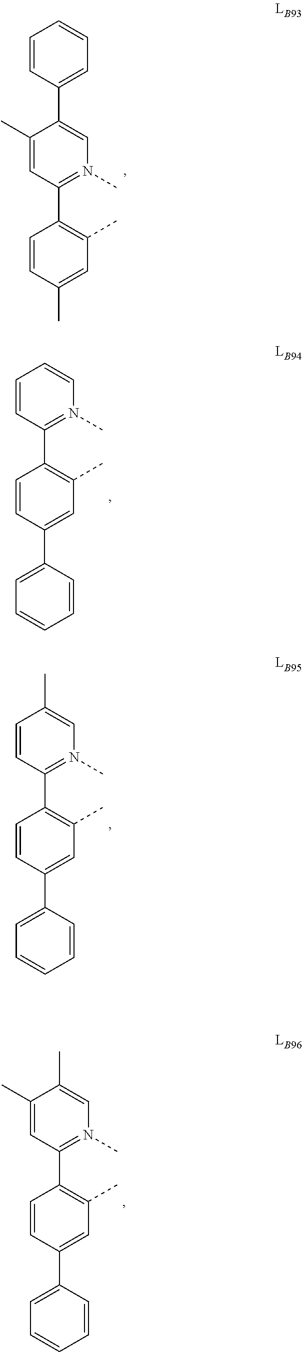

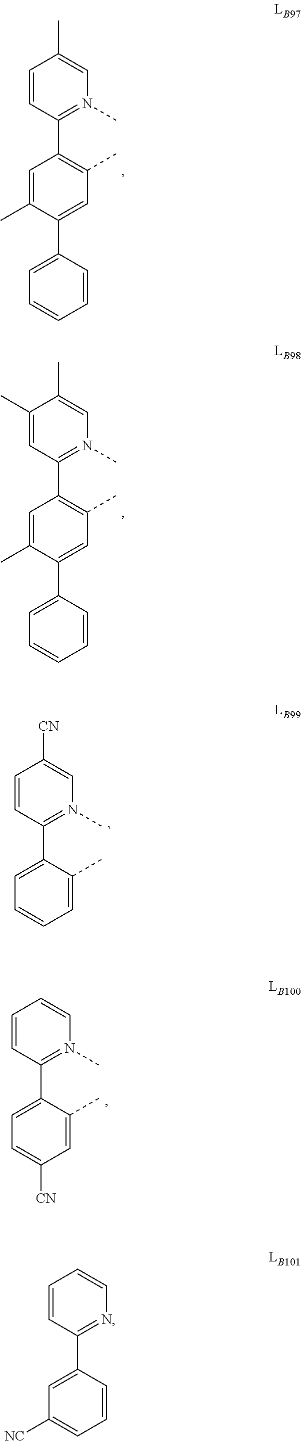

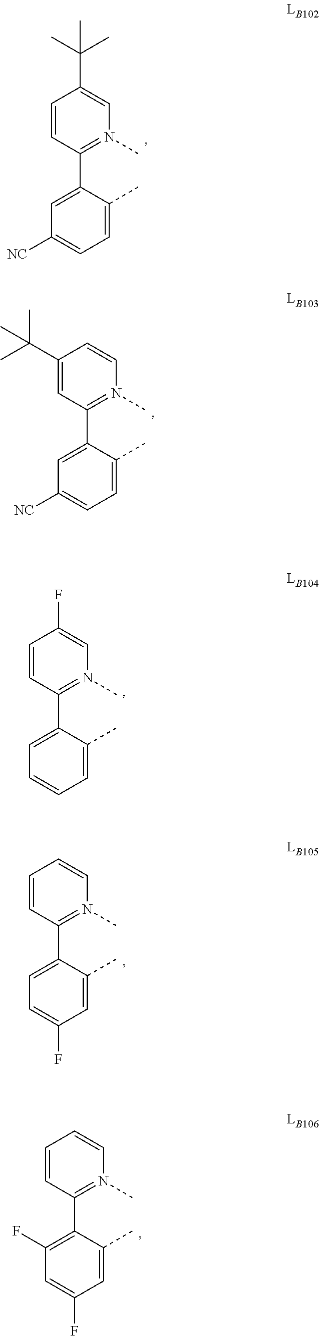

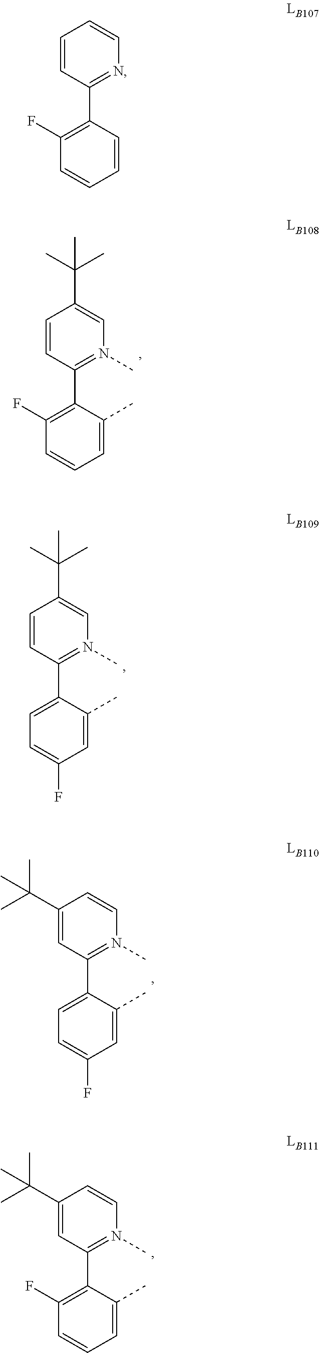

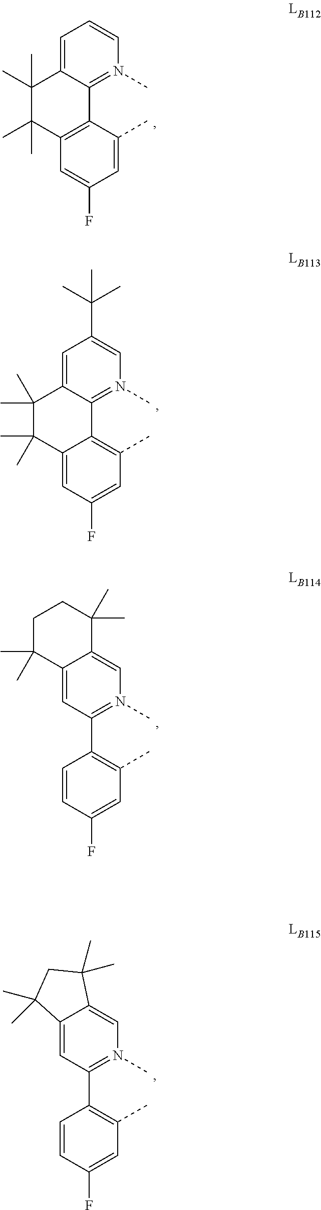

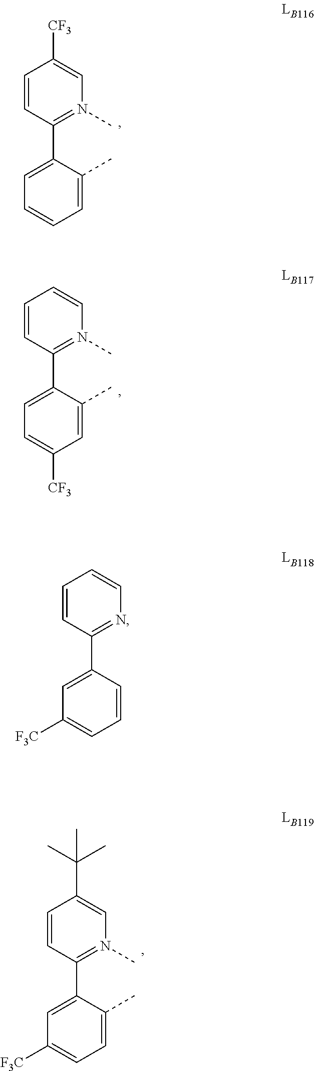

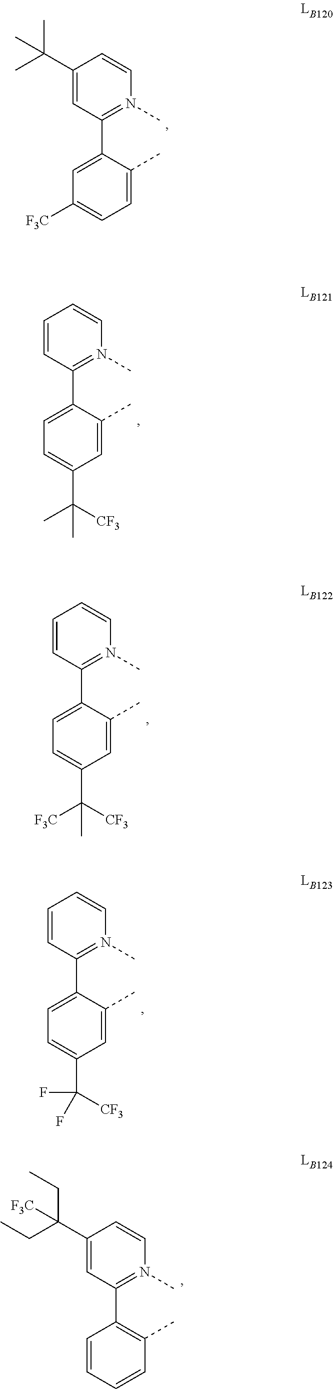

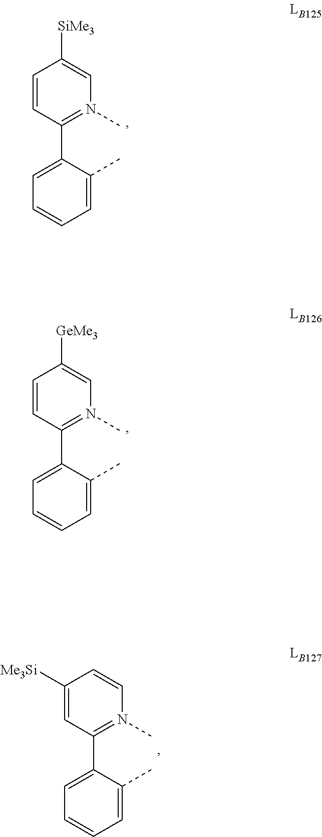

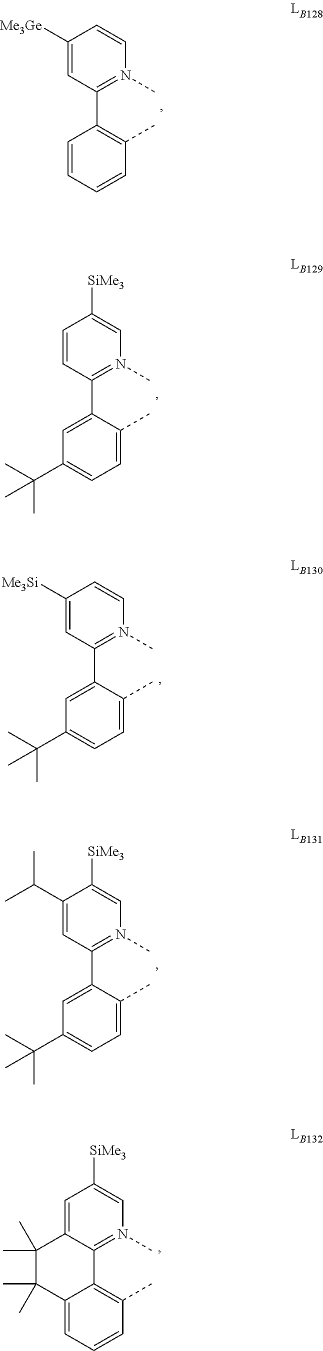

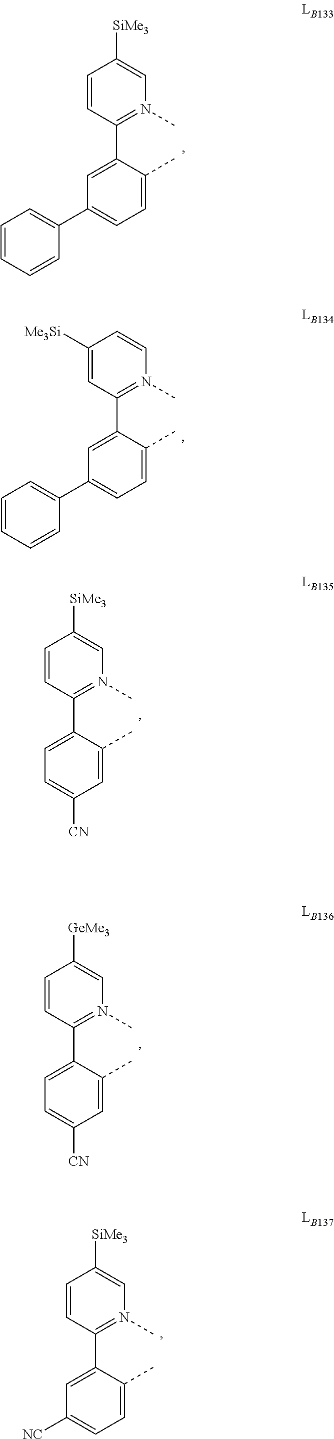

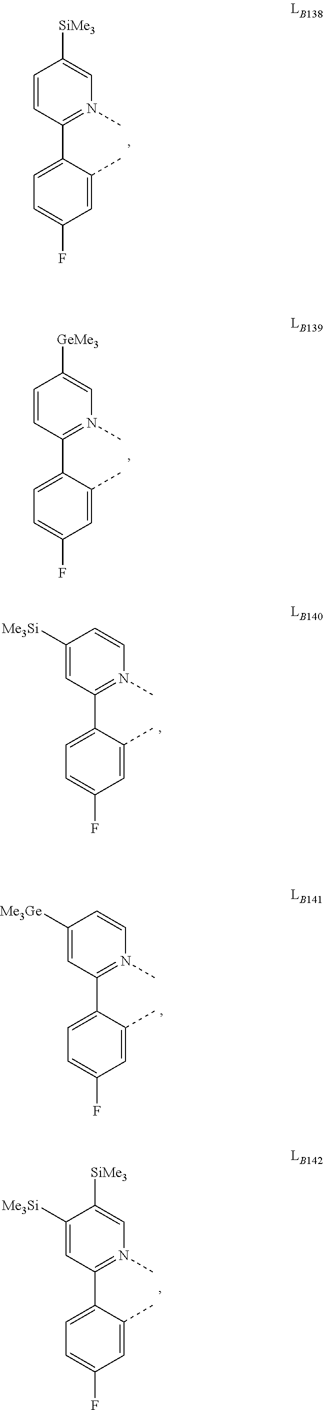

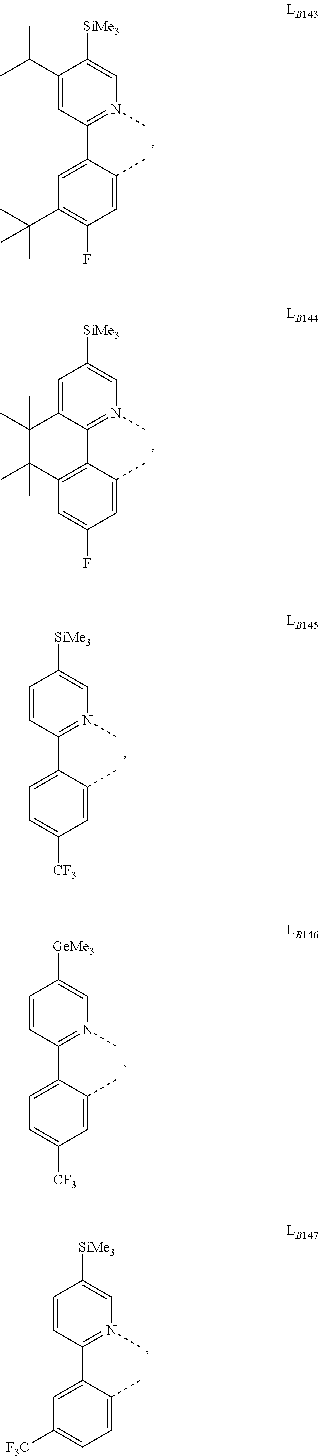

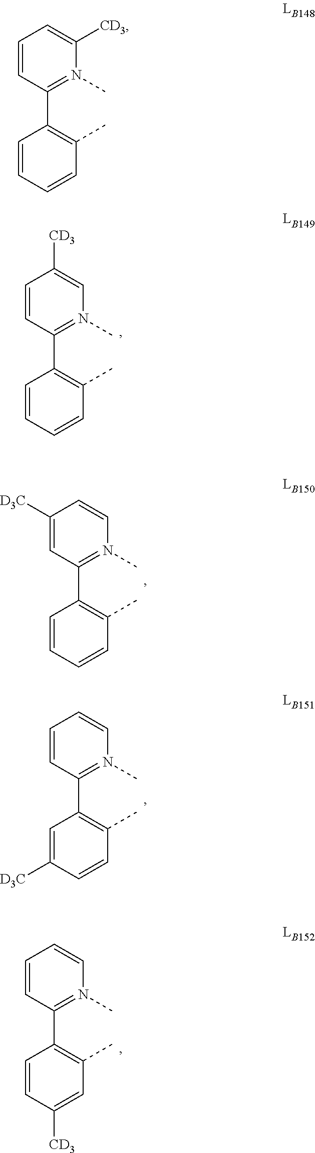

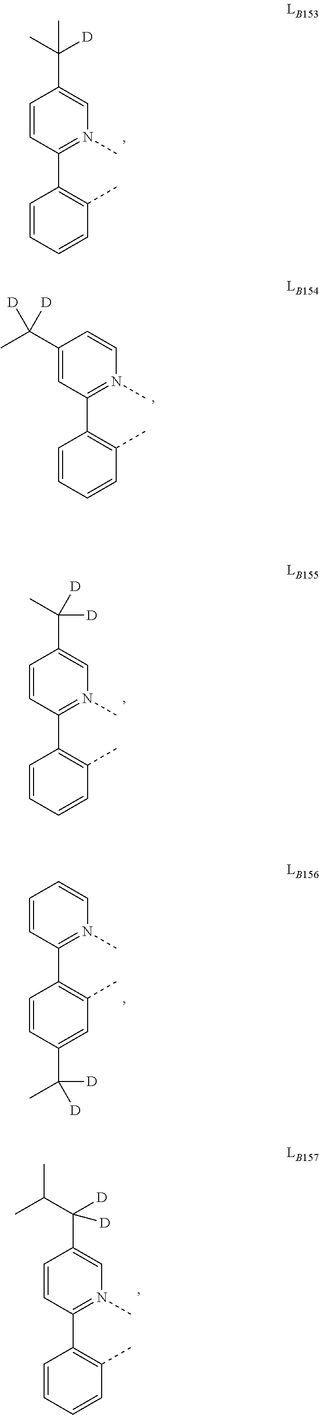

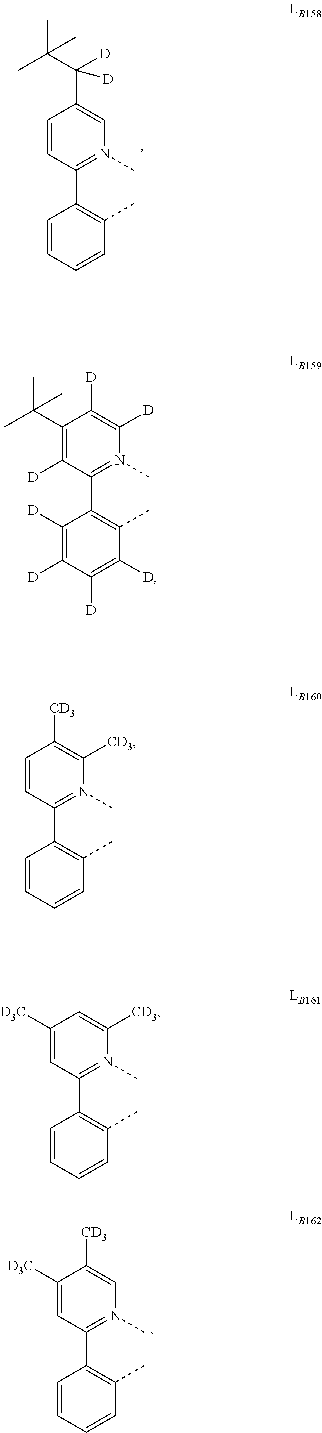

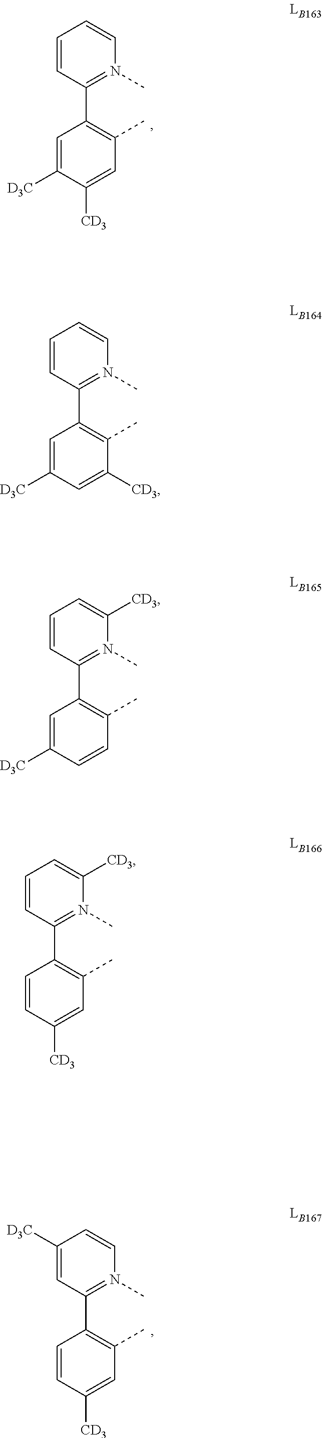

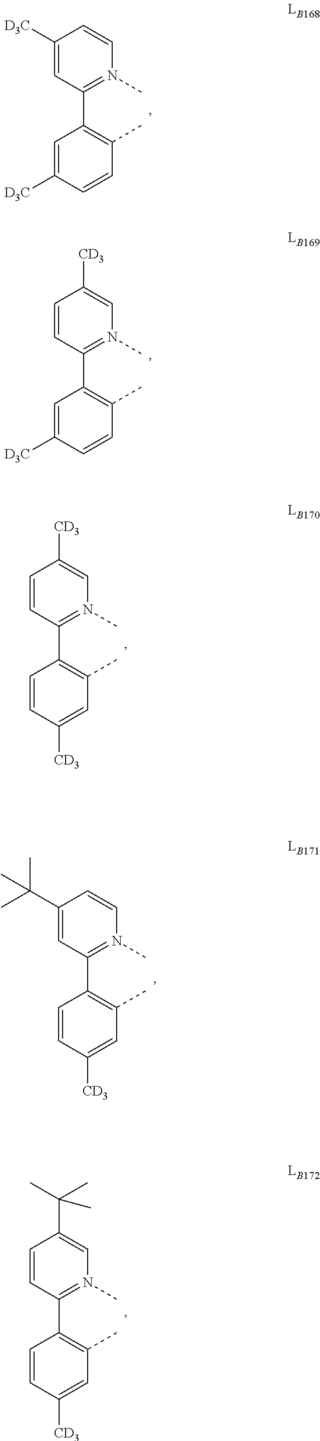

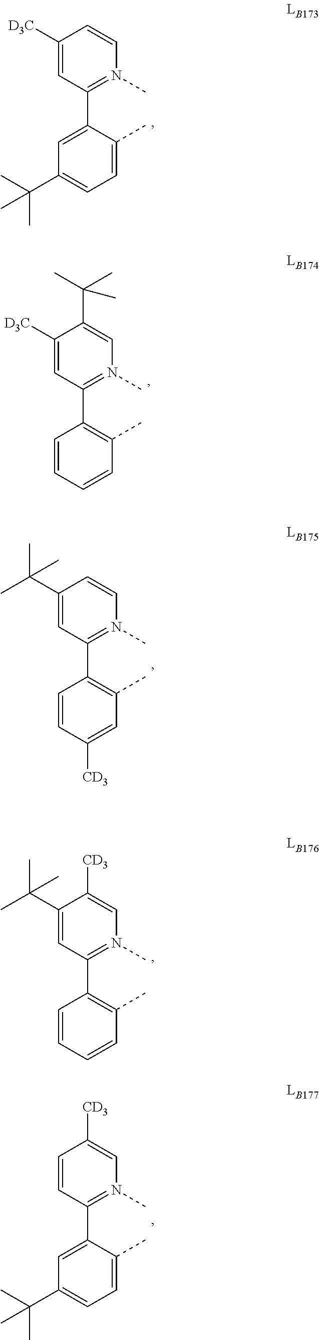

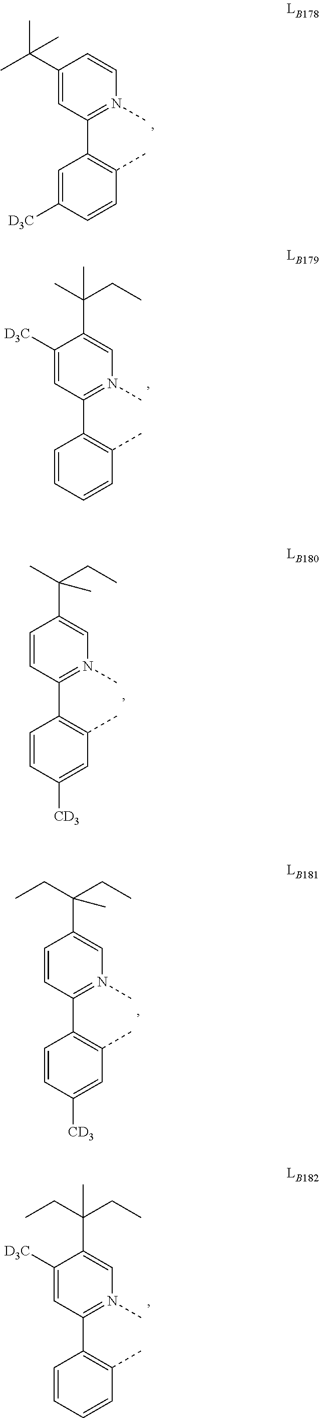

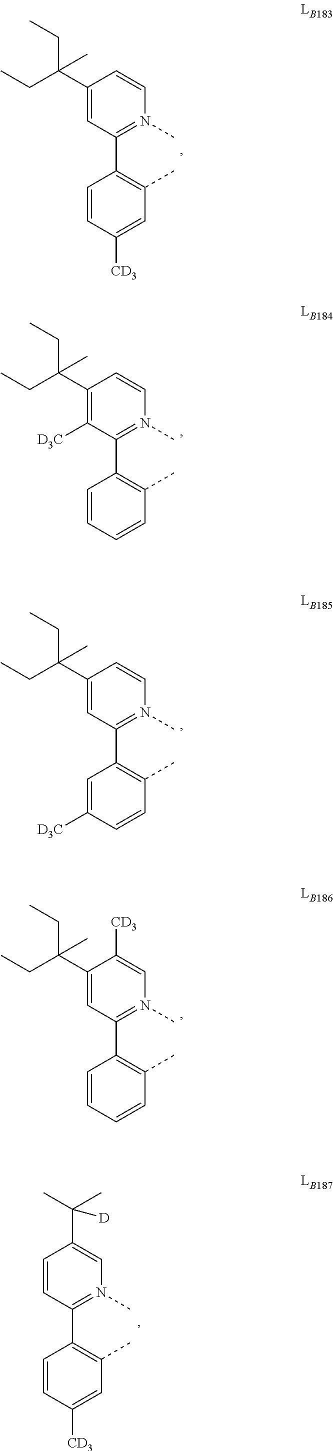

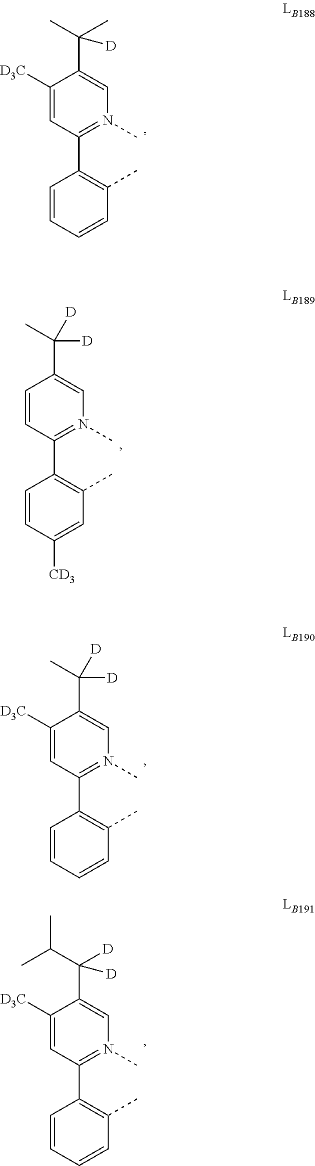

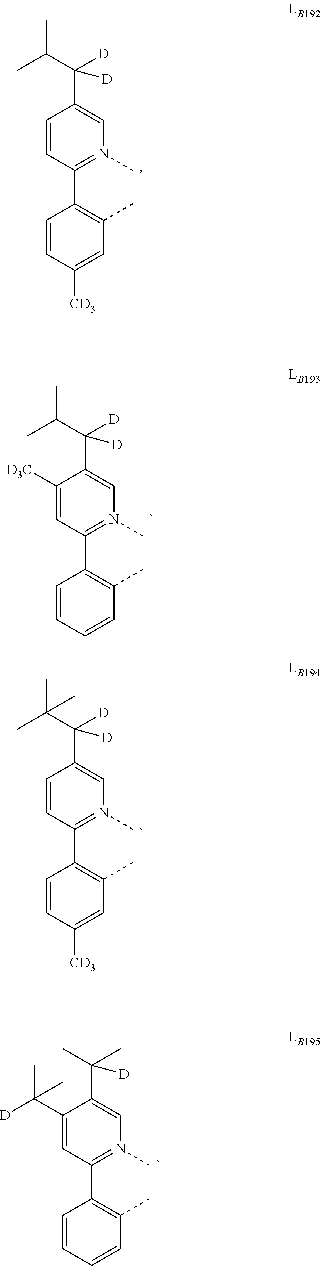

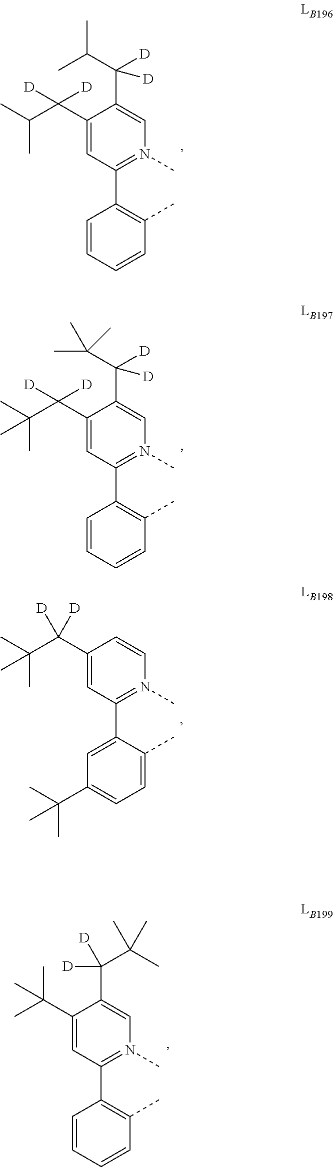

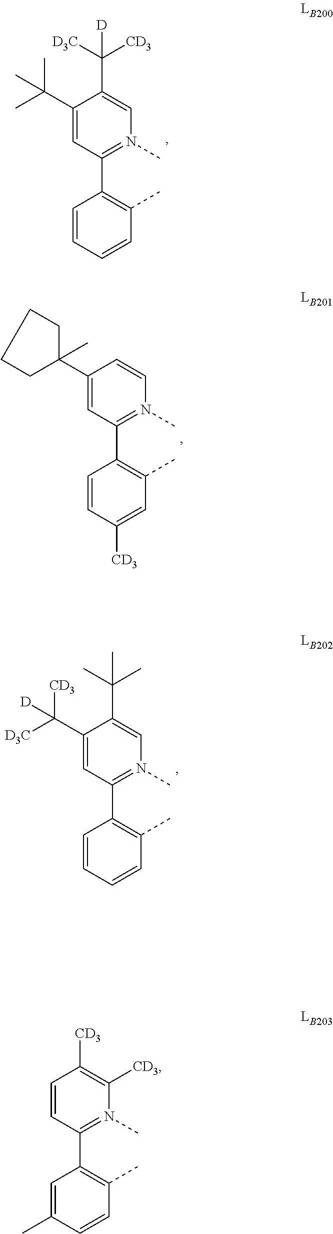

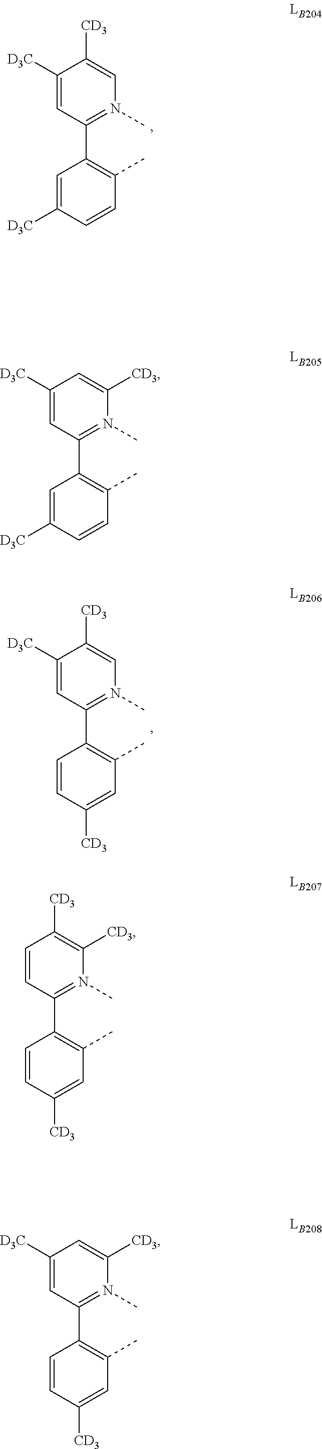

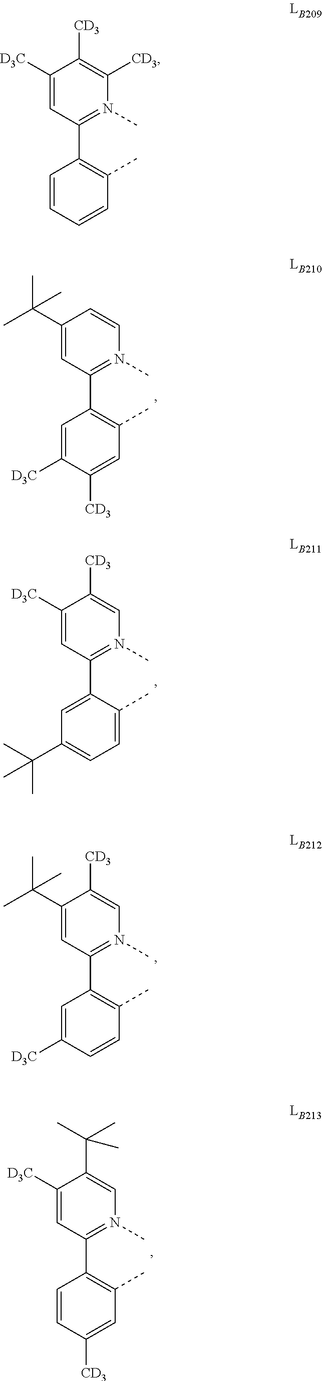

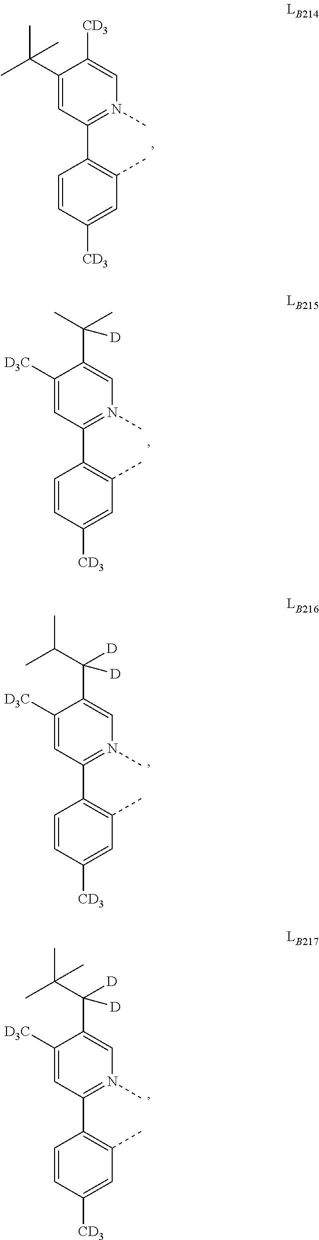

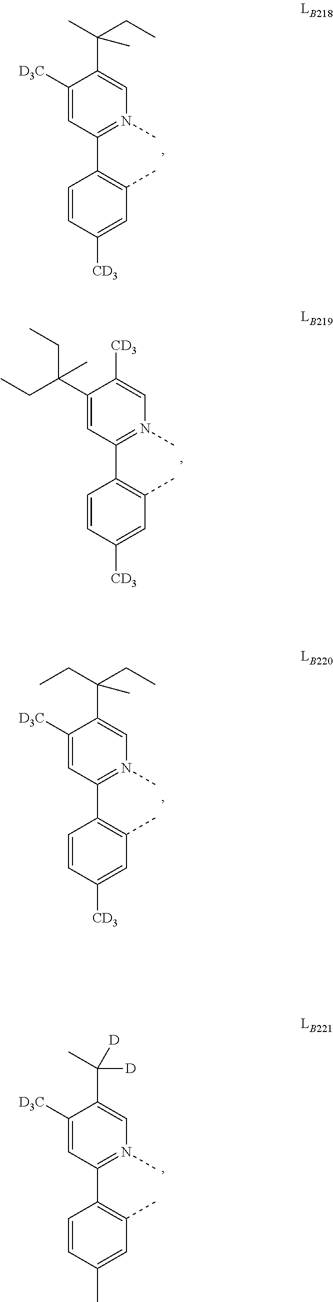

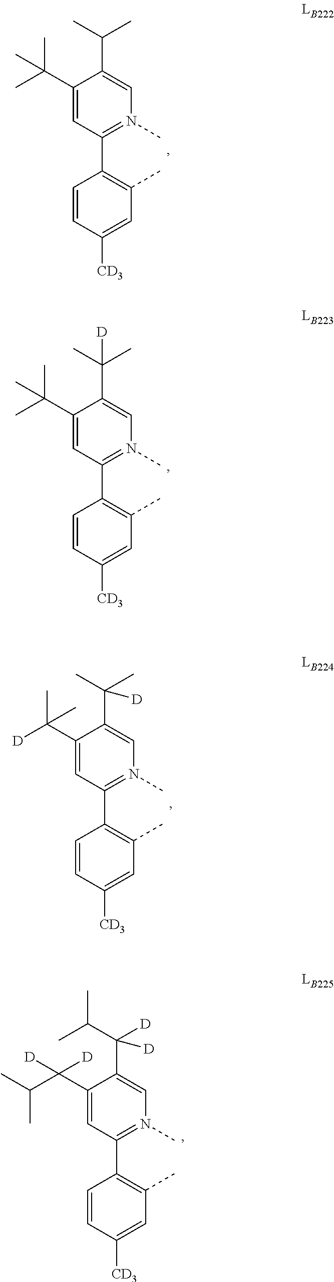

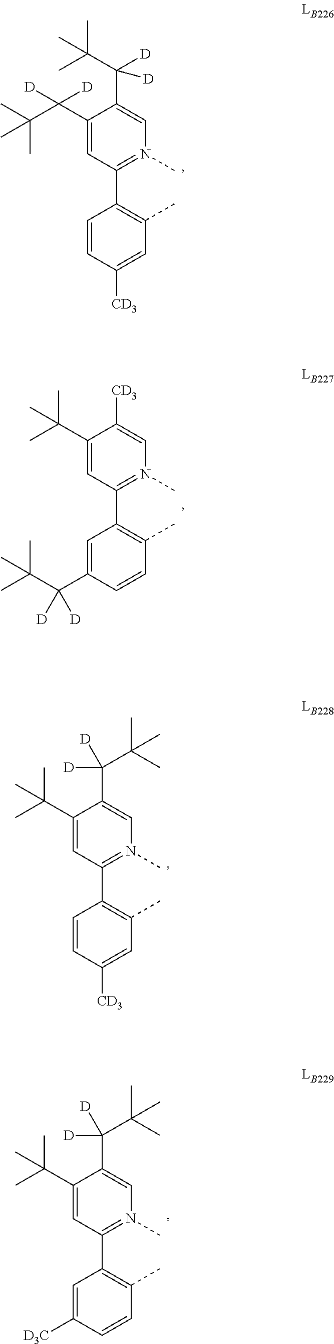

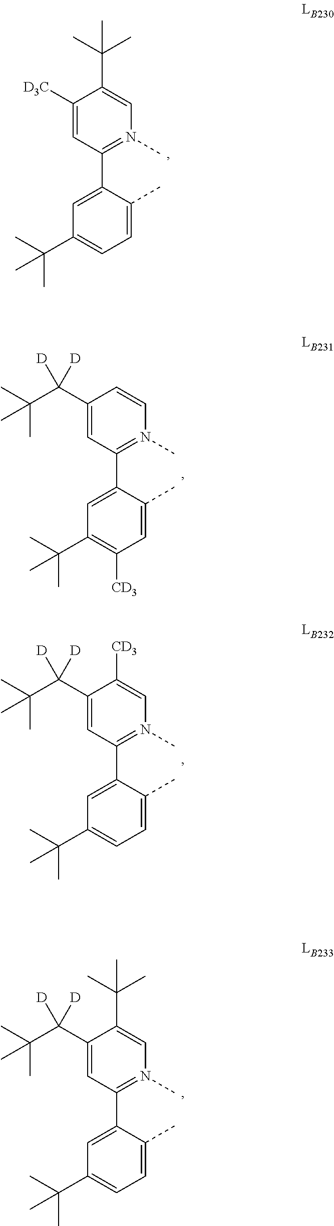

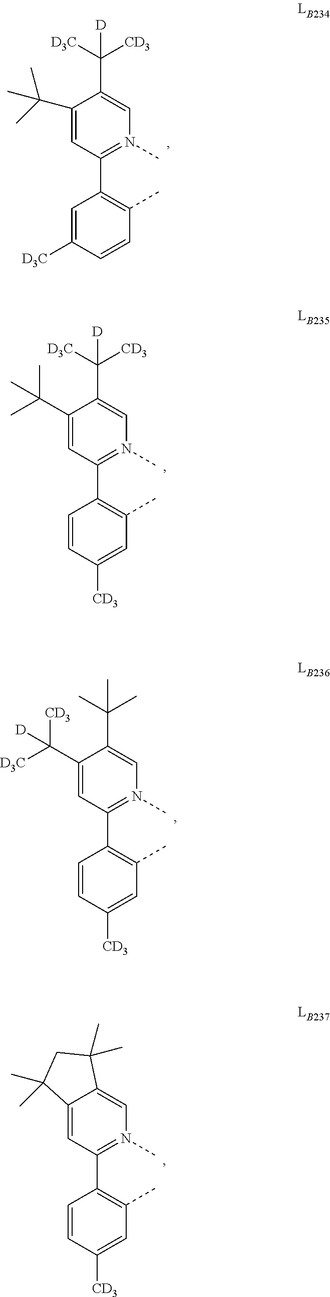

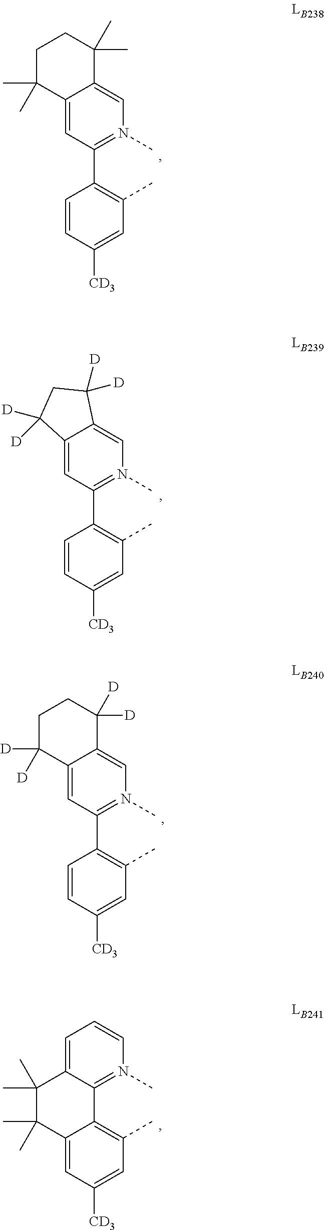

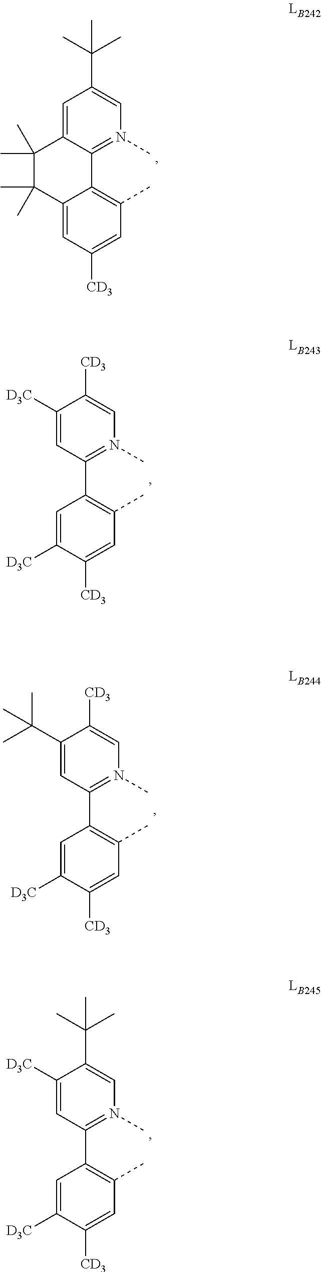

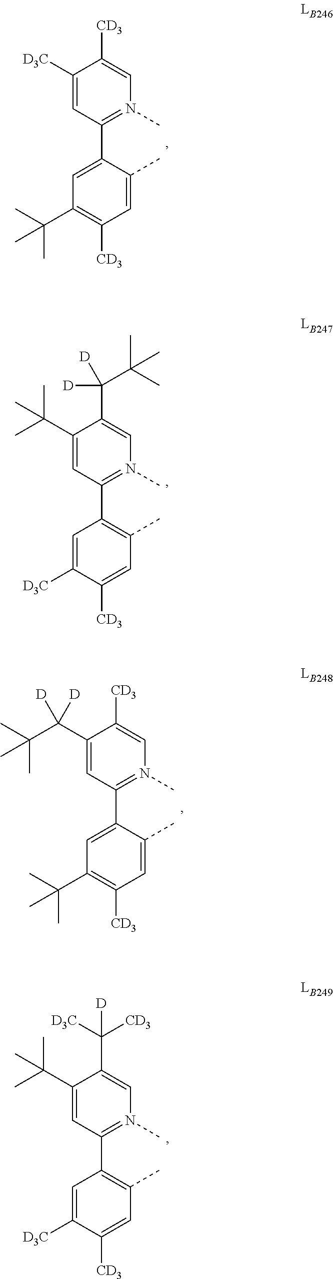

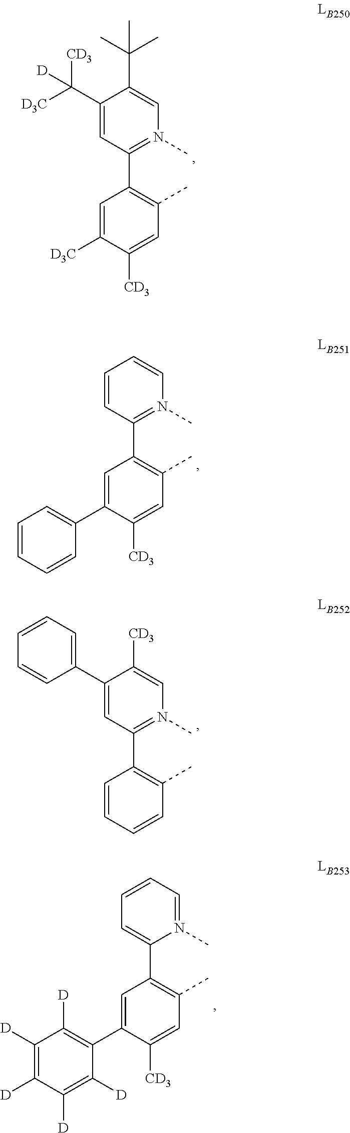

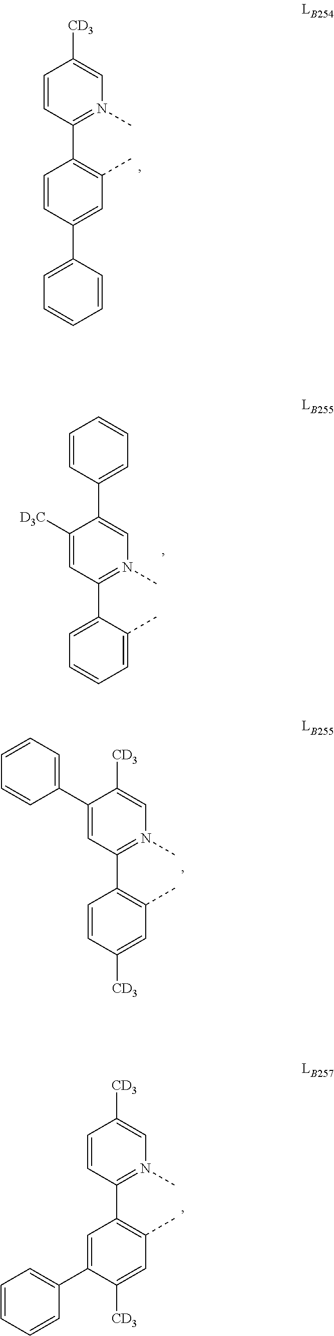

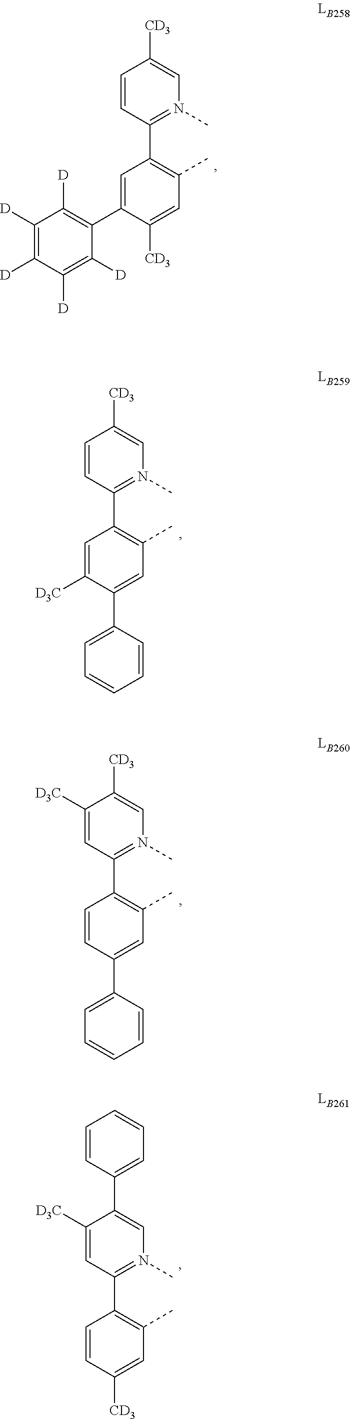

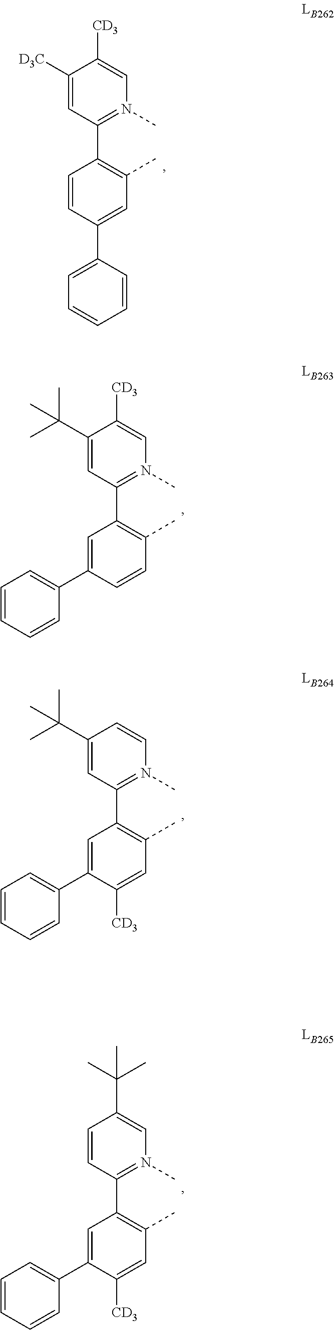

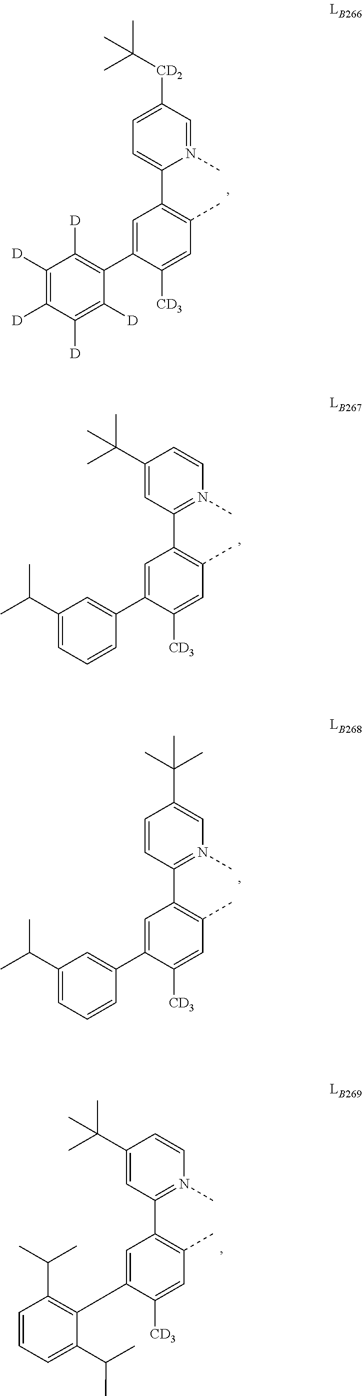

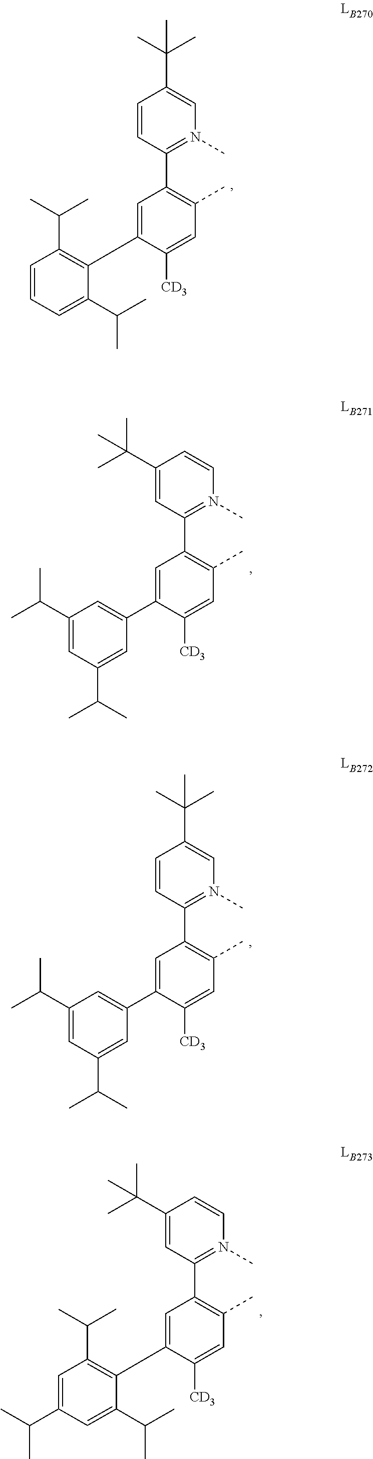

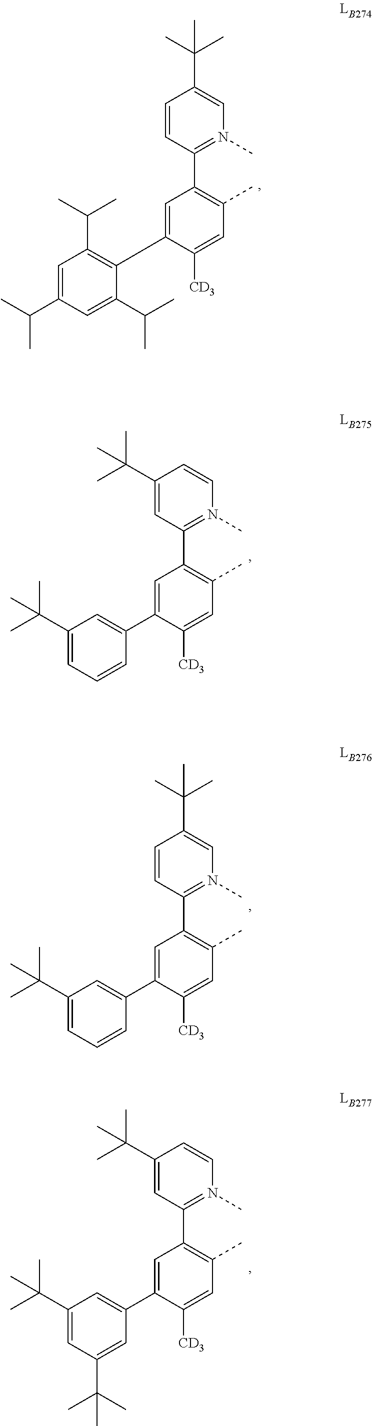

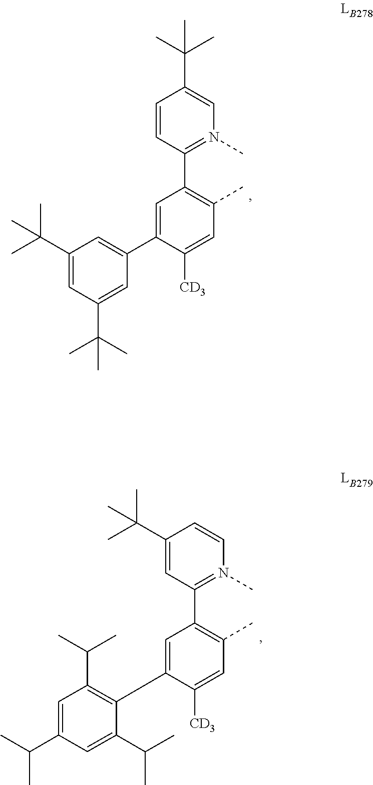

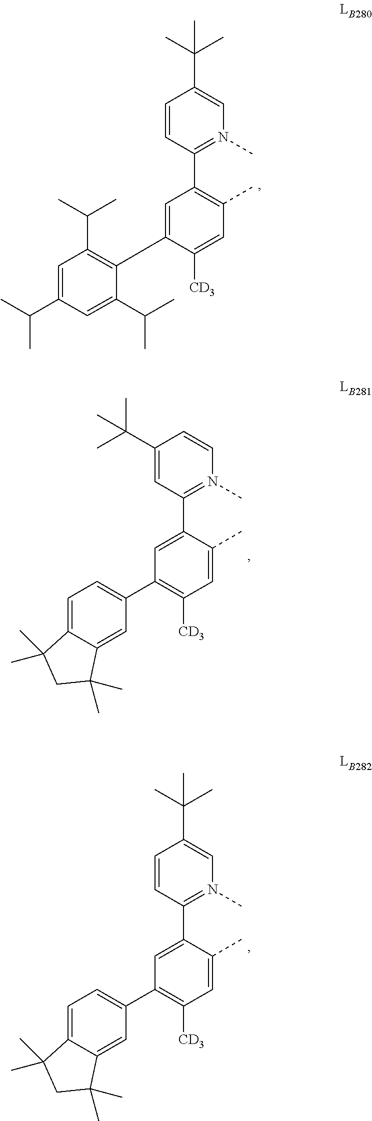

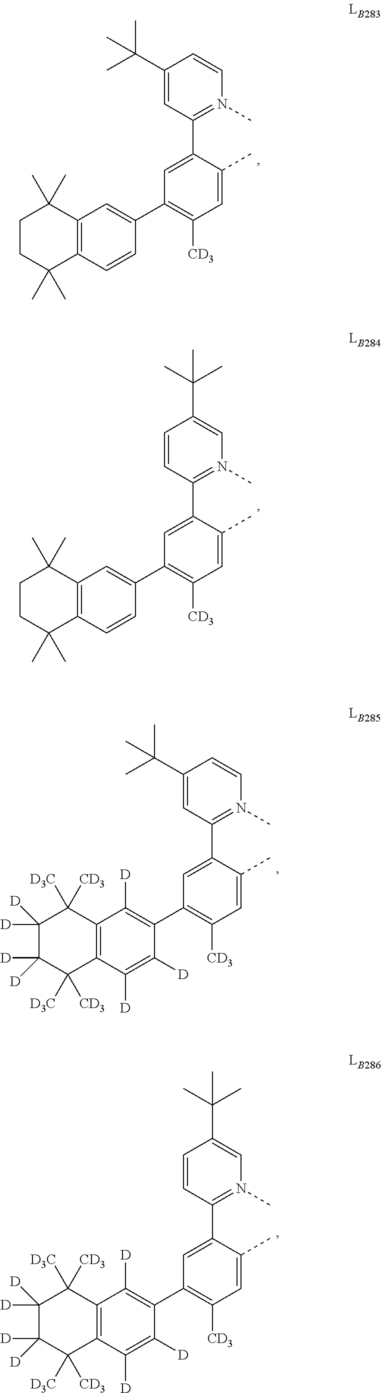

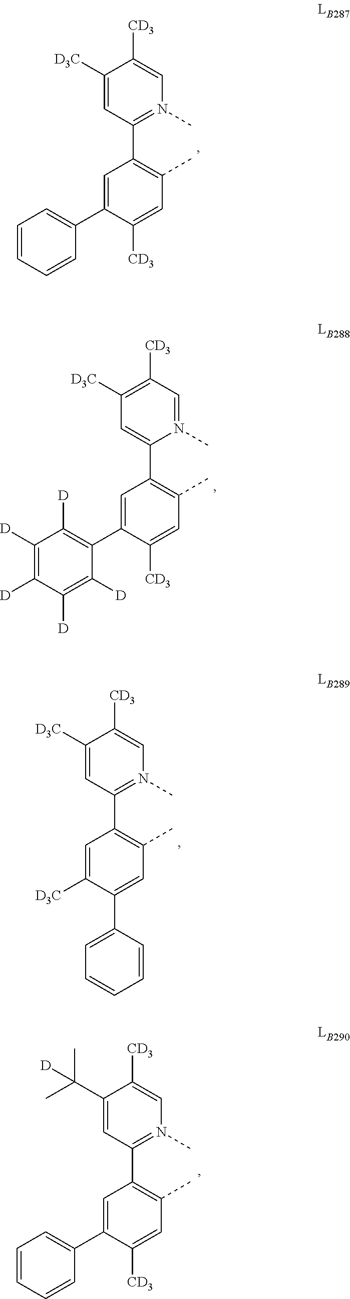

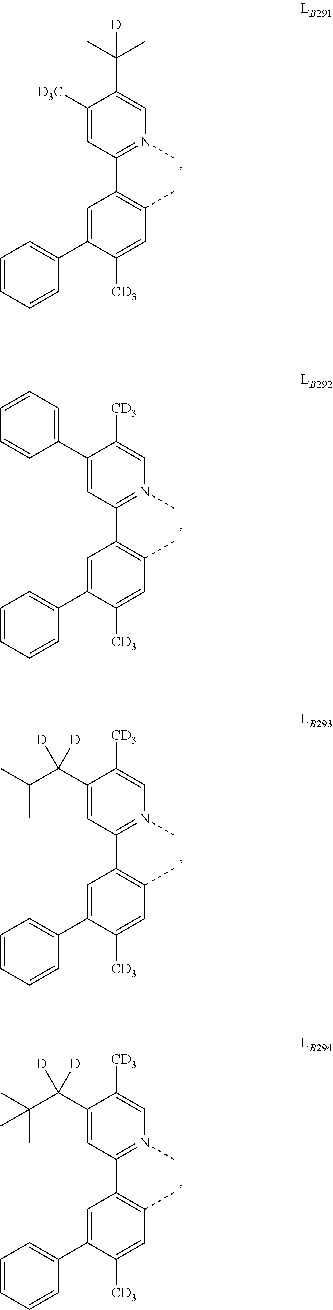

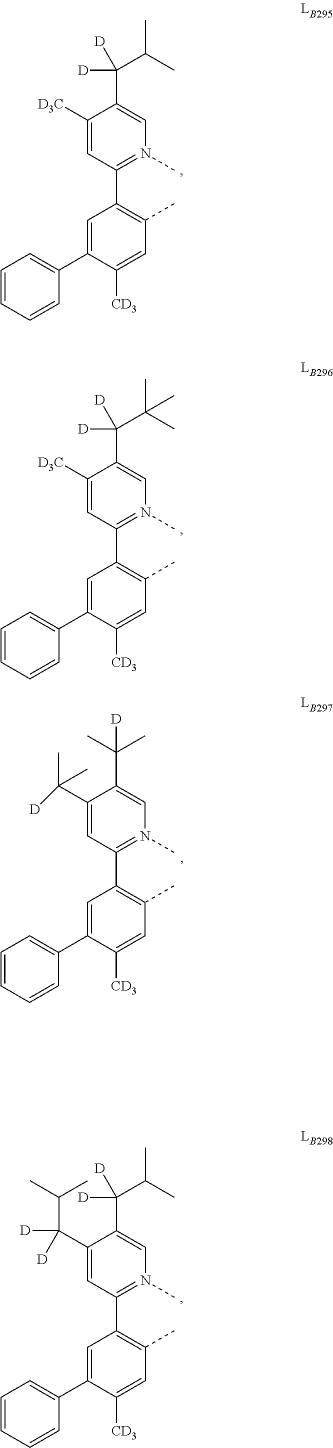

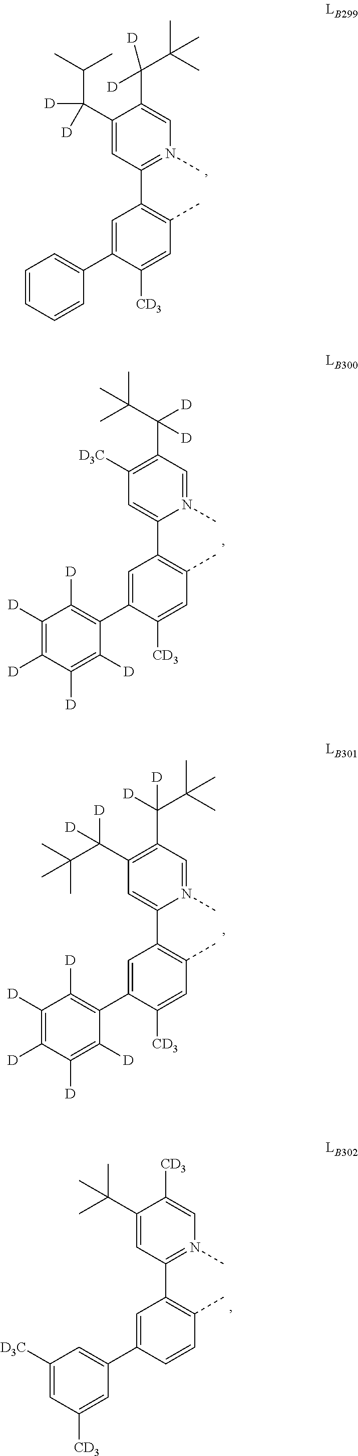

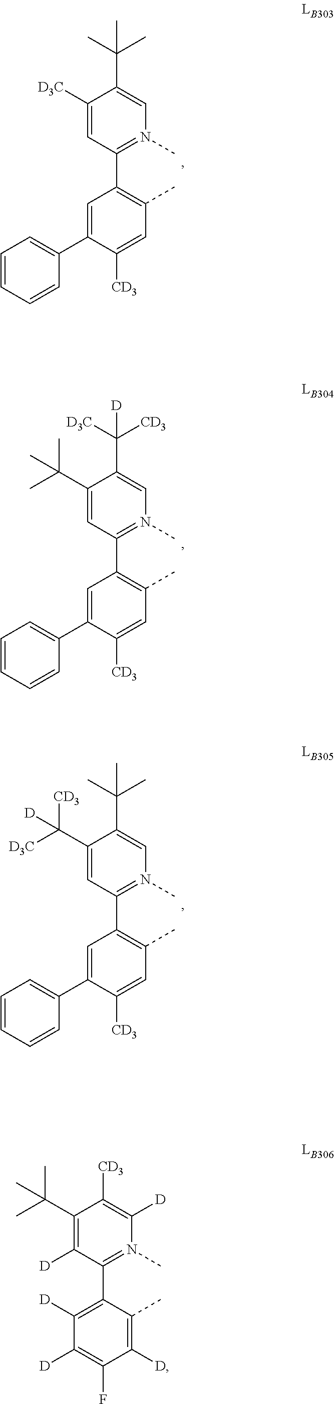

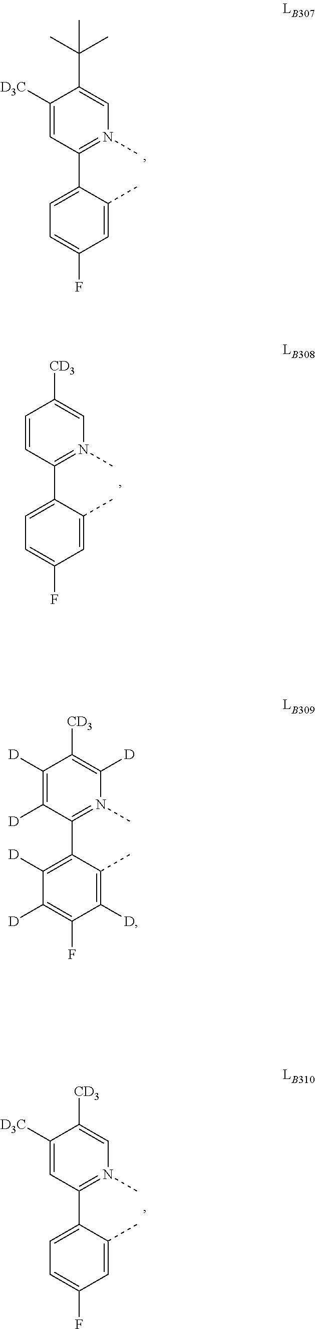

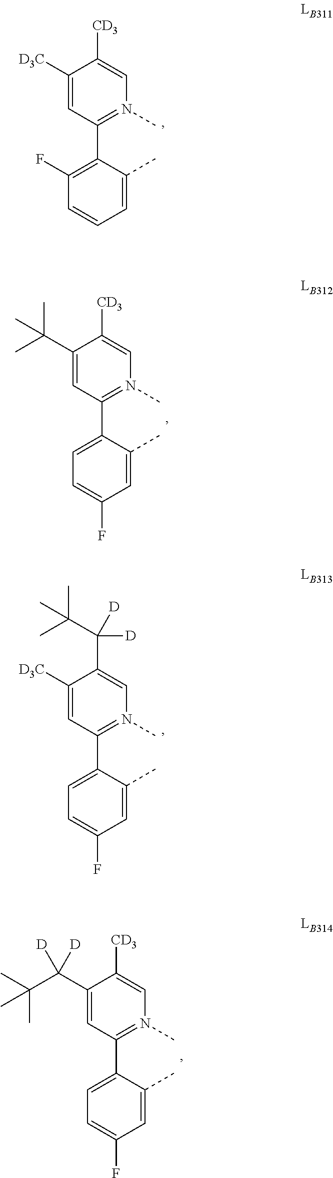

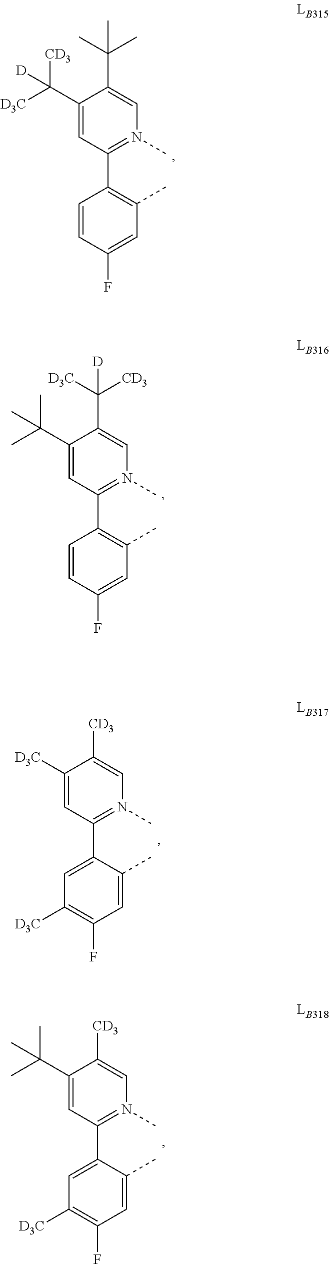

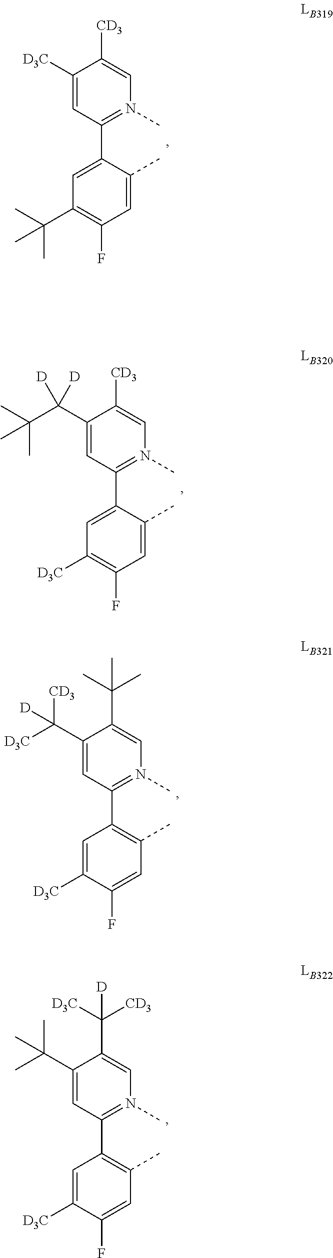

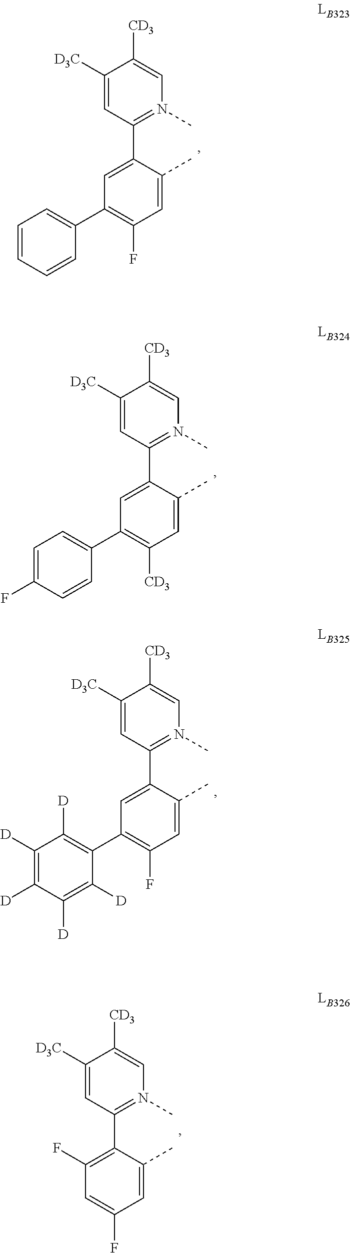

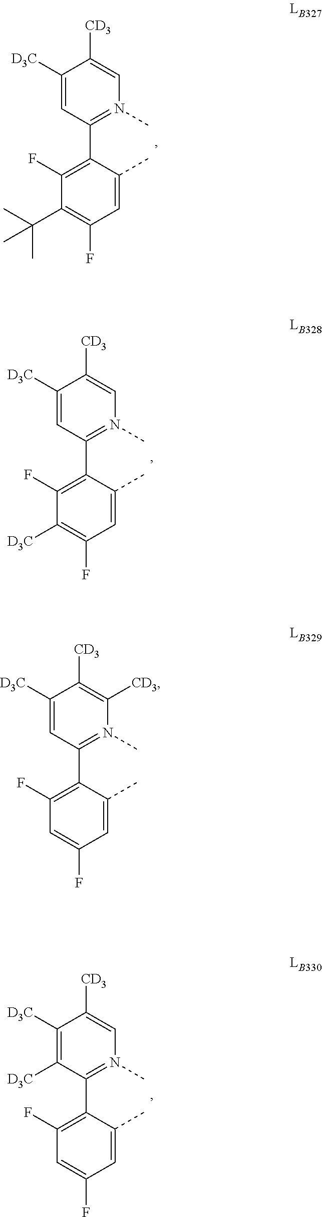

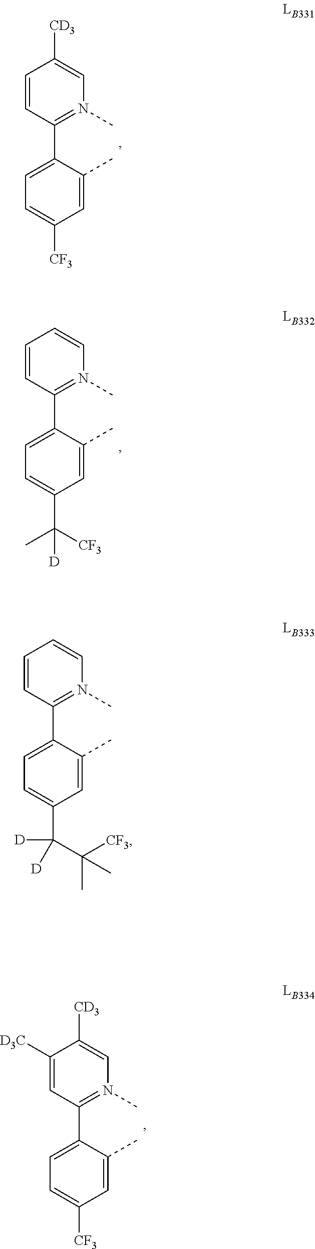

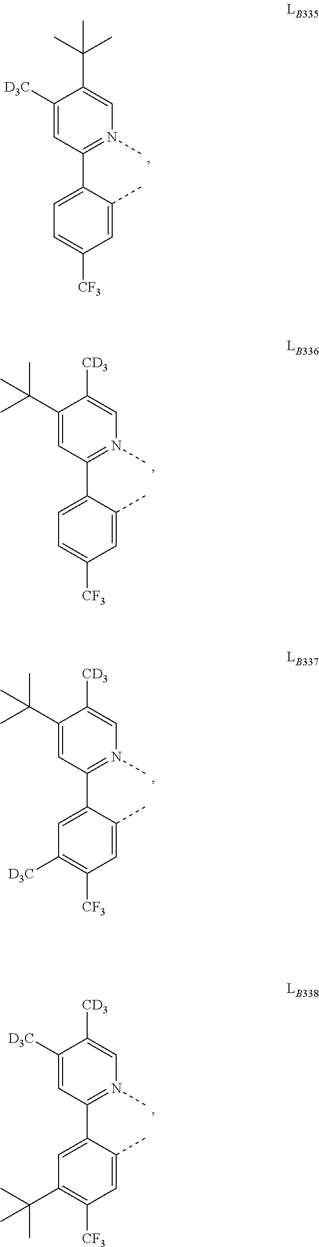

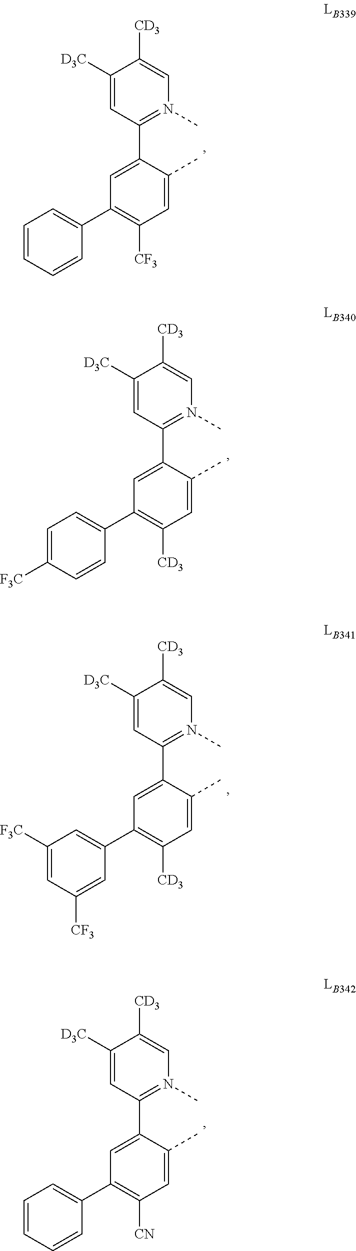

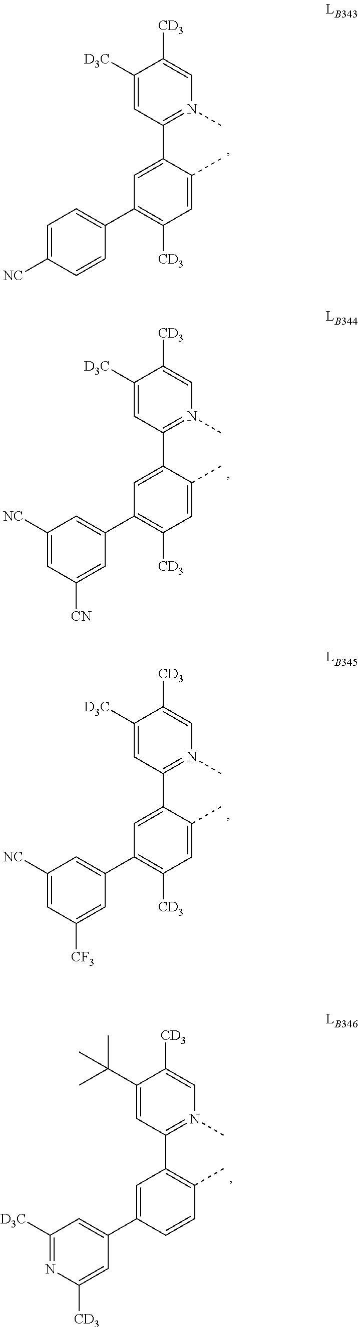

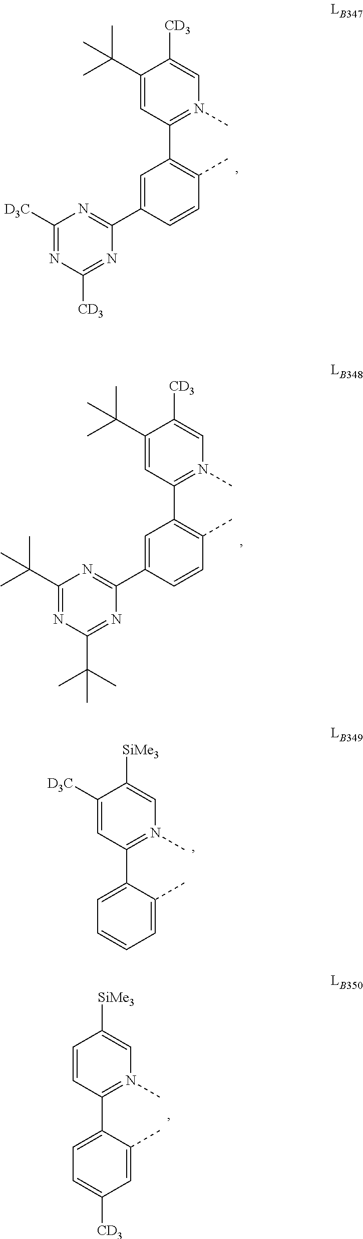

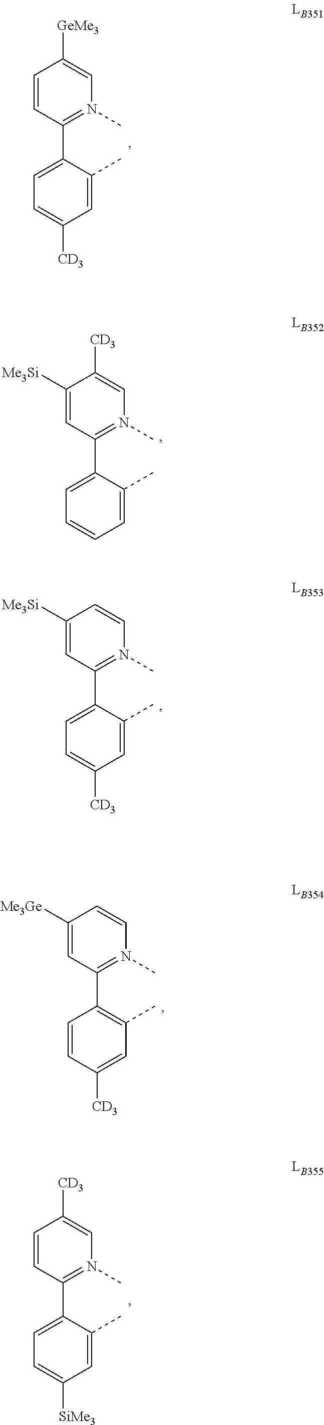

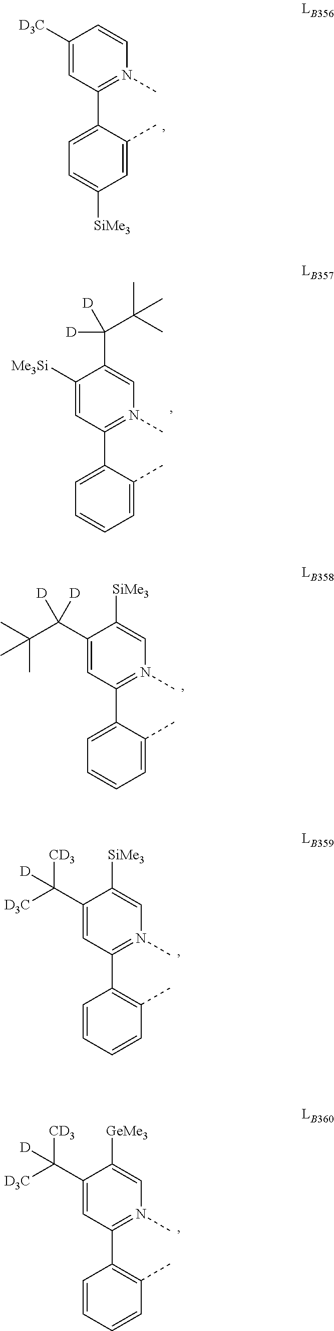

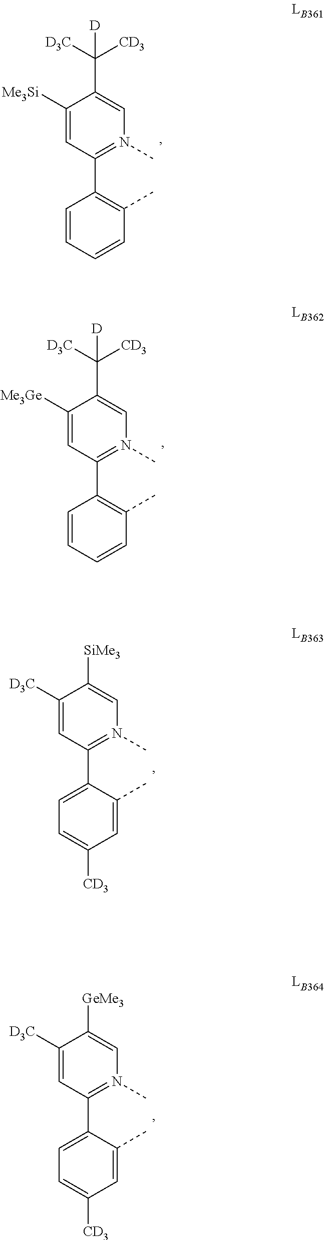

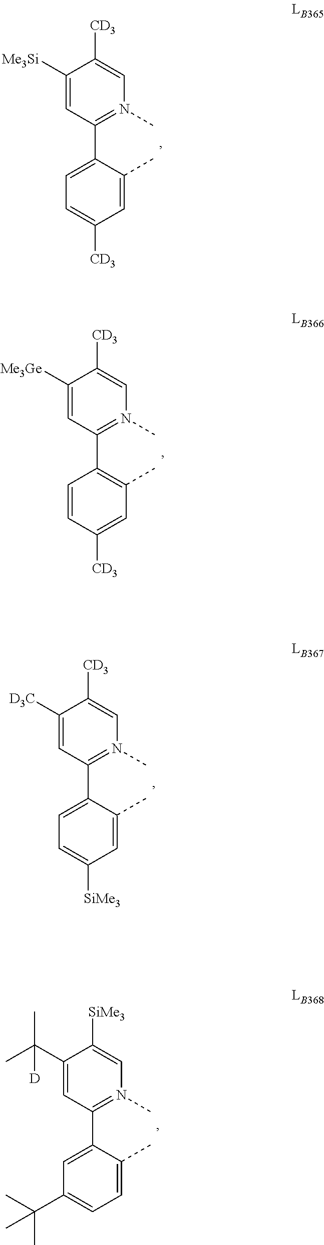

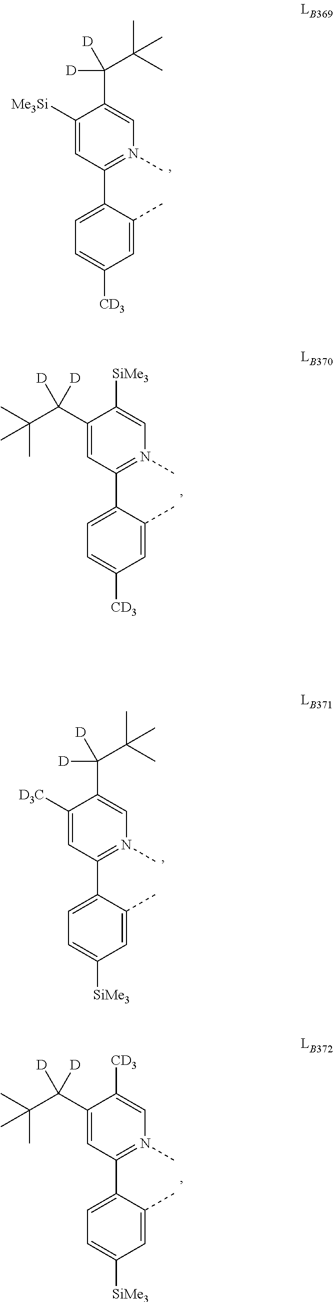

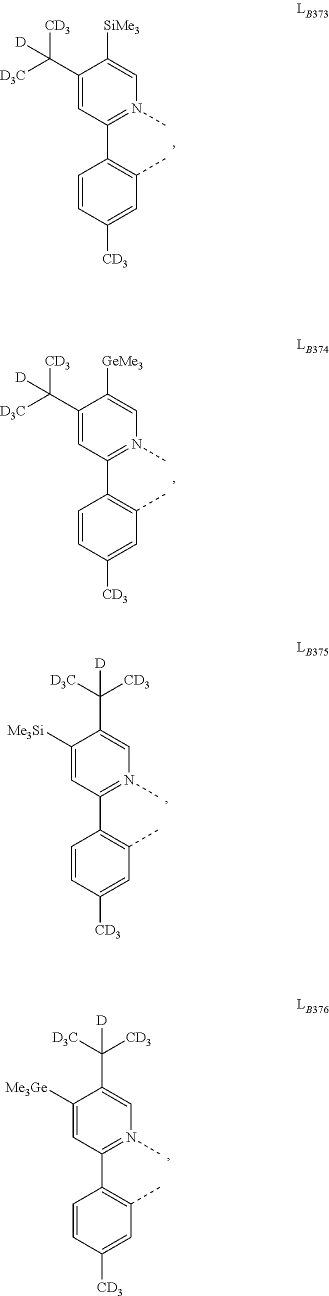

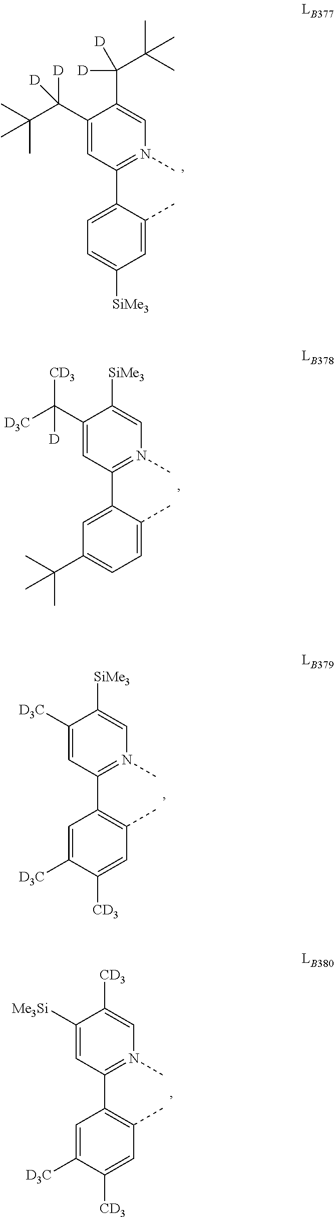

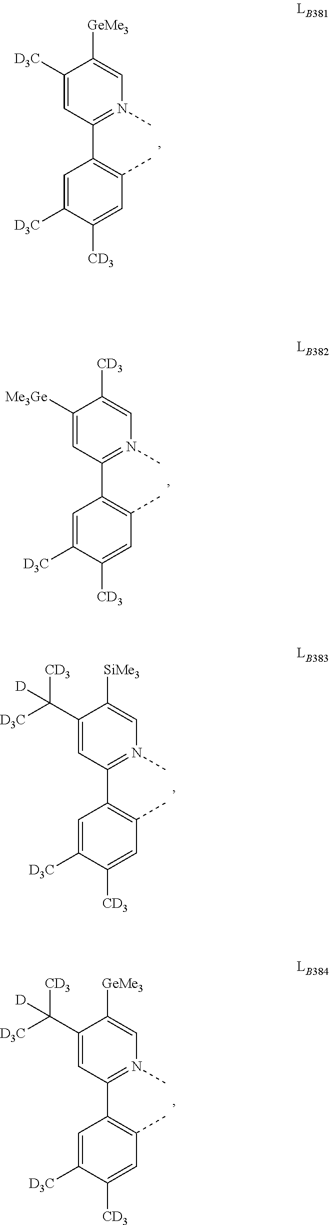

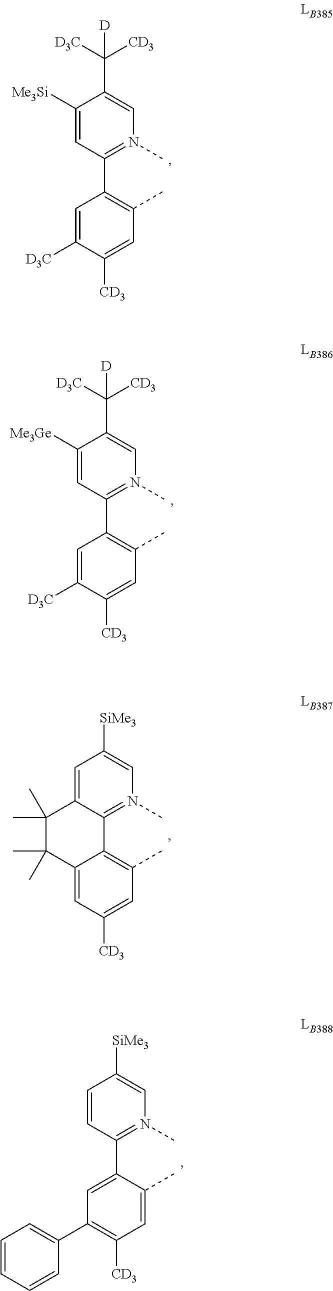

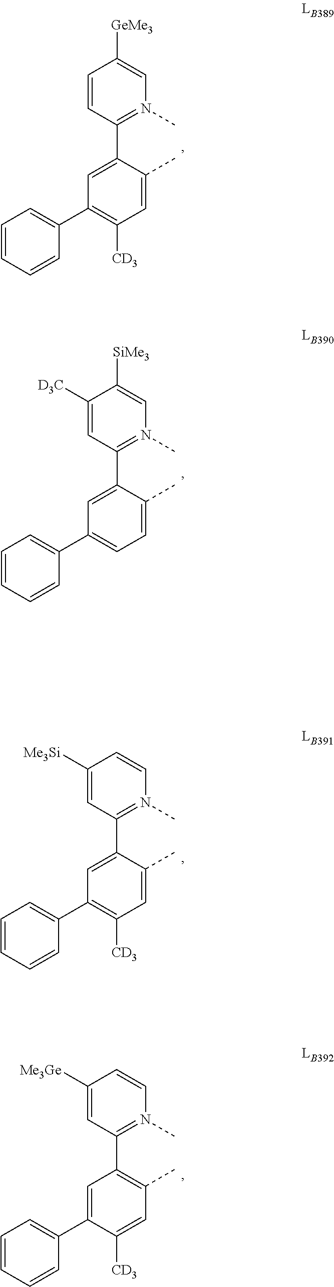

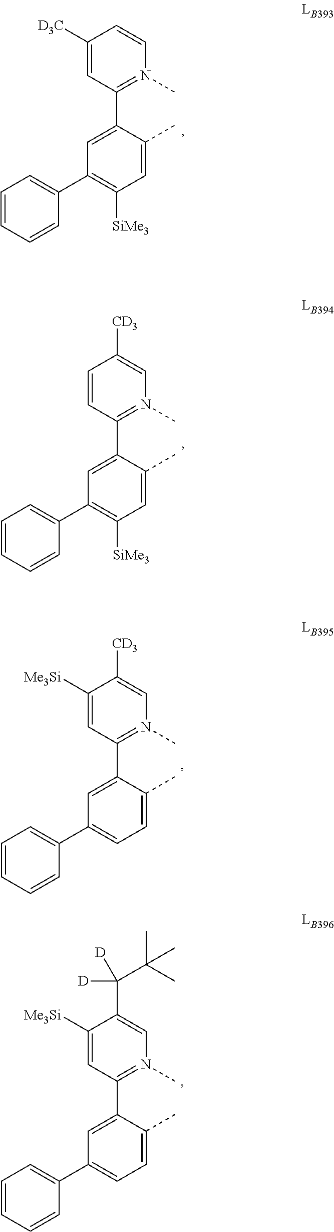

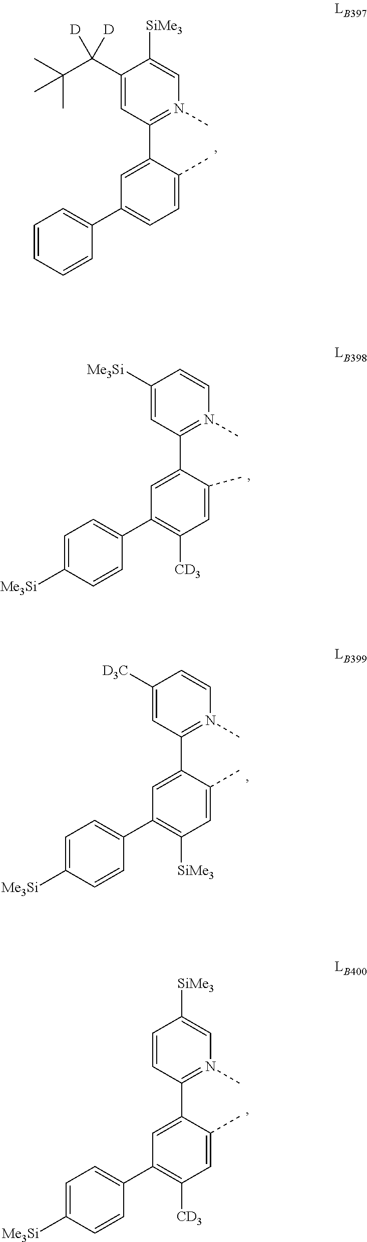

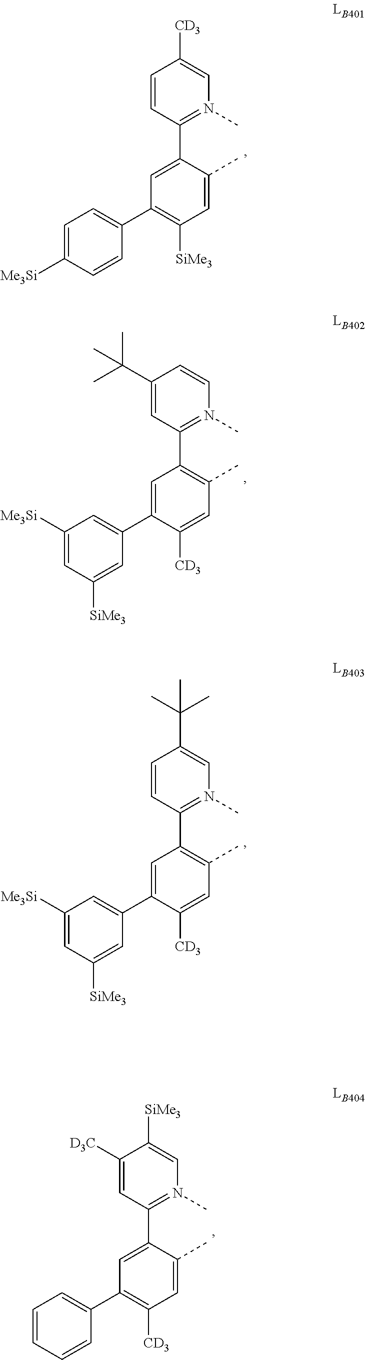

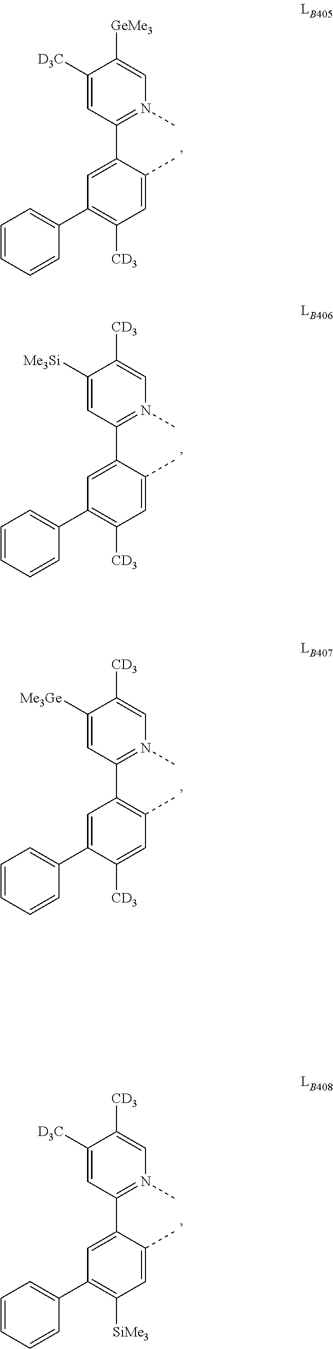

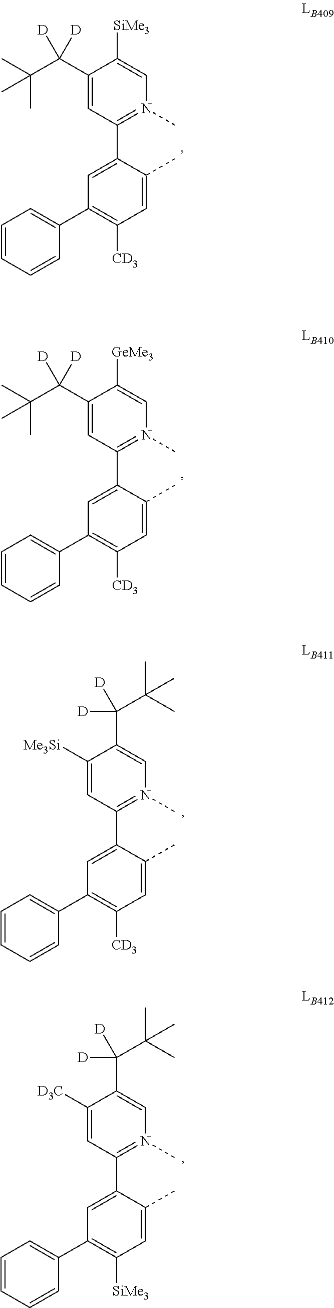

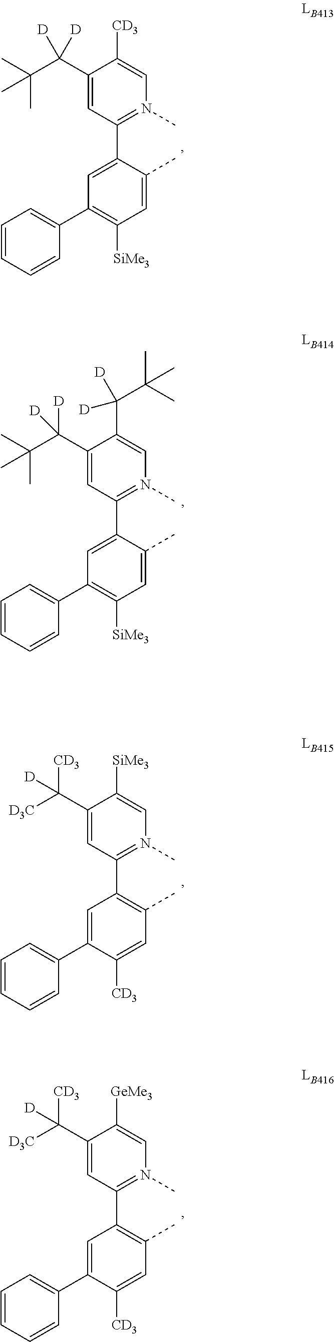

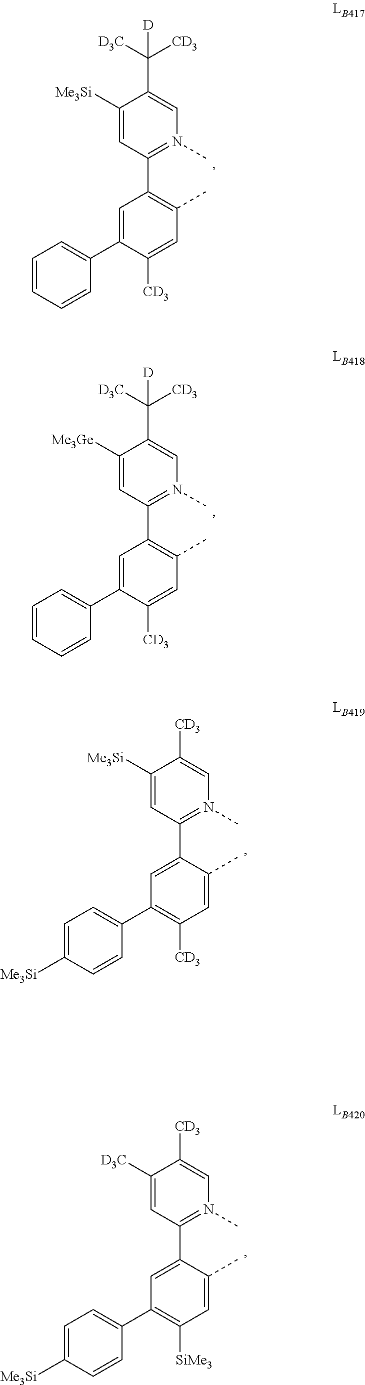

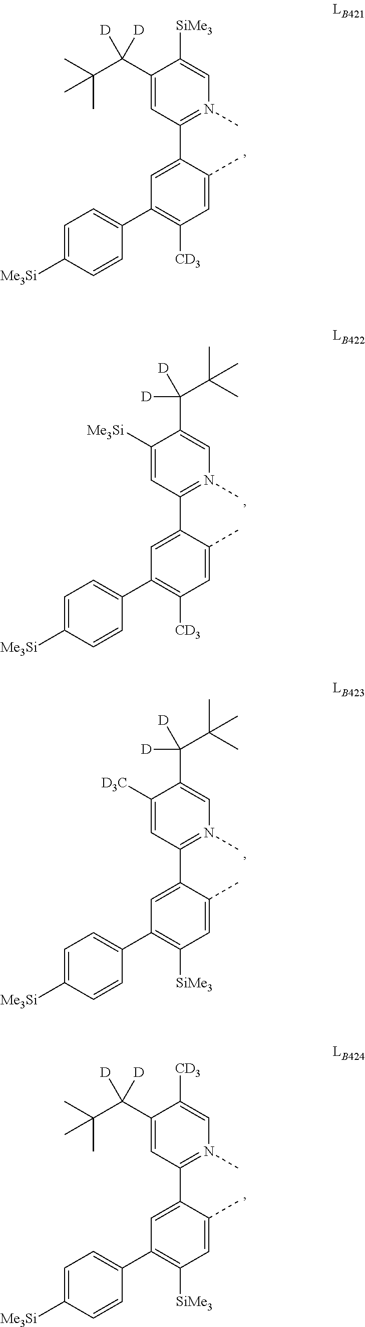

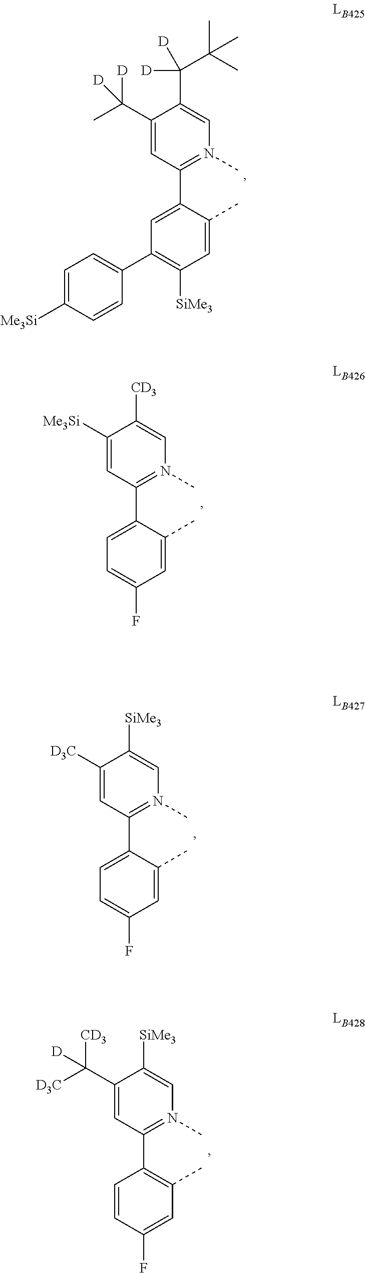

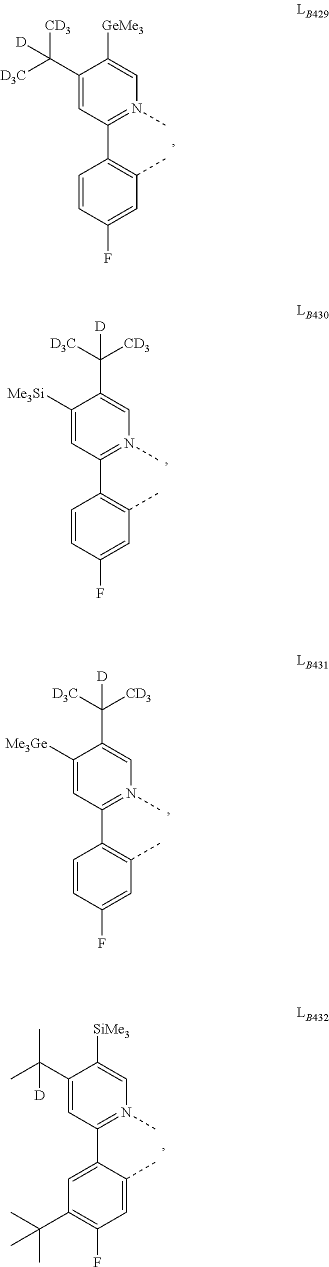

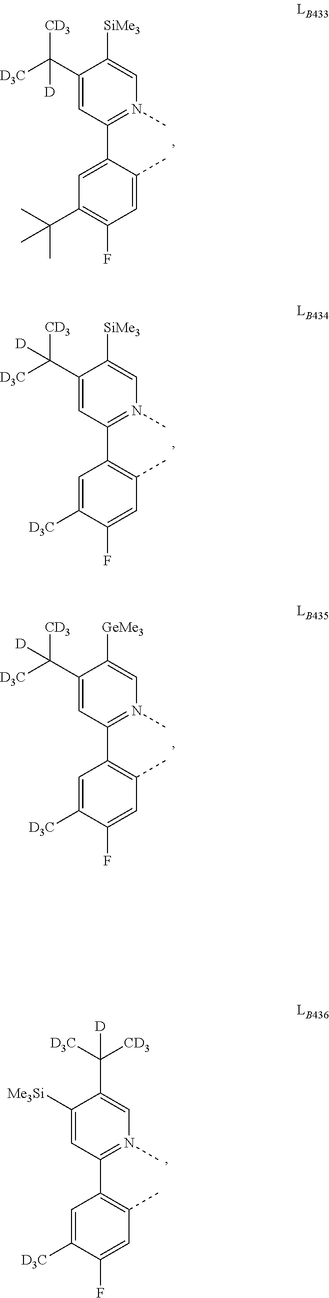

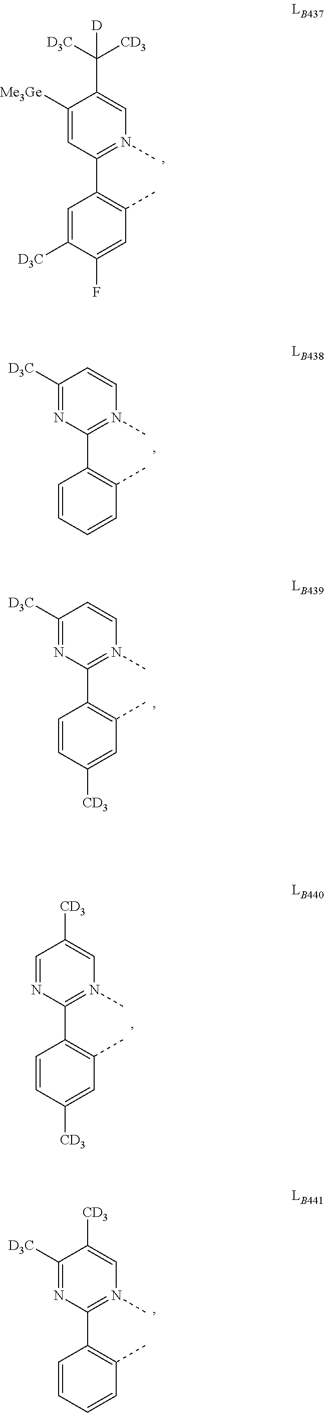

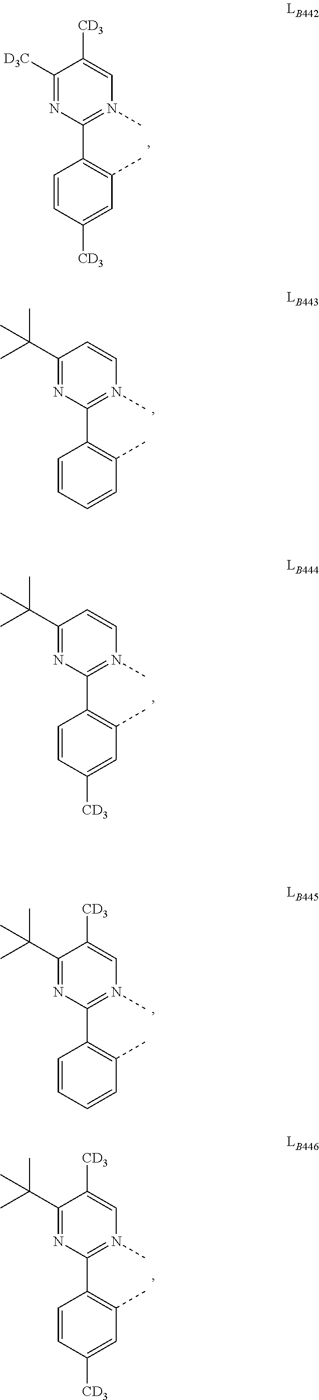

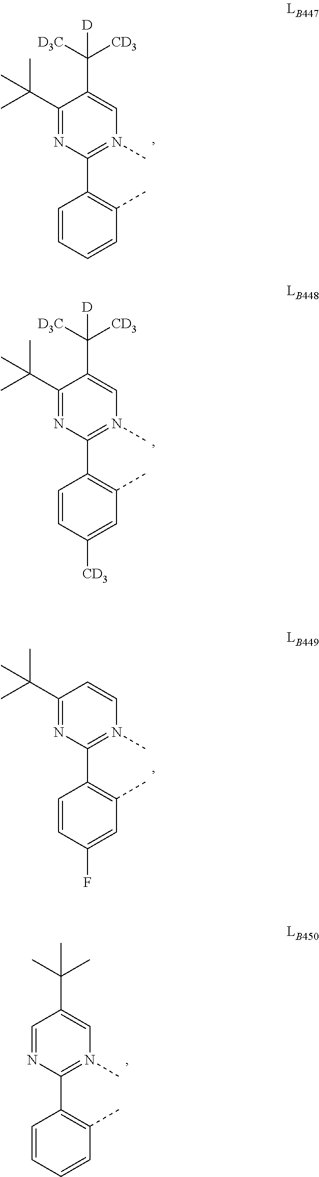

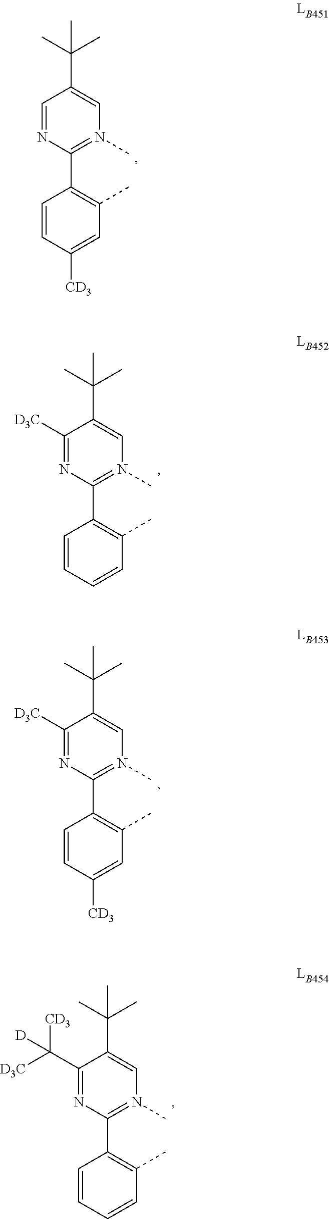

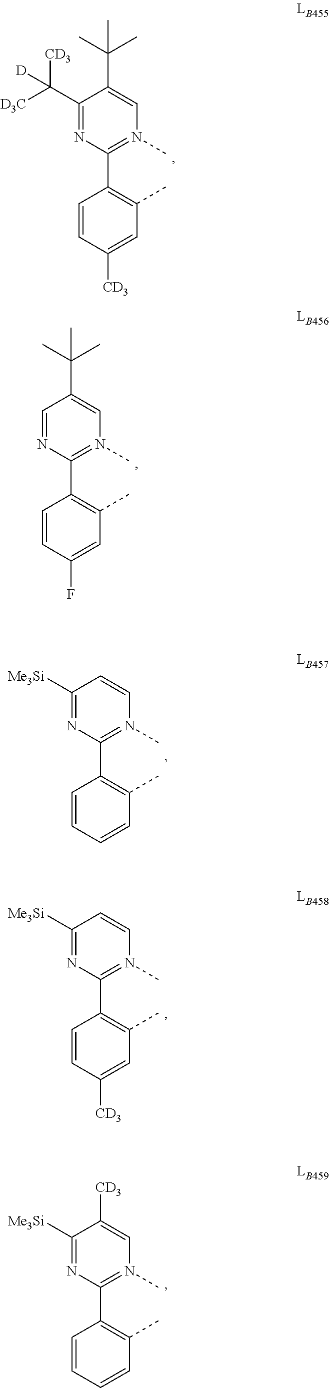

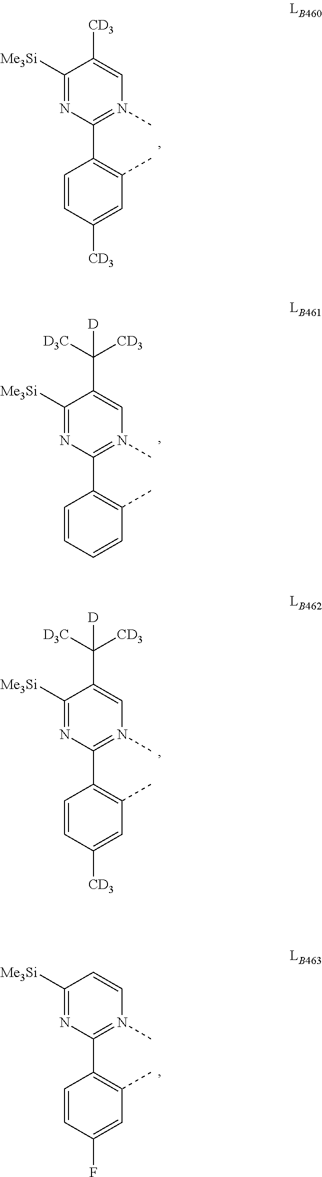

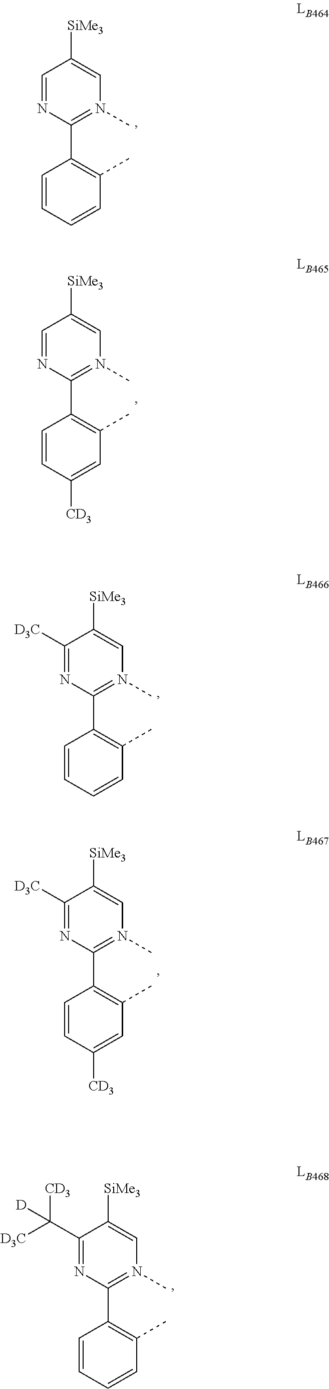

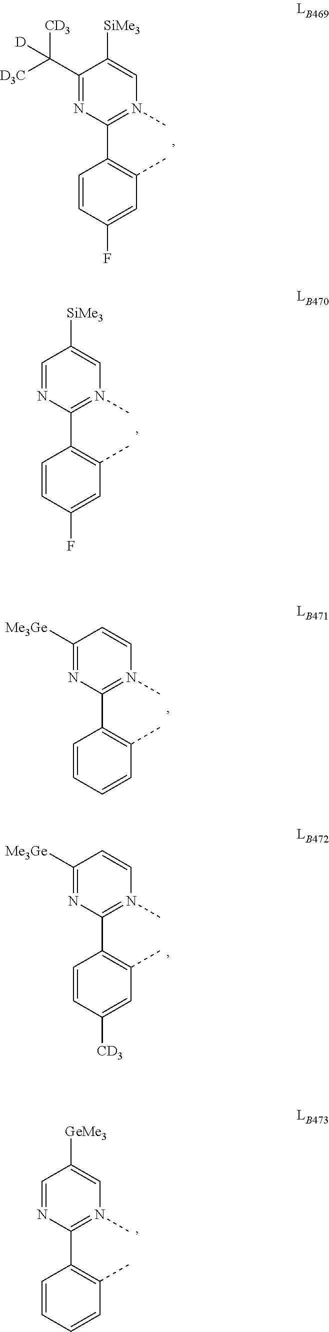

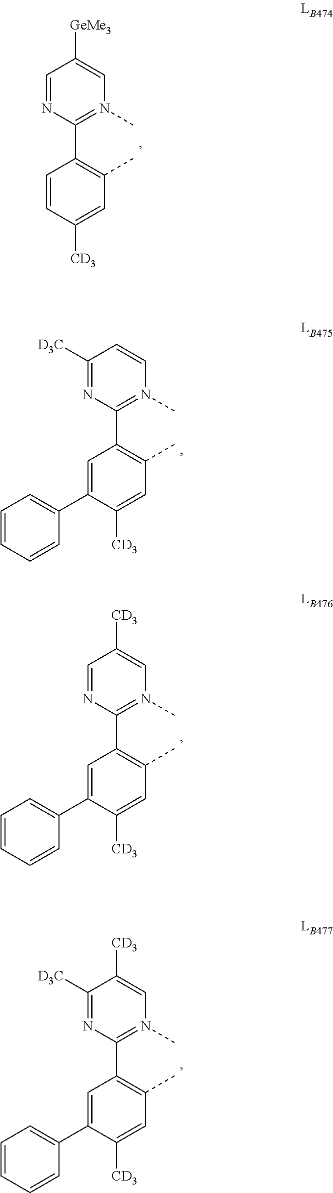

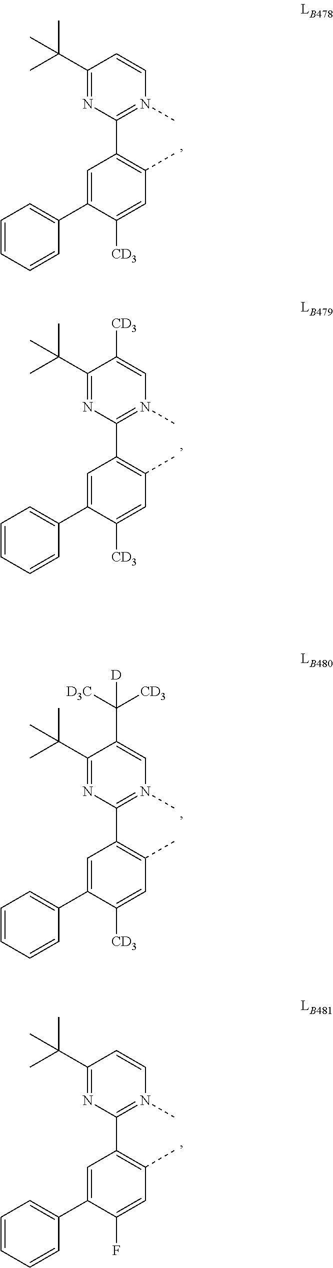

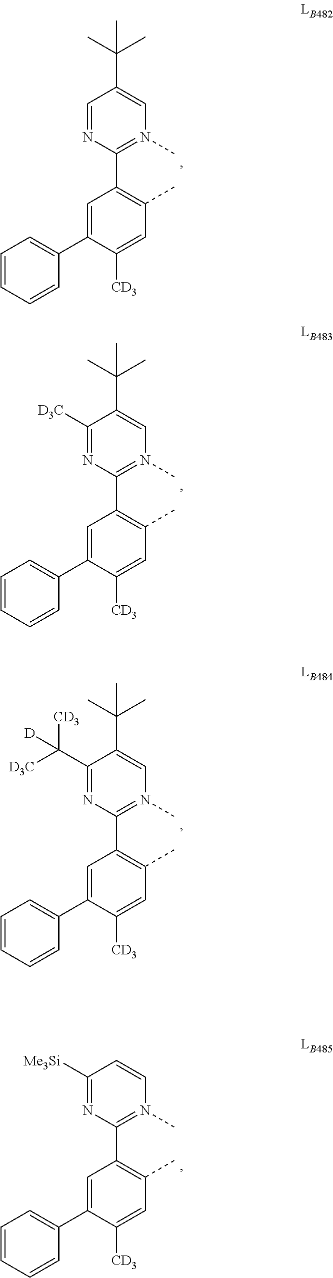

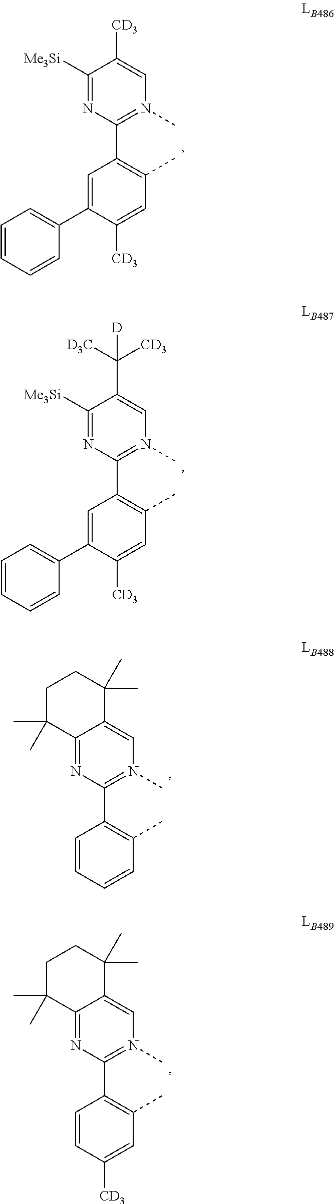

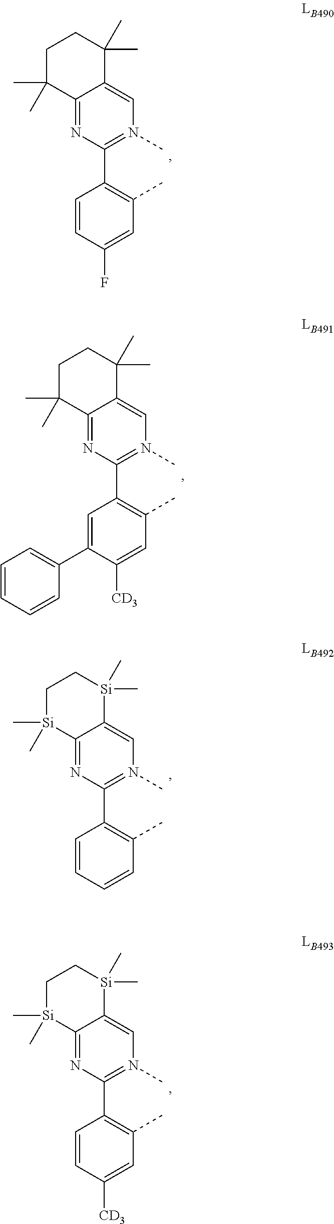

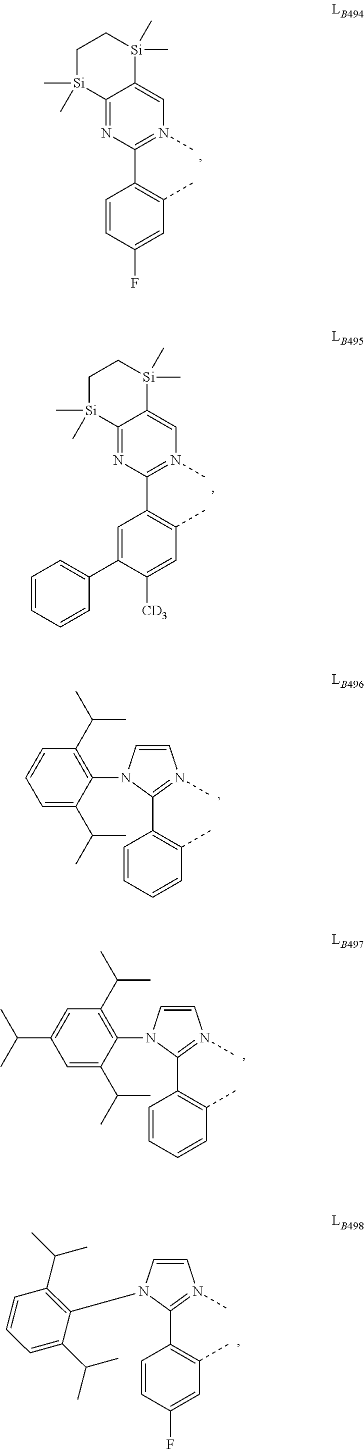

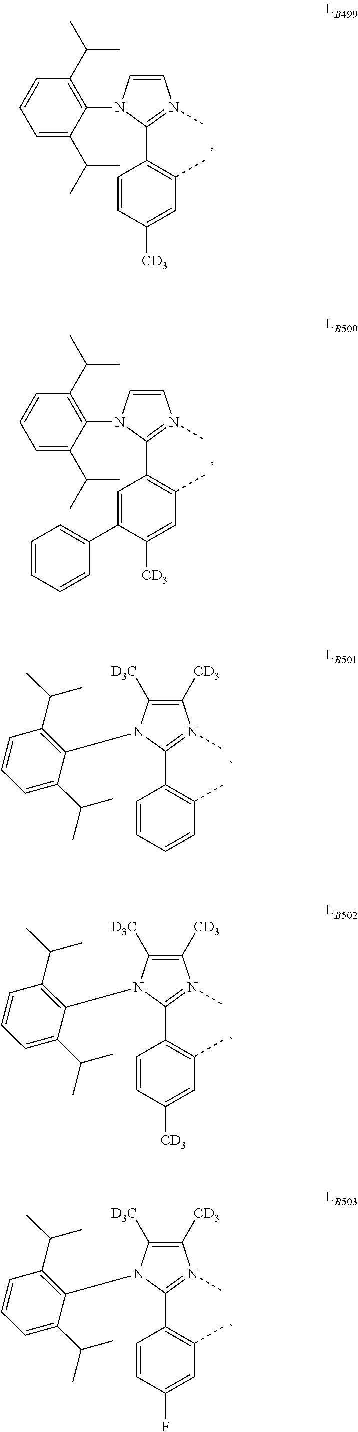

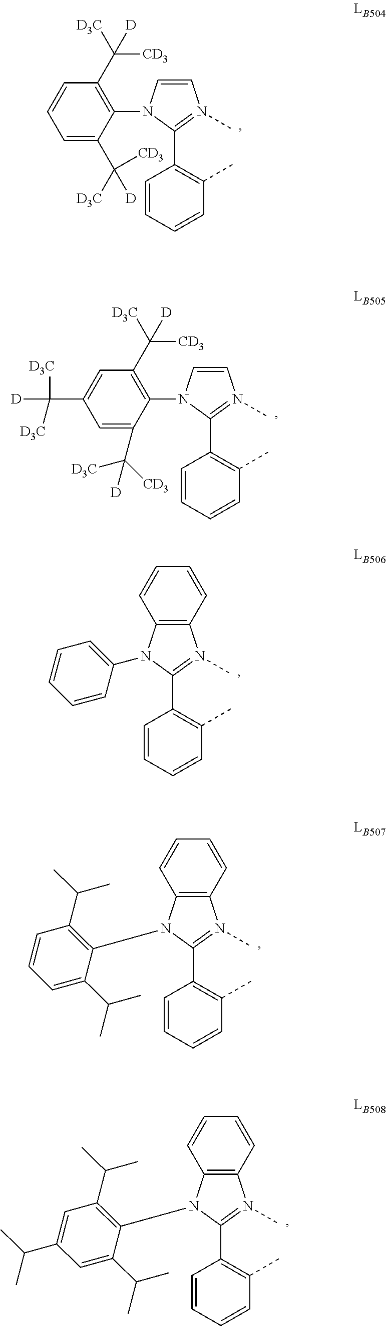

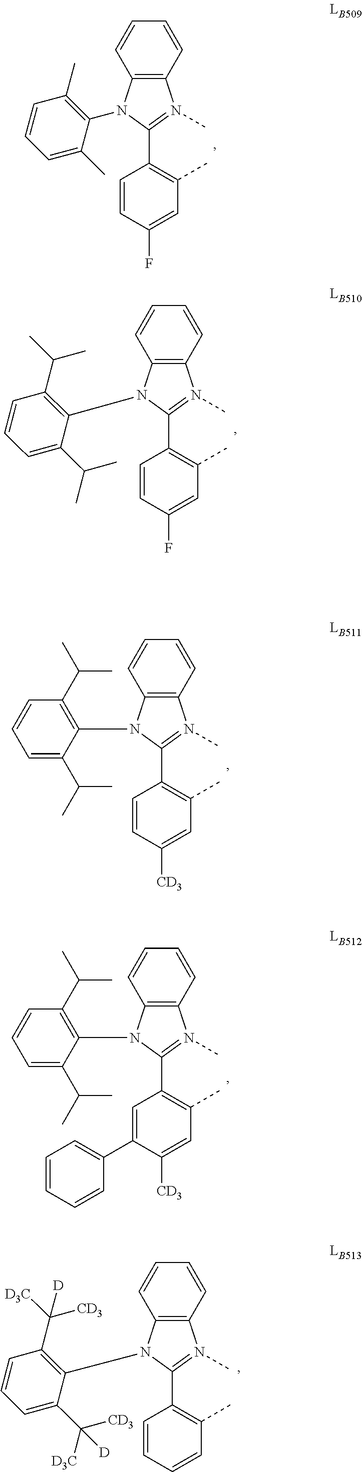

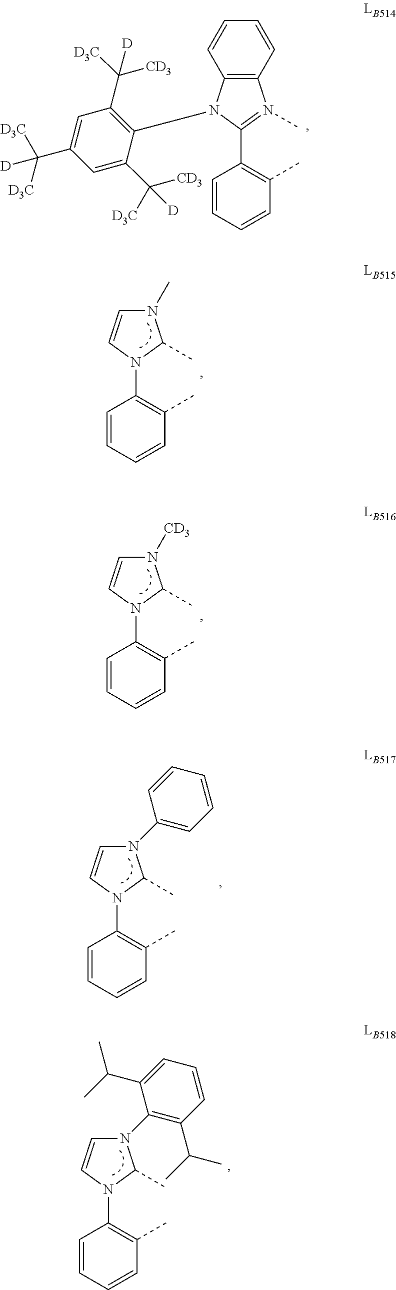

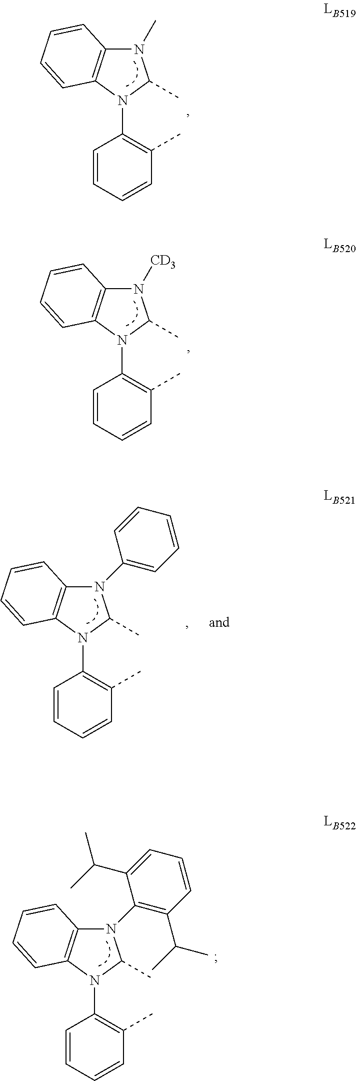

wherein j is an integer from 1 to 1416, and each L_{Cj-I} has a structure based on formula

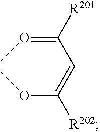

and each L_{Cj-II} has a structure based on formula

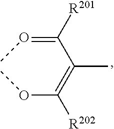

wherein for each L_{Cj} in L_{Cj-I} and L_{Cj-II}, R²⁰¹ and R²⁰² are each independently defined in the following LIST 8:

1. A compound comprising a first ligand L_{A} of Formula I′, 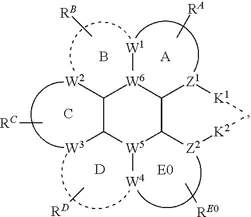
wherein moieties A, B, C, D, and E0 are each independently a monocyclic ring or a polycyclic fused ring system,
wherein the monocyclic ring or each ring of the polycyclic fused ring system is independently a 5-membered or 6-membered carbocyclic or heterocyclic ring;
wherein W¹, W², W³, and W⁴ are each independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
wherein W⁵ and W⁶ are each independently selected from the group consisting of BR, N, CR, SiR, and GeR;
wherein each of K¹ and K² is independently selected from the group consisting of a direct bond, O, S, N(R^{α}), P(R^{α}), B(R^{α}), C(R^{α})(R^{β}), and Si(R^{α})(R^{β});
at least one of K¹ and K² is a direct bond;
each of R^{A}, R^{B}, R^{C}, R^{D}, and R^{E0} independently represents mono to a maximum allowable substitution, or no substitution;
each R, R′, R^{α}, R^{β}, R^{A}, R^{B}, R^{C}, R^{D}, and R^{E0} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M;
M may be coordinate to other ligands;
L_{A} may join with other ligands to form a tridentate, tetradentate, pentadentate, or hexadentate ligand;
wherein any two substituents may be joined or fused to form a ring; and
wherein compound is not

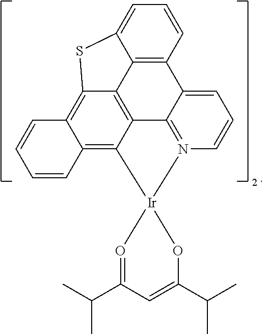

2. The compound of claim 1, wherein the first ligand L_{A} has a structure of Formula I, 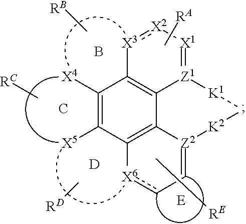
wherein:
each of moiety C, moiety E, and, when present, moieties B and D is independently a monocyclic ring or a polycyclic fused ring system, wherein the monocyclic ring or each ring of the polycyclic fused ring system is independently a 5-membered or 6-membered carbocyclic or heterocyclic ring;
the dashed arcs indicate that moiety B and moiety D are optionally present;
each of X¹, X², Z¹, and Z² is independently C or N;
each of X³ to X⁶ is independently selected from the group consisting of C, O, S, Se, N, P, Si, and Ge;
if each of X³ to X⁶ is carbon, then at least one of moiety B and moiety D is present;
each of K¹ and K² is independently selected from the group consisting of a direct bond, O, S, N(R^{α}), P(R^{α}), B(R^{α}), C(R^{α})(R^{β}), and Si(R^{α})(R^{β});
at least one of K¹ and K² is a direct bond;
each [symbol] is independently a single bond or a double bond;
each of R^{A}, R^{B}, R^{C}, R^{D}, and R^{E} independently represents mono to a maximum allowable substitution, or no substitution;
each R^{α}, R^{β}, R^{A}, R^{B}, R^{C}, R^{D}, and R^{E} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M;
M may be coordinate to other ligands;
L_{A} may join with other ligands to comprise a tridentate, tetradentate, pentadentate, or hexadentate ligand; and
any two substituents may be joined or fused to form a ring.

3. The compound of claim 1, wherein each R^{α}, R^{β}, R^{A}, R^{B}, R^{C}, R^{D}, and R^{E} is independently hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

4. The compound of claim 1, wherein each of moiety C, moiety E, and, when present, moieties B and D is independently selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-anthracene, phenanthridine, fluorene, and aza-fluorene.

5. The compound of claim 1, wherein moiety D is not present; and/or wherein moiety B is present.

6. The compound of claim 1, wherein two R^{A} are joined or fused to form a ring; and/or wherein two R^{B} when present are joined or fused to form a ring; and/or wherein two R^{C} are joined or fused to form a ring; and/or wherein two R^{D} when present are joined or fused to form a ring; and/or wherein two R^{E} are joined or fused to form a ring; and/or wherein the compound comprises an electron-withdrawing group; and/or wherein metal M is selected from the group consisting of Ir, Rh, Re, Ru, Os, Pt, Pd, Ag, Au, and Cu.

7. The compound of claim 1, wherein the ligand L_{A} is selected from the group consisting of: 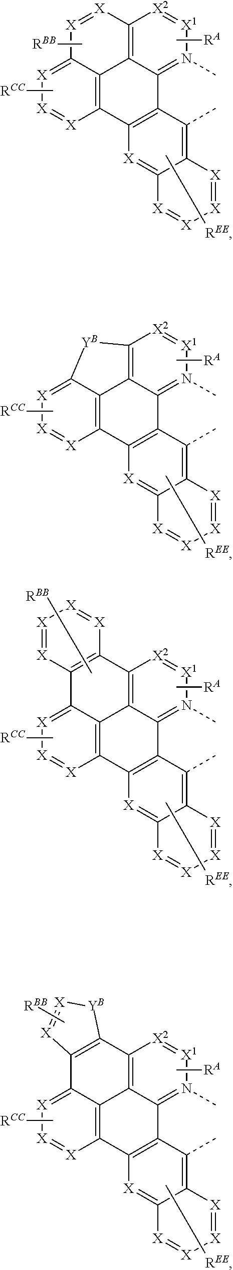 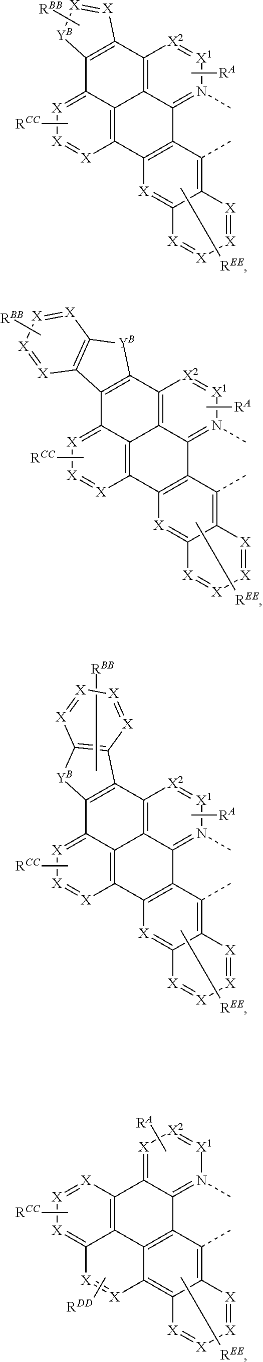 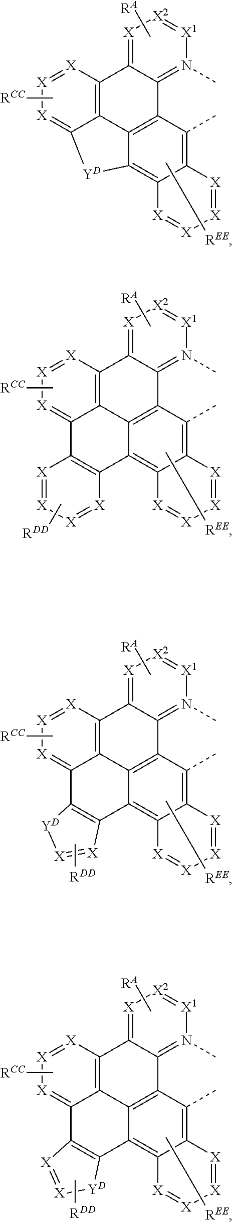 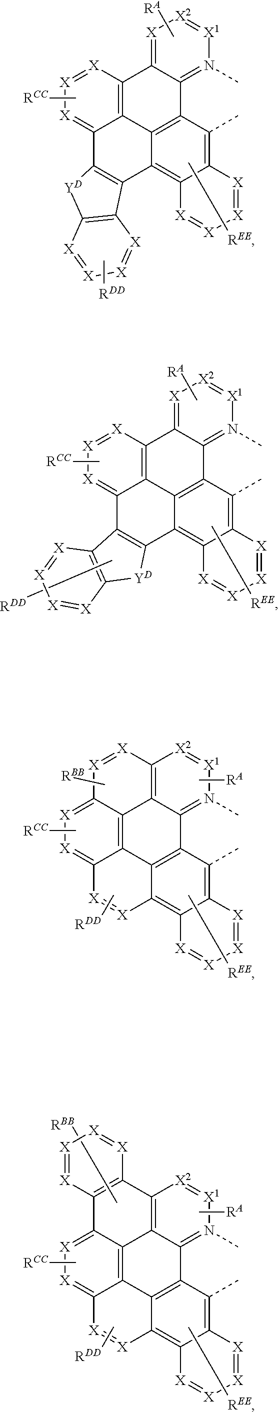 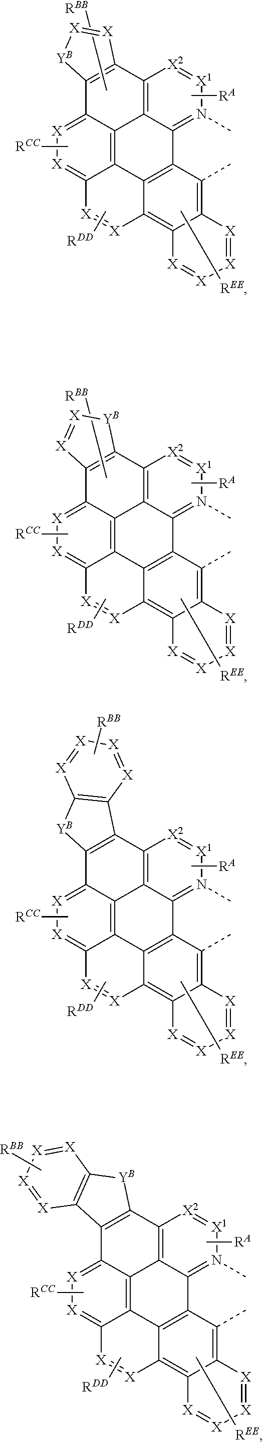 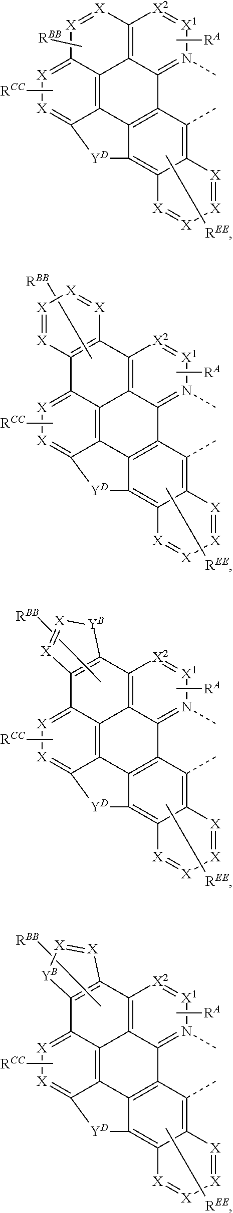 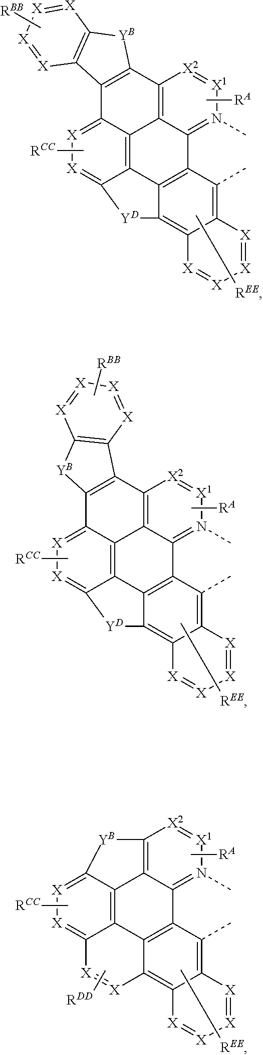 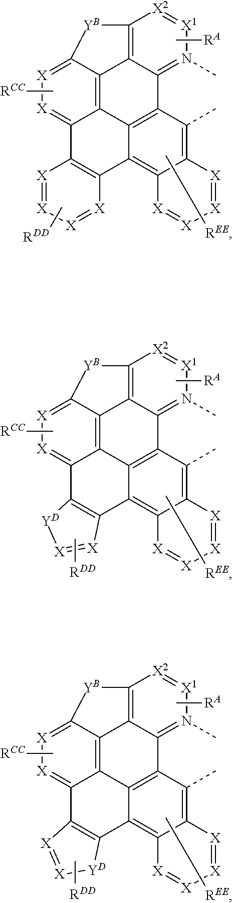 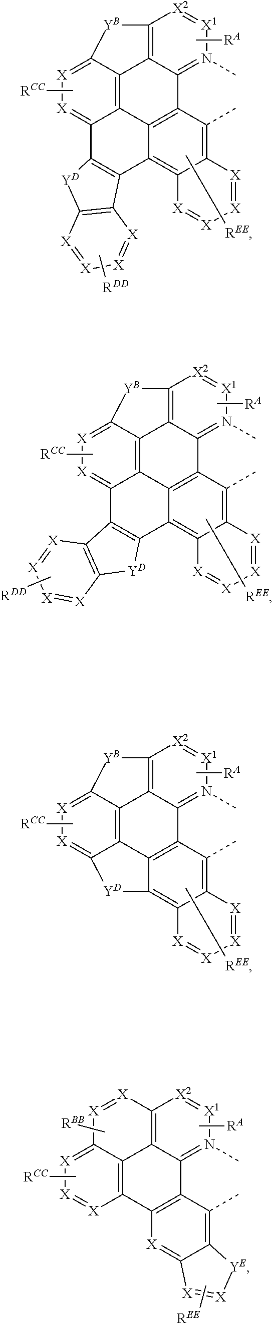 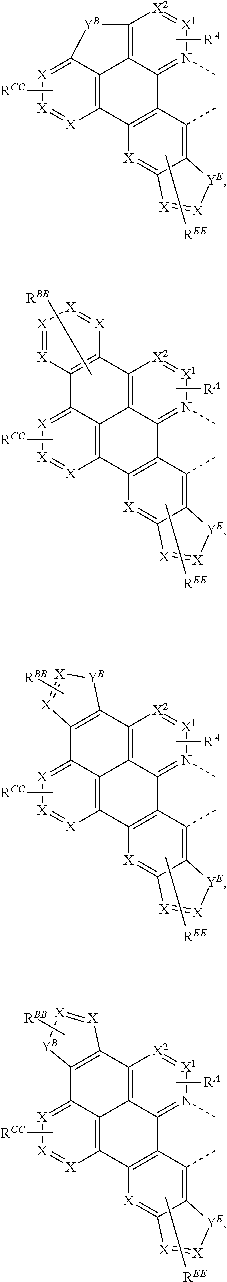 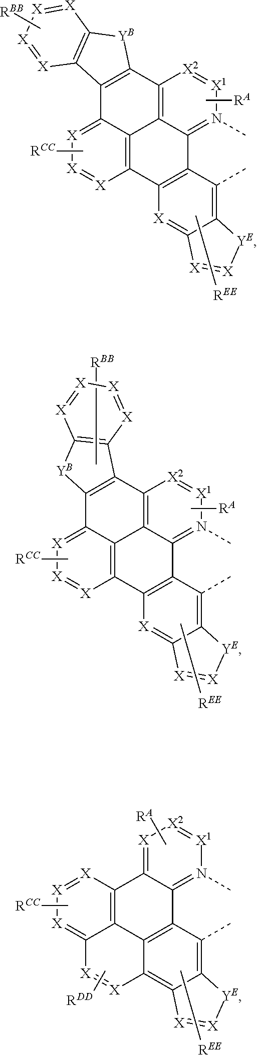 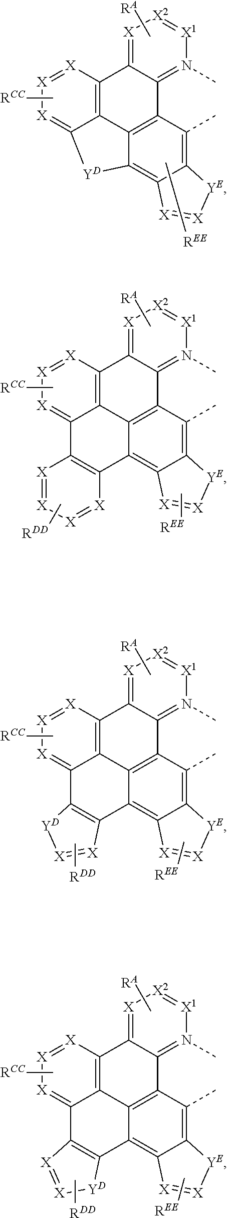 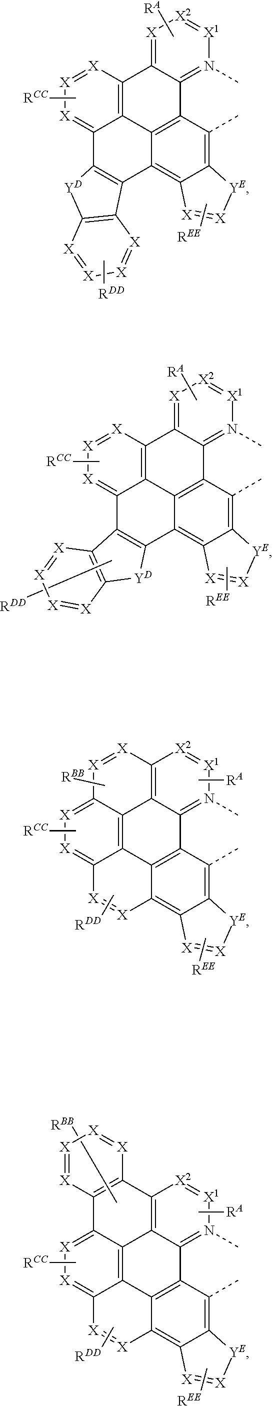 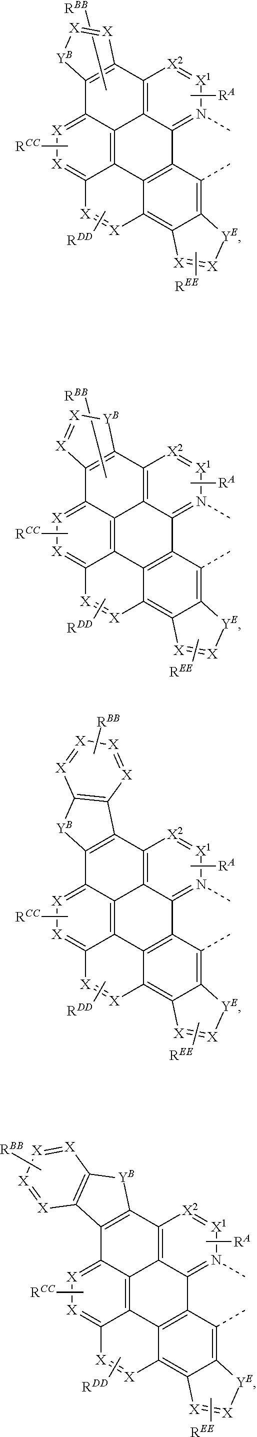 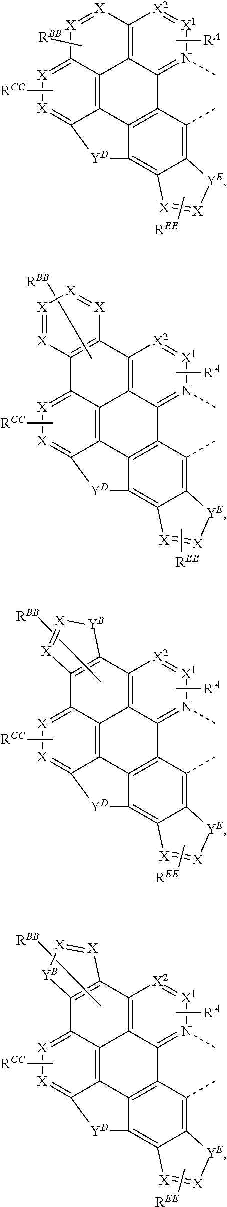 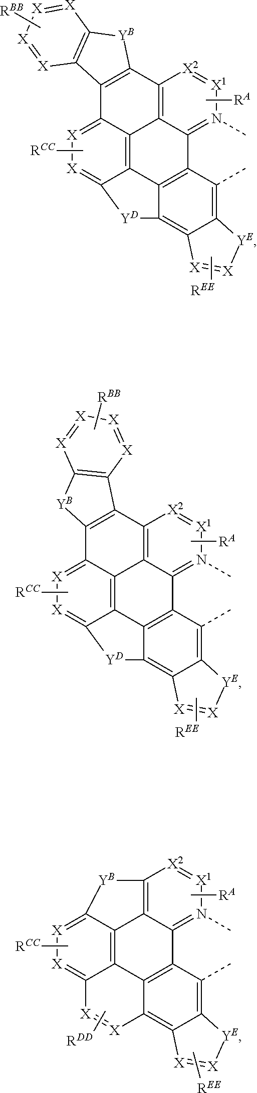 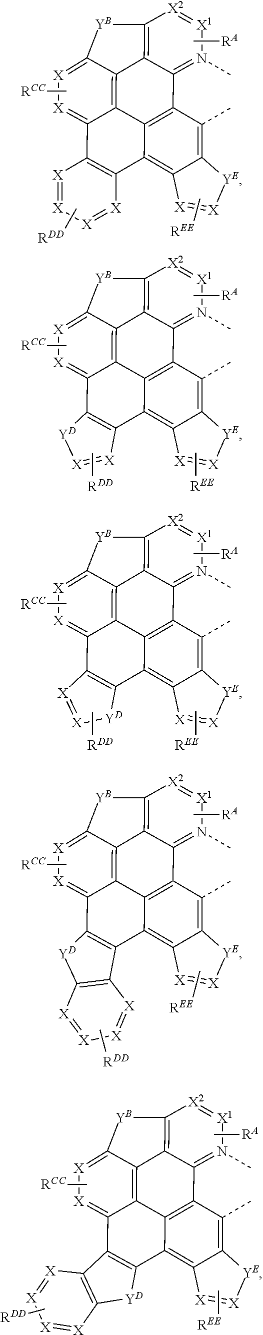 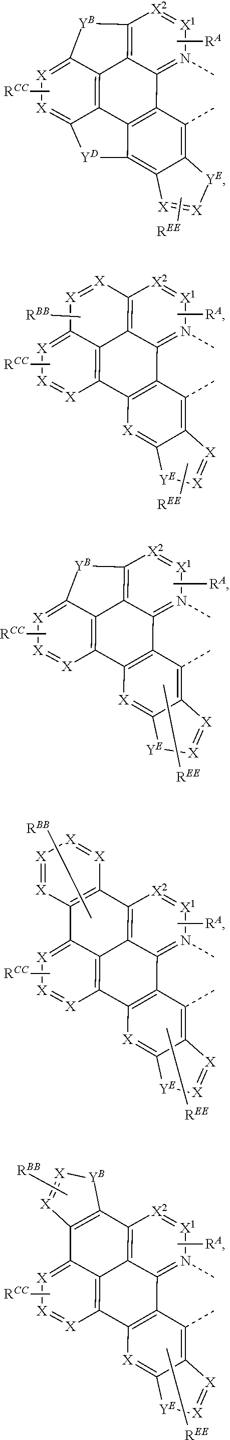 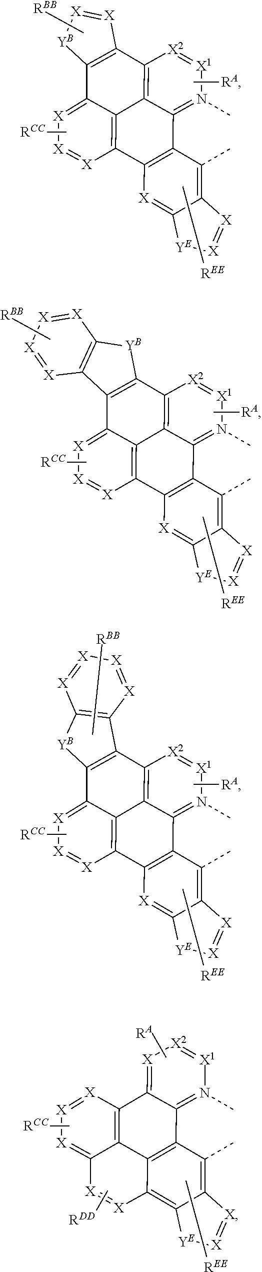 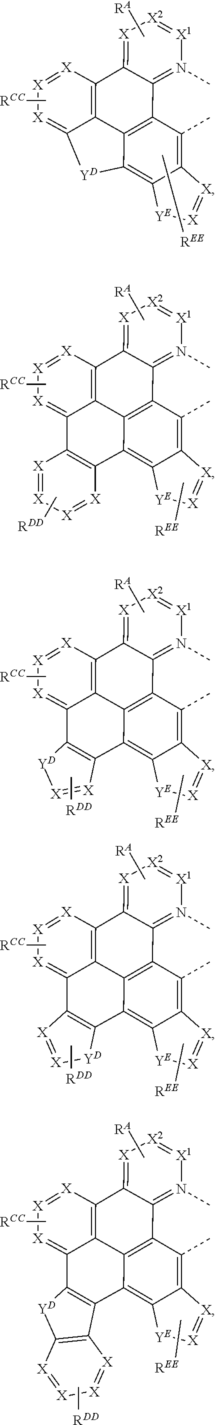 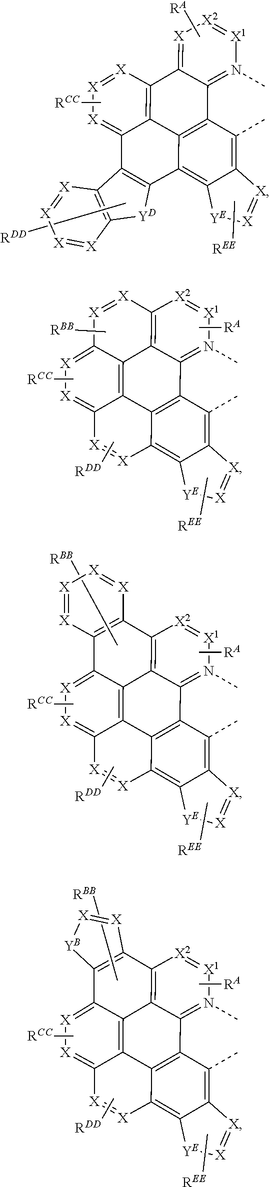 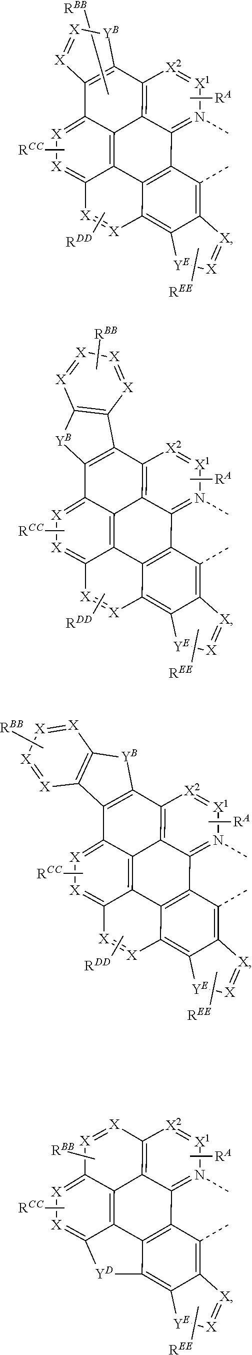 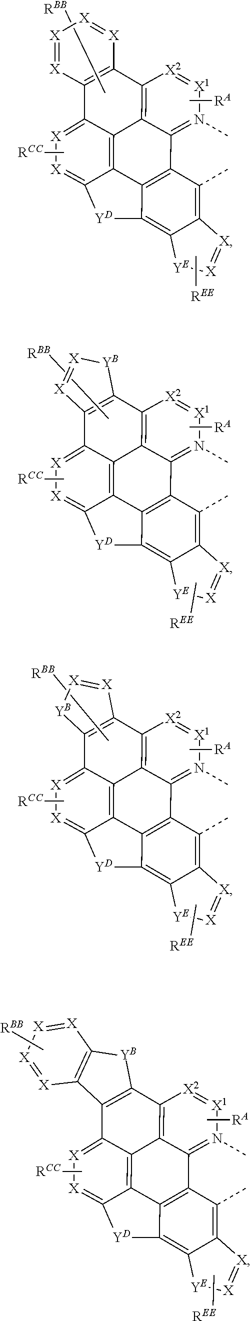 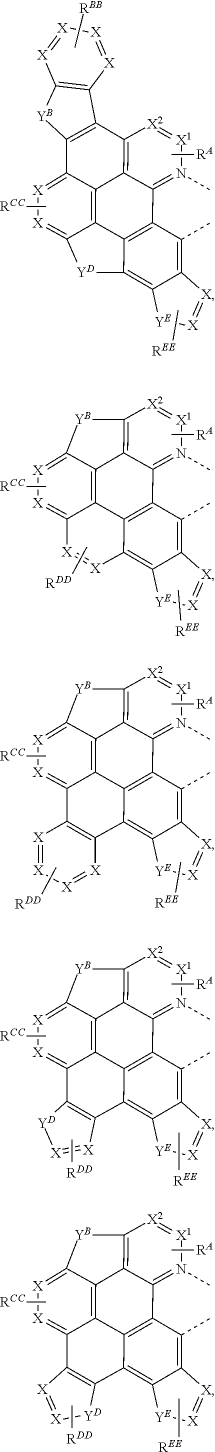 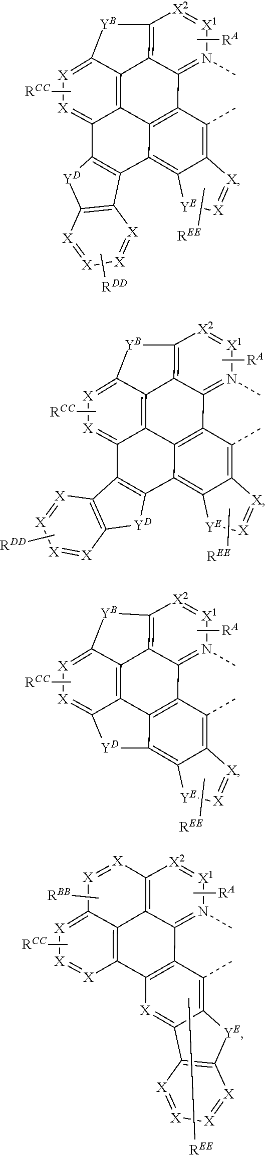 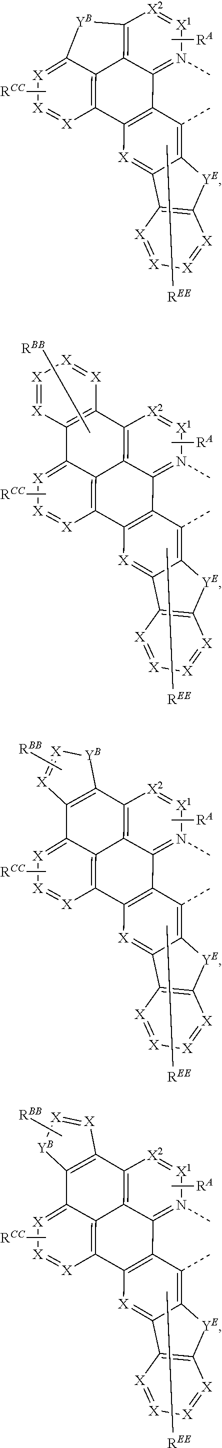 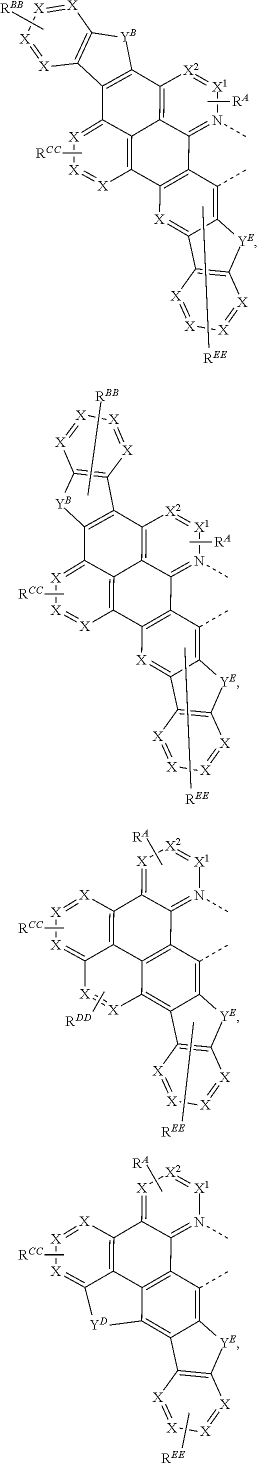 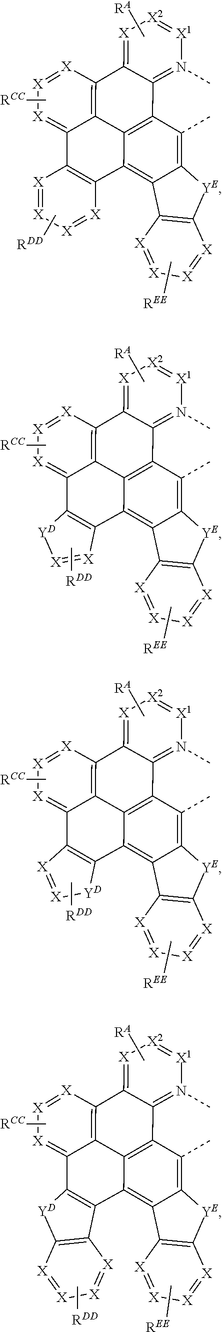 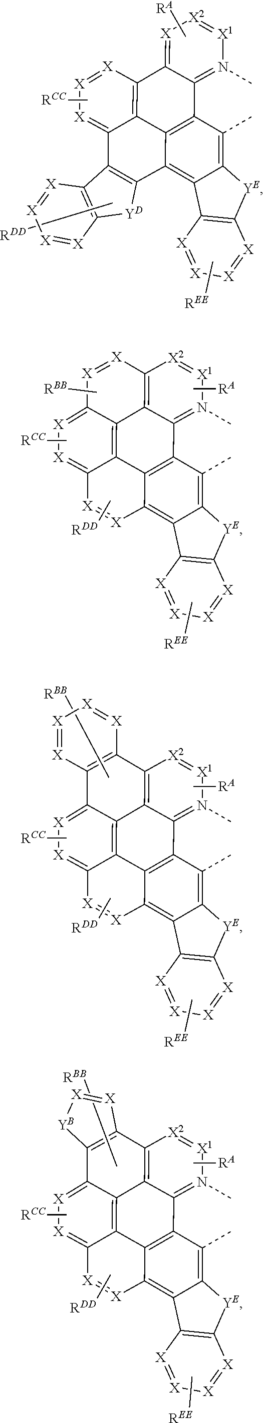 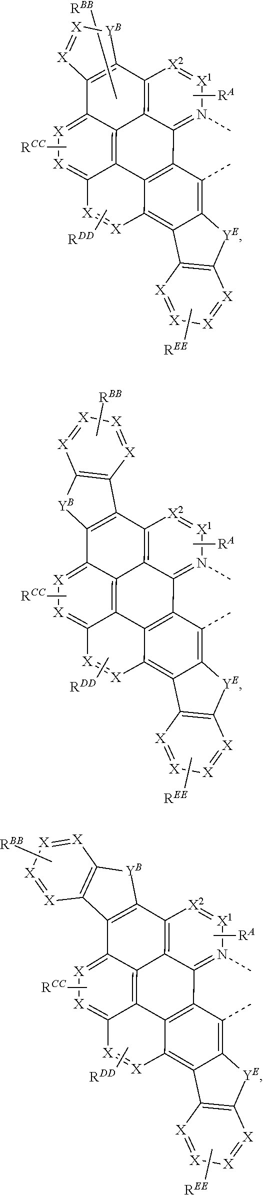 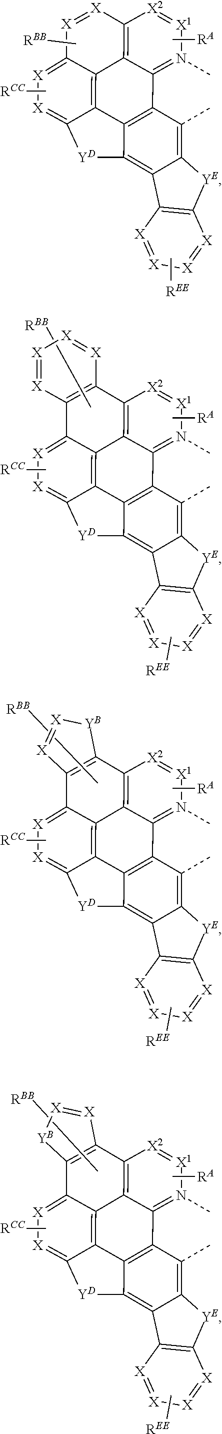 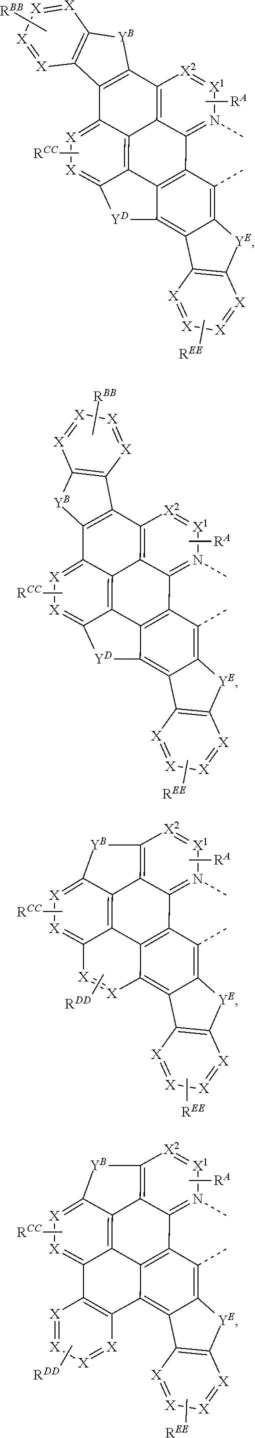 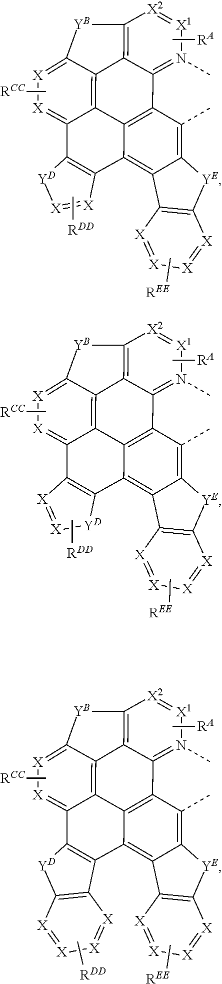 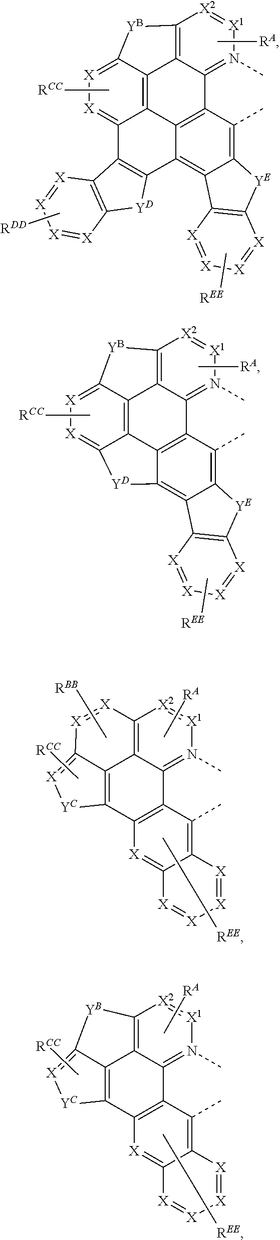 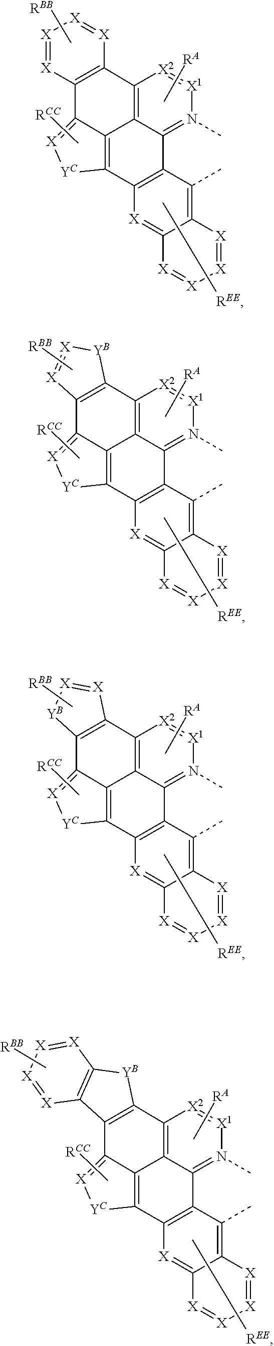 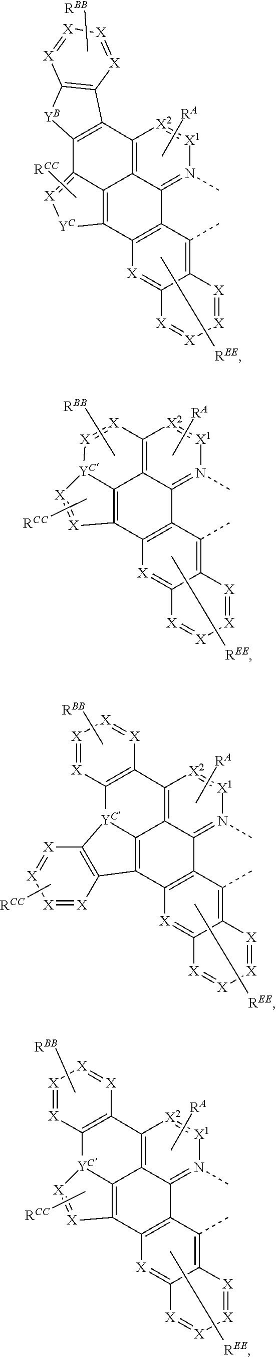 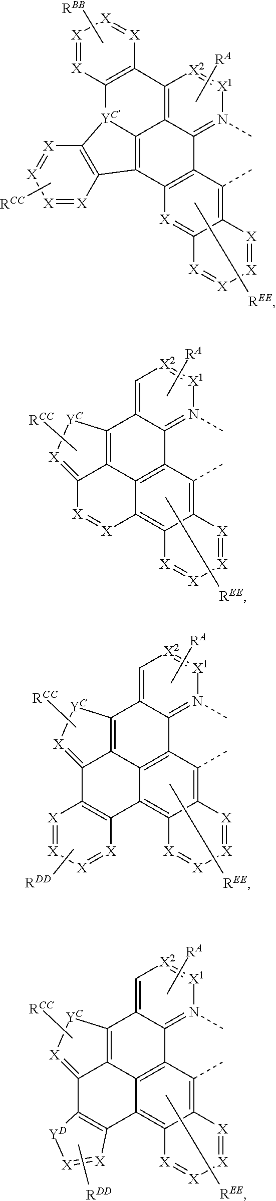 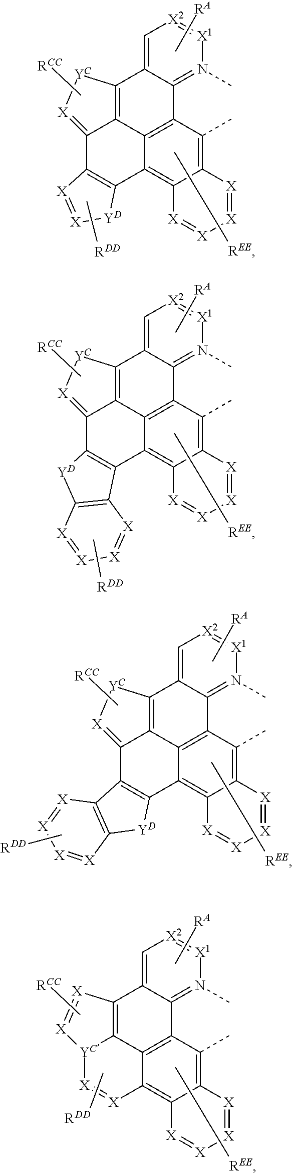 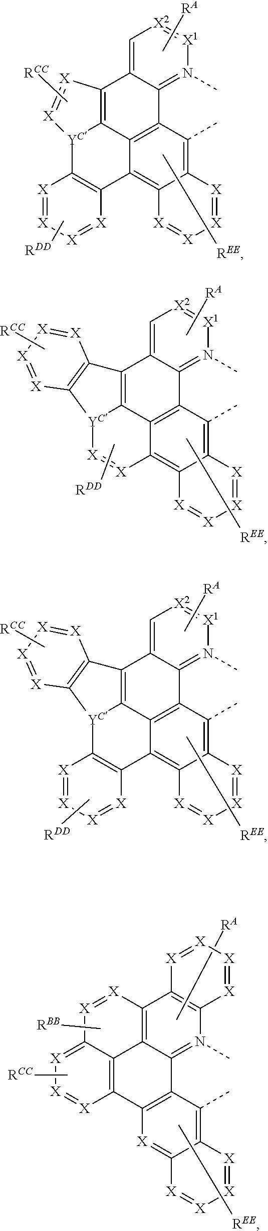 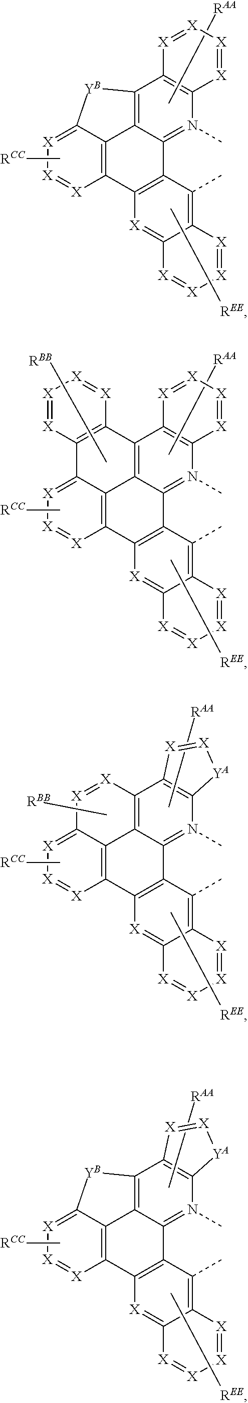 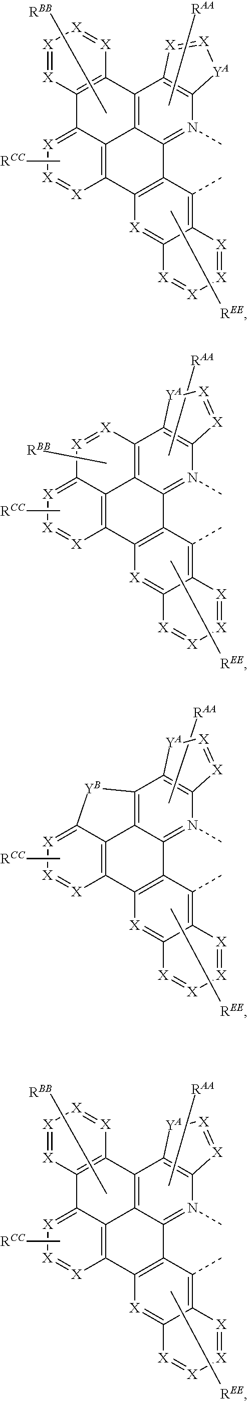 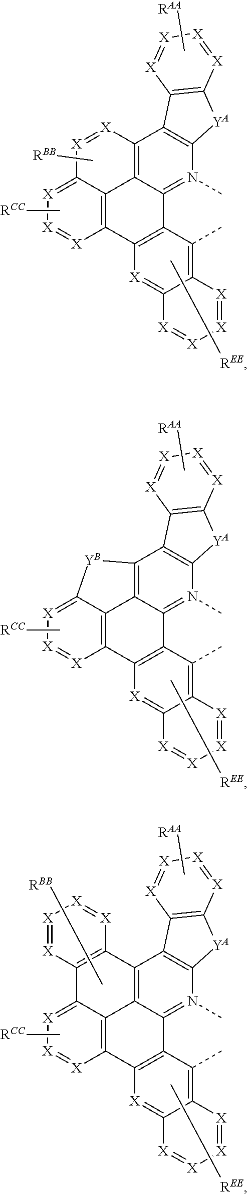 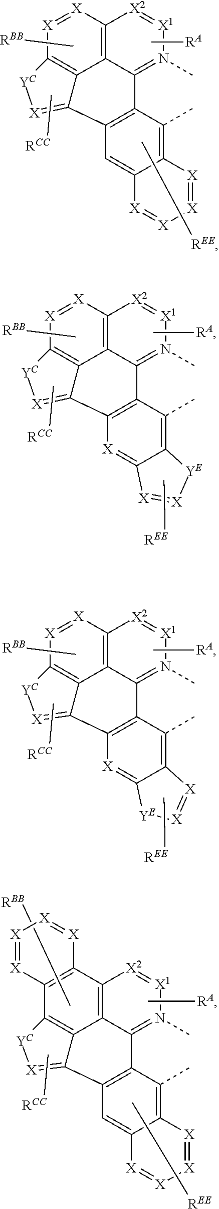 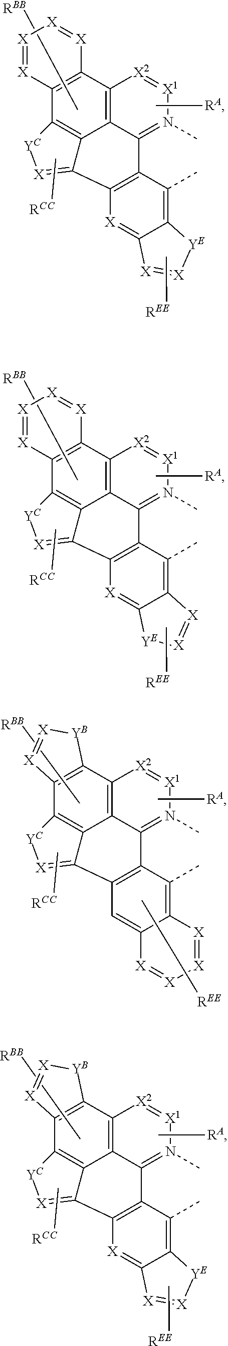 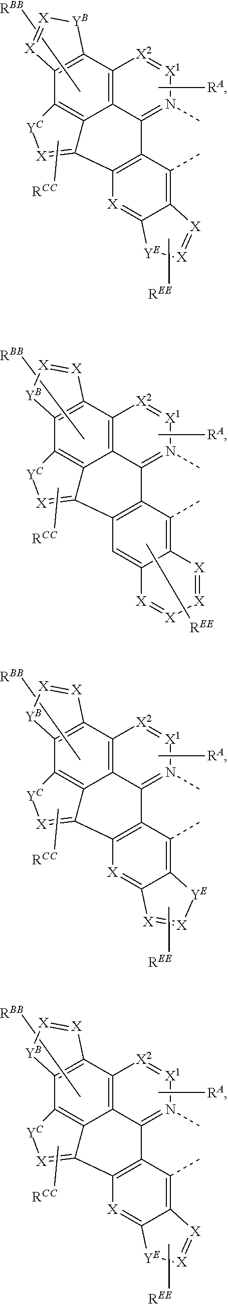 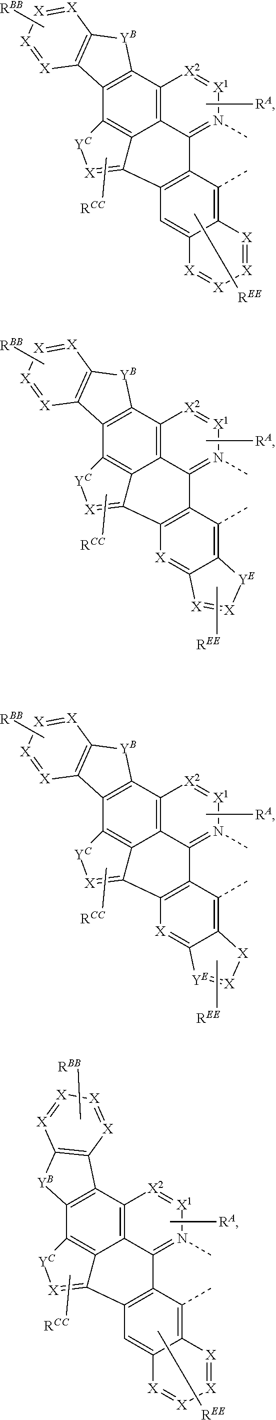 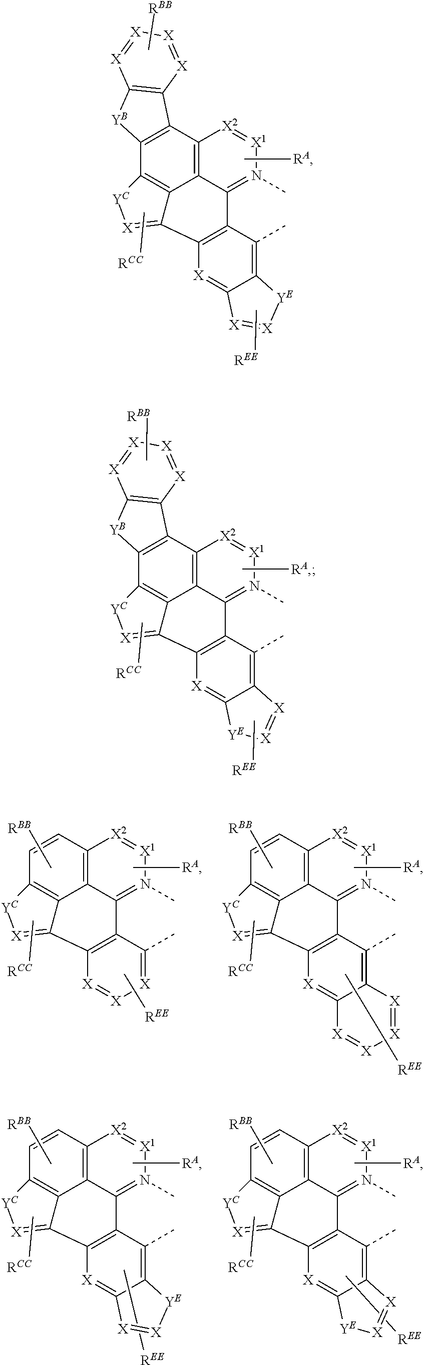 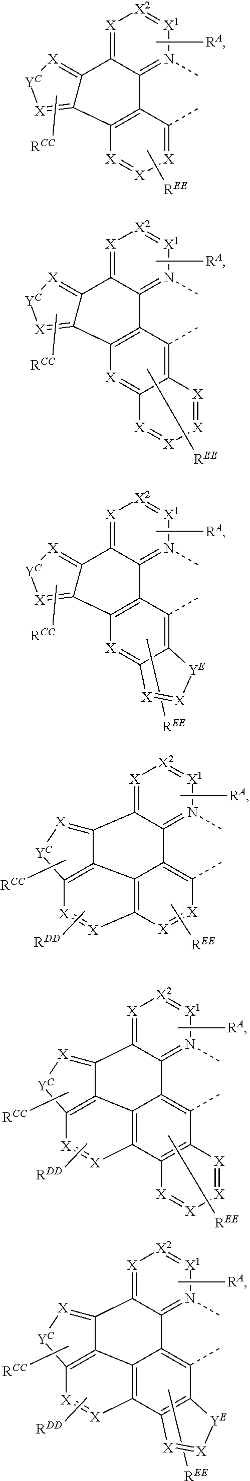 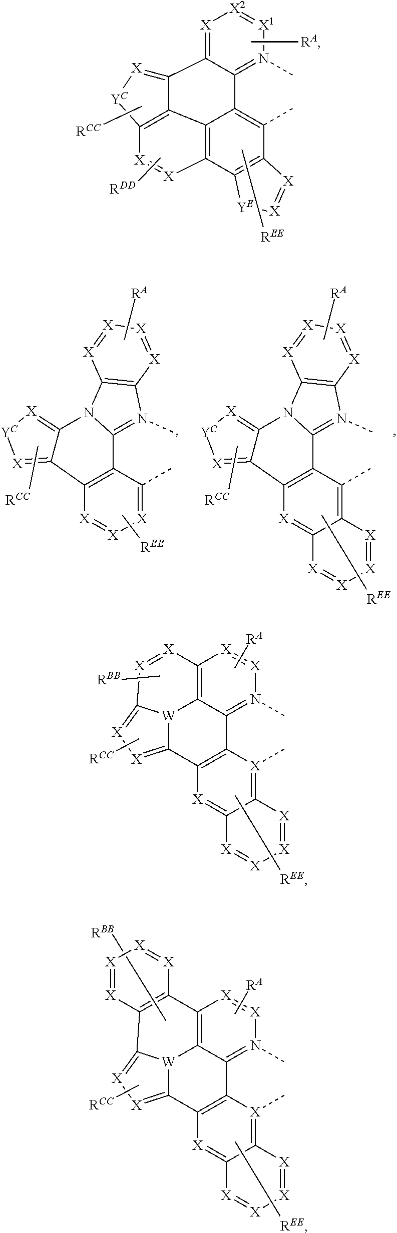 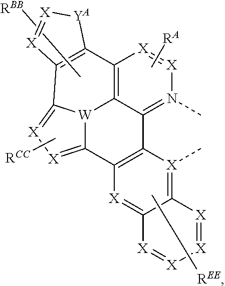 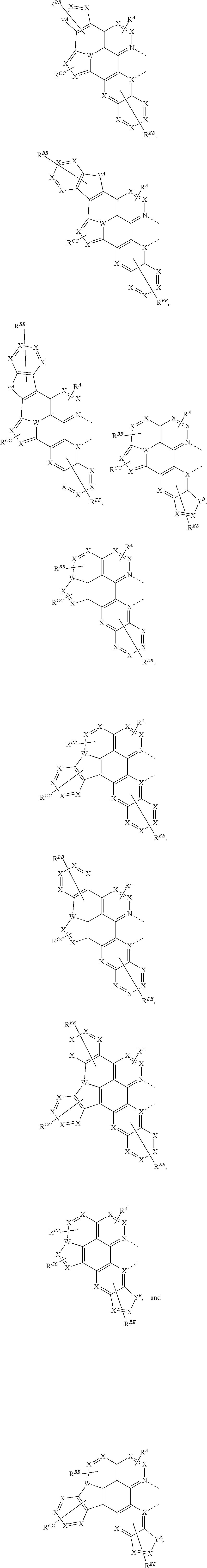
wherein:
for each occurrence, X is independently C or N;
each of Y^{A}, Y^{B}, Y^{C}, Y^{D}, and Y^{E} is independently selected from the group consisting of BR, BRR′, NR, PR, P(O)R, O, S, Se, C═O, C═S, C═Se, C═NR, C═CRR′, S═O, SO₂, CR, CRR′, SiRR′ and GeRR′;
Y^{C′} is selected from the group consisting of C, Si, and Ge;
each of R^{AA}, R^{BB}, R^{CC}, R^{DD}, and R^{EE} independently represents mono to the maximum allowable substitution, or no substitution;
each R, R′, R^{AA}, R^{BB}, R^{CC}, R^{DD}, and R^{EE} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents may be optionally fused or joined to form a ring.

8. The compound of claim 1, wherein the ligand L_{A} is selected from the group consisting of: 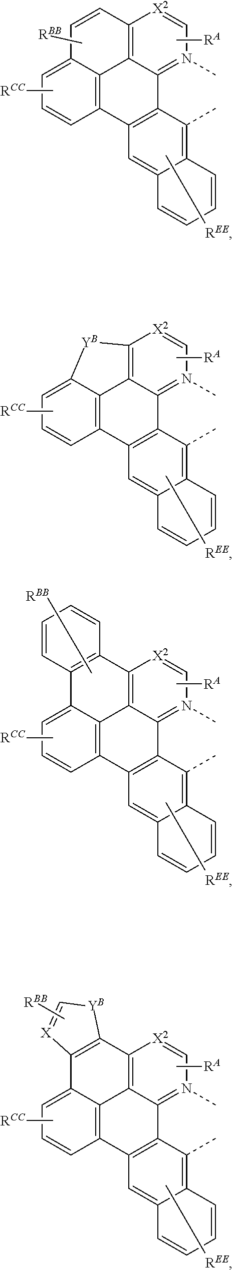 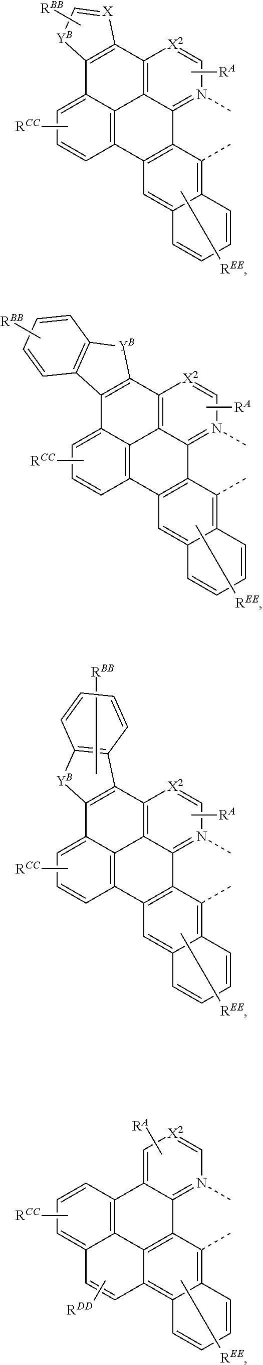 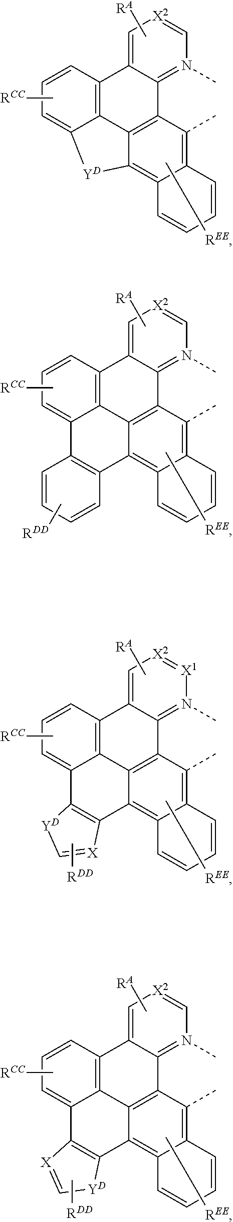 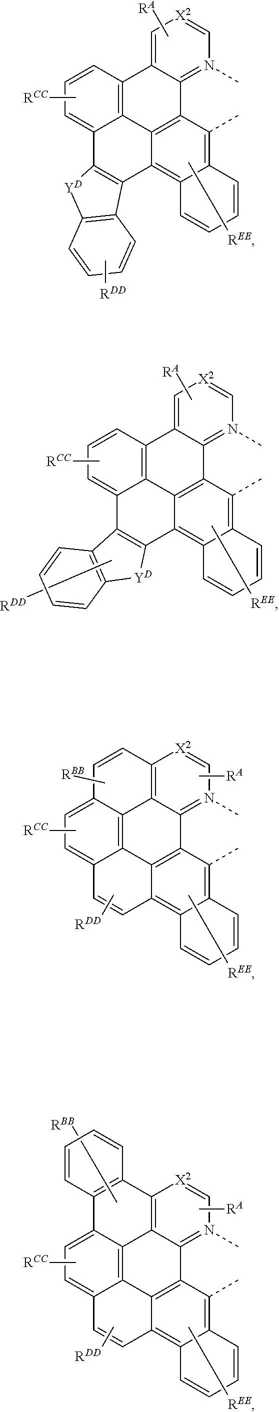 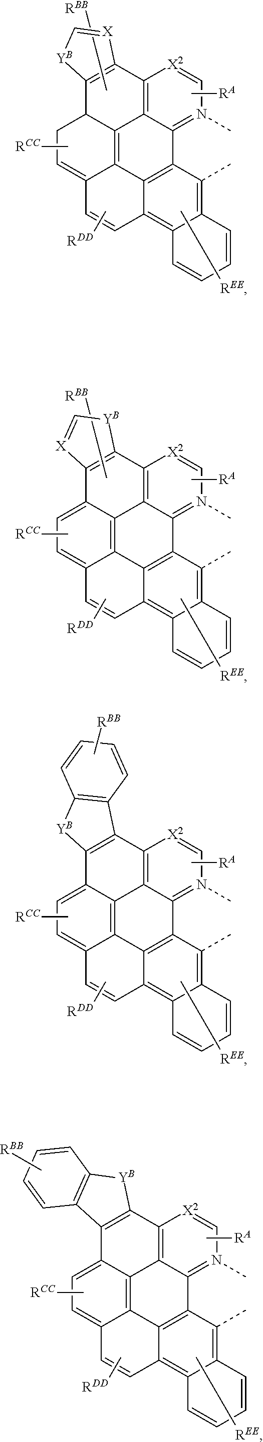 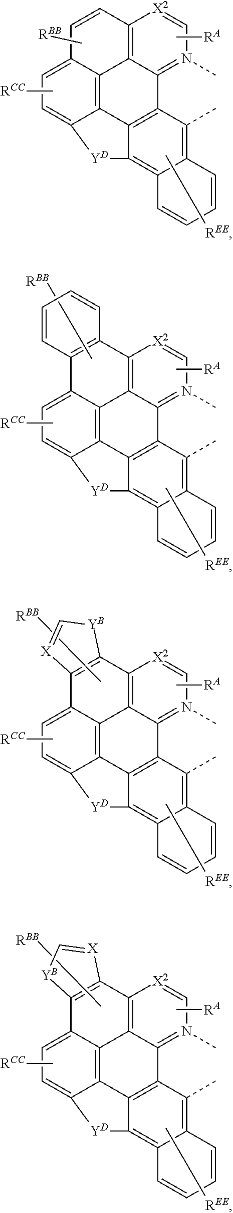 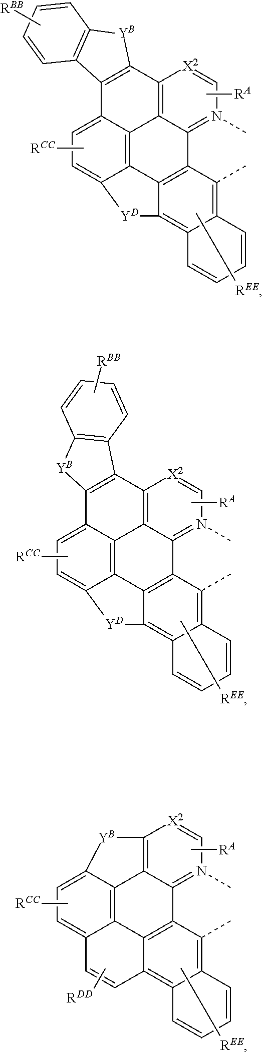 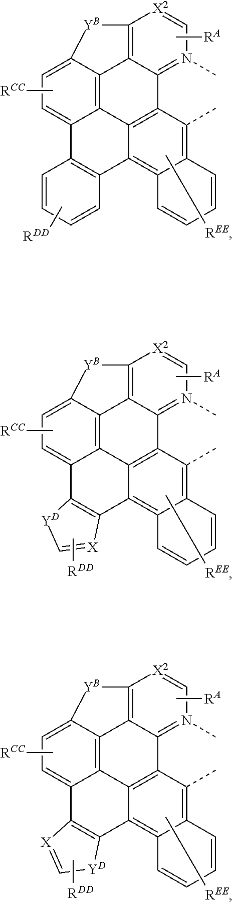 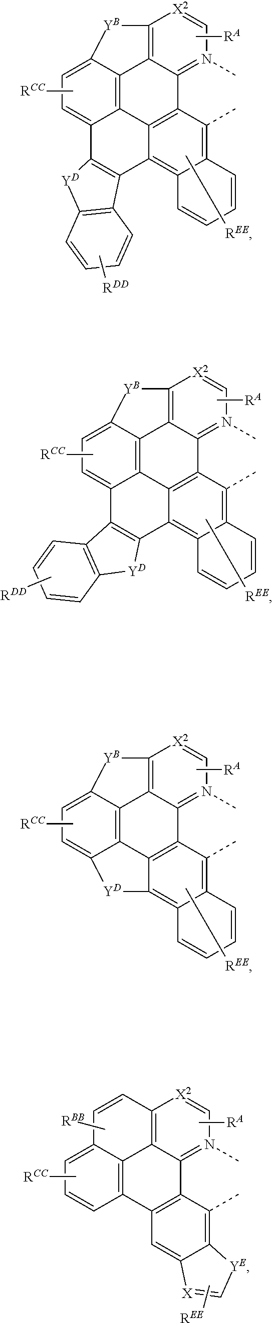 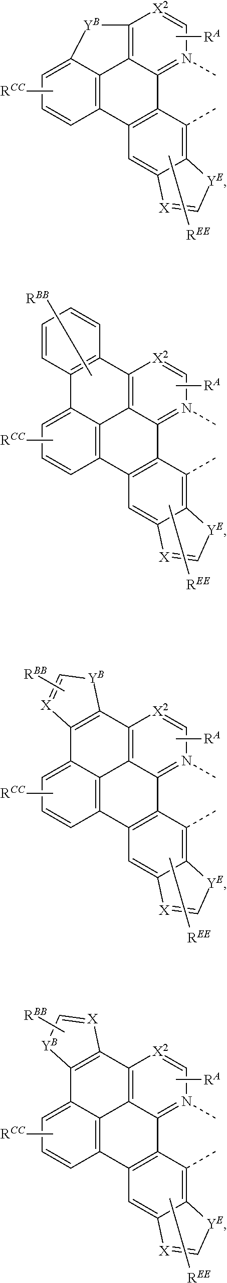 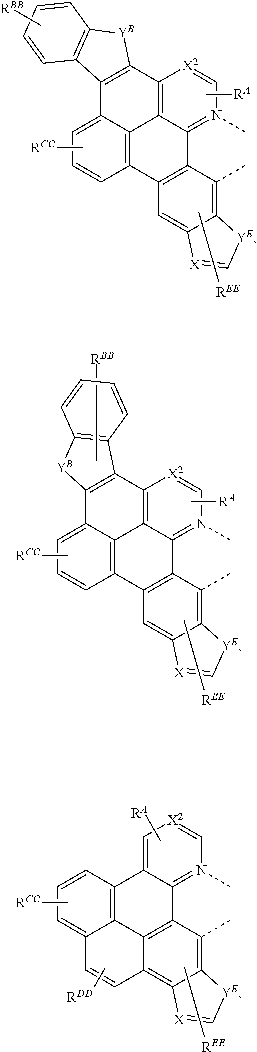 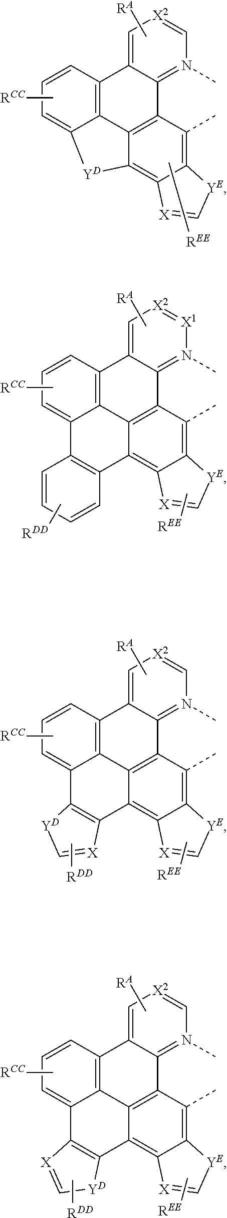 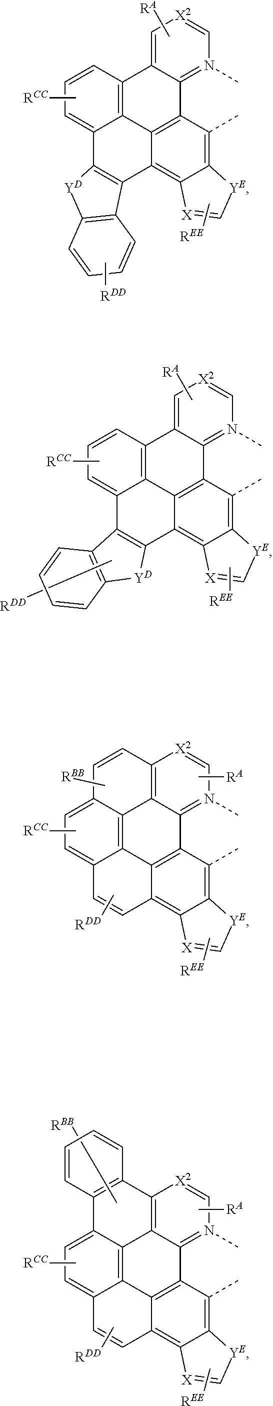 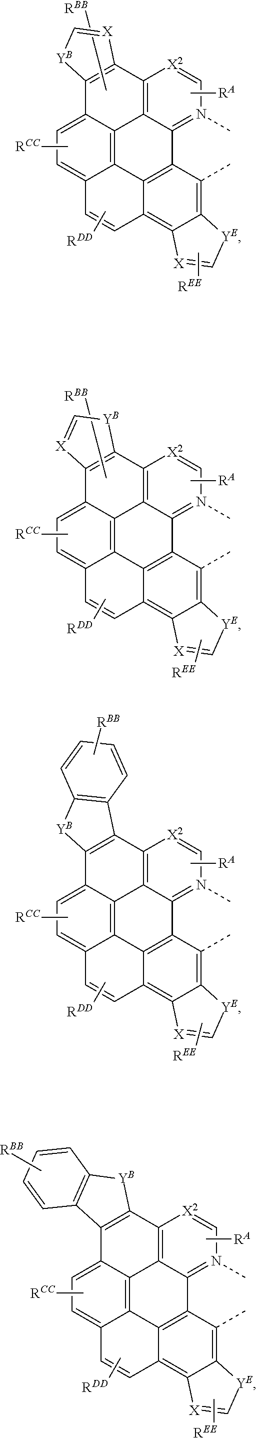 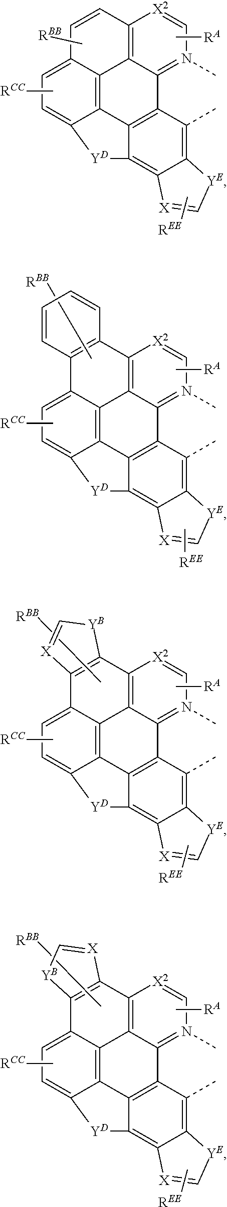 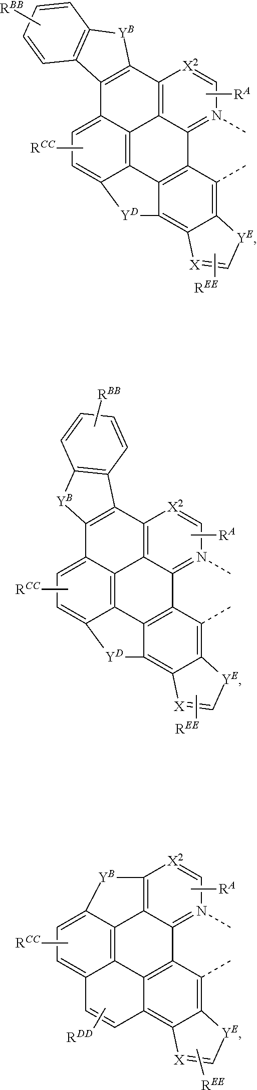 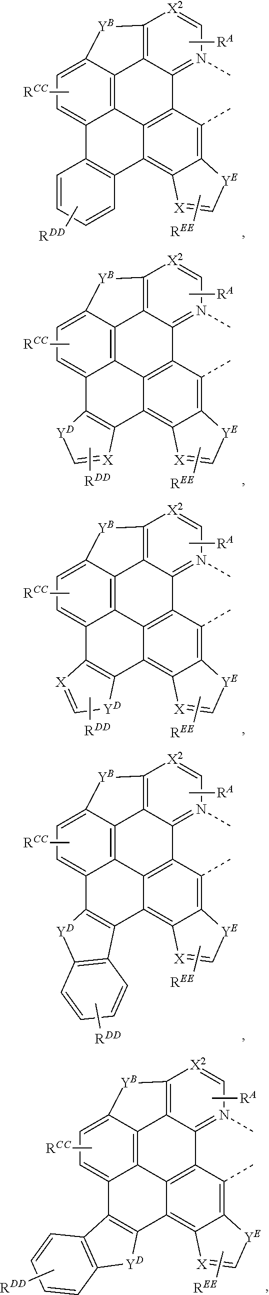 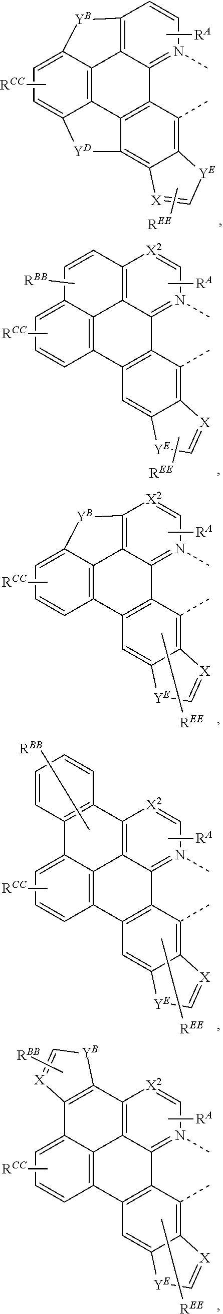 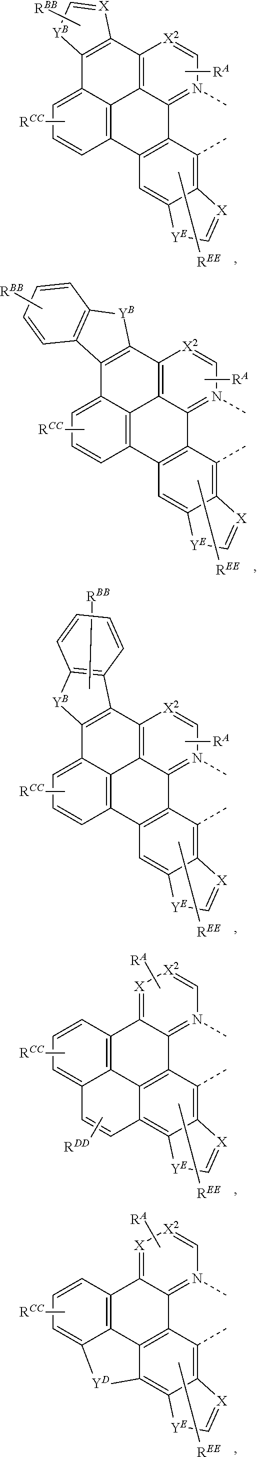 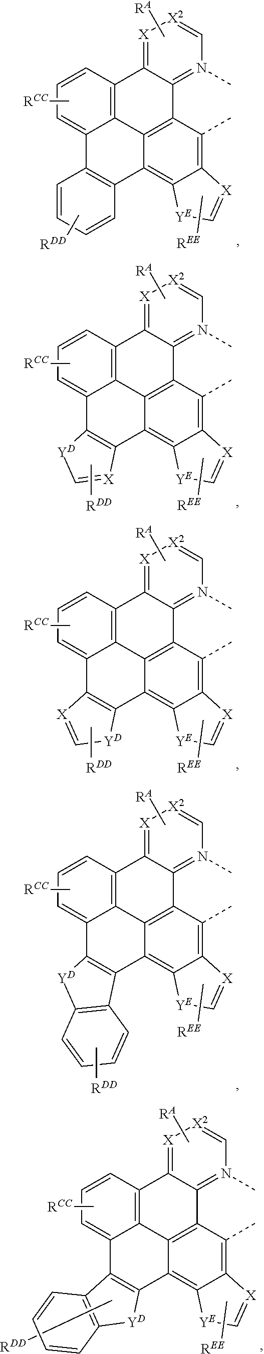 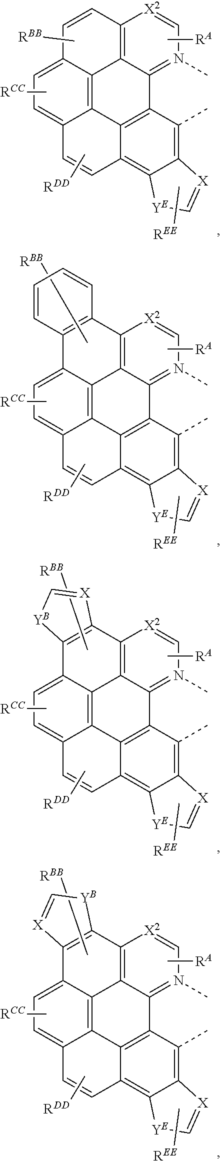 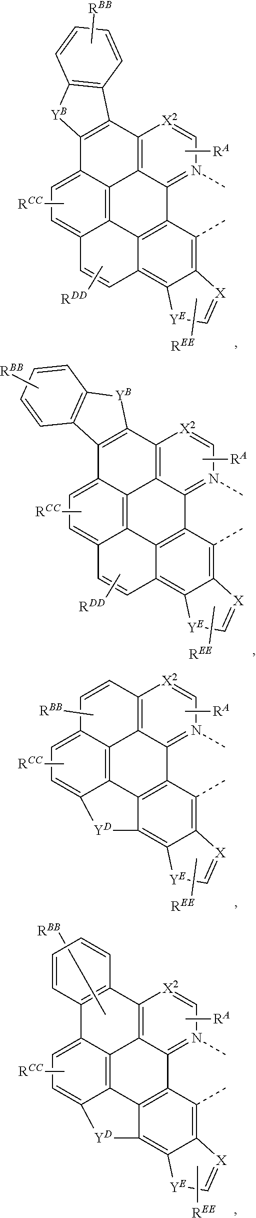 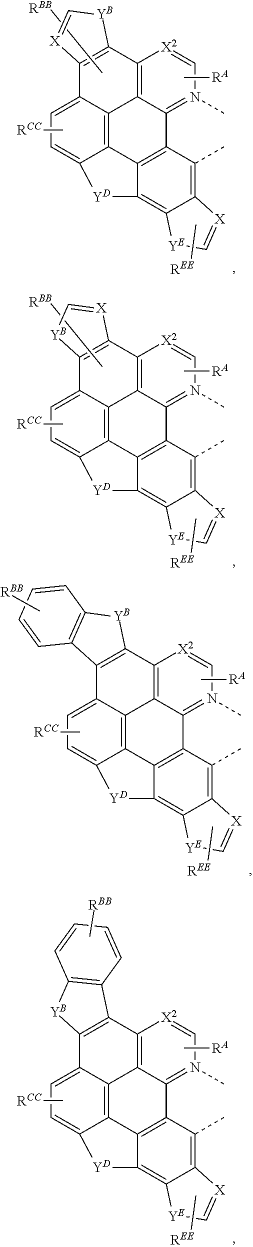 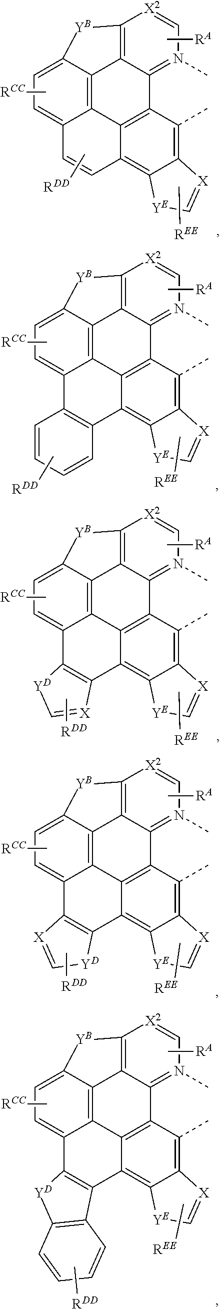 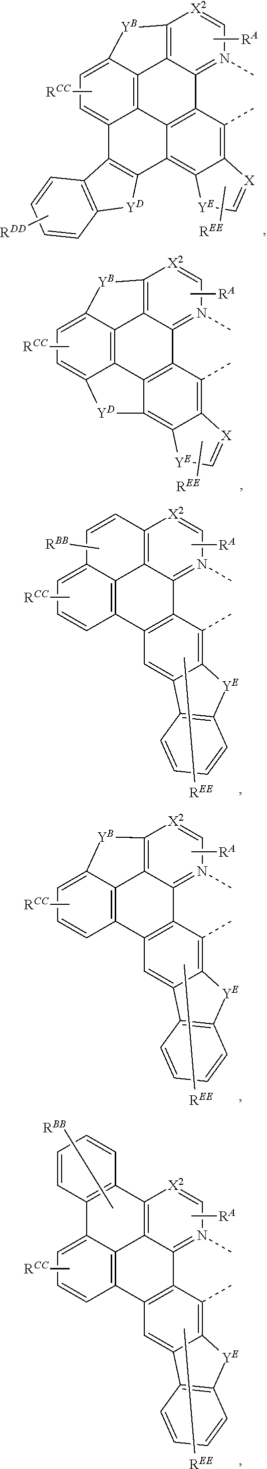 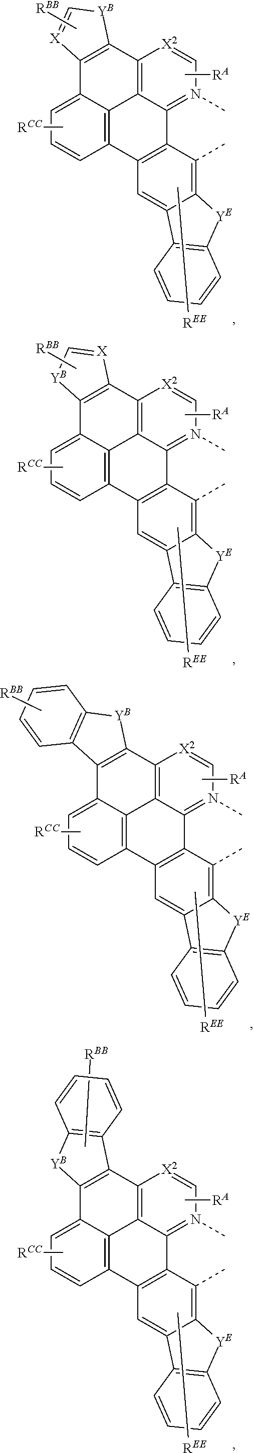 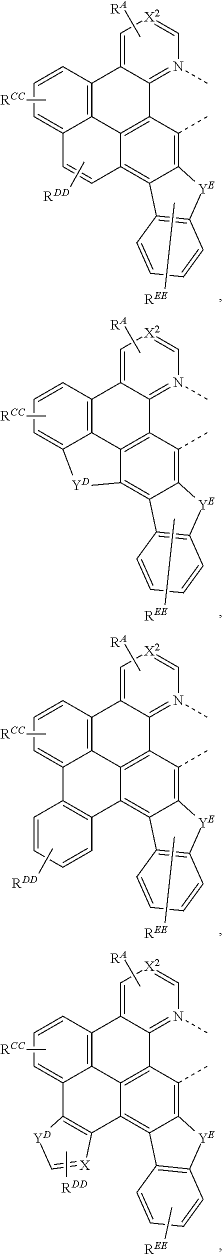 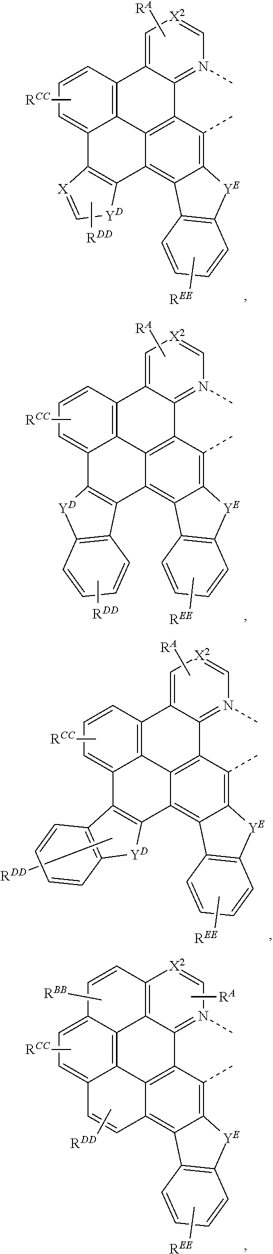 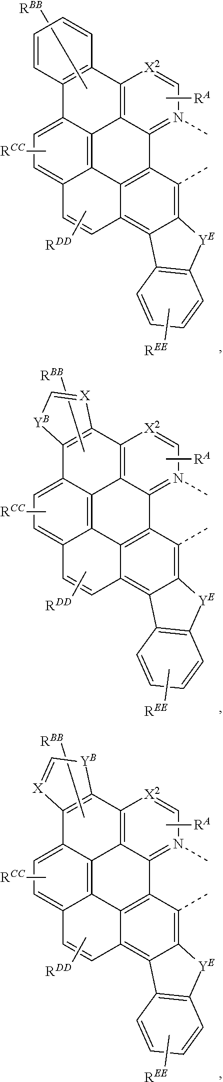 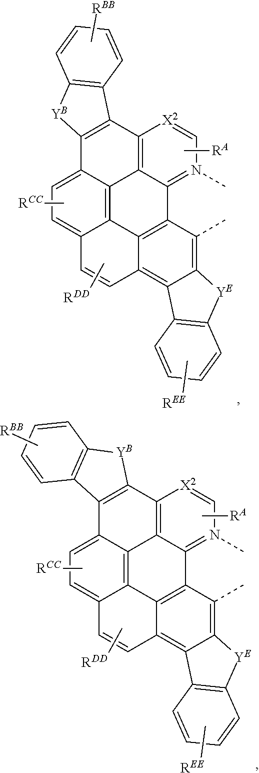 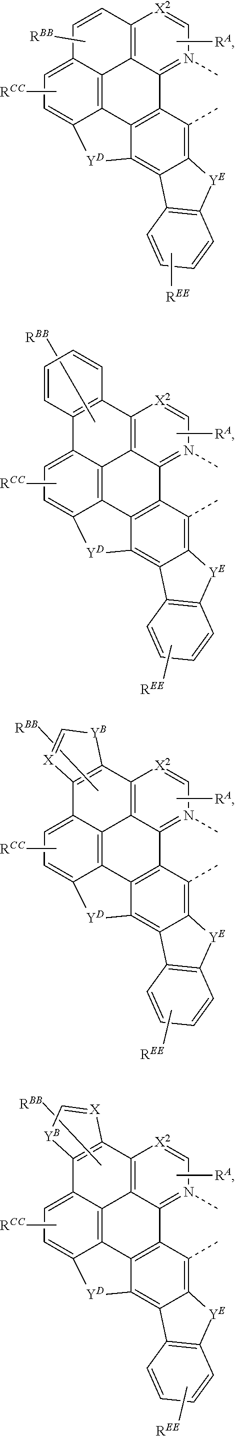 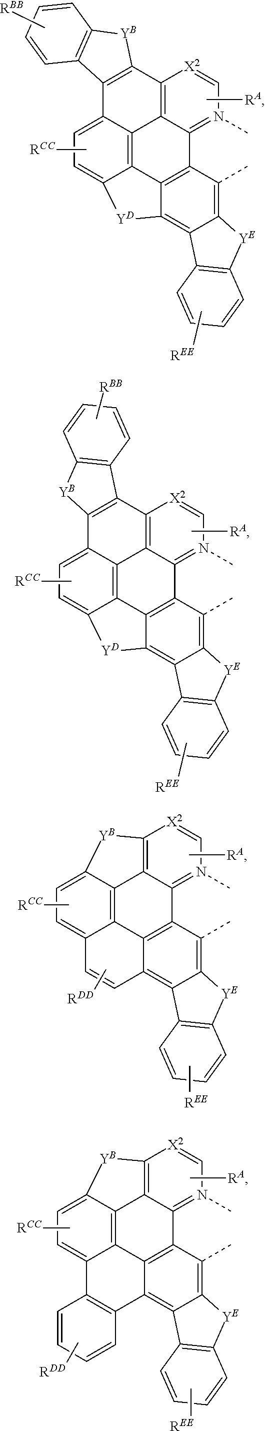 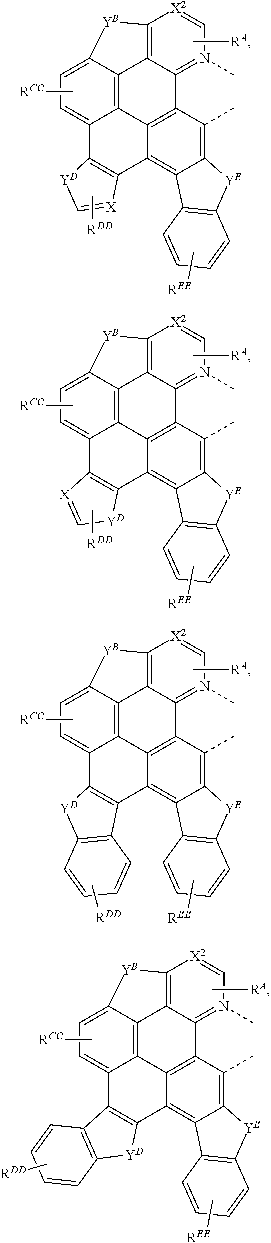 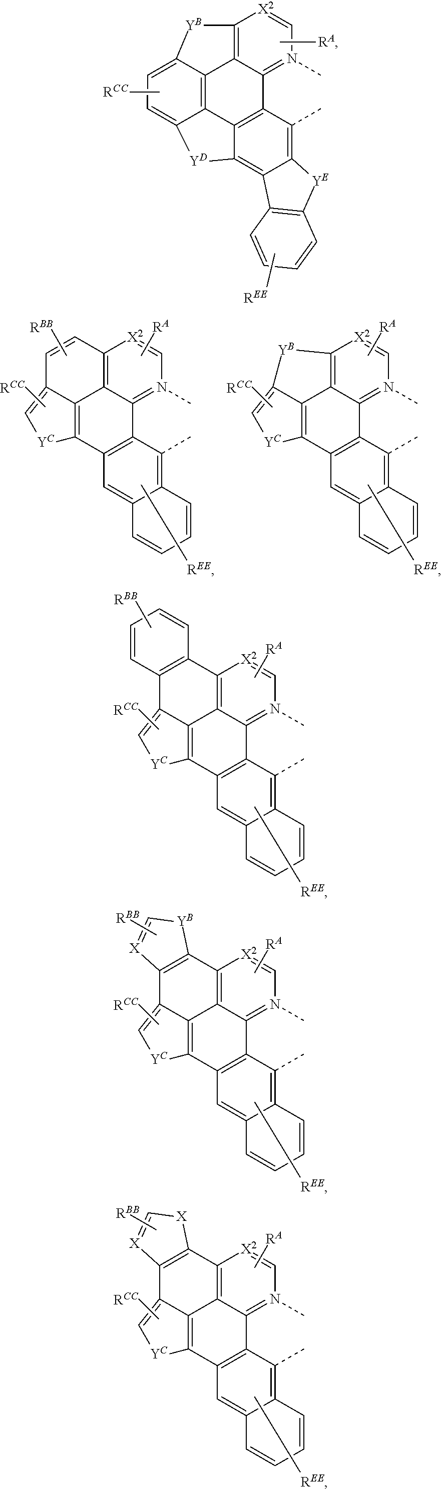 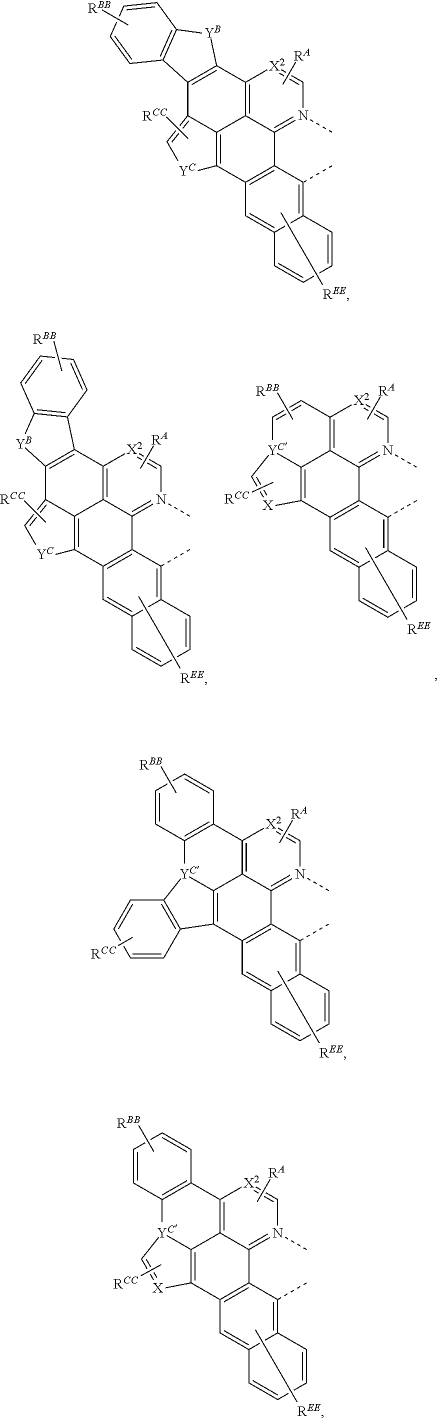 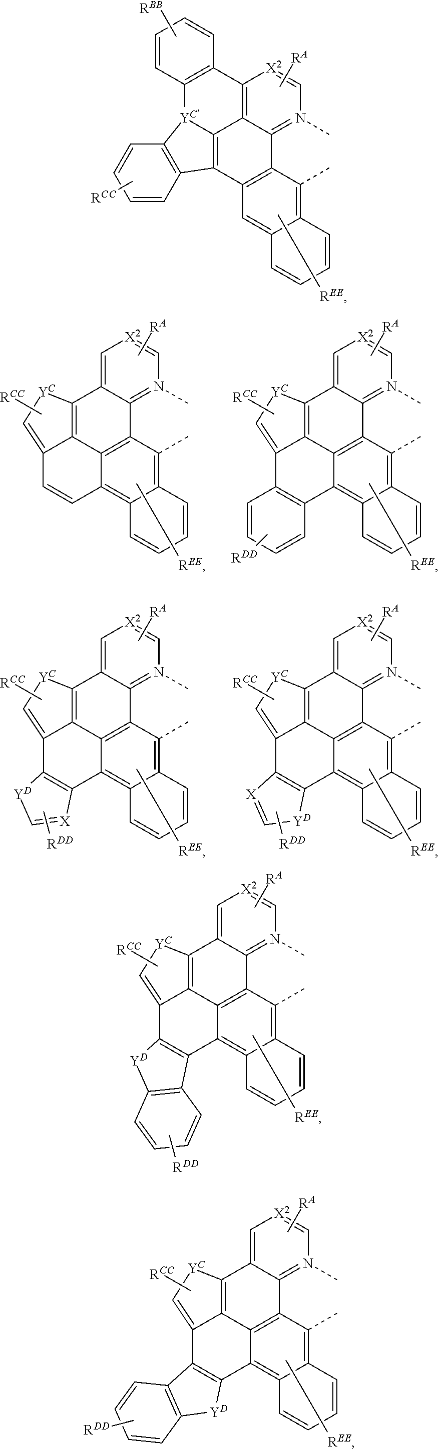 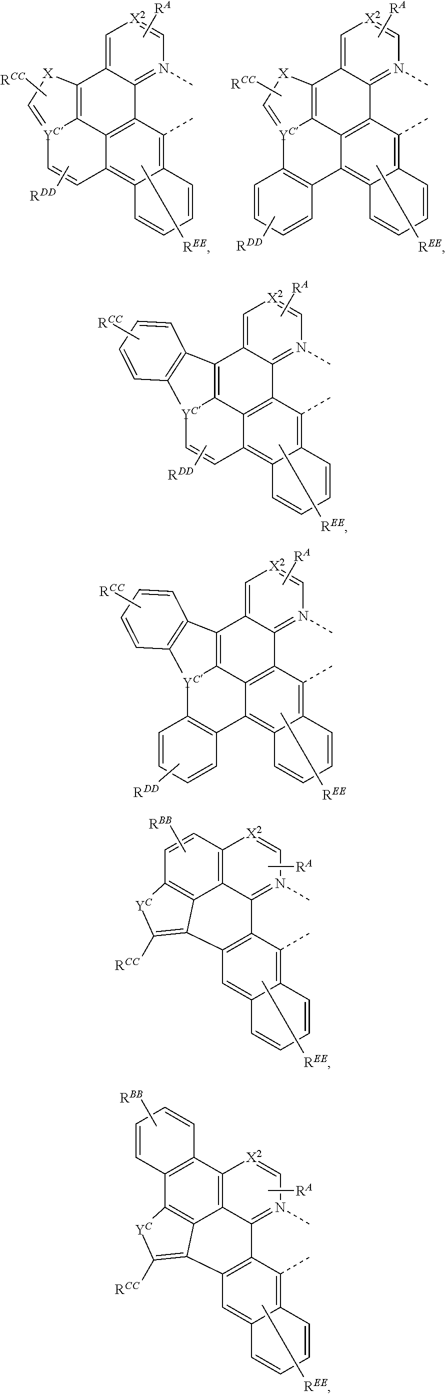 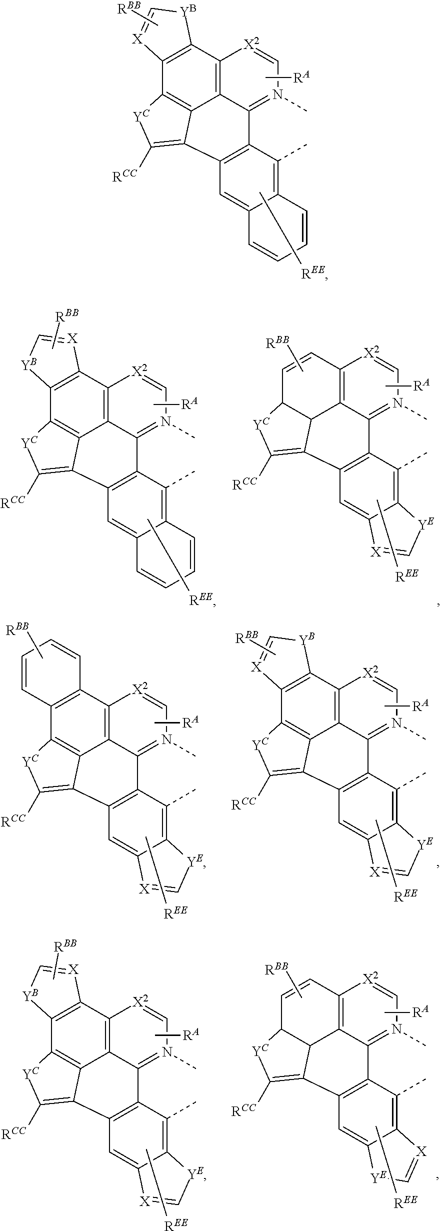 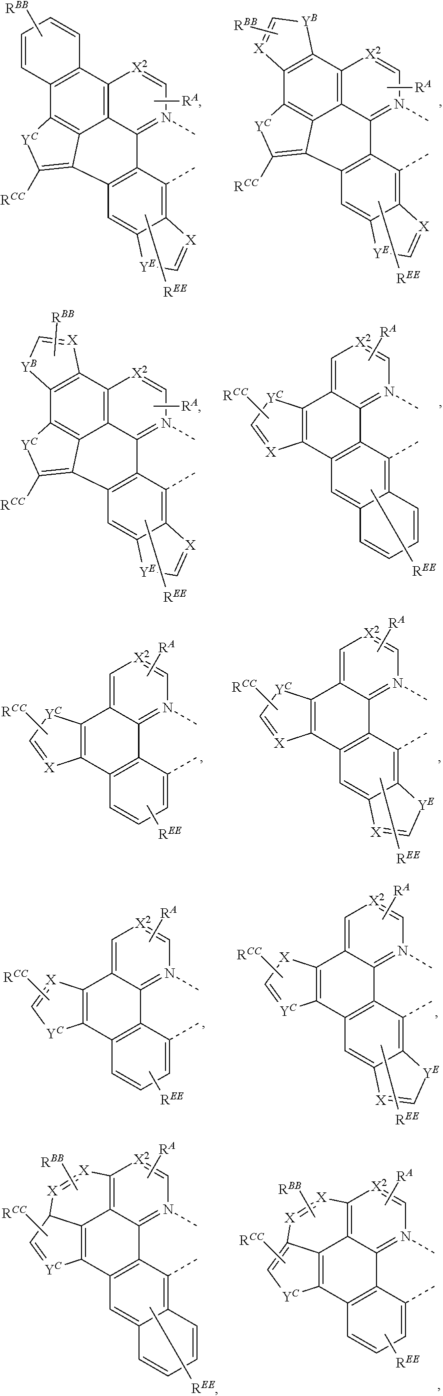 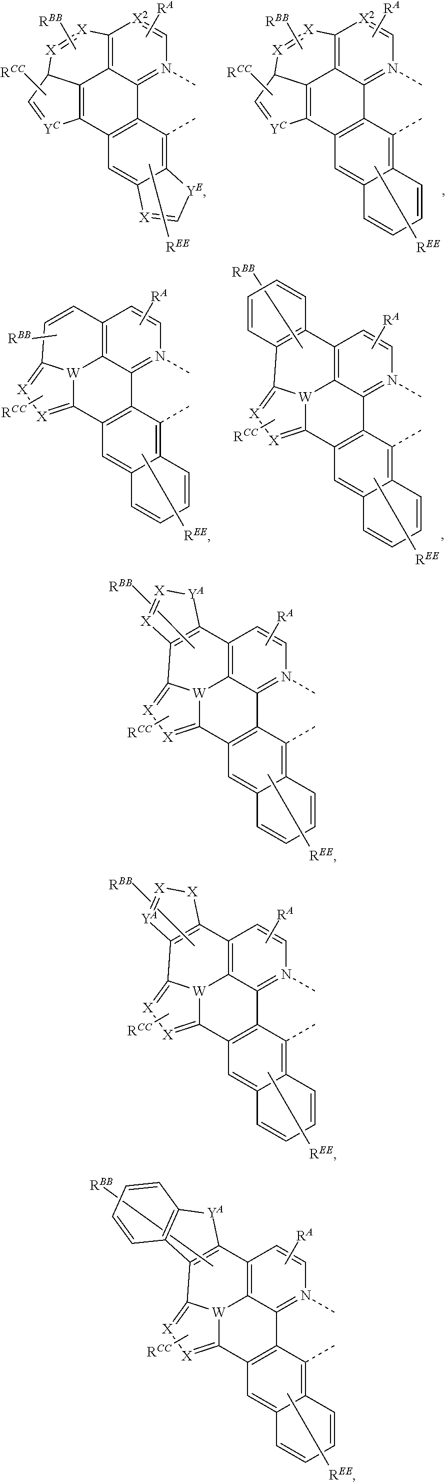 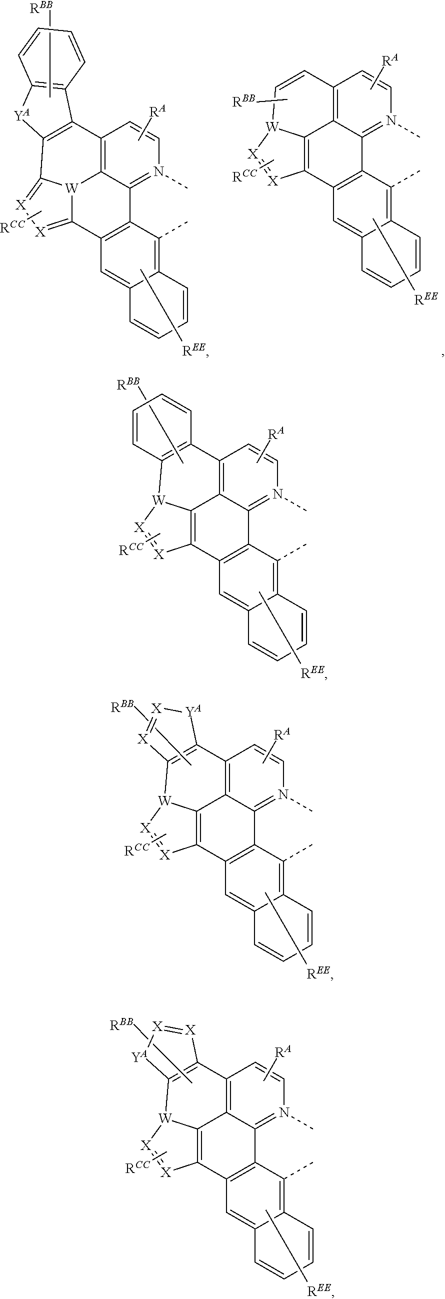 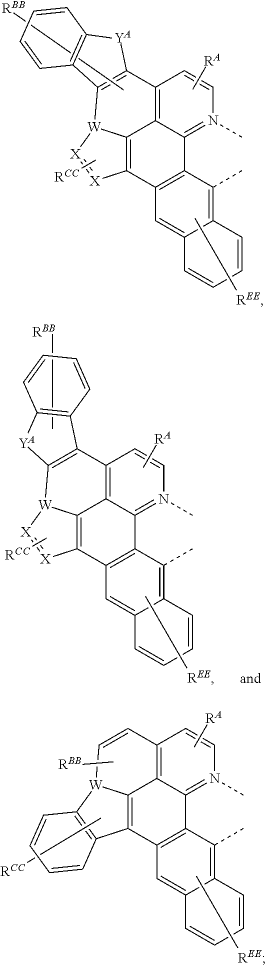
wherein:
each of Y^{B}, Y^{C}, Y^{D}, and Y^{E} is independently selected from the group consisting of BR, BRR′, NR, PR, P(O)R, O, S, Se, C═O, C═S, C═Se, C═NR, C═CRR′, S═O, SO₂, CR, CRR′, SiRR′ and GeRR′;
Y^{C′} is selected from the group consisting of C, Si, and Ge;
each of R^{BB}, R^{CC}, R^{DD}, and R^{EE} independently represents mono to the maximum allowable substitution, or no substitution;
each R, R′, R^{BB}, R^{CC}, R^{DD}, and R^{EE} is independently hydrogen or a substituent selected from the group consisting of deuterium, halogen, alkyl, cycloalkyl, heteroalkyl, heterocycloalkyl, boryl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents may be optionally fused or joined to form a ring.

9. The compound of claim 1, wherein the ligand L_{A} is selected from L_{Ai}(R^{EA})(R^{EB})(R^{EC}) (R^{ED})(R^{EE})(R^{EF})(R^{EG}), wherein i is an integer from 1 to 161, and each of R^{EA}, R^{EB}, R^{EC}, R^{ED}, R^{EE}, R^{EF}, and R^{EG} is independently selected from the group consisting of R₁ to R₂₁₁; wherein each of L_{A1}(R₁)(R₁)(R₁)(R₁)(R₁)(R₁) to L_{A161}(R₂₁₁)(R₂₁₁(R₂₁₁(R₂₁₁)(R₂₁₁(R₂₁₁)(R₂₁₁) is defined as follows:

| L_{A} | Structure of L_{A} |
|---|---|
| L_{A1}(R^{EA})(R^{EB})(R^{EC})(R^{ED}) (R^{EE})(R^{EF})(R^{EG}), wherein L_{A1}(R₁)(R₁)(R₁)(R₁)(R₁) (R₁)(R₁) to L_{A1}(R₂₁₁)(R₂₁₁)(R₂₁₁)(R₂₁₁) (R₂₁₁)(R₂₁₁)(R₂₁₁) have the structure | 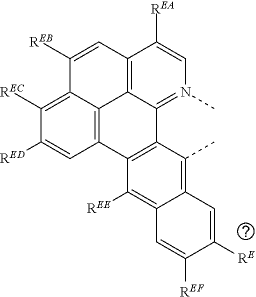 |
| L_{A2}(R^{EA})(R^{EB})(R^{EC})(R^{ED}) (R^{EE})(R^{EF})(R^{EG}), wherein L_{A2}(R₁)(R₁)(R₁)(R₁)(R₁) (R₁₎(R₁) to L_{A2}(R₂₁₁)(R₂₁₁)(R₂₁₁)(R₂₁₁) (R₂₁₁)(R₂₁₁)(R₂₁₁) have the structure | 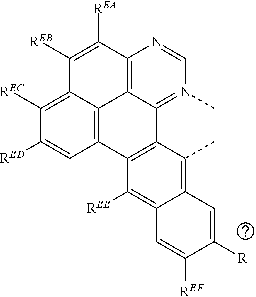 |
| L_{A3}(R^{EA})(R^{EB})(R^{EC})(R^{ED}) (R^{EE})(R^{EF})(R^{EG}), wherein L_{A3}(R₁)(R₁)(R₁)(R₁)(R₁) (R₁₎(R₁) to L_{A3}(R₂₁₁)(R₂₁₁)(R₂₁₁)(R₂₁₁) (R₂₁₁)(R₂₁₁)(R₂₁₁) have the structure | 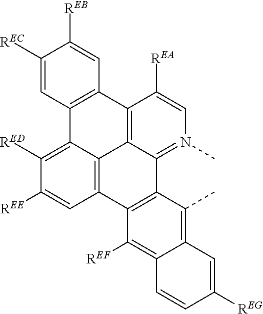 |
| L_{A4}(R^{EA})(R^{EB})(R^{EC})(R^{ED}) (R^{EE})(R^{EF})(R^{EG}), wherein L_{A4}(R₁)(R₁)(R₁)(R₁)(R₁) (R₁₎(R₁) to L_{A4}(R₂₁₁)(R₂₁₁)(R₂₁₁)(R₂₁₁) (R₂₁₁)(R₂₁₁)(R₂₁₁) have the structure | 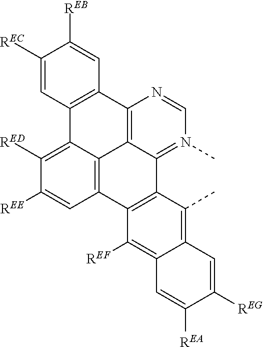 |
| L_{A5}(R^{EA})(R^{EB})(R^{EC})(R^{ED}) (R^{EE})(R^{EF})(R^{EG}), wherein L_{A5}(R₁)(R₁)(R₁)(R₁)(R₁) (R₁₎(R₁) to L_{A5}(R₂₁₁)(R₂₁₁)(R₂₁₁)(R₂₁₁) (R₂₁₁)(R₂₁₁)(R₂₁₁) have the structure | 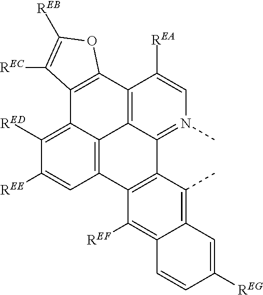 |
| L_{A6}(R^{EA})(R^{EB})(R^{EC})(R^{ED}) (R^{EE})(R^{EF})(R^{EG}), wherein L_{A6}(R₁)(R₁)(R₁)(R₁)(R₁) (R₁₎(R₁) to L_{A6}(R₂₁₁)(R₂₁₁)(R₂₁₁)(R₂₁₁) (R₂₁₁)(R₂₁₁)(R₂₁₁) have the structure | 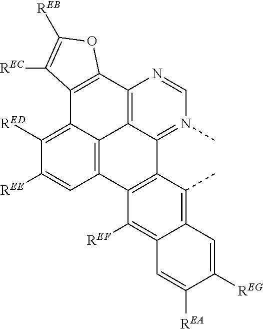 |
| L_{A7}(R^{EA})(R^{EB})(R^{EC})(R^{ED}) (R^{EE})(R^{EF})(R^{EG}), wherein L_{A7}(R₁)(R₁)(R₁)(R₁)(R₁) (R₁₎(R₁) to L_{A7}(R₂₁₁)(R₂₁₁)(R₂₁₁)(R₂₁₁) (R₂₁₁)(R₂₁₁)(R₂₁₁) have the structure | 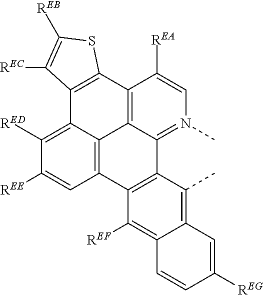 |
| L_{A8}(R^{EA})(R^{EB})(R^{EC})(R^{ED}) (R^{EE})(R^{EF})(R^{EG}), wherein L_{A8}(R₁)(R₁)(R₁)(R₁)(R₁) (R₁₎(R₁) to L_{A8}(R₂₁₁)(R₂₁₁)(R₂₁₁)(R₂₁₁) (R₂₁₁)(R₂₁₁)(R₂₁₁) have the structure | 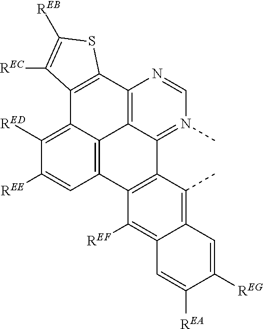 |
| L_{A9}(R^{EA})(R^{EB})(R^{EC})(R^{ED}) (R^{EE})(R^{EF})(R^{EG}), wherein L_{A9}(R₁)(R₁)(R₁)(R₁)(R₁) (R₁₎(R₁) to L_{A9}(R₂₁₁)(R₂₁₁)(R₂₁₁)(R₂₁₁) (R₂₁₁)(R₂₁₁)(R₂₁₁) have the structure | 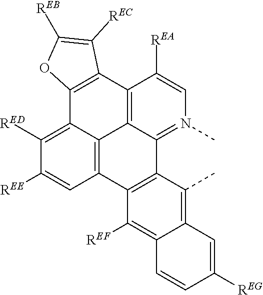 |
| L_{A10}(R^{EA})(R^{EB})(R^{EC})(R^{ED}) (R^{EE})(R^{EF})(R^{EG}), wherein L_{A10}(R₁)(R₁)(R₁)(R₁)(R₁) (R₁₎(R₁) to L_{A10}(R₂₁₁)(R₂₁₁)(R₂₁₁)(R₂₁₁) (R₂₁₁)(R₂₁₁)(R₂₁₁) have the structure | 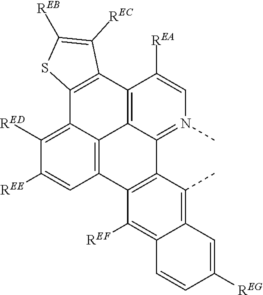 |
| L_{A11}(R^{EA})(R^{EB})(R^{EC})(R^{ED}) (R^{EE})(R^{EF})(R^{EG}), wherein L_{A11}(R₁)(R₁)(R₁)(R₁)(R₁) (R₁₎(R₁) to L_{A11}(R₂₁₁)(R₂₁₁)(R₂₁₁)(R₂₁₁) (R₂₁₁)(R₂₁₁)(R₂₁₁) have the structure | 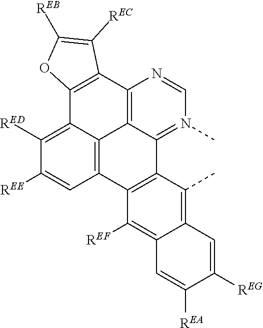 |
| L_{A12}(R^{EA})(R^{EB})(R^{EC})(R^{ED}) (R^{EE})(R^{EF})(R^{EG}), wherein L_{A12}(R₁)(R₁)(R₁)(R₁)(R₁) (R₁₎(R₁) to L_{A12}(R₂₁₁)(R₂₁₁)(R₂₁₁)(R₂₁₁) (R₂₁₁)(R₂₁₁)(R₂₁₁) have the structure | 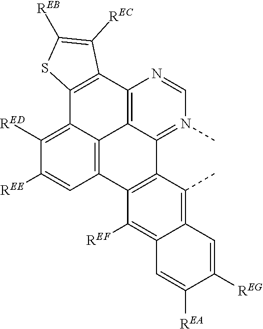 |
| L_{A13}(R^{EA})(R^{EB})(R^{EC})(R^{ED}) (R^{EE})(R^{EF})(R^{EG}). wherein L_{A13}(R₁)(R₁)(R₁)(R₁)(R₁) (R₁₎(R₁) to L_{A13}(R₂₁₁)(R₂₁₁)(R₂₁₁)(R₂₁₁) (R₂₁₁)(R₂₁₁)(R₂₁₁) have the structure | 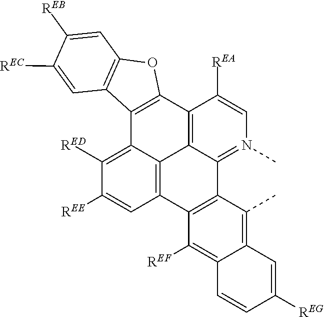 |
| L_{A14}(R^{EA})(R^{EB})(R^{EC})(R^{ED}) (R^{EE})(R^{EF})(R^{EG}), wherein L_{A14}(R₁)(R₁)(R₁)(R₁)(R₁) (R₁₎(R₁) to L_{A14}(R₂₁₁)(R₂₁₁)(R₂₁₁)(R₂₁₁) (R₂₁₁)(R₂₁₁)(R₂₁₁) have the structure | 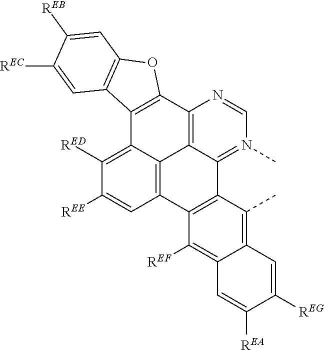 |
| L_{A15}(R^{EA})(R^{EB})(R^{EC})(R^{ED}) (R^{EE})(R^{EF})(R^{EG}), wherein L_{A15}(R₁)(R₁)(R₁)(R₁)(R₁) (R₁₎(R₁) to L_{A15}(R211) (R₂₁₁)(R₂₁₁)(R₂₁₁) (R₂₁₁)(R₂₁₁)(R₂₁₁) have the structure | 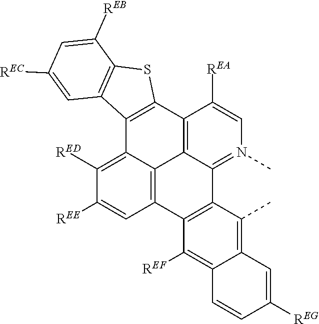 |
| L_{A16}(R^{EA})(R^{EB})(R^{EC})(R^{ED}) (R^{EE})(R^{EF})(R^{EG}), wherein L_{A16}(R₁)(R₁)(R₁)(R₁)(R₁) (R₁₎(R₁) to L_{A16}(R₂₁₁)(R₂₁₁)(R₂₁₁)(R₂₁₁) (R₂₁₁)(R₂₁₁)(R₂₁₁) have the structure | 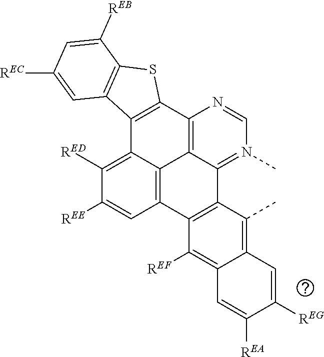 |
| L_{A17}(R^{EA})(R^{EB})(R^{EC})(R^{ED}) (R^{EE})(R^{EF})(R^{EG}), wherein L_{A17}(R₁)(R₁)(R₁)(R₁)(R₁) (R₁₎(R₁) to L_{A17}(R₂₁₁)(R₂₁₁)(R₂₁₁)(R₂₁₁) (R₂₁₁)(R₂₁₁)(R₂₁₁) have the structure | 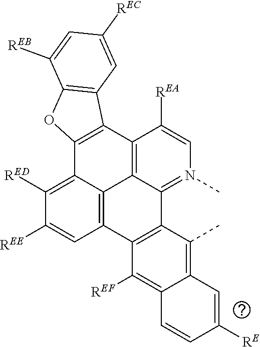 |
| L_{A18}(R^{EA})(R^{EB})(R^{EC})(R^{ED}) (R^{EE})(R^{EF})(R^{EG}), wherein L_{A18}(R₁)(R₁)(R₁)(R₁)(R₁) (R₁₎(R₁) to L_{A18}(R₂₁₁)(R₂₁₁)(R₂₁₁)(R₂₁₁) (R₂₁₁)(R₂₁₁)(R₂₁₁) have the structure | 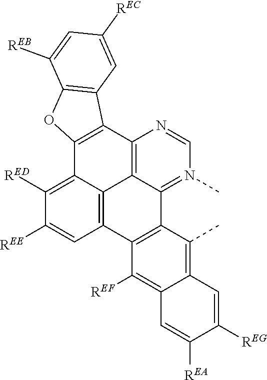 |
| L_{A19}(R^{EA})(R^{EB})(R^{EC})(R^{ED}) (R^{EE})(R^{EF})(R^{EG}), wherein L_{A19}(R₁)(R₁)(R₁)(R₁)(R₁) (R₁₎(R₁) to L_{A19}(R₂₁₁)(R₂₁₁)(R₂₁₁)(R₂₁₁) (R₂₁₁)(R₂₁₁)(R₂₁₁) have the structure | 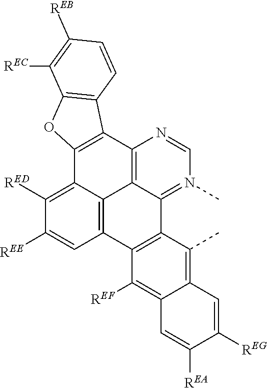 |
| L_{A20}(R^{EA})(R^{EB})(R^{EC})(R^{ED}) (R^{EE})(R^{EF})(R^{EG}), wherein L_{A20}(R₁)(R₁)(R₁)(R₁)(R₁) (R₁₎(R₁) to L_{A20}(R₂₁₁)(R₂₁₁)(R₂₁₁)(R₂₁₁) (R₂₁₁)(R₂₁₁)(R₂₁₁) have the structure | 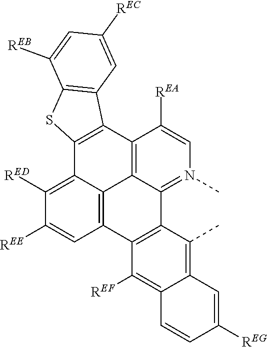 |
| L_{A21}(R^{EA})(R^{EB})(R^{EC})(R^{ED}) (R^{EE})(R^{EF})(R^{EG}), wherein L_{A21}(R₁)(R₁)(R₁)(R₁)(R₁) (R₁₎(R₁) to L_{A21}(R₂₁₁)(R₂₁₁)(R₂₁₁)(R₂₁₁) (R₂₁₁)(R₂₁₁)(R₂₁₁) have the structure | 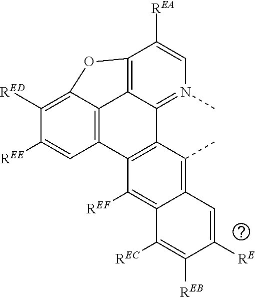 |
| L_{A22}(R^{EA})(R^{EB})(R^{EC})(R^{ED}) (R^{EE})(R^{EF})(R^{EG}), wherein L_{A22}(R₁)(R₁)(R₁)(R₁)(R₁) (R₁₎(R₁) to L_{A22}(R₂₁₁)(R₂₁₁)(R₂₁₁)(R₂₁₁) (R₂₁₁)(R₂₁₁)(R₂₁₁) have the structure | 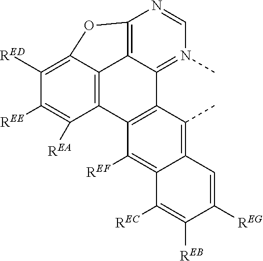 |
| L_{A23}(R^{EA})(R^{EB})(R^{EC})(R^{ED}) (R^{EE})(R^{EF})(R^{EG}), wherein L_{A23}(R₁)(R₁)(R₁)(R₁)(R₁) (R₁₎(R₁) to L_{A23}(R₂₁₁)(R₂₁₁)(R₂₁₁)(R₂₁₁) (R₂₁₁)(R₂₁₁)(R₂₁₁) have the structure | 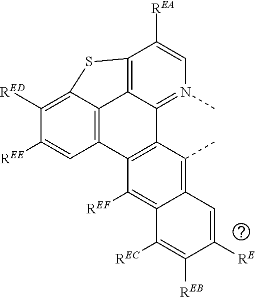 |
| L_{A24}(R^{EA})(R^{EB})(R^{EC})(R^{ED}) (R^{EE})(R^{EF})(R^{EG}), wherein L_{A24}(R₁)(R₁)(R₁)(R₁)(R₁) (R₁₎(R₁) to L_{A24}(R₂₁₁)(R₂₁₁)(R₂₁₁)(R₂₁₁) (R₂₁₁)(R₂₁₁)(R₂₁₁) have the structure | 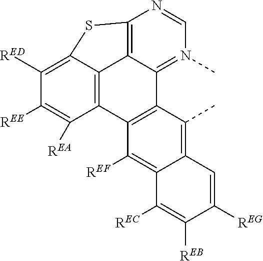 |
| L_{A25}(R^{EA})(R^{EB})(R^{EC})(R^{ED}) (R^{EE})(R^{EF})(R^{EG}), wherein L_{A25}(R₁)(R₁)(R₁)(R₁)(R₁) (R₁₎(R₁) to L_{A25}(R₂₁₁)(R₂₁₁)(R₂₁₁)(R₂₁₁) (R₂₁₁)(R₂₁₁)(R₂₁₁) have the structure | 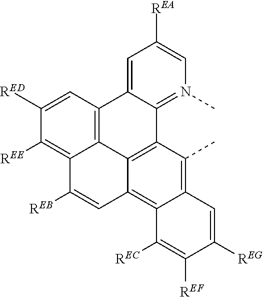 |
| L_{A26}(R^{EA})(R^{EB})(R^{EC})(R^{ED}) (R^{EE})(R^{EF})(R^{EG}), wherein L_{A26}(R₁)(R₁)(R₁)(R₁)(R₁) (R₁₎(R₁) to L_{A26}(R₂₁₁)(R₂₁₁)(R₂₁₁)(R₂₁₁) (R₂₁₁)(R₂₁₁)(R₂₁₁) have the structure | 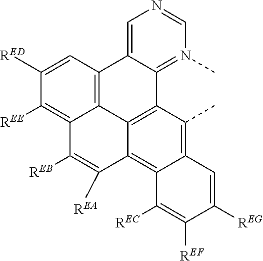 |
| L_{A27}(R^{EA})(R^{EB})(R^{EC})(R^{ED}) (R^{EE})(R^{EF})(R^{EG}), wherein L_{A27}(R₁)(R₁)(R₁)(R₁)(R₁) (R₁₎(R₁) to L_{A27}(R₂₁₁)(R₂₁₁)(R₂₁₁)(R₂₁₁) (R₂₁₁)(R₂₁₁)(R₂₁₁) have the structure | 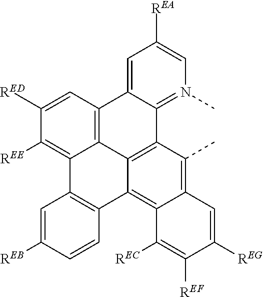 |
| L_{A28}(R^{EA})(R^{EB})(R^{EC})(R^{ED}) (R^{EE})(R^{EF})(R^{EG}), wherein L_{A28}(R₁)(R₁)(R₁)(R₁)(R₁) (R₁₎(R₁) to L_{A28}(R₂₁₁)(R₂₁₁)(R₂₁₁)(R₂₁₁) (R₂₁₁)(R₂₁₁)(R₂₁₁) have the structure | 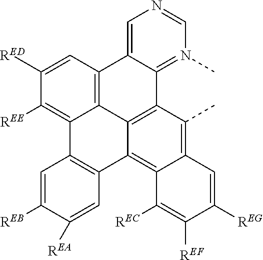 |
| L_{A29}(R^{EA})(R^{EB})(R^{EC})(R^{ED}) (R^{EE})(R^{EF})(R^{EG}), wherein L_{A29}(R₁)(R₁)(R₁)(R₁)(R₁) (R₁₎(R₁) to L_{A29}(R₂₁₁)(R₂₁₁)(R₂₁₁)(R₂₁₁) (R₂₁₁)(R₂₁₁)(R₂₁₁) have the structure | 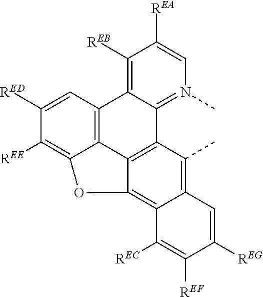 |
| L_{A30}(R^{EA})(R^{EB})(R^{EC})(R^{ED}) (R^{EE})(R^{EF})(R^{EG}), wherein L_{A30}(R₁)(R₁)(R₁)(R₁)(R₁) (R₁₎(R₁) to L_{A30}(R₂₁₁)(R₂₁₁)(R₂₁₁)(R₂₁₁) (R₂₁₁)(R₂₁₁)(R₂₁₁) have the structure | 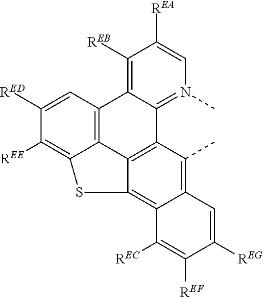 |
| L_{A31}(R^{EA})(R^{EB})(R^{EC})(R^{ED}) (R^{EE})(R^{EF})(R^{EG}), wherein L_{A31}(R₁)(R₁)(R₁)(R₁)(R₁) (R₁₎(R₁) to L_{A31}(R₂₁₁)(R₂₁₁)(R₂₁₁)(R₂₁₁) (R₂₁₁)(R₂₁₁)(R₂₁₁) have the structure | 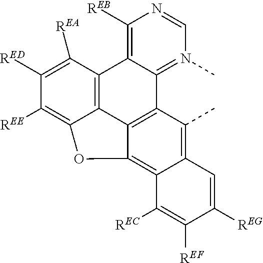 |
| L_{A32}(R^{EA})(R^{EB})(R^{EC})(R^{ED}) (R^{EE})(R^{EF})(R^{EG}), wherein L_{A32}(R₁)(R₁)(R₁)(R₁)(R₁) (R₁₎(R₁) to L_{A32}(R₂₁₁)(R₂₁₁)(R₂₁₁)(R₂₁₁) (R₂₁₁)(R₂₁₁)(R₂₁₁) have the structure | 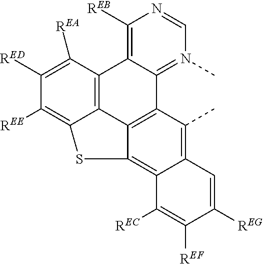 |
| L_{A33}(R^{EA})(R^{EB})(R^{EC})(R^{ED}) (R^{EE})(R^{EF})(R^{EG}), wherein L_{A33}(R₁)(R₁)(R₁)(R₁)(R₁) (R₁₎(R₁) to L_{A33}(R₂₁₁)(R₂₁₁)(R₂₁₁)(R₂₁₁) (R₂₁₁)(R₂₁₁)(R₂₁₁) have the structure | 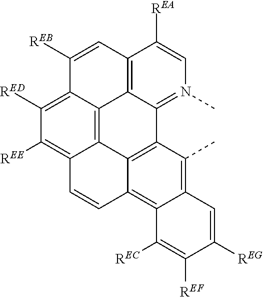 |
| L_{A34}(R^{EA})(R^{EB})(R^{EC})(R^{ED}) (R^{EE})(R^{EF})(R^{EG}), wherein L_{A34}(R₁)(R₁)(R₁)(R₁)(R₁) (R₁₎(R₁) to L_{A34}(R₂₁₁)(R₂₁₁)(R₂₁₁)(R₂₁₁) (R₂₁₁)(R₂₁₁)(R₂₁₁) have the structure | 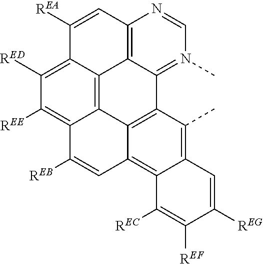 |
| L_{A35}(R^{EA})(R^{EB})(R^{EC})(R^{ED}) (R^{EE})(R^{EF})(R^{EG}), wherein L_{A35}(R₁)(R₁)(R₁)(R₁)(R₁) (R₁₎(R₁) to L_{A35}(R₂₁₁)(R₂₁₁)(R₂₁₁)(R₂₁₁) (R₂₁₁)(R₂₁₁)(R₂₁₁) have the structure | 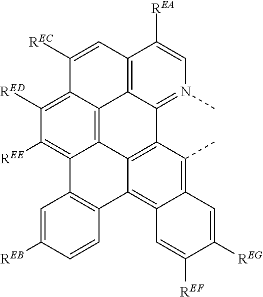 |
| L_{A36}(R^{EA})(R^{EB})(R^{EC})(R^{ED}) (R^{EE})(R^{EF})(R^{EG}), wherein L_{A36}(R₁)(R₁)(R₁)(R₁)(R₁) (R₁₎(R₁) to L_{A36}(R₂₁₁)(R₂₁₁)(R₂₁₁)(R₂₁₁) (R₂₁₁)(R₂₁₁)(R₂₁₁) have the structure | 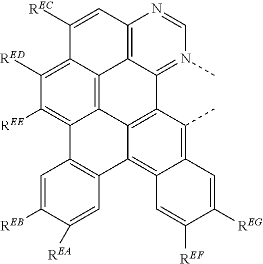 |
| L_{A37}(R^{EA})(R^{EB})(R^{EC})(R^{ED}) (R^{EE})(R^{EF})(R^{EG}), wherein L_{A37}(R₁)(R₁)(R₁)(R₁)(R₁) (R₁₎(R₁) to L_{A37}(R₂₁₁)(R₂₁₁)(R₂₁₁)(R₂₁₁) (R₂₁₁)(R₂₁₁)(R₂₁₁) have the structure | 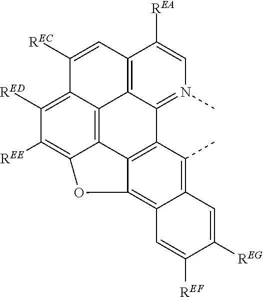 |
| L_{A38}(R^{EA})(R^{EB})(R^{EC})(R^{ED}) (R^{EE})(R^{EF})(R^{EG}), wherein L_{A38}(R₁)(R₁)(R₁)(R₁)(R₁) (R₁₎(R₁) to L_{A38}(R₂₁₁)(R₂₁₁)(R₂₁₁)(R₂₁₁) (R₂₁₁)(R₂₁₁)(R₂₁₁) have the structure | 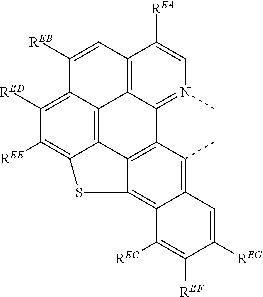 |
| L_{A39}(R^{EA})(R^{EB})(R^{EC})(R^{ED}) (R^{EE})(R^{EF})(R^{EG}), wherein L_{A39}(R₁)(R₁)(R₁)(R₁)(R₁) (R₁₎(R₁) to L_{A39}(R₂₁₁)(R₂₁₁)(R₂₁₁)(R₂₁₁) (R₂₁₁)(R₂₁₁)(R₂₁₁) have the structure | 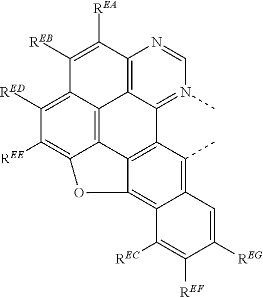 |
| L_{A40}(R^{EA})(R^{EB})(R^{EC})(R^{ED}) (R^{EE})(R^{EF})(R^{EG}), wherein L_{A40}(R₁)(R₁)(R₁)(R₁)(R₁) (R₁₎(R₁) to L_{A40}(R₂₁₁)(R₂₁₁)(R₂₁₁)(R₂₁₁) (R₂₁₁)(R₂₁₁)(R₂₁₁) have the structure | 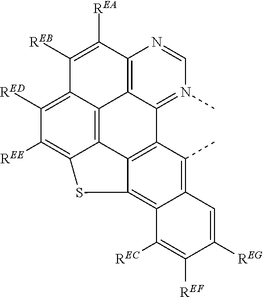 |
| L_{A41}(R^{EA})(R^{EB})(R^{EC})(R^{ED}) (R^{EE})(R^{EF})(R^{EG}), wherein L_{A41}(R₁)(R₁)(R₁)(R₁)(R₁) (R₁₎(R₁) to L_{A41}(R₂₁₁)(R₂₁₁)(R₂₁₁)(R₂₁₁) (R₂₁₁)(R₂₁₁)(R₂₁₁) have the structure | 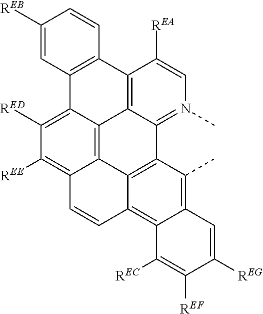 |
| L_{A42}(R^{EA})(R^{EB})(R^{EC})(R^{ED}) (R^{EE})(R^{EF})(R^{EG}), wherein L_{A42}(R₁)(R₁)(R₁)(R₁)(R₁) (R₁₎(R₁) to L_{A42}(R₂₁₁)(R₂₁₁)(R₂₁₁)(R₂₁₁) (R₂₁₁)(R₂₁₁)(R₂₁₁) have the structure | 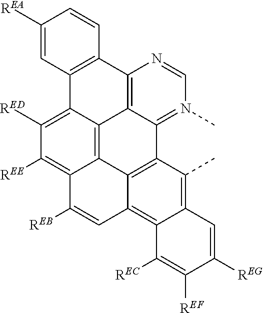 |
| L_{A43}(R^{EA})(R^{EB})(R^{EC})(R^{ED}) (R^{EE})(R^{EF})(R^{EG}), wherein L_{A43}(R₁)(R₁)(R₁)(R₁)(R₁) (R₁₎(R₁) to L_{A43}(R₂₁₁)(R₂₁₁)(R₂₁₁)(R₂₁₁) (R₂₁₁)(R₂₁₁)(R₂₁₁) have the structure | 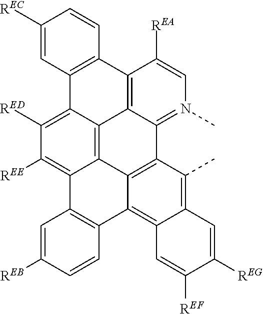 |
| L_{A44}(R^{EA})(R^{EB})(R^{EC})(R^{ED}) (R^{EE})(R^{EF})(R^{EG}), wherein L_{A44}(R₁)(R₁)(R₁)(R₁)(R₁) (R₁₎(R₁) to L_{A44}(R₂₁₁)(R₂₁₁)(R₂₁₁)(R₂₁₁) (R₂₁₁)(R₂₁₁)(R₂₁₁) have the structure | 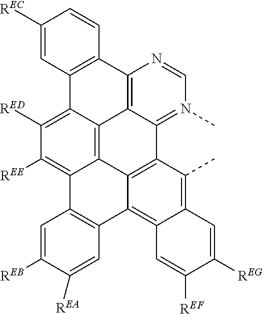 |
| L_{A45}(R^{EA})(R^{EB})(R^{EC})(R^{ED}) (R^{EE})(R^{EF})(R^{EG}), wherein L_{A45}(R₁)(R₁)(R₁)(R₁)(R₁) (R₁₎(R₁) to L_{A45}(R₂₁₁)(R₂₁₁)(R₂₁₁)(R₂₁₁) (R₂₁₁)(R₂₁₁)(R₂₁₁) have the structure | 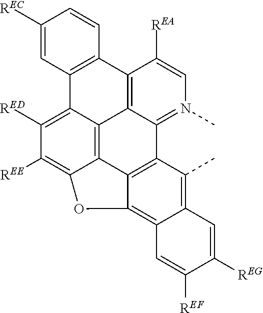 |
| L_{A46}(R^{EA})(R^{EB})(R^{EC})(R^{ED}) (R^{EE})(R^{EF})(R^{EG}), wherein L_{A46}(R₁)(R₁)(R₁)(R₁)(R₁) (R₁₎(R₁) to L_{A6}(R₂₁₁)(R₂₁₁)(R₂₁₁)(R₂₁₁) (R₂₁₁)(R₂₁₁)(R₂₁₁) have the structure | 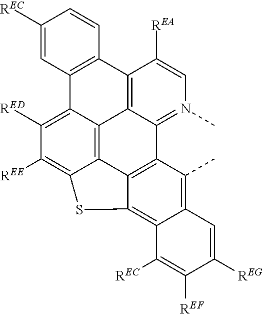 |
| L_{A47}(R^{EA})(R^{EB})(R^{EC})(R^{ED}) (R^{EE})(R^{EF})(R^{EG}), wherein L_{A47}(R₁)(R₁)(R₁)(R₁)(R₁) (R₁₎(R₁) to L_{A47}(R₂₁₁)(R₂₁₁)(R₂₁₁)(R₂₁₁) (R₂₁₁)(R₂₁₁)(R₂₁₁) have the structure | 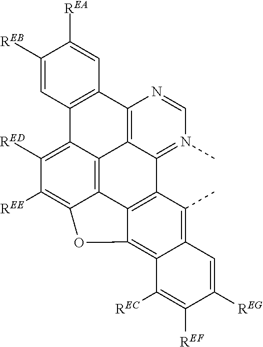 |
| L_{A48}(R^{EA})(R^{EB})(R^{EC})(R^{ED}) (R^{EE})(R^{EF})(R^{EG}), wherein L_{A48}(R₁)(R₁)(R₁)(R₁)(R₁) (R₁₎(R₁) to L_{A48}(R₂₁₁)(R₂₁₁)(R₂₁₁)(R₂₁₁) (R₂₁₁)(R₂₁₁)(R₂₁₁) have the structure | 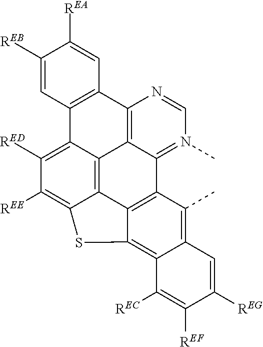 |
| L_{A49}(R^{EA})(R^{EB})(R^{EC})(R^{ED}) (R^{EE})(R^{EF})(R^{EG}), wherein L_{A49}(R₁)(R₁)(R₁)(R₁)(R₁) (R₁₎(R₁) to L_{A49}(R₂₁₁)(R₂₁₁)(R₂₁₁)(R₂₁₁) (R₂₁₁)(R₂₁₁)(R₂₁₁) have the structure | 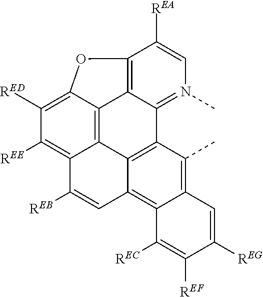 |
| L_{A50}(R^{EA})(R^{EB})(R^{EC})(R^{ED}) (R^{EE})(R^{EF})(R^{EG}), wherein L_{A50}(R₁)(R₁)(R₁)(R₁)(R₁) (R₁₎(R₁) to L_{A50}(R₂₁₁)(R₂₁₁)(R₂₁₁)(R₂₁₁) (R₂₁₁)(R₂₁₁)(R₂₁₁) have the structure | 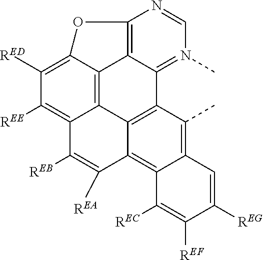 |
| L_{A51}(R^{EA})(R^{EB})(R^{EC})(R^{ED}) (R^{EE})(R^{EF})(R^{EG}), wherein L_{A51}(R₁)(R₁)(R₁)(R₁)(R₁) (R₁₎(R₁) to L_{A51}(R₂₁₁)(R₂₁₁)(R₂₁₁)(R₂₁₁) (R₂₁₁)(R₂₁₁)(R₂₁₁) have the structure | 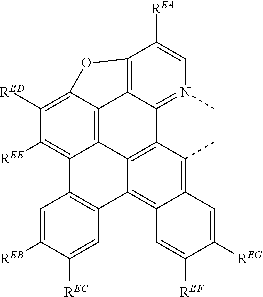 |
| L_{A52}(R^{EA})(R^{EB})(R^{EC})(R^{ED}) (R^{EE})(R^{EF})(R^{EG}), wherein L_{A52}(R₁)(R₁)(R₁)(R₁)(R₁) (R₁₎(R₁) to L_{A52}(R₂₁₁)(R₂₁₁)(R₂₁₁)(R₂₁₁) (R₂₁₁)(R₂₁₁)(R₂₁₁) have the structure | 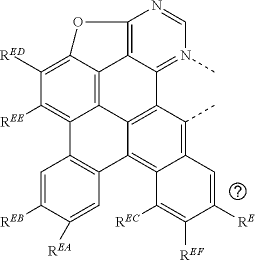 |
| L_{A53}(R^{EA})(R^{EB})(R^{EC})(R^{ED}) (R^{EE})(R^{EF})(R^{EG}), wherein L_{A53}(R₁)(R₁)(R₁)(R₁)(R₁) (R₁₎(R₁) to L_{A53}(R₂₁₁)(R₂₁₁)(R₂₁₁)(R₂₁₁) (R₂₁₁)(R₂₁₁)(R₂₁₁) have the structure | 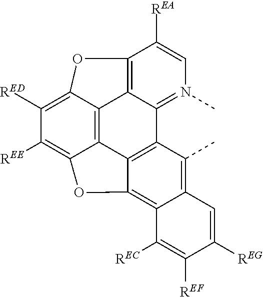 |
| L_{A54}(R^{EA})(R^{EB})(R^{EC})(R^{ED}) (R^{EE})(R^{EF})(R^{EG}), wherein L_{A54}(R₁)(R₁)(R₁)(R₁)(R₁) (R₁₎(R₁) to L_{A54}(R₂₁₁)(R₂₁₁)(R₂₁₁)(R₂₁₁) (R₂₁₁)(R₂₁₁)(R₂₁₁) have the structure | 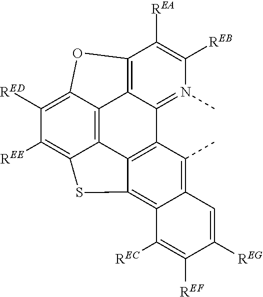 |
| L_{A55}(R^{EA})(R^{EB})(R^{EC})(R^{ED}) (R^{EE})(R^{EF})(R^{EG}), wherein L_{A55}(R₁)(R₁)(R₁)(R₁)(R₁) (R₁₎(R₁) to L_{A55}(R₂₁₁)(R₂₁₁)(R₂₁₁)(R₂₁₁) (R₂₁₁)(R₂₁₁)(R₂₁₁) have the structure | 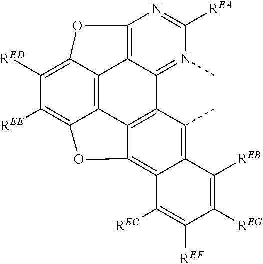 |
| L_{A56}(R^{EA})(R^{EB})(R^{EC})(R^{ED}) (R^{EE})(R^{EF})(R^{EG}), wherein L_{A56}(R₁)(R₁)(R₁)(R₁)(R₁) (R₁₎(R₁) to L_{A56}(R₂₁₁)(R₂₁₁)(R₂₁₁)(R₂₁₁) (R₂₁₁)(R₂₁₁)(R₂₁₁) have the structure | 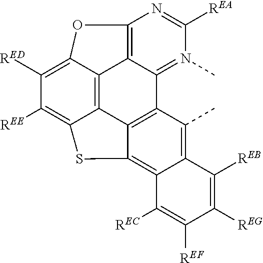 |
| L_{A57}(R^{EA})(R^{EB})(R^{EC})(R^{ED}) (R^{EE})(R^{EF})(R^{EG}), wherein L_{A57}(R₁)(R₁)(R₁)(R₁)(R₁) (R₁₎(R₁) to L_{A57}(R₂₁₁)(R₂₁₁)(R₂₁₁)(R₂₁₁) (R₂₁₁)(R₂₁₁)(R₂₁₁) have the structure | 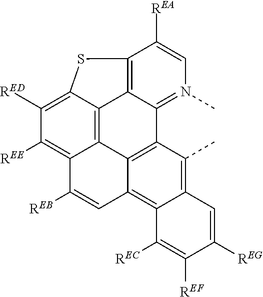 |
| L_{A58}(R^{EA})(R^{EB})(R^{EC})(R^{ED}) (R^{EE})(R^{EF})(R^{EG}), wherein L_{A58}(R₁)(R₁)(R₁)(R₁)(R₁) (R₁₎(R₁) to L_{A58}(R₂₁₁)(R₂₁₁)(R₂₁₁)(R₂₁₁) (R₂₁₁)(R₂₁₁)(R₂₁₁) have the structure | 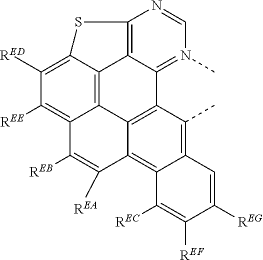 |
| L_{A59}(R^{EA})(R^{EB})(R^{EC})(R^{ED}) (R^{EE})(R^{EF})(R^{EG}), wherein L_{A59}(R₁)(R₁)(R₁)(R₁)(R₁) (R₁₎(R₁) to L_{A59}(R₂₁₁)(R₂₁₁)(R₂₁₁)(R₂₁₁) (R₂₁₁)(R₂₁₁)(R₂₁₁) have the structure | 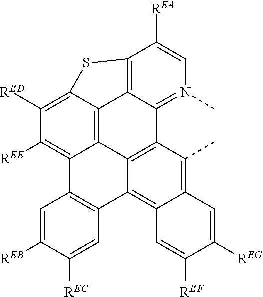 |
| L_{A60}(R^{EA})(R^{EB})(R^{EC})(R^{ED}) (R^{EE})(R^{EF})(R^{EG}), wherein L_{A60}(R₁)(R₁)(R₁)(R₁)(R₁) (R₁₎(R₁) to L_{A60}(R₂₁₁)(R₂₁₁)(R₂₁₁)(R₂₁₁) (R₂₁₁)(R₂₁₁)(R₂₁₁) have the structure | 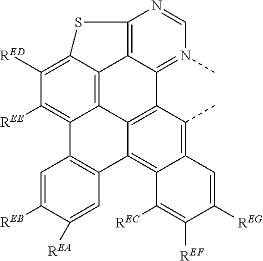 |
| L_{A61}(R^{EA})(R^{EB})(R^{EC})(R^{ED}) (R^{EE})(R^{EF})(R^{EG}), wherein L_{A61}(R₁)(R₁)(R₁)(R₁)(R₁) (R₁₎(R₁) to L_{A61}(R₂₁₁)(R₂₁₁)(R₂₁₁)(R₂₁₁) (R₂₁₁)(R₂₁₁)(R₂₁₁) have the structure | 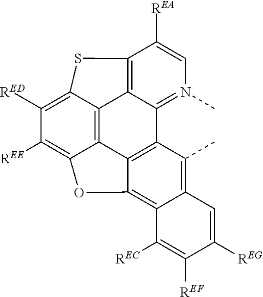 |
| L_{A62}(R^{EA})(R^{EB})(R^{EC})(R^{ED}) (R^{EE})(R^{EF})(R^{EG}), wherein L_{A62}(R₁)(R₁)(R₁)(R₁)(R₁) (R₁₎(R₁) to L_{A62}(R₂₁₁)(R₂₁₁)(R₂₁₁)(R₂₁₁) (R₂₁₁)(R₂₁₁)(R₂₁₁) have the structure | 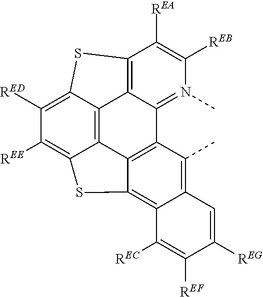 |
| L_{A63}(R^{EA})(R^{EB})(R^{EC})(R^{ED}) (R^{EE})(R^{EF})(R^{EG}), wherein L_{A63}(R₁)(R₁)(R₁)(R₁)(R₁) (R₁₎(R₁) to L_{A63}(R₂₁₁)(R₂₁₁)(R₂₁₁)(R₂₁₁) (R₂₁₁)(R₂₁₁)(R₂₁₁) have the structure | 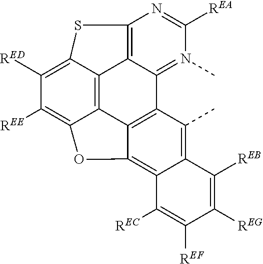 |
| L_{A64}(R^{EA})(R^{EB})(R^{EC})(R^{ED}) (R^{EE})(R^{EF})(R^{EG}), wherein L_{A64}(R₁)(R₁)(R₁)(R₁)(R₁) (R₁₎(R₁) to L_{A64}(R₂₁₁)(R₂₁₁)(R₂₁₁)(R₂₁₁) (R₂₁₁)(R₂₁₁)(R₂₁₁) have the structure | 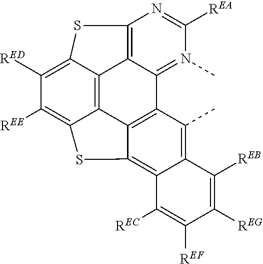 |
| L_{A65}(R^{EA})(R^{EB})(R^{EC})(R^{ED}) (R^{EE})(R^{EF})(R^{EG}), wherein L_{A65}(R₁)(R₁)(R₁)(R₁)(R₁) (R₁₎(R₁) to L_{A65}(R₂₁₁)(R₂₁₁)(R₂₁₁)(R₂₁₁) (R₂₁₁)(R₂₁₁)(R₂₁₁) have the structure | 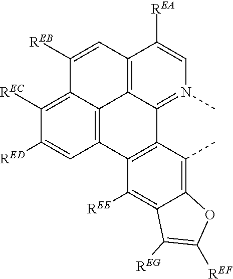 |
| L_{A66}(R^{EA})(R^{EB})(R^{EC})(R^{ED}) (R^{EE})(R^{EF})(R^{EG}), wherein L_{A66}(R₁)(R₁)(R₁)(R₁)(R₁) (R₁₎(R₁) to L_{A66}(R₂₁₁)(R₂₁₁)(R₂₁₁)(R₂₁₁) (R₂₁₁)(R₂₁₁)(R₂₁₁) have the structure | 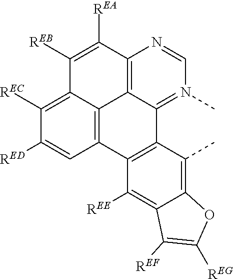 |
| L_{A67}(R^{EA})(R^{EB})(R^{EC})(R^{ED}) (R^{EE})(R^{EF})(R^{EG}), wherein L_{A67}(R₁)(R₁)(R₁)(R₁)(R₁) (R₁₎(R₁) to L_{A67}(R₂₁₁)(R₂₁₁)(R₂₁₁)(R₂₁₁) (R₂₁₁)(R₂₁₁)(R₂₁₁) have the structure | 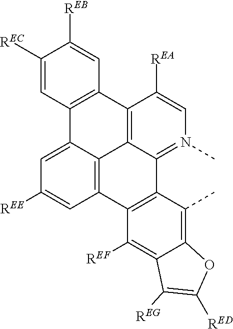 |
| L_{A68}(R^{EA})(R^{EB})(R^{EC})(R^{ED}) (R^{EE})(R^{EF})(R^{EG}), wherein L_{A68}(R₁)(R₁)(R₁)(R₁)(R₁) (R₁₎(R₁) to L_{A68}(R₂₁₁)(R₂₁₁)(R₂₁₁)(R₂₁₁) (R₂₁₁)(R₂₁₁)(R₂₁₁) have the structure | 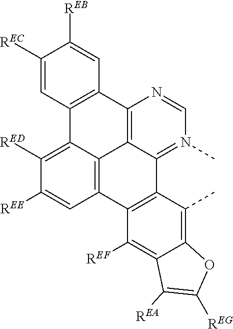 |
| L_{A69}(R^{EA})(R^{EB})(R^{EC})(R^{ED}) (R^{EE})(R^{EF})(R^{EG}), wherein L_{A69}(R₁)(R₁)(R₁)(R₁)(R₁) (R₁₎(R₁) to L_{A69}(R₂₁₁)(R₂₁₁)(R₂₁₁)(R₂₁₁) (R₂₁₁)(R₂₁₁)(R₂₁₁) have the structure | 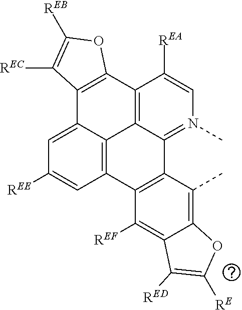 |
| L_{A70}(R^{EA})(R^{EB})(R^{EC})(R^{ED}) (R^{EE})(R^{EF})(R^{EG}), wherein L_{A70}(R₁)(R₁)(R₁)(R₁)(R₁) (R₁₎(R₁) to L_{A70}(R₂₁₁)(R₂₁₁)(R₂₁₁)(R₂₁₁) (R₂₁₁)(R₂₁₁)(R₂₁₁) have the structure | 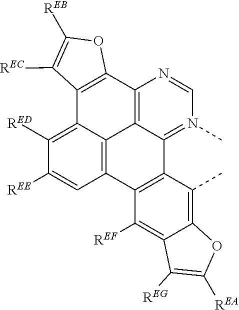 |
| L_{A71}(R^{EA})(R^{EB})(R^{EC})(R^{ED}) (R^{EE})(R^{EF})(R^{EG}), wherein L_{A71}(R₁)(R₁)(R₁)(R₁)(R₁) (R₁₎(R₁) to L_{A71}(R₂₁₁)(R₂₁₁)(R₂₁₁)(R₂₁₁) (R₂₁₁)(R₂₁₁)(R₂₁₁) have the structure | 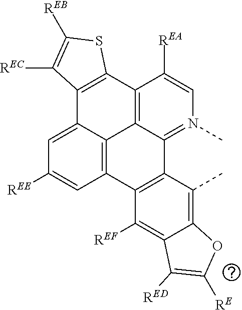 |
| L_{A72}(R^{EA})(R^{EB})(R^{EC})(R^{ED}) (R^{EE})(R^{EF})(R^{EG}), wherein L_{A72}(R₁)(R₁)(R₁)(R₁)(R₁) (R₁₎(R₁) to L_{A72}(R₂₁₁)(R₂₁₁)(R₂₁₁)(R₂₁₁) (R₂₁₁)(R₂₁₁)(R₂₁₁) have the structure | 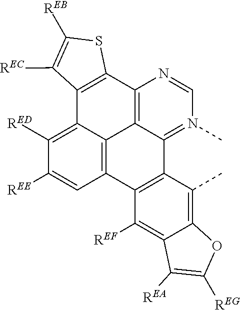 |
| L_{A73}(R^{EA})(R^{EB})(R^{EC})(R^{ED}) (R^{EE})(R^{EF})(R^{EG}), wherein L_{A73}(R₁)(R₁)(R₁)(R₁)(R₁) (R₁₎(R₁) to L_{A73}(R₂₁₁)(R₂₁₁)(R₂₁₁)(R₂₁₁) (R₂₁₁)(R₂₁₁)(R₂₁₁) have the structure | 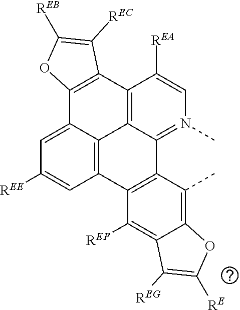 |
| L_{A74}(R^{EA})(R^{EB})(R^{EC})(R^{ED}) (R^{EE})(R^{EF})(R^{EG}), wherein L_{A74}(R₁)(R₁)(R₁)(R₁)(R₁) (R₁₎(R₁) to L_{A74}(R₂₁₁)(R₂₁₁)(R₂₁₁)(R₂₁₁) (R₂₁₁)(R₂₁₁)(R₂₁₁) have the structure | 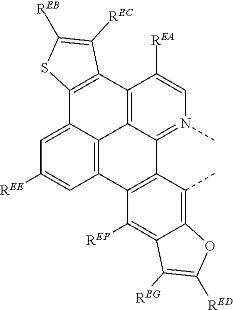 |
| L_{A75}(R^{EA})(R^{EB})(R^{EC})(R^{ED}) (R^{EE})(R^{EF})(R^{EG}), wherein L_{A75}(R₁)(R₁)(R₁)(R₁)(R₁) (R₁₎(R₁) to L_{A75}(R₂₁₁)(R₂₁₁)(R₂₁₁)(R₂₁₁) (R₂₁₁)(R₂₁₁)(R₂₁₁) have the structure | 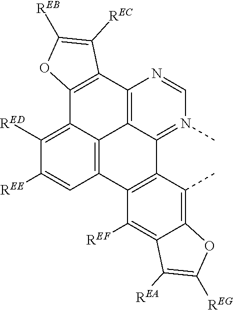 |
| L_{A76}(R^{EA})(R^{EB})(R^{EC})(R^{ED}) (R^{EE})(R^{EF})(R^{EG}), wherein L_{A76}(R₁)(R₁)(R₁)(R₁)(R₁) (R₁₎(R₁) to L_{A76}(R₂₁₁)(R₂₁₁)(R₂₁₁)(R₂₁₁) (R₂₁₁)(R₂₁₁)(R₂₁₁) have the structure | 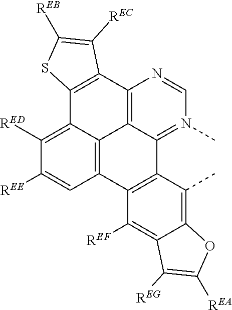 |
| L_{A77}(R^{EA})(R^{EB})(R^{EC})(R^{ED}) (R^{EE})(R^{EF})(R^{EG}), wherein L_{A77}(R₁)(R₁)(R₁)(R₁)(R₁) (R₁₎(R₁) to L_{A77}(R₂₁₁)(R₂₁₁)(R₂₁₁)(R₂₁₁) (R₂₁₁)(R₂₁₁)(R₂₁₁) have the structure | 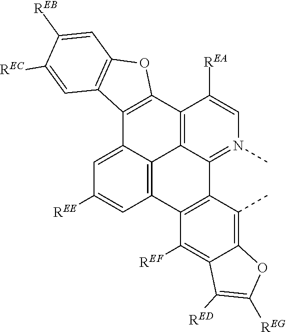 |
| L_{A78}(R^{EA})(R^{EB})(R^{EC})(R^{ED}) (R^{EE})(R^{EF})(R^{EG}), wherein L_{A78}(R₁)(R₁)(R₁)(R₁)(R₁) (R₁₎(R₁) to L_{A78}(R₂₁₁)(R₂₁₁)(R₂₁₁)(R₂₁₁) (R₂₁₁)(R₂₁₁)(R₂₁₁) have the structure | 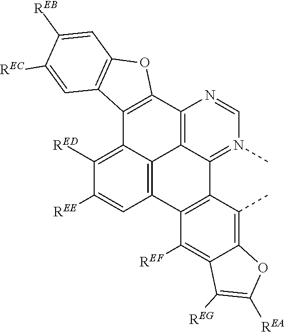 |
| L_{A79}(R^{EA})(R^{EB})(R^{EC})(R^{ED}) (R^{EE})(R^{EF})(R^{EG}), wherein L_{A79}(R₁)(R₁)(R₁)(R₁)(R₁) (R₁₎(R₁) to L_{A79}(R₂₁₁)(R₂₁₁)(R₂₁₁)(R₂₁₁) (R₂₁₁)(R₂₁₁)(R₂₁₁) have the structure | 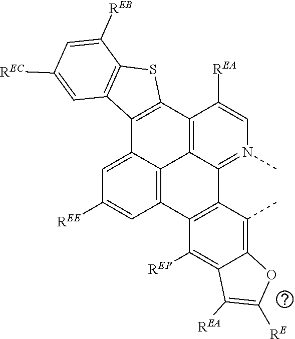 |
| L_{A80}(R^{EA})(R^{EB})(R^{EC})(R^{ED}) (R^{EE})(R^{EF})(R^{EG}), wherein L_{A80}(R₁)(R₁)(R₁)(R₁)(R₁) (R₁₎(R₁) to L_{A80}(R₂₁₁)(R₂₁₁)(R₂₁₁)(R₂₁₁) (R₂₁₁)(R₂₁₁)(R₂₁₁) have the structure | 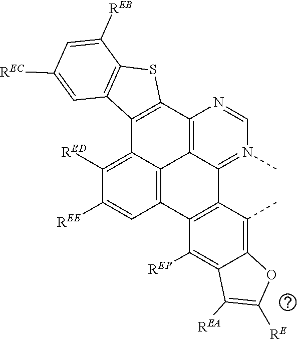 |
| L_{A81}(R^{EA})(R^{EB})(R^{EC})(R^{ED}) (R^{EE})(R^{EF})(R^{EG}), wherein L_{A81}(R₁)(R₁)(R₁)(R₁)(R₁) (R₁₎(R₁) to L_{A81}(R₂₁₁)(R₂₁₁)(R₂₁₁)(R₂₁₁) (R₂₁₁)(R₂₁₁)(R₂₁₁) have the structure | 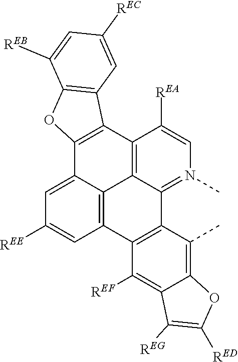 |
| L_{A82}(R^{EA})(R^{EB})(R^{EC})(R^{ED}) (R^{EE})(R^{EF})(R^{EG}), wherein L_{A82}(R₁)(R₁)(R₁)(R₁)(R₁) (R₁₎(R₁) to L_{A82}(R₂₁₁)(R₂₁₁)(R₂₁₁)(R₂₁₁) (R₂₁₁)(R₂₁₁)(R₂₁₁) have the structure | 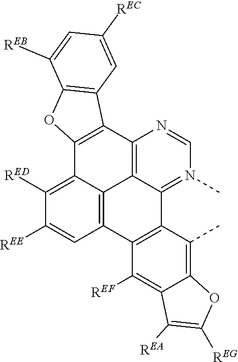 |
| L_{A83}(R^{EA})(R^{EB})(R^{EC})(R^{ED}) (R^{EE})(R^{EF})(R^{EG}), wherein L_{A83}(R₁)(R₁)(R₁)(R₁)(R₁) (R₁₎(R₁) to L_{A83}(R₂₁₁)(R₂₁₁)(R₂₁₁)(R₂₁₁) (R₂₁₁)(R₂₁₁)(R₂₁₁) have the structure | 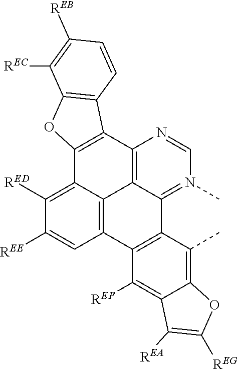 |
| L_{A84}(R^{EA})(R^{EB})(R^{EC})(R^{ED}) (R^{EE})(R^{EF})(R^{EG}), wherein L_{A84}(R₁)(R₁)(R₁)(R₁)(R₁) (R₁₎(R₁) to L_{A84}(R₂₁₁)(R₂₁₁)(R₂₁₁)(R₂₁₁) (R₂₁₁)(R₂₁₁)(R₂₁₁) have the structure | 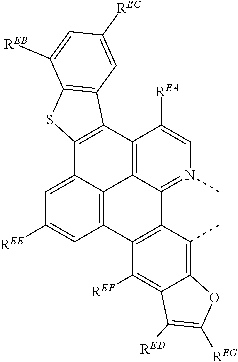 |
| L_{A85}(R^{EA})(R^{EB})(R^{EC})(R^{ED}) (R^{EE})(R^{EF})(R^{EG}), wherein L_{A85}(R₁)(R₁)(R₁)(R₁)(R₁) (R₁₎(R₁) to L_{A85}(R₂₁₁)(R₂₁₁)(R₂₁₁)(R₂₁₁) (R₂₁₁)(R₂₁₁)(R₂₁₁) have the structure | 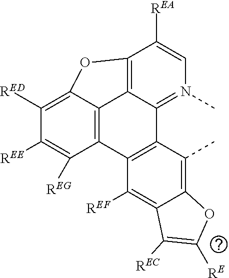 |
| L_{A86}(R^{EA})(R^{EB})(R^{EC})(R^{ED}) (R^{EE})(R^{EF})(R^{EG}), wherein L_{A86}(R₁)(R₁)(R₁)(R₁)(R₁) (R₁₎(R₁) to L_{A86}(R₂₁₁)(R₂₁₁)(R₂₁₁)(R₂₁₁) (R₂₁₁)(R₂₁₁)(R₂₁₁) have the structure | 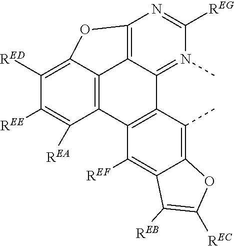 |
| L_{A87}(R^{EA})(R^{EB})(R^{EC})(R^{ED}) (R^{EE})(R^{EF})(R^{EG}), wherein L_{A87}(R₁)(R₁)(R₁)(R₁)(R₁) (R₁₎(R₁) to L_{A87}(R₂₁₁)(R₂₁₁)(R₂₁₁)(R₂₁₁) (R₂₁₁)(R₂₁₁)(R₂₁₁) have the structure | 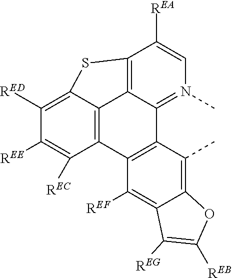 |
| L_{A88}(R^{EA})(R^{EB})(R^{EC})(R^{ED}) (R^{EE})(R^{EF})(R^{EG}), wherein L_{A88}(R₁)(R₁)(R₁)(R₁)(R₁) (R₁₎(R₁) to L_{A88}(R₂₁₁)(R₂₁₁)(R₂₁₁)(R₂₁₁) (R₂₁₁)(R₂₁₁)(R₂₁₁) have the structure | 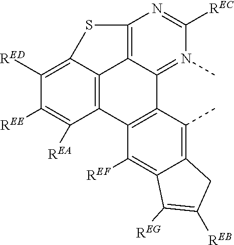 |
| L_{A89}(R^{EA})(R^{EB})(R^{EC})(R^{ED}) (R^{EE})(R^{EF})(R^{EG}), wherein L_{A89}(R₁)(R₁)(R₁)(R₁)(R₁) (R₁₎(R₁) to L_{A89}(R₂₁₁)(R₂₁₁)(R₂₁₁)(R₂₁₁) (R₂₁₁)(R₂₁₁)(R₂₁₁) have the structure | 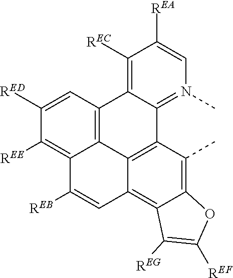 |
| L_{A90}(R^{EA})(R^{EB})(R^{EC})(R^{ED}) (R^{EE})(R^{EF})(R^{EG}), wherein L_{A90}(R₁)(R₁)(R₁)(R₁)(R₁) (R₁₎(R₁) to L_{A90}(R₂₁₁)(R₂₁₁)(R₂₁₁)(R₂₁₁) (R₂₁₁)(R₂₁₁)(R₂₁₁) have the structure | 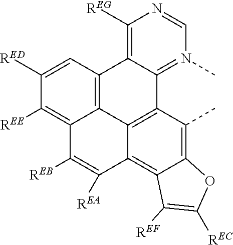 |
| L_{A91}(R^{EA})(R^{EB})(R^{EC})(R^{ED}) (R^{EE})(R^{EF})(R^{EG}), wherein L_{A91}(R₁)(R₁)(R₁)(R₁)(R₁) (R₁₎(R₁) to L_{A91}(R₂₁₁)(R₂₁₁)(R₂₁₁)(R₂₁₁) (R₂₁₁)(R₂₁₁)(R₂₁₁) have the structure | 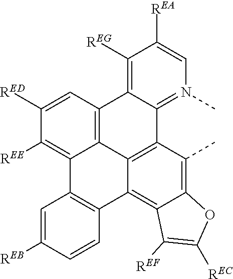 |
| L_{A92}(R^{EA})(R^{EB})(R^{EC})(R^{ED}) (R^{EE})(R^{EF})(R^{EG}), wherein L_{A92}(R₁)(R₁)(R₁)(R₁)(R₁) (R₁₎(R₁) to L_{A92}(R₂₁₁)(R₂₁₁)(R₂₁₁)(R₂₁₁) (R₂₁₁)(R₂₁₁)(R₂₁₁) have the structure | 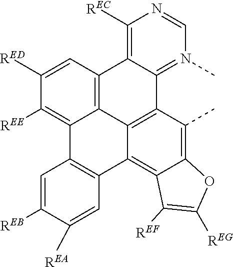 |
| L_{A93}(R^{EA})(R^{EB})(R^{EC})(R^{ED}) (R^{EE})(R^{EF})(R^{EG}), wherein L_{A93}(R₁)(R₁)(R₁)(R₁)(R₁) (R₁₎(R₁) to L_{A93}(R₂₁₁)(R₂₁₁)(R₂₁₁)(R₂₁₁) (R₂₁₁)(R₂₁₁)(R₂₁₁) have the structure | 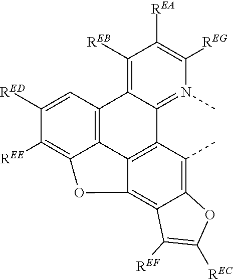 |
| L_{A94}(R^{EA})(R^{EB})(R^{EC})(R^{ED}) (R^{EE})(R^{EF})(R^{EG}), wherein L_{A94}(R₁)(R₁)(R₁)(R₁)(R₁) (R₁₎(R₁) to L_{A94}(R₂₁₁)(R₂₁₁)(R₂₁₁)(R₂₁₁) (R₂₁₁)(R₂₁₁)(R₂₁₁) have the structure | 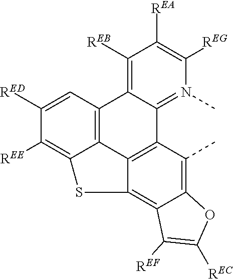 |
| L_{A95}(R^{EA})(R^{EB})(R^{EC})(R^{ED}) (R^{EE})(R^{EF})(R^{EG}), wherein L_{A95}(R₁)(R₁)(R₁)(R₁)(R₁) (R₁₎(R₁) to L_{A95}(R₂₁₁)(R₂₁₁)(R₂₁₁)(R₂₁₁) (R₂₁₁)(R₂₁₁)(R₂₁₁) have the structure | 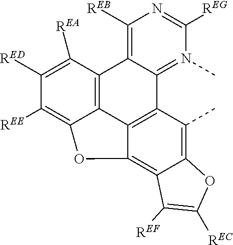 |
| L_{A96}(R^{EA})(R^{EB})(R^{EC})(R^{ED}) (R^{EE})(R^{EF})(R^{EG}), wherein L_{A96}(R₁)(R₁)(R₁)(R₁)(R₁) (R₁₎(R₁) to L_{A96}(R₂₁₁)(R₂₁₁)(R₂₁₁)(R₂₁₁) (R₂₁₁)(R₂₁₁)(R₂₁₁) have the structure | 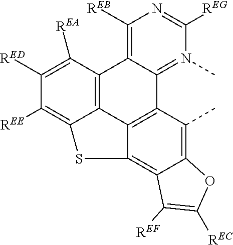 |
| L_{A97}(R^{EA})(R^{EB})(R^{EC})(R^{ED}) (R^{EE})(R^{EF})(R^{EG}), wherein L_{A97}(R₁)(R₁)(R₁)(R₁)(R₁) (R₁₎(R₁) to L_{A97}(R₂₁₁)(R₂₁₁)(R₂₁₁)(R₂₁₁) (R₂₁₁)(R₂₁₁)(R₂₁₁) have the structure | 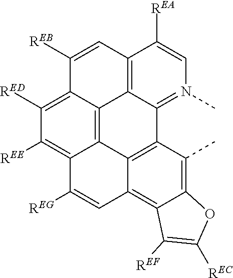 |
| L_{A98}(R^{EA})(R^{EB})(R^{EC})(R^{ED}) (R^{EE})(R^{EF})(R^{EG}), wherein L_{A98}(R₁)(R₁)(R₁)(R₁)(R₁) (R₁₎(R₁) to L_{A98}(R₂₁₁)(R₂₁₁)(R₂₁₁)(R₂₁₁) (R₂₁₁)(R₂₁₁)(R₂₁₁) have the structure | 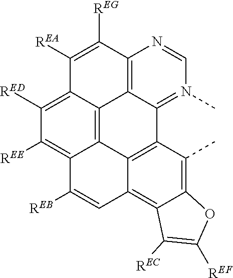 |
| L_{A99}(R^{EA})(R^{EB})(R^{EC})(R^{ED}) (R^{EE})(R^{EF})(R^{EG}), wherein L_{A99}(R₁)(R₁)(R₁)(R₁)(R₁) (R₁₎(R₁) to L_{A99}(R₂₁₁)(R₂₁₁)(R₂₁₁)(R₂₁₁) (R₂₁₁)(R₂₁₁)(R₂₁₁) have the structure | 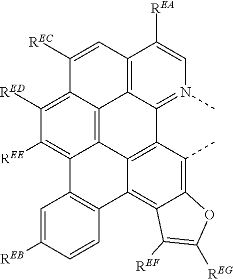 |
| L_{A100}(R^{EA})(R^{EB})(R^{EC})(R^{ED}) (R^{EE})(R^{EF})(R^{EG}), wherein L_{A100}(R₁)(R₁)(R₁)(R₁)(R₁) (R₁₎(R₁) to L_{A100}(R₂₁₁)(R₂₁₁)(R₂₁₁)(R₂₁₁) (R₂₁₁)(R₂₁₁)(R₂₁₁) have the structure | 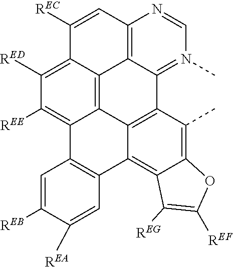 |
| L_{A101}(R^{EA})(R^{EB})(R^{EC})(R^{ED}) (R^{EE})(R^{EF})(R^{EG}), wherein L_{A101}(R₁)(R₁)(R₁)(R₁)(R₁) (R₁₎(R₁) to L_{A101}(R211) (R₂₁₁)(R₂₁₁)(R₂₁₁) (R₂₁₁)(R₂₁₁)(R₂₁₁) have the structure | 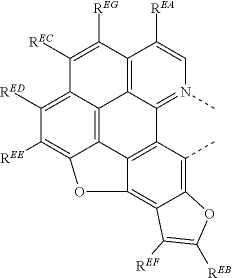 |
| L_{A102}(R^{EA})(R^{EB})(R^{EC})(R^{ED}) (R^{EE})(R^{EF})(R^{EG}), wherein L_{A102}(R₁)(R₁)(R₁)(R₁)(R₁) (R₁₎(R₁) to L_{A102}(R₂₁₁)(R₂₁₁)(R₂₁₁)(R₂₁₁) (R₂₁₁)(R₂₁₁)(R₂₁₁) have the structure | 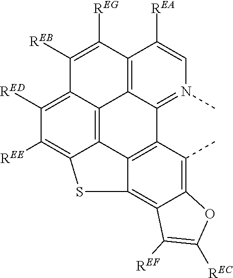 |
| L_{A103}(R^{EA})(R^{EB})(R^{EC})(R^{ED}) (R^{EE})(R^{EF})(R^{EG}), wherein L_{A103}(R₁)(R₁)(R₁)(R₁)(R₁) (R₁₎(R₁) to L_{A103}(R₂₁₁)(R₂₁₁)(R₂₁₁)(R₂₁₁) (R₂₁₁)(R₂₁₁)(R₂₁₁) have the structure | 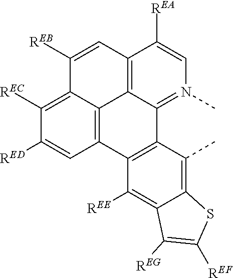 |
| L_{A104}(R^{EA})(R^{EB})(R^{EC})(R^{ED}) (R^{EE})(R^{EF})(R^{EG}), wherein L_{A104}(R₁)(R₁)(R₁)(R₁)(R₁) (R₁₎(R₁) to L_{A104}(R₂₁₁)(R₂₁₁)(R₂₁₁)(R₂₁₁) (R₂₁₁)(R₂₁₁)(R₂₁₁) have the structure | 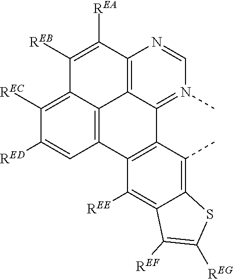 |
| L_{A105}(R^{EA})(R^{EB})(R^{EC})(R^{ED}) (R^{EE})(R^{EF})(R^{EG}), wherein L_{A105}(R₁)(R₁)(R₁)(R₁)(R₁) (R₁₎(R₁) to L_{A105}(R₂₁₁)(R₂₁₁)(R₂₁₁)(R₂₁₁) (R₂₁₁)(R₂₁₁)(R₂₁₁) have the structure | 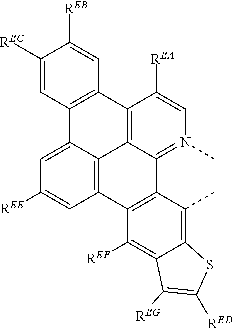 |
| L_{A106}(R^{EA})(R^{EB})(R^{EC})(R^{ED}) (R^{EE})(R^{EF})(R^{EG}), wherein L_{A106}(R₁)(R₁)(R₁)(R₁)(R₁) (R₁₎(R₁) to L_{A106}(R₂₁₁)(R₂₁₁)(R₂₁₁)(R₂₁₁) (R₂₁₁)(R₂₁₁)(R₂₁₁) have the structure | 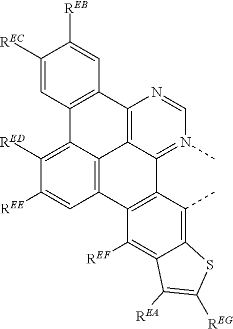 |
| L_{A107}(R^{EA})(R^{EB})(R^{EC})(R^{ED}) (R^{EE})(R^{EF})(R^{EG}), wherein L_{A107}(R₁)(R₁)(R₁)(R₁)(R₁) (R₁₎(R₁) to L_{A107}(R₂₁₁)(R₂₁₁)(R₂₁₁)(R₂₁₁) (R₂₁₁)(R₂₁₁)(R₂₁₁) have the structure | 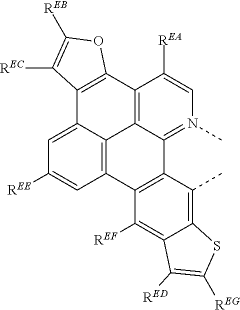 |
| L_{A108}(R^{EA})(R^{EB})(R^{EC})(R^{ED}) (R^{EE})(R^{EF})(R^{EG}), wherein L_{A108}(R₁)(R₁)(R₁)(R₁)(R₁) (R₁₎(R₁) to L_{A108}(R₂₁₁)(R₂₁₁)(R₂₁₁)(R₂₁₁) (R₂₁₁)(R₂₁₁)(R₂₁₁) have the structure | 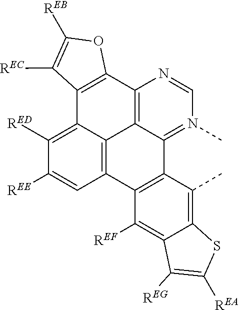 |
| L_{A109}(R^{EA})(R^{EB})(R^{EC})(R^{ED}) (R^{EE})(R^{EF})(R^{EG}), wherein L_{A109}(R₁)(R₁)(R₁)(R₁)(R₁) (R₁₎(R₁) to L_{A109}(R₂₁₁)(R₂₁₁)(R₂₁₁)(R₂₁₁) (R₂₁₁)(R₂₁₁)(R₂₁₁) have the structure | 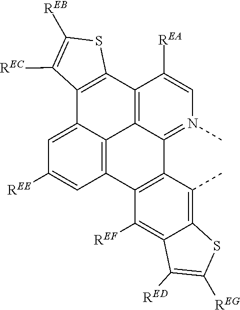 |
| L_{A110}(R^{EA})(R^{EB})(R^{EC})(R^{ED}) (R^{EE})(R^{EF})(R^{EG}), wherein L_{A110}(R₁)(R₁)(R₁)(R₁)(R₁) (R₁₎(R₁) to L_{A110}(R₂₁₁)(R₂₁₁)(R₂₁₁)(R₂₁₁) (R₂₁₁)(R₂₁₁)(R₂₁₁) have the structure | 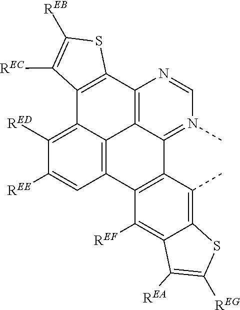 |
| L_{A111}(R^{EA})(R^{EB})(R^{EC})(R^{ED}) (R^{EE})(R^{EF})(R^{EG}), wherein L_{A111}(R₁)(R₁)(R₁)(R₁)(R₁) (R₁₎(R₁) to L_{A111}(R₂₁₁)(R₂₁₁)(R₂₁₁)(R₂₁₁) (R₂₁₁)(R₂₁₁)(R₂₁₁) have the structure | 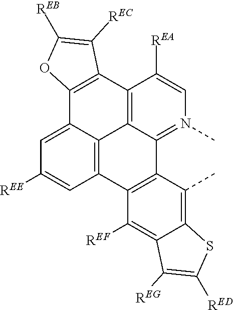 |
| L_{A112}(R^{EA})(R^{EB})(R^{EC})(R^{ED}) (R^{EE})(R^{EF})(R^{EG}), wherein L_{A112}(R₁)(R₁)(R₁)(R₁)(R₁) (R₁₎(R₁) to L_{A112}(R₂₁₁)(R₂₁₁)(R₂₁₁)(R₂₁₁) (R₂₁₁)(R₂₁₁)(R₂₁₁) have the structure | 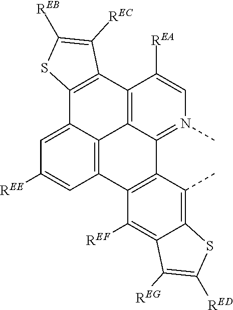 |
| L_{A113}(R^{EA})(R^{EB})(R^{EC})(R^{ED}) (R^{EE})(R^{EF})(R^{EG}), wherein L_{A113}(R₁)(R₁)(R₁)(R₁)(R₁) (R₁₎(R₁) to L_{A113}(R₂₁₁)(R₂₁₁)(R₂₁₁)(R₂₁₁) (R₂₁₁)(R₂₁₁)(R₂₁₁) have the structure | 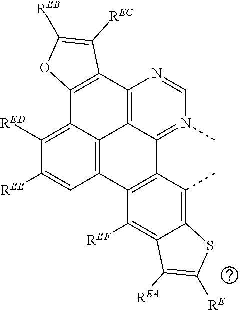 |
| L_{A114}(R^{EA})(R^{EB})(R^{EC})(R^{ED}) (R^{EE})(R^{EF})(R^{EG}), wherein L_{A114}(R₁)(R₁)(R₁)(R₁)(R₁) (R₁₎(R₁) to L_{A114(}R211)(R₂₁₁)(R₂₁₁)(R₂₁₁) (R₂₁₁)(R₂₁₁)(R₂₁₁) have the structure | 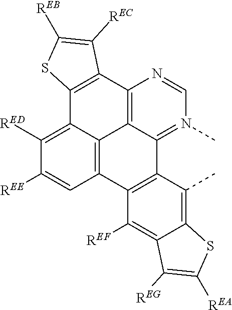 |
| L_{A115}(R^{EA})(R^{EB})(R^{EC})(R^{ED}) (R^{EE})(R^{EF})(R^{EG}), wherein L_{A115}(R₁)(R₁)(R₁)(R₁)(R₁) (R₁₎(R₁) to L_{A115}(R₂₁₁)(R₂₁₁)(R₂₁₁)(R₂₁₁) (R₂₁₁)(R₂₁₁)(R₂₁₁) have the structure | 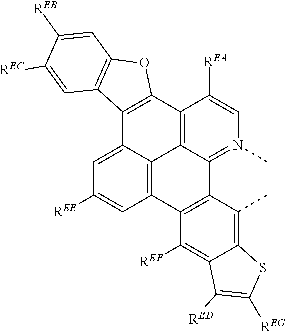 |
| L_{A116}(R^{EA})(R^{EB})(R^{EC})(R^{ED}) (R^{EE})(R^{EF})(R^{EG}). wherein L_{A116}(R₁)(R₁)(R₁)(R₁)(R₁) (R₁₎(R₁) to L_{A116}(R₂₁₁)(R₂₁₁)(R₂₁₁)(R₂₁₁) (R₂₁₁)(R₂₁₁)(R₂₁₁) have the structure | 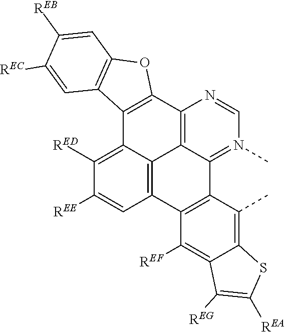 |
| L_{A117}(R^{EA})(R^{EB})(R^{EC})(R^{ED}) (R^{EE})(R^{EF})(R^{EG}), wherein L_{A117}(R₁)(R₁)(R₁)(R₁)(R₁) (R₁₎(R₁) to L_{A117}(R₂₁₁)(R₂₁₁)(R₂₁₁)(R₂₁₁) (R₂₁₁)(R₂₁₁)(R₂₁₁) have the structure | 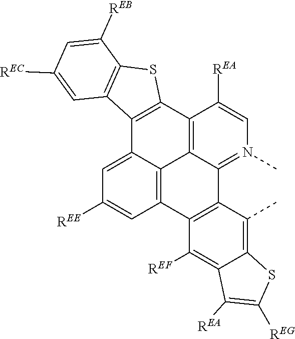 |
| L_{A118}(R^{EA})(R^{EB})(R^{EC})(R^{ED}) (R^{EE})(R^{EF})(R^{EG}), wherein L_{A118}(R₁)(R₁)(R₁)(R₁)(R₁) (R₁₎(R₁) to L_{A118}(R₂₁₁)(R₂₁₁)(R₂₁₁)(R₂₁₁) (R₂₁₁)(R₂₁₁)(R₂₁₁) have the structure | 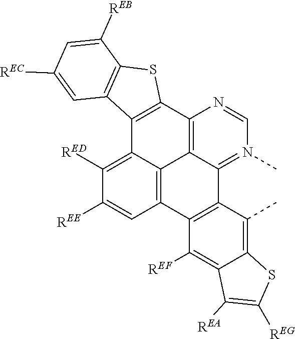 |
| L_{A119}(R^{EA})(R^{EB})(R^{EC})(R^{ED}) (R^{EE})(R^{EF})(R^{EG}), wherein L_{A119}(R₁)(R₁)(R₁)(R₁)(R₁) (R₁₎(R₁) to L_{A119}(R₂₁₁)(R₂₁₁)(R₂₁₁)(R₂₁₁) (R₂₁₁)(R₂₁₁)(R₂₁₁) have the structure | 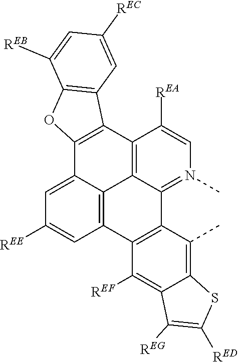 |
| L_{A120}(R^{EA})(R^{EB})(R^{EC})(R^{ED}) (R^{EE})(R^{EF})(R^{EG}), wherein L_{A120}(R₁)(R₁)(R₁)(R₁)(R₁) (R₁₎(R₁) to L_{A120}(R₂₁₁)(R₂₁₁)(R₂₁₁)(R₂₁₁) (R₂₁₁)(R₂₁₁)(R₂₁₁) have the structure | 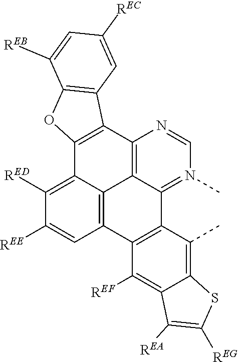 |
| L_{A121}(R^{EA})(R^{EB})(R^{EC})(R^{ED}) (R^{EE})(R^{EF})(R^{EG}), wherein L_{A121}(R₁)(R₁)(R₁)(R₁)(R₁) (R₁₎(R₁) to L_{A121}(R₂₁₁)(R₂₁₁)(R₂₁₁)(R₂₁₁) (R₂₁₁)(R₂₁₁)(R₂₁₁) have the structure | 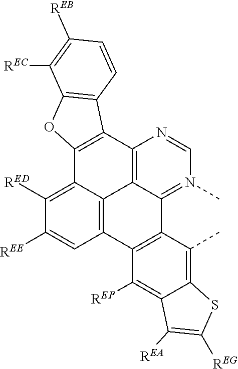 |
| L_{A122}(R^{EA})(R^{EB})(R^{EC})(R^{ED}) (R^{EE})(R^{EF})(R^{EG}), wherein L_{A122}(R₁)(R₁)(R₁)(R₁)(R₁) (R₁₎(R₁) to L_{A122}(R₂₁₁)(R₂₁₁)(R₂₁₁)(R₂₁₁) (R₂₁₁)(R₂₁₁)(R₂₁₁) have the structure | 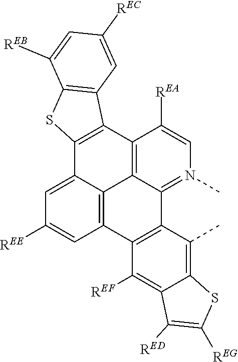 |
| L_{A123}(R^{EA})(R^{EB})(R^{EC})(R^{ED}) (R^{EE})(R^{EF})(R^{EG}), wherein L_{A123}(R₁)(R₁)(R₁)(R₁)(R₁) (R₁₎(R₁) to L_{A123}(R₂₁₁)(R₂₁₁)(R₂₁₁)(R₂₁₁) (R₂₁₁)(R₂₁₁)(R₂₁₁) have the structure | 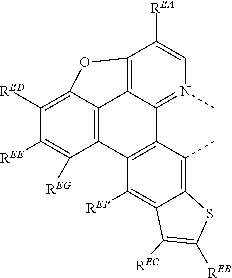 |
| L_{A124}(R^{EA})(R^{EB})(R^{EC})(R^{ED}) (R^{EE})(R^{EF})(R^{EG}), wherein L_{A124}(R₁)(R₁)(R₁)(R₁)(R₁) (R₁₎(R₁) to L_{A124}(R₂₁₁)(R₂₁₁)(R₂₁₁)(R₂₁₁) (R₂₁₁)(R₂₁₁)(R₂₁₁) have the structure | 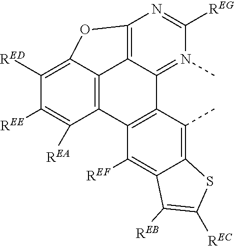 |
| L_{A125}(R^{EA})(R^{EB})(R^{EC})(R^{ED}) (R^{EE})(R^{EF})(R^{EG}), wherein L_{A125}(R₁)(R₁)(R₁)(R₁)(R₁) (R₁₎(R₁) to L_{A125}(R₂₁₁)(R₂₁₁)(R₂₁₁)(R₂₁₁) (R₂₁₁)(R₂₁₁)(R₂₁₁) have the structure | 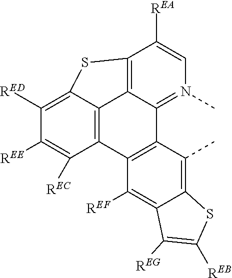 |
| L_{A126}(R^{EA})(R^{EB})(R^{EC})(R^{ED}) (R^{EE})(R^{EF})(R^{EG}), wherein L_{A126}(R₁)(R₁)(R₁)(R₁)(R₁) (R₁₎(R₁) to L_{A126}(R₂₁₁)(R₂₁₁)(R₂₁₁)(R₂₁₁) (R₂₁₁)(R₂₁₁)(R₂₁₁) have the structure | 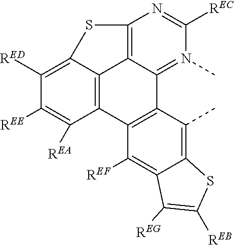 |
| L_{A127}(R_{EA})(R_{EB})(R_{EC})(R_{ED}) (R^{EE})(R^{EF})(R^{EG}), wherein L_{A127}(R₁)(R₁)(R₁)(R₁)(R₁) (R₁₎(R₁) to L_{A127}(R₂₁₁)(R₂₁₁)(R₂₁₁)(R₂₁₁) (R₂₁₁)(R₂₁₁)(R₂₁₁) have the structure | 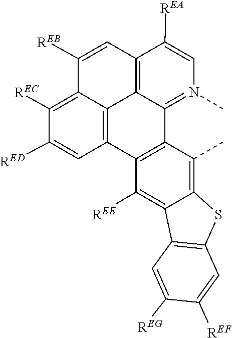 |
| L_{A128}(R^{EA})(R^{EB})(R^{EC})(R^{ED}) (R^{EE})(R^{EF})(R^{EG}), wherein L_{A128}(R₁)(R₁)(R₁)(R₁)(R₁) (R₁₎(R₁) to L_{A128}(R₂₁₁)(R₂₁₁)(R₂₁₁)(R₂₁₁) (R₂₁₁)(R₂₁₁)(R₂₁₁) have the structure | 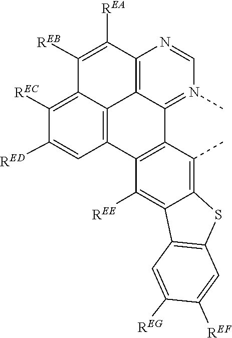 |
| L_{A129}(R^{EA})(R^{EB})(R^{EC})(R^{ED}) (R^{EE})(R^{EF})(R^{EG}), wherein L_{A129}(R₁)(R₁)(R₁)(R₁)(R₁) (R₁₎(R₁) to L_{A129}(R₂₁₁)(R₂₁₁)(R₂₁₁)(R₂₁₁) (R₂₁₁)(R₂₁₁)(R₂₁₁) have the structure | 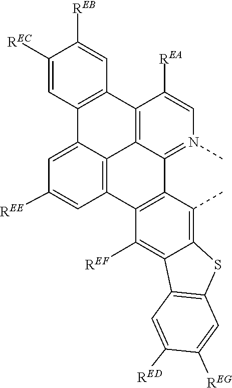 |
| L_{A130}(R^{EA})(R^{EB})(R^{EC})(R^{ED}) (R^{EE})(R^{EF})(R^{EG}), wherein L_{A130}(R₁)(R₁)(R₁)(R₁)(R₁) (R₁₎(R₁) to L_{A130}(R₂₁₁)(R₂₁₁)(R₂₁₁)(R₂₁₁) (R₂₁₁)(R₂₁₁)(R₂₁₁) have the structure | 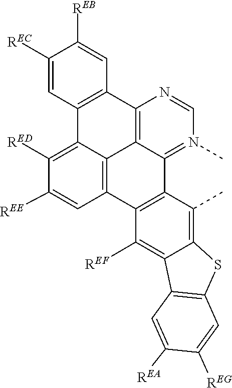 |
| L_{A131}(R^{EA})(R^{EB})(R^{EC})(R^{ED}) (R^{EE})(R^{EF})(R^{EG}), wherein L_{A131}(R₁)(R₁)(R₁)(R₁)(R₁) (R₁₎(R₁) to L_{A131}(R₂₁₁)(R₂₁₁)(R₂₁₁)(R₂₁₁) (R₂₁₁)(R₂₁₁)(R₂₁₁) have the structure | 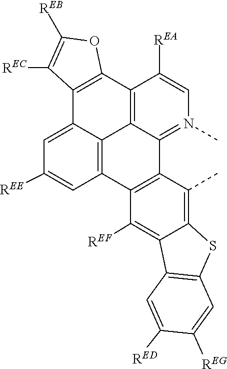 |
| L_{A132}(R^{EA})(R^{EB})(R^{EC})(R^{ED}) (R^{EE})(R^{EF})(R^{EG}), wherein L_{A132}(R₁)(R₁)(R₁)(R₁)(R₁) (R₁₎(R₁) to L_{A132}(R₂₁₁)(R₂₁₁)(R₂₁₁)(R₂₁₁) (R₂₁₁)(R₂₁₁)(R₂₁₁) have the structure | 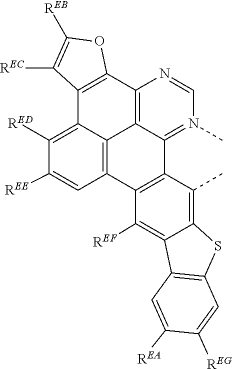 |
| L_{A133}(R^{EA})(R^{EB})(R^{EC})(R^{ED}) (R^{EE})(R^{EF})(R^{EG}), wherein L_{A133}(R₁)(R₁)(R₁)(R₁)(R₁) (R₁₎(R₁) to L_{A133}(R₂₁₁)(R₂₁₁)(R₂₁₁)(R₂₁₁) (R₂₁₁)(R₂₁₁)(R₂₁₁) have the structure | 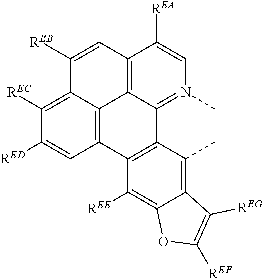 |
| L_{A134}(R^{EA})(R^{EB})(R^{EC})(R^{ED}) (R^{EE})(R^{EF})(R^{EG}), wherein L_{A134}(R₁)(R₁)(R₁)(R₁)(R₁) (R₁₎(R₁) to L_{A134}(R₂₁₁)(R₂₁₁)(R₂₁₁)(R₂₁₁) (R₂₁₁)(R₂₁₁)(R₂₁₁) have the structure | 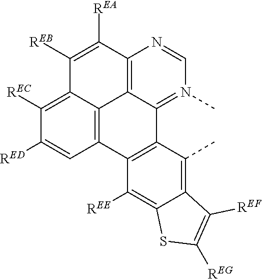 |
| L_{A135}(R^{EA})(R^{EB})(R^{EC})(R^{ED}) (R^{EE})(R^{EF})(R^{EG}), wherein L_{A135}(R₁)(R₁)(R₁)(R₁)(R₁) (R₁₎(R₁) to L_{A135}(R₂₁₁)(R₂₁₁)(R₂₁₁)(R₂₁₁) (R₂₁₁)(R₂₁₁)(R₂₁₁) have the structure | 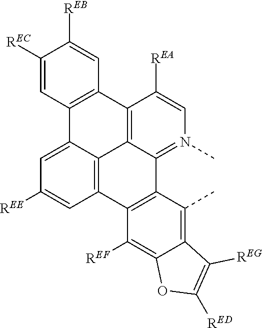 |
| L_{A136}(R^{EA})(R^{EB})(R^{EC})(R^{ED}) (R^{EE})(R^{EF})(R^{EG}), wherein L_{A136}(R₁)(R₁)(R₁)(R₁)(R₁) (R₁₎(R₁) to L_{A136}(R₂₁₁)(R₂₁₁)(R₂₁₁)(R₂₁₁) (R₂₁₁)(R₂₁₁)(R₂₁₁) have the structure | 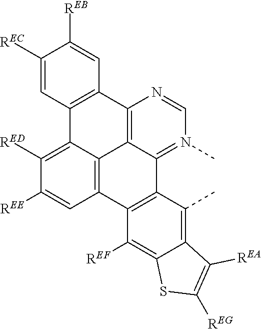 |
| L_{A137}(R^{EA})(R^{EB})(R^{EC})(R^{ED}) (R^{EE})(R^{EF})(R^{EG}), wherein L_{A137}(R₁)(R₁)(R₁)(R₁)(R₁) (R₁₎(R₁) to L_{A137}(R₂₁₁)(R₂₁₁)(R₂₁₁)(R₂₁₁) (R₂₁₁)(R₂₁₁)(R₂₁₁) have the structure | 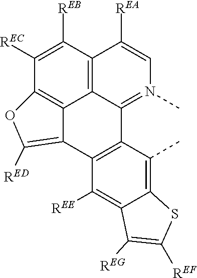 |
| L_{A138}(R^{EA})(R^{EB})(R^{EC})(R^{ED}) (R^{EE})(R^{EF})(R^{EG}), wherein L_{A138}(R₁)(R₁)(R₁)(R₁)(R₁) (R₁₎(R₁) to L_{A138}(R₂₁₁)(R₂₁₁)(R₂₁₁)(R₂₁₁) (R₂₁₁)(R₂₁₁)(R₂₁₁) have the structure | 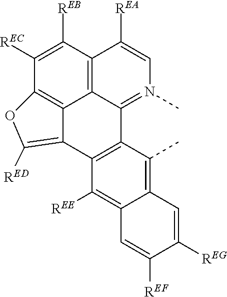 |
| L_{A139}(R^{EA})(R^{EB})(R^{EC})(R^{ED}) (R^{EE})(R^{EF})(R^{EG}), wherein L_{A139}(R₁)(R₁)(R₁)(R₁)(R₁) (R₁₎(R₁) to L_{A139}(R₂₁₁)(R₂₁₁)(R₂₁₁)(R₂₁₁) (R₂₁₁)(R₂₁₁)(R₂₁₁) have the structure | 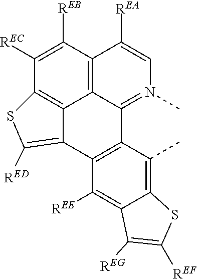 |
| L_{A140}(R^{EA})(R^{EB})(R^{EC})(R^{ED}) (R^{EE})(R^{EF})(R^{EG}), wherein L_{A140}(R₁)(R₁)(R₁)(R₁)(R₁) (R₁₎(R₁) to L_{A140}(R₂₁₁)(R₂₁₁)(R₂₁₁)(R₂₁₁) (R₂₁₁)(R₂₁₁)(R₂₁₁) have the structure | 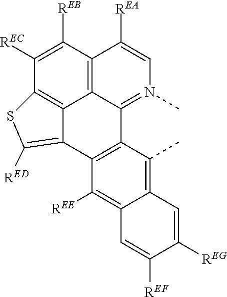 |
| L_{A141}(R^{EA})(R^{EB})(R^{EC})(R^{ED}) (R^{EE})(R^{EF})(R^{EG}), wherein L_{A141}(R₁)(R₁)(R₁)(R₁)(R₁) (R₁₎(R₁) to L_{A141}(R₂₁₁)(R₂₁₁)(R₂₁₁)(R₂₁₁) (R₂₁₁)(R₂₁₁)(R₂₁₁) have the structure | 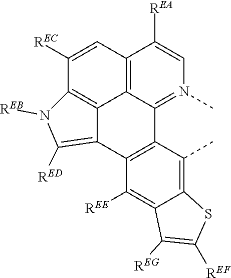 |
| L_{A142}(R^{EA})(R^{EB})(R^{EC})(R^{ED}) (R^{EE})(R^{EF})(R^{EG}), wherein L_{A142}(R₁)(R₁)(R₁)(R₁)(R₁) (R₁₎(R₁) to L_{A142}(R₂₁₁)(R₂₁₁)(R₂₁₁)(R₂₁₁) (R₂₁₁)(R₂₁₁)(R₂₁₁) have the structure | 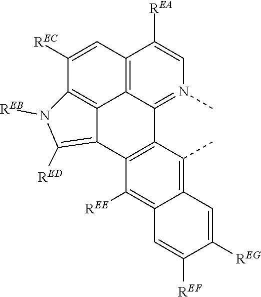 |
| L_{A143}(R^{EA})(R^{EB})(R^{EC})(R^{ED}) (R^{EE})(R^{EF})(R^{EG}), wherein L_{A143}(R₁)(R₁)(R₁)(R₁)(R₁) (R₁₎(R₁) to L_{A143}(R₂₁₁)(R₂₁₁)(R₂₁₁)(R₂₁₁) (R₂₁₁)(R₂₁₁)(R₂₁₁) have the structure | 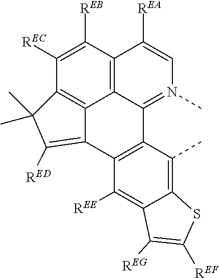 |
| L_{A144}(R^{EA})(R^{EB})(R^{EC})(R^{ED}) (R^{EE})(R^{EF})(R^{EG}), wherein L_{A144}(R₁)(R₁)(R₁)(R₁)(R₁) (R₁₎(R₁) to L_{A144}(R₂₁₁)(R₂₁₁)(R₂₁₁)(R₂₁₁) (R₂₁₁)(R₂₁₁)(R₂₁₁) have the structure | 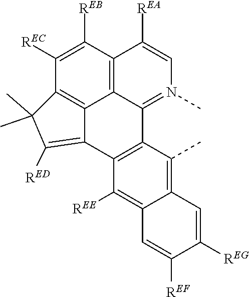 |
| L_{A145}(R^{EA})(R^{EB})(R^{EC})(R^{ED}) (R^{EE})(R^{EF})(R^{EG}), wherein L_{A145}(R₁)(R₁)(R₁)(R₁)(R₁) (R₁₎(R₁) to L_{A145}(R₂₁₁)(R₂₁₁)(R₂₁₁)(R₂₁₁) (R₂₁₁)(R₂₁₁)(R₂₁₁) have the structure | 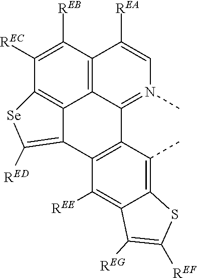 |
| L_{A146}(R^{EA})(R^{EB})(R^{EC})(R^{ED}) (R^{EE})(R^{EF})(R^{EG}), wherein L_{A146}(R₁)(R₁)(R₁)(R₁)(R₁) (R₁₎(R₁) to L_{A146}(R₂₁₁)(R₂₁₁)(R₂₁₁)(R₂₁₁) (R₂₁₁)(R₂₁₁)(R₂₁₁) have the structure | 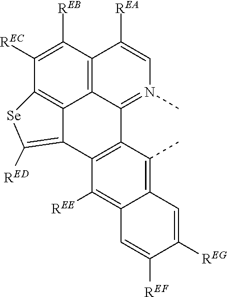 |
| L_{A147}(R^{EA})(R^{EB})(R^{EC})(R^{ED}) (R^{EE})(R^{EF})(R^{EG}), wherein L_{A147}(R₁)(R₁)(R₁)(R₁)(R₁) (R₁₎(R₁) to L_{A147}(R₂₁₁)(R₂₁₁)(R₂₁₁)(R₂₁₁) (R₂₁₁)(R₂₁₁)(R₂₁₁) have the structure | 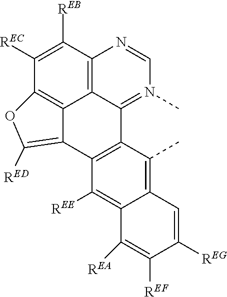 |
| L_{A148}(R^{EA})(R^{EB})(R^{EC})(R^{ED}) (R^{EE})(R^{EF})(R^{EG}), wherein L_{A148}(R₁)(R₁)(R₁)(R₁)(R₁) (R₁₎(R₁) to L_{A148}(R₂₁₁)(R₂₁₁)(R₂₁₁)(R₂₁₁) (R₂₁₁)(R₂₁₁)(R₂₁₁) have the structure | 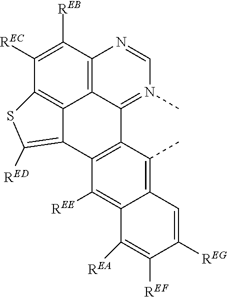 |
| L_{A149}(R^{EA})(R^{EB})(R^{EC})(R^{ED}) (R^{EE})(R^{EF})(R^{EG}), wherein L_{A149}(R₁)(R₁)(R₁)(R₁)(R₁) (R₁₎(R₁) to L_{A149}(R₂₁₁)(R₂₁₁)(R₂₁₁)(R₂₁₁) (R₂₁₁)(R₂₁₁)(R₂₁₁) have the structure | 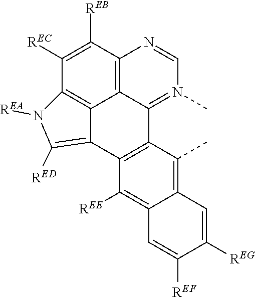 |
| L_{A150}(R^{EA})(R^{EB})(R^{EC})(R^{ED}) (R^{EE})(R^{EF})(R^{EG}), wherein L_{A150}(R₁)(R₁)(R₁)(R₁)(R₁) (R₁₎(R₁) to L_{A150}(R₂₁₁)(R₂₁₁)(R₂₁₁)(R₂₁₁) (R₂₁₁)(R₂₁₁)(R₂₁₁) have the structure | 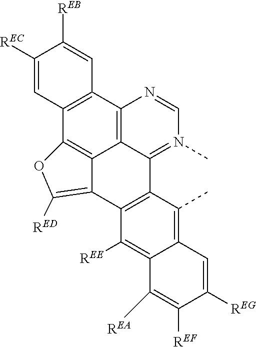 |
| L_{A151}(R^{EA})(R^{EB})(R^{EC})(R^{ED}) (R^{EE})(R^{EF})(R^{EG}), wherein L_{A151}(R₁)(R₁)(R₁)(R₁)(R₁) (R₁₎(R₁) to L_{A151}(R₂₁₁)(R₂₁₁)(R₂₁₁)(R₂₁₁) (R₂₁₁)(R₂₁₁)(R₂₁₁) have the structure | 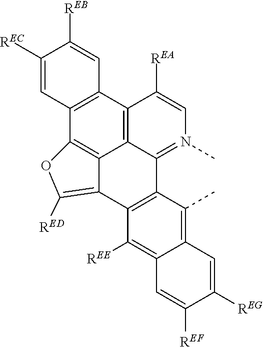 |
| L_{A152}(R^{EA})(R^{EB})(R^{EC})(R^{ED}) (R^{EE})(R^{EF})(R^{EG}), wherein L_{A152}(R₁)(R₁)(R₁)(R₁)(R₁) (R₁₎(R₁) to L_{A152}(R₂₁₁)(R₂₁₁)(R₂₁₁)(R₂₁₁) (R₂₁₁)(R₂₁₁)(R₂₁₁) have the structure | 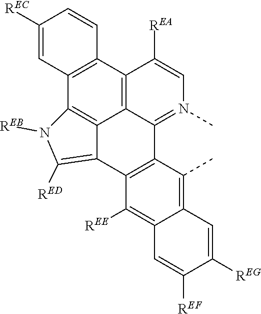 |
| L_{A153}(R^{EA})(R^{EB})(R^{EC})(R^{ED}) (R^{EE})(R^{EF})(R^{EG}), wherein L_{A153}(R₁)(R₁)(R₁)(R₁)(R₁) (R₁₎(R₁) to L_{A153}(R₂₁₁)(R₂₁₁)(R₂₁₁)(R₂₁₁) (R₂₁₁)(R₂₁₁)(R₂₁₁) have the structure | 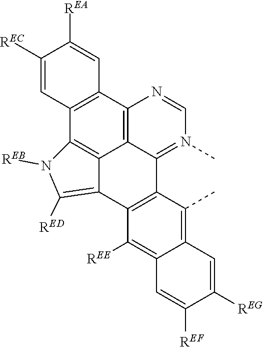 |
| L_{A154}(R^{EA})(R^{EB})(R^{EC})(R^{ED}) (R^{EE})(R^{EF})(R^{EG}), wherein L_{A154}(R₁)(R₁)(R₁)(R₁)(R₁) (R₁₎(R₁) to L_{A154}(R₂₁₁)(R₂₁₁)(R₂₁₁)(R₂₁₁) (R₂₁₁)(R₂₁₁)(R₂₁₁) have the structure | 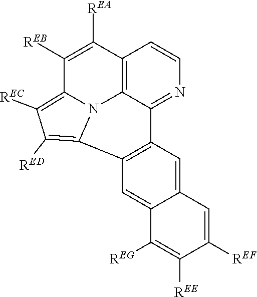 |
| L_{A155}(R^{EA})(R^{EB})(R^{EC})(R^{ED}) (R^{EE})(R^{EF})(R^{EG}), wherein L_{A155}(R₁)(R₁)(R₁)(R₁)(R₁) (R₁₎(R₁) to L_{A155}(R₂₁₁)(R₂₁₁)(R₂₁₁)(R₂₁₁) (R₂₁₁)(R₂₁₁)(R₂₁₁) have the structure | 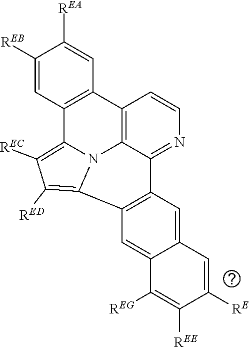 |
| L_{A156}(R^{EA})(R^{EB})(R^{EC})(R^{ED}) (R^{EE})(R^{EF})(R^{EG}), wherein L_{A156}(R₁)(R₁)(R₁)(R₁)(R₁) (R₁₎(R₁) to L_{A156}(R₂₁₁)(R₂₁₁)(R₂₁₁)(R₂₁₁) (R₂₁₁)(R₂₁₁)(R₂₁₁) have the structure | 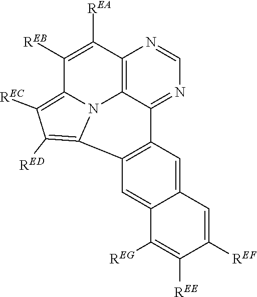 |
| L_{A157}(R^{EA})(R^{EB})(R^{EC})(R^{ED}) (R^{EE})(R^{EF})(R^{EG}), wherein L_{A157}(R₁)(R₁)(R₁)(R₁)(R₁) (R₁₎(R₁) to L_{A157}(R₂₁₁)(R₂₁₁)(R₂₁₁)(R₂₁₁) (R₂₁₁)(R₂₁₁)(R₂₁₁) have the structure | 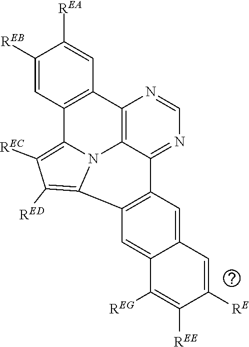 |
| L_{A158}(R^{EA})(R^{EB})(R^{EC})(R^{ED}) (R^{EE})(R^{EF})(R^{EG}), wherein L_{A158}(R₁)(R₁)(R₁)(R₁)(R₁) (R₁₎(R₁) to L_{A158}(R₂₁₁)(R₂₁₁)(R₂₁₁)(R₂₁₁) (R₂₁₁)(R₂₁₁)(R₂₁₁) have the structure | 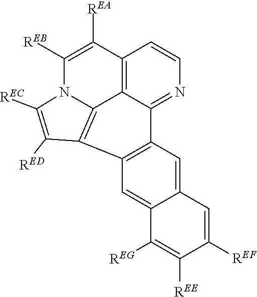 |
| L_{A159}(R^{EA})(R^{EB})(R^{EC})(R^{ED}) (R^{EE})(R^{EF})(R^{EG}), wherein L_{A159}(R₁)(R₁)(R₁)(R₁)(R₁) (R₁₎(R₁) to L_{A159}(R₂₁₁)(R₂₁₁)(R₂₁₁)(R₂₁₁) (R₂₁₁)(R₂₁₁)(R₂₁₁) have the structure | 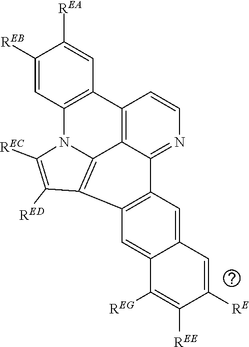 |
| L_{A160}(R^{EA})(R^{EB})(R^{EC})(R^{ED}) (R^{EE})(R^{EF})(R^{EG}), wherein L_{A160}(R₁)(R₁)(R₁)(R₁)(R₁) (R₁₎(R₁) to L_{A160}(R₂₁₁)(R₂₁₁)(R₂₁₁)(R₂₁₁) (R₂₁₁)(R₂₁₁)(R₂₁₁) have the structure | 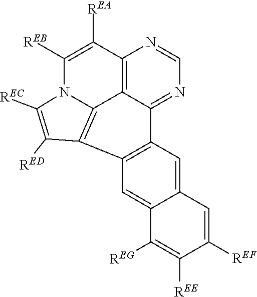 |
| L_{A161}(R^{EA})(R^{EB})(R^{EC})(R^{ED}) (R^{EE})(R^{EF})(R^{EG}), wherein L_{A161}(R₁)(R₁)(R₁)(R₁)(R₁) (R₁₎(R₁) to L_{A161}(R₂₁₁)(R₂₁₁)(R₂₁₁)(R₂₁₁) (R₂₁₁)(R₂₁₁)(R₂₁₁) have the structure | 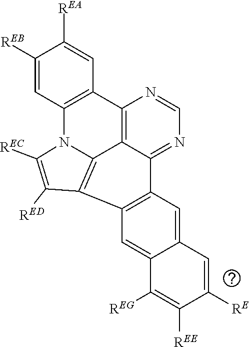 |

wherein R₁ to R₂₁₁ have the following structures:

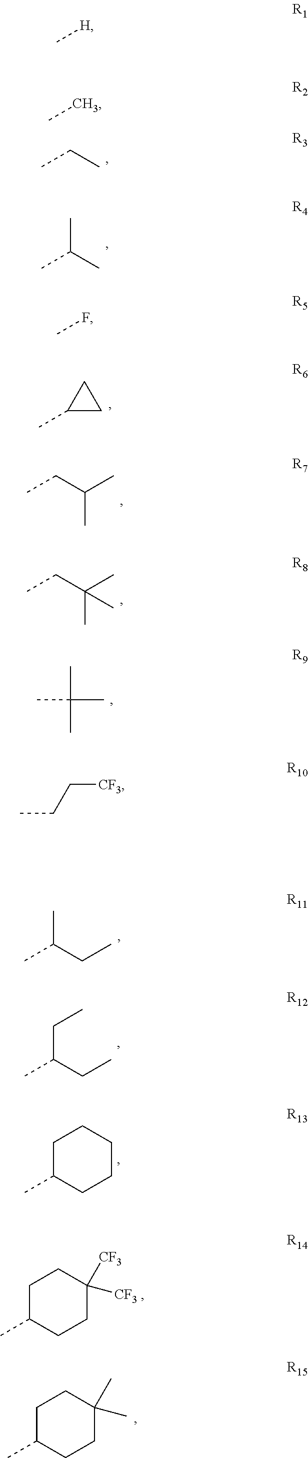

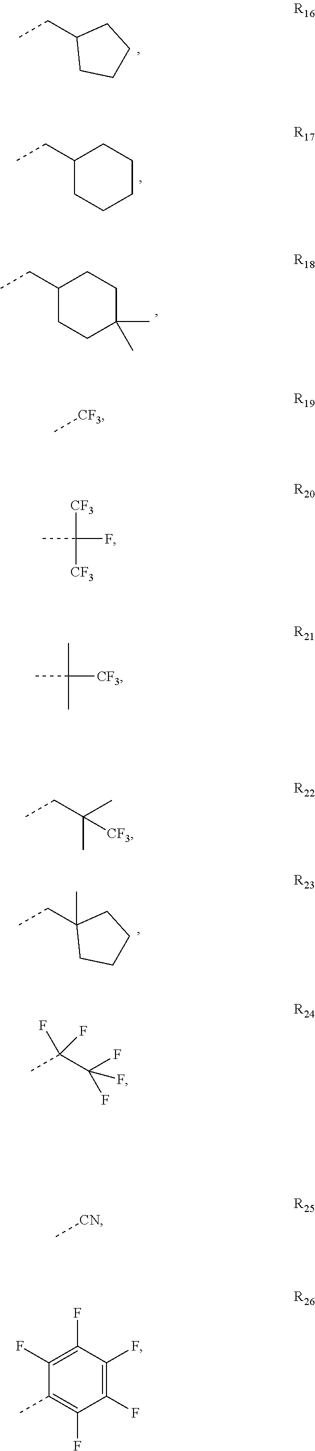

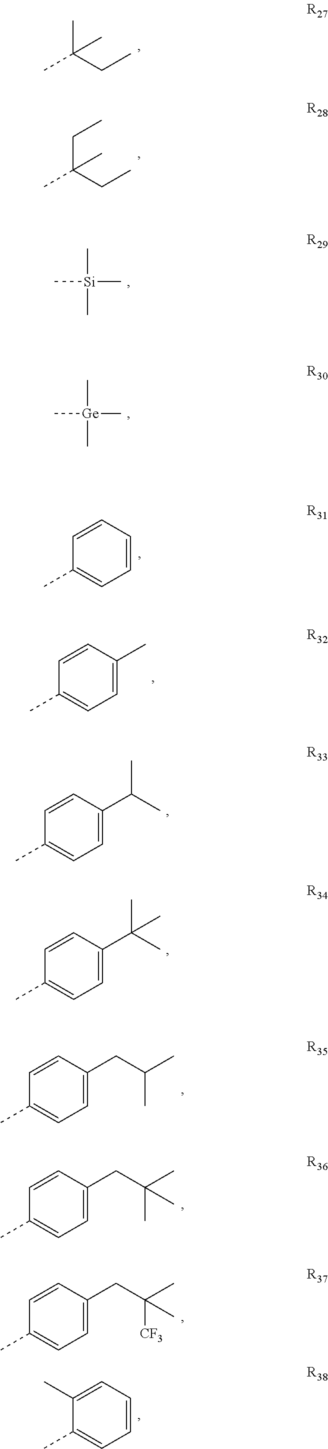

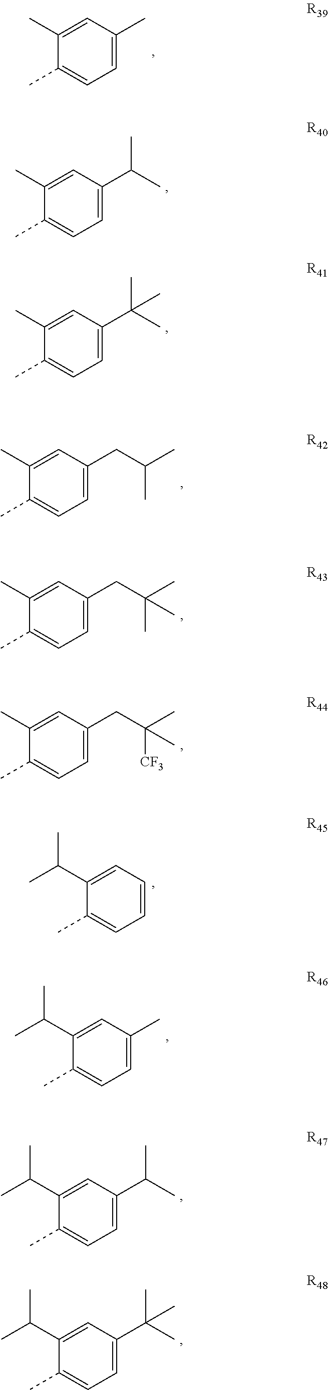

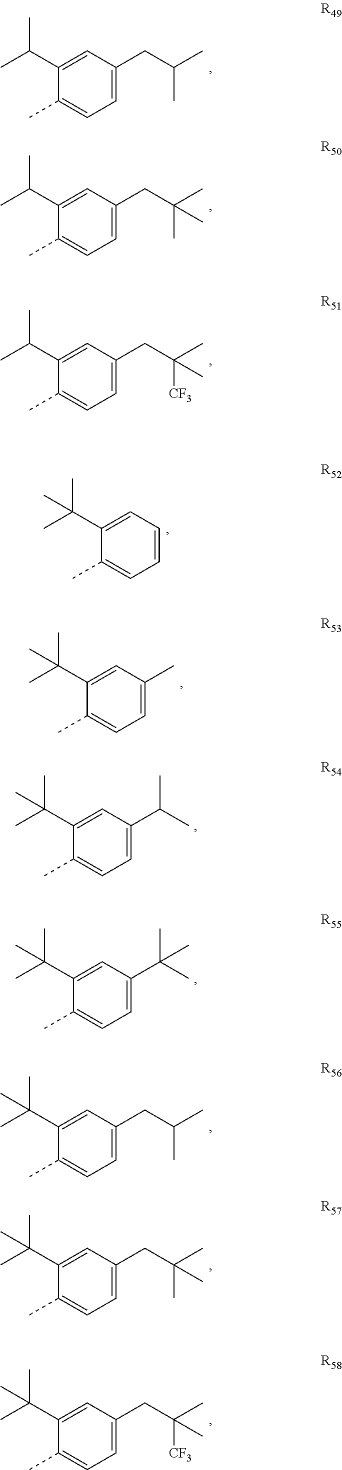

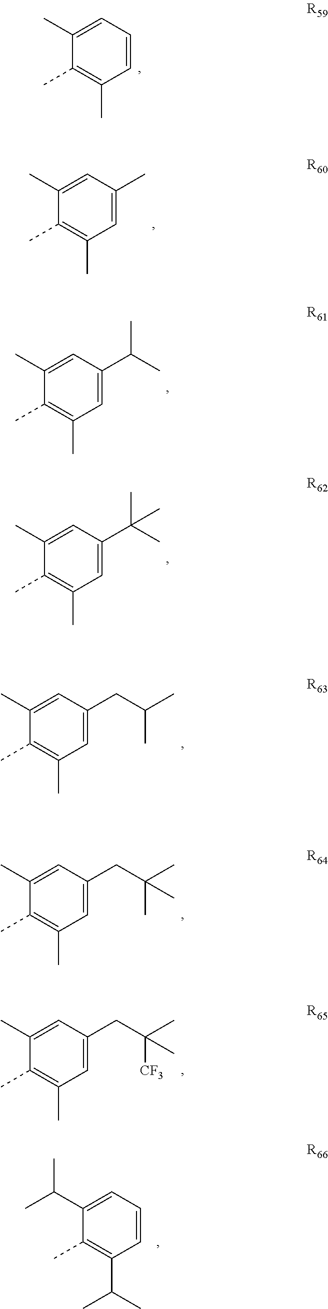

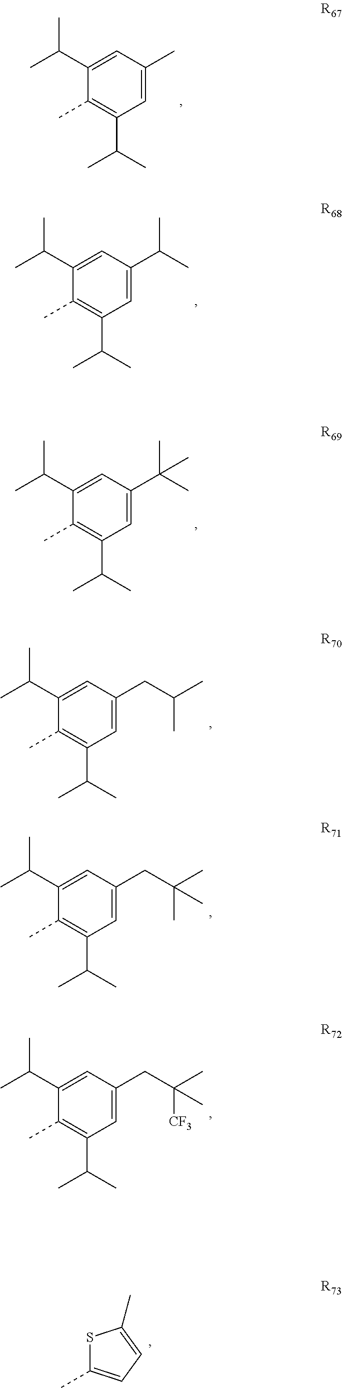

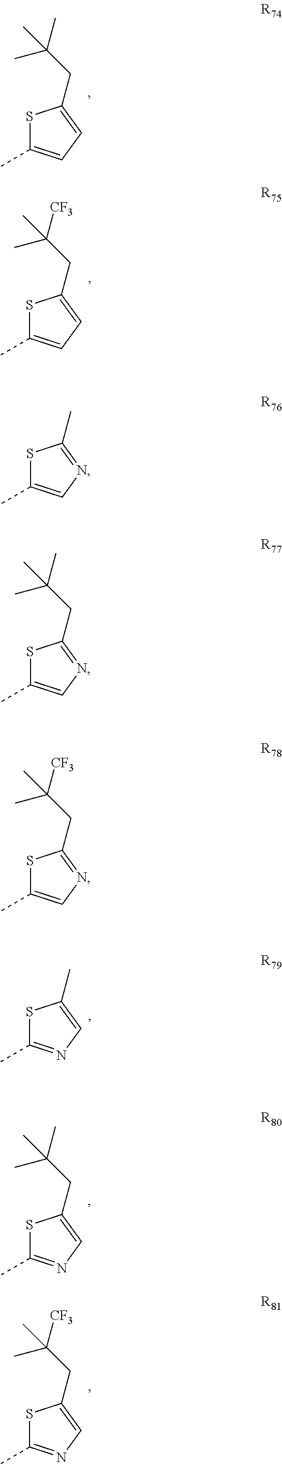

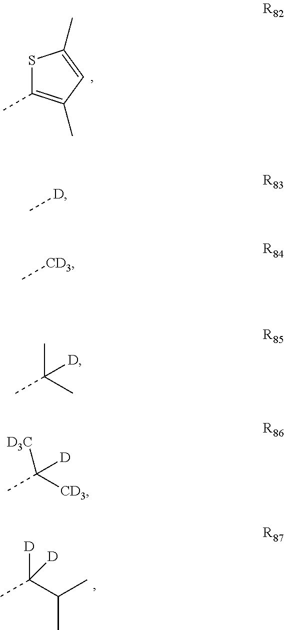

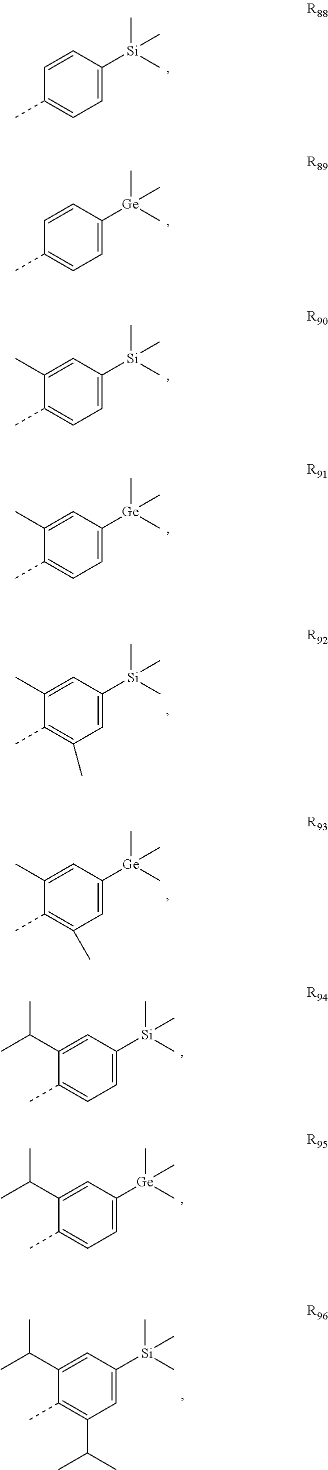

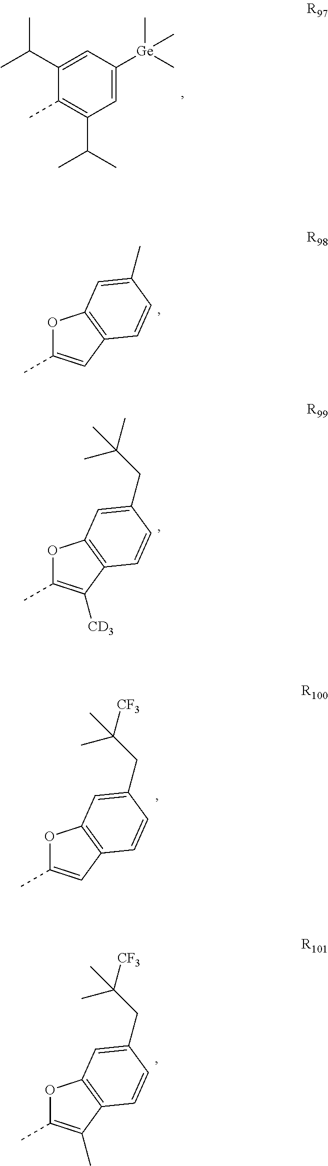

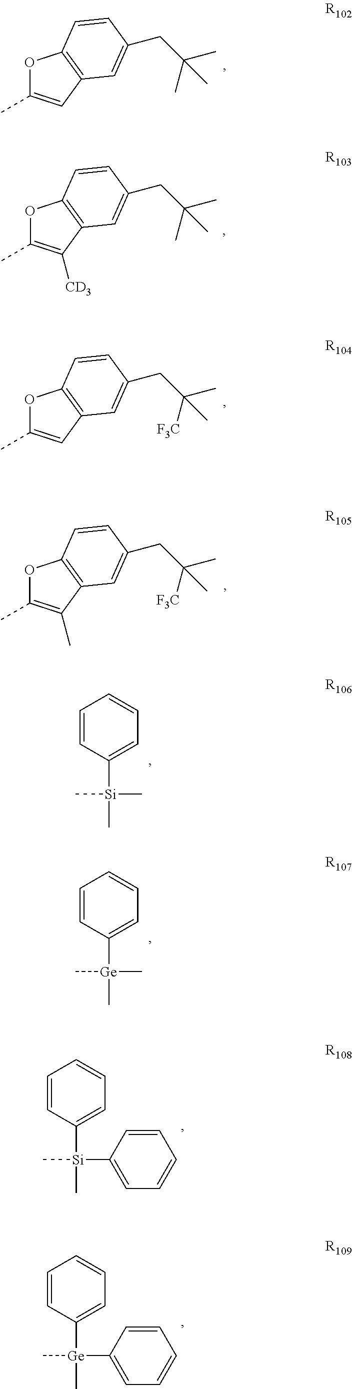

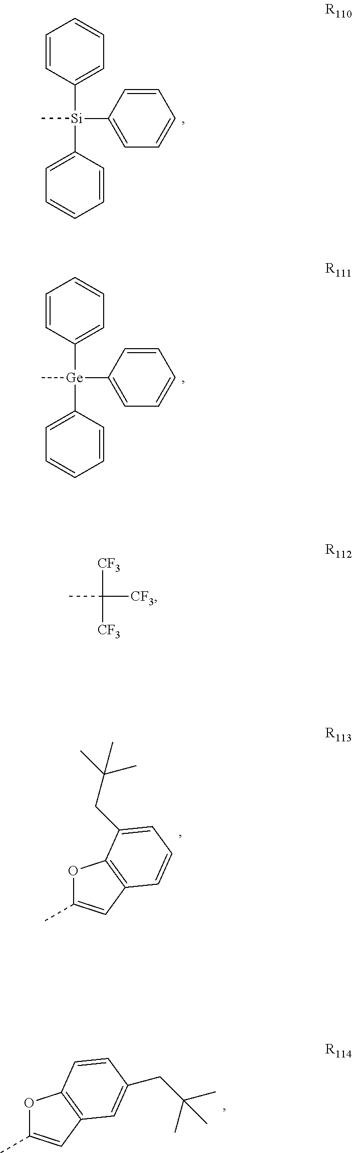

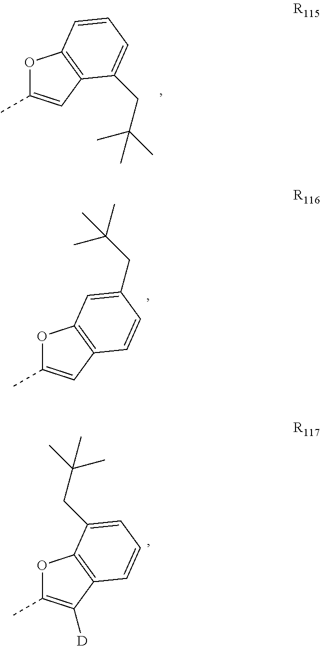

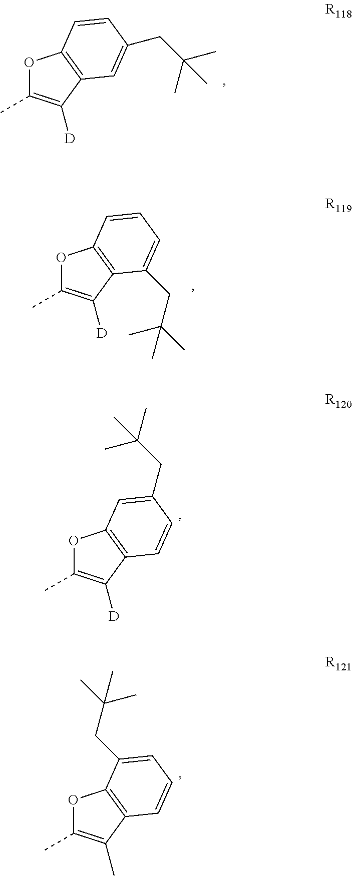

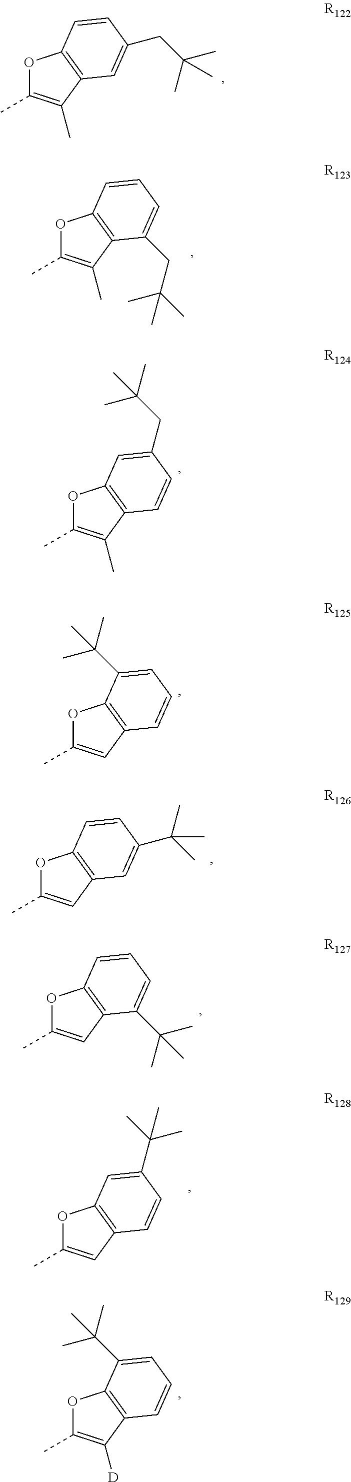

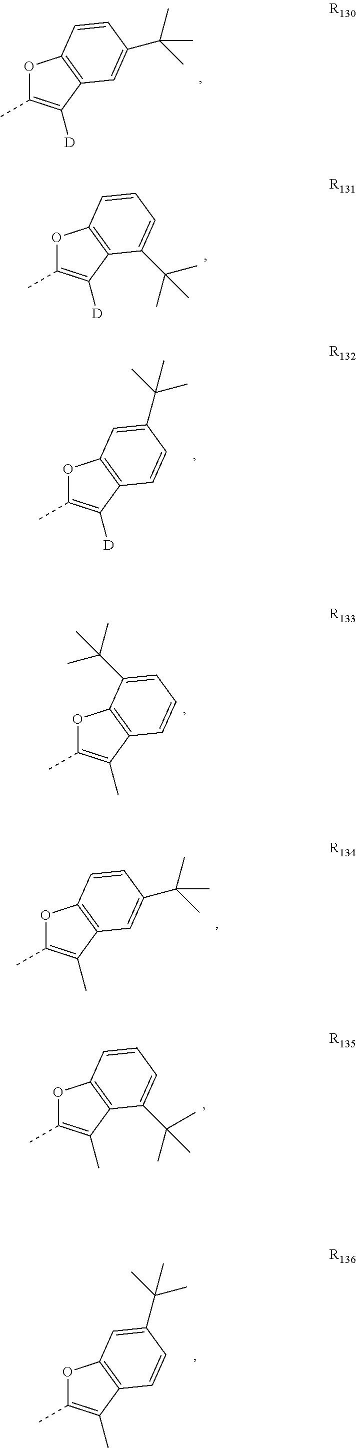

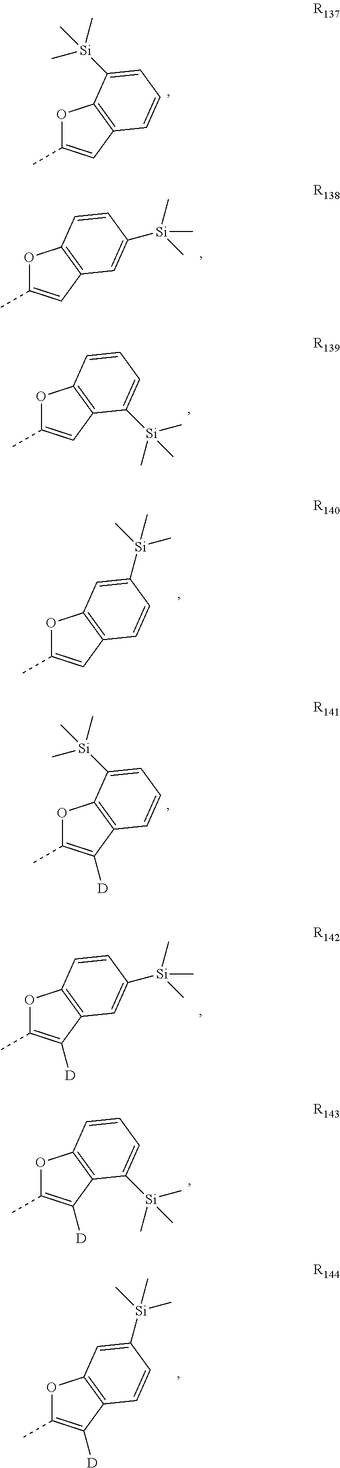

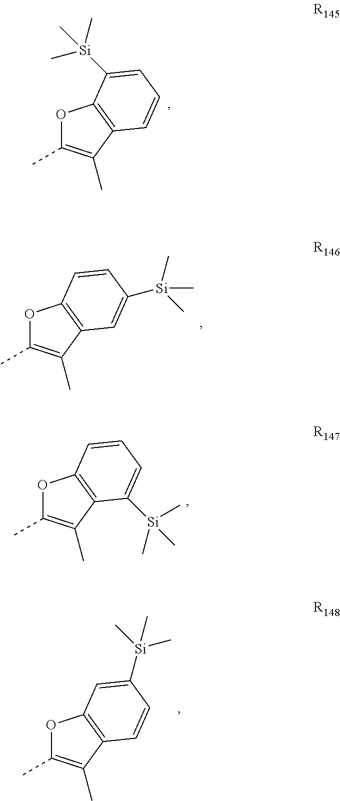

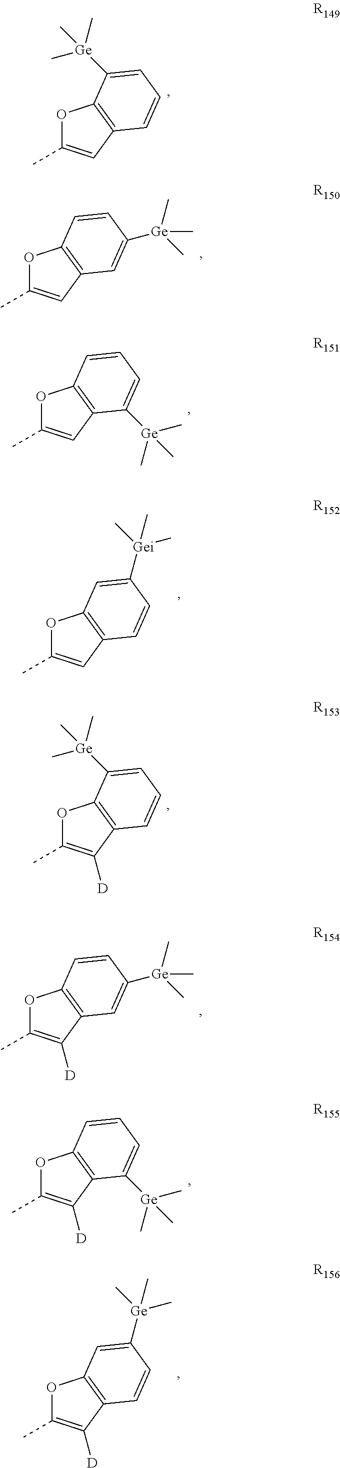

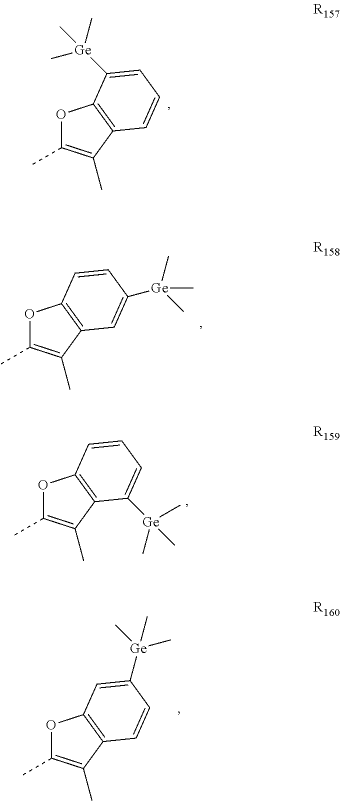

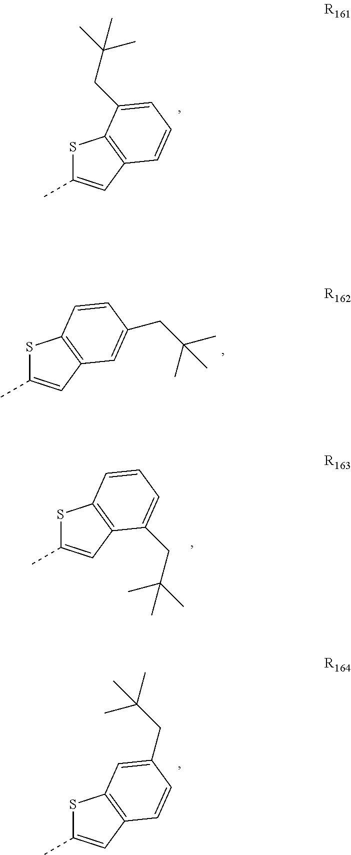

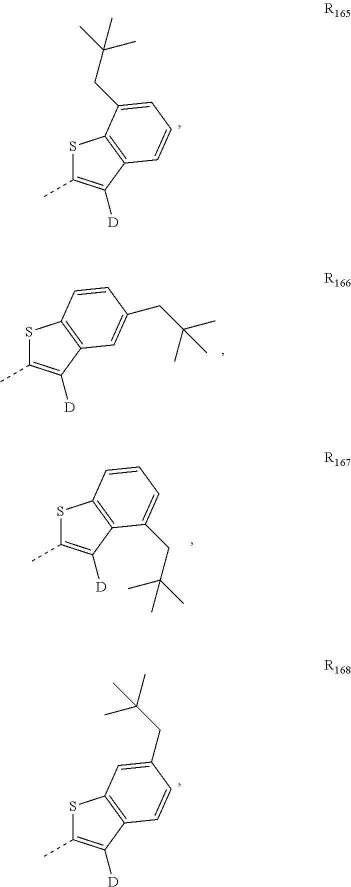

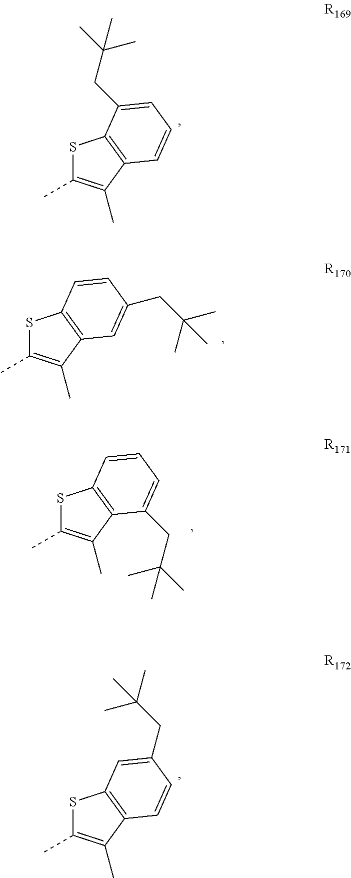

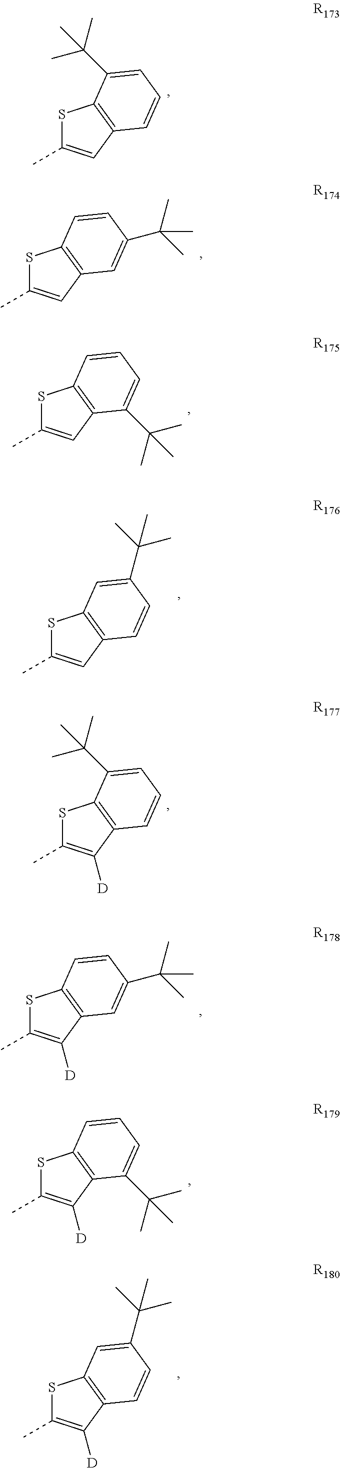

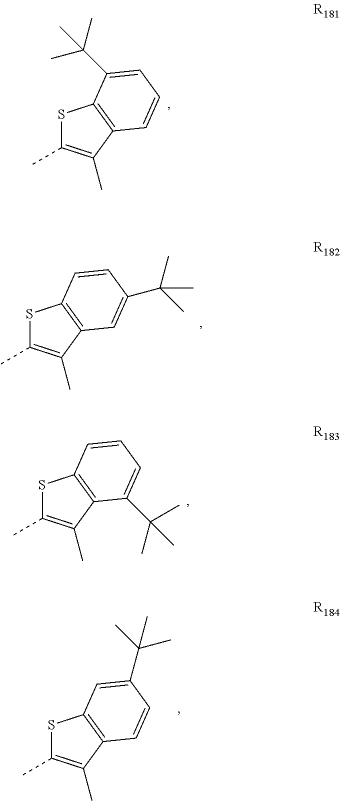

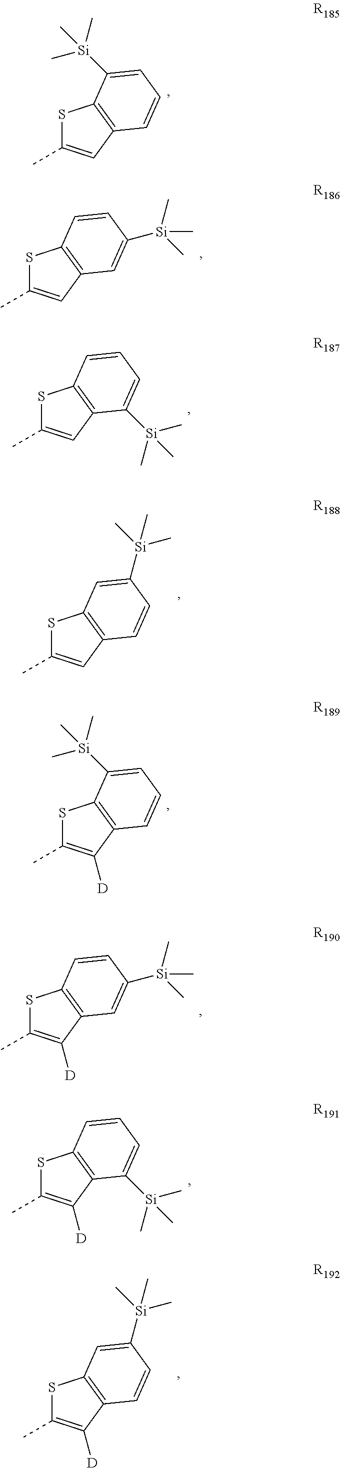

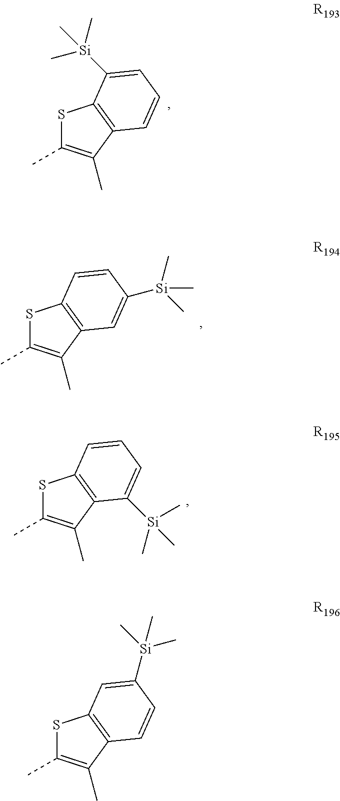

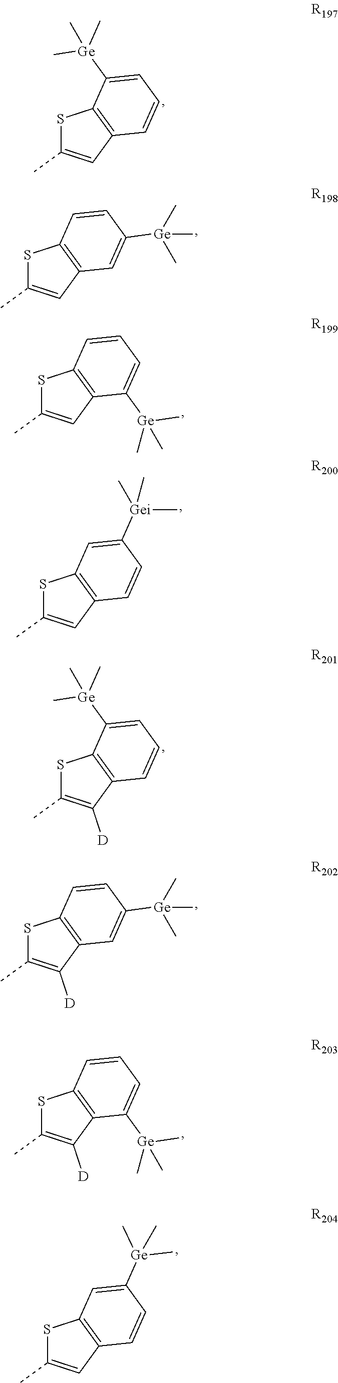

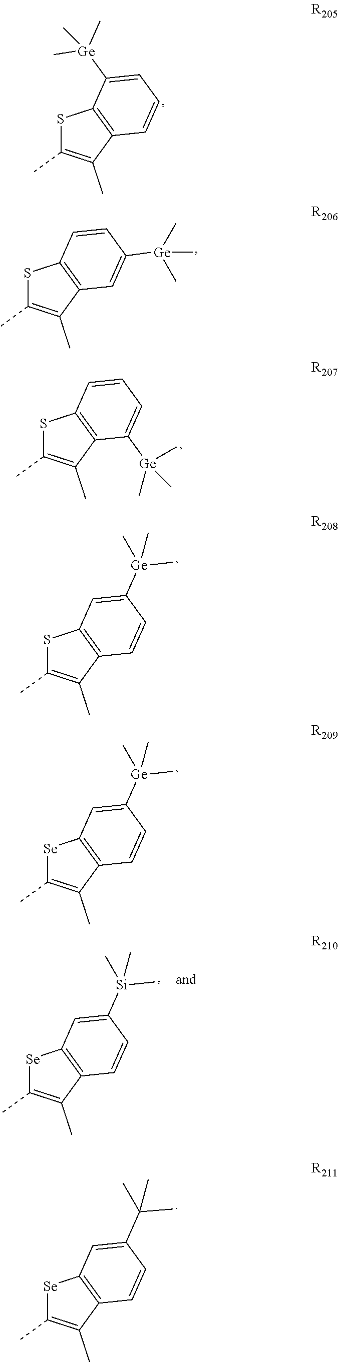

10. The compound of claim 1, wherein the compound has a formula of M(L_{A})ₚ(L_{B})_{q}(L_{C})ᵣ, wherein L_{B} and L_{C} are each a bidentate ligand; and
wherein p is 1, 2, or 3; q is 0, 1, or 2; r is 0, 1, or 2; and p+q+r is the oxidation state of the metal M.

11. The compound of claim 10, wherein the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other; or a formula of Pt(L_{A})(L_{B}); and wherein L_{A} and L_{B} can be same or different.

12. The compound of claim 10, wherein L_{B} and L_{C} are each independently selected from the group consisting of: 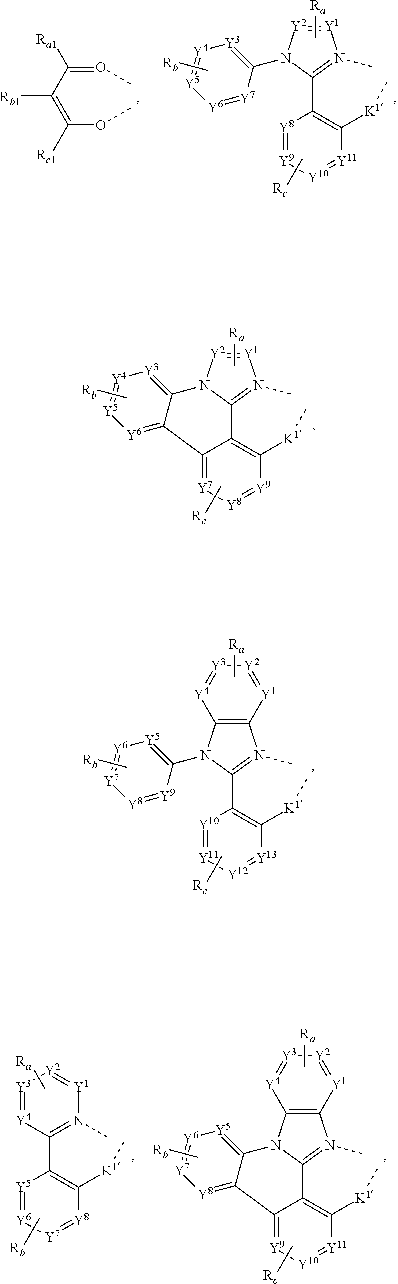 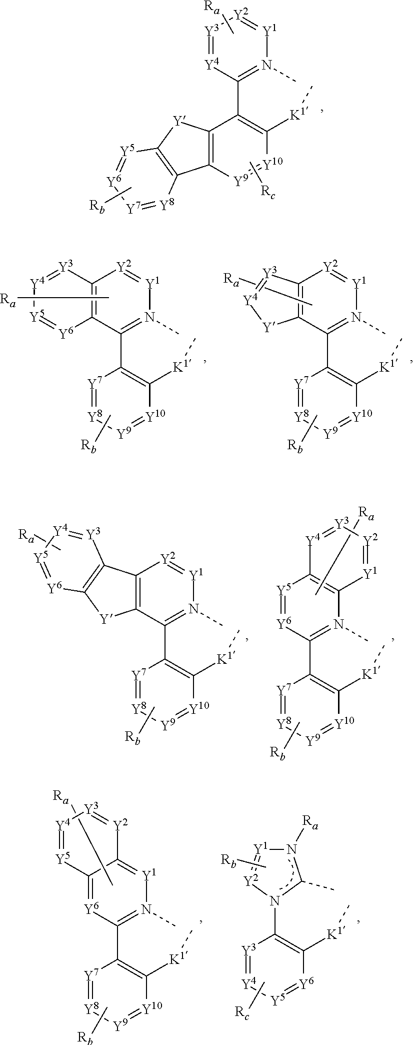 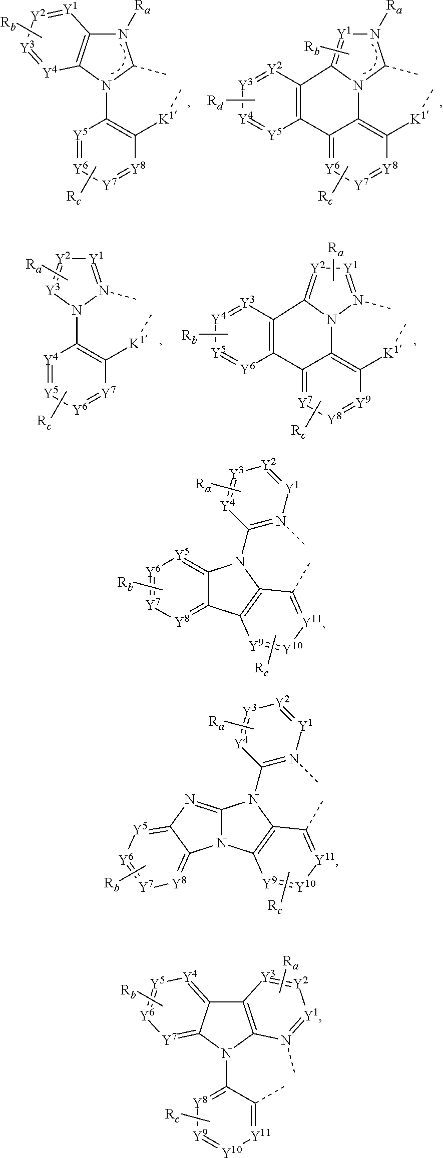 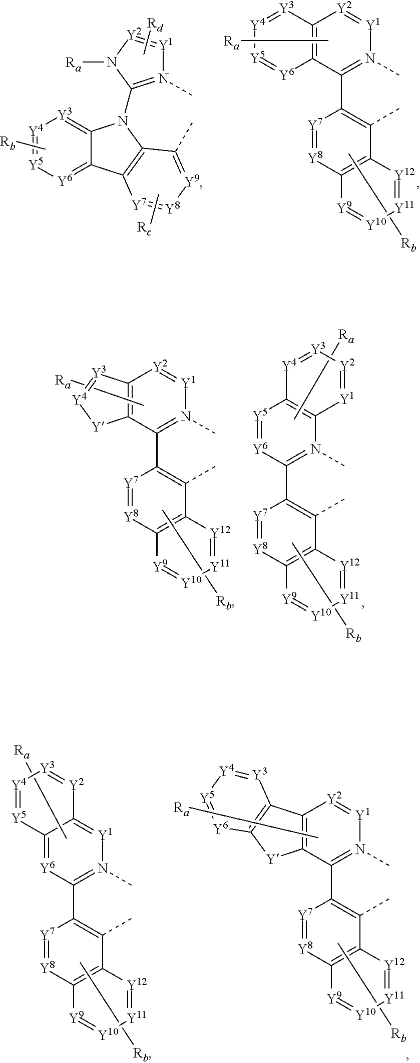 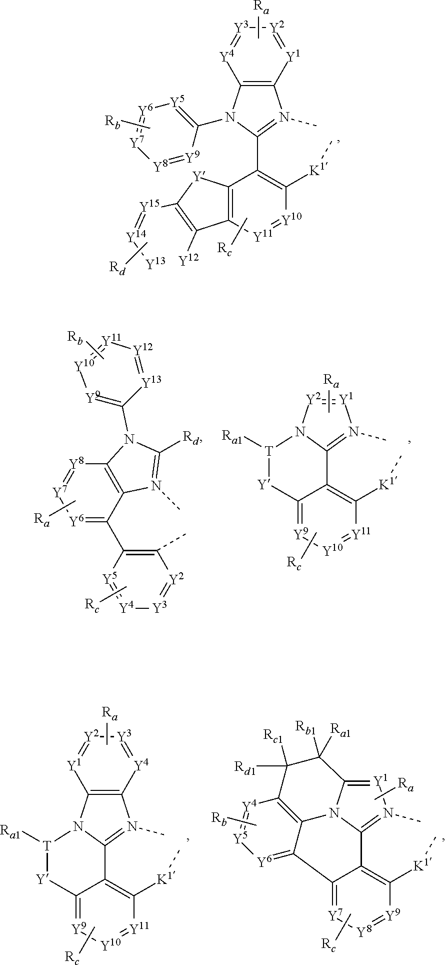 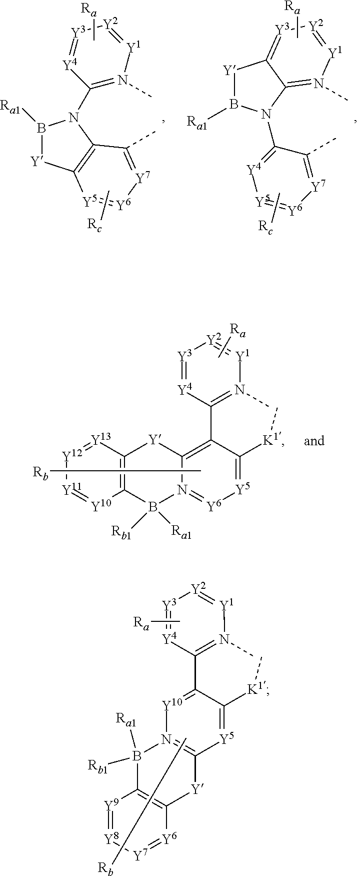
wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

13. The compound of claim 9 wherein the compound has formula Ir(L_{A})₃, formula Ir(L_{A})(L_{Bk})₂, formula Ir(L_{A})₂(L_{Bk}), formula Ir(L_{A})₂(L_{Cj-I}), or formula Ir(L_{A})₂(L_{Cj-II}),
wherein k is an integer from 1 to 522, and each L_{Bk} has the structure defined as follows: 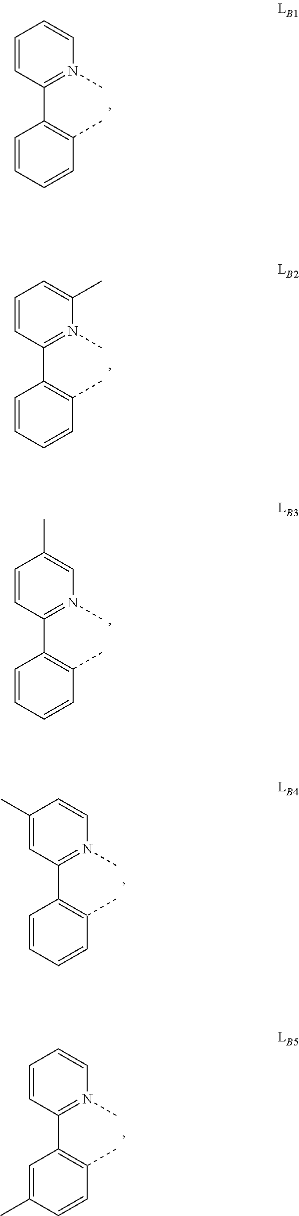 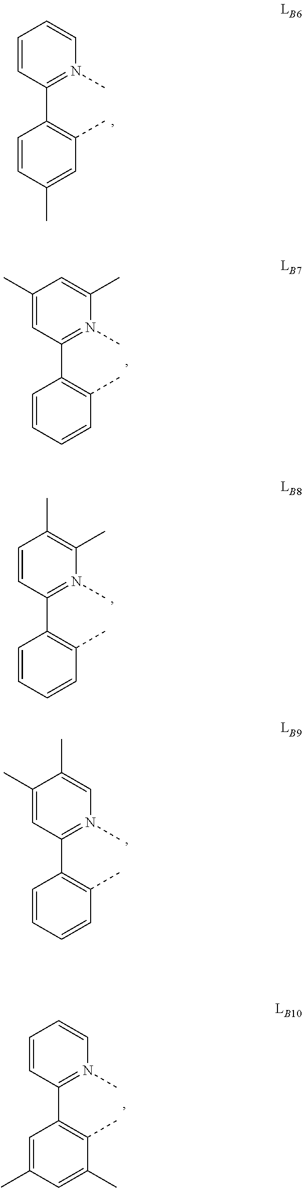 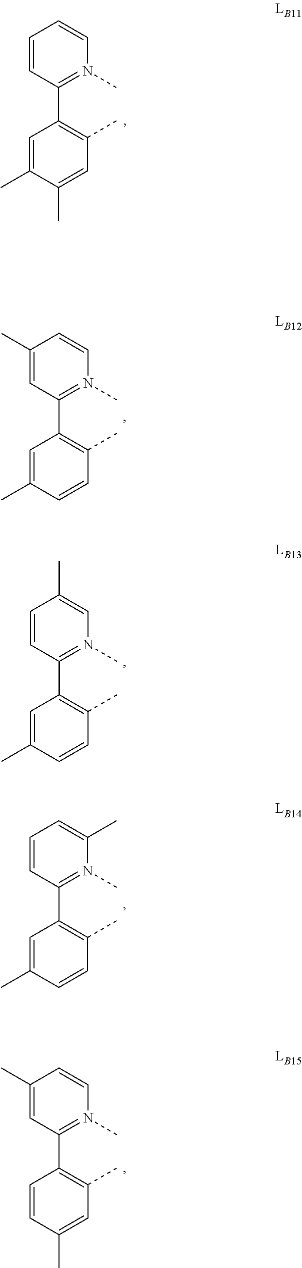 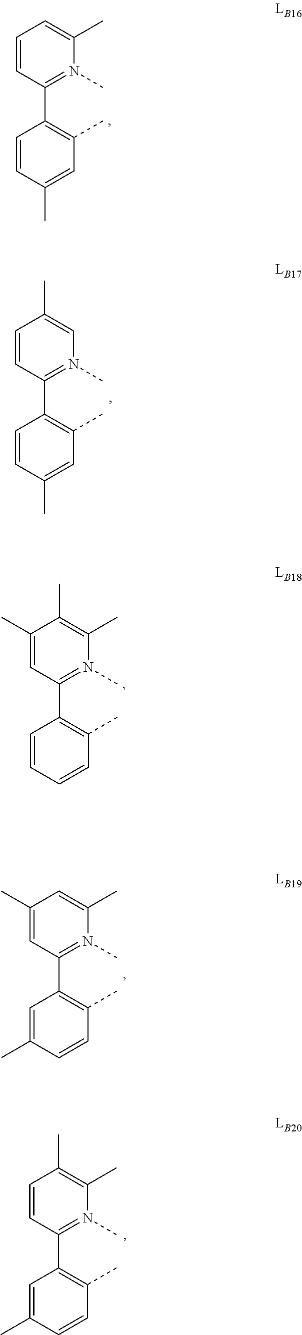 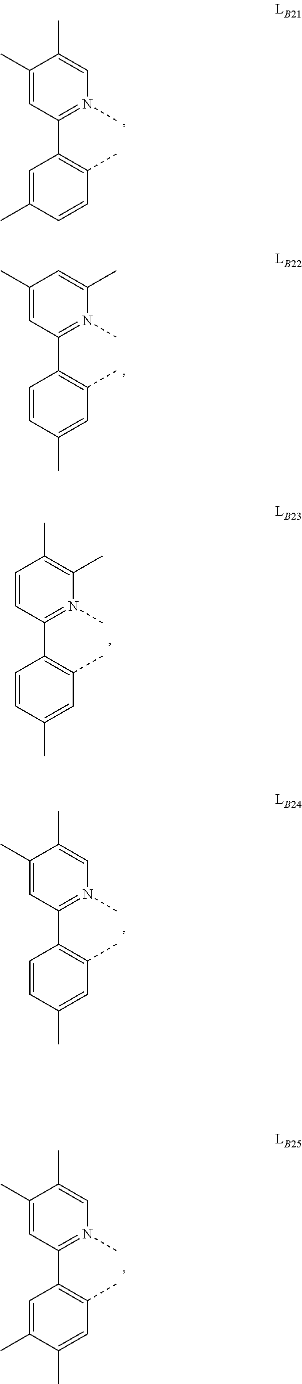 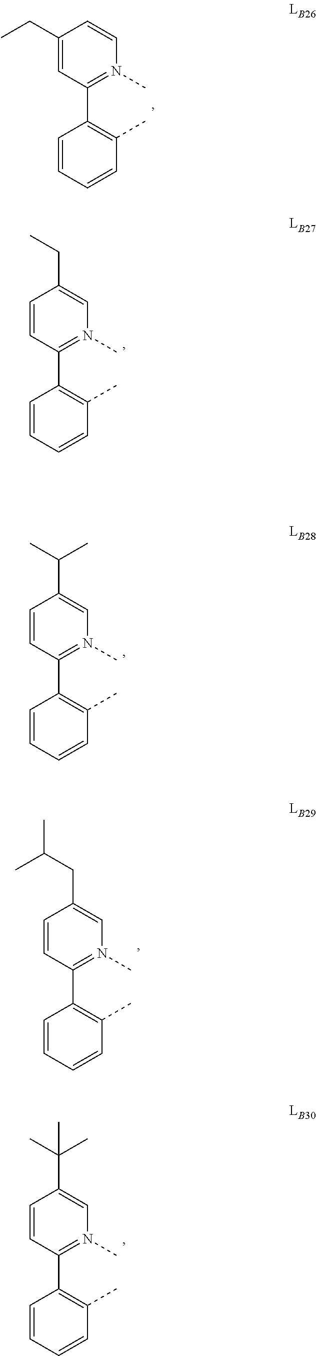 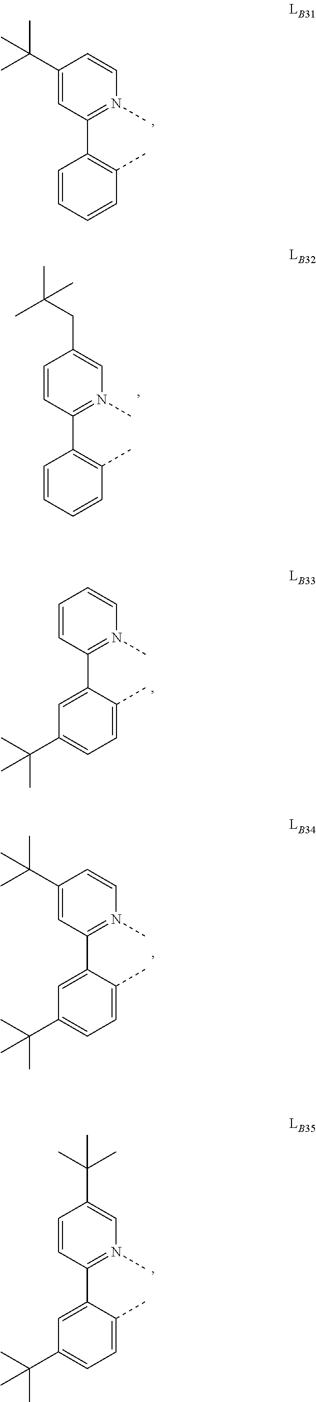 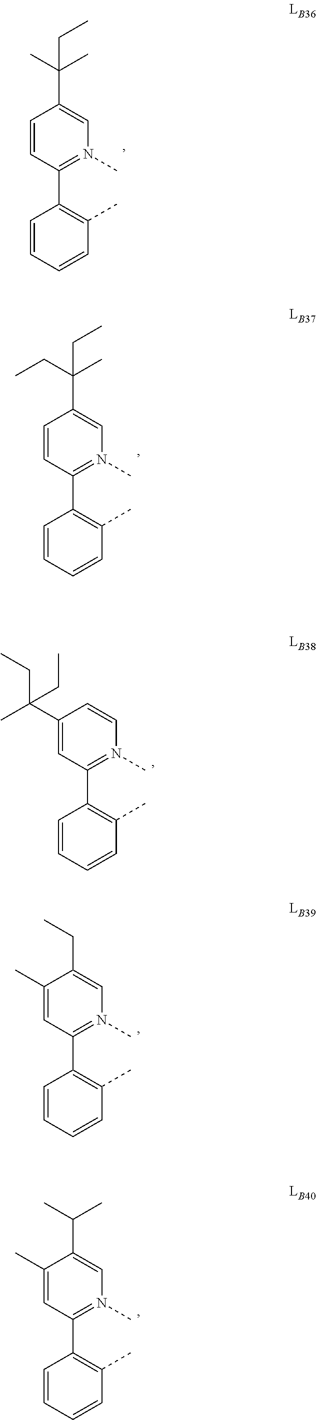 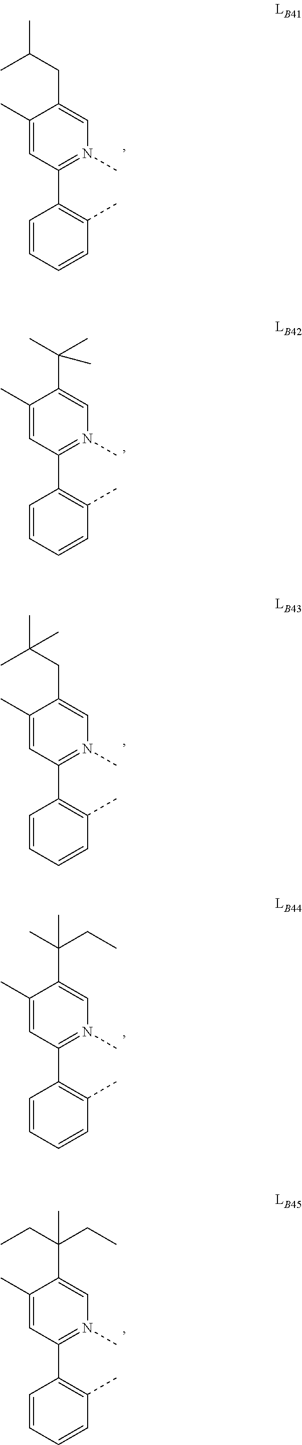 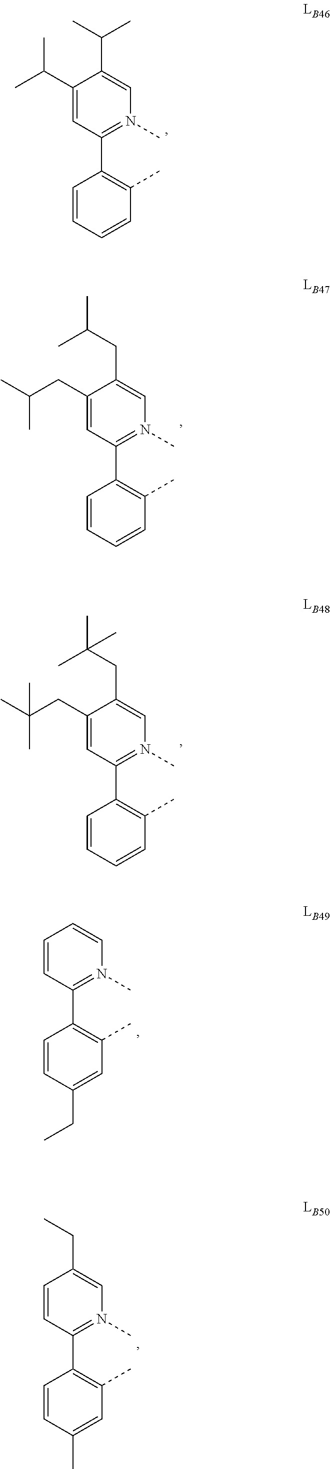 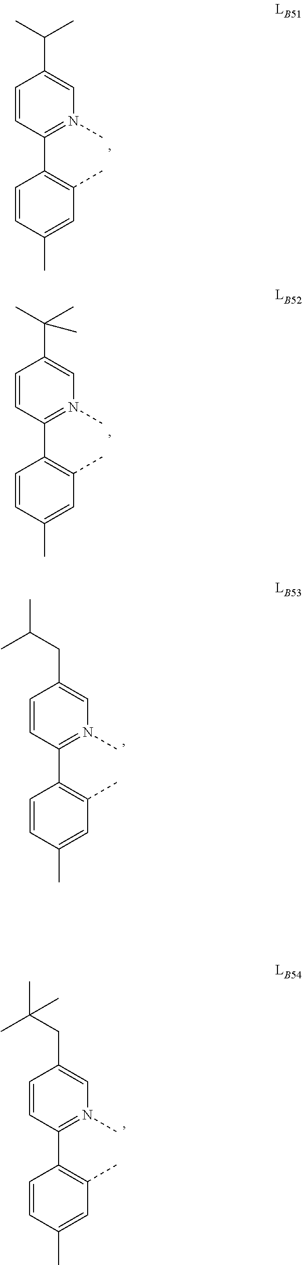 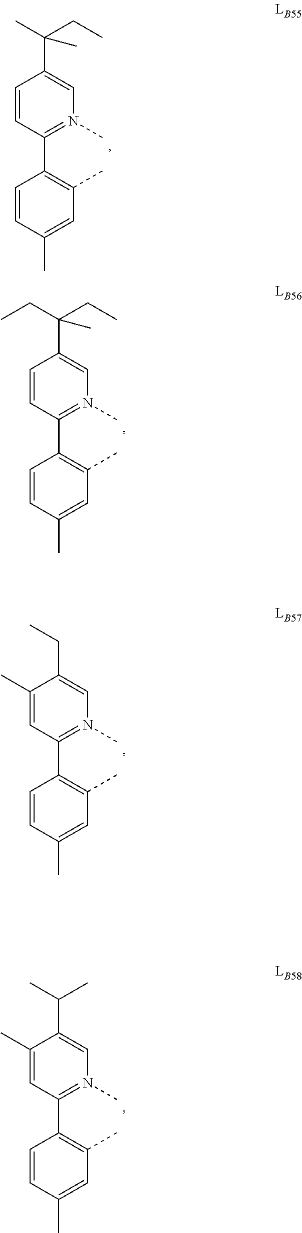 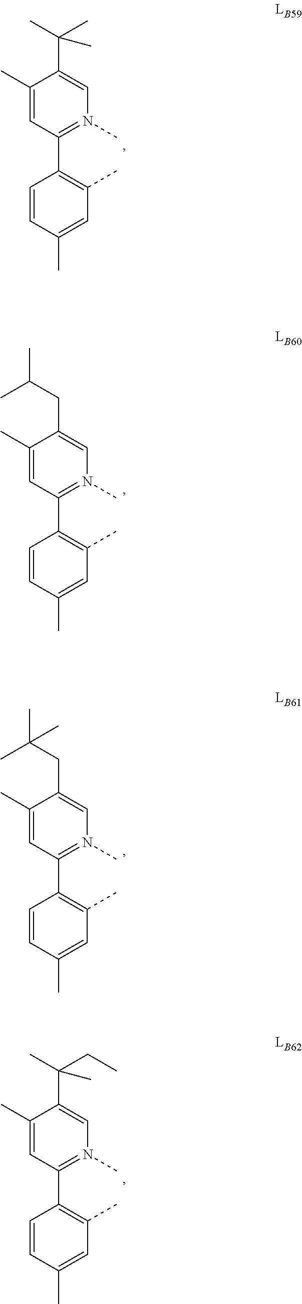 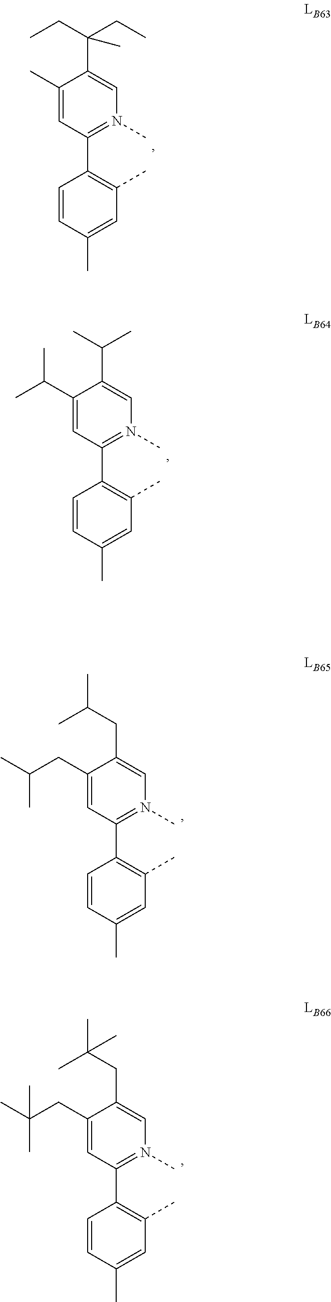 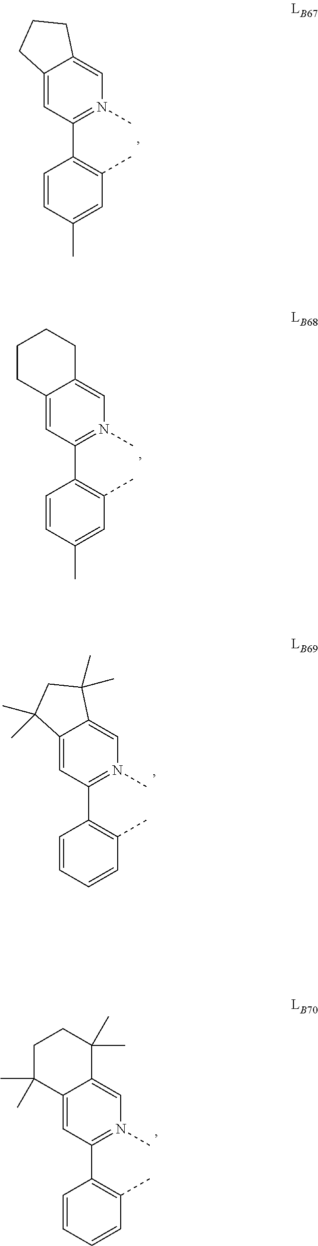 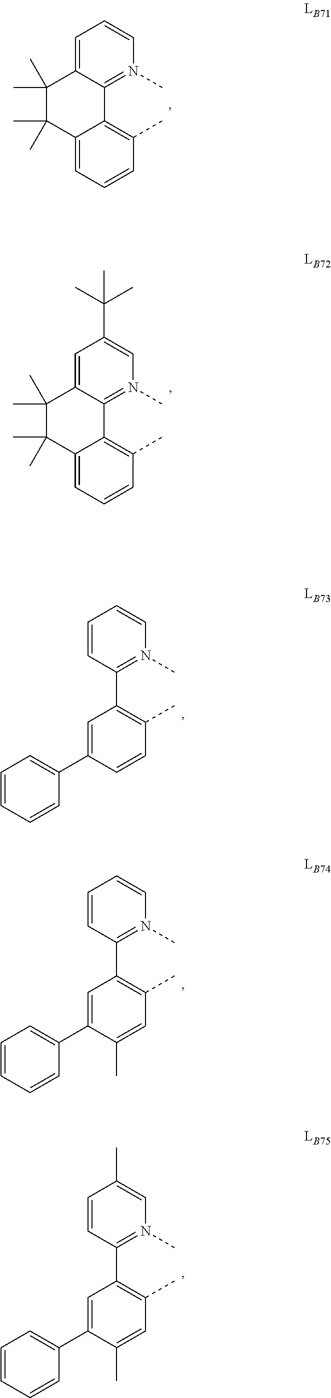 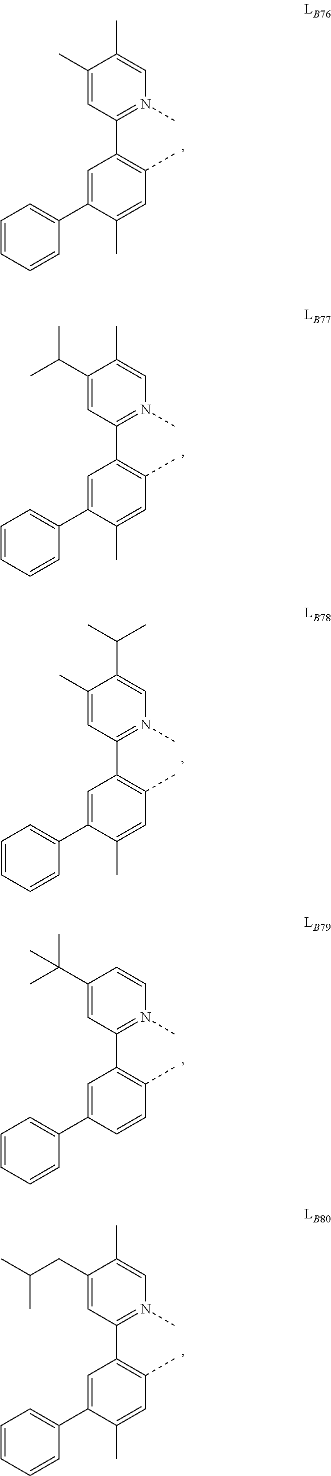 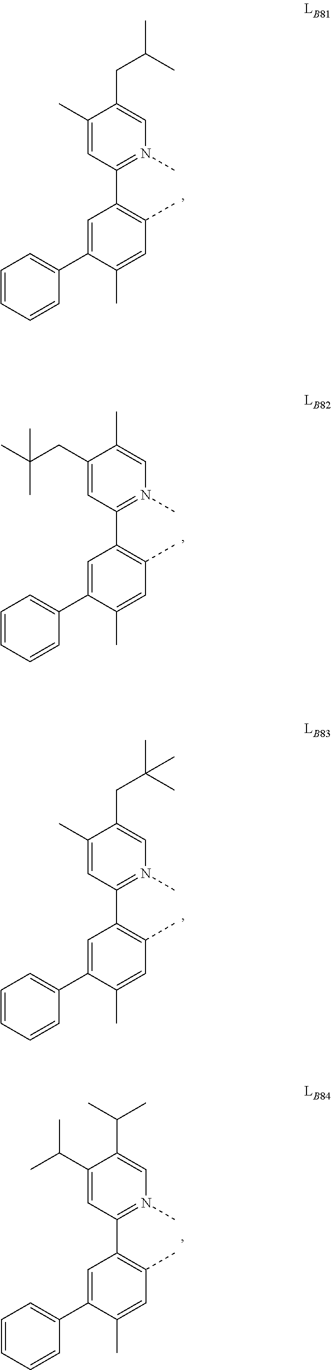 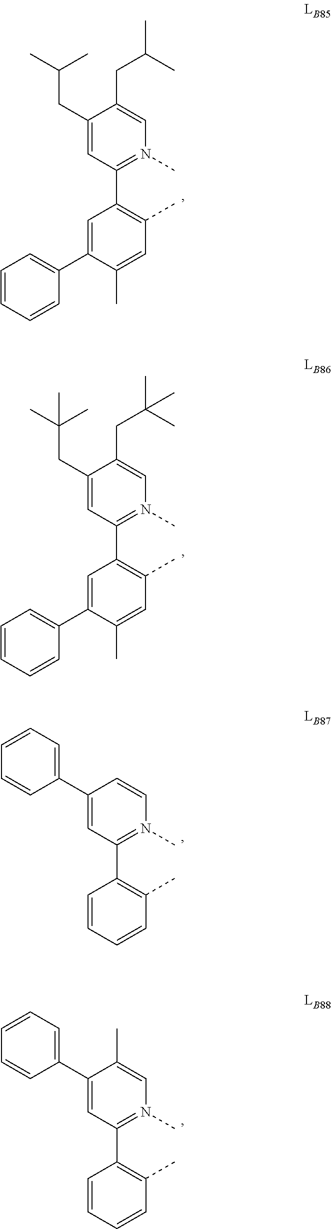 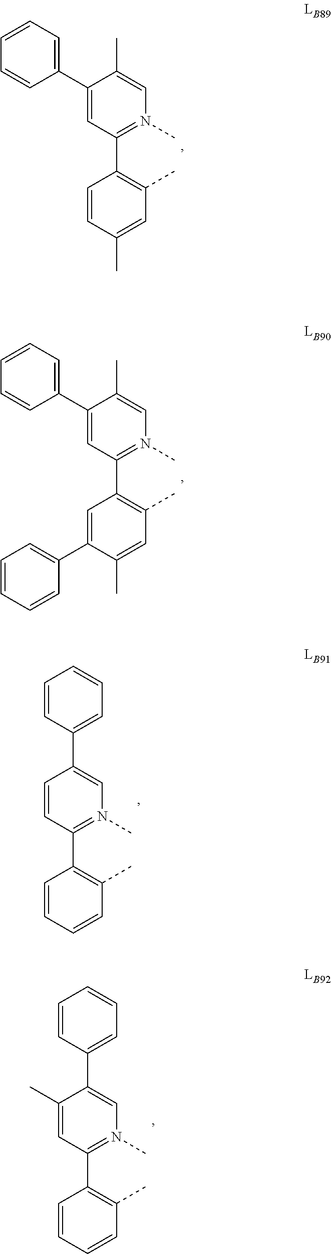 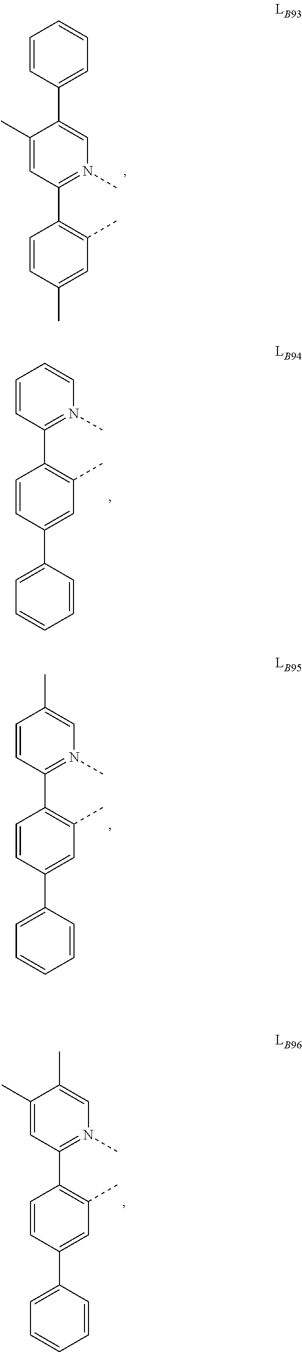 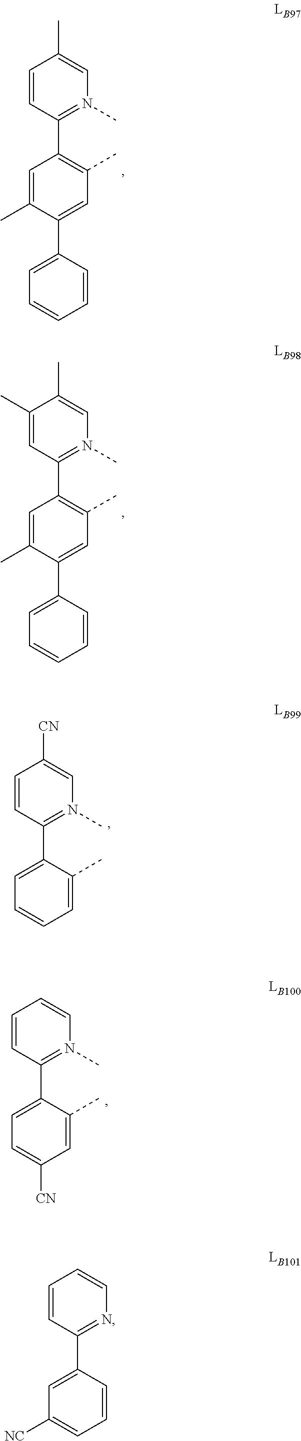 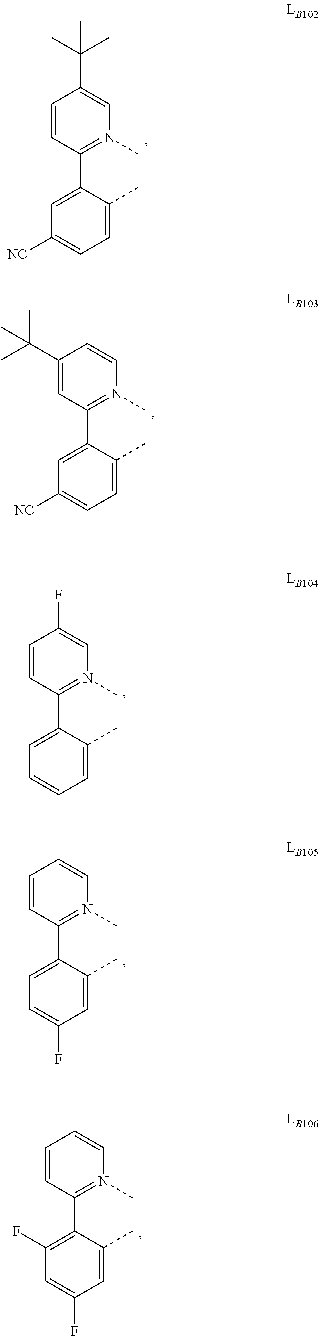 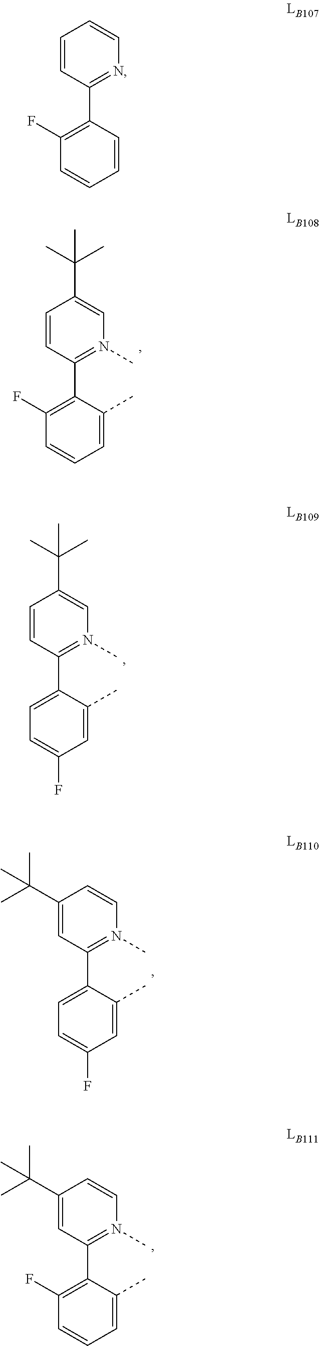 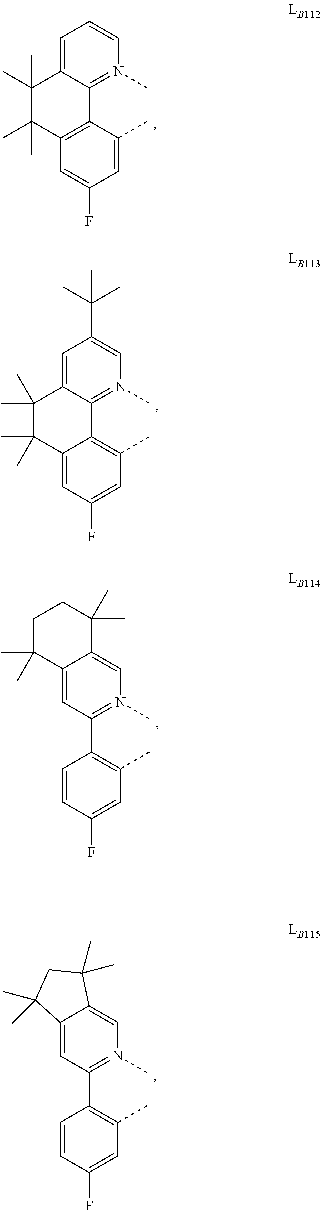 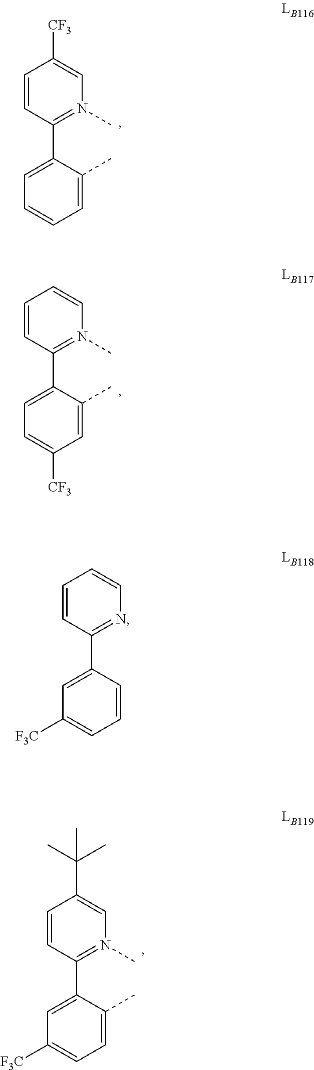 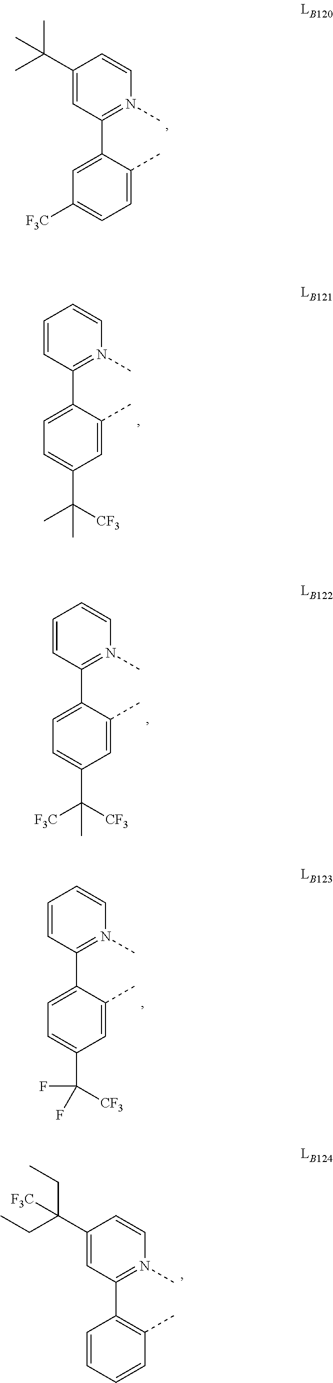 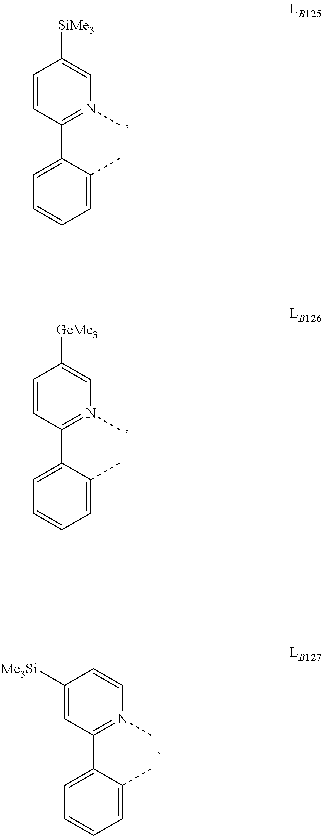 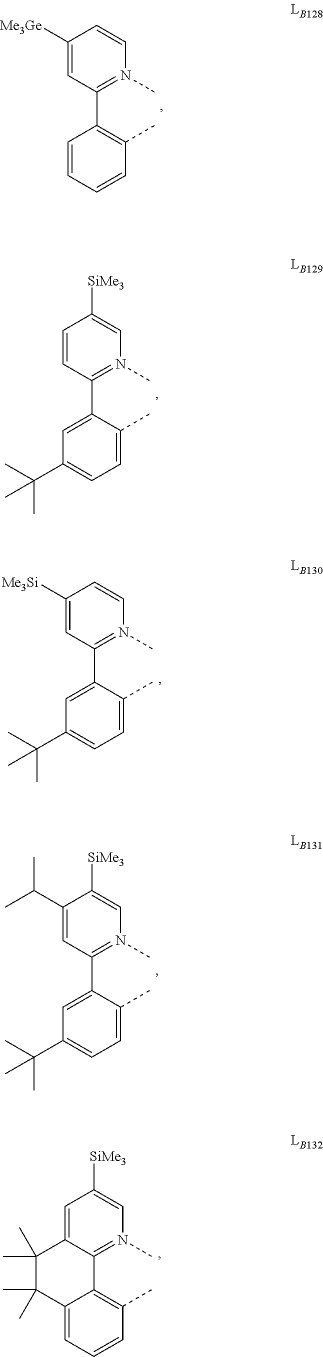 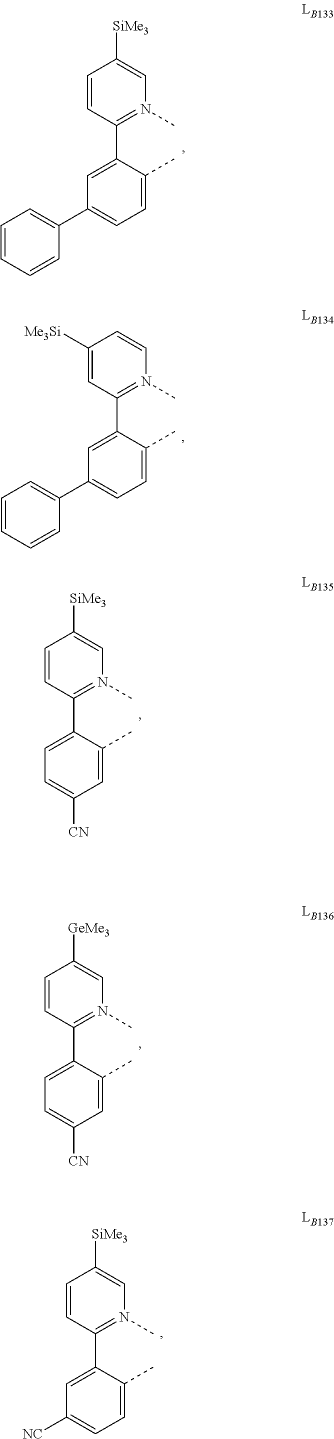 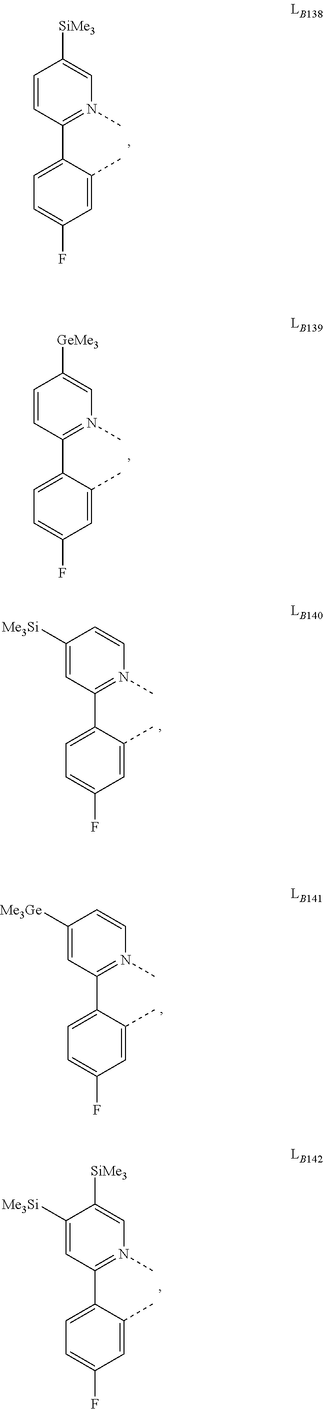 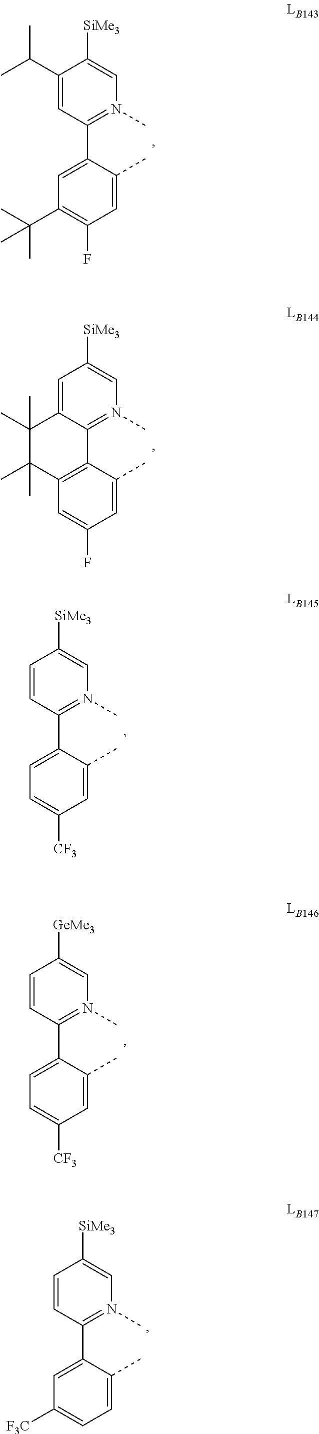 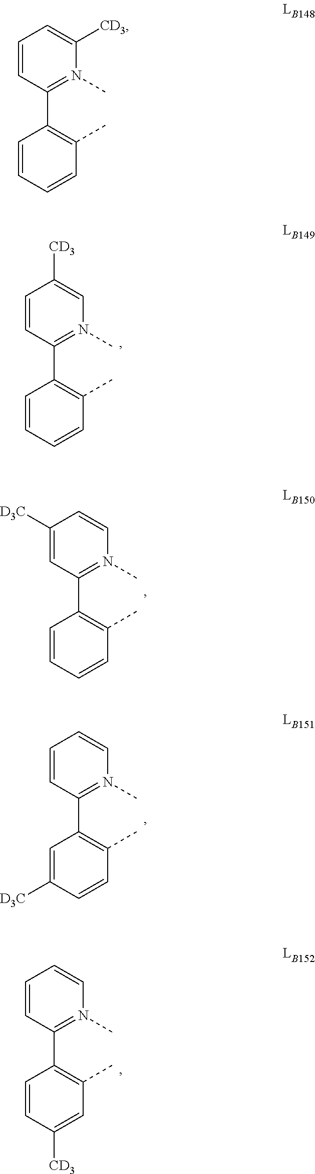 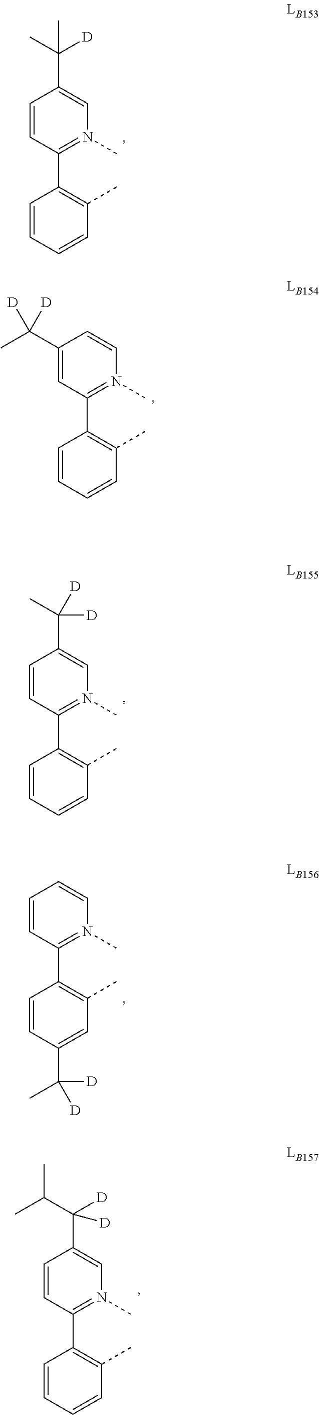 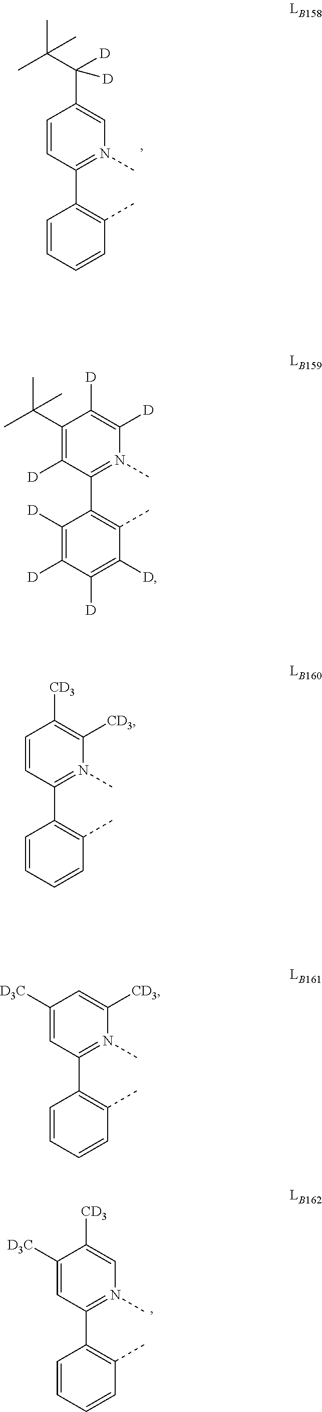 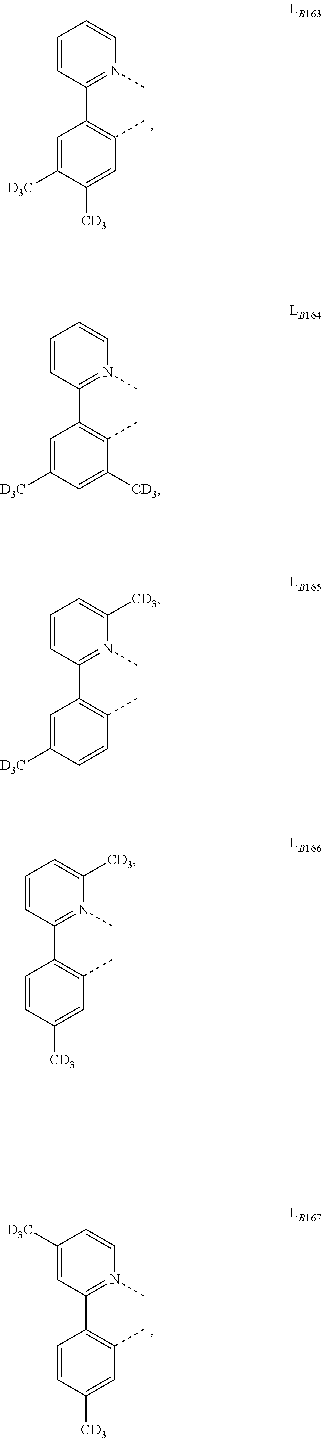 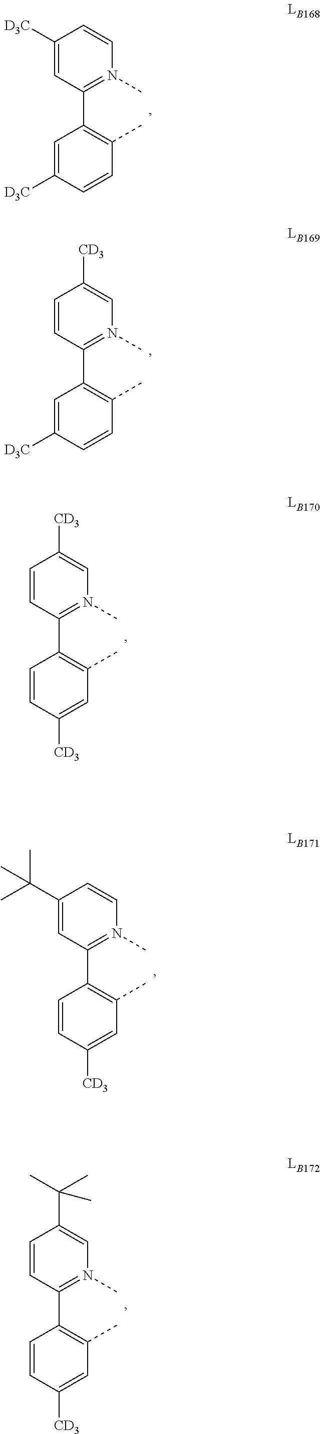 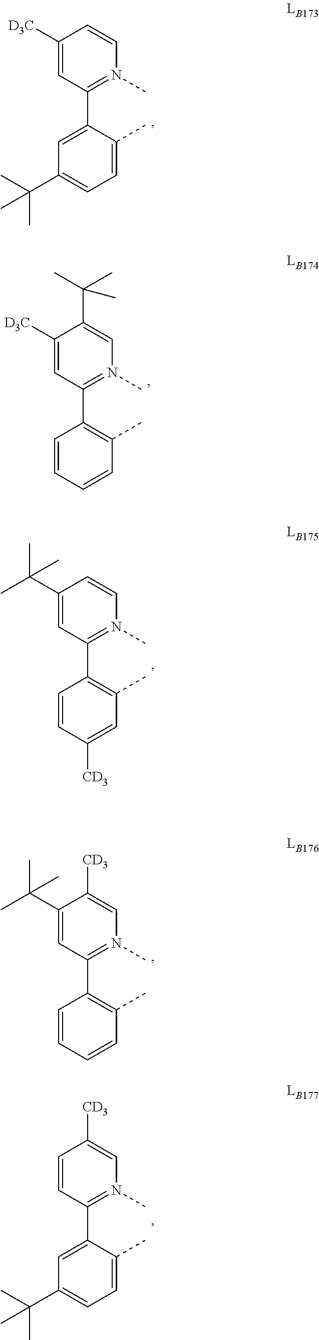 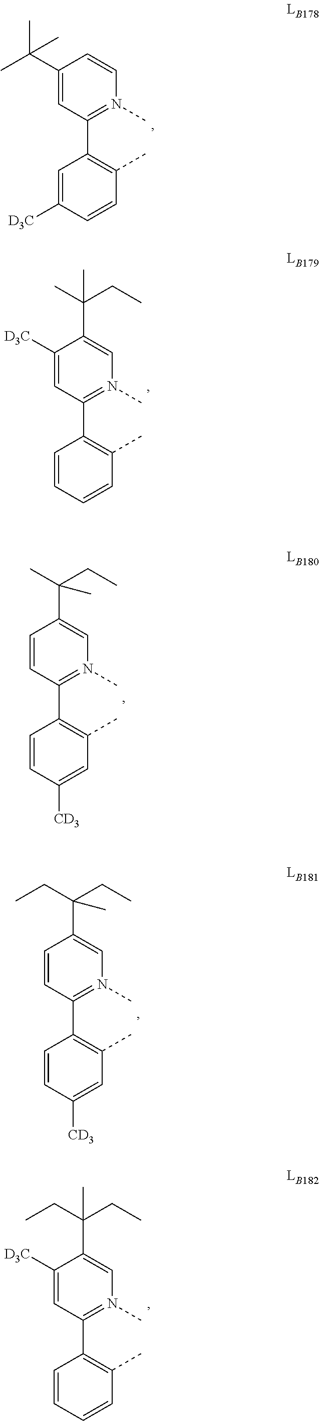 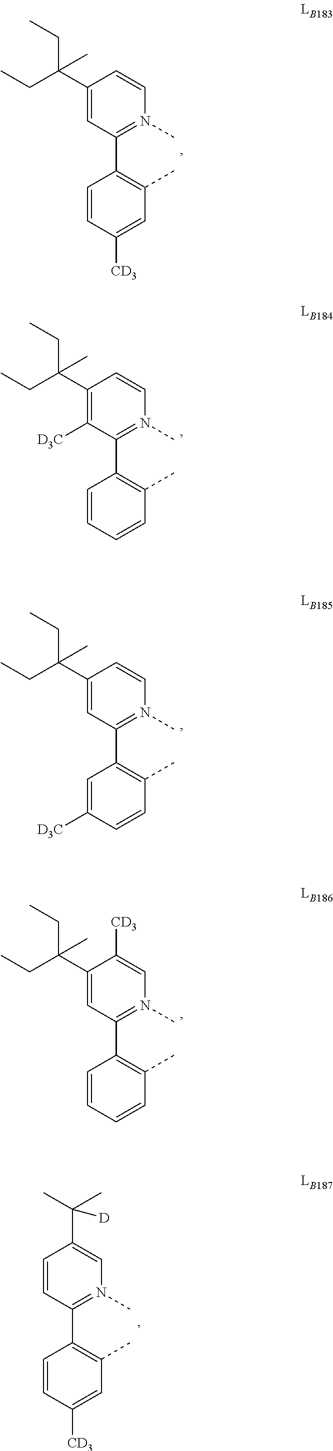 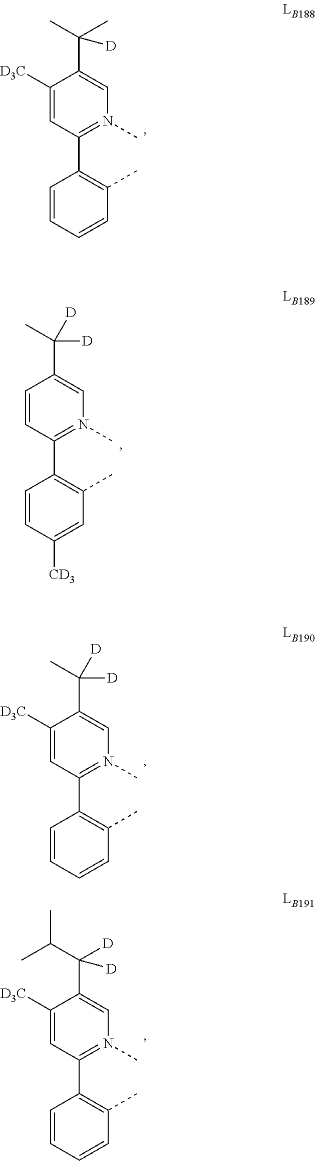 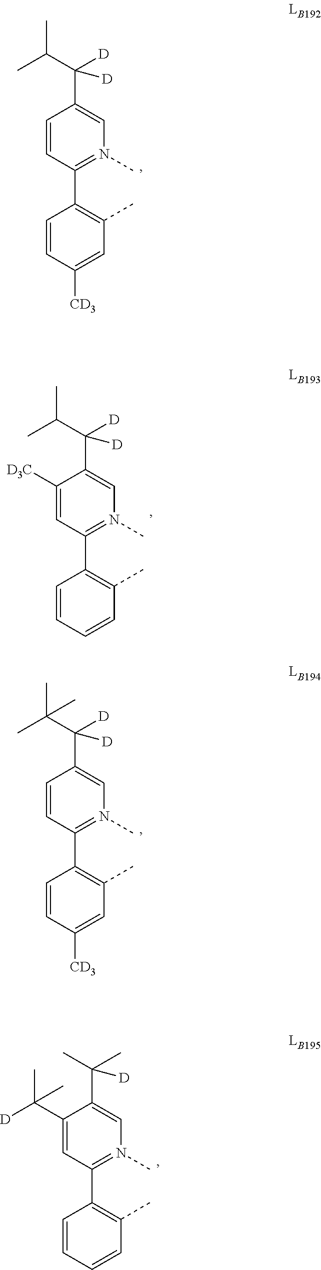 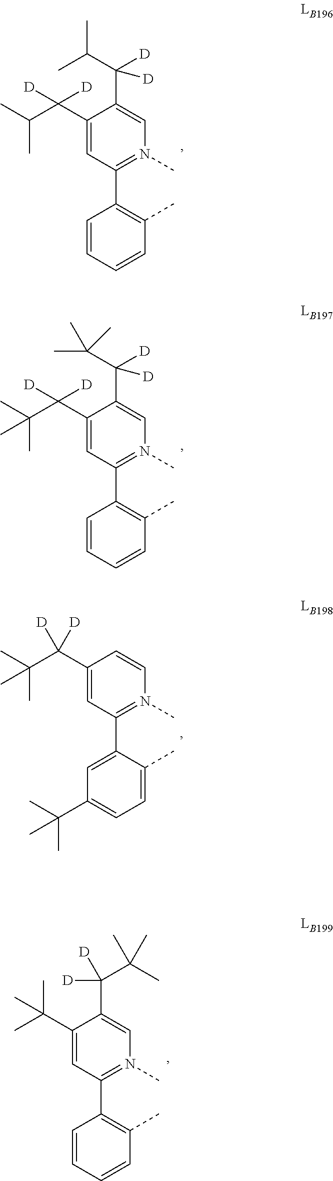 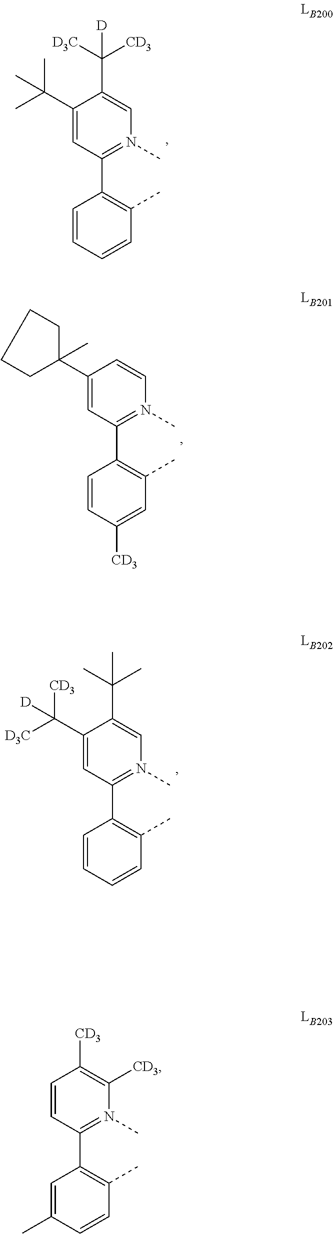 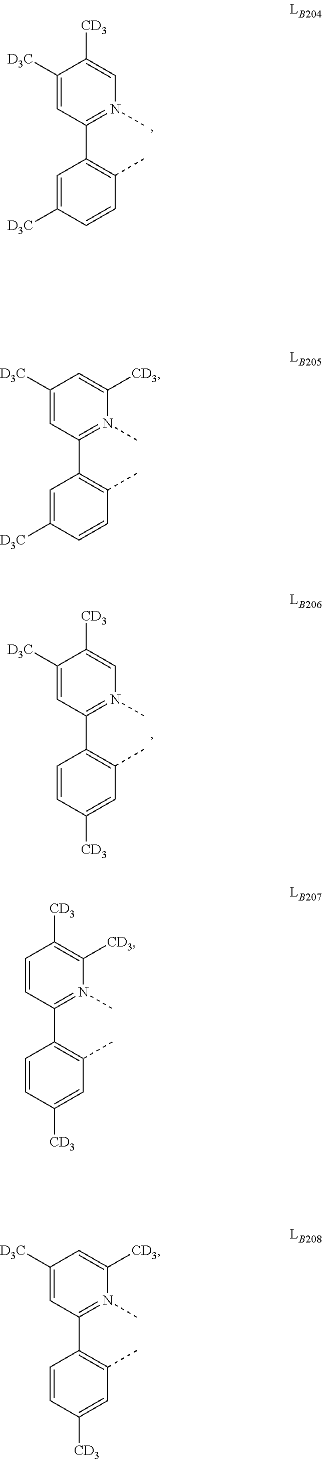 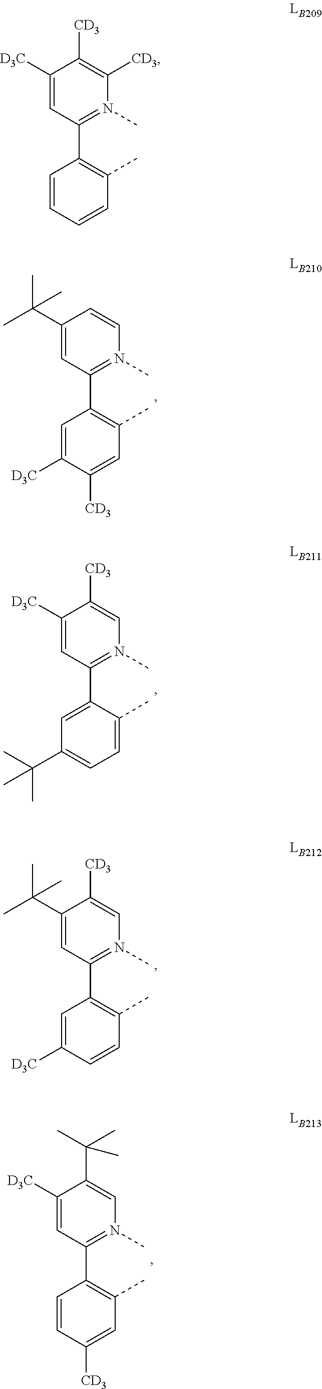 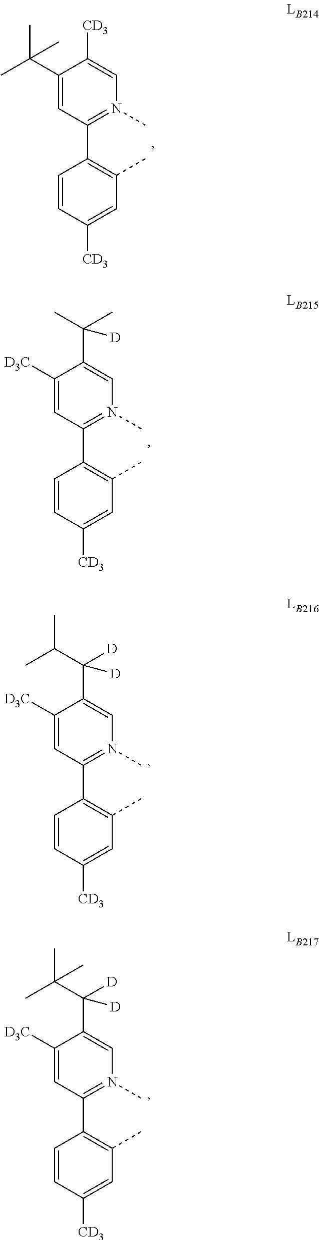 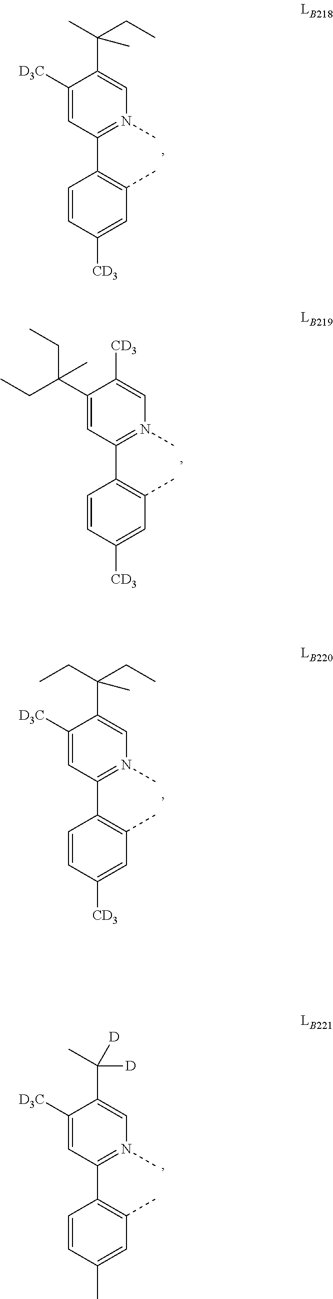 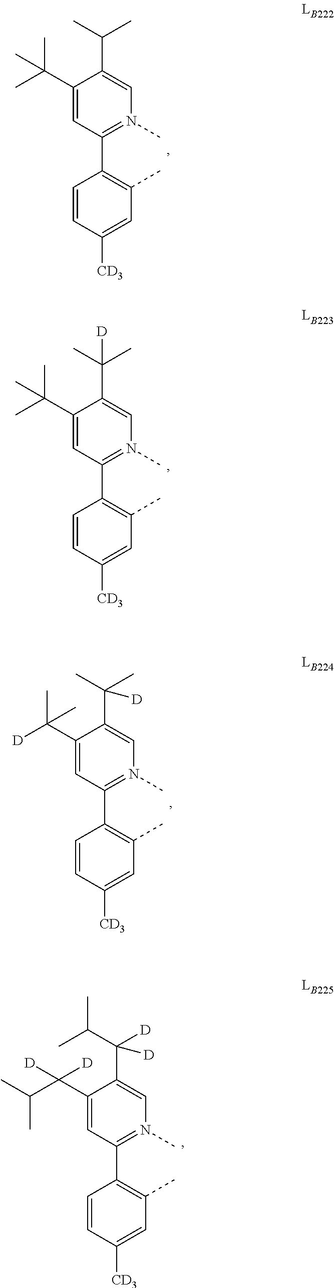 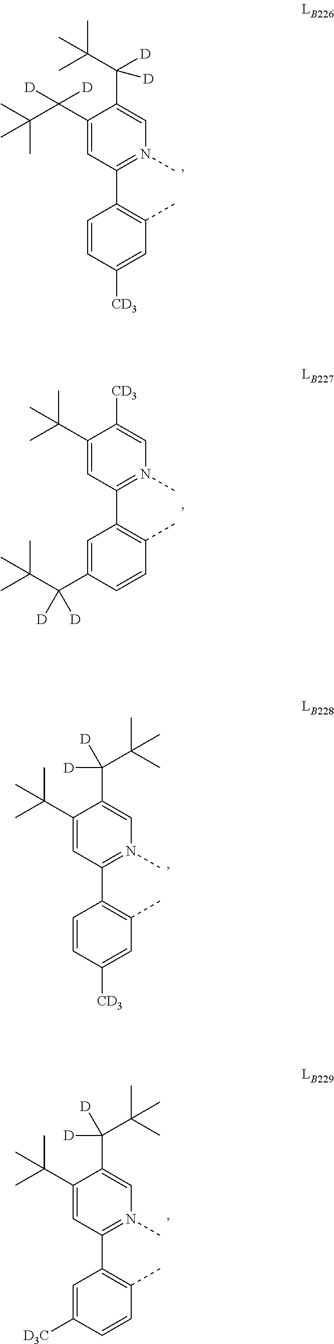 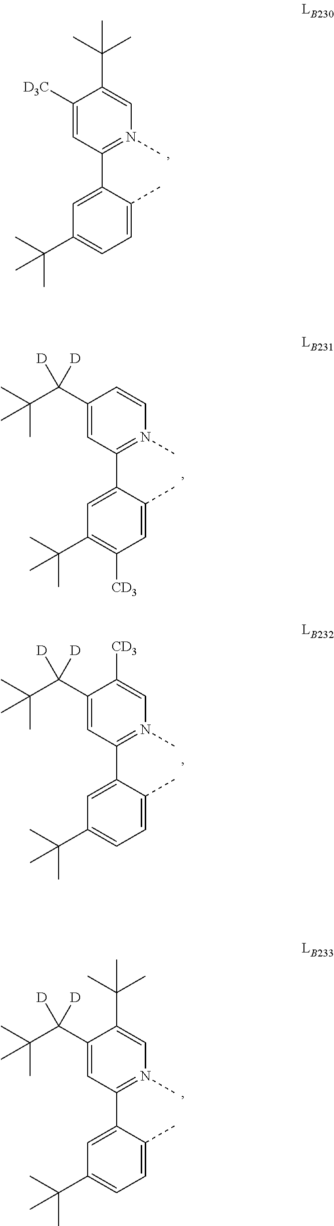 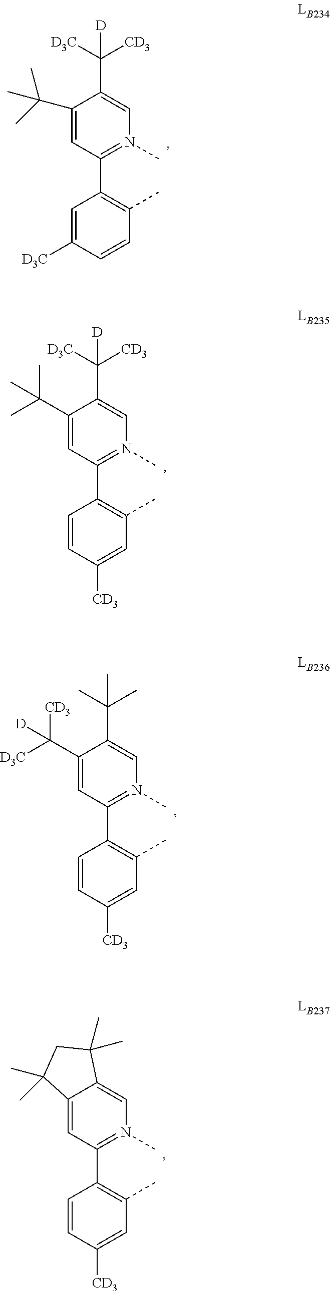 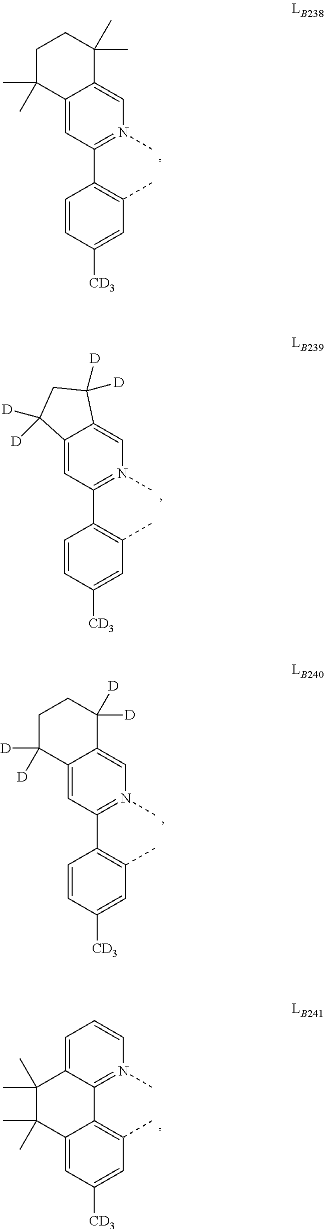 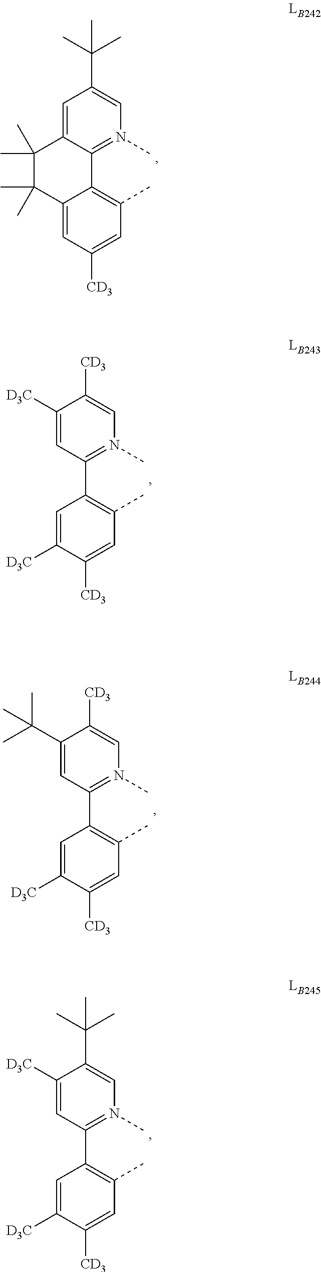 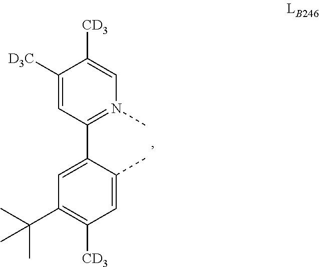 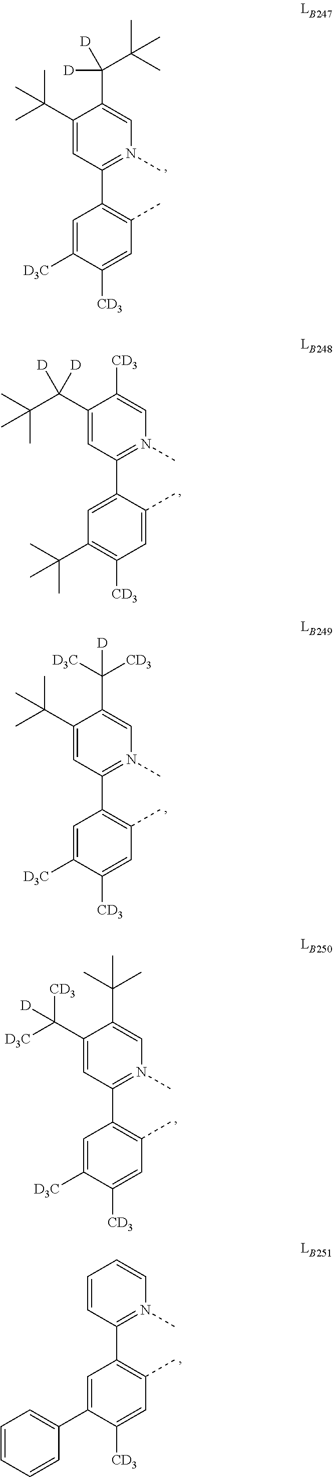 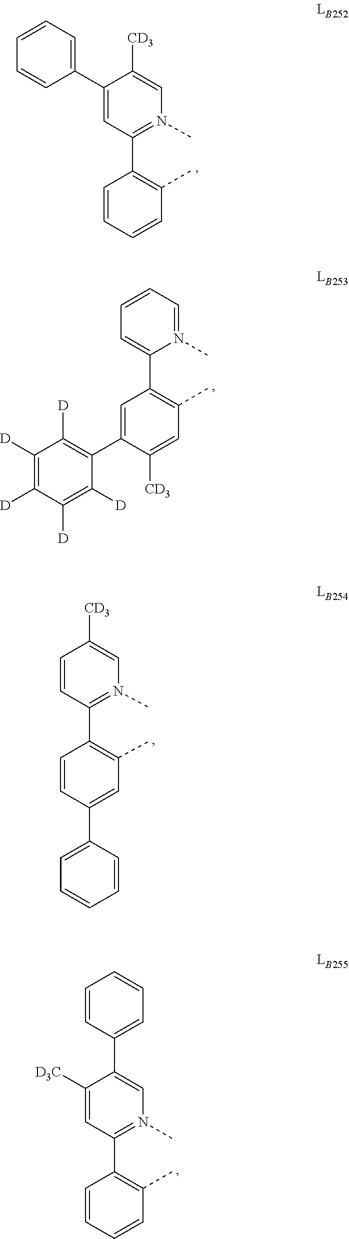 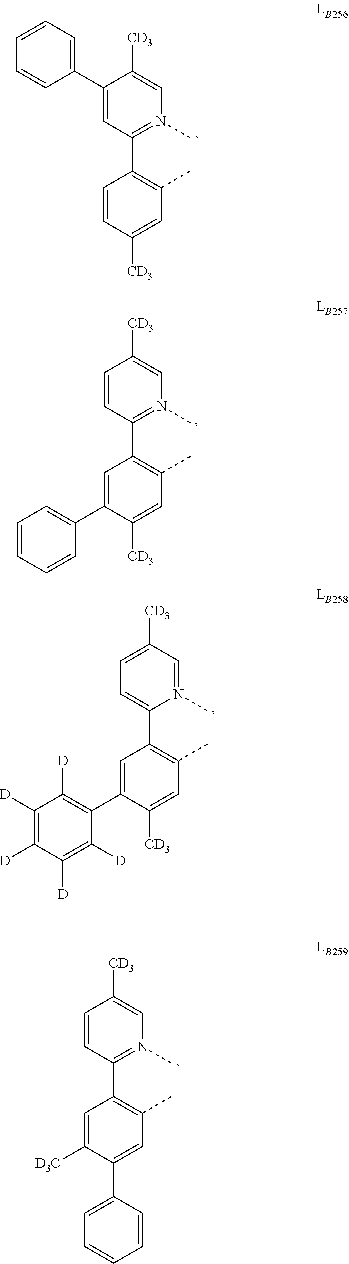 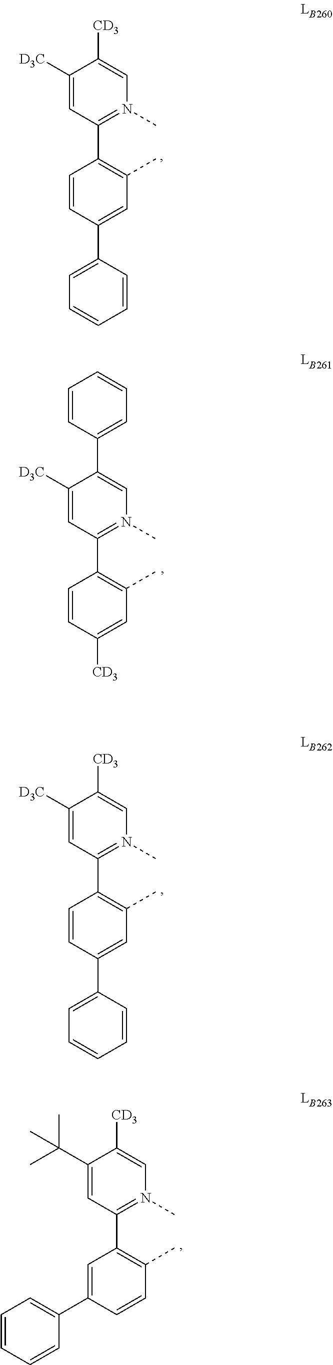 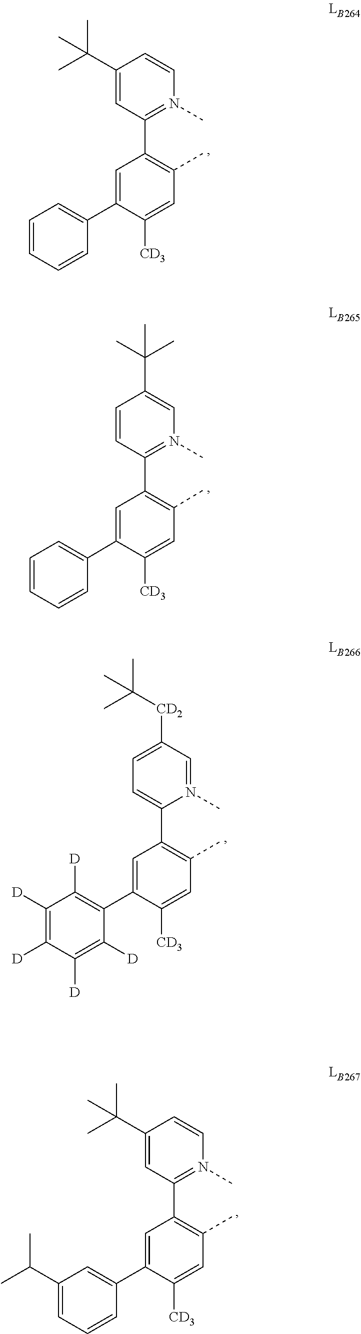 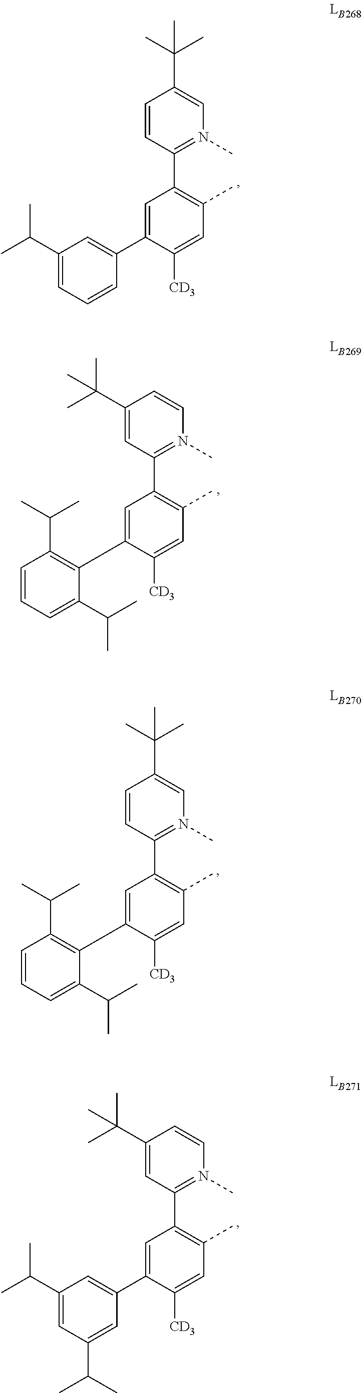 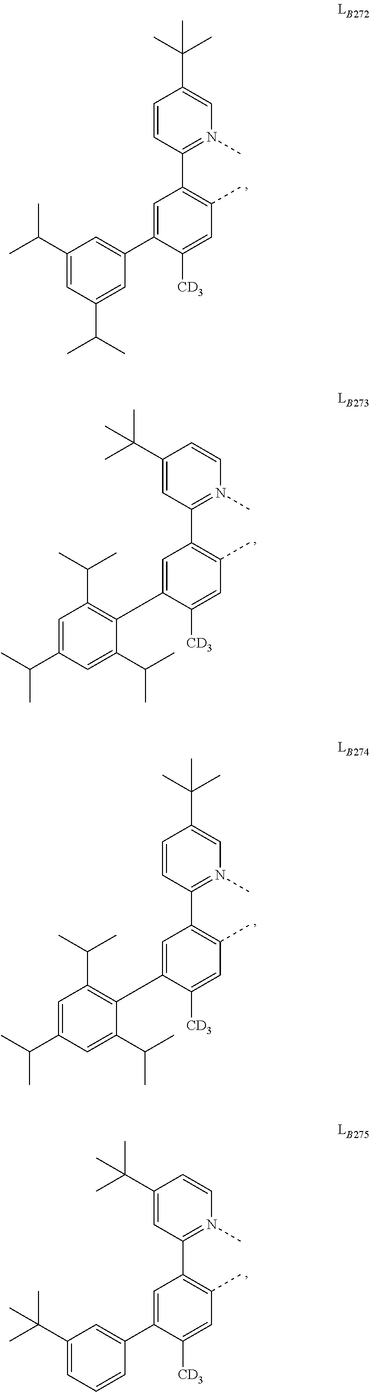 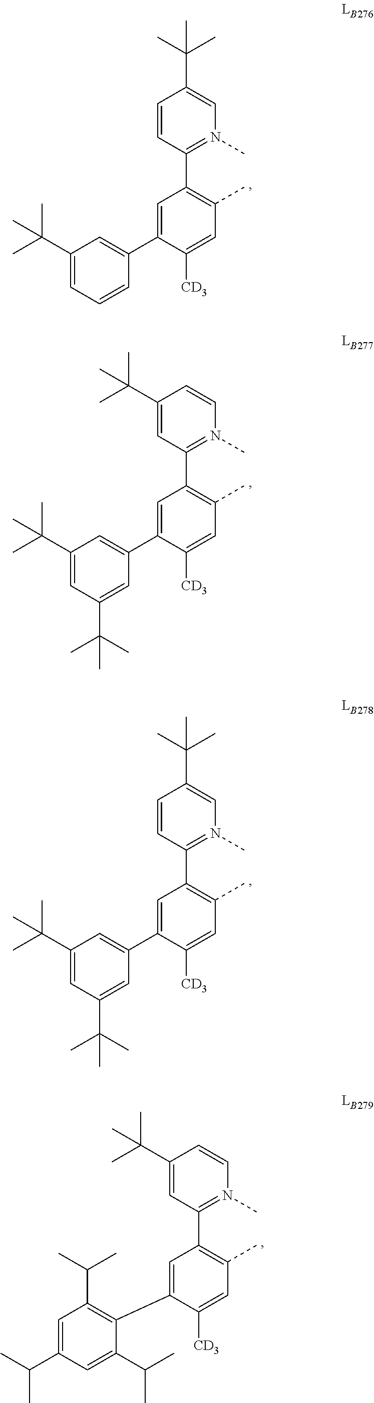 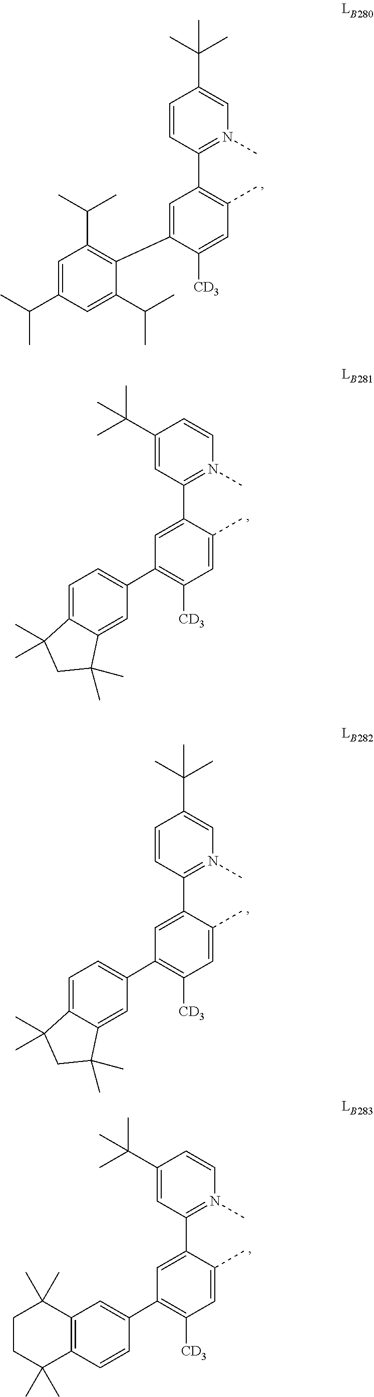 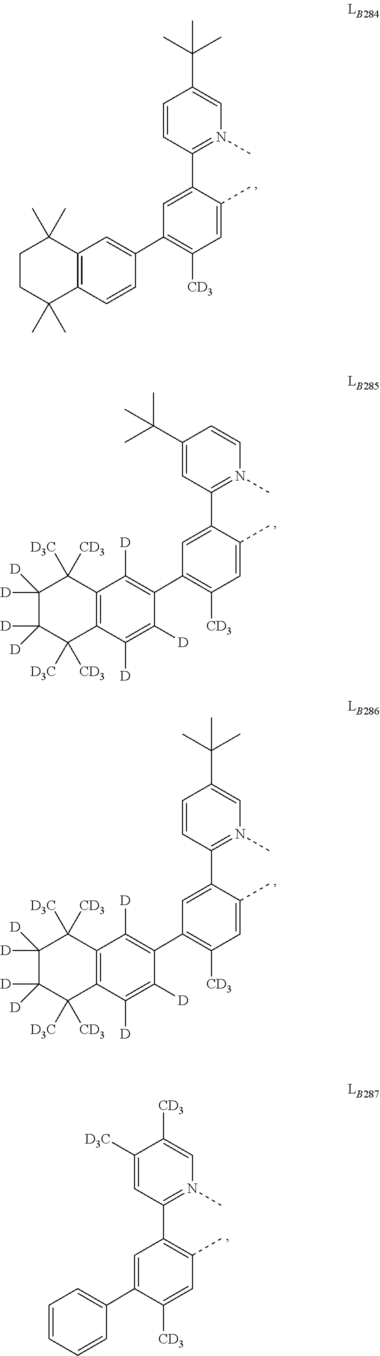 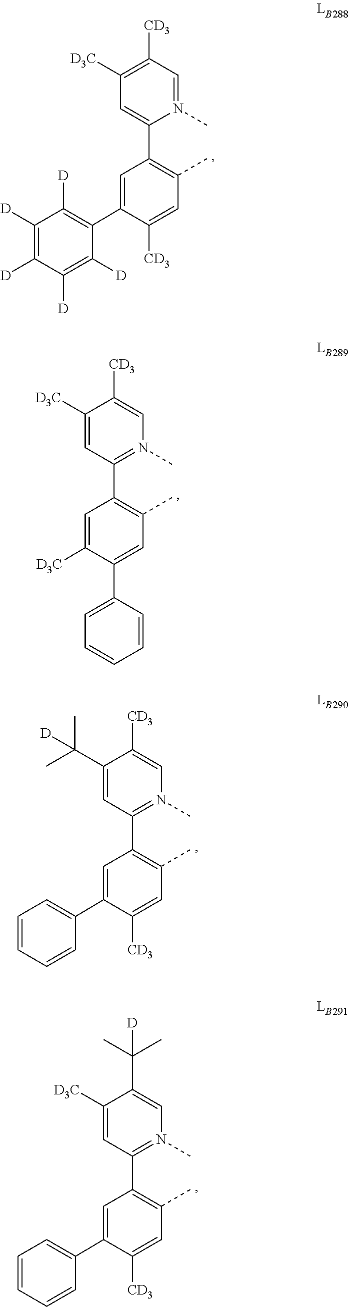 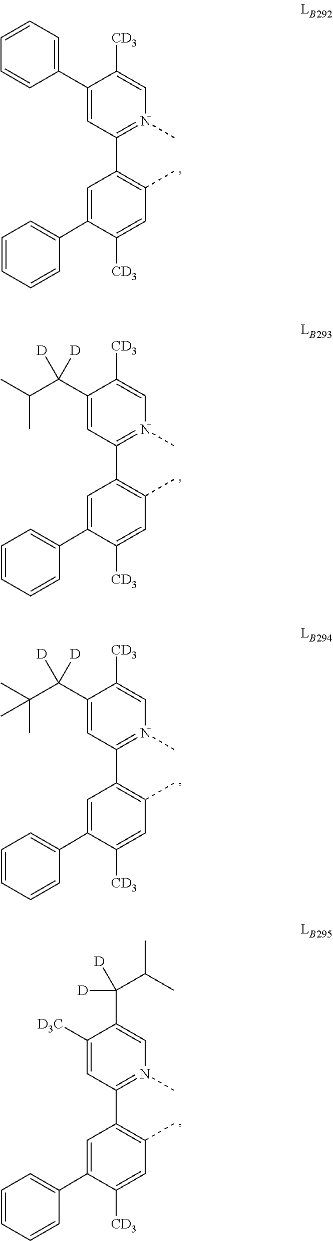 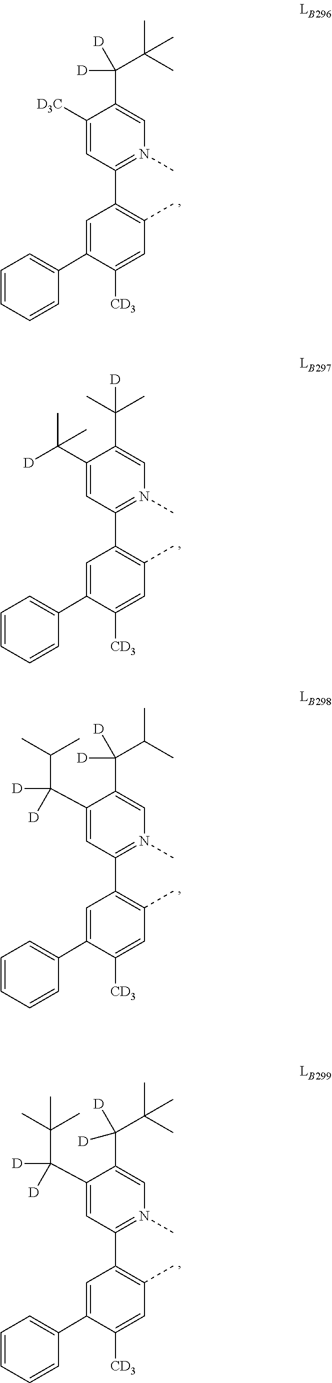 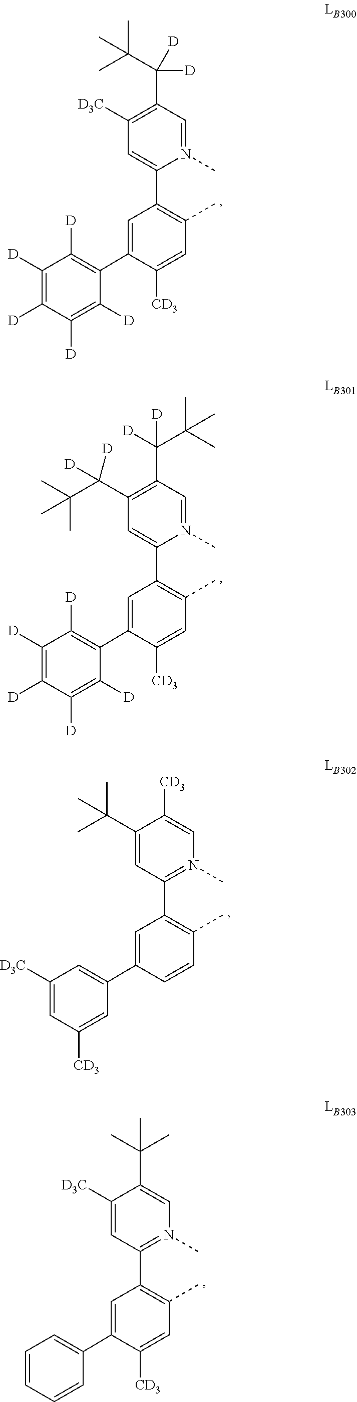 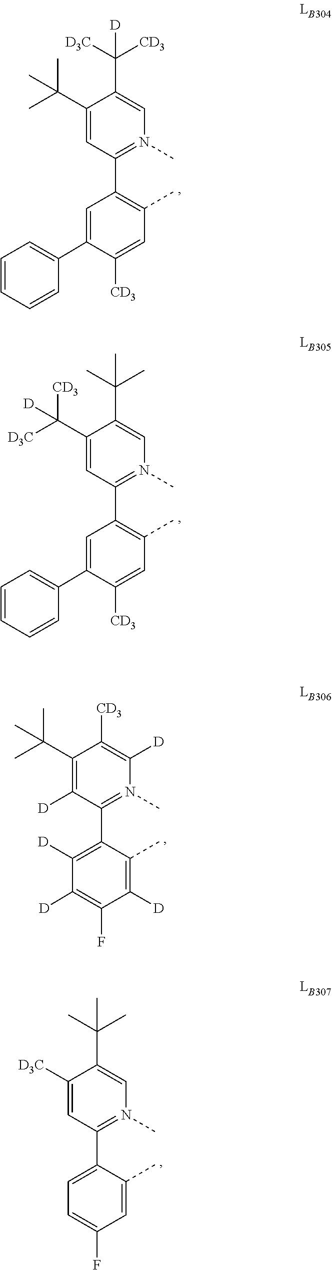 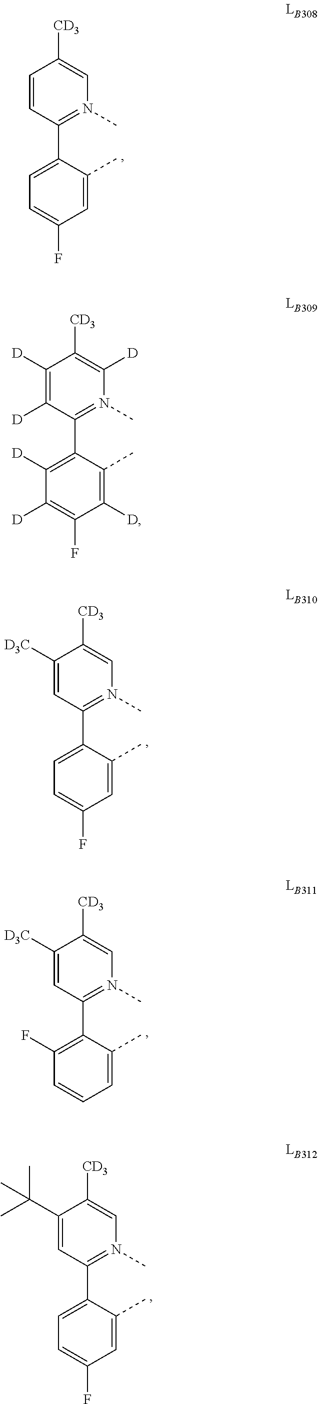 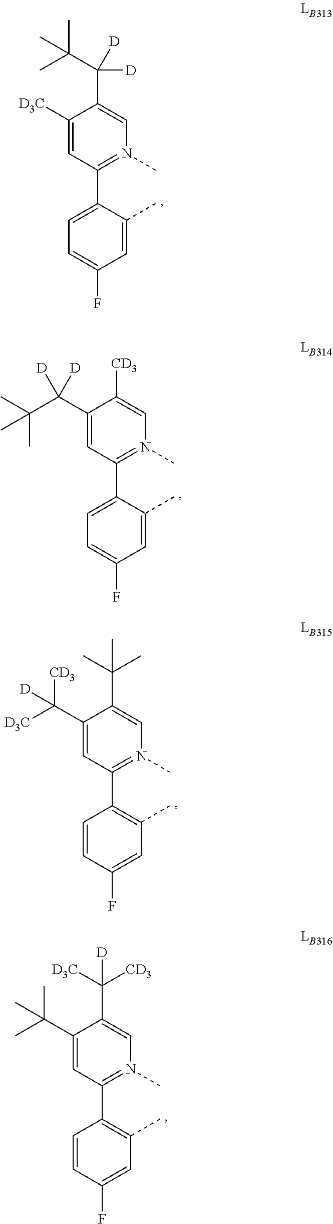 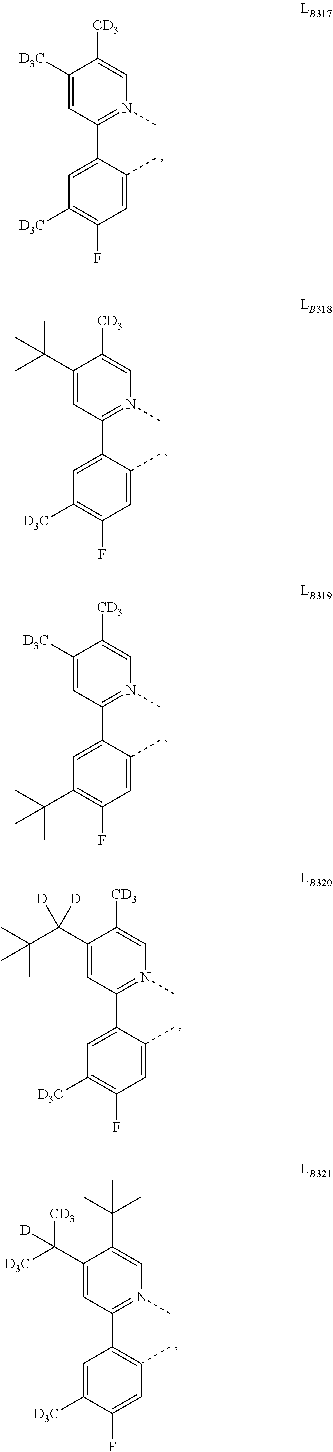 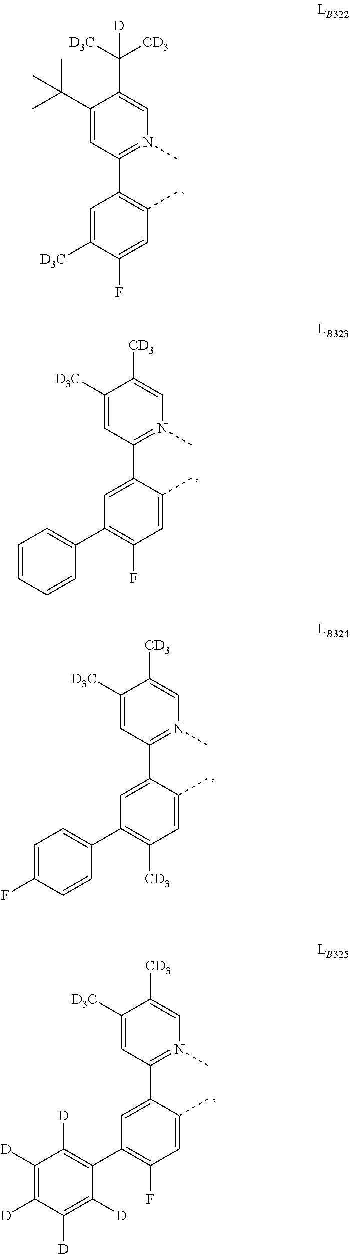 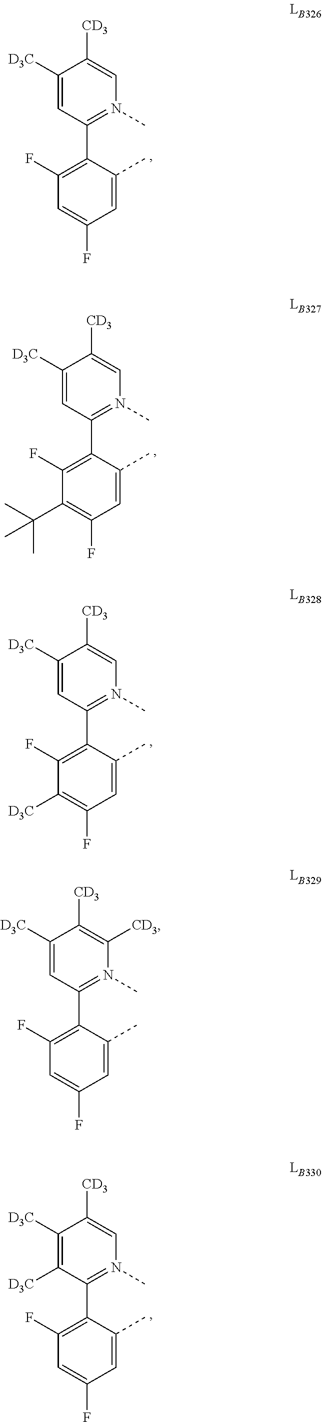 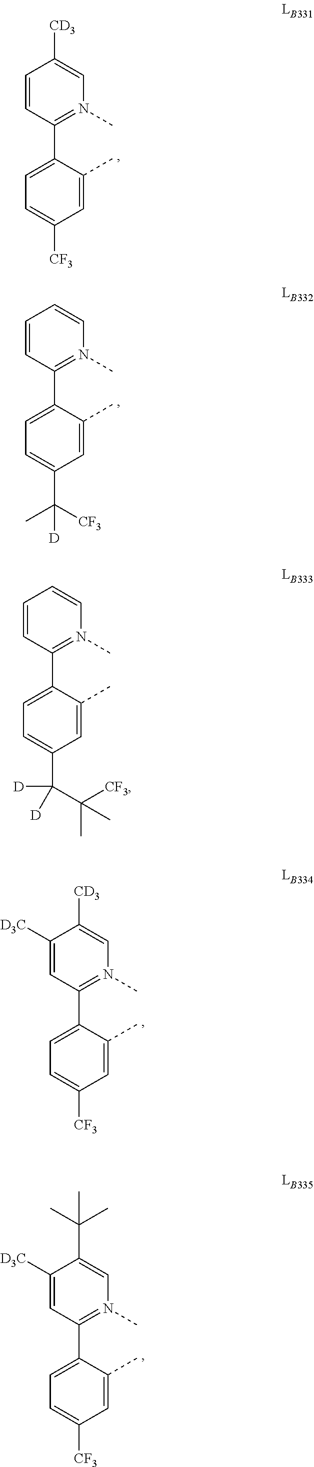 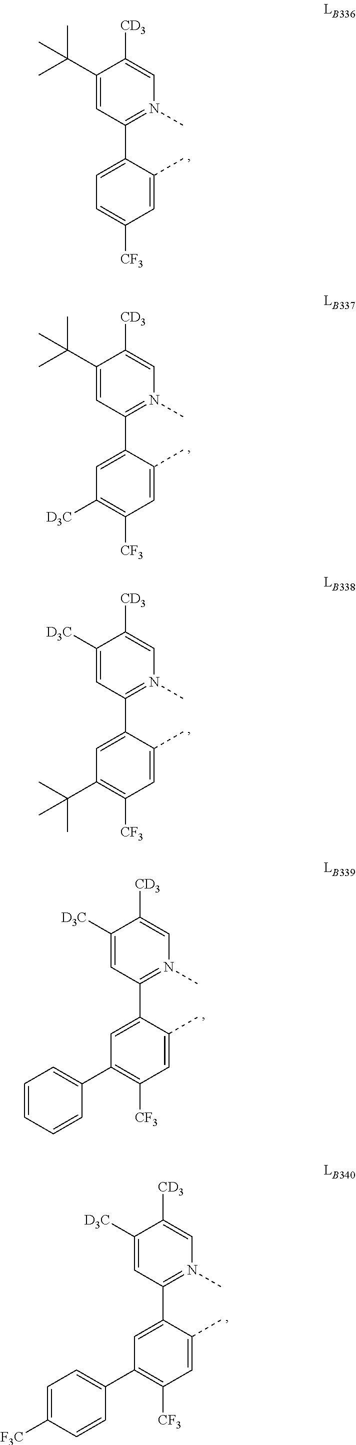 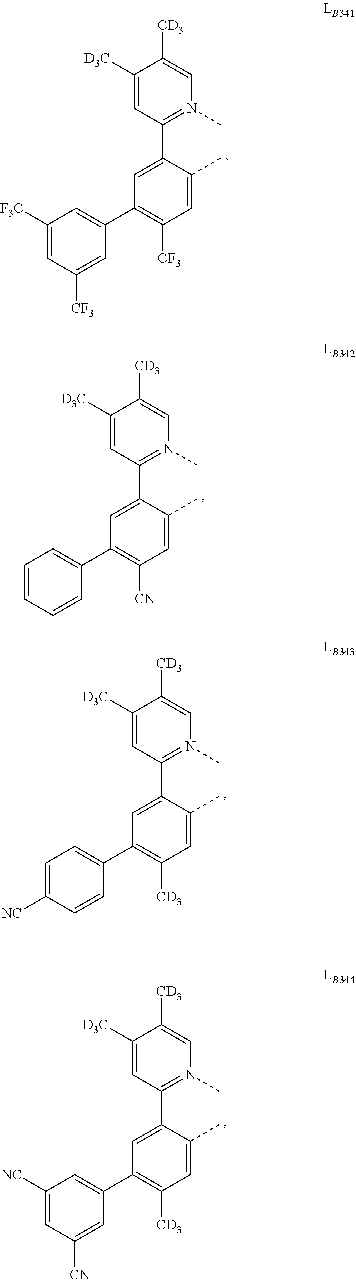 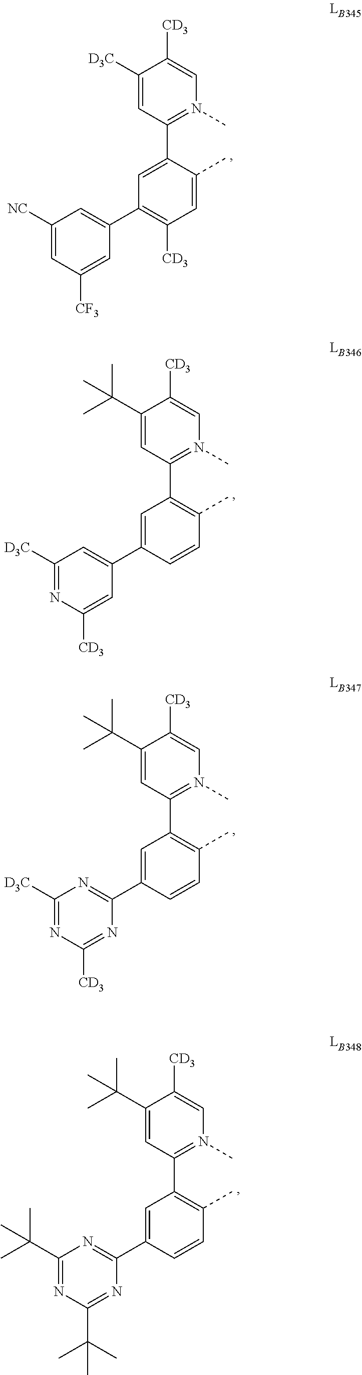 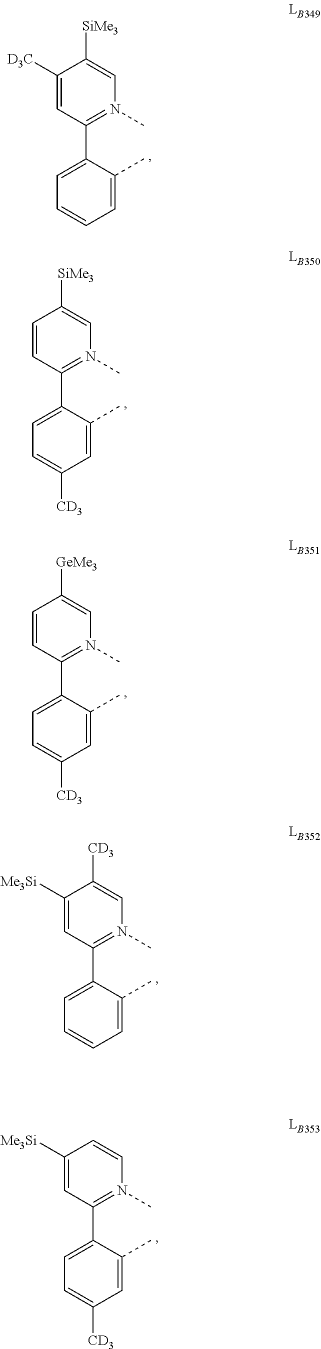 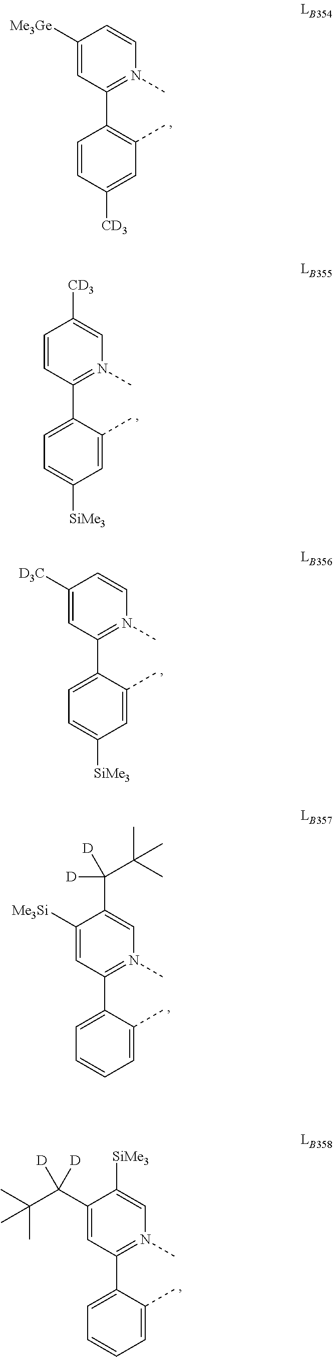 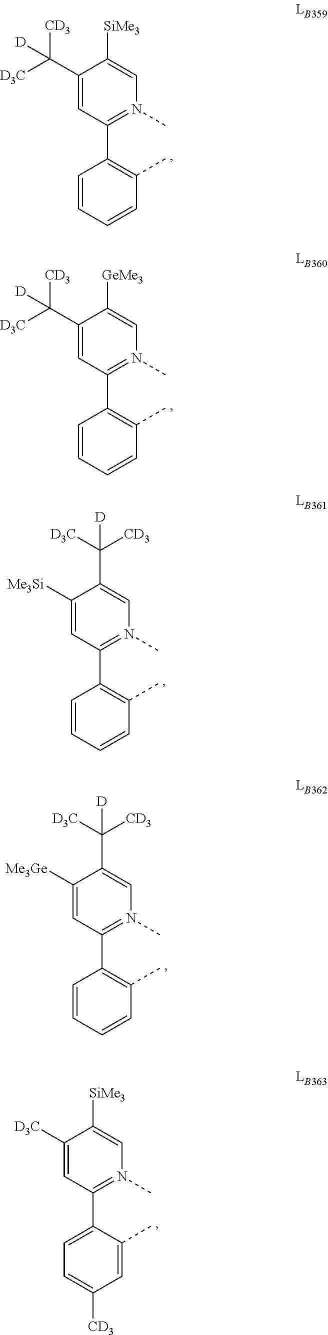 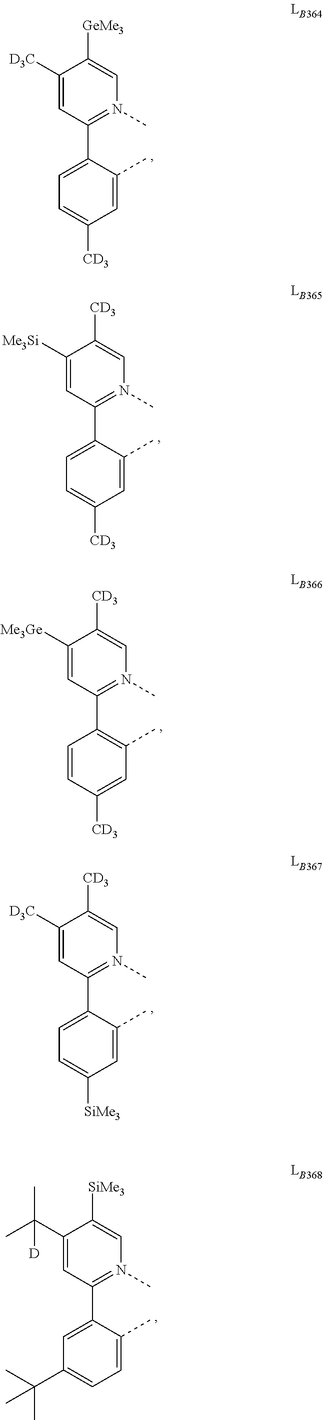 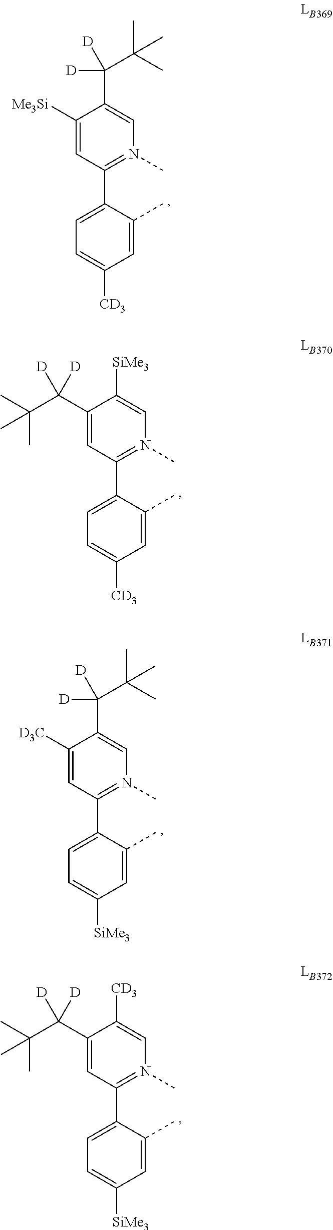 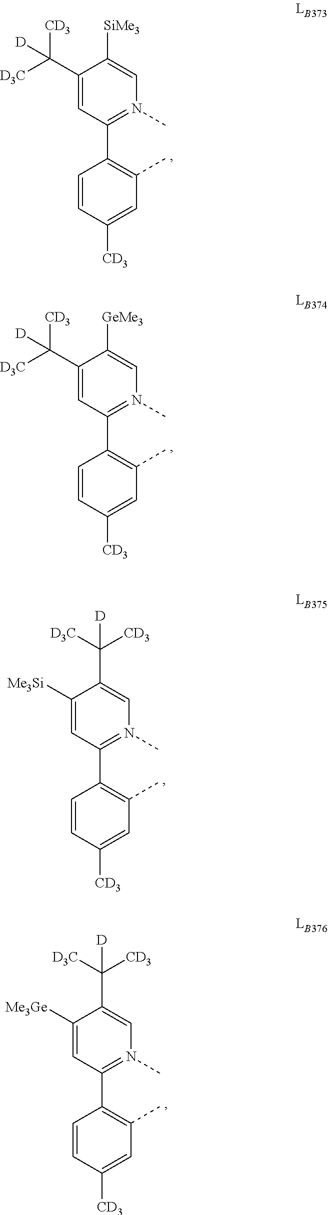 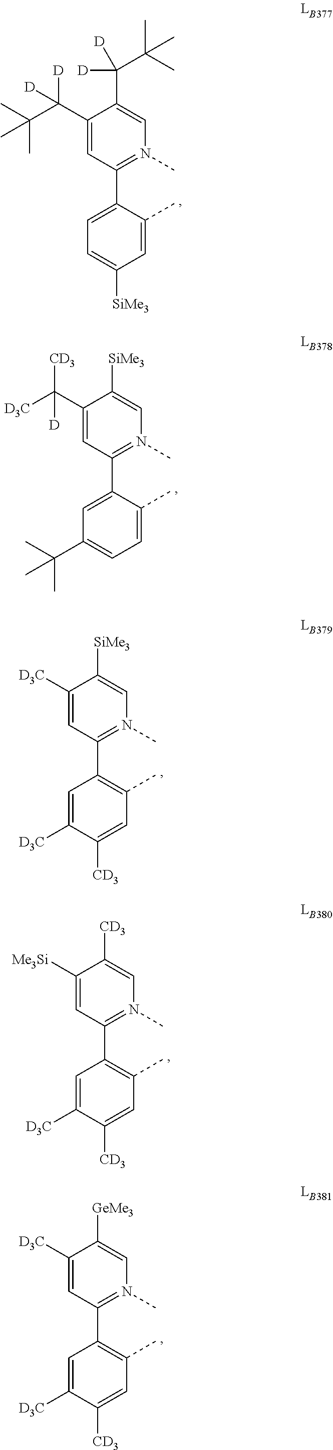 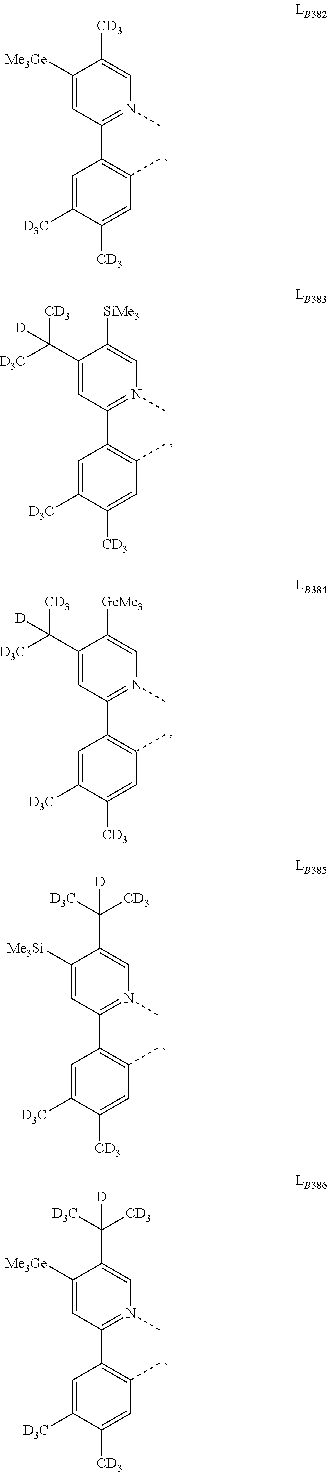 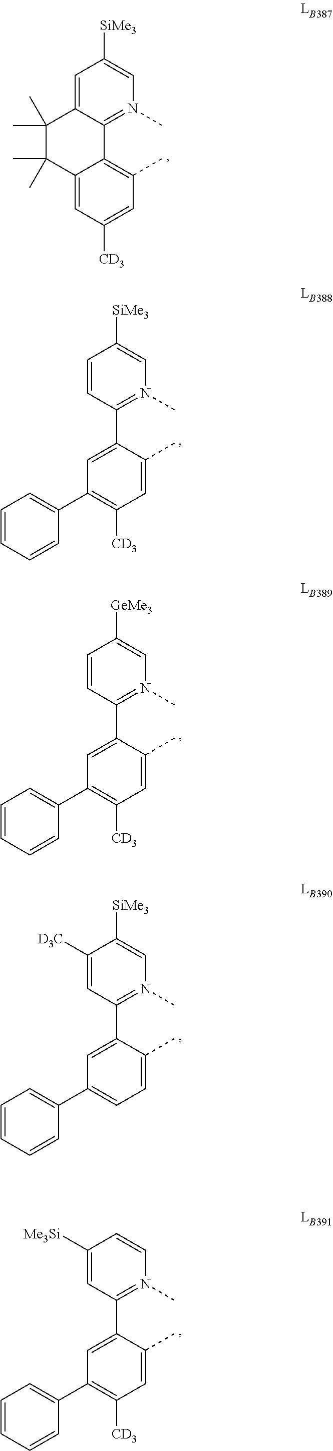 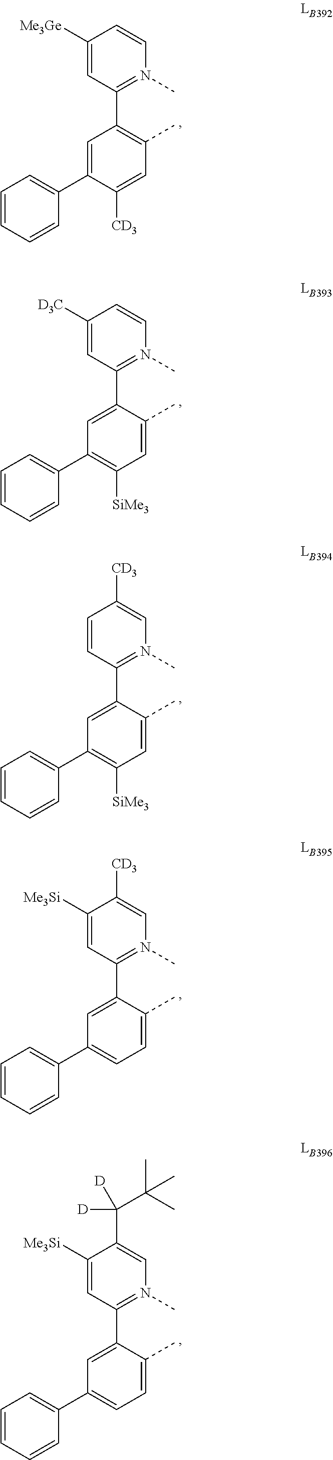 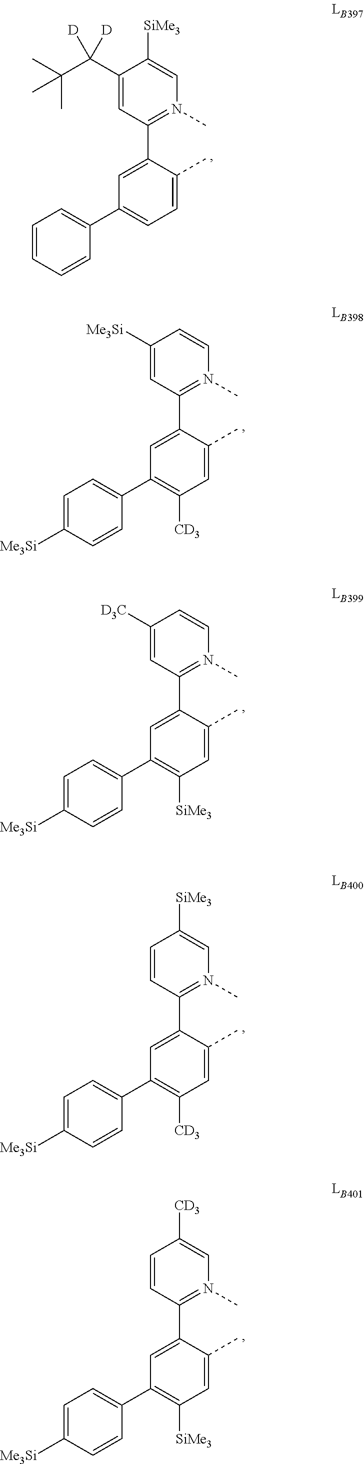 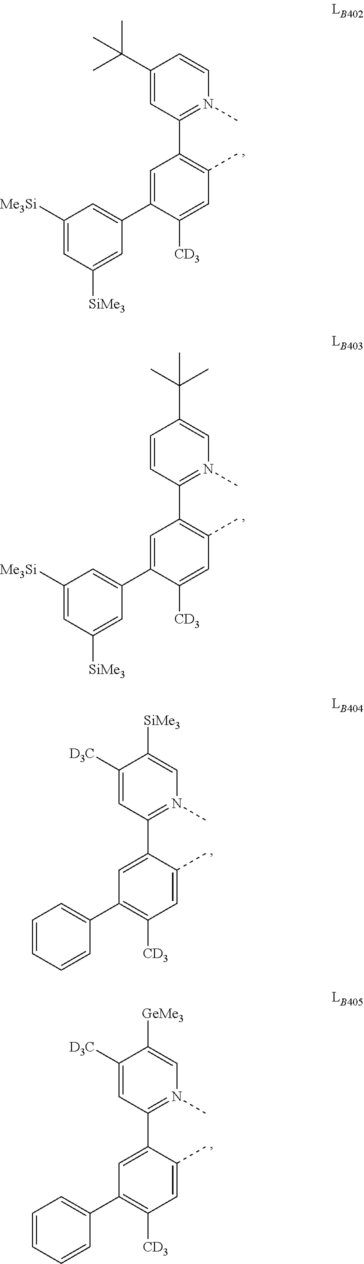 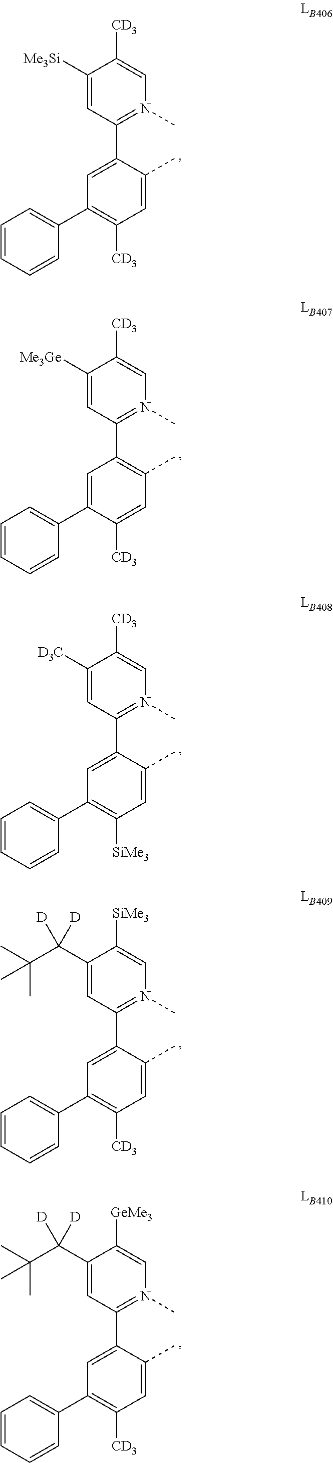 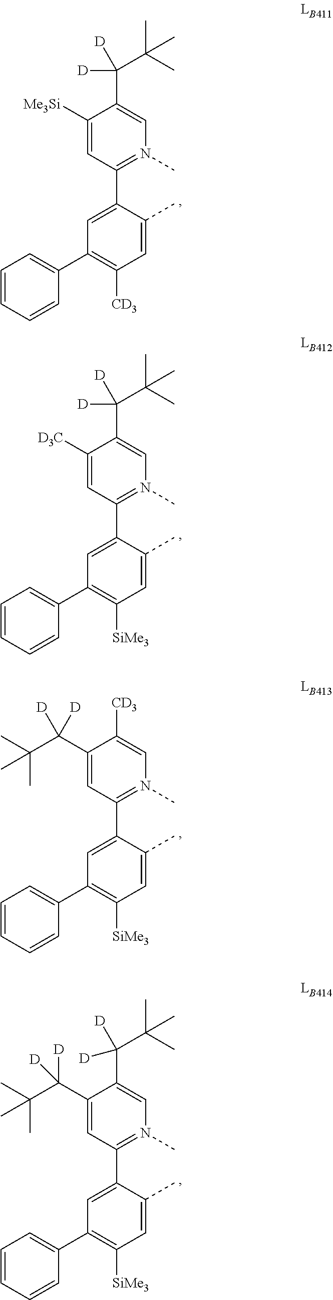 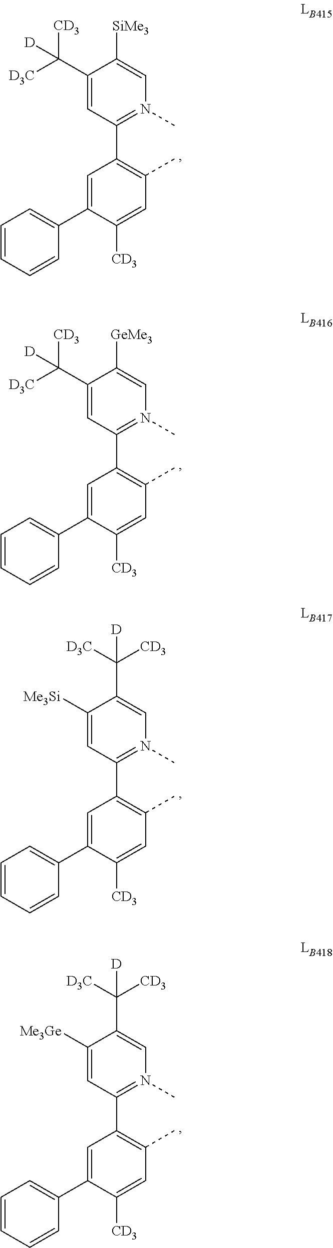 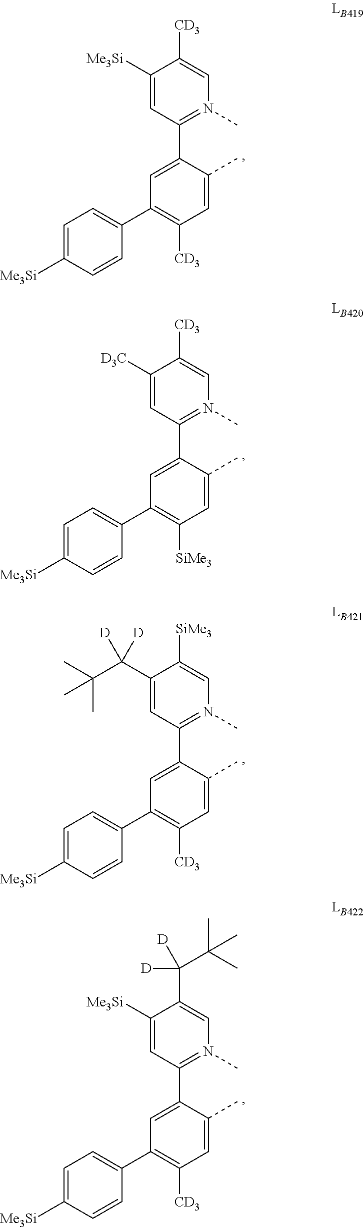 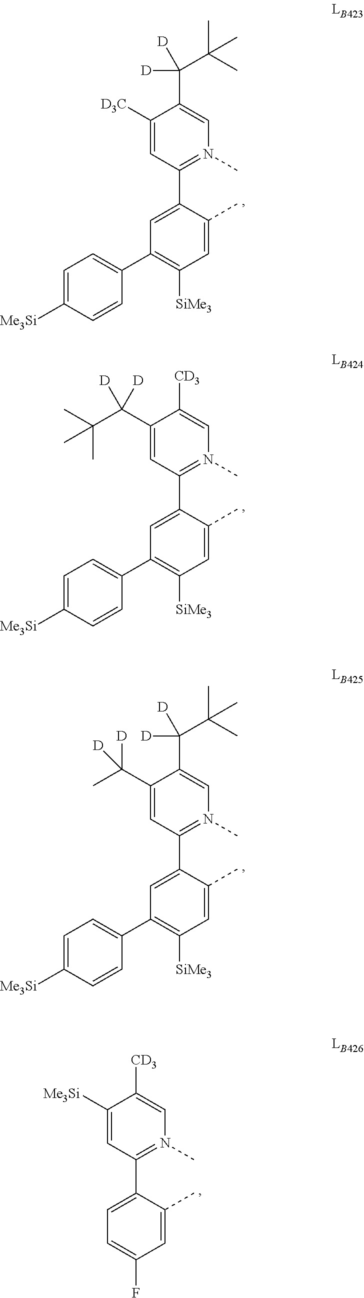 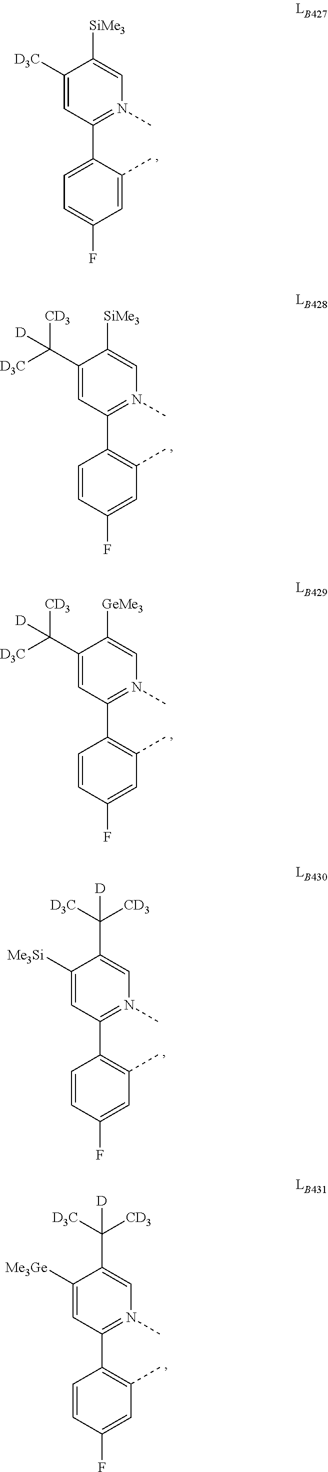 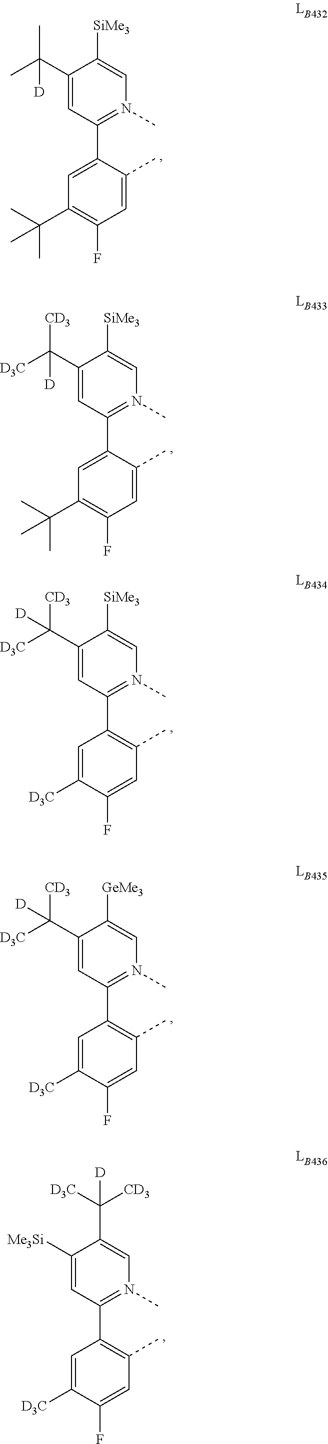 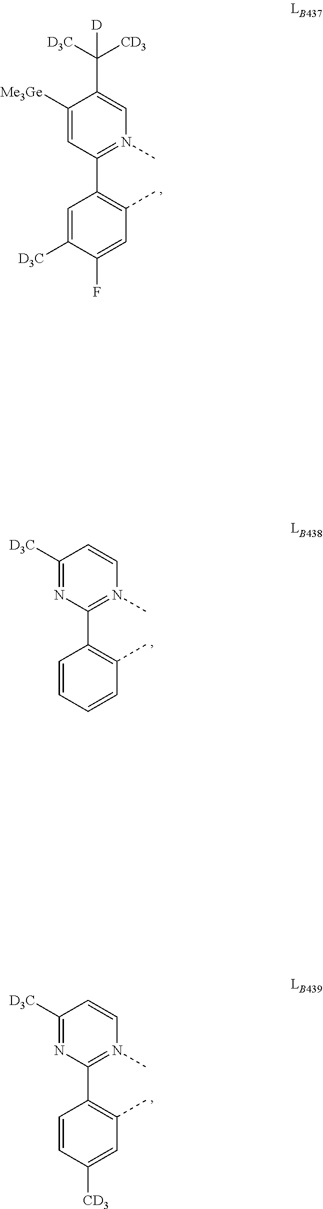 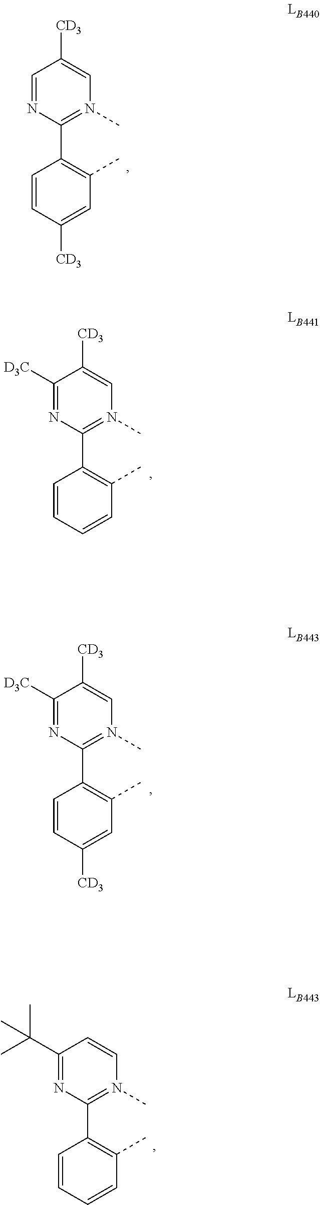 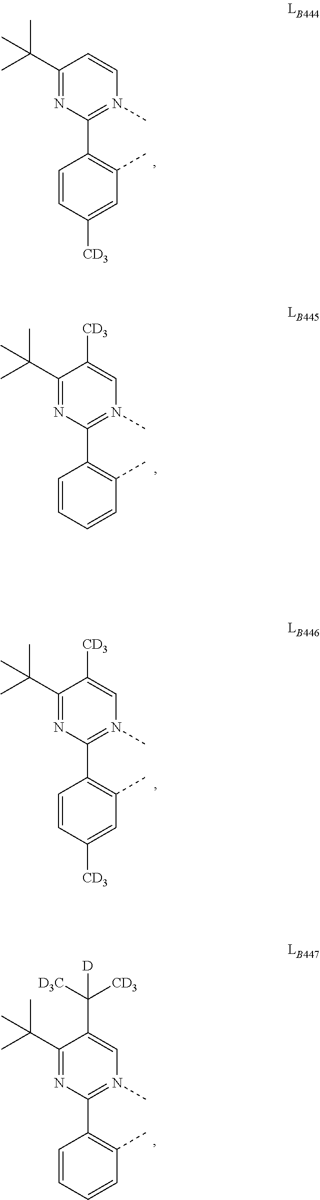 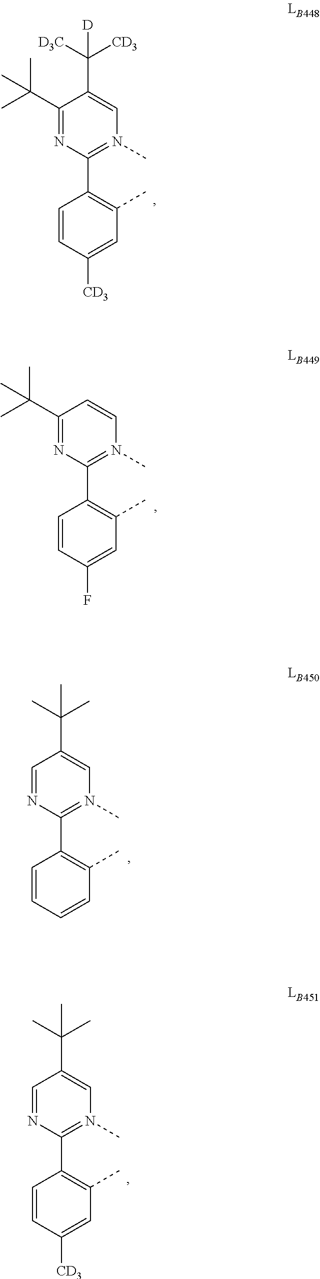 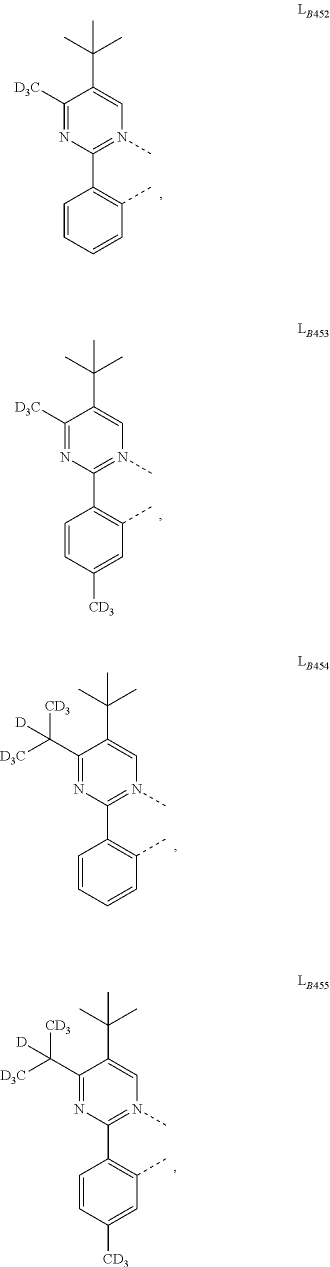 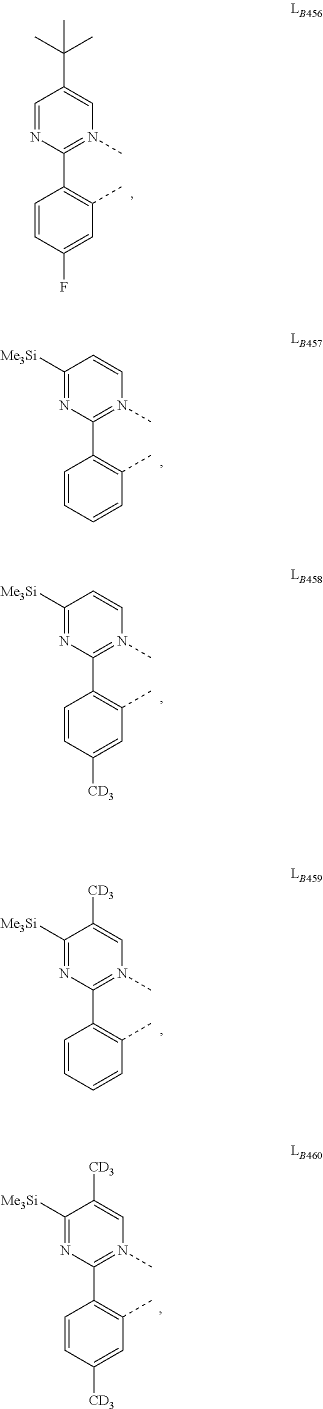 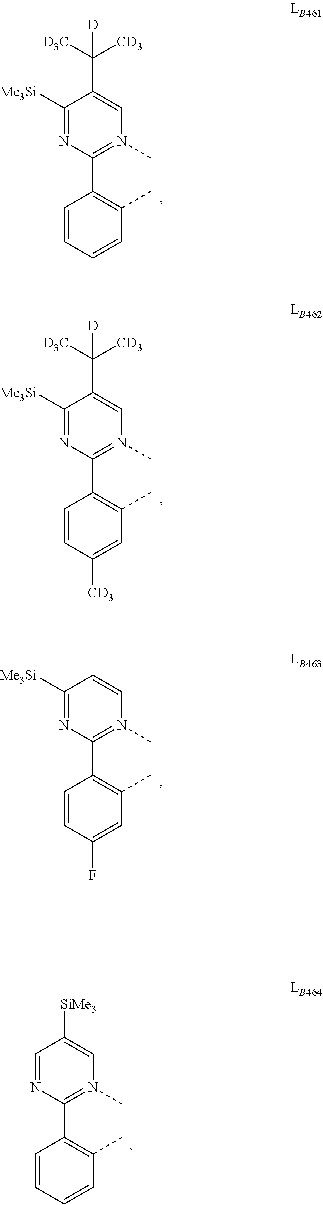 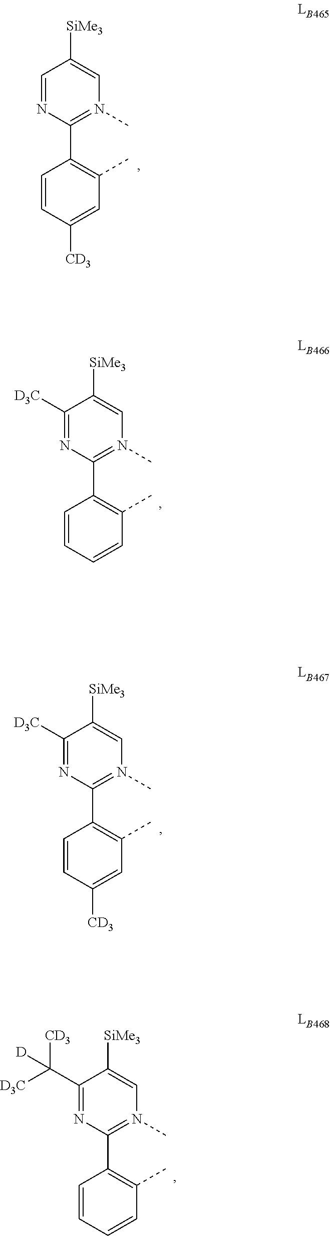 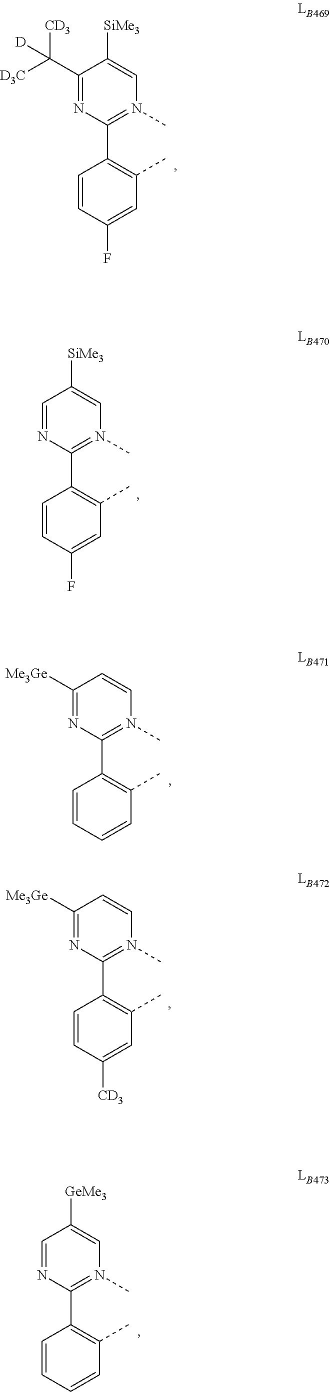 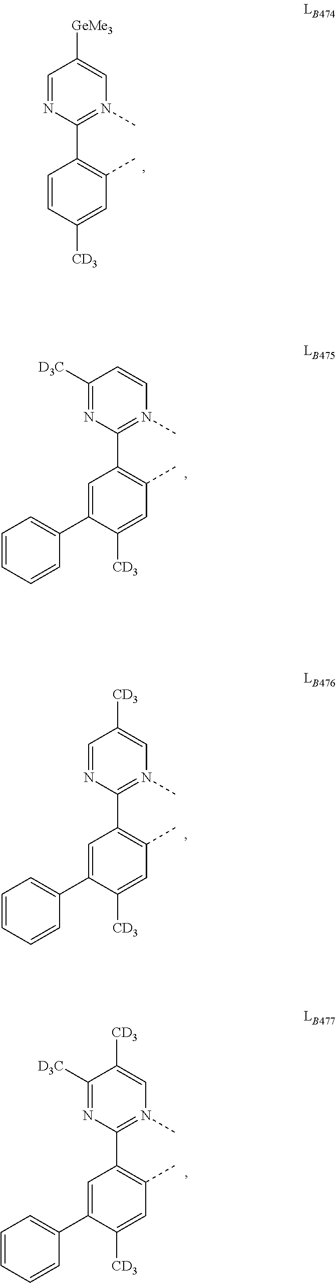 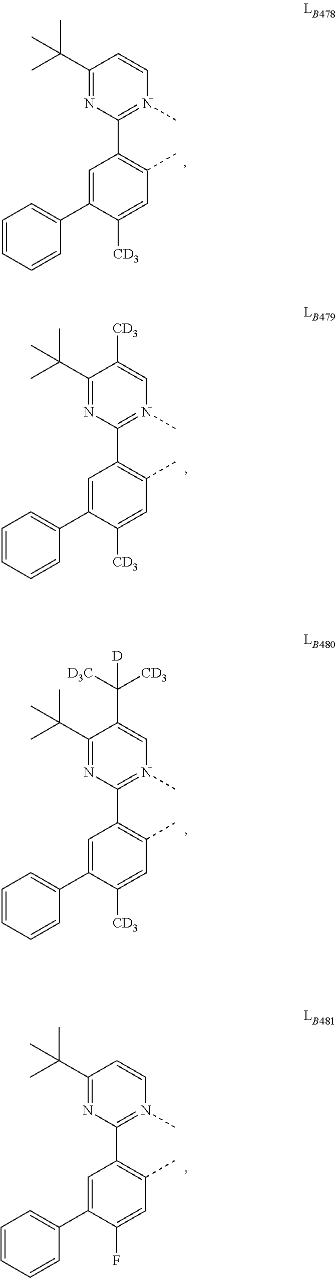 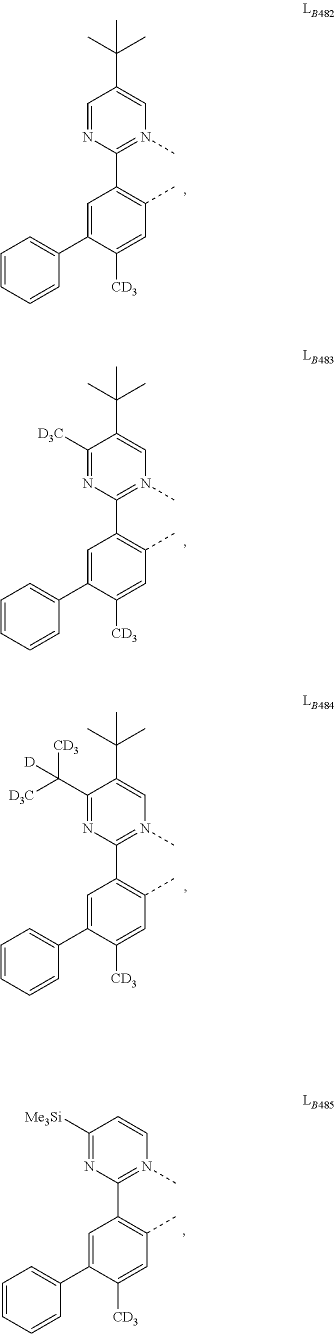 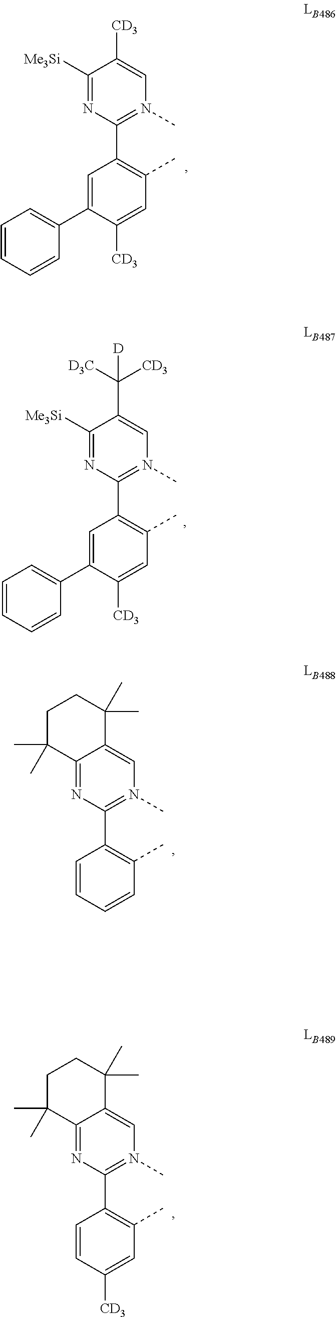 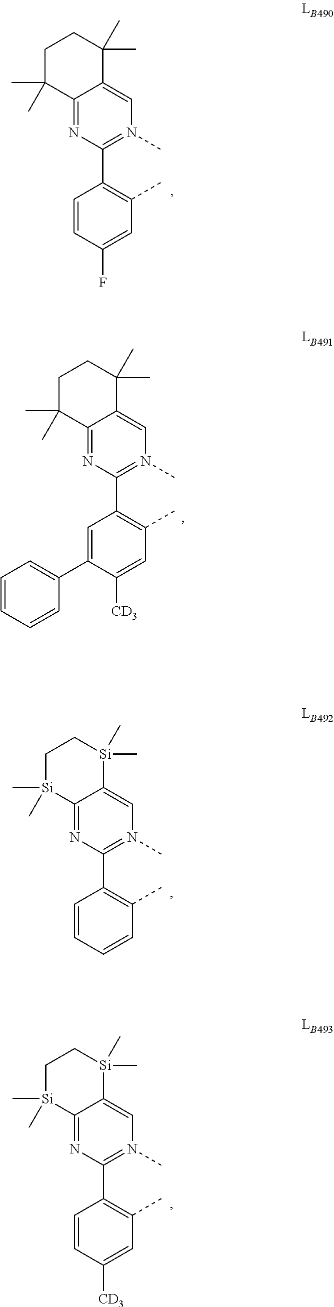 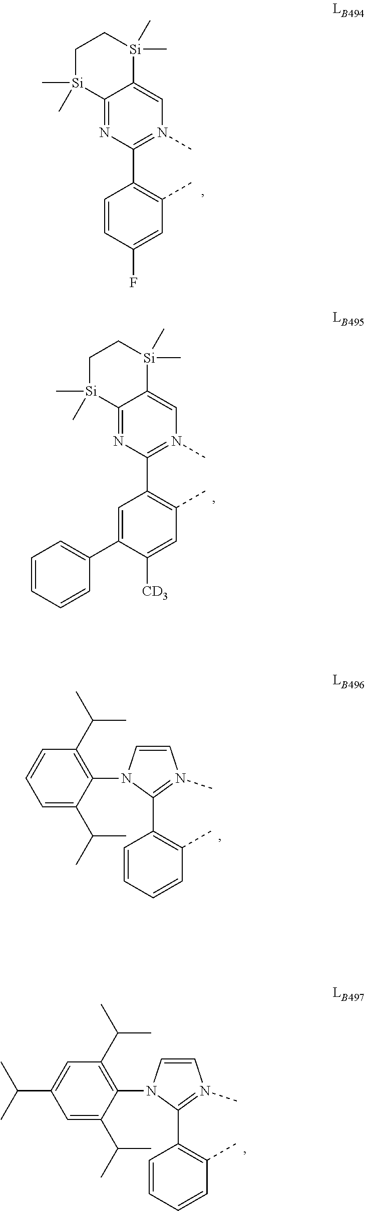 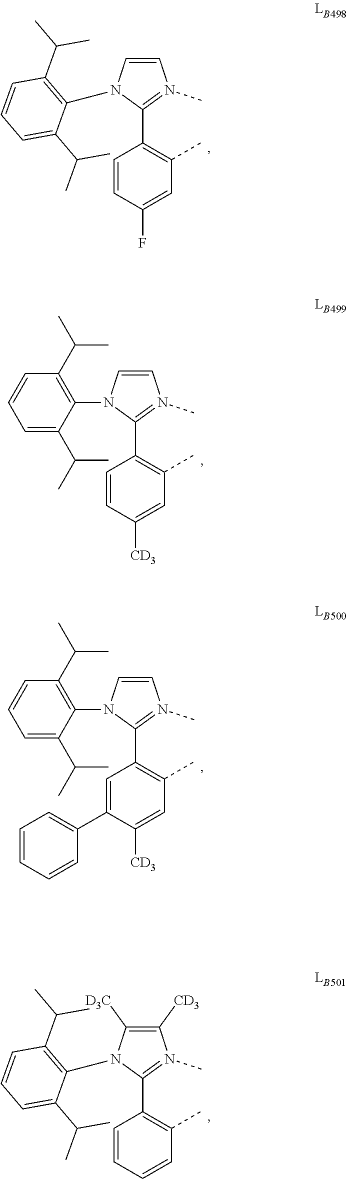 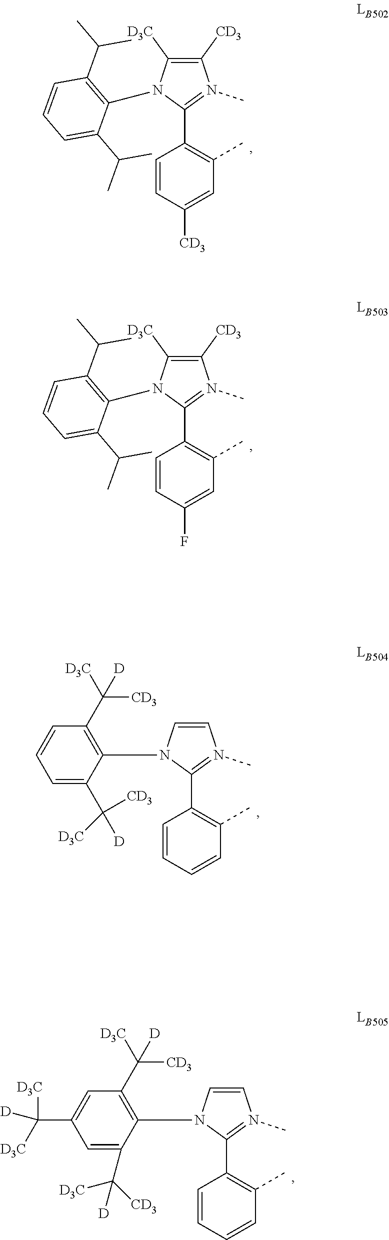 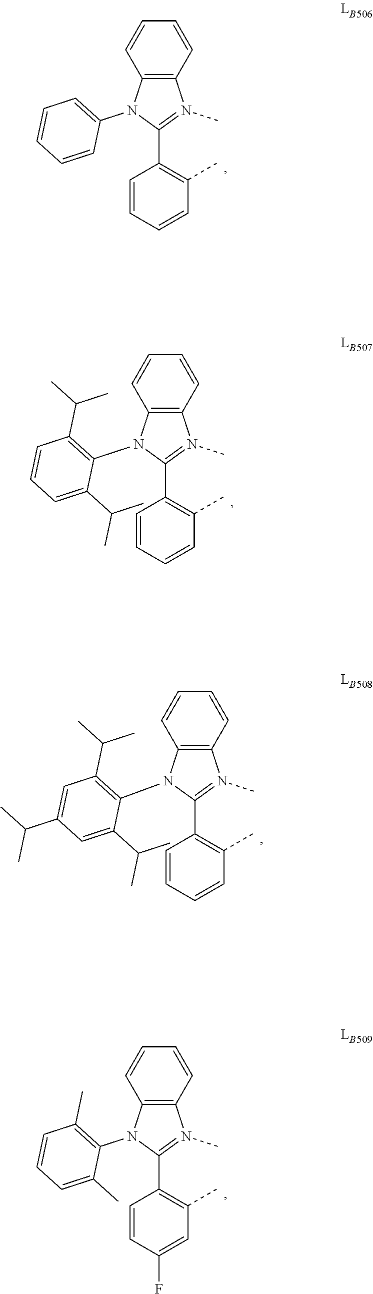 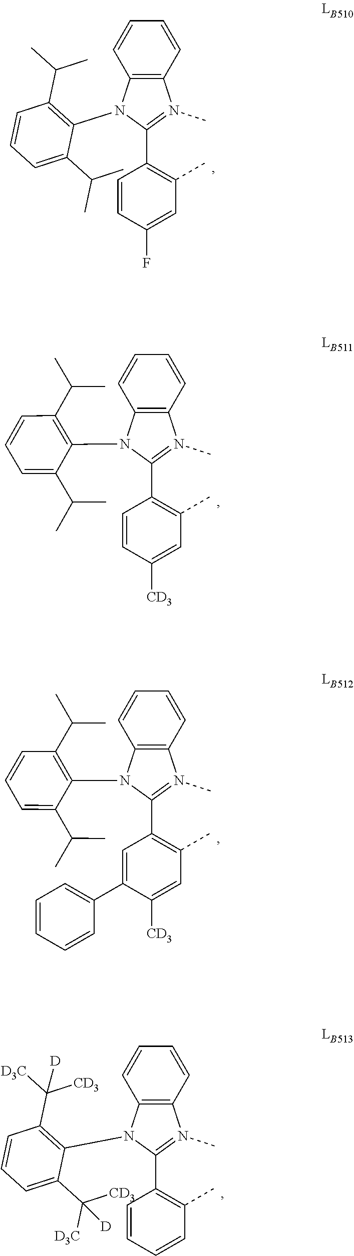 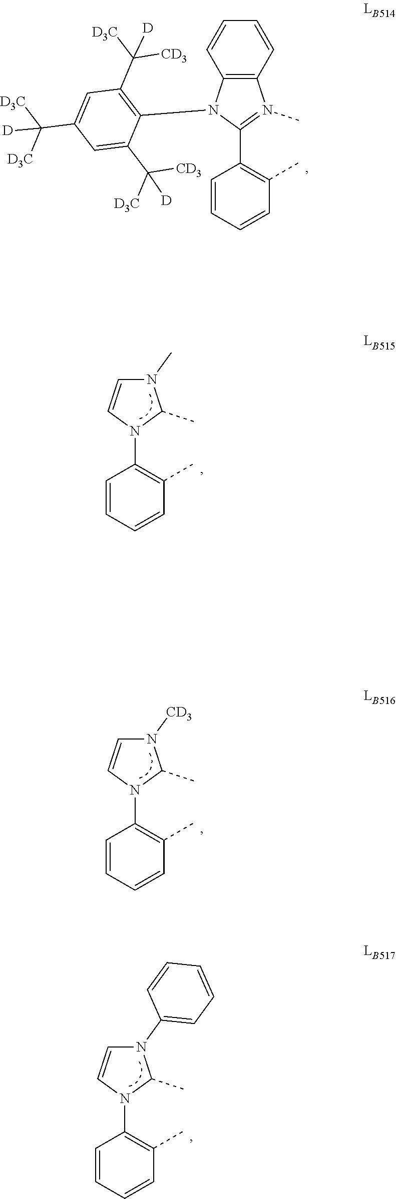 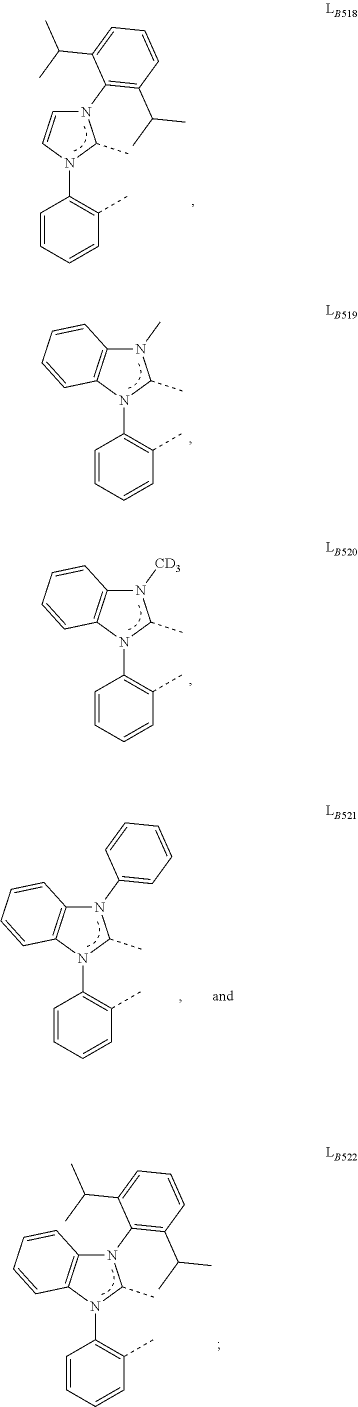
wherein j is an integer from 1 to 1416, and each L_{Cj-I} has a structure based on formula 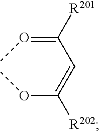
and
each L_{Cj-II} has a structure based on formula 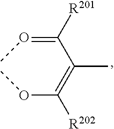
wherein for each L_{Cj} in L_{Cj-I} and L_{Cj-II}, R²⁰¹ and R²⁰² are defined as follows:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D144} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D145} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C935} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246}; |

wherein R^{D1} to R^{D246} have the following structures:

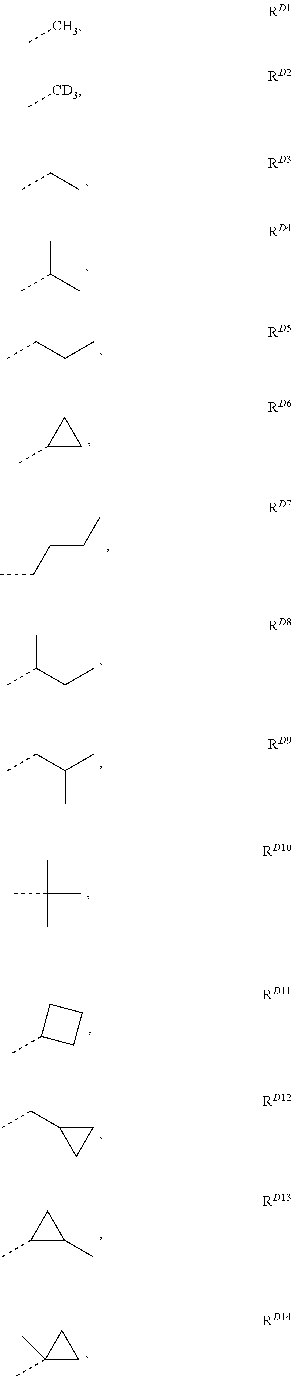

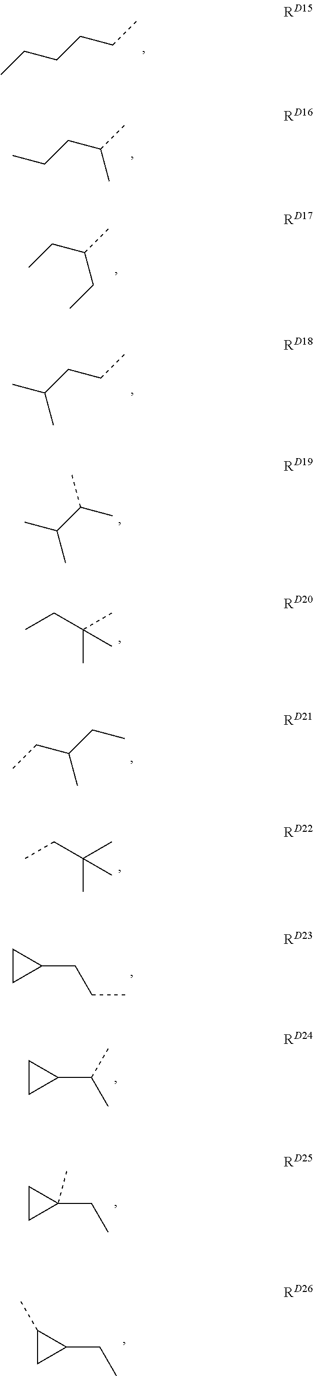

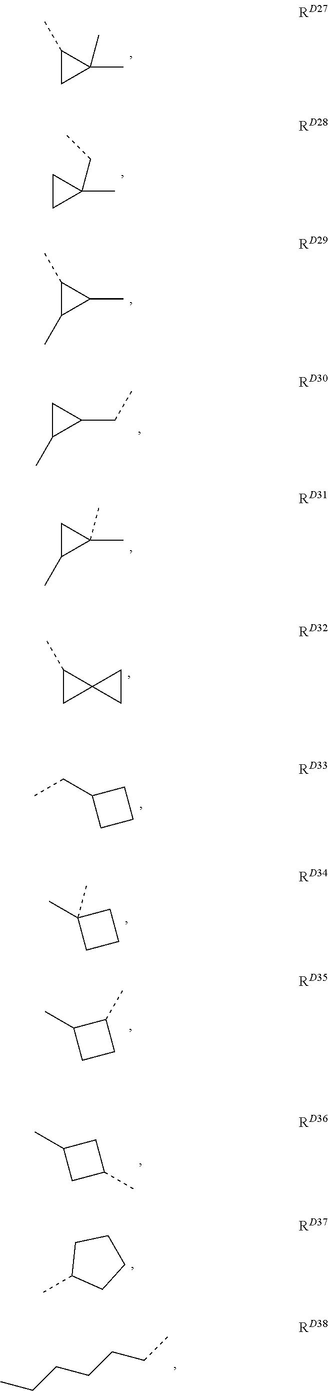

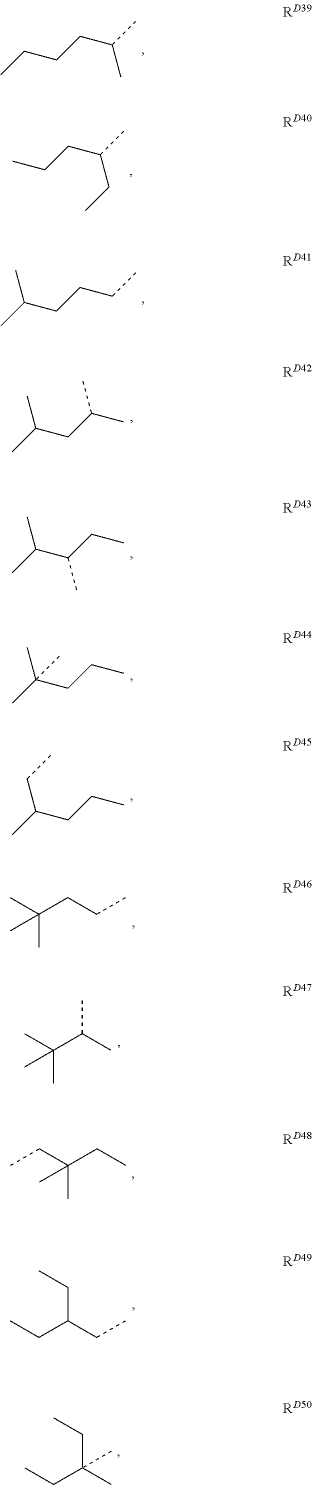

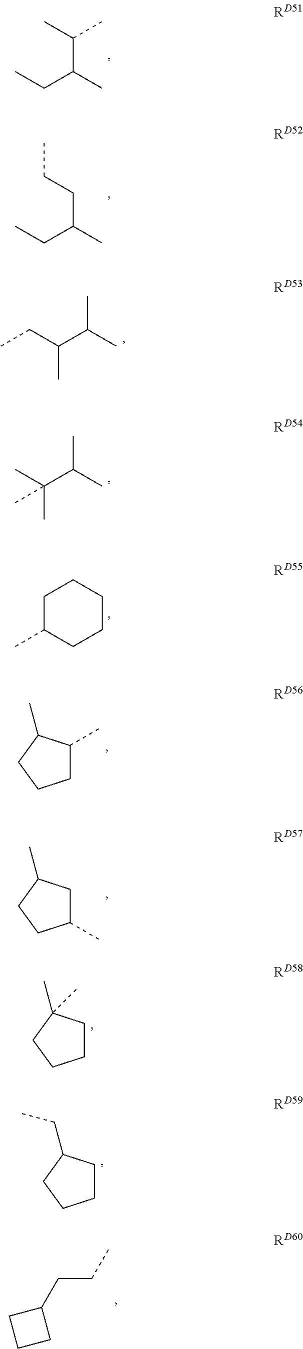

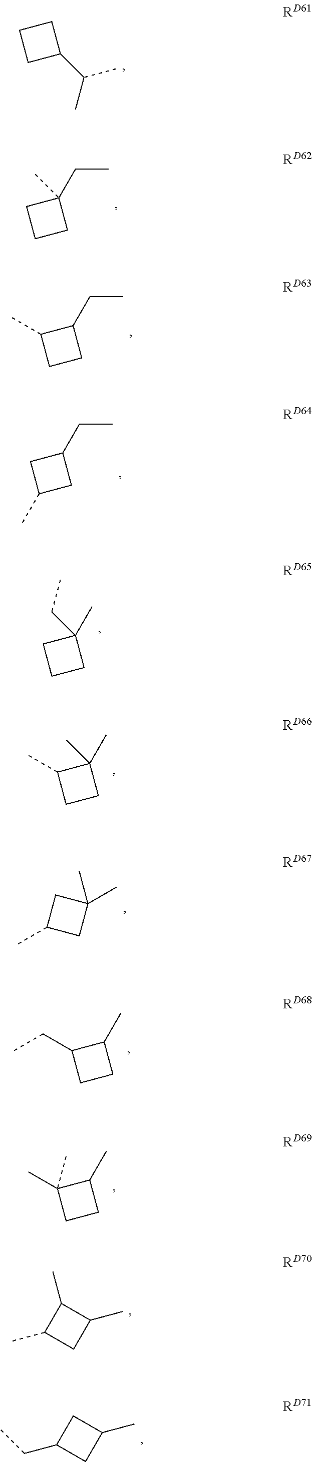

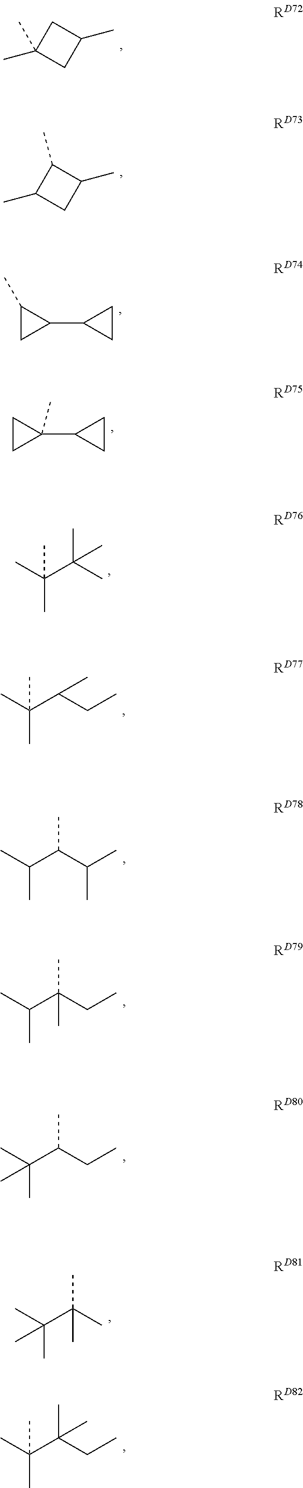

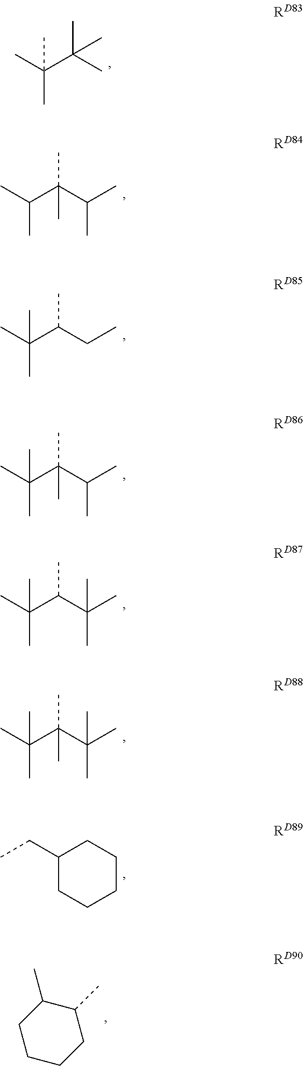

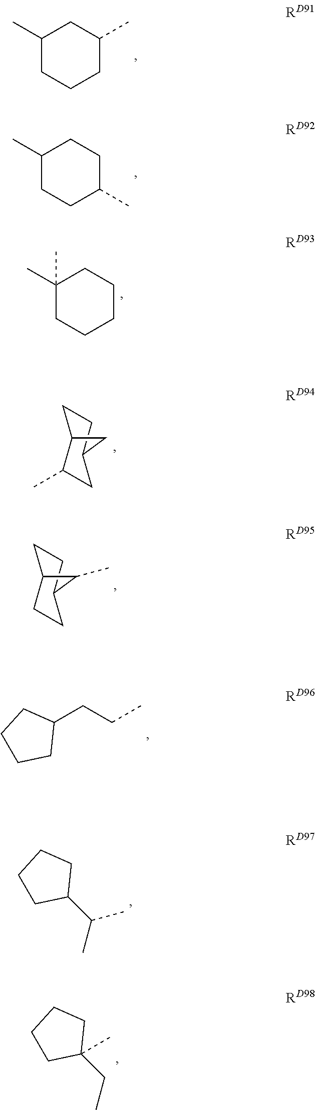

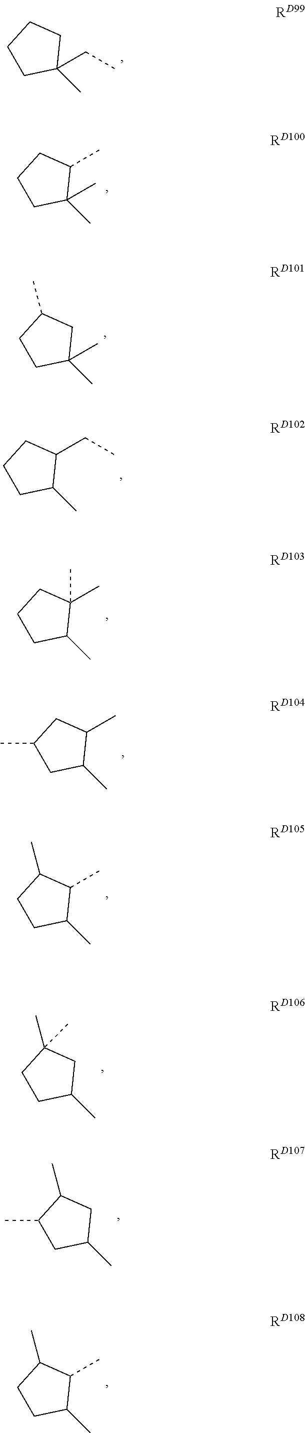

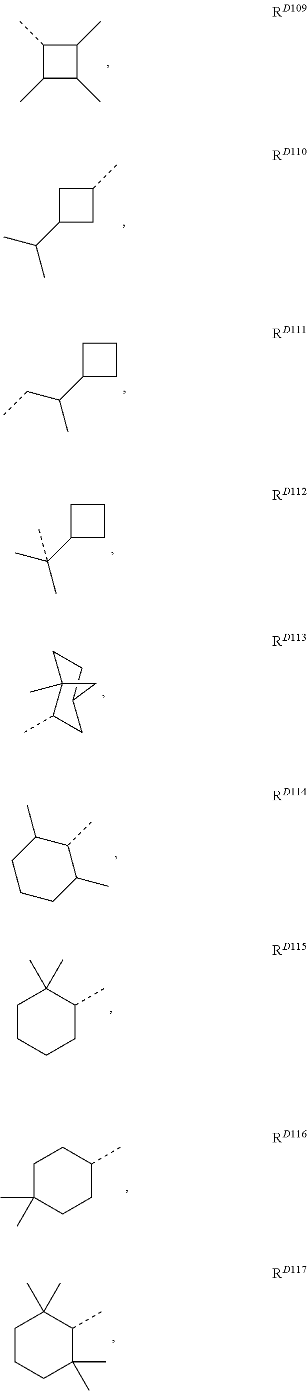

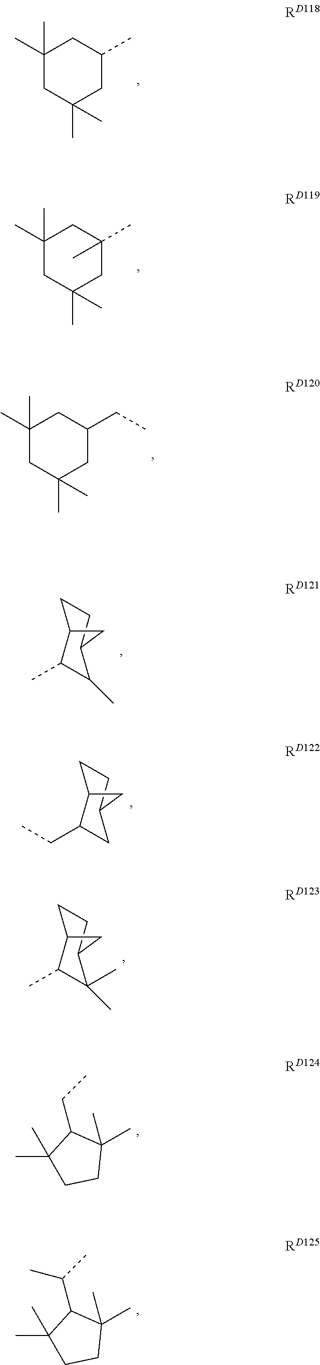

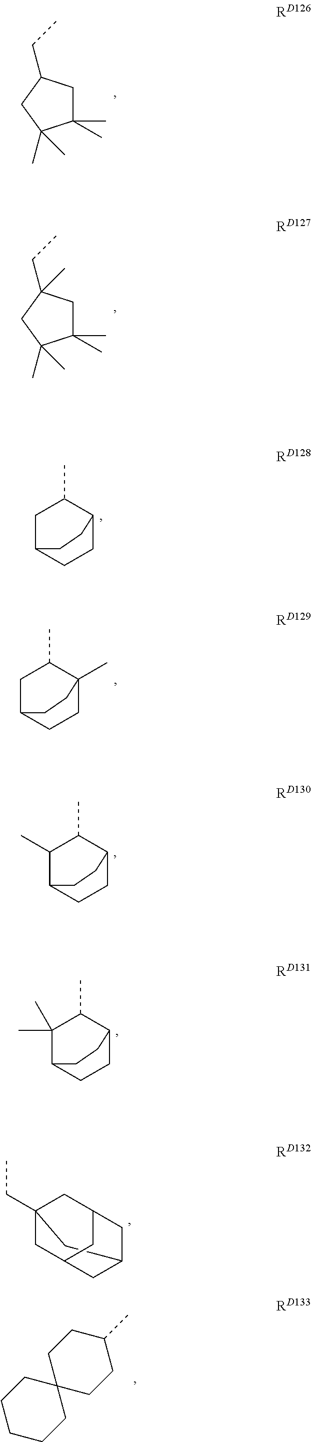

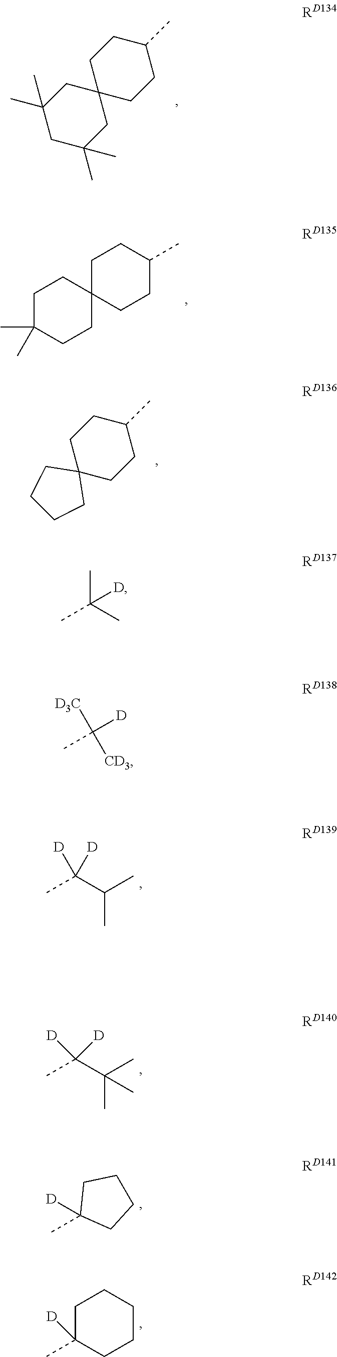

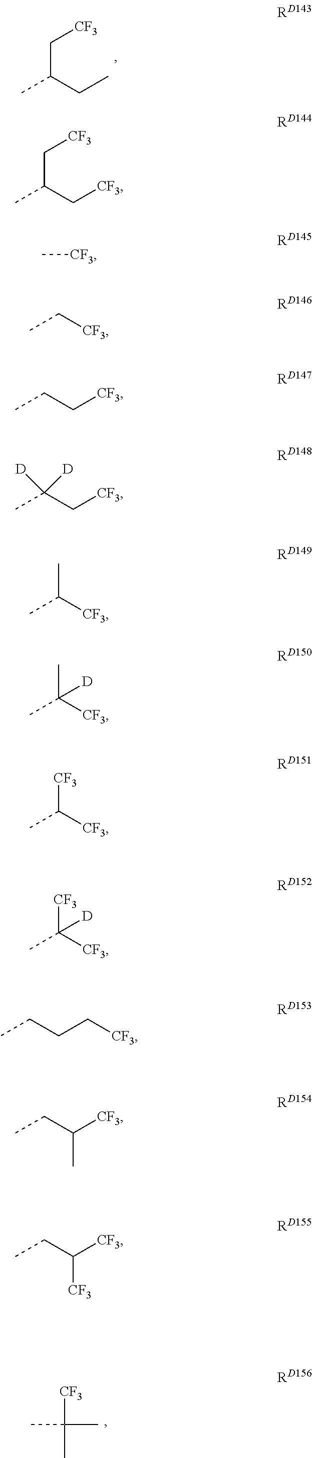

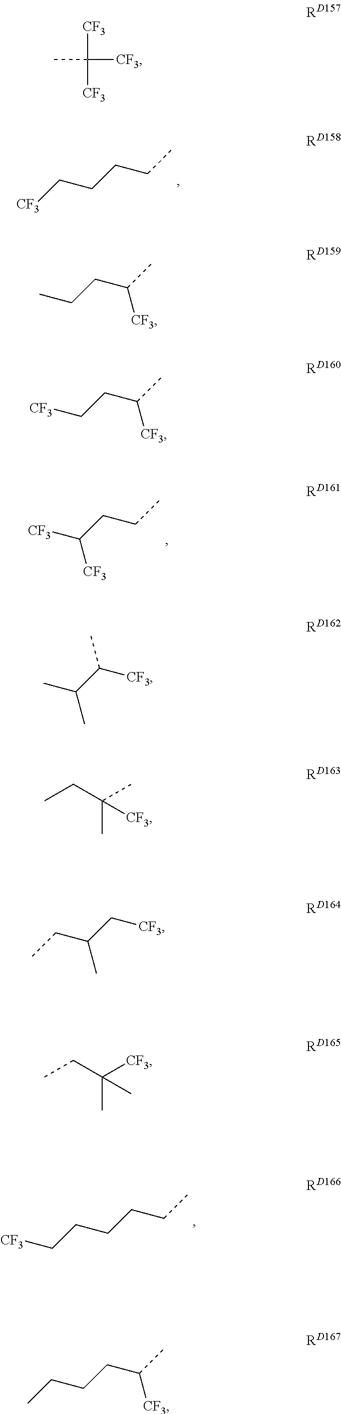

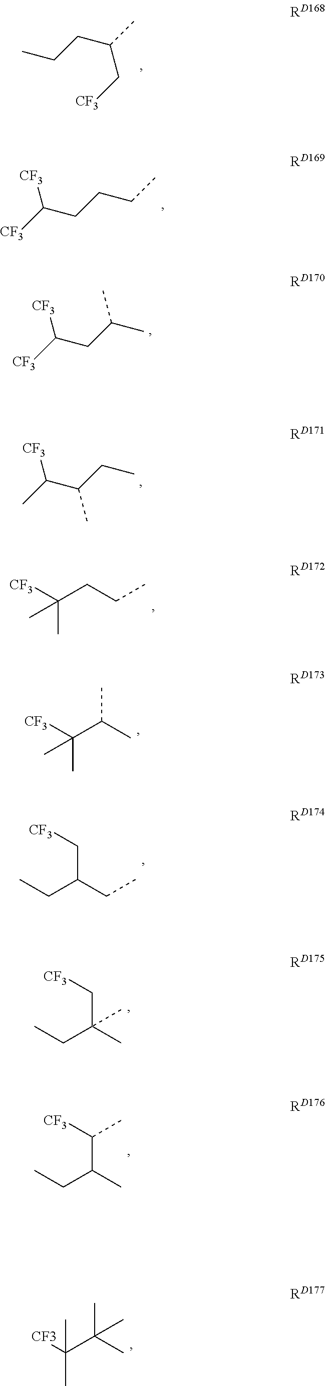

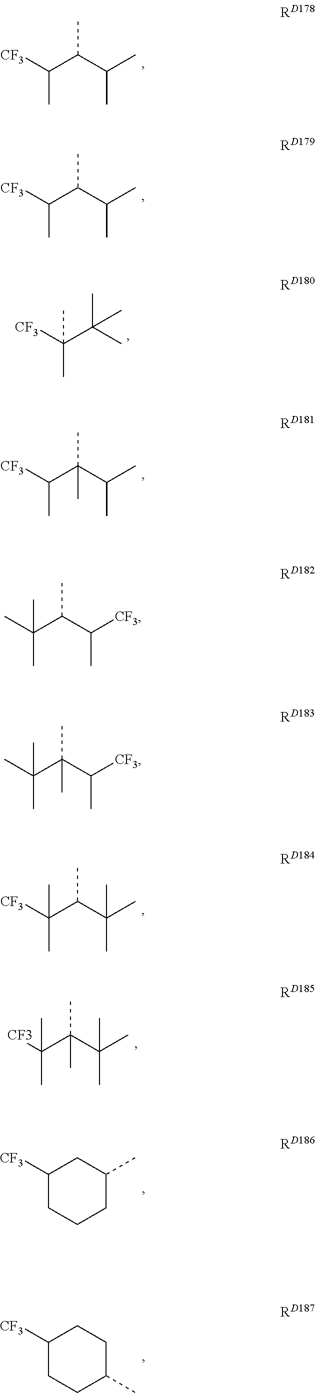

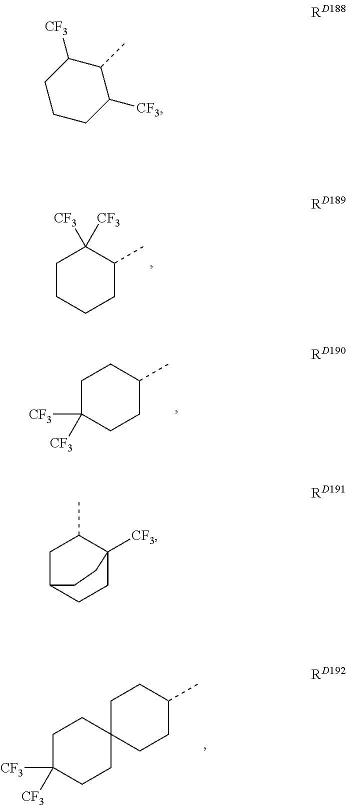

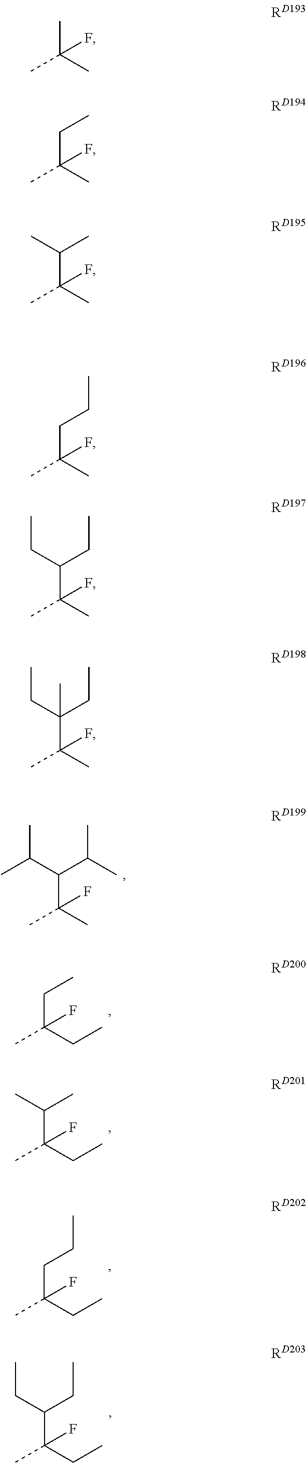

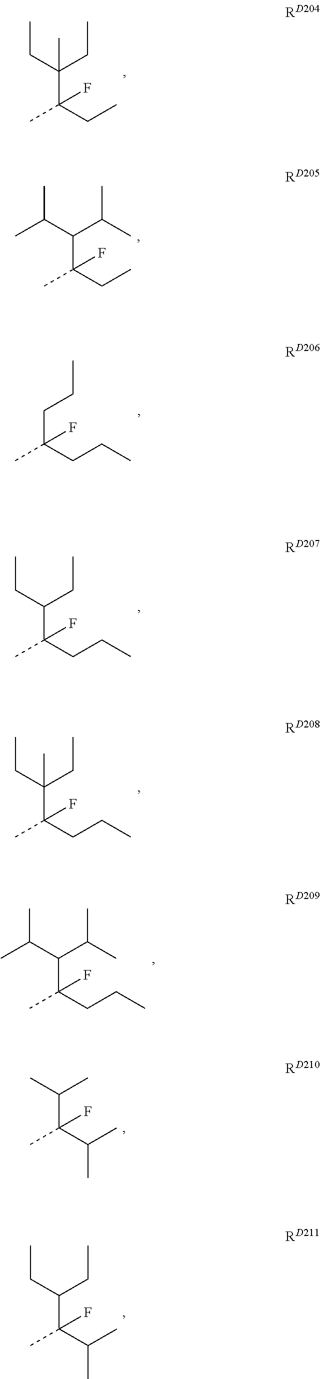

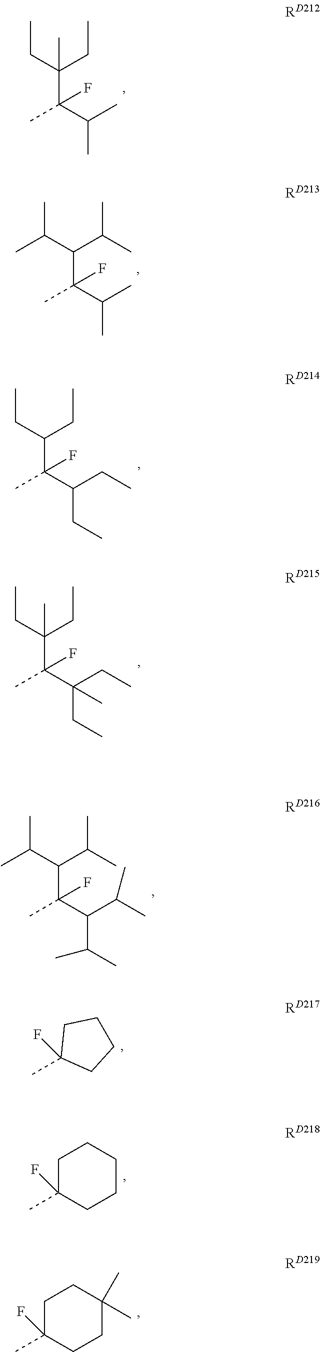

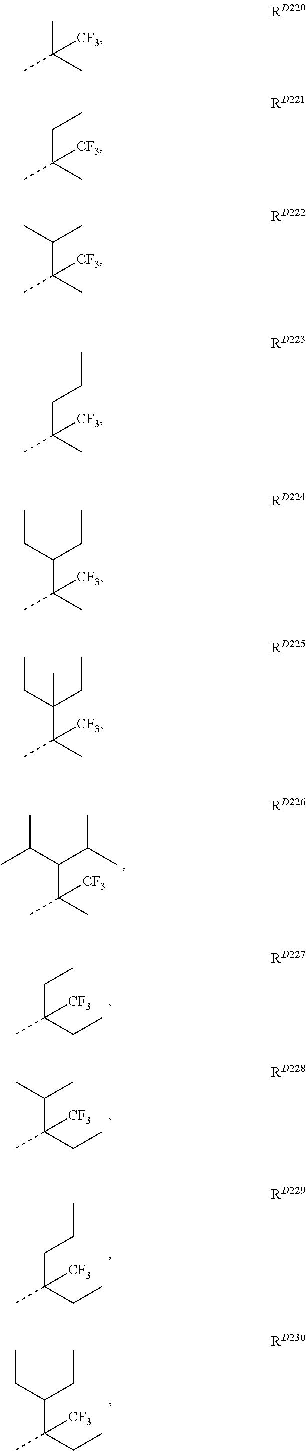

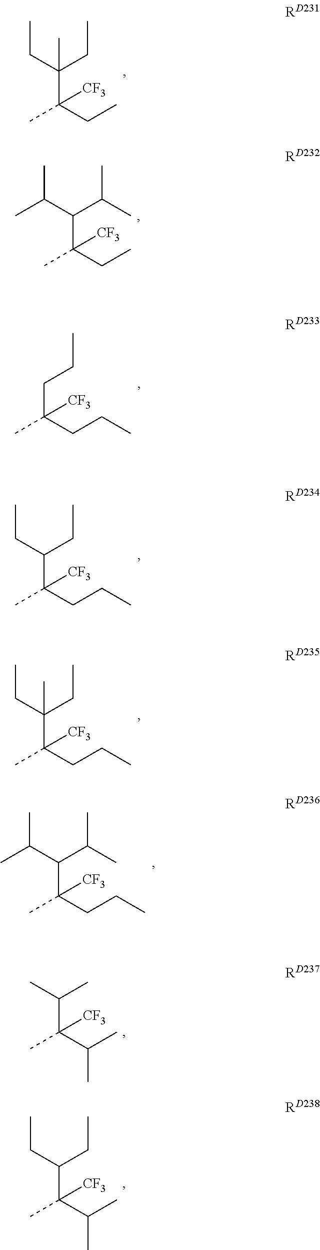

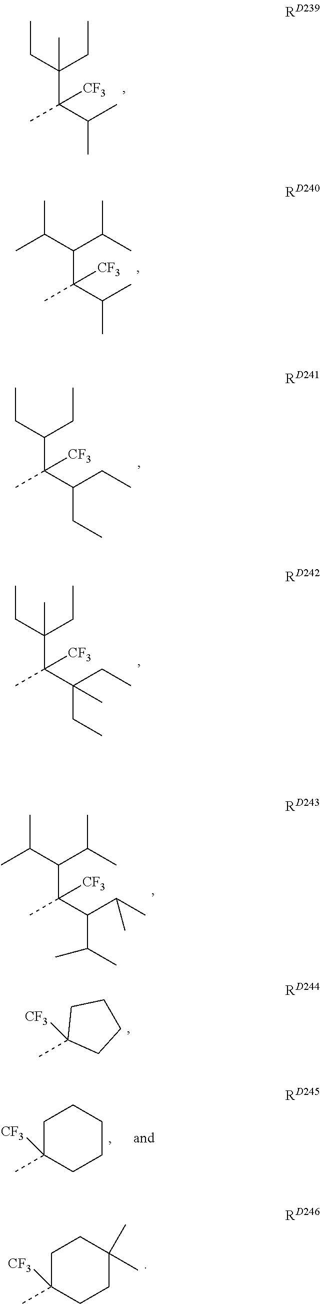

14. The compound of claim 1, wherein the compound is selected from the group consisting of

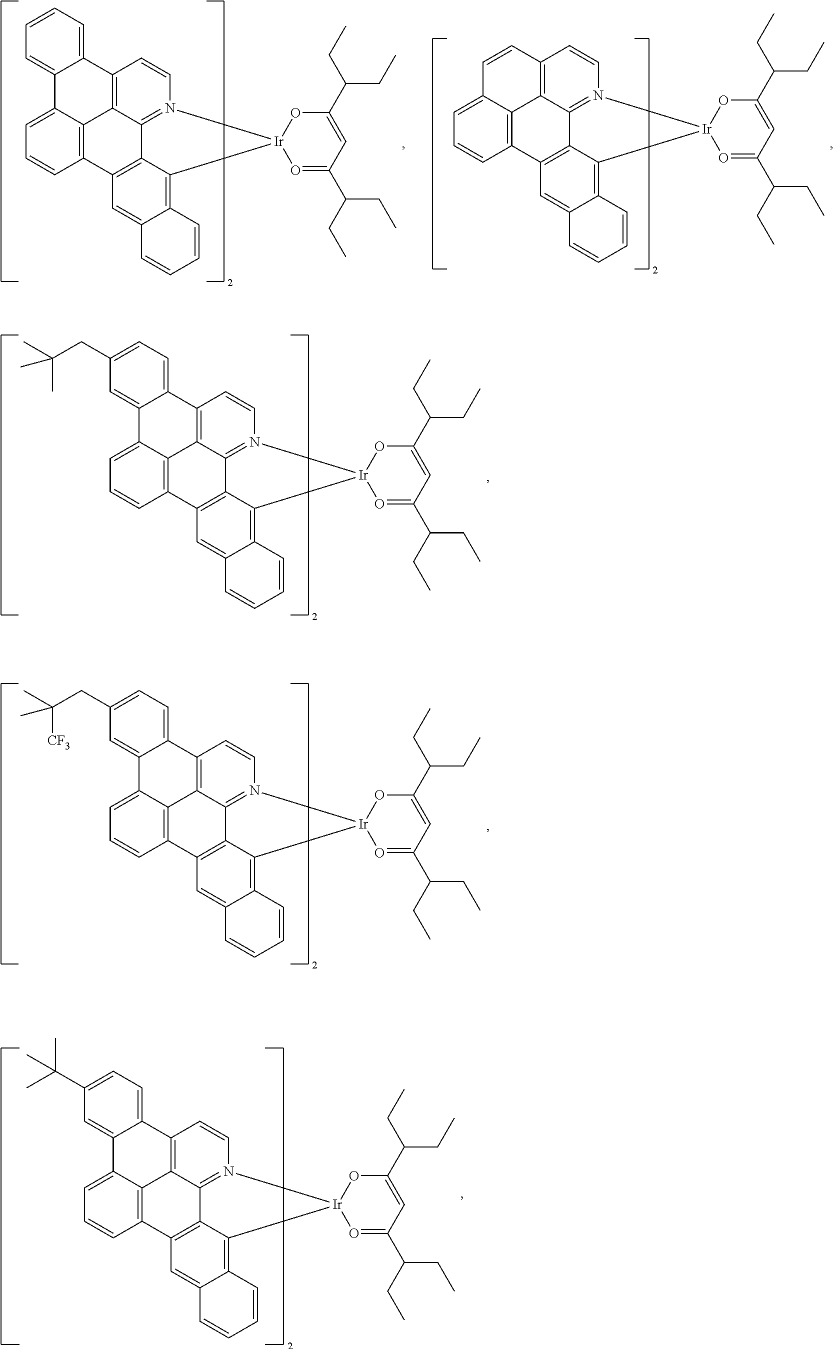

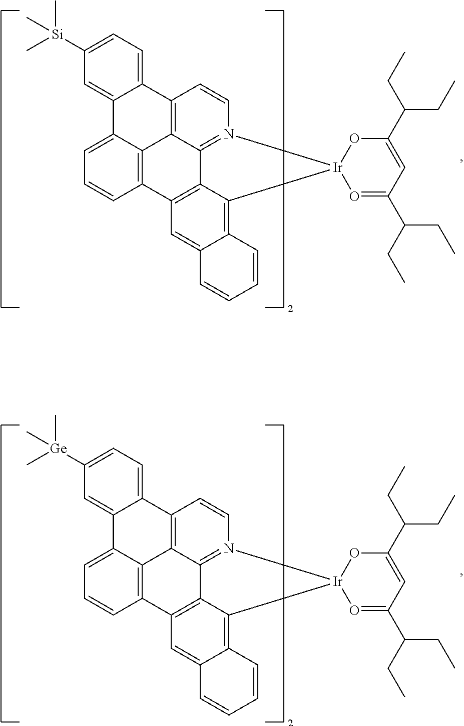

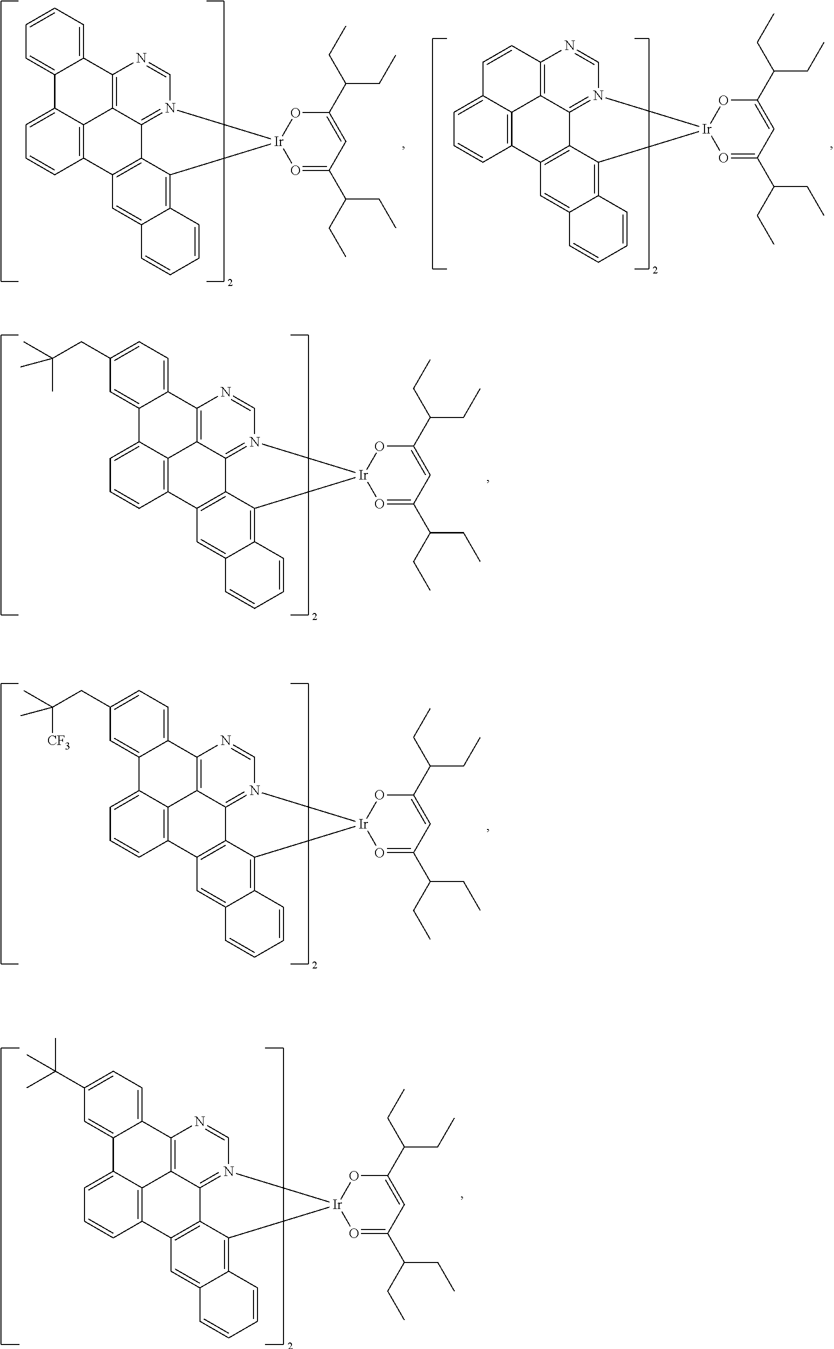

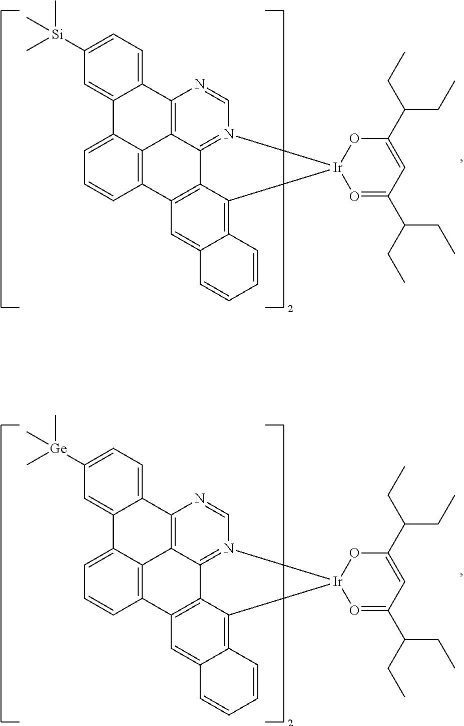

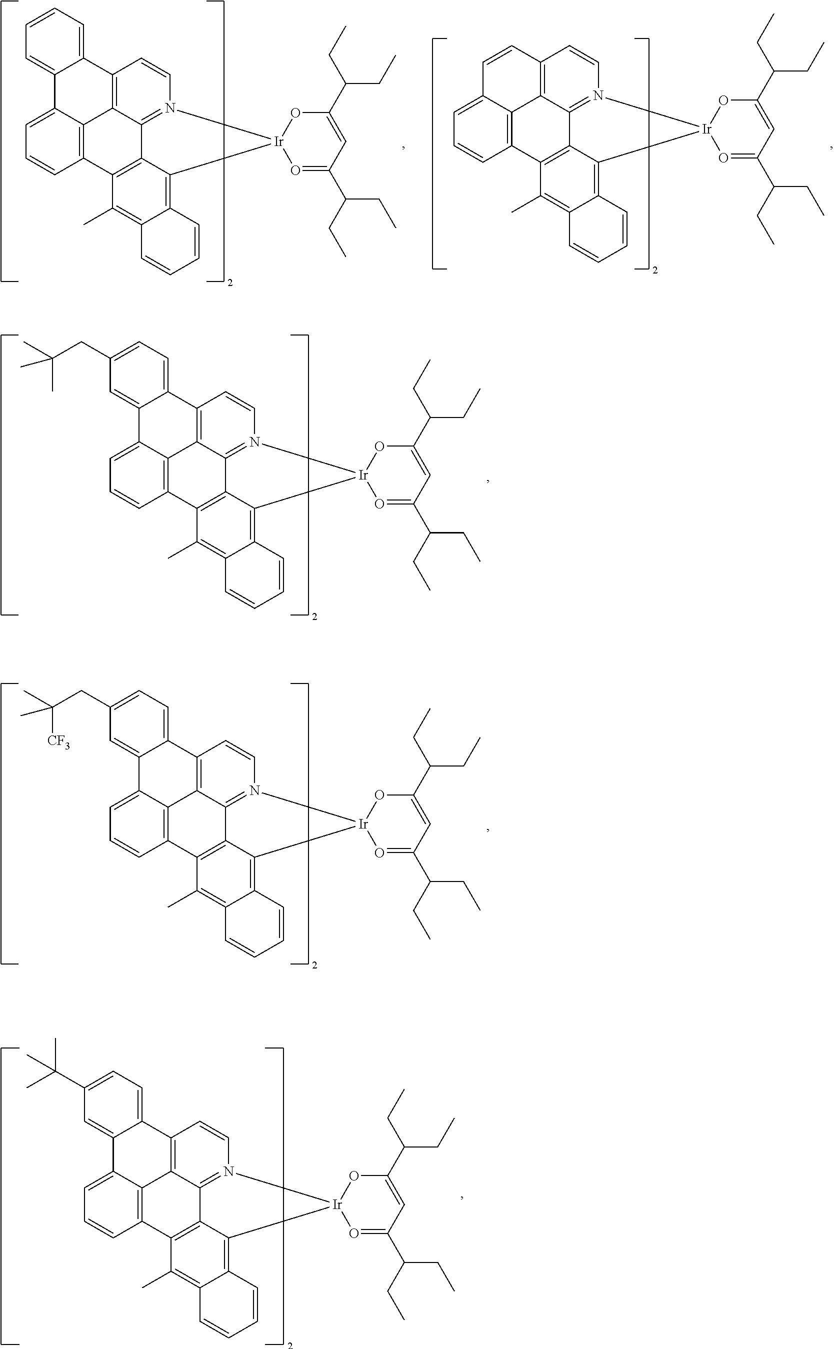

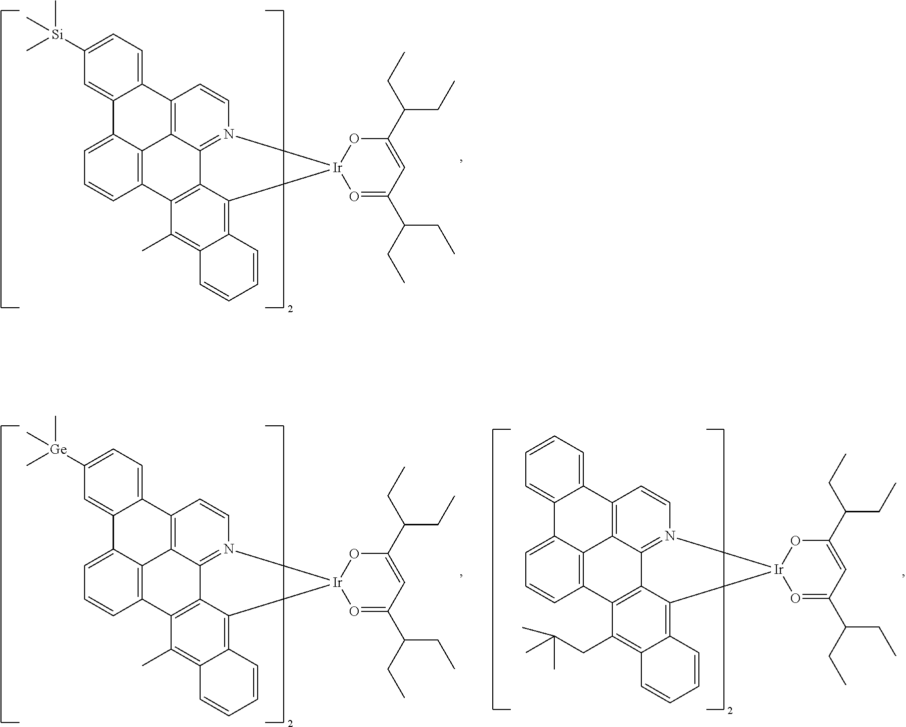

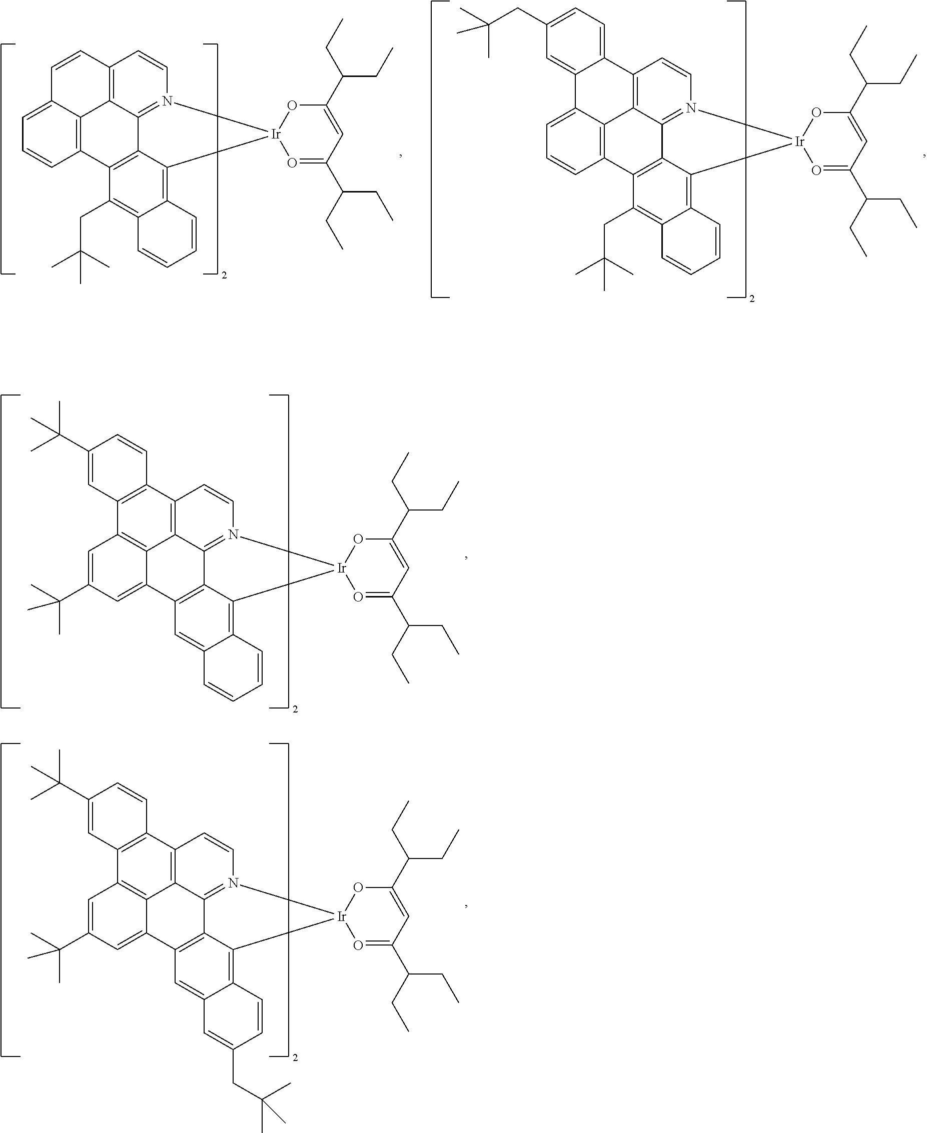

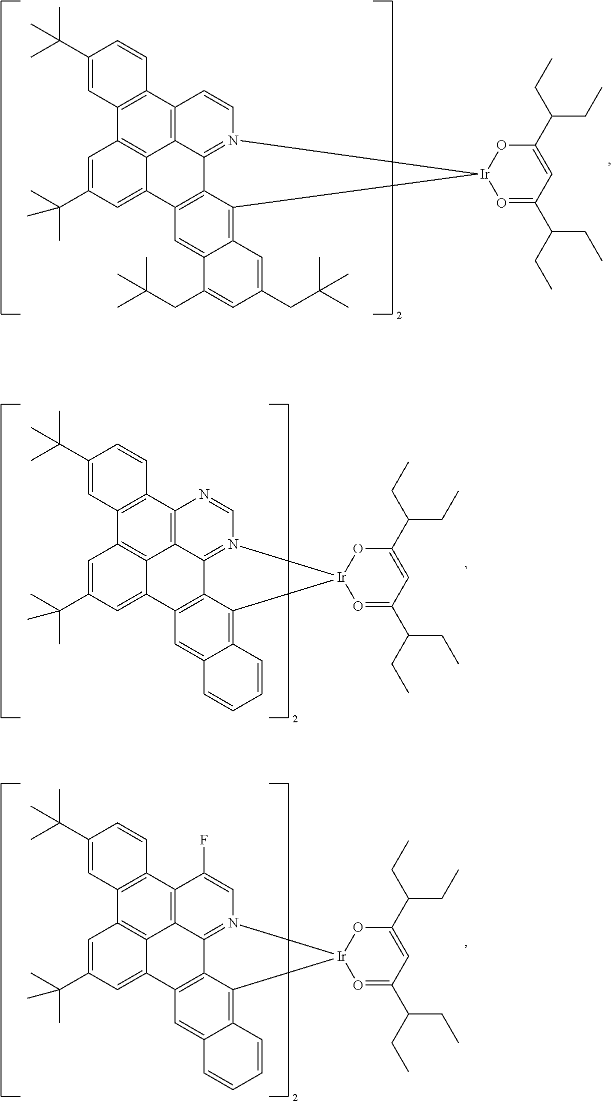

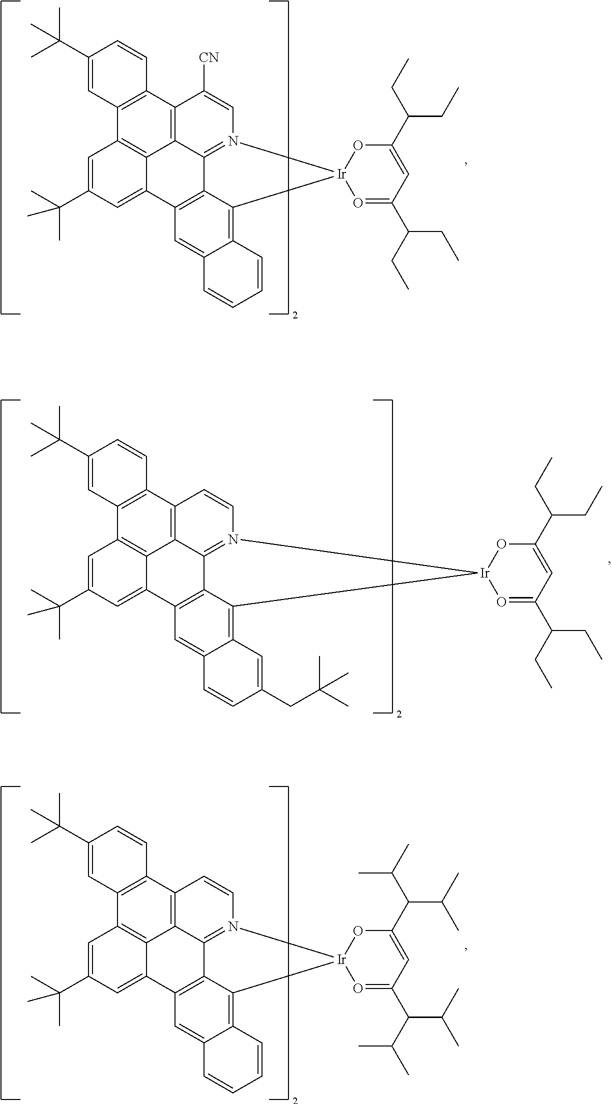

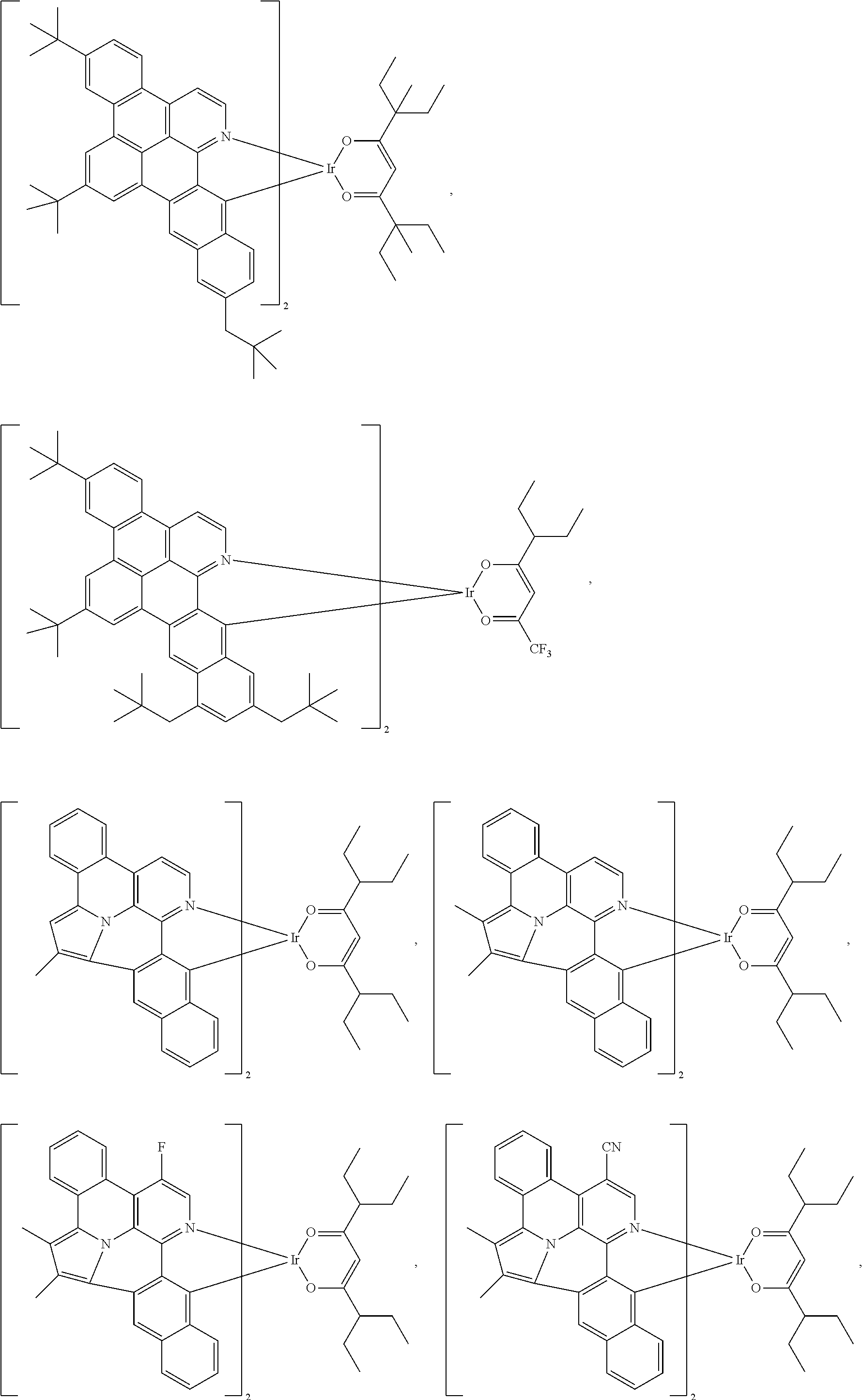

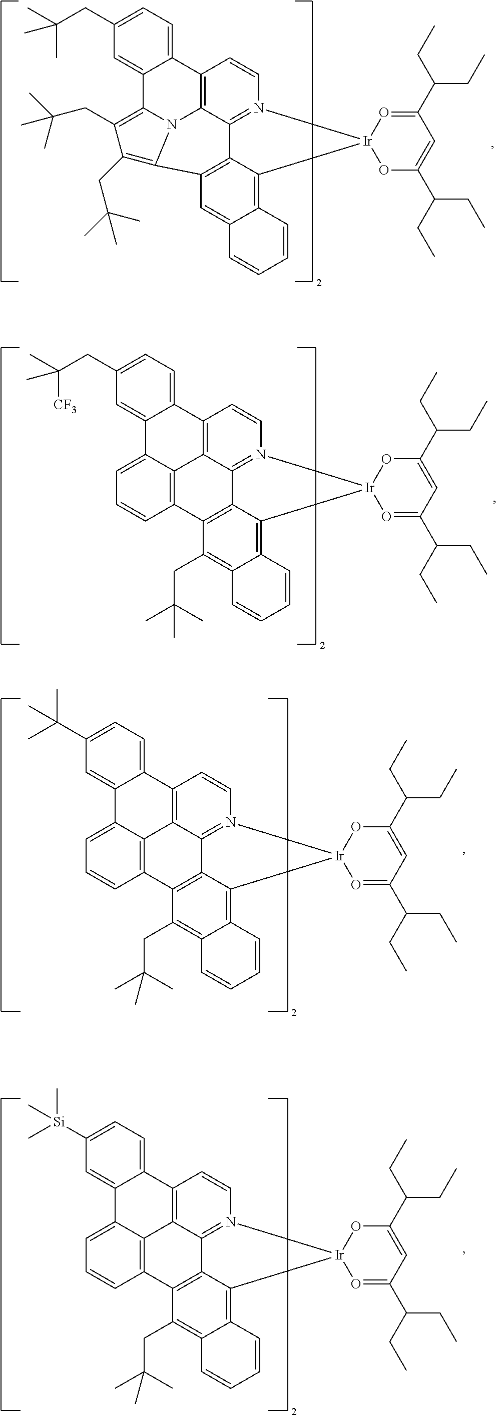

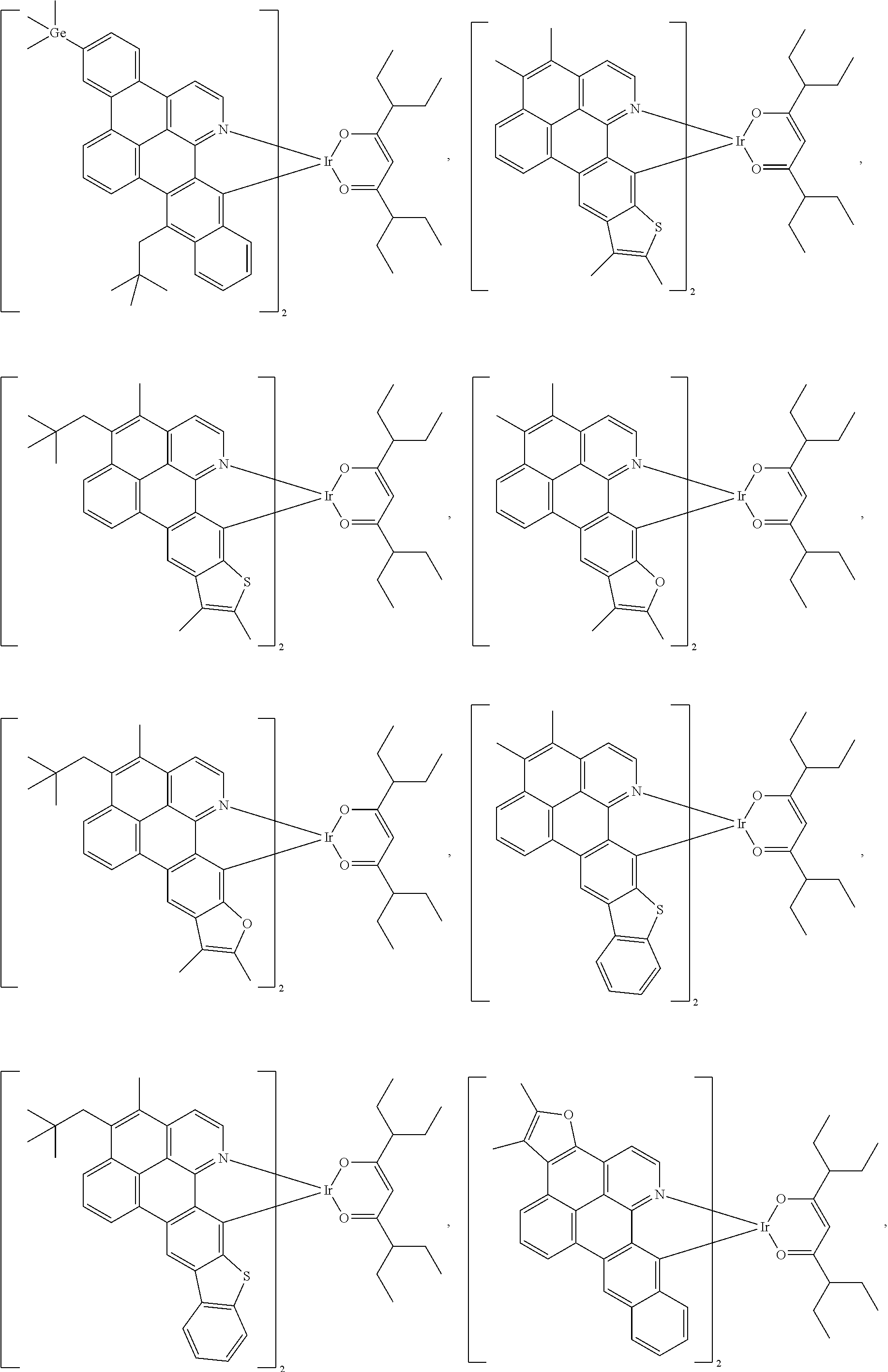

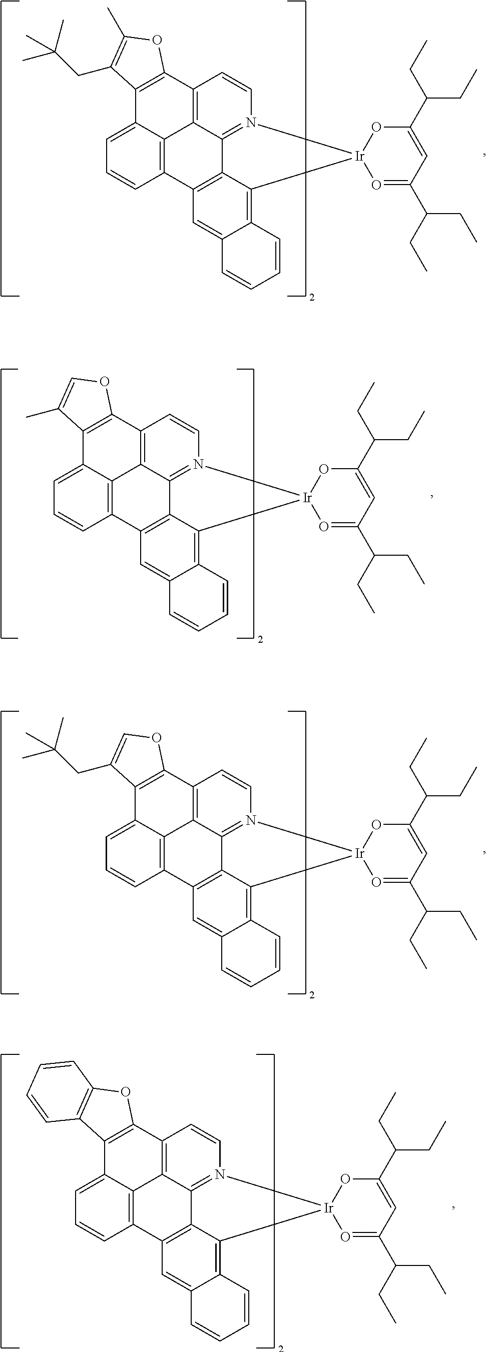

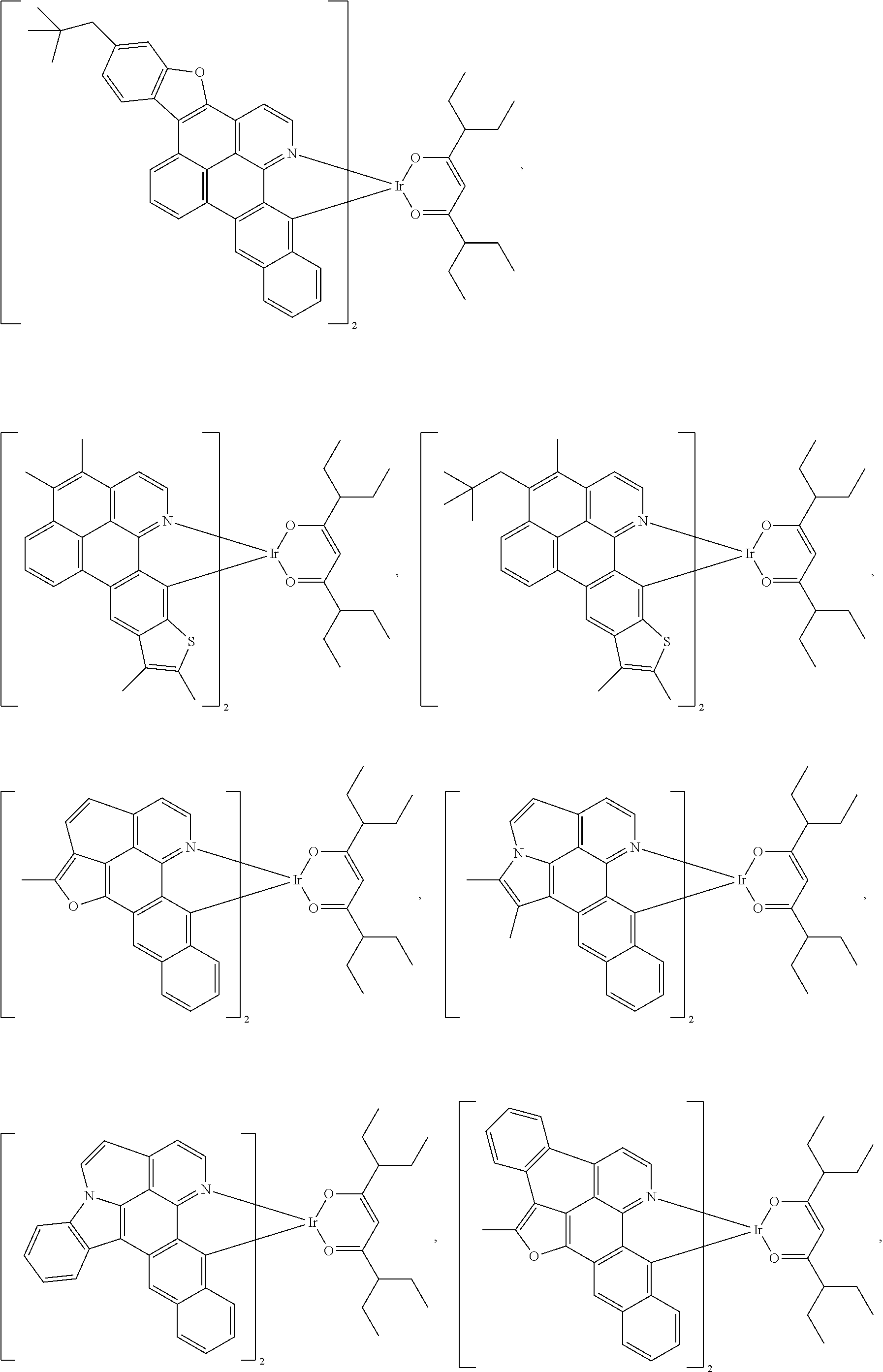

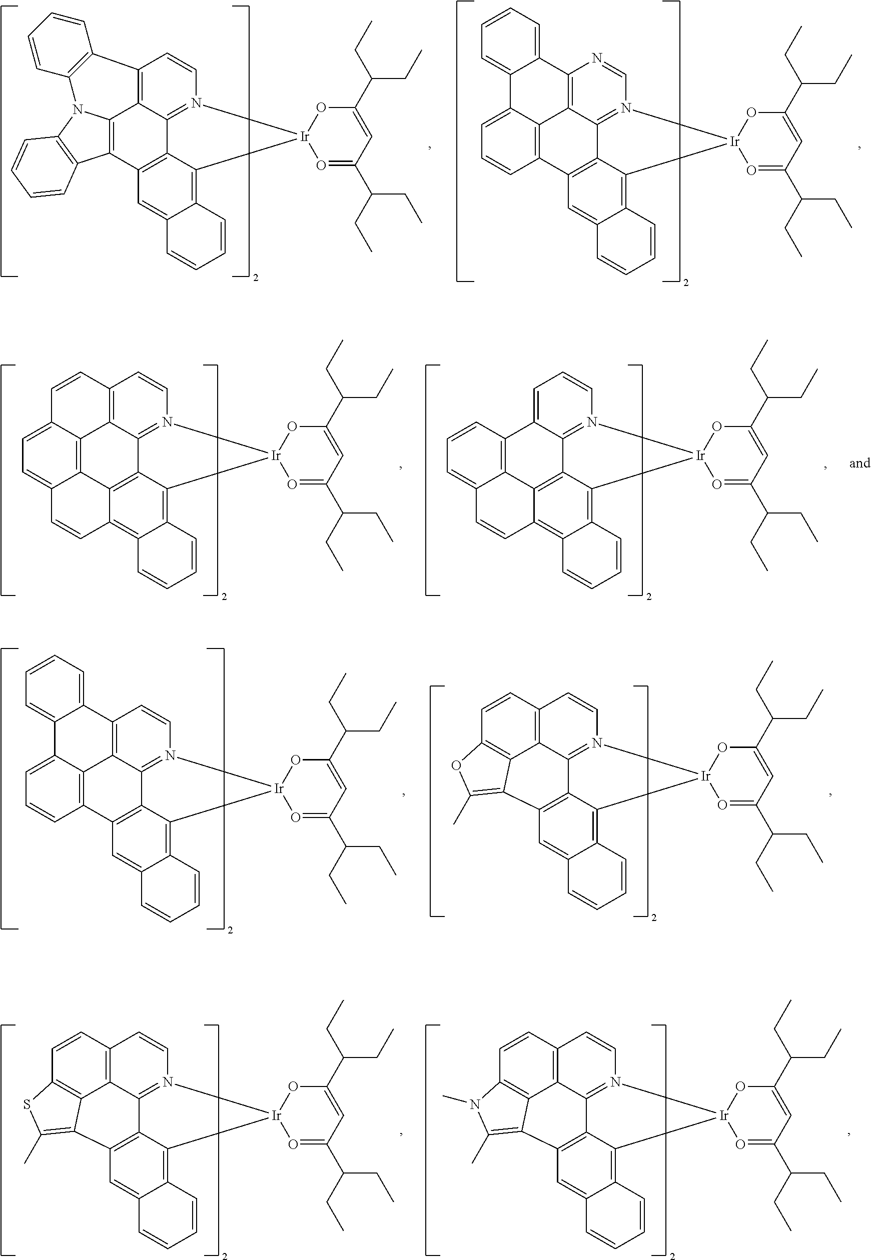

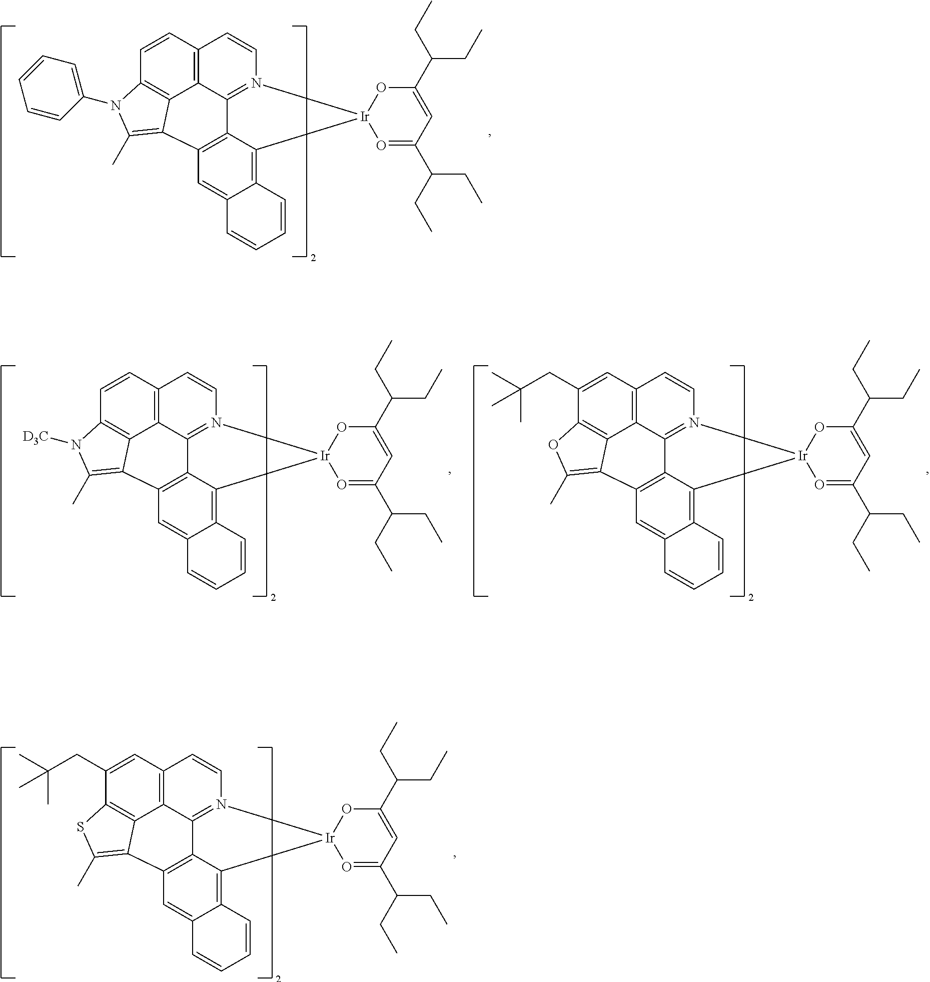

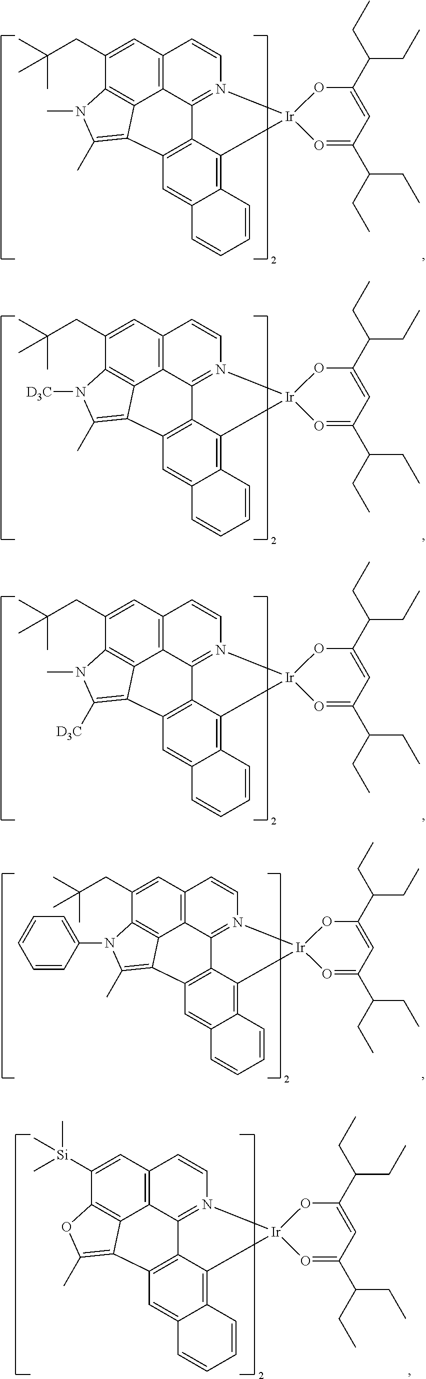

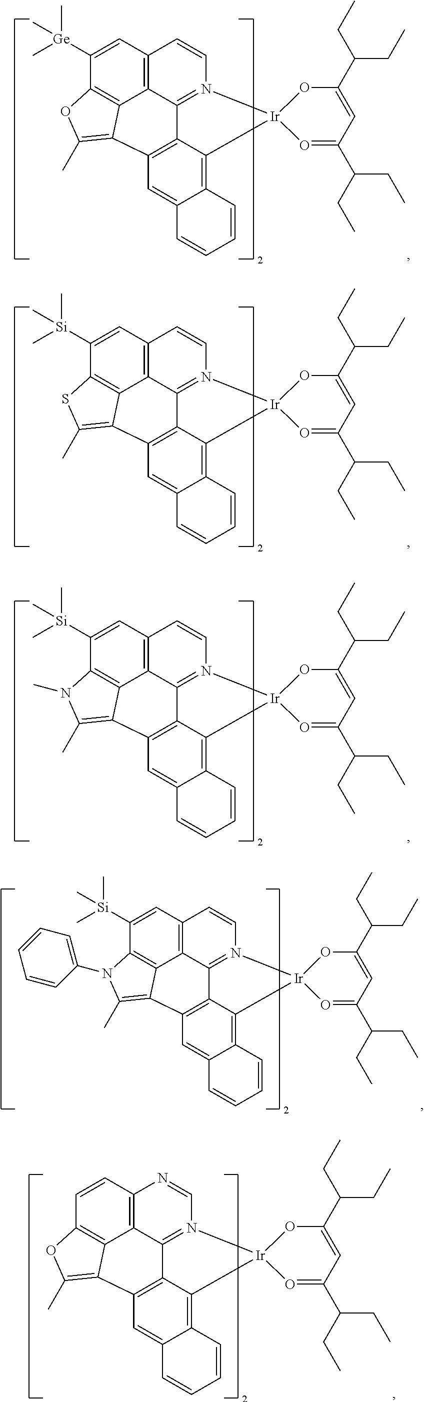

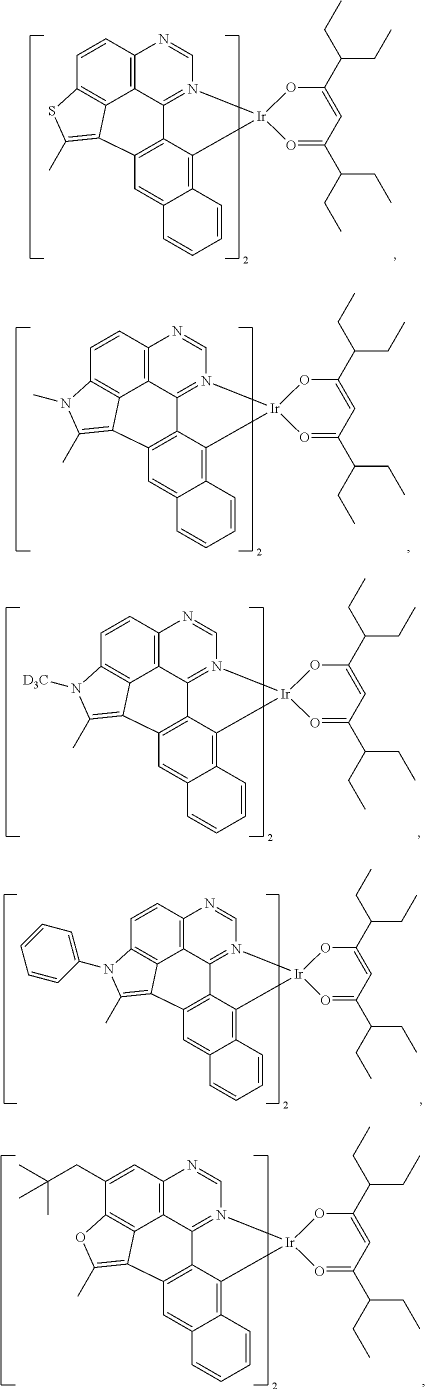

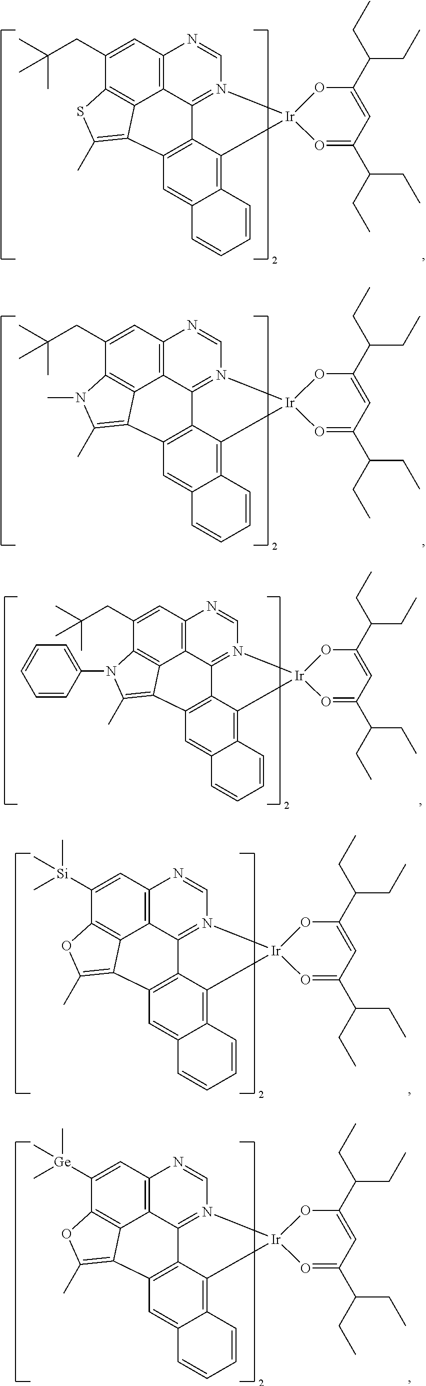

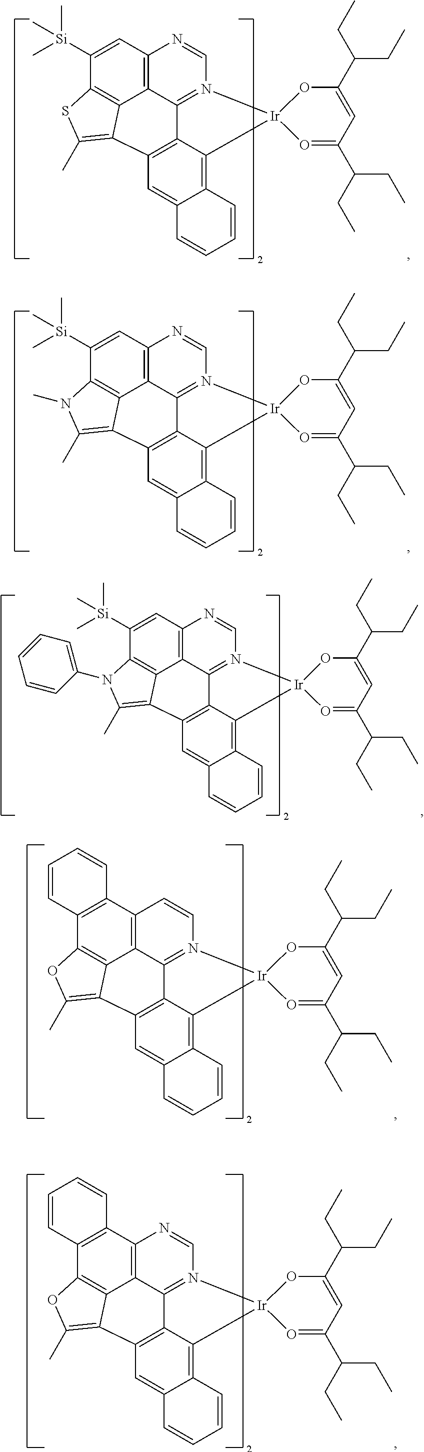

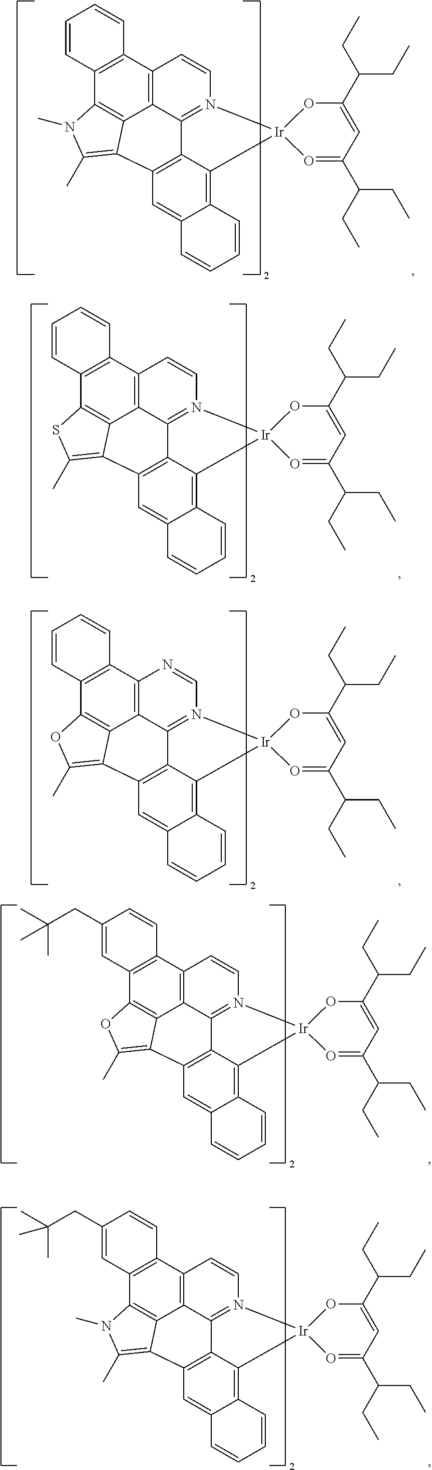

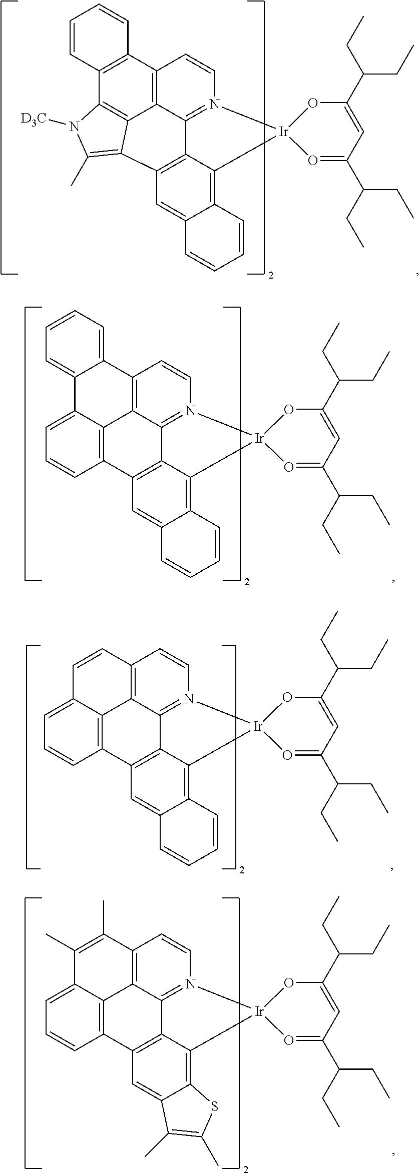

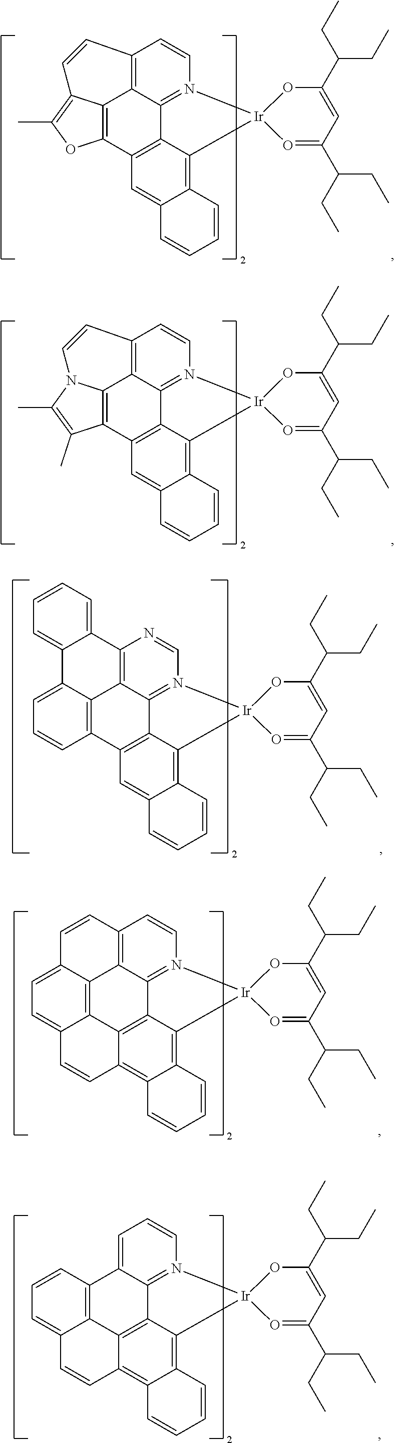

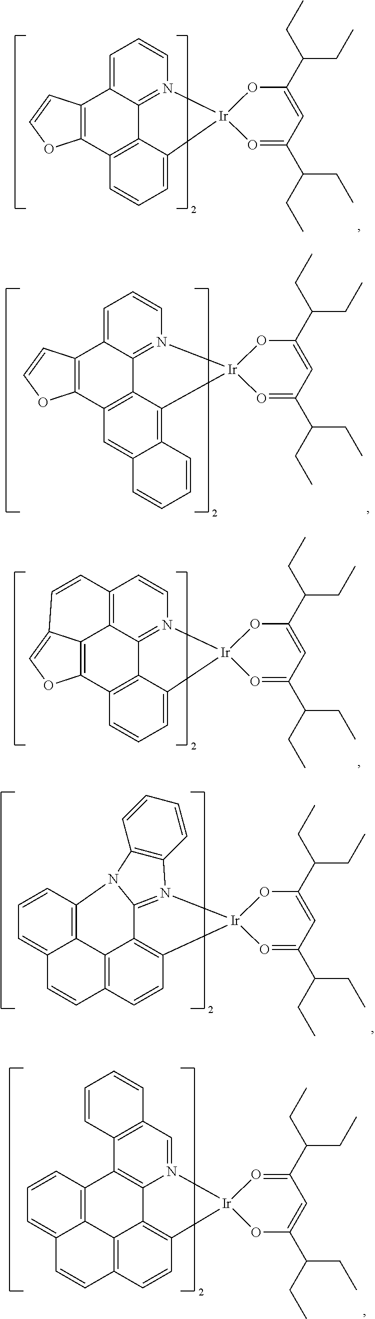

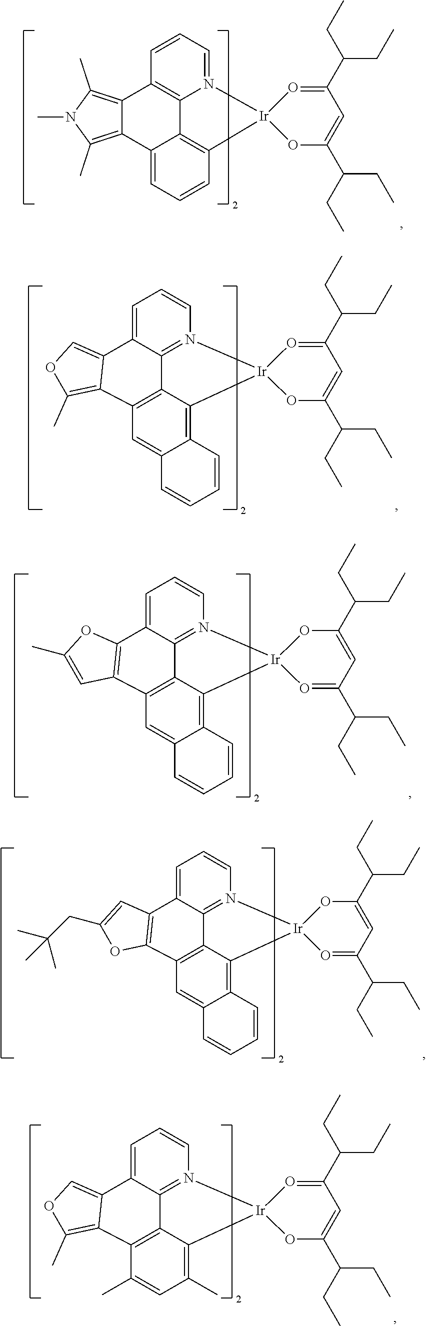

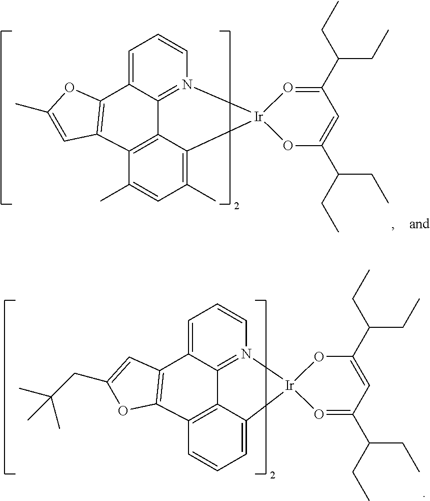

15. The compound of claim 10, wherein the compound has the structure of 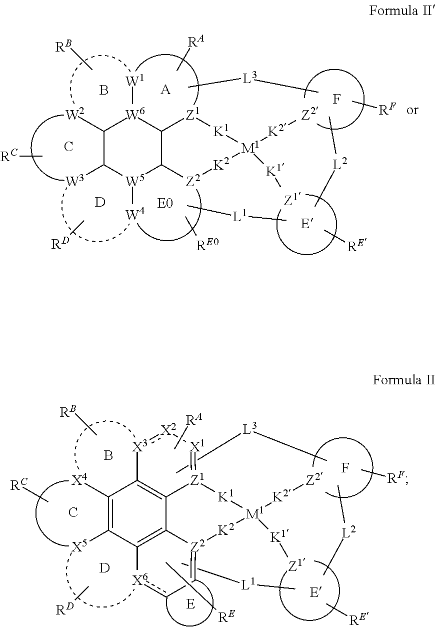
wherein:
M¹ is Pd or Pt;
moieties E′ and F are each independently a monocyclic ring or a polycyclic fused ring system, wherein the monocyclic ring or each ring of the polycyclic fused ring system is independently a 5-membered or 6-membered carbocyclic or heterocyclic ring;
Z¹ and Z² are each independently C or N;
K¹, K², K^{1′}, and K^{2′} are each independently selected from the group consisting of a direct bond, O, and S, wherein at least two of them are direct bonds;
L¹, L², and L³ are each independently absent or selected from the group consisting of a direct bond, BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof, wherein at least one of L¹ and L² is present;
R^{E′} and R^{F} each independently represents zero, mono, or up to a maximum allowed number of substitutions to its associated ring;
each of R, R′, R^{E′}, and R^{F} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
two adjacent R^{A}, R^{B}, R^{C}, R^{D}, R^{E}, R^{E′}, and R^{F} can be joined or fused together to form a ring.

16. A compound comprising a first ligand L_{A*} of Formula I*: 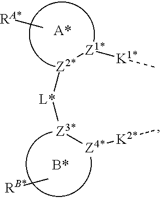
wherein each moiety A* and moiety B* is independently a monocyclic ring or a polycyclic fused ring system,
wherein the monocyclic ring or each ring of the polycyclic fused ring system is independently a 5-membered to 10-membered carbocyclic or heterocyclic ring;
wherein Z^{1*}-Z^{4*} are each independently C or N;
wherein each R^{A*} and R^{B*} independently represents mono to the maximum allowable substitution, or no substitution;
wherein K^{1*} and K^{2*} are each independently selected from the group consisting of a direct bond, O, S, N(R^{α}), P(R^{α}), B(R^{α}), C(R^{α})(R^{β}), and Si(R^{α})(R^{β});
wherein L* is selected from the group consisting of a direct bond, BR, BRR′, NR, PR, P(O)R, O, S, Se, C═O, C═S, C═Se, C═NR′, C═CR′R″, S═O, SO₂, CRR′, SiRR′, and GeRR′;
wherein each of R^{α}, R^{β}, R, R′, R^{A*}, and R^{B*} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
wherein any two substituents may be joined or fused to form a ring;
wherein L_{A*} comprises a structure of Formula II* 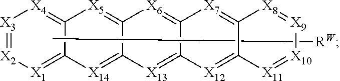
wherein each of X₁ to X₁₄ is independently C or N; each R^{W} represents mono to the maximum allowable substitution, or no substitution; and each R^{W} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and any two R^{W} may be optionally joined or fused to form a ring;
wherein L_{A*} is coordinated to a metal M having an atomic mass of at least 40;
wherein the compound is a monometallic compound;
wherein the metal M may be coordinated to other ligands; and
wherein L_{A*} may be joined with other ligands to form a tridentate, tetradentate, pentadentate, or hexadentate ligand;
with a proviso that the compound is not

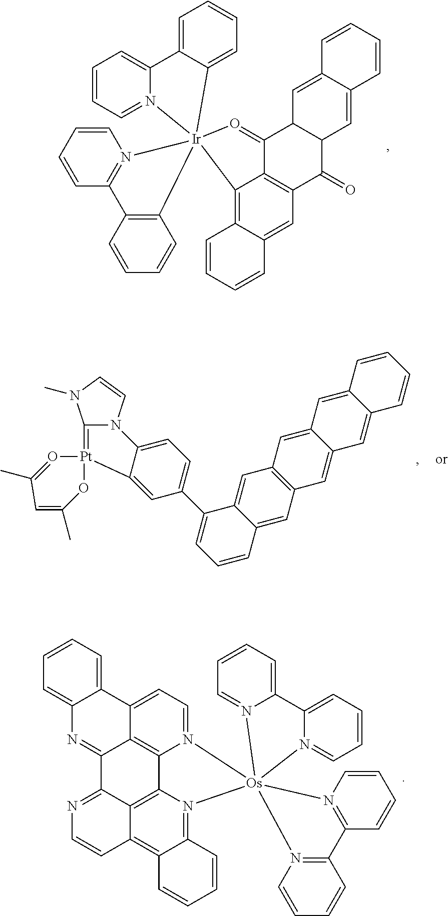

17. An organic light emitting device (OLED) comprising:
an anode;
a cathode; and
an organic layer disposed between the anode and the cathode, wherein the organic layer comprises a compound according to claim 1.

18. The OLED of claim 17, wherein the host is selected from the group consisting of: 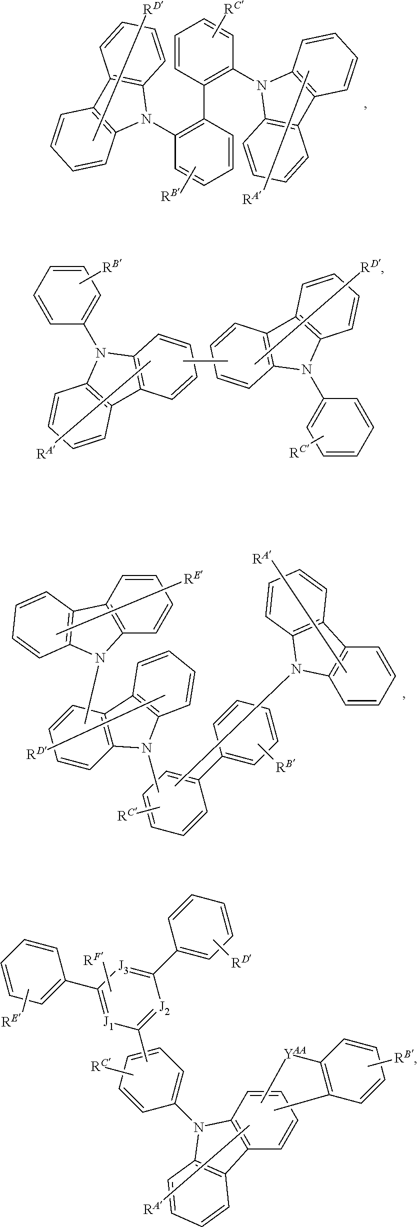 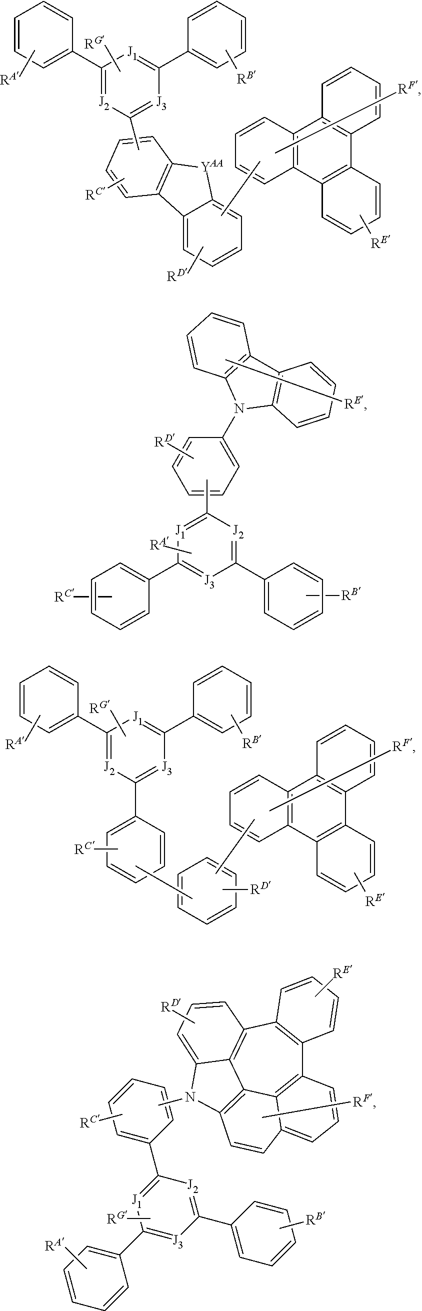 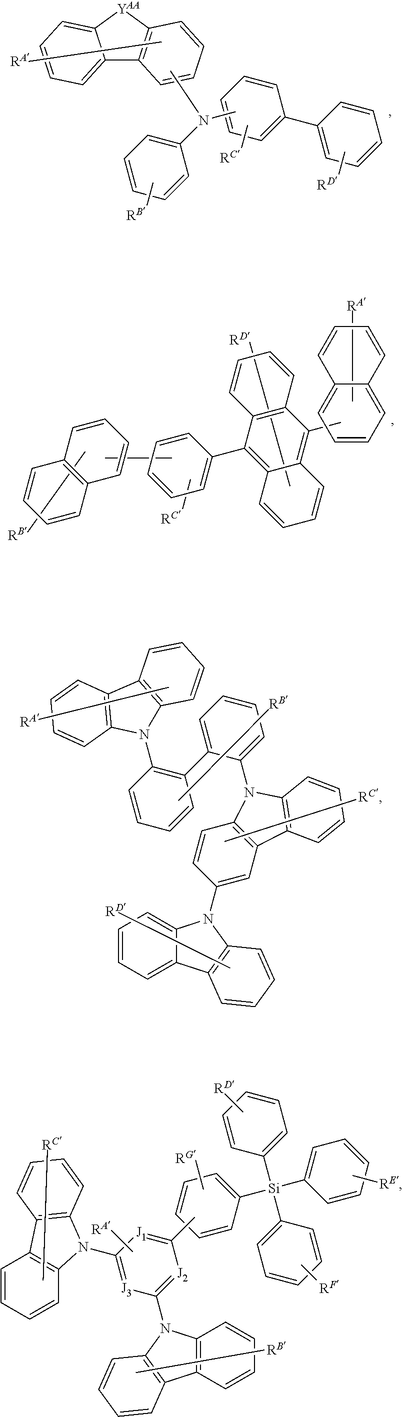 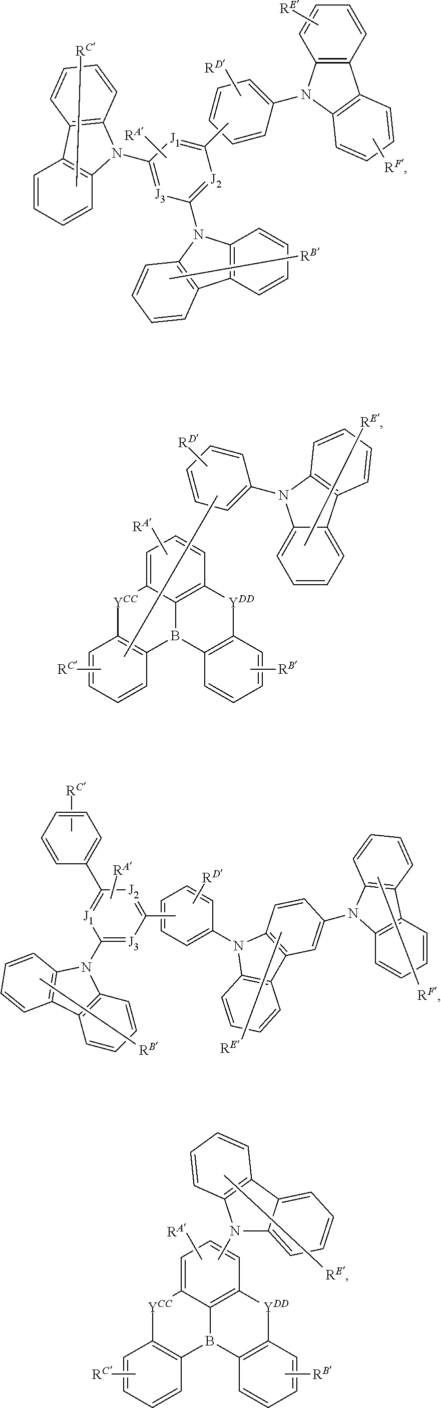 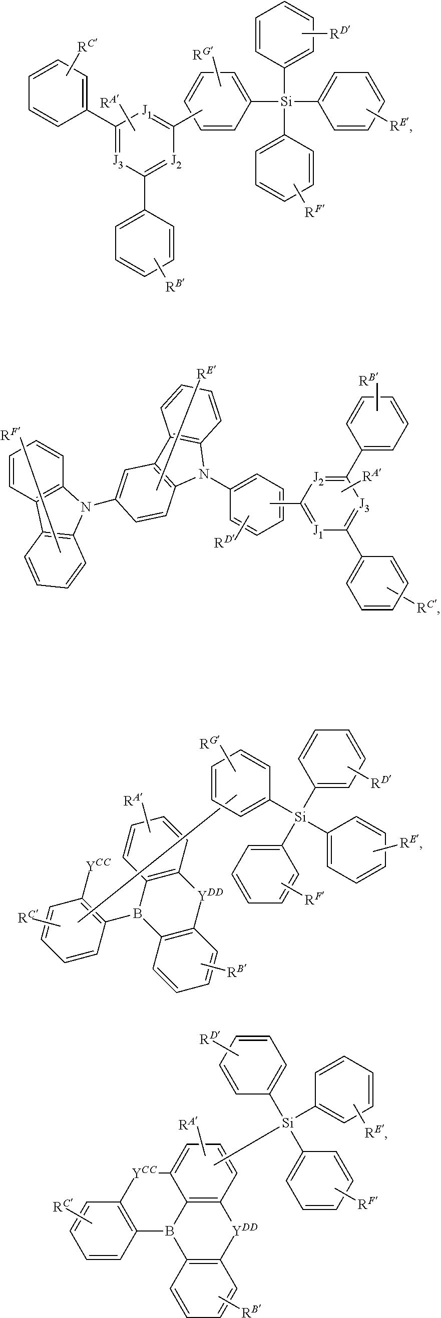 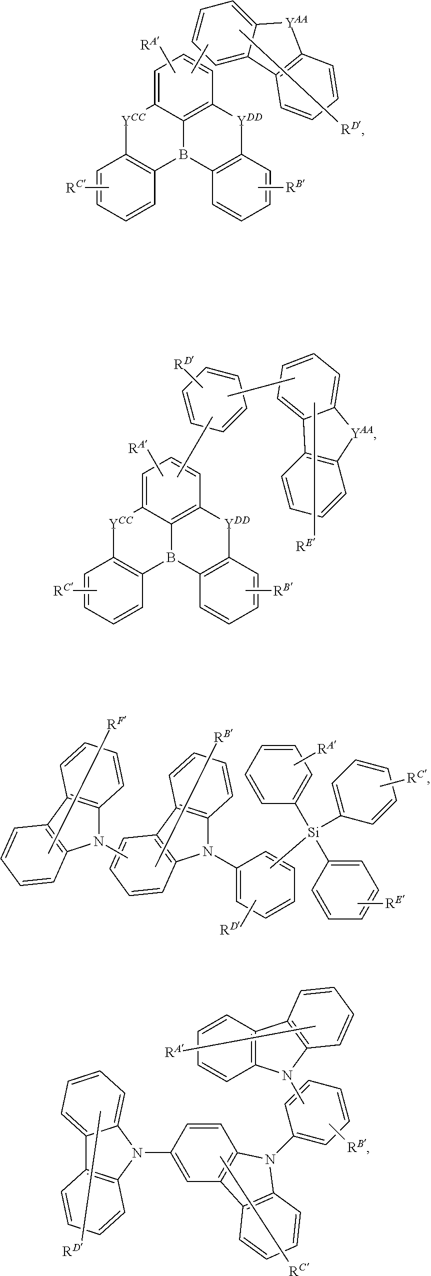 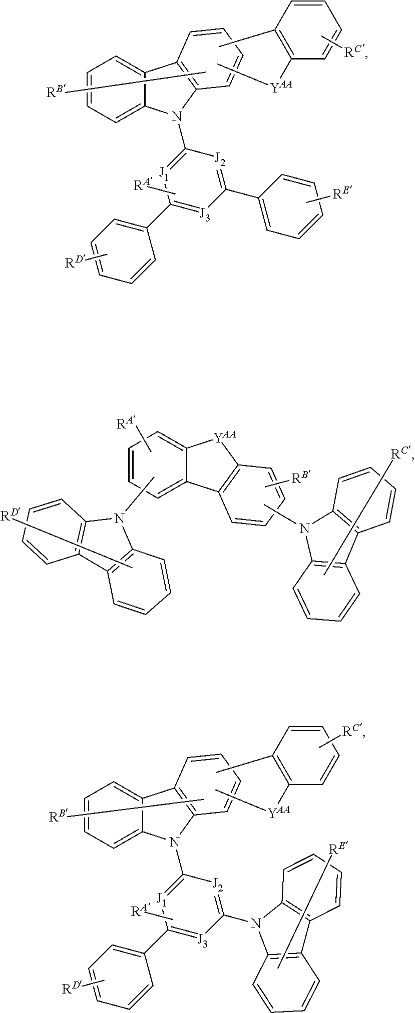 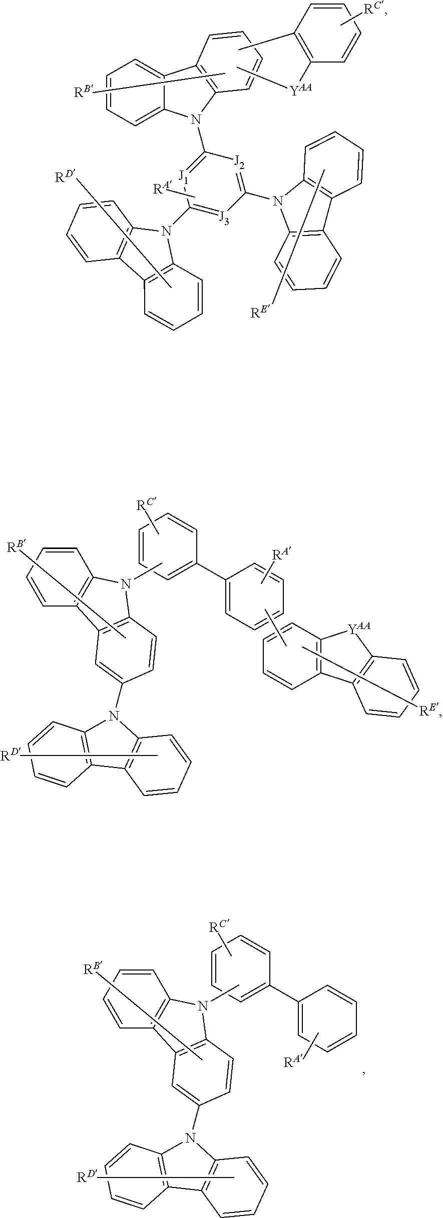 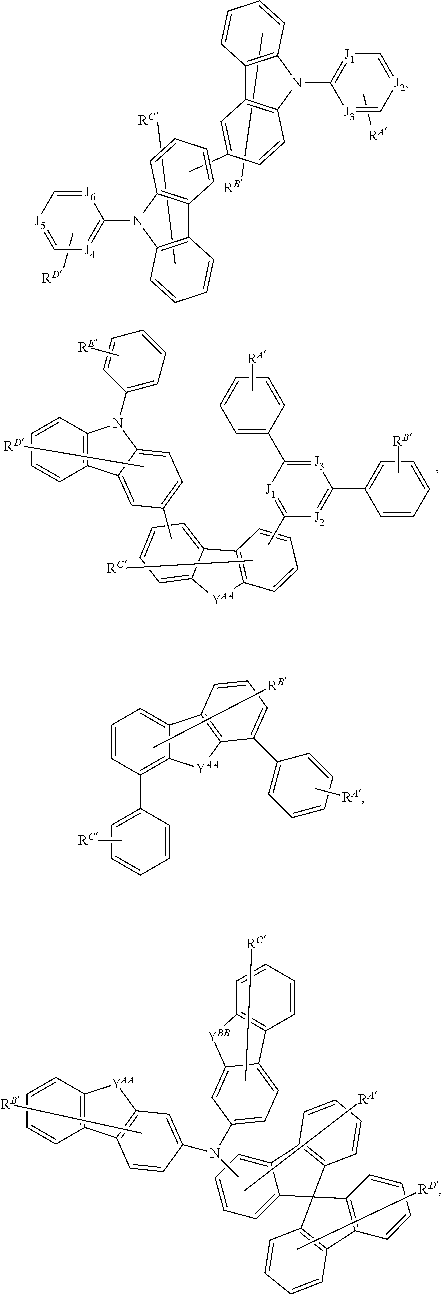 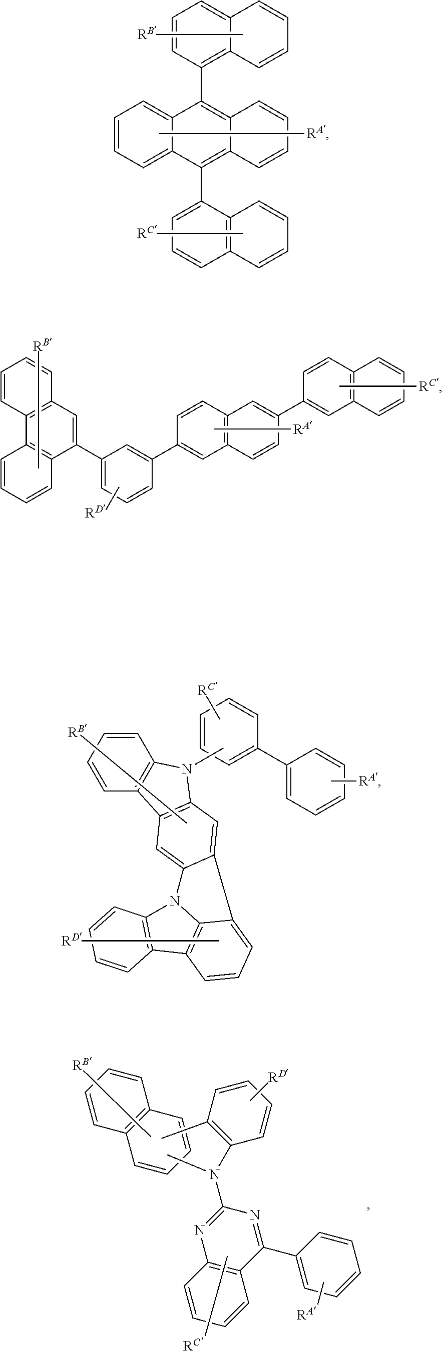 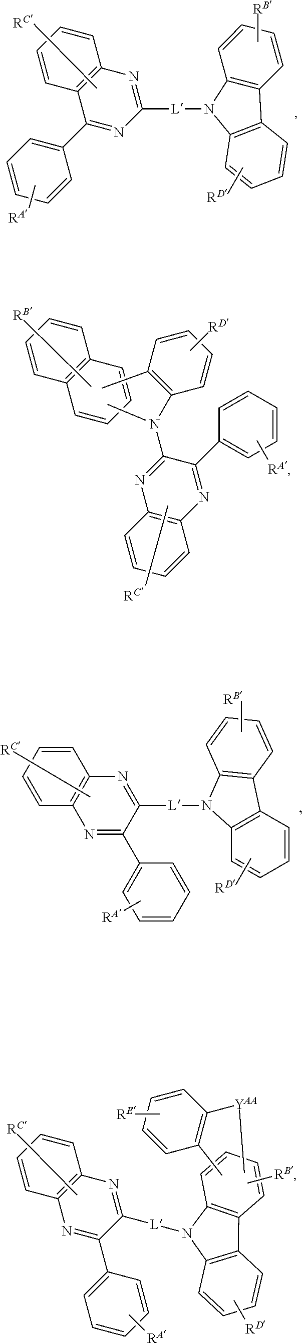 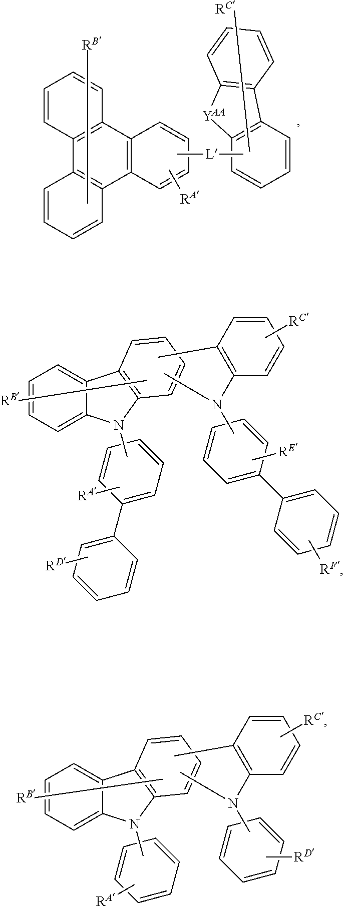 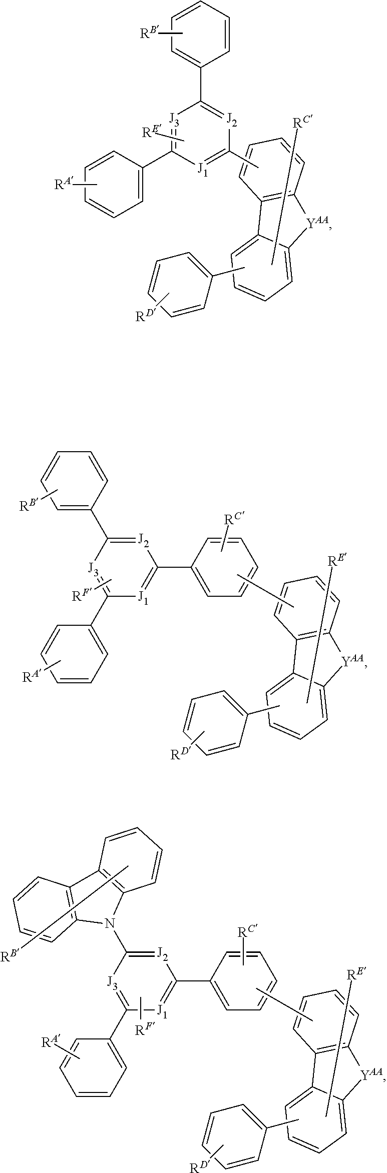 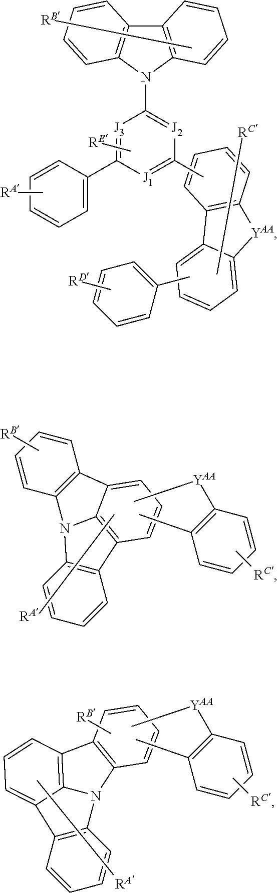 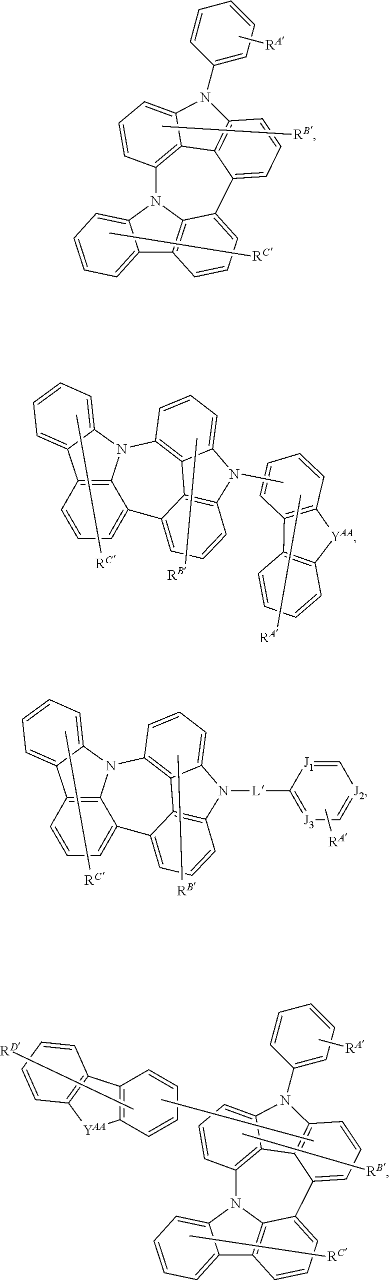 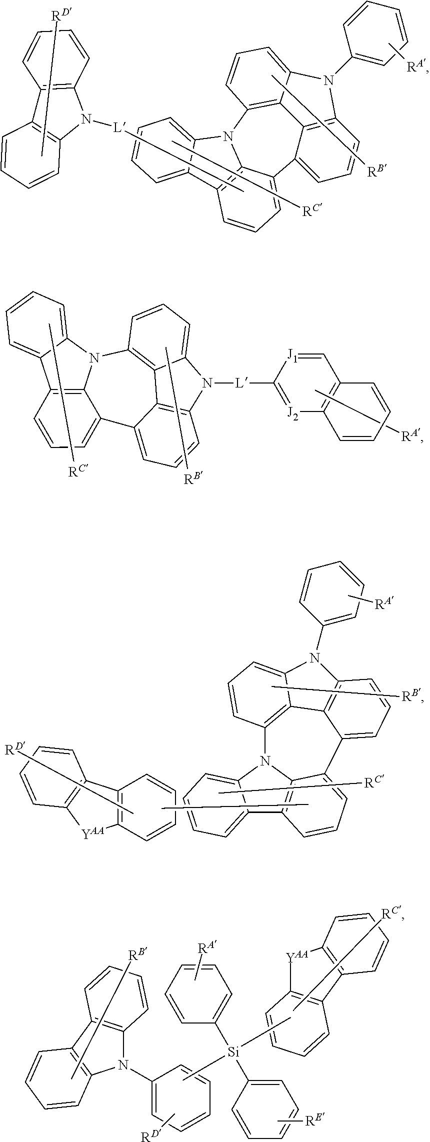 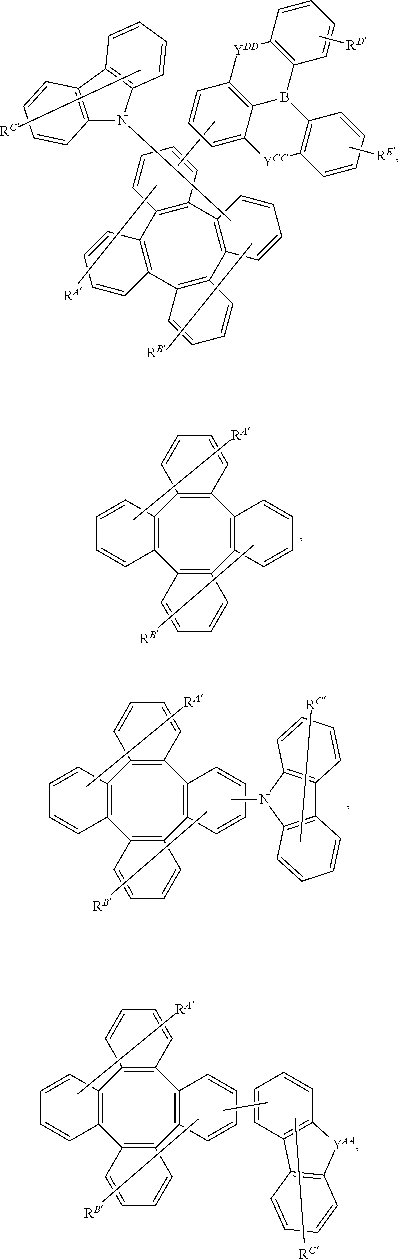 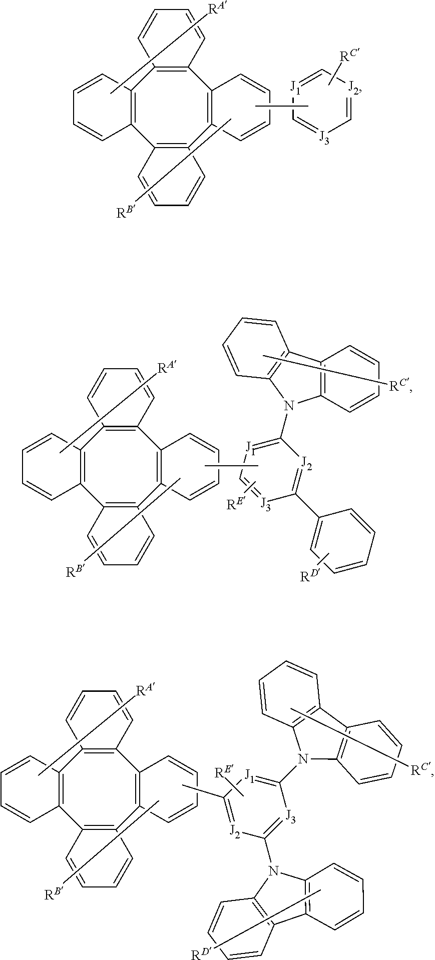 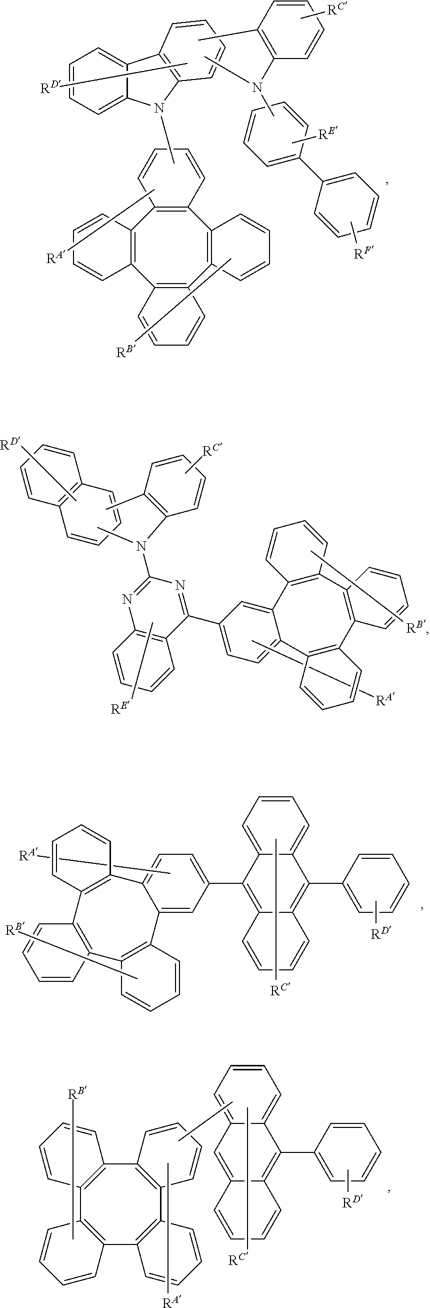 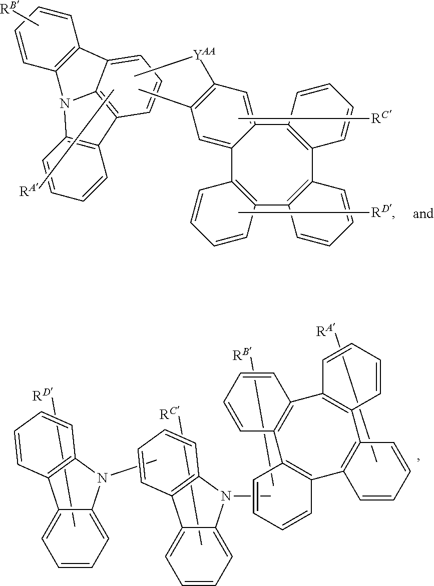
wherein:
each of J₁ to J₆ is independently C or N;
L′ is a direct bond or an organic linker;
each Y^{AA}, Y^{BB}, Y^{CC} and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of the general substituents as defined herein; any two substituents can be joined or fused to form a ring;
and where possible, each unsubstituted aromatic carbon atom is optionally replaced with N to form an aza-substituted ring.

19. The OLED of claim 17, wherein the compound is a sensitizer, and the OLED further comprises an acceptor selected from the group consisting of a fluorescent emitter, a delayed fluorescence emitter, and combination thereof.

20. A consumer product comprising an organic light-emitting device comprising:
an anode;
a cathode; and
an organic layer disposed between the anode and the cathode, wherein the organic layer comprises a compound according to claim 1.
